(19) United States
(12) Patent Application Publication
(10) Pub. No.: US 2026/0026329 A1
(43) Pub. Date: Jan. 22, 2026

(54) SEMICONDUCTOR DEVICE

(71) Applicant: ROHM CO., LTD., Kyoto (JP)

(72) Inventors: Satoki TANIGUCHI, Kyoto-shi (JP); Kentaro NASU, Kyoto-shi (JP); Nozomu NISHIURA, Kyoto-shi (JP); Kohei MORITA, Kyoto-shi (JP)

(73) Assignee: ROHM CO., LTD., Kyoto (JP)

(21) Appl. No.: 19/344,404

(22) Filed: Sep. 29, 2025

Related U.S. Application Data
(63) Continuation of application No. PCT/JP2024/012749, filed on Mar. 28, 2024.

(30) Foreign Application Priority Data
Mar. 30, 2023 (JP) 2023-056610
Mar. 30, 2023 (JP) 2023-056611
Mar. 30, 2023 (JP) 2023-056612
Mar. 30, 2023 (JP) 2023-056613

(51) Int. Cl. H01L 23/535; H01L 23/00

(52) U.S. Cl. CPC H01L 23/535; H01L 24/05; H01L 24/06; H01L 24/13; H01L 24/14; H01L 2224/0556; H01L 2224/06135; H01L 2224/13026; H01L 2224/14135

(57) ABSTRACT

A semiconductor device includes one and the other wiring groups that are arranged at an interval in a first direction X, the one and the other wiring groups each including first lower wirings and second lower wirings arrayed as stripes extending in the first direction X, a first pad wiring that is arranged over the one and the other wiring groups and is electrically connected to at least one of the first lower wirings of each of the wiring groups, and a second pad wiring that is arranged over the one and the other wiring groups at an interval from the first pad wiring in a second direction Y intersecting the first direction X and is electrically connected to at least one of the second lower wirings of each of the wiring groups.

### CROSS REFERENCE TO RELATED APPLICATIONS

This application is a bypass continuation of International Patent Application No. PCT/JP2024/012749 filed on Mar. 28, 2024, which claims the benefit of priority to Japanese Patent Application No. 2023-056610 filed on Mar. 30, 2023, Japanese Patent Application No. 2023-056611 filed on Mar. 30, 2023, Japanese Patent Application No. 2023-056612 filed on Mar. 30, 2023, and Japanese Patent Application No. 2023-056613 filed on Mar. 30, 2023, and the entire contents of these applications are hereby incorporated herein by reference.

### BACKGROUND

### 1. Field of the Disclosure

The present disclosure relates to a semiconductor device.

### 2. Description of the Related Art

US 2008/0093638 A1 discloses a semiconductor device including a source pad electrode, a drain pad electrode, a plurality of source electrodes, and a plurality of drain electrodes, which are two-dimensionally arranged on the same insulation film. The plurality of source electrodes are led out in a comb teeth shape from the source pad electrode onto the insulation film, penetrate the insulation film, and are electrically connected to a source region.

The plurality of drain electrodes are led out, from the drain pad electrode onto the insulation film, in a comb teeth shape that meshes with the plurality of source electrodes, penetrate the insulation film, and are electrically connected to a drain region. This semiconductor device has a relatively long wiring distance and relatively high wiring resistance between the source pad electrode and the drain pad electrode.

### BRIEF DESCRIPTION OF DRAWINGS

FIG. 1 is a plan view showing a semiconductor device according to a first embodiment.

FIG. 2 is a cross-sectional view taken along line II-II in FIG. 1.

FIG. 3 is a plan view showing a layout example of a first main surface.

FIG. 4 is an enlarged plan view showing a main portion of the first main surface.

FIG. 5 is an enlarged plan view showing another main portion of the first main surface.

FIG. 6 is an enlarged plan view showing still another main portion of the first main surface.

FIG. 7 is a cross-sectional view taken along line VII-VII in FIG. 5.

FIG. 8 is a cross-sectional view taken along line VIII-VIII in FIG. 5.

FIG. 9 is a cross-sectional view taken along line IX-IX in FIG. 5.

FIG. 10 is a cross-sectional view taken along line X-X in FIG. 5.

FIG. 11 is a cross-sectional view taken along line XI-XI in FIG. 6.

FIG. 12 is a cross-sectional view taken along line XII-XII in FIG. 6.

FIG. 13 is a cross-sectional view taken along line XIII-XIII in FIG. 6.

FIG. 14 is a plan view showing a layout example of a first layer wiring.

FIG. 15 is a plan view showing a layout example of a second layer wiring.

FIGS. 16A to 16J are enlarged plan views showing first wiring units according to first to tenth examples, respectively.

FIGS. 17A to 17C are enlarged plan views showing second wiring units according to first to third examples, respectively.

FIG. 18 is an enlarged plan view showing an example of a third wiring unit.

FIG. 19 is an enlarged plan view showing an example of a fourth wiring unit.

FIG. 20 is an enlarged plan view showing a first wiring unit of a semiconductor device according to a second embodiment.

FIG. 21 is an enlarged plan view showing a main portion of the first wiring unit in FIG. 20.

FIG. 22 is a plan view showing a first layout example of a second layer wiring of a semiconductor device according to a third embodiment.

FIG. 23 is a plan view showing a second layout example of the second layer wiring in FIG. 22.

FIG. 24 is an enlarged plan view showing a main portion of the second layer wiring in FIG. 23.

FIG. 25 is an enlarged plan view showing another main portion of the second layer wiring in FIG. 23.

FIG. 26 is an enlarged plan view showing still another main portion of the second layer wiring in FIG. 23.

FIG. 27 is an enlarged plan view showing still another main portion of the second layer wiring in FIG. 23.

FIG. 28 is a plan view showing a first modification example of the semiconductor devices according to the first to third embodiments.

FIG. 29 is an enlarged plan view showing a main portion of a second layer wiring.

FIG. 30 is a plan view showing a second modification example of the semiconductor devices according to the first to third embodiments.

FIG. 31 is a plan view showing a semiconductor device according to a fourth embodiment.

FIG. 32 is a cross-sectional view taken along line XXXII-XXXII in FIG. 31.

FIG. 33 is a plan view showing a layout example of a first main surface.

FIG. 34 is an enlarged plan view showing a main portion of the first main surface.

FIG. 35 is an enlarged plan view showing another main portion of the first main surface.

FIG. 36 is a cross-sectional view taken along line XXXVI-XXXVI in FIG. 35.

FIG. 37 is a cross-sectional view taken along line XXXVII-XXXVII in FIG. 35.

FIG. 38 is a cross-sectional view taken along line XXXVIII-XXXVIII in FIG. 35.

FIG. 39 is a cross-sectional view taken along line XXXIX-XXXIX in FIG. 35.

FIG. 40 is a plan view showing a layout example of a first layer wiring.

FIG. 41 is a plan view showing a layout example of a second layer wiring.

FIGS. 42A to 42J are enlarged plan views showing first wiring units according to first to tenth examples, respectively.

FIGS. 43A to 43C are enlarged plan views showing second wiring units according to first to third examples, respectively.

FIG. 44 is an enlarged plan view showing an example of a third wiring unit.

FIG. 45 is an enlarged plan view showing an example of a fourth wiring unit.

FIG. 46 is a plan view showing a modification example of the semiconductor device according to the fourth embodiment.

### DETAILED DESCRIPTION OF THE PREFERRED EMBODIMENTS

Hereinafter, specific embodiments will be described in detail with reference to accompanying drawings. All of the accompanying drawings are not precisely illustrated but are schematic views and are not necessarily matched in relative positional relationship, scale, ratio, angle, etc. Identical reference signs are given to corresponding structures among the attached drawings, and duplicate descriptions thereof shall be omitted or simplified. Descriptions provided before the omission or simplification will be applied to structures described in an omitted or simplified manner.

When the wording “substantially” is used in this description, the wording includes a numerical value (shape) equal to a numerical value (shape) of a comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element may be at least one type among boron, aluminum, gallium, and indium. The pentavalent element is at least one type among nitrogen, phosphorus, arsenic, antimony, and bismuth.

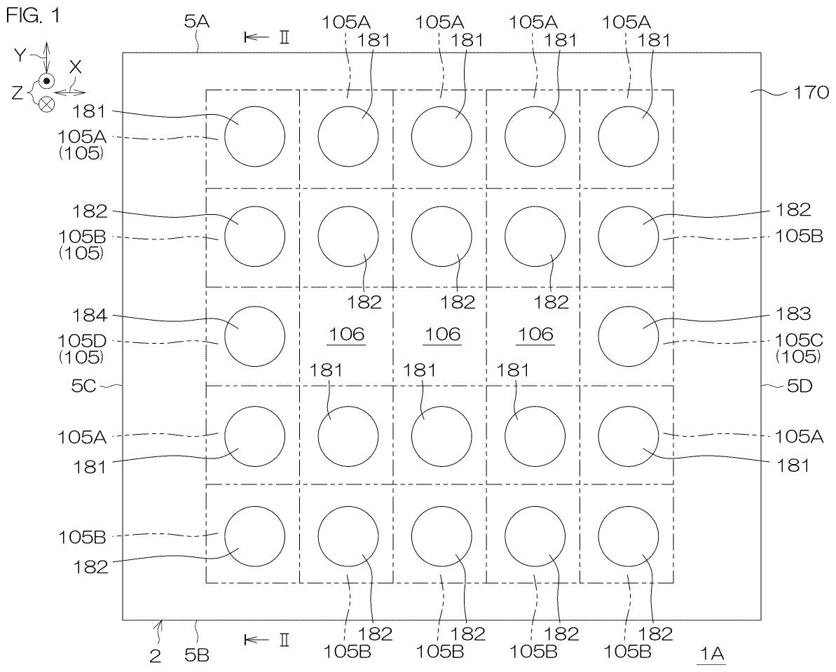

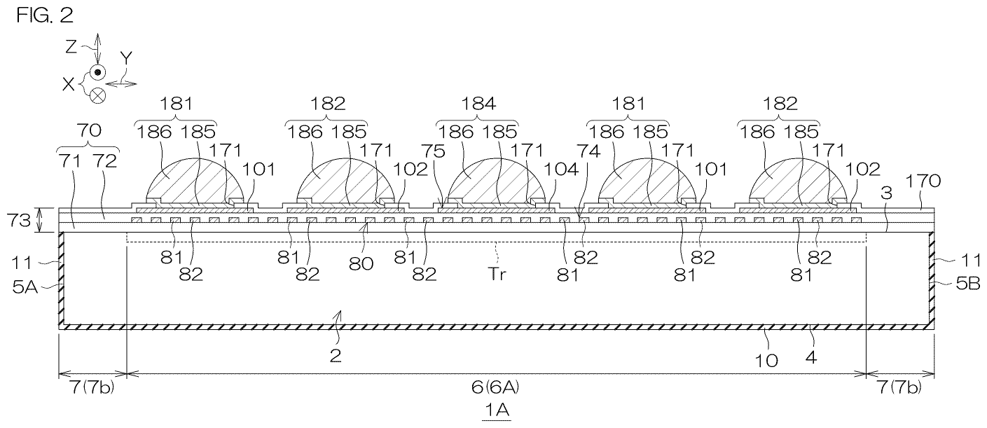

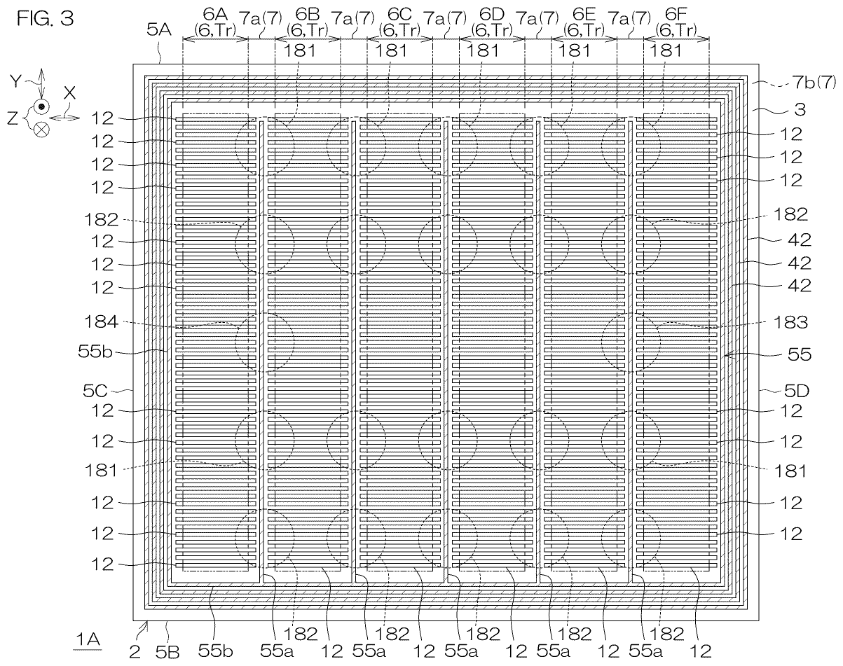

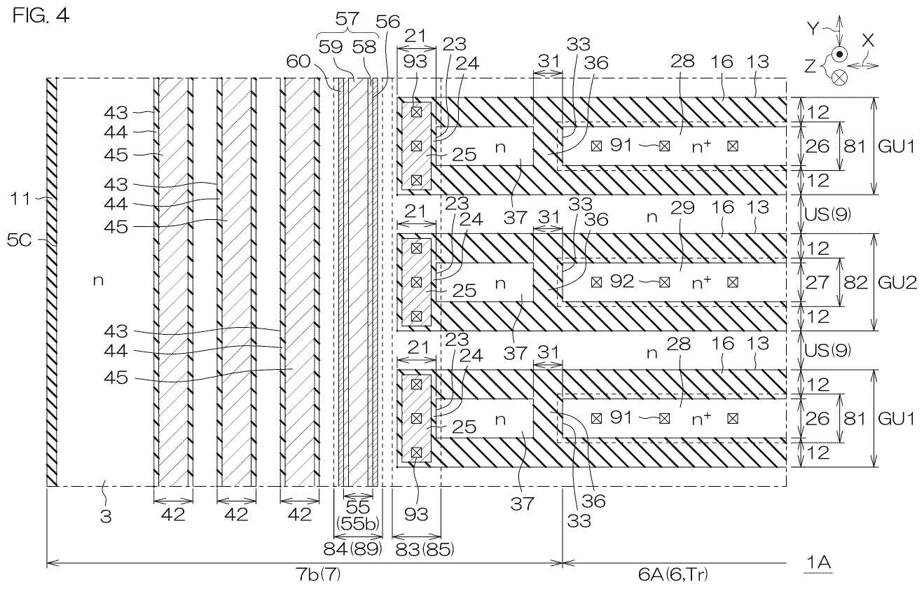

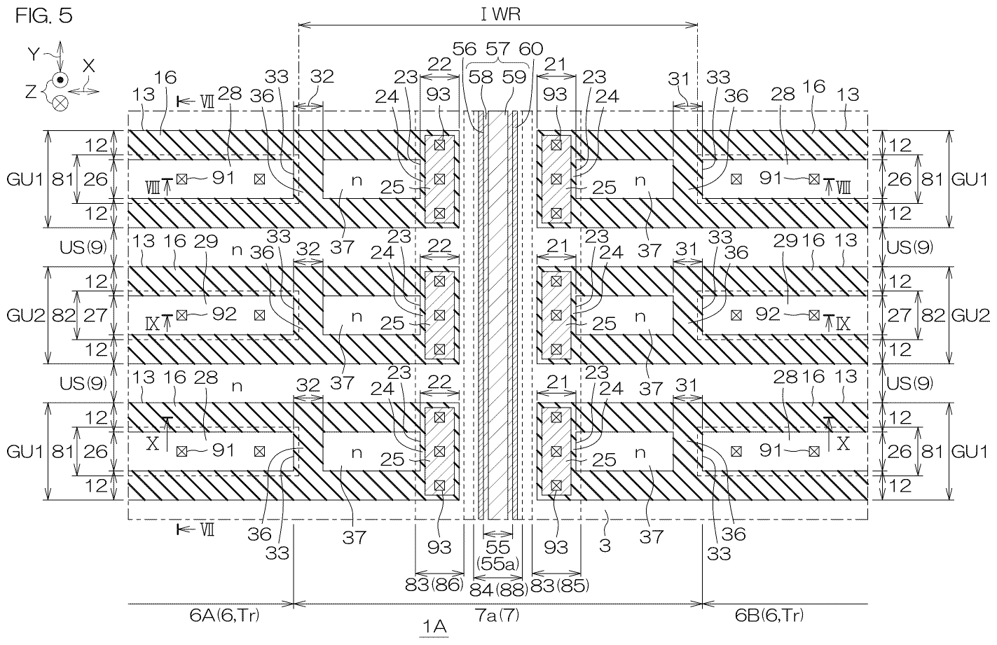

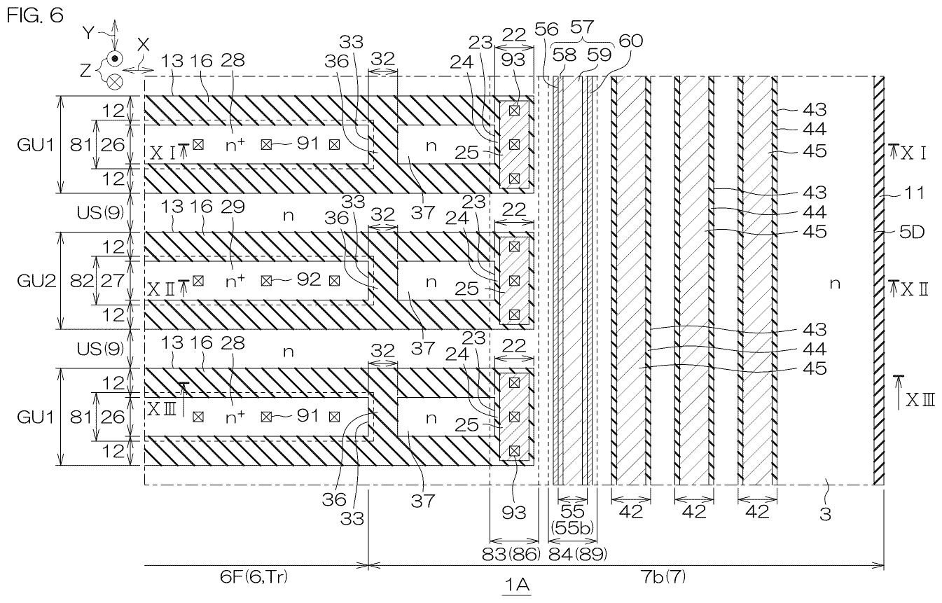

FIG. 1 is a plan view showing a semiconductor device 1A according to a first embodiment. FIG. 2 is a cross-sectional view taken along line II-II in FIG. 1. FIG. 3 is a plan view showing a layout example of a first main surface 3. FIG. 4 is an enlarged plan view showing a main portion of the first main surface 3. FIG. 5 is an enlarged plan view showing another main portion (a main portion different from that in FIG. 4) of the first main surface 3. FIG. 6 is an enlarged plan view showing still another main portion (a main portion different from those in FIGS. 4 and 5) of the first main surface 3.

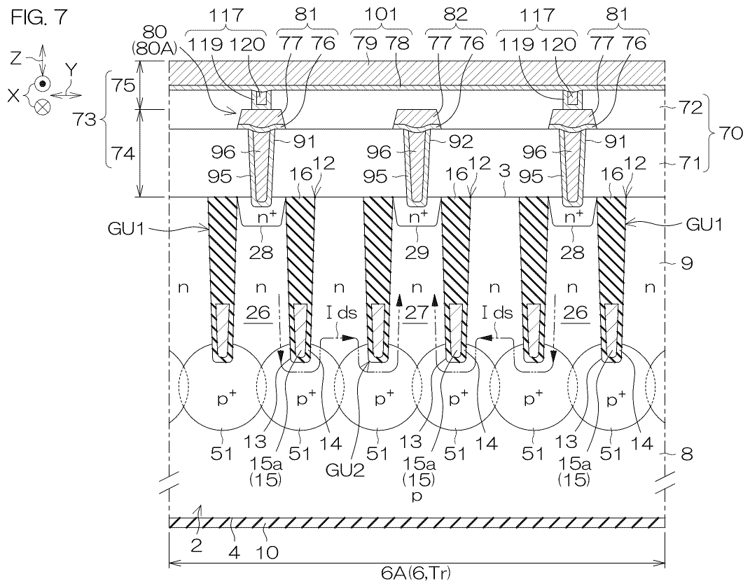

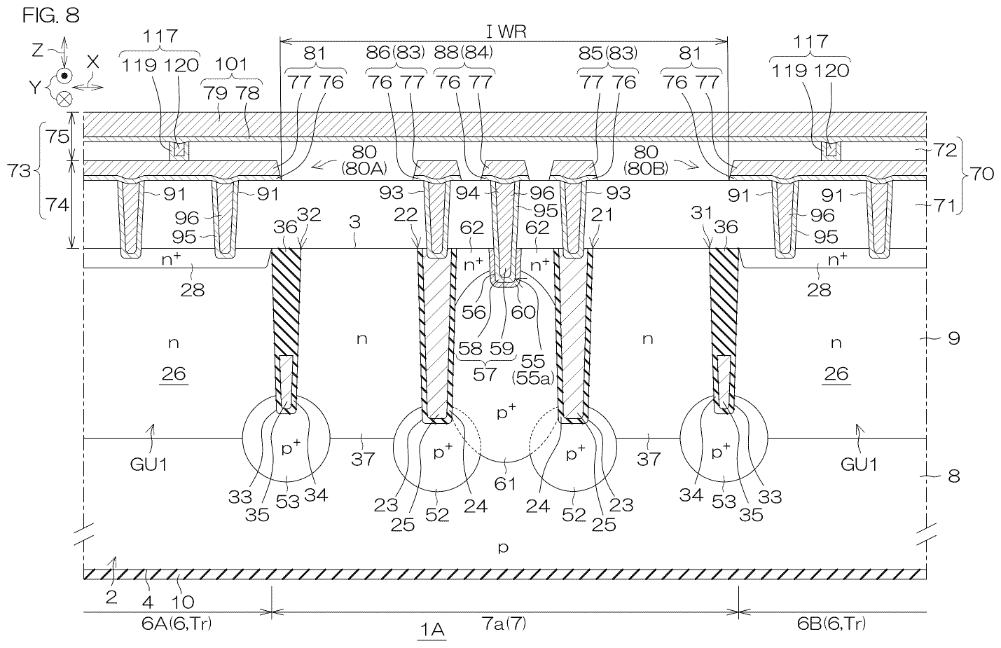

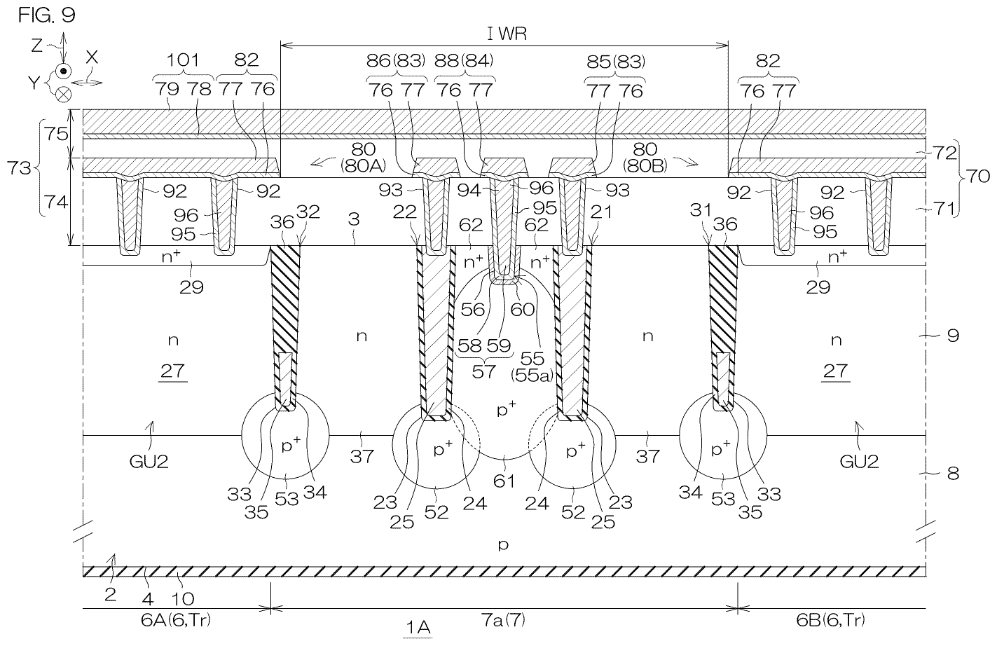

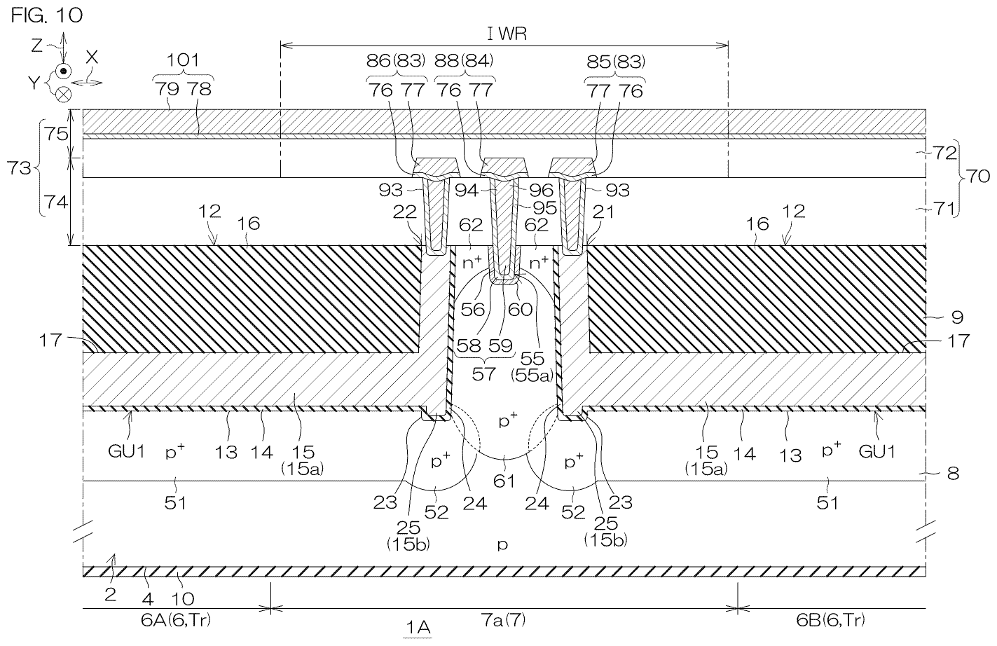

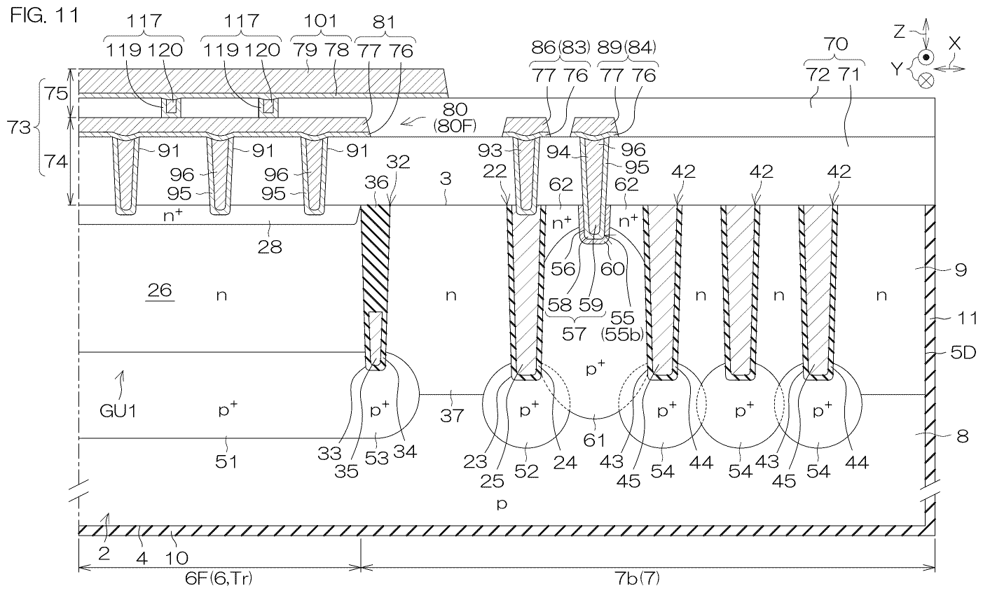

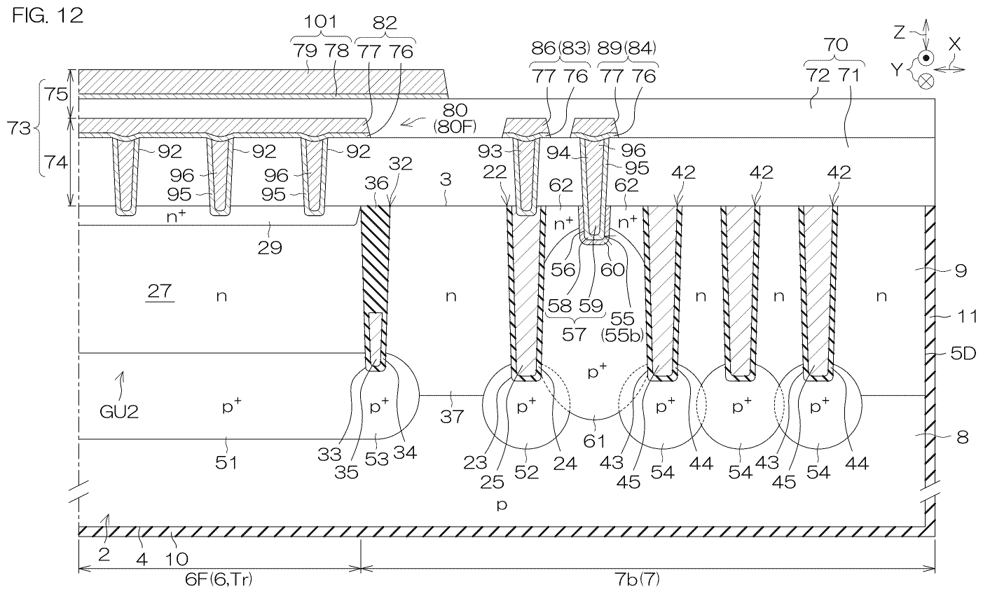

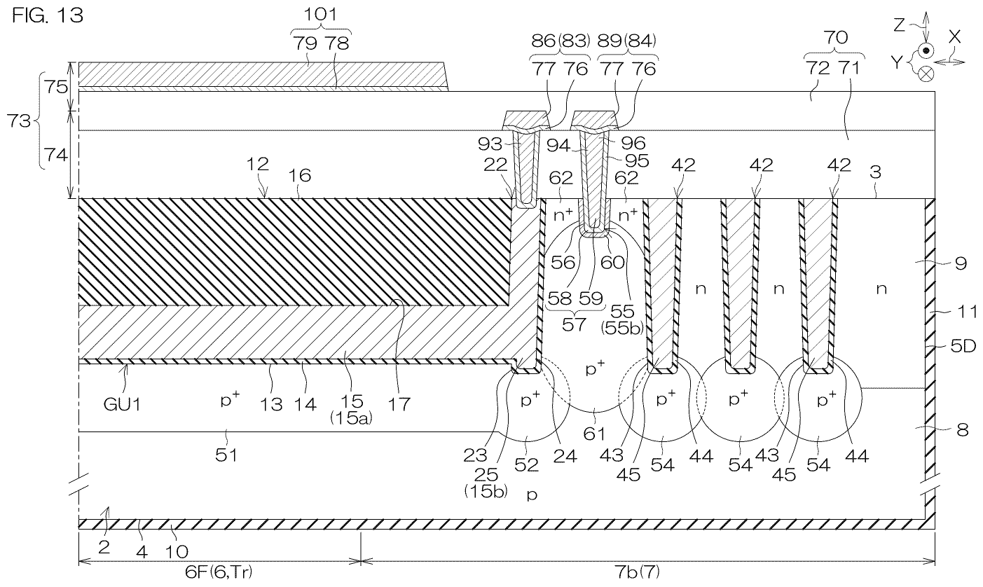

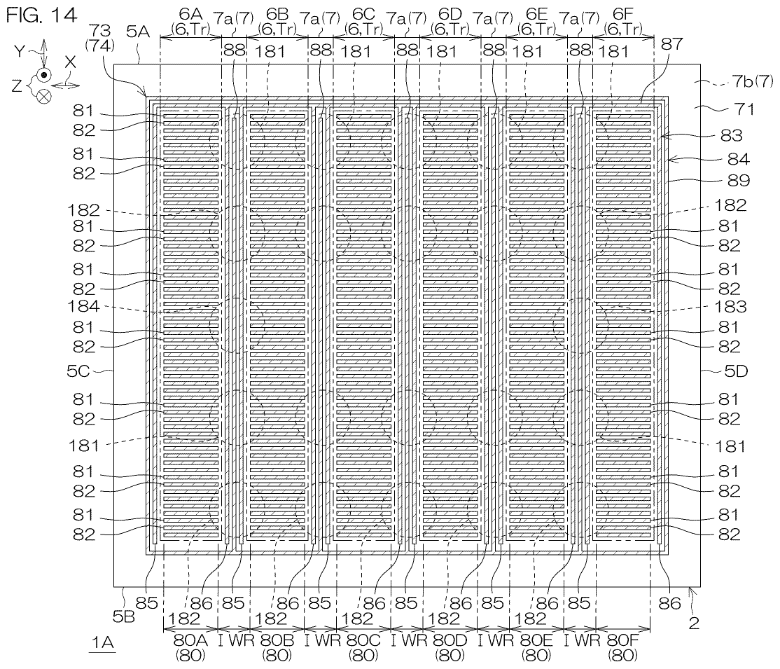

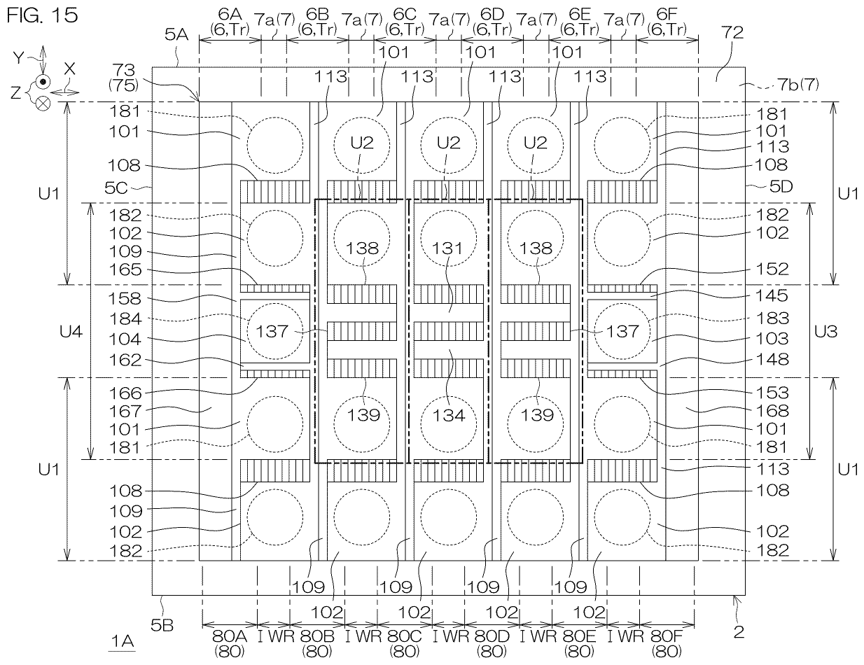

FIG. 7 is a cross-sectional view taken along line VII-VII in FIG. 5. FIG. 8 is a cross-sectional view taken along line VIII-VIII in FIG. 5. FIG. 9 is a cross-sectional view taken along line IX-IX in FIG. 5. FIG. 10 is a cross-sectional view taken along line X-X in FIG. 5. FIG. 11 is a cross-sectional view taken along line XI-XI in FIG. 6. FIG. 12 is a cross-sectional view taken along line XII-XII in FIG. 6. FIG. 13 is a cross-sectional view taken along line XIII-XIII in FIG. 6. FIG. 14 is a plan view showing a layout example of a first layer wiring 74. FIG. 15 is a plan view showing a layout example of a second layer wiring 75.

The semiconductor device 1A is a semiconductor switching device including a lateral drain source common transistor structure Tr (a field effect transistor) as an example of a device structure. With reference to FIGS. 1 to 15, the semiconductor device 1A includes a chip 2 having a hexahedral shape (specifically, a rectangular parallelepiped shape). The chip 2 may be referred to as a “semiconductor chip.” In this embodiment, the chip 2 has a single layer structure constituted of a silicon monocrystal substrate (a semiconductor substrate).

The chip 2 has a first main surface 3 on one side, a second main surface 4 on the other side, and first to fourth side surfaces 5A to 5D connecting the first main surface 3 and the second main surface 4. The first main surface 3 and the second main surface 4 are formed in a quadrangular shape in plan view in a normal direction Z of both the main surfaces (hereinafter, simply referred to as “plan view”). The normal direction Z is also a thickness direction of the chip 2.

The first side surface 5A and the second side surface 5B extend in a first direction X along the first main surface 3 and oppose each other in a second direction Y intersecting the first direction X along the first main surface 3. Specifically, the second direction Y is orthogonal to the first direction X. The third side surface 5C and the fourth side surface 5D extend in the second direction Y and oppose each other in the first direction X. In the following description, one side in the first direction X means the third side surface 5C side, and the other side in the first direction X means the fourth side surface 5D side. Also, one side in the second direction Y means the first side surface 5A side, and the other side in the second direction Y means the second side surface 5B side.

The semiconductor device 1A includes a plurality of (in this embodiment, six) active regions 6 provided at intervals in the first direction X on the first main surface 3. The plurality of active regions 6 are arrayed as first to sixth active regions 6A to 6F in this order from the third side surface 5C side. The plurality of active regions 6 are regions in which the transistor structures Tr (device structures) are respectively formed.

The plurality of active regions 6 are provided in an inner portion of the first main surface 3 at intervals from peripheral edges (the first to fourth side surfaces 5A to 5D) of the first main surface 3 and are each defined as a band extending in the second direction Y. Specifically, the plurality of active regions 6 are each defined in a polygonal shape (in this embodiment, a quadrangular shape) having four sides parallel to peripheral edges of the chip 2 in plan view. A planar shape of the active region 6 is arbitrary.

The semiconductor device 1A includes an outer region 7 provided in a region outside the plurality of active regions 6 on the first main surface 3. In this embodiment, the outer region 7 includes a plurality of boundary regions 7a and one outer peripheral region 7b. The plurality of boundary regions 7a are each defined as a band extending in the second direction Y in regions between the plurality of active regions 6 adjacent in the first direction X.

The outer peripheral region 7b is provided in a region between the peripheral edges of the first main surface 3 and the plurality of active regions 6 and extends as a band along the peripheral edges of the first main surface 3 and the plurality of active regions 6. In this embodiment, the outer peripheral region 7b surrounds the plurality of active regions 6 collectively in plan view and is defined as a polygonal annular shape (in this embodiment, a quadrangular annular shape) having four sides parallel to the peripheral edges of the chip 2. The outer peripheral region 7b is connected to the plurality of boundary regions 7a.

The semiconductor device 1A includes a base layer 8 (a base region) of a p-type formed in the chip 2. The base layer 8 may have a p-type impurity concentration of not less than 1×10¹³ cm⁻³ and not more than 1×10¹⁶ cm⁻³. A base potential is to be applied to the base layer 8. The base potential may be a reference potential. The reference potential is a potential serving as a reference of circuit operation. The reference potential may be a ground potential.

The base layer 8 is formed in the entire region between the first main surface 3 and the second main surface 4 in a thickness range of the chip 2. The base layer 8 extends in a layer shape along the first main surface 3 and the second main surface 4 and forms the first main surface 3, the second main surface 4, and the first to fourth side surfaces 5A to 5D. In this embodiment, the chip 2 is constituted of a semiconductor substrate of the p-type (a semiconductor chip of the p-type), and the base layer 8 is formed using the chip 2 of the p-type.

The base layer 8 may have a thickness of not less than 1 μm and not more than 800 μm. The thickness of the base layer 8 may have a value falling within at least one of ranges of not less than 1 μm and not more than 50 μm, not less than 50 μm and not more than 100 μm, not less than 100 μm and not more than 200 μm, not less than 200 μm and not more than 300 μm, not less than 300 μm and not more than 400 μm, not less than 400 μm and not more than 500 μm, not less than 500 μm and not more than 600 μm, not less than 600 μm and not more than 700 μm, and not less than 700 μm and not more than 800 μm.

The semiconductor device 1A includes at least one (in this embodiment, one) drift layer 9 (a drift region) of an n-type formed in a surface layer portion of the first main surface 3. In this embodiment, the drift layer 9 is an impurity region in which a conductivity type of the base layer 8 is replaced from the p-type to the n-type by an ion implantation method. As a matter of course, the drift layer 9 may be an epitaxial layer of the n-type laminated on the semiconductor substrate (the base layer 8) of the p-type. The drift layer 9 may have an n-type impurity concentration of not less than 1×10¹⁴ cm⁻³ and not more than 1×10¹⁸ cm⁻³.

The drift layer 9 is formed at intervals from the second main surface 4 (a bottom portion of the base layer 8) toward the first main surface 3 in the plurality of active regions 6 and extends in a layer shape along the first main surface 3. The drift layer 9 has portions that are led out from the plurality of active regions 6 to the outer region 7 and are positioned in the outer region 7. In this embodiment, the drift layer 9 is formed in the surface layer portion of the first main surface 3 in the entire region of the first main surface 3 and is exposed from the first to fourth side surfaces 5A to 5D.

As a matter of course, the drift layer 9 may be formed in the surface layer portion of the first main surface 3 at intervals inward from the first to fourth side surfaces 5A to 5D. As a matter of course, a plurality of drift layers 9 may be formed in a one-to-one correspondence relationship with the plurality of active regions 6. In this case, the plurality of drift layers 9 are respectively formed at intervals in the first direction X such as to be respectively positioned in the plurality of active regions 6, and are each formed as a band extending in the second direction Y.

A depth of the drift layer 9 may be not less than 0.1 μm and not more than 10 μm. The depth of the drift layer 9 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm. The depth of the drift layer 9 is preferably not more than 2 μm.

The semiconductor device 1A includes outer insulation films 10 and 11 covering outer surfaces of the chip 2. The outer insulation films 10 and 11 include a first outer insulation film 10 and a second outer insulation film 11. The outer insulation films 10 and 11 do not necessarily include both the first outer insulation film 10 and the second outer insulation film 11 at the same time and may be constituted only one of the first outer insulation film 10 and the second outer insulation film 11. As a matter of course, the presence or absence of the outer insulation films 10 and 11 is arbitrary, and a configuration without the outer insulation films 10 and 11 may be employed.

The first outer insulation film 10 covers, in a film shape, the second main surface 4. That is, the first outer insulation film 10 covers the base layer 8 exposed from the second main surface 4. In this embodiment, the first outer insulation film 10 covers the entire region of the second main surface 4 and insulates and reinforces the chip 2 from the second main surface 4 side.

The second outer insulation film 11 covers, in a film shape, at least one of the first to fourth side surfaces 5A to 5D. That is, the second outer insulation film 11 covers the base layer 8 and the drift layer 9 exposed from at least one of the first to fourth side surfaces 5A to 5D. In this embodiment, the second outer insulation film 11 covers all of the first to fourth side surfaces 5A to 5D and insulates and reinforces the chip 2 from the first to fourth side surfaces 5A to 5D sides. The second outer insulation film 11 is continuous to the first outer insulation film 10 at peripheral edges of the second main surface 4.

The outer insulation films 10 and 11 may have a single layer structure or a laminated structure including any one or both of an inorganic insulation film and an organic insulation film. In a case where the outer insulation films 10 and 11 having the laminated structure are employed, the outer insulation films 10 and 11 may include the inorganic insulation film and the organic insulation film laminated in that order from the chip 2 side.

For example, the inorganic insulation film may include at least one of a silicon oxide film, a silicon nitride film, and a silicon oxynitride film. For example, the organic insulation film may include at least one type among polyimide, polyamide, polybenzoxazole, and epoxy resin.

The semiconductor device 1A includes a plurality of transistor structures Tr respectively formed in the plurality of active regions 6 on the first main surface 3. Hereinafter, a configuration of the plurality of transistor structures Tr will be specifically described. The semiconductor device 1A includes a plurality of trench-electrode gate structures 12 (control ends) formed in the first main surface 3 in each of the active regions 6. The gate structure 12 may be referred to as a “trench gate structure.” A gate potential (a gate signal) as a control potential is to be applied to the plurality of gate structures 12.

The plurality of gate structures 12 are each formed as a band extending in the first direction X in each of the active regions 6 and are arrayed at intervals in the second direction Y. That is, the plurality of gate structures 12 are arrayed as stripes extending in the first direction X. Each of the plurality of gate structures 12 has a first end portion on the one side in the first direction X and a second end portion on the other side in the first direction X. The first end portion and the second end portion are led out from the active region 6 to the outer region 7.

In the first active region 6A, the first end portions of the plurality of gate structures 12 are led out to the outer peripheral region 7b, and the second end portions of the plurality of gate structures 12 are led out to the boundary region 7a. In the second to fifth active regions 6B to 6E, the first end portions of the plurality of gate structures 12 are led out to one boundary region 7a, and the second end portions of the plurality of gate structures 12 are led out to the other boundary region 7a. In the sixth active region 6F, the first end portions of the plurality of gate structures 12 are led out to the boundary region 7a, and the second end portions of the plurality of gate structures 12 are led out to the outer peripheral region 7b.

With regard to the plurality of active regions 6, the plurality of gate structures 12 oppose each other in the first direction X. That is, with regard to one active region 6 (6A, 6C, or 6E) and the other active region 6 (6B, 6D, or 6F), the first end portions of the plurality of gate structures 12 arranged in the other active region 6 oppose the second end portions of the plurality of gate structures 12 arranged in the one active region 6 in a one-to-one correspondence relationship.

In this embodiment, the plurality of gate structures 12 are positioned in the drift layer 9 in cross-sectional view. Specifically, the plurality of gate structures 12 are formed at intervals from a depth position of a bottom portion of the drift layer 9 toward the first main surface 3 and have side walls and bottom walls positioned in the drift layer 9. The plurality of gate structures 12 may be formed in a tapered shape having an opening width narrowing toward the bottom wall in cross-sectional view.

The plurality of gate structures 12 may penetrate the bottom portion of the drift layer 9 such as to reach the base layer 8. That is, each of the plurality of gate structures 12 may have a portion (the side wall) positioned in the drift layer 9 and a portion (the bottom wall) positioned in the base layer 8. The bottom walls of the plurality of gate structures 12 preferably have flat portions extending substantially parallel to the first main surface 3, respectively. The bottom walls of the plurality of gate structures 12 may be curved in a circular arc shape toward the second main surface 4.

The intervals between the plurality of gate structures 12 may be not less than 0.1 μm and not more than 5 μm. The interval between the gate structures 12 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The interval between the gate structures 12 is preferably not more than 3 μm.

A width of the gate structure 12 may be not less than 0.1 μm and not more than 5 μm. The width of the gate structure 12 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the gate structure 12 is preferably not more than 3 μm.

A depth of the gate structure 12 may be not less than 0.1 μm and not more than 10 μm. The depth of the gate structure 12 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm. The depth of the gate structure 12 is preferably not more than 3 μm.

Hereinafter, a configuration of one of the gate structures 12 will be described. The gate structure 12 includes a trench 13, an insulation film 14, an embedded electrode 15, and an embedded insulator 16. The trench 13 may be referred to as a “gate trench,” the insulation film 14 may be referred to as a “gate insulation film,” and the embedded electrode 15 may be referred to as a “gate electrode.” The trench 13 is dug down from the first main surface 3 toward the second main surface 4 and defines the side walls and the bottom wall of the gate structure 12.

The insulation film 14 covers, in a film shape, the wall surfaces of the trench 13. The insulation film 14 may include at least one of a silicon oxide film, a silicon nitride film, and a silicon oxynitride film. The insulation film 14 preferably has a single layer structure. The insulation film 14 preferably includes a silicon oxide film constituted of an oxide of the chip 2.

The embedded electrode 15 is embedded in the trench 13 via the insulation film 14. The embedded electrode 15 may contain conductive polysilicon. The embedded electrode 15 includes an embedded portion 15a and at least one (in this embodiment, a plurality) of lead-out portions 15b.

The embedded portion 15a is embedded on the bottom wall side of the trench 13 at intervals from the first main surface 3 toward the bottom wall of the trench 13 in the active region 6. It is preferable that the embedded portion 15a is embedded at intervals from an intermediate portion of the trench 13 toward the bottom wall of the trench 13 and has an electrode surface positioned closer to the bottom wall than to the intermediate portion of the trench 13.

The plurality of lead-out portions 15b include the lead-out portion 15b positioned at the first end portion of the trench 13 in the outer region 7 and the lead-out portion 15b positioned at the second end portion of the trench 13 in the outer region 7. The plurality of lead-out portions 15b are each led out from the bottom wall side (the embedded portion 15a side) of the trench 13 to an opening side of the trench 13. The plurality of lead-out portions 15b define, together with the embedded portions 15a, electrode recesses 17 on the opening side of the trenches 13. The electrode recesses 17 extend as bands in the first direction X along the trenches 13.

Each of the plurality of lead-out portions 15b has an electrode surface positioned in the vicinity of the first main surface 3. The electrode surface of the lead-out portion 15b may be formed flush with the first main surface 3. The electrode surface of the lead-out portion 15b may be positioned on the bottom wall side of the trench 13 with respect to the first main surface 3. The electrode surface of the lead-out portion 15b may project upward from the first main surface 3.

The embedded insulator 16 is embedded on the opening side of the trench 13. Specifically, the embedded insulator 16 is embedded in the electrode recess 17 and covers the embedded portion 15a in the trench 13. The embedded insulator 16 may be embedded in the trench 13 across the insulation film 14. The embedded insulator 16 may be embedded in the trench 13 without interposition of the insulation film 14 such as to directly cover the side walls of the trench 13. The embedded insulator 16 extends as a band in the first direction X in plan view. The embedded insulator 16 is provided as a field insulator that relaxes an electric field with respect to the trench 13. A cross-sectional area of the embedded insulator 16 is preferably larger than a cross-sectional area of the embedded portion 15a.

The embedded insulator 16 has an insulation surface positioned in the vicinity of the first main surface 3. The insulation surface may be formed flush with the first main surface 3. The insulation surface may be positioned on the bottom wall side of the trench 13 with respect to the first main surface 3. The insulation surface may project upward from the first main surface 3.

The embedded insulator 16 may include at least one type among silicon oxide, silicon nitride, and silicon oxynitride. The embedded insulator 16 may have a single layer structure. The embedded insulator 16 may be formed of the same insulating material as the insulation film 14. In this case, it is preferable that the embedded insulator 16 is constituted of a deposited substance accumulated by a chemical vapor deposition (CVD) method, etc., and has a denseness different from a denseness of the insulation film 14.

The semiconductor device 1A includes a plurality of gate units GU1 and GU2 in each of the active regions 6. The plurality of gate units GU1 and GU2 include a plurality of first gate units GU1 and a plurality of second gate units GU2.

Each of the plurality of first gate units GU1 is constituted of at least two (in this embodiment, two) of the gate structures 12 adjacent in the second direction Y in each of the active regions 6. The plurality of first gate units GU1 are alternately arrayed with at least two (in this embodiment, two) of the gate structures 12 in the second direction Y in each of the active regions 6.

With regard to the plurality of active regions 6, the plurality of first gate units GU1 oppose each other in the first direction X. That is, with regard to the one active region 6 (6A, 6C, or 6E) and the other active region 6 (6B, 6D, or 6F), the plurality of first gate units GU1 arranged in the other active region 6 oppose the plurality of first gate units GU1 arranged in the one active region 6 in a one-to-one correspondence relationship.

Each of the plurality of second gate units GU2 is constituted of at least two (in this embodiment, two) of the gate structures 12 other than the plurality of gate structures 12 constituting the plurality of first gate units GU1 among the plurality of gate structures 12 in each of the active regions 6. Each of the plurality of second gate units GU2 is constituted of at least two of the gate structures 12 adjacent in the second direction Y in each of the active regions 6. The plurality of second gate units GU2 and the plurality of first gate units GU1 are alternately arrayed in the second direction Y in each of the active regions 6.

With regard to the plurality of active regions 6, the plurality of second gate units GU2 oppose each other in the first direction X. That is, with regard to the one active region 6 (6A, 6C, or 6E) and the other active region 6 (6B, 6D, or 6F), the plurality of second gate units GU2 arranged in the other active region 6 oppose the plurality of second gate units GU2 arranged in the one active region 6 in a one-to-one correspondence relationship.

The semiconductor device 1A includes a plurality of unit spaces US respectively defined by regions between the plurality of first gate units GU1 and the plurality of second gate units GU2 adjacent in the second direction Y in each of the active regions 6. Each of the unit spaces US is defined by a region between the single gate structure 12 of the first gate unit GU1 and the single gate structure 12 of the second gate unit GU2 and includes the drift layer 9.

The semiconductor device 1A includes a plurality of trench-electrode connection structures 21 and 22 formed in the outer region 7 in the first main surface 3. The plurality of connection structures 21 and 22 connect at least two of the gate structures 12 adjacent in the second direction Y. The gate potential is to be applied to the plurality of connection structures 21 and 22. The connection structures 21 and 22 may be referred to as “gate connection structures.”

The plurality of connection structures 21 and 22 are respectively connected to the first end portions and the second end portions of the plurality of gate structures 12 in the corresponding gate units GU1 and GU2. Consequently, the plurality of connection structures 21 and 22 respectively constitute, together with the plurality of corresponding gate structures 12, the plurality of gate units GU1 and GU2 each of which has an annular shape or a ladder shape (in this embodiment, a quadrangular annular shape).

The plurality of connection structures 21 and 22 include a plurality of first connection structures 21 arranged on the first end portion side of the plurality of gate structures 12 and a plurality of second connection structures 22 arranged on the second end portion side of the plurality of gate structures 12.

The plurality of first connection structures 21 are each formed as a band extending in the second direction Y and are arrayed at intervals in the second direction Y. The plurality of first connection structures 21 are aligned in the second direction Y. The plurality of first connection structures 21 are respectively connected to the first end portions of the plurality of gate structures 12 which are to be unitized (grouped). In this embodiment, the plurality of first connection structures 21 respectively connect the first end portions of pairs of gate structures 12 adjacent in the second direction Y.

The plurality of second connection structures 22 are each formed as a band extending in the second direction Y and are arrayed at intervals in the second direction Y. The plurality of second connection structures 22 are aligned in the second direction Y. The plurality of second connection structures 22 are respectively connected to the second end portions of the plurality of gate structures 12 unitized (grouped) by the first connection structures 21. In this embodiment, the plurality of second connection structures 22 are respectively connected to the second end portions of pairs of gate structures 12 adjacent in the second direction Y.

With regard to the first active region 6A, the plurality of first connection structures 21 are respectively connected to the first end portions of the plurality of gate structures 12 adjacent in the second direction Y in the outer peripheral region 7b, and the plurality of second connection structures 22 are respectively connected to the second end portions of the plurality of gate structures 12 unitized by the first connection structures 21 in the boundary region 7a.

With regard to the second to fifth active regions 6B to 6E, the plurality of first connection structures 21 are respectively connected to the first end portions of the plurality of gate structures 12 adjacent in the second direction Y in the one boundary region 7a, and the plurality of second connection structures 22 are respectively connected to the second end portions of the plurality of gate structures 12 unitized by the first connection structures 21 in the other boundary region 7a.

With regard to the sixth active region 6F, the plurality of first connection structures 21 are respectively connected to the first end portions of the plurality of gate structures 12 adjacent in the second direction Y in the boundary region 7a, and the plurality of second connection structures 22 are respectively connected to the second end portions of the plurality of gate structures 12 unitized by the first connection structures 21 in the outer peripheral region 7b. In each of the boundary regions 7a, the plurality of second connection structures 22 are formed at intervals in the first direction X from the plurality of first connection structures 21 and respectively oppose the plurality of first connection structures 21 in the first direction X in a one-to-one correspondence relationship.

In this embodiment, the plurality of connection structures 21 and 22 are positioned in the drift layer 9 in cross-sectional view. Specifically, the plurality of connection structures 21 and 22 are formed at intervals from the depth position of the bottom portion of the drift layer 9 toward the first main surface 3 and have side walls and bottom walls positioned in the drift layer 9. The plurality of connection structures 21 and 22 may be formed in a tapered shape having an opening width narrowing toward the bottom wall in cross-sectional view.

The plurality of connection structures 21 and 22 may respectively have bottom walls which penetrate the bottom portion of the drift layer 9 such as to reach the base layer 8 and are positioned in the base layer 8. That is, each of the plurality of connection structures 21 and 22 may have a portion (the side wall) positioned in the drift layer 9 and a portion (the bottom wall) positioned in the base layer 8. The bottom walls of the plurality of connection structures 21 and 22 preferably have flat portions extending substantially parallel to the first main surface 3, respectively. As a matter of course, the bottom walls of the plurality of connection structures 21 and 22 may be curved in a circular arc shape toward the second main surface 4.

In this embodiment, a width of each of the connection structures 21 and 22 is larger than the width of the gate structure 12. The width of each of the connection structures 21 and 22 may be substantially equal to the width of the gate structure 12. The width of each of the connection structures 21 and 22 may be less than the width of the gate structure 12.

The width of each of the connection structures 21 and 22 may be not less than 0.1 μm and not more than 5 μm. The width of each of the connection structures 21 and 22 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, a depth of each of the connection structures 21 and 22 is larger than the depth of the gate structure 12. The depth of each of the connection structures 21 and 22 may be substantially equal to the depth of the gate structure 12. The depth of each of the connection structures 21 and 22 may be less than the depth of the gate structure 12.

The depth of each of the connection structures 21 and 22 may be not less than 0.1 μm and not more than 10 μm. The depth of each of the connection structures 21 and 22 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

Hereinafter, a configuration of one of the connection structures 21 and 22 will be described. Each of the connection structures 21 and 22 includes a connection trench 23, a connection insulation film 24, and a connection electrode 25. The connection trench 23 is dug from the first main surface 3 toward the second main surface 4 and defines the side wall and the bottom wall of each of the connection structures 21 and 22. The connection trench 23 is connected to the plurality of trenches 13 adjacent in the second direction Y.

The connection insulation film 24 covers, in a film shape, wall surfaces of the connection trench 23. The connection insulation film 24 is connected to the insulation film 14 and the embedded insulator 16 at communication portions between the trenches 13 and the connection trench 23. The connection insulation film 24 may include at least one of a silicon oxide film, a silicon nitride film, and a silicon oxynitride film. The connection insulation film 24 preferably has a single layer structure. The connection insulation film 24 preferably includes the silicon oxide film constituted of the oxide of the chip 2. The connection insulation film 24 is preferably formed of the same insulating material as the insulation film 14.

The connection electrode 25 is embedded in the connection trench 23 via the connection insulation film 24. The connection electrode 25 may contain conductive polysilicon. The connection electrode 25 is formed as a band extending in the second direction Y in plan view and is connected to the embedded electrode 15 at a communication portion between the trench 13 and the connection trench 23.

The connection electrode 25 can be regarded as a portion of the embedded electrode 15 (the lead-out portion 15b) led out into the connection trench 23. A connection portion between the embedded electrode 15 and the connection electrode 25 may be regarded as one component of the gate structure 12 or may be regarded as one component of each of the connection structures 21 and 22.

The connection electrode 25 has an electrode surface positioned in the vicinity of the first main surface 3. The electrode surface of the connection electrode 25 may be formed flush with the first main surface 3. The electrode surface of the connection electrode 25 may be positioned on the bottom wall side of the connection trench 23 with respect to the first main surface 3. The electrode surface of the connection electrode 25 may project upward from the first main surface 3. A plane area of the electrode surface of the connection electrode 25 is preferably larger than a plane area of the electrode surface of the embedded portion 15a.

The semiconductor device 1A includes a plurality of mesa portions 26 and 27 defined in each of the plurality of active regions 6 on the first main surface 3. The plurality of mesa portions 26 and 27 are respectively defined by the plurality of gate units GU1 and GU2. That is, the mesa portions 26 and 27 are constituted of respective portions surrounded by the plurality of gate structures 12 and the plurality of connection structures 21 and 22. The plurality of mesa portions 26 and 27 respectively extend as bands in the first direction X and are defined at intervals in the second direction Y. That is, the plurality of mesa portions 26 and 27 are defined as stripes extending in the first direction X.

The plurality of mesa portions 26 and 27 include a plurality of first mesa portions 26 and a plurality of second mesa portions 27. The plurality of first mesa portions 26 are regions (first application ends) which are respectively defined in the plurality of first gate units GU1, and to which a first drain source potential as a first potential (a high potential) is to be applied.

With regard to the plurality of active regions 6, the plurality of first mesa portions 26 oppose each other in the first direction X. That is, with regard to the one active region 6 (6A, 6C, or 6E) and the other active region 6 (6B, 6D, or 6F), the plurality of first mesa portions 26 defined in the other active region 6 oppose the plurality of first mesa portions 26 defined in the one active region 6 in a one-to-one correspondence relationship.

The plurality of second mesa portions 27 are regions (second application ends) which are respectively defined by the plurality of second gate units GU2, and to which a second drain source potential as a second potential (a low potential) different from the first potential is to be applied.

That is, the plurality of second mesa portions 27 and the plurality of first mesa portions 26 are alternately defined in the second direction Y via the plurality of unit spaces US. The second drain source potential may be the same potential as the base potential or may be a potential different from the base potential.

With regard to the plurality of active regions 6, the plurality of second mesa portions 27 oppose each other in the first direction X. That is, with regard to the one active region 6 (6A, 6C, or 6E) and the other active region 6 (6B, 6D, or 6F), the plurality of second mesa portions 27 defined in the other active region 6 oppose the plurality of second mesa portions 27 defined in the one active region 6 in a one-to-one correspondence relationship.

The semiconductor device 1A includes a plurality of drain source regions 28 and 29 of the n-type formed in the surface layer portion of the first main surface 3 (the drift layer 9) in each of the active regions 6. The plurality of drain source regions 28 and 29 are formed in the plurality of mesa portions 26 and 27. That is, the plurality of drain source regions 28 and 29 are respectively formed in regions between the plurality of gate structures 12 in the corresponding gate units GU1 and GU2. The plurality of drain source regions 28 and 29 have an n-type impurity concentration higher than the n-type impurity concentration of the drift layer 9. The n-type impurity concentration of the plurality of drain source regions 28 and 29 may be not less than 1×10¹⁶ cm⁻³ and not more than 1×10²¹ cm⁻³.

The plurality of drain source regions 28 and 29 include a plurality of first drain source regions 28 and a plurality of second drain source regions 29. The plurality of first drain source regions 28 are regions (the first application ends) to which the first drain source potential is to be applied and are formed as bands extending in the first direction X in the plurality of first mesa portions 26.

With regard to the plurality of active regions 6, the plurality of first drain source regions 28 oppose each other in the first direction X. That is, with regard to the one active region 6 (6A, 6C, or 6E) and the other active region 6 (6B, 6D, or 6F), the plurality of first drain source regions 28 arranged in the other active region 6 oppose the plurality of first drain source regions 28 arranged in the one active region 6 in a one-to-one correspondence relationship.

The plurality of second drain source regions 29 are regions (the second application ends) to which the second drain source potential is to be applied and are formed as bands extending in the first direction X in the plurality of second mesa portions 27. That is, the plurality of second drain source regions 29 and the plurality of first drain source regions 28 are alternately formed in the second direction Y. Also, the plurality of drain source regions 28 and 29 are arrayed as stripes extending in the first direction X.

With regard to the plurality of active regions 6, the plurality of second drain source regions 29 oppose each other in the first direction X. That is, with regard to the one active region 6 (6A, 6C, or 6E) and the other active region 6 (6B, 6D, or 6F), the plurality of second drain source regions 29 arranged in the other active region 6 oppose the plurality of second drain source regions 29 arranged in the one active region 6 in a one-to-one correspondence relationship.

Hereinafter, a configuration of one of the drain source region 28 and 29 will be described. The drain source regions 28 and 29 are formed at intervals from the bottom walls of the plurality of gate structures 12 toward the first main surface 3 and oppose the base layer 8 across a part of the drift layer 9. Specifically, the drain source regions 28 and 29 are formed at intervals from depth positions of the electrode surfaces of the plurality of embedded electrodes 15 toward the first main surface 3 and oppose the plurality of embedded insulators 16 in a horizontal direction along the first main surface 3.

Such a configuration is effective in preventing breakdown voltage from decreasing due to a voltage drop between the gate structures 12 and the drain source regions 28 and 29. The drain source regions 28 and 29 may be in contact with the plurality of gate structures 12. That is, the drain source regions 28 and 29 may be in contact with portions of the plurality of gate structures 12 in which the embedded insulators 16 are arranged.

The drain source regions 28 and 29 are formed at intervals in the first direction X from the first end portions and the second end portions of the plurality of gate structures 12 and are not in contact with portions of the plurality of gate structures 12 in which the lead-out portions 15b are arranged. That is, the drain source regions 28 and 29 are formed at intervals in the first direction X from the plurality of connection structures 21 and 22 positioned on both sides. Such a configuration is effective in preventing the breakdown voltage from decreasing due to a voltage drop between the end portions of the gate structures 12 (the connection structures 21 and 22) and the drain source regions 28 and 29.

The drain source regions 28 and 29 are preferably formed at region intervals of not less than 0.1 μm and not more than 2 μm from the end portions of the gate structures 12 (the connection structures 21 and 22). The region interval may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The semiconductor device 1A includes a plurality of trench-electrode separating structures 31 and 32 formed in each of the active regions 6 in the first main surface 3. A gate potential is to be applied to the plurality of separating structures 31 and 32. The separating structures 31 and 32 may be referred to as “gate separating structures.” The plurality of separating structures 31 and 32 respectively connect the plurality of gate structures 12 adjacent in the second direction Y in the corresponding gate units GU1 and GU2.

The plurality of separating structures 31 and 32 are respectively arranged in regions between the end portions of the plurality of gate structures 12 and the plurality of drain source regions 28 and 29 and physically and electrically isolate the plurality of drain source regions 28 and 29 from the end portions of the plurality of gate structures 12. That is, the plurality of separating structures 31 and 32 physically and electrically isolate the plurality of drain source regions 28 and 29 from the plurality of connection structures 21 and 22.

Each of the plurality of separating structures 31 and 32 defines a boundary portion between the active region 6 and the outer region 7 on the first main surface 3 and at the same time, increases a creepage distance between the end portion of each of the gate structures 12 (each of the connection structures 21 and 22) and each of the drain source regions 28 and 29. In this embodiment, the plurality of separating structures 31 and 32 include a plurality of first separating structures 31 arranged on the first end portion side and a plurality of second separating structures 32 arranged on the second end portion side.

The plurality of first separating structures 31 are arranged at intervals from the plurality of first end portions (the plurality of first connection structures 21) toward the drain source regions 28 and 29. The plurality of first separating structures 31 respectively extend as bands in the second direction Y and are respectively connected to the plurality of gate structures 12 adjacent in the second direction Y. The plurality of first separating structures 31 are aligned in the second direction Y. The plurality of first separating structures 31 may be connected to the drain source regions 28 and 29.

The plurality of second separating structures 32 are arranged at intervals from the plurality of second end portions (the plurality of second connection structures 22) toward the drain source regions 28 and 29. The plurality of second separating structures 32 respectively extend as bands in the second direction Y and are respectively connected to the plurality of gate structures 12 adjacent in the second direction Y. The plurality of second separating structures 32 are aligned in the second direction Y. The plurality of second separating structures 32 may be connected to the drain source regions 28 and 29.

In this embodiment, the plurality of separating structures 31 and 32 are positioned in the drift layer 9 in cross-sectional view. Specifically, the plurality of separating structures 31 and 32 are formed at intervals from the depth position of the bottom portion of the drift layer 9 toward the first main surface 3 and have side walls and bottom walls positioned in the drift layer 9. The plurality of separating structures 31 and 32 may be formed in a tapered shape having an opening width narrowing toward the bottom wall in cross-sectional view.

The plurality of separating structures 31 and 32 may penetrate the bottom portion of the drift layer 9 such as to reach the base layer 8. That is, each of the plurality of separating structures 31 and 32 may have a portion (the side wall) positioned in the drift layer 9 and a portion (the bottom wall) positioned in the base layer 8. The bottom walls of the plurality of separating structures 31 and 32 preferably have flat portions extending substantially parallel to the first main surface 3, respectively. As a matter of course, the bottom walls of the plurality of separating structures 31 and 32 may be curved in a circular arc shape toward the second main surface 4.

In this embodiment, a width of each of the separating structures 31 and 32 is less than the width of each of the connection structures 21 and 22. The width of each of the separating structures 31 and 32 may be substantially equal to the width of each of the connection structures 21 and 22. The width of each of the separating structures 31 and 32 may be larger than the width of each of the connection structures 21 and 22. The width of each of the separating structures 31 and 32 may be substantially equal to the width of the gate structure 12. The width of each of the separating structures 31 and 32 may be larger than the width of the gate structure 12. The width of each of the separating structures 31 and 32 may be less than the width of the gate structure 12.

The width of each of the separating structures 31 and 32 may be not less than 0.1 μm and not more than 5 μm. The width of each of the separating structures 31 and 32 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, a depth of each of the separating structures 31 and 32 is less than the depth of each of the connection structures 21 and 22. The depth of each of the separating structures 31 and 32 may be substantially equal to the depth of each of the connection structures 21 and 22. The depth of each of the separating structures 31 and 32 may be larger than the depth of each of the connection structures 21 and 22. The depth of each of the separating structures 31 and 32 may be substantially equal to the depth of the gate structure 12. The depth of each of the separating structures 31 and 32 may be larger than the depth of the gate structure 12. The depth of each of the separating structures 31 and 32 may be less than the depth of the gate structure 12. For example, the separating structures 31 and 32 may be formed at intervals from a depth position of an intermediate portion of the gate structures 12 toward the first main surface 3.

The depth of each of the separating structures 31 and 32 may be not less than 0.1 μm and not more than 10 μm. The depth of each of the separating structures 31 and 32 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

Hereinafter, a configuration of one of the separating structures 31 and 32 will be described. Each of the separating structures 31 and 32 includes a separation trench 33, a separation insulation film 34, a separation electrode 35, and a separation embedded insulator 36. The separation trench 33 is dug from the first main surface 3 toward the second main surface 4 and defines the side walls and the bottom wall of each of the separating structures 31 and 32. The separation trench 33 is connected to the plurality of trenches 13 adjacent in the second direction Y.

The separation insulation film 34 covers, in a film shape, wall surfaces of the separation trench 33. The separation insulation film 34 is connected to the insulation film 14 and the embedded insulator 16 at communication portions between the trenches 13 and the separation trench 33. The separation insulation film 34 can be regarded as a portion of the insulation film 14 led out into the separation trench 33. A connection portion between the insulation film 14 and the separation insulation film 34 may be regarded as one component of the gate structure 12 or may be regarded as one component of each of the separating structures 31 and 32.

The separation insulation film 34 may include at least one of a silicon oxide film, a silicon nitride film, and a silicon oxynitride film. The separation insulation film 34 preferably has a single layer structure. The separation insulation film 34 preferably includes the silicon oxide film constituted of an oxide of the chip 2. The separation insulation film 34 is preferably formed of the same insulating material as the insulation film 14.

The separation electrode 35 is embedded in the separation trench 33 via the separation insulation film 34. The separation electrode 35 may contain conductive polysilicon. The separation electrode 35 is embedded on the bottom wall side of the trench 13 at intervals from the first main surface 3 toward a bottom wall of the separation trench 33. It is preferable that the separation electrode 35 is embedded at intervals from an intermediate portion of the separation trench 33 toward the bottom wall of the separation trench 33 and has an electrode surface positioned closer to the bottom wall than to the intermediate portion of the separation trench 33.

The separation electrode 35 is connected to the embedded portion 15a at a communication portion between the trench 13 and the separation trench 33. The separation electrode 35 can be regarded as a portion of the embedded electrode 15 (the embedded portion 15a) led out into the separation trench 33. A connection portion between the embedded electrode 15 and the separation electrode 35 may be regarded as one component of the gate structure 12 or may be regarded as one component of each of the separating structures 31 and 32.

The electrode surface of the separation electrode 35 may be positioned on the bottom wall side of the separation trench 33 with respect to the electrode surface of the lead-out portion 15b of the embedded electrode 15. The electrode surface of the separation electrode 35 is preferably positioned at a depth position substantially equal to the electrode surface of the embedded portion 15a.

The separation embedded insulator 36 is embedded on an opening side of the separation trench 33. The separation embedded insulator 36 may be embedded in the separation trench 33 across the separation insulation film 34. The separation embedded insulator 36 may be embedded in the separation trench 33 without interposition of the separation insulation film 34 such as to directly cover the side walls of the separation trench 33.

The separation embedded insulator 36 extends as a band in the second direction Y in plan view. The separation embedded insulator 36 is connected to the embedded insulator 16 at a communication portion between the trench 13 and the separation trench 33. The separation embedded insulator 36 is provided as a field insulator that relaxes an electric field with respect to the separation trench 33. A cross-sectional area of the separation embedded insulator 36 is preferably larger than a cross-sectional area of the separation electrode 35.

The separation embedded insulator 36 has an insulation surface positioned in the vicinity of the first main surface 3. The insulation surface may be formed flush with the first main surface 3. The insulation surface may be positioned on the bottom wall side of the separation trench 33 with respect to the first main surface 3. The insulation surface may project upward from the first main surface 3.

The separation embedded insulator 36 may include at least one type among silicon oxide, silicon nitride, and silicon oxynitride. The separation embedded insulator 36 may have a single layer structure. The separation embedded insulator 36 may be formed of the same insulating material as the separation insulation film 34. It is preferable that the separation embedded insulator 36 is constituted of a deposited substance accumulated by the CVD method, etc., and has a denseness different from a denseness of the separation insulation film 34. The separation embedded insulator 36 is preferably formed of the same insulating material as the embedded insulator 16.

The separating structures 31 and 32 may be of a trench insulation type instead of the trench electrode type. In this case, instead of the separation electrode 35, an insulator (silicon oxide, silicon nitride, silicon oxynitride, etc.) is embedded in the separation trench 33 via the separation insulation film 34. In this case, the separation insulation film 34 may be removed.

The semiconductor device 1A includes a plurality of floating regions 37 of the n-type formed in regions between the end portions of the plurality of gate structures 12 (the connection structures 21 and 22) and the plurality of separating structures 31 and 32 in the outer region 7. The plurality of floating regions 37 respectively include portions of the drift layer 9 positioned in regions between the end portions of the plurality of gate structures 12 (the connection structures 21 and 22) and the plurality of separating structures 31 and 32 and are formed in an electrically floating state.

Although not specifically shown, the plurality of floating regions 37 may include a high concentration region having an n-type impurity concentration higher than the n-type impurity concentration of the drift layer 9 in the surface layer portion of the drift layer 9. In this case, the n-type impurity concentration of the high concentration region may be substantially equal to the n-type impurity concentration of the drain source regions 28 and 29. Also, the high concentration region may have a depth substantially equal to the depth of the drain source regions 28 and 29.

The semiconductor device 1A includes one or a plurality of trench-electrode field structures 42 formed in the outer region 7 in the first main surface 3. The field structure 42 may be referred to as a “trench field structure.” The number of the field structures 42 is arbitrary and is adjusted depending on an electric field, etc., which are to be relaxed.

The number of the field structures 42 may be one, two, three, four, five, six, seven, eight, nine, or ten. The number of the field structures 42 is preferably not more than five. In this embodiment, the semiconductor device 1A includes the three field structures 42. The base potential or the second drain source potential (the low potential) may be applied to the plurality of field structures 42. The plurality of field structures 42 may be formed in an electrically floating state.

The plurality of field structures 42 are formed in the first main surface 3 of the outer peripheral region 7b at intervals from the plurality of gate structures 12 (the plurality of connection structures 21 and 22) toward the peripheral edge of the first main surface 3. An interval between the plurality of gate structures 12 (the plurality of connection structures 21 and 22) and the innermost field structure 42 (on the active region 6 side) is preferably larger than the intervals between the plurality of gate structures 12. As a matter of course, the interval between the gate structures 12 and the field structure 42 may be less than or equal to (less than) the intervals between the plurality of gate structures 12.

Each of the plurality of field structures 42 is arranged at intervals from each other and extends as a band along the peripheral edge of the first main surface 3. In this embodiment, the plurality of field structures 42 collectively surround the plurality of active regions 6 (the plurality of gate structures 12) in plan view and are formed in a polygonal annular shape (in this embodiment, a quadrangular annular shape) having four sides parallel to the peripheral edges of the chip 2.

In this embodiment, the plurality of field structures 42 are positioned in the drift layer 9 in cross-sectional view. Specifically, the plurality of field structures 42 are formed at intervals from the depth position of the bottom portion of the drift layer 9 toward the first main surface 3 and have side walls and bottom walls positioned in the drift layer 9. The plurality of field structures 42 may be formed in a tapered shape having an opening width narrowing toward the bottom wall in cross-sectional view.

The plurality of field structures 42 may penetrate the bottom portion of the drift layer 9 such as to reach the base layer 8. That is, each of the plurality of field structures 42 may have a portion (the side wall) positioned in the drift layer 9 and a portion (the bottom wall) positioned in the base layer 8. The bottom walls of the plurality of field structures 42 preferably have flat portions extending substantially parallel to the first main surface 3, respectively. As a matter of course, the bottom walls of the plurality of field structures 42 may be curved in a circular arc shape toward the second main surface 4.

The intervals between the plurality of field structures 42 may be substantially equal to the intervals between the plurality of gate structures 12. The intervals between the plurality of field structures 42 may be less than the intervals between the plurality of gate structures 12. The intervals between the plurality of field structures 42 may be larger than the intervals between the plurality of gate structures 12.

The intervals between the plurality of field structures 42 may be not less than 0.1 μm and not more than 5 μm. The interval between the field structures 42 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, a width of the field structure 42 is larger than the width of the gate structure 12. The width of the field structure 42 may be less than the width of the gate structure 12. The width of the field structure 42 may be substantially equal to the width of the gate structure 12. The width of the field structure 42 may be substantially equal to the width of each of the connection structures 21 and 22. The width of the field structure 42 may be larger than the width of each of the connection structures 21 and 22. The width of the field structure 42 may be less than the width of each of the connection structures 21 and 22.

The width of the field structure 42 may be not less than 0.1 μm and not more than 5 μm. The width of the field structure 42 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, a depth of the field structure 42 is larger than the depth of the gate structure 12. The depth of the field structure 42 may be less than the depth of the gate structure 12. The depth of the field structure 42 may be substantially equal to the depth of the gate structure 12. The depth of the field structure 42 may be substantially equal to the depth of each of the connection structures 21 and 22. The depth of the field structure 42 may be larger than the depth of each of the connection structures 21 and 22. The depth of the field structure 42 may be less than the depth of each of the connection structures 21 and 22.

The depth of the field structure 42 may be not less than 0.1 μm and not more than 10 μm. The depth of the field structure 42 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

Hereinafter, a configuration of one of the field structures 42 will be described. The field structure 42 includes a field trench 43, a field insulation film 44, and a field electrode 45. The field trench 43 is dug from the first main surface 3 toward the second main surface 4 and defines side walls and a bottom wall of the field structure 42.

The field insulation film 44 covers, in a film shape, wall surfaces of the field trench 43. The field insulation film 44 may include at least one of a silicon oxide film, a silicon nitride film, and a silicon oxynitride film. The field insulation film 44 preferably has a single layer structure. The field insulation film 44 preferably includes the silicon oxide film constituted of an oxide of the chip 2. The field insulation film 44 is preferably formed of the same insulating material as the insulation film 14.

The field electrode 45 is embedded in the field trench 43 via the field insulation film 44. The field electrode 45 may contain conductive polysilicon. The field electrode 45 has an electrode surface positioned on the first main surface 3 side with respect to the electrode surface of the embedded portion 15a. The electrode surface of the field electrode 45 is positioned in the vicinity of the first main surface 3.

The electrode surface of the field electrode 45 may be formed flush with the first main surface 3. The electrode surface of the field electrode 45 may be positioned on the bottom wall side of the field trench 43 with respect to the first main surface 3. The electrode surface of the field electrode 45 may project upward from the first main surface 3.

The field structure 42 may be of the trench insulation type instead of the trench electrode type. In this case, instead of the field electrode 45, an insulator (silicon oxide, silicon nitride, silicon oxynitride, etc.) is embedded in the field trench 43 via the field insulation film 44. In this case, the field insulation film 44 may be removed.

The semiconductor device 1A includes a plurality of first impurity regions 51 of the p-type respectively formed in regions along lower end portions of the plurality of gate structures 12 in the chip 2. The first impurity regions 51 have a p-type impurity concentration higher than the p-type impurity concentration of the base layer 8. The p-type impurity concentration of the first impurity regions 51 may be not less than 1×10¹⁶ cm⁻³ and not more than 1×10¹⁹ cm⁻³.

The plurality of first impurity regions 51 are respectively formed at intervals from the gate structure 12 adjacent in the second direction Y in a one-to-one correspondence relationship with the lower end portions of the corresponding gate structures 12. The plurality of first impurity regions 51 respectively have portions covering bottom walls and portions covering side walls at the lower end portions of the corresponding gate structures 12. The plurality of first impurity regions 51 extend as bands in the first direction X along the corresponding gate structures 12 in plan view.

The plurality of first impurity regions 51 oppose the embedded electrodes 15 across the insulation films 14 at the lower end portions of the corresponding gate structures 12. The plurality of first impurity regions 51 are electrically connected to the drift layer 9 on the first main surface 3 side and are electrically connected to the base layer 8 on the second main surface 4 side. In this embodiment, each of the plurality of first impurity regions 51 has a portion in which the conductivity type of the drift layer 9 on the first main surface 3 side is replaced from the n-type to the p-type.

In a case where the bottom walls of the plurality of gate structures 12 are positioned in the base layer 8, the plurality of first impurity regions 51 may be formed at intervals from the bottom portion of the drift layer 9 toward the second main surface 4. In this case, the plurality of first impurity regions 51 may oppose the drift layer 9 across a part of the base layer 8.

The plurality of first impurity regions 51 are respectively formed to be wider than the corresponding gate structures 12. Specifically, the plurality of first impurity regions 51 respectively include bulging portions flared in an arc shape (a circular arc shape) in the horizontal direction (on both sides) from regions below the gate structures 12 in cross-sectional view. In a case where the gate structures 12 are each formed in a tapered shape, the bulging portions oppose the side walls of the gate structures 12 in the thickness direction of the chip 2.

With regard to the plurality of first impurity regions 51 adjacent in the second direction Y, a bulging portion of one of the first impurity regions 51 is connected to a bulging portion of the other of the first impurity regions 51. That is, the plurality of first impurity regions 51 are connected to each other in the second direction Y. Consequently, the plurality of first impurity regions 51 separate the base layer 8 and the drift layer 9 from each other in an up-down direction in the corresponding active region 6. Connection portions of the plurality of bulging portions may oppose the plurality of drain source regions 28 and 29 across the drift layer 9.

Portions of the plurality of first impurity regions 51 along the lower end portions of the plurality of gate structures 12 respectively form channels (current paths) of the transistor structure Tr. Inversion and non-inversion of the channels are controlled by the plurality of gate structures 12.

When the gate potential is applied to the plurality of gate structures 12, the first drain source potential is applied to the first drain source region 28, and the second drain source potential is applied to the second drain source region 29, the plurality of channels are turned on, and a drain source current Ids is generated (see FIG. 6).

The drain source current Ids flows from the first drain source region 28 to the second drain source region 29 via the drift layer 9 and the plurality of first impurity regions 51. That is, the drain source current Ids passes through the region below the plurality of (in this embodiment, two) gate structures 12 interposed between the first drain source region 28 and the second drain source region 29 in the second direction Y.

The first impurity region 51 is formed by introducing a p-type impurity into the chip 2 via a bottom wall portion of the trench 13. In the case of the trench 13 having a flat bottom wall, the p-type impurity can be appropriately introduced into the chip 2. Therefore, the first impurity region 51 (the channel) is appropriately formed in the region along the lower end portion of the gate structure 12.

The semiconductor device 1A includes a plurality of second impurity regions 52 of the p-type respectively formed in regions along lower end portions of the plurality of connection structures 21 and 22 inside the chip 2. The second impurity regions 52 have a p-type impurity concentration higher than the p-type impurity concentration of the base layer 8. It is preferable that the p-type impurity concentration of the second impurity regions 52 is substantially equal to the p-type impurity concentration of the first impurity regions 51. The p-type impurity concentration of the second impurity regions 52 may be not less than 1×10¹⁶ cm⁻³ and not more than 1×10¹⁹ cm⁻³.

The plurality of second impurity regions 52 are respectively formed in a one-to-one correspondence relationship with the lower end portions of the corresponding connection structures 21 and 22. The plurality of second impurity regions 52 respectively have portions covering bottom walls and portions covering side walls at the lower end portions of the corresponding connection structures 21 and 22. The plurality of second impurity regions 52 extend as bands in the second direction Y along the corresponding connection structures 21 and 22 in plan view and are connected to the first impurity regions 51 at both end portions of the corresponding connection structures 21 and 22.

The plurality of second impurity regions 52 oppose the connection electrodes 25 across the connection insulation films 24 at the lower end portions of the corresponding connection structures 21 and 22. The plurality of second impurity regions 52 are electrically connected to the drift layer 9 on the first main surface 3 side and are electrically connected to the base layer 8 on the second main surface 4 side. In this embodiment, each of the plurality of second impurity regions 52 has a portion in which the conductivity type of the drift layer 9 on the first main surface 3 side is replaced from the n-type to the p-type.

In a case where the bottom walls of the plurality of connection structures 21 and 22 are positioned in the base layer 8, the plurality of second impurity regions 52 may be formed at intervals from the bottom portion of the drift layer 9 toward the second main surface 4. In this case, the plurality of second impurity regions 52 may oppose the drift layer 9 across a part of the base layer 8.

In this embodiment, the plurality of connection structures 21 and 22 are formed deeper than the plurality of gate structures 12, and the plurality of second impurity regions 52 are formed deeper than the plurality of first impurity regions 51. That is, bottom portions of the plurality of second impurity regions 52 are positioned on the second main surface 4 side with respect to bottom portions of the plurality of first impurity regions 51. As a matter of course, the plurality of connection structures 21 and 22 may be formed at substantially the same depth as the plurality of gate structures 12, and the plurality of second impurity regions 52 may be formed at substantially the same depth as the plurality of first impurity regions 51.

The plurality of second impurity regions 52 are respectively formed to be wider than the corresponding connection structures 21 and 22. Specifically, similarly to the plurality of first impurity regions 51, the plurality of second impurity regions 52 respectively include bulging portions flared in an arc shape (a circular arc shape) in the horizontal direction (on both sides) from regions below the connection structures 21 and 22 in cross-sectional view. In a case where the connection structures 21 and 22 are each formed in a tapered shape, the bulging portions oppose the side walls of the connection structures 21 and 22 in the thickness direction of the chip 2.

The second impurity region 52 is formed by introducing the p-type impurity into the chip 2 via a bottom wall portion of the connection trench 23. In the case of the connection trench 23 having a flat bottom wall, the p-type impurity can be appropriately introduced into the chip 2. Therefore, the second impurity regions 52 are appropriately formed in the regions along the lower end portions of the connection structures 21 and 22.

The semiconductor device 1A includes a plurality of third impurity regions 53 of the p-type respectively formed in regions along lower end portions of the plurality of separating structures 31 and 32 inside the chip 2. The third impurity regions 53 have a p-type impurity concentration higher than the p-type impurity concentration of the base layer 8. It is preferable that the p-type impurity concentration of the third impurity regions 53 is substantially equal to the p-type impurity concentration of the first impurity regions 51. The p-type impurity concentration of the third impurity regions 53 may be not less than 1×10¹⁶ cm⁻³ and not more than 1×10¹⁹ cm⁻³.

The plurality of third impurity regions 53 are respectively formed in a one-to-one correspondence relationship with the lower end portions of the corresponding separating structures 31 and 32. The plurality of third impurity regions 53 respectively have portions covering bottom walls and portions covering side walls at the lower end portions of the corresponding separating structures 31 and 32. The plurality of third impurity regions 53 extend as bands in the second direction Y along the corresponding separating structures 31 and 32 in plan view and are connected to the first impurity regions 51 at both end portions of the corresponding separating structures 31 and 32.

The plurality of third impurity regions 53 oppose the separation electrodes 35 across the separation insulation films 34 at the lower end portions of the corresponding separating structures 31 and 32. The plurality of third impurity regions 53 are electrically connected to the drift layer 9 on the first main surface 3 side and are electrically connected to the base layer 8 on the second main surface 4 side. In this embodiment, each of the plurality of third impurity regions 53 has a portion in which the conductivity type of the drift layer 9 on the first main surface 3 side is replaced from the n-type to the p-type.

In a case where the bottom walls of the plurality of separating structures 31 and 32 are positioned in the base layer 8, the plurality of third impurity regions 53 may be formed at intervals from the bottom portion of the drift layer 9 toward the second main surface 4. In this case, the plurality of third impurity regions 53 may oppose the drift layer 9 across a part of the base layer 8.

In this embodiment, the plurality of separating structures 31 and 32 are formed at substantially the same depth as the plurality of gate structures 12, and the plurality of third impurity regions 53 are formed at substantially the same depth as the plurality of first impurity regions 51. As a matter of course, the plurality of separating structures 31 and 32 may be formed deeper than the plurality of gate structures 12, and the plurality of third impurity regions 53 may be formed deeper than the plurality of first impurity regions 51.

The plurality of third impurity regions 53 are respectively formed to be wider than the corresponding separating structures 31 and 32. Specifically, similarly to the plurality of first impurity regions 51, the plurality of third impurity regions 53 respectively include bulging portions flared in an arc shape (a circular arc shape) in the horizontal direction (on both sides) from regions below the separating structures 31 and 32 in cross-sectional view. In a case where the separating structures 31 and 32 are each formed in a tapered shape, the bulging portions oppose the side walls of the separating structures 31 and 32 in the thickness direction of the chip 2.

The third impurity region 53 is formed by introducing the p-type impurity into the chip 2 via a bottom wall portion of the separation trench 33. In the case of the separation trench 33 having a flat bottom wall, the p-type impurity can be appropriately introduced into the chip 2. Therefore, the third impurity regions 53 are appropriately formed in the regions along the lower end portions of the separating structures 31 and 32.

The semiconductor device 1A includes a plurality of fourth impurity regions 54 of the p-type respectively formed in regions along lower end portions of the plurality of field structures 42 in the chip 2. The fourth impurity regions 54 have a p-type impurity concentration higher than the p-type impurity concentration of the base layer 8. It is preferable that the p-type impurity concentration of the fourth impurity regions 54 is substantially equal to the p-type impurity concentration of the first impurity regions 51. The p-type impurity concentration of the fourth impurity regions 54 may be not less than 1×10¹⁶ cm⁻³ and not more than 1×10¹⁹ cm⁻³.

The plurality of fourth impurity regions 54 are respectively formed at intervals from the first impurity regions 51, the second impurity regions 52, and the third impurity regions 53 in a one-to-one correspondence relationship with the lower end portions of the corresponding field structures 42. The plurality of fourth impurity regions 54 respectively have portions covering bottom walls and portions covering side walls at the lower end portions of the corresponding field structures 42. The plurality of fourth impurity regions 54 extend as bands along the corresponding field structures 42 in plan view. Specifically, the plurality of fourth impurity regions 54 extend in an annular shape along the corresponding field structures 42 in plan view.

The plurality of fourth impurity regions 54 oppose the field electrodes 45 across the field insulation films 44 at the lower end portions of the corresponding field structures 42. The plurality of fourth impurity regions 54 are electrically connected to the drift layer 9 on the first main surface 3 side and are electrically connected to the base layer 8 on the second main surface 4 side. In this embodiment, each of the plurality of fourth impurity regions 54 has a portion in which the conductivity type of the drift layer 9 on the first main surface 3 side is replaced from the n-type to the p-type.

In a case where the bottom walls of the plurality of field structures 42 are positioned in the base layer 8, the plurality of fourth impurity regions 54 may be formed at intervals from the bottom portion of the drift layer 9 toward the second main surface 4. In this case, the plurality of fourth impurity regions 54 may oppose the drift layer 9 across a part of the base layer 8.

In this embodiment, the plurality of field structures 42 are formed deeper than the plurality of gate structures 12, and the plurality of fourth impurity regions 54 are formed deeper than the plurality of first impurity regions 51. That is, bottom portions of the plurality of fourth impurity regions 54 are positioned on the second main surface 4 side with respect to bottom portions of the plurality of first impurity regions 51. As a matter of course, the plurality of field structures 42 may be formed at substantially the same depth as the plurality of gate structures 12, and the plurality of fourth impurity regions 54 may be formed at substantially the same depth as the plurality of first impurity regions 51.

The plurality of fourth impurity regions 54 are respectively formed to be wider than the corresponding field structures 42. Specifically, similarly to the plurality of first impurity regions 51, the plurality of fourth impurity regions 54 respectively include bulging portions flared in an arc shape (a circular arc shape) in the horizontal direction (on both sides) from regions below the field structures 42 in cross-sectional view. In a case where the field structures 42 are each formed in a tapered shape, the bulging portions oppose the side walls of the field structures 42 in the thickness direction of the chip 2.

With regard to the plurality of adjacent fourth impurity regions 54, a bulging portion of one of the fourth impurity regions 54 is connected to a bulging portion of the other of the fourth impurity regions 54. Consequently, the plurality of fourth impurity regions 54 separate the base layer 8 and the drift layer 9 from each other in the up-down direction in the outer region 7.

The fourth impurity region 54 is formed by introducing the p-type impurity into the chip 2 via a bottom wall portion of the field trench 43. In the case of the field trench 43 having a flat bottom wall, the p-type impurity can be appropriately introduced into the chip 2. Therefore, the fourth impurity regions 54 are appropriately formed in the regions along the lower end portions of the field structures 42.

The semiconductor device 1A includes one or a plurality (in this embodiment, one) of a trench-electrode base structure 55 formed in the outer region 7 on the first main surface 3. The base structure 55 may be referred to as a “trench base structure.” The base potential is to be applied to the base structure 55. The base structure 55 includes a plurality of first base structures 55a and at least one (in this embodiment, one) second base structure 55b.

The plurality of first base structures 55a are respectively arranged in the plurality of boundary regions 7a. Each of the plurality of first base structures 55a extends as a band in the second direction Y in the corresponding boundary region 7a. Each of the plurality of first base structures 55a has a first end portion on the one side in the second direction Y and a second end portion on the other side in the second direction Y. As a matter of course, the plurality of first base structures 55a may be respectively arrayed at intervals in the second direction Y in corresponding one boundary region 7a.

Each of the first base structures 55a is arranged at intervals inward from the plurality of gate structures 12 adjacent in the first direction X and opposes the plurality of gate structures 12 on both sides in the first direction X. That is, each of the first base structures 55a is arranged in a region between the plurality of first connection structures 21 and the plurality of second connection structures 22 in the corresponding boundary region 7a and opposes the plurality of connection structures 21 and 22 on both sides in the first direction X. Consequently, the plurality of first base structures 55a separate the plurality of active regions 6 (the plurality of gate structures 12) on both sides in the first direction X.

The second base structure 55b is arranged in the outer peripheral region 7b. The second base structure 55b is arranged in a region between the plurality of active regions 6 (the plurality of gate structures 12) and the innermost field structure 42 and extends as a band along the plurality of active regions 6. In this embodiment, the second base structure 55b has a portion extending as a band in the first direction X and a portion extending as a band in the second direction Y in plan view and defines the plurality of active regions 6 from a plurality of directions.

In this embodiment, the second base structure 55b collectively surrounds the plurality of active regions 6 (the plurality of gate structures 12) in plan view and is formed in a polygonal annular shape (in this embodiment, a quadrangular annular shape) having four sides parallel to the peripheral edges of the chip 2. The second base structure 55b opposes the plurality of active regions 6 (the plurality of gate structures 12) in the first direction X and the second direction Y. As a matter of course, the plurality of second base structures 55b may be arrayed at intervals in the first direction X and the second direction Y along the plurality of active regions 6 such as to surround the plurality of active regions 6 (the plurality of gate structures 12).

The second base structure 55b is formed in a region on the one side in the second direction Y at intervals from the first end portions of the plurality of first base structures 55a toward the peripheral edge of the chip 2 (toward the innermost field structure 42). That is, the first end portions of the plurality of first base structures 55a are formed as open ends.

The second base structure 55b is connected to the second end portions of the plurality of first base structures 55a on the other side in the second direction Y. That is, the second base structure 55b is connected to the plurality of first base structures 55a in a comb teeth shape facing the plurality of boundary regions 7a. Also, the second base structure 55b is formed as a lead-out portion led out from the plurality of first base structures 55a to the outer peripheral region 7b.

The base structure 55 is positioned in the drift layer 9 in cross-sectional view. Specifically, the base structure 55 is formed at intervals from the depth position of the bottom portion of the drift layer 9 toward the first main surface 3 and has side walls and a bottom wall positioned in the drift layer 9. The base structure 55 may be formed in a tapered shape having an opening width narrowing toward the bottom wall in cross-sectional view. The bottom wall of the base structure 55 may have a flat portion extending substantially parallel to the first main surface 3. As a matter of course, the bottom wall of the base structure 55 may be curved in a circular arc shape toward the second main surface 4.

A width of the base structure 55 is preferably less than the width of the field structure 42. The width of the base structure 55 may be larger than the width of the field structure 42. The width of the base structure 55 may be substantially equal to the width of the field structure 42. In this embodiment, the width of the base structure 55 is less than the width of the gate structure 12. The width of the base structure 55 may be larger than the width of the gate structure 12. The width of the base structure 55 may be substantially equal to the width of the gate structure 12.

The width of the base structure 55 may be not less than 0.1 μm and not more than 5 μm. The width of the base structure 55 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

A depth of the base structure 55 is less than the depth of the field structure 42. In this embodiment, the depth of the base structure 55 is less than the depth of the gate structure 12. The base structure 55 is preferably formed at intervals from the depth position of the electrode surface of the embedded portion 15a of the gate structure 12 toward the first main surface 3. The base structure 55 is preferably formed at intervals from the depth position of the intermediate portion of the gate structure 12 toward the first main surface 3. That is, the bottom wall of the base structure 55 is preferably formed at a depth position opposing the embedded insulator 16 in the horizontal direction.

The depth of the base structure 55 may be not less than 0.1 μm and not more than 10 μm. The depth of the base structure 55 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

The base structure 55 includes a base trench 56 and a base electrode 57. The base trench 56 is dug from the first main surface 3 toward the second main surface 4, and defines the side walls and the bottom wall of the base structure 55. The base electrode 57 is embedded in the base trench 56 and is electrically connected to the chip 2 in the base trench 56.

In this embodiment, the base electrode 57 includes a first electrode 58 and a second electrode 59. The first electrode 58 covers, in a film shape, wall surfaces of the base trench 56. The first electrode 58 may have a single layer structure constituted of a Ti film or a Ti alloy film. The first electrode 58 may have a laminated structure including the Ti film and the Ti alloy film laminated in that order from the chip 2 side. The Ti alloy film may be a TiN film.

The second electrode 59 is embedded in the base trench 56 via the first electrode 58 and is electrically connected to the chip 2 via the first electrode 58. The second electrode 59 may contain at least one type among W, Al, an Al alloy, Cu, and a Cu alloy. The Al alloy may include at least one type among an AlSi alloy, an AlCu alloy, and an AlSiCu alloy.

The semiconductor device 1A includes a silicide layer 60 formed in a region along the base structure 55 in the chip 2. The silicide layer 60 is formed in each of regions along the plurality of first base structures 55a and a region along the second base structure 55b in the chip 2. The silicide layer 60 is formed in a film shape along the wall surfaces (the side walls and the bottom wall) of the base structure 55 and is mechanically and electrically connected to the base electrode 57.

The silicide layer 60 is formed at intervals inward from the plurality of gate structures 12 (the plurality of connection structures 21 and 22) adjacent in the first direction X in the plurality of boundary regions 7a. The silicide layer 60 is formed at intervals from the plurality of gate structures 12 (the plurality of connection structures 21 and 22) and the innermost field structure 42 in the outer peripheral region 7b.

The silicide layer 60 may include at least one of a Ti silicide layer, an Ni silicide layer, a Co silicide layer, a Mo silicide layer, and a W silicide layer. In this embodiment, the silicide layer 60 includes the Ti silicide layer.

A thickness of the silicide layer 60 may be not less than 1 nm and not more than 500 nm. The thickness of the silicide layer 60 may have a value falling within at least one of ranges of not less than 1 nm and not more than 50 nm, not less than 50 nm and not more than 100 nm, not less than 100 nm and not more than 200 nm, not less than 200 nm and not more than 300 nm, not less than 300 nm and not more than 400 nm, and not less than 400 nm and not more than 500 nm.

The semiconductor device 1A includes a contact region 61 of the p-type formed in a region below the base structure 55 in the chip 2. In this embodiment, the contact region 61 is formed by introducing the p-type impurity into the drift layer 9. The contact region 61 has a p-type impurity concentration higher than the n-type impurity concentration of the drift layer 9 and replaces the conductivity type of the drift layer 9 from the n-type to the p-type.

The p-type impurity concentration of the contact region 61 is higher than the p-type impurity concentration of the base layer 8. As a matter of course, the contact region 61 may be formed by introducing the p-type impurity into the base layer 8. The p-type impurity concentration of the contact region 61 may be not less than 1×10¹⁶ cm⁻³ and not more than 1×10²¹ cm⁻³.

The contact region 61 extends as a band along the base structure 55. Specifically, the contact region 61 is formed in each of regions below the plurality of first base structures 55a and a region below the second base structure 55b in the chip 2. The contact region 61 extends as a band in the second direction Y along the corresponding first base structure 55a in each of the boundary regions 7a.

The contact region 61 extends as a band along the second base structure 55b in the outer peripheral region 7b. The contact region 61 has a portion extending as a band in the first direction X and a portion extending as a band in the second direction Y along the second base structure 55b. In this embodiment, the contact region 61 is formed in a polygonal annular shape (in this embodiment, a quadrangular annular shape) extending along the base structure 55.

The contact region 61 flares in the horizontal direction from a region directly below the base structure 55 and is connected to the plurality of gate structures 12, the plurality of connection structures 21 and 22, and the innermost field structure 42. The contact region 61 extends in the thickness direction of the chip 2 in a thickness range between the base layer 8 and the base structure 55 and penetrates the bottom portion of the drift layer 9 to reach the base layer 8.

The contact region 61 has a lower end portion connected to the base layer 8 and an upper end portion connected to the base structure 55 and electrically connects the base structure 55 to the base layer 8. In this embodiment, the lower end portion of the contact region 61 is formed at intervals from the depth positions of the bottom portions of the first impurity region 51 and the fourth impurity region 54 toward the first main surface 3.

As a matter of course, the lower end portion of the contact region 61 may be positioned below the depth positions of the bottom portions of the first impurity region 51 and the fourth impurity region 54 (on the second main surface 4 side). The lower end portion of the contact region 61 may be curved in an arc shape (a circular arc shape) toward the second main surface 4.

The lower end portion of the contact region 61 may be connected to the first impurity regions 51 at portions along the gate structures 12. The lower end portion of the contact region 61 may be connected to the second impurity regions 52 at portions along the connection structures 21 and 22. The lower end portion of the contact region 61 may be connected to the innermost fourth impurity region 54 at a portion along the innermost field structure 42.

For example, in the boundary region 7a, the lower end portion of the contact region 61 may be connected to the plurality of first impurity regions 51 at portions along the plurality of gate structures 12 adjacent in the first direction X. For example, in the boundary region 7a, the lower end portion of the contact region 61 may be connected to the plurality of second impurity regions 52 at portions along the first connection structure 21 and the second connection structure 22 adjacent in the first direction X.

For example, in the outer peripheral region 7b, the lower end portion of the contact region 61 may be connected to the first impurity regions 51 and the fourth impurity region 54 at portions along the gate structures 12 and the innermost field structure 42. For example, in the outer peripheral region 7b, the lower end portion of the contact region 61 may be connected to the second impurity regions 52 and the fourth impurity region 54 at portions along the connection structures 21 and 22 and the innermost field structure 42.

The upper end portion of the contact region 61 is formed at intervals from the first main surface 3 toward the bottom wall of the base structure 55 and has a portion along the side walls and the bottom wall of the base structure 55. The upper end portion of the contact region 61 is electrically connected to the side walls and the bottom wall of the base structure 55 via the silicide layer 60. The upper end portion of the contact region 61 may be curved in an arc shape (a circular arc shape) toward the first main surface 3. That is, the upper end portion of the contact region 61 may be formed to be gradually separated from the first main surface 3 as being away from the base structure 55.

The semiconductor device 1A includes a surface layer region 62 of the n-type formed around the base structure 55 in the surface layer portion of the first main surface 3. The surface layer region 62 has an n-type impurity concentration higher than the n-type impurity concentration of the drift layer 9. The n-type impurity concentration of the surface layer region 62 may be higher than the n-type impurity concentration of the drain source regions 28 and 29. The n-type impurity concentration of the surface layer region 62 may be lower than the n-type impurity concentration of the drain source regions 28 and 29. The n-type impurity concentration of the surface layer region 62 may be not less than 1×10¹⁵ cm⁻³ and not more than 1×10²⁰ cm⁻³.

The surface layer region 62 extends as a band along the base structure 55. Specifically, in this embodiment, the surface layer region 62 is formed in each of the regions along the plurality of first base structures 55a and the region along the second base structure 55b in the surface layer portion of the first main surface 3. The surface layer region 62 extends as a band in the second direction Y along the corresponding first base structure 55a in each of the boundary regions 7a.

The surface layer region 62 extends as a band along the second base structure 55b in the outer peripheral region 7b. The surface layer region 62 has a portion extending as a band in the first direction X and a portion extending as a band in the second direction Y along the second base structure 55b. In this embodiment, the surface layer region 62 is formed in a polygonal annular shape (in this embodiment, a quadrangular annular shape) extending along the second base structure 55b.

The surface layer region 62 is formed in a thickness range between the first main surface 3 and the contact region 61. The surface layer region 62 has an upper end portion that is electrically connected to the base structure 55 via the silicide layer 60 and a lower end portion that is electrically connected to the contact region 61. In this embodiment, the surface layer region 62 has a bottom portion curved in an arc shape toward the first main surface 3.

That is, the surface layer region 62 is formed to gradually become deeper as being away from the base structure 55 and has a shallow portion formed in the vicinity of the base structure 55 and a deep portion formed far from the base structure 55. The shallow portion of the surface layer region 62 is formed at intervals from the bottom wall of the base structure 55 toward the first main surface 3 and is electrically connected to the side walls of the base structure 55 via the silicide layer 60.

The deep portion of the surface layer region 62 is positioned in a region on the second main surface 4 side with respect to the depth position of the bottom wall of the base structure 55. The deep portion of the surface layer region 62 is positioned in a region on the first main surface 3 side with respect to depth positions of the bottom walls of the plurality of gate structures 12 and the bottom walls of the plurality of field structures 42. The deep portion of the surface layer region 62 is preferably positioned in a region on the first main surface 3 side with respect to the depth position of the electrode surface of the embedded electrode 15.

The deep portion of the surface layer region 62 is particularly preferably positioned in a region on the first main surface 3 side with respect to the depth position of the intermediate portion of the gate structure 12. The deep portion of the surface layer region 62 is connected to the plurality of gate structures 12, the plurality of connection structures 21 and 22, and the innermost field structure 42. As a matter of course, the surface layer region 62 may have a substantially constant depth.

The surface layer region 62 may have a concentration gradient in which the n-type impurity concentration gradually decreases in the thickness direction. That is, the n-type impurity concentration of the surface layer region 62 may gradually decrease from the shallow portion toward the deep portion. In this case, the n-type impurity concentration in the deep portion is less than the n-type impurity concentration in the shallow portion. The n-type impurity concentration of the shallow portion may be substantially equal to the n-type impurity concentration of the plurality of drain source regions 28 and 29.

With reference to FIGS. 7 to 10, the semiconductor device 1A includes an insulating interlayer film 70 covering the first main surface 3. The interlayer film 70 may be referred to as an “interlayer insulation film,” an “intermediate film,” an “intermediate insulation film,” etc. The interlayer film 70 has a laminated structure including a first interlayer film 71 and a second interlayer film 72 laminated in that order from the chip 2 (the first main surface 3) side.

The first interlayer film 71 is an insulation film, in which a wiring is arranged, and has a single layer structure constituted of a single insulation film or a laminated structure including a plurality of insulation films. The first interlayer film 71 may include at least one of a silicon oxide film, a silicon nitride film, and a silicon oxynitride film. The first interlayer film 71 collectively covers, in a film shape (a layer shape), the plurality of active regions 6 and the outer region 7 on the first main surface 3.

That is, the first interlayer film 71 collectively covers the plurality of gate structures 12, the plurality of connection structures 21 and 22, the plurality of separating structures 31 and 32, the plurality of drain source regions 28 and 29, the plurality of field structures 42, etc. The first interlayer film 71 may cover the outer insulation films 10 and 11 on the peripheral edge side of the first main surface 3. The first interlayer film 71 may cover the first main surface 3 at intervals inward from the outer insulation films 10 and 11 and expose the outer insulation films 10 and 11.

The second interlayer film 72 is an insulation film, in which a wiring is arranged at a position higher than that of the first interlayer film 71, and has a single layer structure constituted of a single insulation film or a laminated structure including a plurality of insulation films. The second interlayer film 72 may include at least one of a silicon oxide film, a silicon nitride film, and a silicon oxynitride film. The second interlayer film 72 covers, in a film shape (a layer shape), the first interlayer film 71.

With reference to FIGS. 14 and 15, the semiconductor device 1A includes a multilayer wiring structure 73 arranged on the chip 2 (the first main surface 3). The multilayer wiring structure 73 is formed using the interlayer film 70. Specifically, the multilayer wiring structure 73 includes the first layer wiring 74 arranged on a lower layer side of the interlayer film 70 and the second layer wiring 75 arranged on an upper layer side of the interlayer film 70. The first layer wiring 74 is arranged on the first interlayer film 71 and is covered with the second interlayer film 72. The second layer wiring 75 is arranged on the second interlayer film 72 and three-dimensionally intersects the first layer wiring 74.

In this embodiment, the multilayer wiring structure 73 is constituted of a two-layer structure including the first layer wiring 74 and the second layer wiring 75. That is, the first layer wiring 74 is formed as the lowermost wiring of the multilayer wiring structure 73, and the second layer wiring 75 is formed as the uppermost wiring of the multilayer wiring structure 73. The second layer wiring 75 is exposed from the interlayer film 70.

The multilayer wiring structure 73 may include the first layer wiring 74 and the second layer wiring 75 opposing each other in the up-down direction across a part (the second interlayer film 72) of the interlayer film 70, and the number of laminated layers of the multilayer wiring structure 73 is not limited to two. That is, the multilayer wiring structure 73 may have a laminated structure of three or more layers. For example, in a case where the interlayer film 70 has one or a plurality of lower interlayer films below the first interlayer film 71, the multilayer wiring structure 73 may include one or a plurality of lower layer wirings arranged below the first layer wirings 74.

The first layer wiring 74 has a laminated structure including a first electrode 76 and a second electrode 77 laminated in that order from the first interlayer film 71 side. The first electrode 76 covers, in a film shape, the first interlayer film 71. The first electrode 76 may include one or both of a Ti film and a Ti alloy film. The Ti alloy film may be a TiN film.

The second electrode 77 covers, in a film shape, the first electrode 76. The second electrode 77 may include at least one of a W film, an Al film, an Al alloy film, a Cu film, and a Cu alloy film. The Al alloy film may include at least one of an AlSi alloy film, an AlCu alloy film, and an AlSiCu alloy film.

The second layer wiring 75 has a laminated structure including a first electrode 78 and a second electrode 79 laminated in that order from the second interlayer film 72 side. The first electrode 78 covers, in a film shape, the second interlayer film 72. The first electrode 78 may include one or both of a Ti film and a Ti alloy film. The Ti alloy film may be a TiN film.

The second electrode 79 covers, in a film shape, the first electrode 78. The second electrode 79 may include at least one of a W film, an Al film, an Al alloy film, a Cu film, and a Cu alloy film. The Al alloy film may include at least one of an AlSi alloy film, an AlCu alloy film, and an AlSiCu alloy film.

With reference to FIG. 14, etc., the first layer wiring 74 includes a plurality of wiring groups 80. The plurality of wiring groups 80 are respectively arranged on the plurality of active regions 6 at intervals in the first direction X. The plurality of wiring groups 80 are arranged in a one-to-one correspondence relationship with the first to sixth active regions 6A to 6F and are arrayed as first to sixth wiring groups 80A to 80F in this order from the third side surface 5C side.

The first wiring group 80A is arranged on the first active region 6A. The second wiring group 80B is arranged on the second active region 6B at intervals in the first direction X from the first wiring group 80A and opposes the first wiring group 80A in the first direction X. The third wiring group 80C is arranged on the third active region 6C at intervals in the first direction X from the second wiring group 80B and opposes the second wiring group 80B in the first direction X.

The fourth wiring group 80D is arranged on the fourth active region 6D at intervals in the first direction X from the third wiring group 80C and opposes the third wiring group 80C in the first direction X. The fifth wiring group 80E is arranged on the fifth active region 6E at intervals in the first direction X from the fourth wiring group 80D and opposes the fourth wiring group 80D in the first direction X. The sixth wiring group 80F is arranged on the sixth active region 6F at intervals in the first direction X from the fifth wiring group 80E and opposes the fifth wiring group 80E in the first direction X.

Each of the plurality of wiring groups 80 includes a plurality of first lower wirings 81 and a plurality of second lower wirings 82. The first lower wiring 81 transmits the first drain source potential to the first drain source region 28. The second lower wiring 82 transmits the second drain source potential to the second drain source region 29. The first lower wiring 81 may be referred to as a “first drain source wiring.” The second lower wiring 82 may be referred to as a “second drain source wiring.”

The plurality of first lower wirings 81 respectively extend as bands in the first direction X on the corresponding active region 6 and are arrayed at intervals in the second direction Y. That is, the plurality of first lower wirings 81 are arrayed as stripes extending in the first direction X. The plurality of first lower wirings 81 are respectively arranged on the plurality of first drain source regions 28 (the plurality of first mesa portions 26) and respectively oppose the plurality of first drain source regions 28 (the plurality of first mesa portions 26) in a one-to-one correspondence relationship in a lamination direction. The plurality of first lower wirings 81 are respectively electrically connected to the corresponding first drain source regions 28.

With regard to the plurality of wiring groups 80, the plurality of first lower wirings 81 oppose each other in the first direction X. That is, with regard to the one and the other wiring groups 80, the plurality of first lower wirings 81 belonging to the other wiring group 80 oppose the plurality of first lower wirings 81 belonging to the one wiring group 80 in a one-to-one correspondence relationship.

Hereinafter, a layout of one of the first lower wirings 81 will be described. The first lower wiring 81 preferably has both end portions positioned inward (on an inner side of the corresponding active region 6) from both end portions (the first end portion and the second end portion) of the corresponding gate structure 12 in the first direction X. Both the end portions of the first lower wiring 81 are preferably positioned inward from the plurality of connection structures 21 and 22.

Both the end portions of the first lower wiring 81 may be positioned in regions between the corresponding connection structures 21 and 22 and the separating structures 31 and 32 and may oppose the floating region 37 in the lamination direction. Both the end portions of the first lower wiring 81 may be positioned on the corresponding separating structures 31 and 32. Both the end portions of the first lower wiring 81 may be positioned inward from the corresponding separating structures 31 and 32 such as to be positioned on the corresponding first drain source region 28 (the first mesa portion 26).

Each of the first lower wirings 81 may have a width larger than a width of the corresponding first mesa portion 26 in the second direction Y. That is, the first lower wiring 81 may overlap the plurality of (in this embodiment, two) gate structures 12 positioned directly below. In this case, the first lower wiring 81 preferably has a width less than a width of the corresponding first gate unit GU1. As a matter of course, the first lower wiring 81 may have a width less than the width of the first mesa portion 26. As a matter of course, the first lower wiring 81 may have a width larger than the width of the first gate unit GU1.

The width of the first lower wiring 81 may be not less than 0.1 μm and not more than 15 μm. The width of the first lower wiring 81 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, not less than 9 μm and not more than 10 μm, not less than 10 μm and not more than 11 μm, not less than 11 μm and not more than 12 μm, not less than 12 μm and not more than 13 μm, not less than 13 μm and not more than 14 μm, and not less than 14 μm and not more than 15 μm.

The plurality of second lower wirings 82 are respectively arranged at intervals in the second direction Y from the plurality of first lower wirings 81 on the corresponding active region 6. The plurality of second lower wirings 82 respectively extend as bands in the first direction X and are arrayed at intervals in the second direction Y. That is, the plurality of second lower wirings 82 are arrayed as stripes extending in the first direction X. The plurality of second lower wirings 82 are respectively interposed in regions between the plurality of first lower wirings 81. Specifically, the plurality of second lower wirings 82 and the plurality of first lower wirings 81 are alternately arrayed in the second direction Y.

The plurality of second lower wirings 82 are respectively arranged on the plurality of second drain source regions 29 (the plurality of second mesa portions 27) and respectively oppose the plurality of second drain source regions 29 (the plurality of second mesa portions 27) in a one-to-one correspondence relationship in the lamination direction. The plurality of second lower wirings 82 are respectively electrically connected to the corresponding second drain source regions 29.

With regard to the plurality of wiring groups 80, the plurality of second lower wirings 82 oppose each other in the first direction X. That is, with regard to the one and the other wiring groups 80, the plurality of second lower wirings 82 belonging to the other wiring group 80 oppose the plurality of second lower wirings 82 belonging to the one wiring group 80 in a one-to-one correspondence relationship. The plurality of second lower wirings 82 may be respectively arranged at wiring intervals of not less than 0.1 μm and not more than 15 μm from the plurality of first lower wirings 81 in the second direction Y.

The wiring interval may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, not less than 9 μm and not more than 10 μm, not less than 10 μm and not more than 11 μm, not less than 11 μm and not more than 12 μm, not less than 12 μm and not more than 13 μm, not less than 13 μm and not more than 14 μm, and not less than 14 μm and not more than 15 μm.

Hereinafter, a layout of one of the second lower wirings 82 will be described. The second lower wiring 82 preferably has both end portions positioned inward (on an inner side of the corresponding active region 6) from both end portions (the first end portion and the second end portion) of the corresponding gate structure 12 in the first direction X. Both the end portions of the second lower wiring 82 are preferably positioned inward from the corresponding connection structures 21 and 22.

Both the end portions of the second lower wiring 82 may be positioned in regions between the corresponding connection structures 21 and 22 and the corresponding separating structures 31 and 32 and may oppose the floating region 37 in the lamination direction. Both the end portions of the second lower wiring 82 may be positioned on the corresponding separating structures 31 and 32. Both the end portions of the second lower wiring 82 may be positioned inward from the corresponding separating structures 31 and 32 such as to be positioned on the corresponding second drain source region 29 (the second mesa portion 27).

Each of the second lower wirings 82 may have a width larger than a width of the corresponding second mesa portion 27 in the second direction Y. That is, the second lower wiring 82 may overlap the plurality of (in this embodiment, two) gate structures 12 positioned directly below. In this case, the second lower wiring 82 preferably has a width less than a width of the corresponding second gate unit GU2. As a matter of course, the second lower wiring 82 may have a width less than the width of the second mesa portion 27. As a matter of course, the second lower wiring 82 may have a width larger than the width of the second gate unit GU2.

The width of the second lower wiring 82 may be not less than 0.1 μm and not more than 15 μm. The width of the second lower wiring 82 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, not less than 9 μm and not more than 10 μm, not less than 10 μm and not more than 11 μm, not less than 11 μm and not more than 12 μm, not less than 12 μm and not more than 13 μm, not less than 13 μm and not more than 14 μm, and not less than 14 μm and not more than 15 μm.

The second lower wiring 82 preferably has a length substantially equal to a length of the first lower wiring 81 in the first direction X. According to this configuration, variation in wiring resistance between the first lower wiring 81 and the second lower wiring 82 is prevented. The second lower wiring 82 preferably has a width substantially equal to the width of the first lower wiring 81 in the second direction Y. According to this configuration, variation in the wiring resistance between the first lower wiring 81 and the second lower wiring 82 is prevented.

As described above, in each of the wiring groups 80, the first drain source potential is to be applied to the plurality of first drain source regions 28 via the plurality of first lower wirings 81, and the second drain source potential is to be applied to the second drain source region 29 via the plurality of second lower wirings 82. That is, the first drain source potential and the second drain source potential are alternately applied in the second direction Y corresponding to a layout of the plurality of first lower wirings 81 and the plurality of second lower wirings 82. Therefore, according to this, the drain source current Ids is alternately input and output in the second direction Y.

The semiconductor device 1A (the first layer wiring 74) includes a plurality of inter-wiring regions IWR defined by regions between the plurality of wiring groups 80. The plurality of inter-wiring regions IWR are each defined by a region between an end portion of the one wiring group 80 and an end portion of the other wiring group 80. The end portions of each of the wiring groups 80 are formed by the end portions of the plurality of first lower wirings 81 and the end portions of the plurality of second lower wirings 82. The inter-wiring region IWR does not have the first lower wiring 81 and the second lower wiring 82.

The plurality of inter-wiring regions IWR are each defined as a band extending in the second direction Y and expose the first interlayer film 71. The plurality of inter-wiring regions IWR oppose the plurality of boundary regions 7a in a one-to-one correspondence relationship in the lamination direction and extend as bands along the corresponding boundary regions 7a. It is preferable that each of the inter-wiring regions IWR exposes the first end portions of the plurality of gate structures 12 (the plurality of first connection structures 21) and the second end portions of the plurality of gate structures 12 (the plurality of second connection structures 22) adjacent in the first direction X in plan view.

The semiconductor device 1A (the first layer wiring 74) includes one or a plurality (in this embodiment, one) of a third lower wiring 83 and one or a plurality (in this embodiment, one) of a fourth lower wiring 84. The third lower wiring 83 transmits the gate potential to the gate structures 12. The fourth lower wiring 84 transmits the base potential to the base structure 55. The third lower wiring 83 may be referred to as a “gate wiring.” The fourth lower wiring 84 may be referred to as a “base wiring.”

The third lower wiring 83 is arranged on the outer region 7 at intervals from the plurality of wiring groups 80. The third lower wiring 83 is routed inside and outside the plurality of inter-wiring regions IWR. Specifically, the third lower wiring 83 includes a plurality of first gate wirings 85, a plurality of second gate wirings 86, and at least one (in this embodiment, one) third gate wiring 87.

The plurality of first gate wirings 85 are respectively arranged on the one side in the first direction X with respect to the plurality of active regions 6. The plurality of first gate wirings 85 extend as bands in the second direction Y such as to intersect (in this embodiment, be orthogonal to) the first end portions of the plurality of gate structures 12 and are electrically connected to the first end portions of the plurality of gate structures 12.

That is, the first gate wiring 85 for the first active region 6A extends as a band in the second direction Y in the outer peripheral region 7b and intersects the first end portions of the plurality of gate structures 12. The first gate wiring 85 for the first active region 6A opposes the plurality of wiring groups 80 (both the plurality of first lower wirings 81 and the plurality of second lower wirings 82) in the first direction X.

The plurality of first gate wirings 85 for the second to sixth active regions 6B to 6F respectively extend as bands in the second direction Y in the corresponding boundary regions 7a (the inter-wiring regions IWR) and intersect (specifically, are orthogonal to) the first end portions of the plurality of gate structures 12. The first gate wirings 85 for the second to sixth active regions 6B to 6F oppose the plurality of wiring groups 80 (both the plurality of first lower wirings 81 and the plurality of second lower wirings 82) on both sides in the first direction X.

In this embodiment, the plurality of first gate wirings 85 extend as bands along the plurality of first connection structures 21 and collectively cover the plurality of first connection structures 21. The plurality of first gate wirings 85 are electrically connected to the plurality of first connection structures 21 and apply the gate potential to the plurality of gate structures 12 via the plurality of first connection structures 21. The plurality of first gate wirings 85 respectively have first end portions on the one side in the second direction Y and second end portions on the other side in the second direction Y.

In this embodiment, the plurality of first gate wirings 85 are arranged only in the corresponding inter-wiring regions IWR and do not have a portion positioned in the wiring groups 80 (regions between the first lower wirings 81 and the second lower wirings 82). That is, the plurality of first gate wirings 85 do not have a portion that crosses an adjacent wiring group 80 in the first direction X. In this embodiment, the plurality of first gate wirings 85 do not have a portion extending in the first direction X in the inter-wiring region IWR. As a matter of course, the plurality of first gate wirings 85 may have meandering portions on the one side and the other side in the first direction X in the inter-wiring region IWR.

The plurality of second gate wirings 86 are respectively arranged on the other side in the first direction X with respect to the plurality of active regions 6, and oppose the plurality of first gate wirings 85 across the corresponding active region 6 in the first direction X. The plurality of second gate wirings 86 extend as bands in the second direction Y such as to intersect (in this embodiment, be orthogonal to) the second end portions of the plurality of gate structures 12 and are electrically connected to the second end portions of the plurality of gate structures 12.

That is, the second gate wirings 86 for the first to fifth active regions 6A to 6E respectively extend as bands in the second direction Y in the corresponding boundary regions 7a (the inter-wiring regions IWR) and intersect the second end portions of the plurality of gate structures 12. The second gate wirings 86 for the first to fifth active regions 6A to 6E oppose the plurality of wiring groups 80 (both the plurality of first lower wirings 81 and the plurality of second lower wirings 82) on both sides in the first direction X.

The second gate wiring 86 for the sixth active region 6F extends as a band in the second direction Y in the outer peripheral region 7b and intersects (specifically, is orthogonal to) the second end portions of the plurality of gate structures 12. The second gate wiring 86 for the sixth active region 6F opposes the plurality of wiring groups 80 (both the plurality of first lower wirings 81 and the plurality of second lower wirings 82) in the first direction X.

In this embodiment, the plurality of second gate wirings 86 extend as bands along the plurality of second connection structures 22 and collectively cover the plurality of second connection structures 22. The plurality of second gate wirings 86 are electrically connected to the plurality of second connection structures 22 and apply the gate potential to the plurality of gate structures 12 via the plurality of second connection structures 22.

The plurality of second gate wirings 86 are respectively arranged at intervals in the first direction X from the first gate wirings 85 in the corresponding inter-wiring regions IWR and extend substantially parallel to the first gate wirings 85. The plurality of second gate wirings 86 respectively have first end portions on the one side in the second direction Y and second end portions on the other side in the second direction Y.

The third gate wiring 87 is arranged on the outer peripheral region 7b in a region on the one side in the second direction Y with respect to the plurality of wiring groups 80 and opposes the plurality of wiring groups 80 in the second direction Y. The third gate wiring 87 extends as a band in the first direction X and is connected to the first end portions of the plurality of first gate wirings 85 and the first end portions of the plurality of second gate wirings 86.

That is, the third gate wiring 87 connects the plurality of first gate wirings 85 and the plurality of second gate wirings 86 in a comb teeth shape facing the plurality of inter-wiring regions IWR (the boundary region 7a). The third gate wiring 87 is formed as a lead-out portion led out from the plurality of first gate wirings 85 and the plurality of second gate wirings 86 to the outer peripheral region 7b. The second end portions of the plurality of first gate wirings 85 and the second end portions of the plurality of second gate wirings 86 are formed as open ends.

The third gate wiring 87 is arranged in a region between the plurality of active regions 6 (the plurality of gate structures 12) and the innermost field structure 42. The third gate wiring 87 is arranged at intervals from the first end portions (the open ends) of the plurality of first base structures 55a toward one side (the field structure 42 side) in the second direction Y and opposes the first end portions (the open ends) of the plurality of first base structures 55a in the second direction Y. That is, a region between the first end portions of the plurality of first base structures 55a and the second base structure 55b is formed as a wiring path of the third gate wiring 87 (the third lower wiring 83).

The fourth lower wiring 84 is arranged on the outer region 7 at intervals from the plurality of wiring groups 80. The fourth lower wiring 84 is arranged at a position overlapping the base structure 55 in the outer region 7 and is routed inside and outside the plurality of inter-wiring regions IWR. Specifically, the fourth lower wiring 84 includes a plurality of first base wirings 88 and at least one (in this embodiment, one) second base wiring 89.

The plurality of first base wirings 88 are respectively arranged on the corresponding first base structures 55a in the plurality of inter-wiring regions IWR (the boundary regions 7a) and are electrically connected to the corresponding first base structures 55a. The plurality of first base wirings 88 are each arranged in a region between the first gate wiring 85 and the second gate wiring 86 in the corresponding inter-wiring region IWR and oppose the first gate wiring 85 and the second gate wiring 86 on both sides in the first direction X.

Each of the plurality of first base wirings 88 extends as a band in the second direction Y along the first base structure 55a in a region between the corresponding first gate wiring 85 and the corresponding second gate wiring 86. Each of the plurality of first base wirings 88 has a first end portion on the one side in the second direction Y and a second end portion on the other side in the second direction Y. The first end portions of the plurality of first base wirings 88 are formed at intervals from the third lower wiring 83 (the third gate wiring 87) toward the other side in the second direction Y and oppose the third lower wiring 83 (the third gate wiring 87) in the second direction Y.

In this embodiment, the plurality of first base wirings 88 are arranged only in the corresponding inter-wiring regions IWR and do not have a portion positioned in the wiring groups 80 (regions between the first lower wirings 81 and the second lower wirings 82). That is, each of the plurality of first base wirings 88 does not have a portion that crosses an adjacent wiring group 80 in the first direction X. In this embodiment, each of the plurality of first base wirings 88 does not have a portion extending in the first direction X in the inter-wiring region IWR. As a matter of course, each of the plurality of first base wirings 88 may have meandering portions on the one side and the other side in the first direction X in the inter-wiring region IWR.

The second base wiring 89 is arranged on the second base structure 55b in the outer peripheral region 7b and is electrically connected to the second base structure 55b. The second base wiring 89 is arranged in a region between the plurality of active regions 6 (the plurality of gate structures 12) and the innermost field structure 42 and extends as a band along the second base structure 55b. Specifically, the second base wiring 89 is arranged in a region between the third lower wiring 83 and the innermost field structure 42.

In this embodiment, the second base wiring 89 has a portion extending as a band in the first direction X and a portion extending as a band in the second direction Y along the second base structure 55b. In this embodiment, the second base wiring 89 collectively surrounds the plurality of active regions 6 (the plurality of gate structures 12) along the second base structure 55b and is defined as a polygonal annular shape (in this embodiment, a quadrangular annular shape) having four sides parallel to the peripheral edges of the chip 2. The second base wiring 89 opposes the plurality of wiring groups 80 in the first direction X and the second direction Y.

The second base wiring 89 is connected to the second end portions of the plurality of first base wirings 88 on the other side in the second direction Y. That is, the second base wiring 89 is connected to the plurality of first base wirings 88 in a comb teeth shape facing the plurality of inter-wiring regions IWR. The plurality of first base wirings 88 are connected in the comb teeth shape that meshes with the plurality of first gate wirings 85 and the plurality of second gate wirings 86. The second base wiring 89 is formed as a lead-out portion led out from the plurality of first base wirings 88 to the outer peripheral region 7b.

The second base wiring 89 is formed at intervals in the second direction Y from the second end portions (the open ends) of the plurality of first gate wirings 85 and the second end portions (the open ends) of the plurality of second gate wirings 86 and opposes the second end portions (the open ends) of the plurality of first gate wirings 85 and the second end portions (the open ends) of the plurality of second gate wirings 86 in the second direction Y.

For example, in a case where the base potential is to be applied to the plurality of field structures 42, the second base wiring 89 (the fourth lower wiring 84) collectively covers the plurality of field structures 42 and is electrically connected to the plurality of field structures 42. In a case where the plurality of field structures 42 are formed in an electrically floating state, the electrical connection portion of the second base wiring 89 (the fourth lower wiring 84) to the plurality of field structures 42 is not formed.

In this case, the second base wiring 89 (the fourth lower wiring 84) may be arranged in a region directly on the plurality of field structures 42 and may oppose the plurality of field structures 42 across the first interlayer film 71. As a matter of course, the second base wiring 89 (the fourth lower wiring 84) may be arranged at intervals inward from the plurality of field structures 42.

The multilayer wiring structure 73 (the semiconductor device 1A) includes a plurality of via electrodes 91 to 94 embedded in the first interlayer film 71. The plurality of via electrodes 91 to 94 include a plurality of first via electrodes 91, a plurality of second via electrodes 92, a plurality of third via electrodes 93, and at least one (in this embodiment, one) fourth via electrode 94.

The first via electrode 91 is a plug electrode that transmits the first drain source potential to the first drain source region 28. The second via electrode 92 is a plug electrode that transmits the second drain source potential to the second drain source region 29. The third via electrode 93 is a plug electrode that transmits the gate potential to the gate structures 12 (the connection structures 21 and 22). The fourth via electrode 94 is a plug electrode that transmits the base potential to the base structure 55.

The first via electrode 91 may be referred to as a “first drain source via electrode.” The second via electrode 92 may be referred to as a “second drain source via electrode.” The third via electrode 93 may be referred to as a “gate via electrode.” The fourth via electrode 94 may be referred to as a “base via electrode.”

In this embodiment, each of the plurality of via electrodes 91 to 94 includes a first electrode 95 and a second electrode 96. The first electrode 95 covers, in a film shape, wall surfaces of a via hole formed in the first interlayer film 71. The first electrode 95 may include one or both of a Ti film and a Ti alloy film. The Ti alloy film may be a TiN film.

The second electrode 96 is embedded in the via hole via the first electrode 95. The second electrode 96 may contain at least one type among W, Al, an Al alloy, Cu, and a Cu alloy. The Al alloy may include at least one type among an AlSi alloy, an AlCu alloy, and an AlSiCu alloy.

The plurality of first via electrodes 91 are interposed in a region between the plurality of first drain source regions 28 and the plurality of first lower wirings 81 in the first interlayer film 71 and respectively electrically connect the plurality of first lower wirings 81 to the corresponding first drain source regions 28. The multilayer wiring structure 73 may have at least one of the first via electrodes 91 in a region between one of the first lower wirings 81 and one of the first drain source regions 28.

In this embodiment, the plurality of first via electrodes 91 are interposed in the region between the corresponding first lower wiring 81 and the corresponding first drain source region 28 and are arrayed at intervals in the first direction X. The first via electrode 91 may be formed in a triangular shape, a quadrangular shape, a rectangular shape, a polygonal shape, a circular shape, or an elliptical shape in plan view. As a matter of course, the first via electrode 91 may be formed as a band (for example, in a rectangular shape) extending in the first direction X.

The first via electrode 91 may be formed using the first lower wiring 81. In this case, the first electrode 95 of the first via electrode 91 is integrally formed with the first electrode 76 of the first lower wiring 81 and forms one electrode film together with the first electrode 76. Similarly, the second electrode 96 of the first via electrode 91 is integrally formed with the second electrode 77 of the first lower wiring 81 and forms one electrode with the second electrode 77.

The plurality of second via electrodes 92 are interposed in a region between the plurality of second drain source regions 29 and the plurality of second lower wirings 82 in the first interlayer film 71 and respectively electrically connect the plurality of second lower wirings 82 to the corresponding second drain source regions 29. The multilayer wiring structure 73 may have at least one of the second via electrodes 92 in a region between one of the second lower wirings 82 and one of the second drain source regions 29.

In this embodiment, the plurality of second via electrodes 92 are interposed in the region between the corresponding second lower wiring 82 and the corresponding second drain source region 29 and are arrayed at intervals in the first direction X. The second via electrode 92 may be formed in a triangular shape, a quadrangular shape, a rectangular shape, a polygonal shape, a circular shape, or an elliptical shape in plan view. As a matter of course, the second via electrode 92 may be formed as a band (for example, a rectangular shape) extending in the first direction X.

The second via electrode 92 may be formed using the second lower wiring 82. In this case, the first electrode 95 of the second via electrode 92 is integrally formed with the first electrode 76 of the second lower wiring 82 and forms one electrode film together with the first electrode 76. Similarly, the second electrode 96 of the second via electrode 92 is integrally formed with the second electrode 77 of the second lower wiring 82 and forms one electrode with the second electrode 77.

The plurality of third via electrodes 93 are interposed in regions between the plurality of gate structures 12 (the plurality of connection structures 21 and 22) and the third lower wirings 83 in the first interlayer film 71 and electrically connect the third lower wirings 83 to the plurality of gate structures 12 (the plurality of connection structures 21 and 22). The multilayer wiring structure 73 may have at least one of the third via electrodes 93 for one of the gate structures 12 (the connection structures 21 and 22).

In this embodiment, the plurality of third via electrodes 93 are interposed in a region between one of the connection structures 21 and 22 and the third lower wiring 83 and are arrayed at intervals in the second direction Y. The third via electrode 93 may be formed in a triangular shape, a quadrangular shape, a rectangular shape, a polygonal shape, a circular shape, or an elliptical shape in plan view. As a matter of course, the third via electrode 93 may be formed as a band (for example, in a rectangular shape) extending in the second direction Y.

In this embodiment, the connection structures 21 and 22 wider than the gate structures 12 are formed. Therefore, since alignment margins of the third via electrodes 93 with respect to the connection structures 21 and 22 are secured, the third via electrodes 93 are appropriately connected to the connection structures 21 and 22.

The third via electrode 93 may be formed using the third lower wiring 83. In this case, the first electrode 95 of the third via electrode 93 is integrally formed with the first electrode 76 of the third lower wiring 83 and forms one electrode film together with the first electrode 76. Similarly, the second electrode 96 of the third via electrode 93 is integrally formed with the second electrode 77 of the third lower wiring 83 and forms one electrode with the second electrode 77. The fourth via electrode 94 is interposed in a region between the base structure 55 and the fourth lower wiring 84 in the first interlayer film 71 and electrically connects the fourth lower wiring 84 to the base structure 55. The fourth via electrode 94 is formed as a band extending along the base structure 55 in plan view. In this embodiment, the fourth via electrode 94 has a planar shape matched with a planar shape of the base structure 55 in plan view. That is, the fourth via electrode 94 has a plurality of portions extending as bands along the plurality of first base structures 55a and a portion extending as a band along the second base structure 55b.

As a matter of course, the multilayer wiring structure 73 may include a plurality of fourth via electrodes 94. In this case, the plurality of fourth via electrodes 94 are arrayed at intervals along the base structure 55 (the fourth lower wiring 84). In this case, the fourth via electrode 94 may be formed in a triangular shape, a quadrangular shape, a rectangular shape, a polygonal shape, a circular shape, or an elliptical shape in plan view. As a matter of course, the fourth via electrode 94 may be formed in an ended band shape extending along the base structure 55 (the base wiring).

The fourth via electrode 94 is mechanically and electrically connected to the base electrode 57. In this embodiment, the fourth via electrode 94 is integrally formed with the base electrode 57. Specifically, the first electrode 95 of the fourth via electrode 94 is integrally formed with the first electrode 58 of the base electrode 57 and forms one electrode film with the first electrode 58. Similarly, the second electrode 96 of the fourth via electrode 94 is integrally formed with the second electrode 59 of the base electrode 57 and forms one electrode with the second electrode 59.

The fourth via electrode 94 may be formed using the fourth lower wiring 84. In this case, the first electrode 95 of the fourth via electrode 94 is integrally formed with the first electrode 76 of the fourth lower wiring 84 and forms one electrode film together with the first electrode 76. Similarly, the second electrode 96 of the fourth via electrode 94 is integrally formed with the second electrode 77 of the fourth lower wiring 84 and forms one electrode with the second electrode 77.

In a case where the base potential is to be applied to the plurality of field structures 42, the plurality of fourth via electrodes 94 are interposed between the second base wiring 89 (the fourth lower wiring 84) and the plurality of field structures 42 and electrically connect the second base wiring 89 (the fourth lower wiring 84) to the plurality of field structures 42.

With reference to FIG. 15, etc., the second layer wiring 75 includes a plurality of pad wirings 101 to 104. The plurality of pad wirings 101 to 104 include one or a plurality (in this embodiment, a plurality) of the first pad wirings 101, one or a plurality (in this embodiment, a plurality) of the second pad wirings 102, one or a plurality (in this embodiment, one) of the third pad wiring 103, and one or a plurality of (in this embodiment, one) of the fourth pad wiring 104.

The first pad wiring 101 applies the first drain source potential to the first lower wiring 81. The second pad wiring 102 applies the second drain source potential to the second lower wiring 82. The third pad wiring 103 applies the gate potential to the third lower wiring 83. The fourth pad wiring 104 applies the base potential to the fourth lower wiring 84.

The first pad wiring 101 may be referred to as a “first drain source pad wiring.” The second pad wiring 102 may be referred to as a “second drain source pad wiring.” The third pad wiring 103 may be referred to as a “gate pad wiring.” The fourth pad wiring 104 may be referred to as a “base pad wiring.”

The number of the first pad wirings 101, the number of the second pad wirings 102, the number of the third pad wirings 103, and the number of the fourth pad wirings 104 are all arbitrary. In this embodiment, the multilayer wiring structure 73 (the semiconductor device 1A) includes the ten first pad wirings 101, the ten second pad wirings 102, the one third pad wiring 103, and the one fourth pad wiring 104. That is, the total number of the first to fourth pad wirings 101 to 104 is 22.

The plurality of pad wirings 101 to 104 are respectively arranged in a plurality of arrangement regions 105 set in the interlayer film 70 (see also FIG. 1). The arrangement region 105 may be referred to as a “pad arrangement region.” The plurality of arrangement regions 105 are quadrangular imaginary regions set as a matrix (in this embodiment, five rows and five columns) along the first direction X and the second direction Y in plan view. A plurality of arrangement regions 105 are all set on the corresponding one boundary region 7a and straddle the two active regions 6 adjacent in the first direction X. A plane area of the plurality of arrangement regions 105 is appropriately adjusted depending on a plane area of the chip 2, a wiring layout of a mounting substrate, etc.

The ten first pad wirings 101 are arranged in the five arrangement regions 105 of the first row and the five arrangement regions 105 of the fourth row at intervals in the first direction X. The first pad wirings 101 are each arranged on the boundary region 7a in the corresponding arrangement region 105 and straddle the two active regions 6 adjacent in the first direction X.

The ten second pad wirings 102 are arranged in the five arrangement regions 105 of the second row and the five arrangement regions 105 of the fifth row at intervals in the first direction X. The second pad wirings 102 are each arranged on the boundary region 7a in the corresponding arrangement region 105 and straddle the two active regions 6 adjacent in the first direction X.

The plurality of second pad wirings 102 arranged in the second row respectively oppose the plurality of first pad wirings 101 arranged in the first row in a one-to-one correspondence relationship in the second direction Y. Similarly, the plurality of second pad wirings 102 arranged in the fifth row respectively oppose the plurality of first pad wirings 101 arranged in the fourth row in a one-to-one correspondence relationship in the second direction Y.

The third pad wiring 103 is arranged in the arrangement region 105 of the fifth column in the third row. The third pad wiring 103 is set on the boundary region 7a in the corresponding arrangement region 105 and straddles the two active regions 6 adjacent in the first direction X. The third pad wiring 103 opposes the second pad wiring 102 on the one side in the second direction Y and opposes the first pad wiring 101 on the other side in the second direction Y.

The fourth pad wiring 104 is arranged in the arrangement region 105 of the first column in the third row. The fourth pad wiring 104 is set on the boundary region 7a in the corresponding arrangement region 105 and straddles the two active regions 6 adjacent in the first direction X. The fourth pad wiring 104 opposes the second pad wiring 102 on the one side in the second direction Y and opposes the first pad wiring 101 on the other side in the second direction Y.

The extra arrangement regions 105 without having the pad wirings 101 to 104 are set as space regions 106. In this embodiment, three arrangement regions 105 of the second to fourth columns of the third row are set as the space regions 106. That is, the three second pad wirings 102 arranged in the second row respectively oppose the three first pad wirings 101 arrayed in the fourth row across the three space regions 106 in a one-to-one correspondence relationship in the second direction Y. The fourth pad wiring 104 opposes the third pad wiring 103 in the first direction X across the three space regions 106.

The second layer wiring 75 includes a plurality of first wiring units U1, a plurality of second wiring units U2, one third wiring unit U3, and one fourth wiring unit U4. The first to fourth wiring units U1 to U4 are grouped (classified) according to a layout of the first to fourth pad wirings 101 to 104.

Each of the plurality of first wiring units U1 includes the first pad wiring 101 and the second pad wiring 102 opposing (closely opposing) each other in the second direction Y. That is, the second layer wiring 75 includes the ten first wiring units U1. In each of the first wiring units U1, the first pad wiring 101 and the second pad wiring 102 are selectively electrically connected to the first lower wirings 81 and the second lower wirings 82 of the plurality of wiring groups 80 positioned directly below. The plurality of first wiring units U1 have identical layouts to each other except for a difference in connection targets which are the first lower wirings 81 and the second lower wirings 82.

Each of the plurality of second wiring units U2 includes the first pad wiring 101 and the second pad wiring 102 opposing each other in the second direction Y across the space region 106. That is, the second layer wiring 75 includes the three second wiring units U2. In each of the second wiring units U2, the first pad wiring 101 and the second pad wiring 102 are selectively electrically connected to the first lower wirings 81 and the second lower wirings 82 of the plurality of wiring groups 80 positioned directly below.

The third wiring unit U3 includes the first pad wiring 101, the second pad wiring 102, and the third pad wiring 103 opposing (closely opposing) each other in the second direction Y. In the third wiring unit U3, the first pad wiring 101 and the second pad wiring 102 are selectively electrically connected to the first lower wirings 81 and the second lower wirings 82 of the plurality of wiring groups 80 positioned directly below. Also, the third pad wiring 103 is electrically connected to the third lower wiring 83.

The fourth wiring unit U4 includes the first pad wiring 101, the second pad wiring 102, and the fourth pad wiring 104 opposing (closely opposing) each other in the second direction Y. In the fourth wiring unit U4, the first pad wiring 101 and the second pad wiring 102 are selectively electrically connected to the first lower wirings 81 and the second lower wirings 82 of the plurality of wiring groups 80 positioned directly below. Also, the fourth pad wiring 104 is electrically connected to the fourth lower wiring 84.

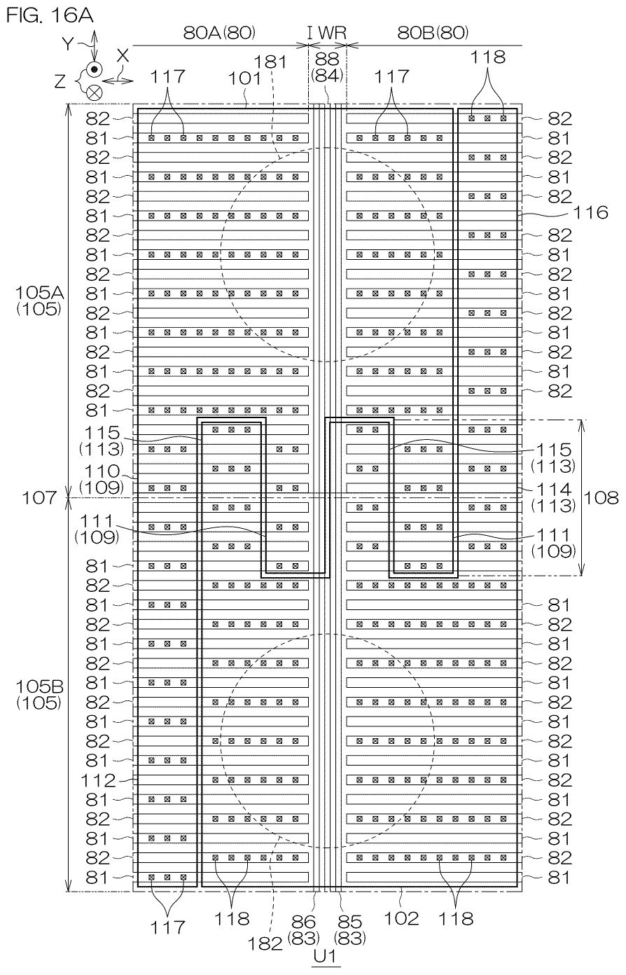

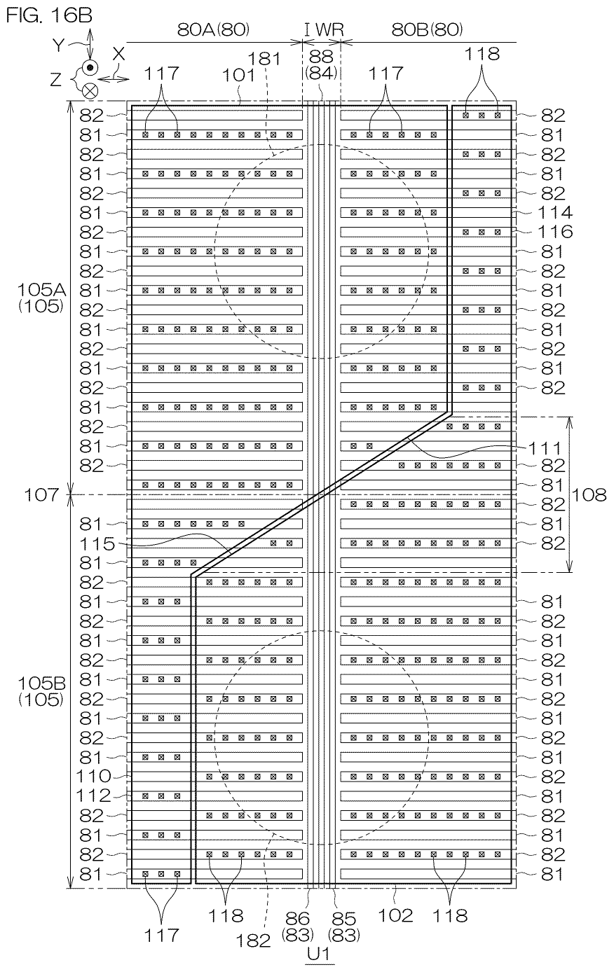

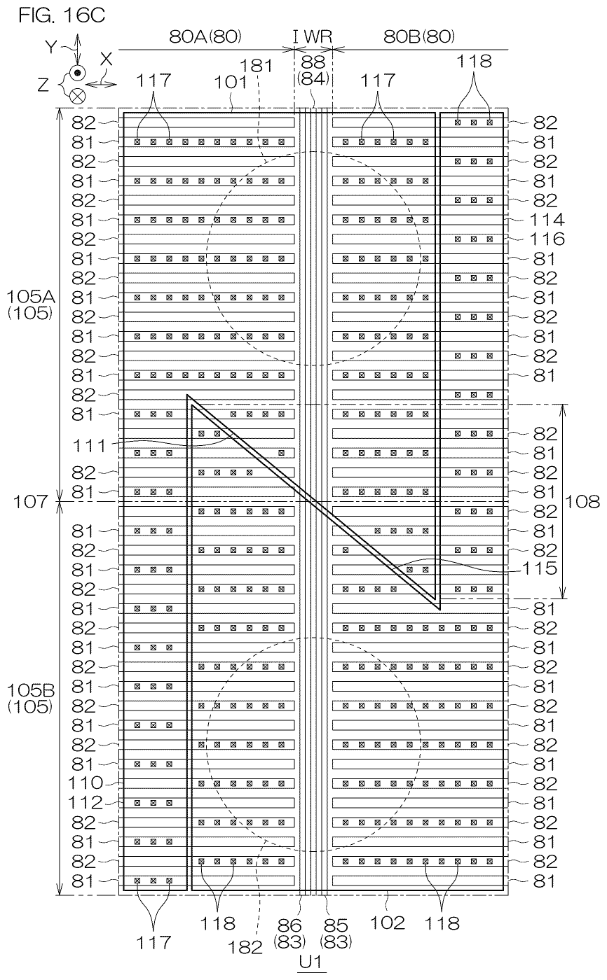

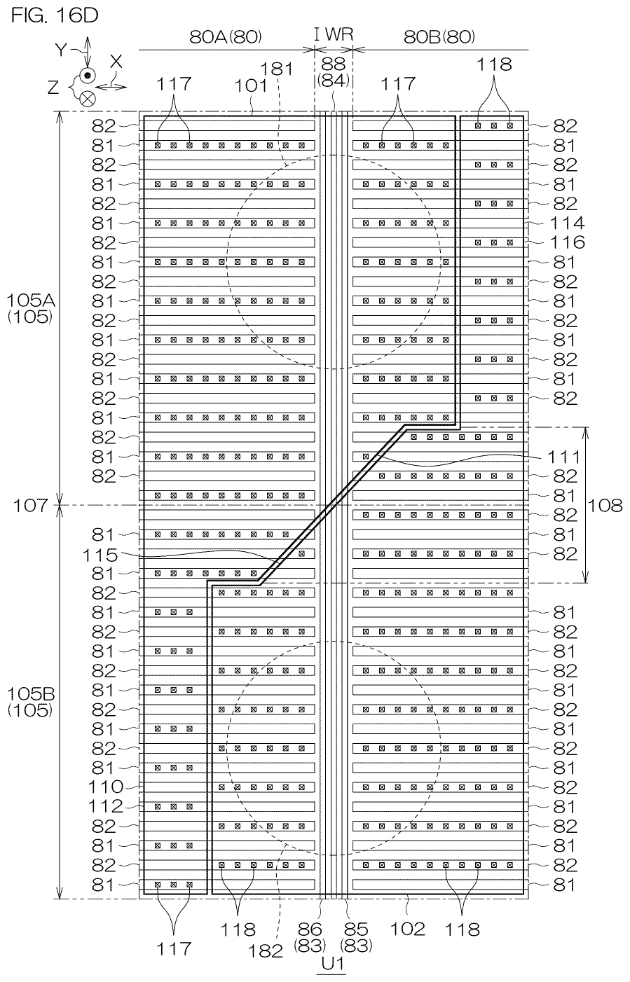

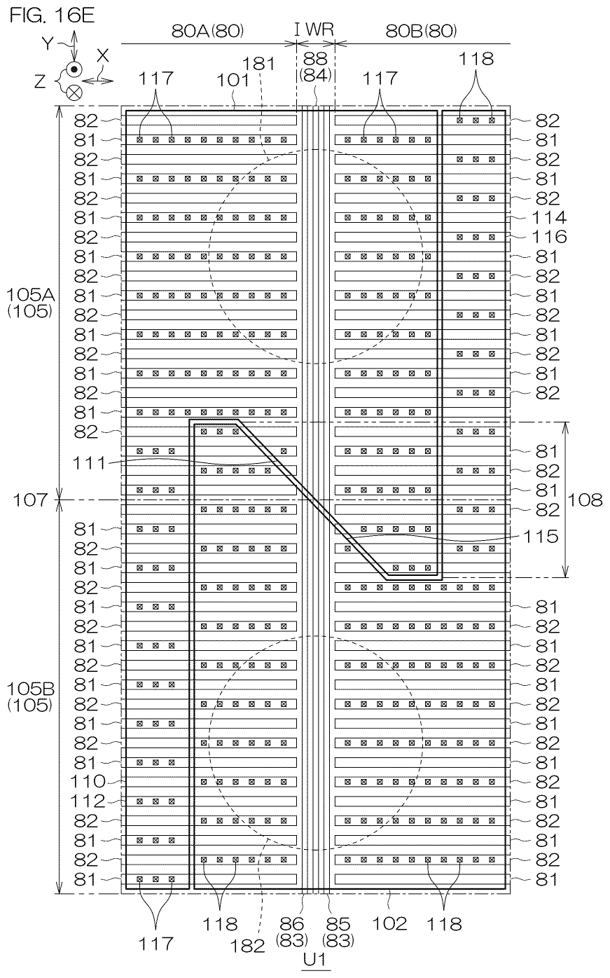

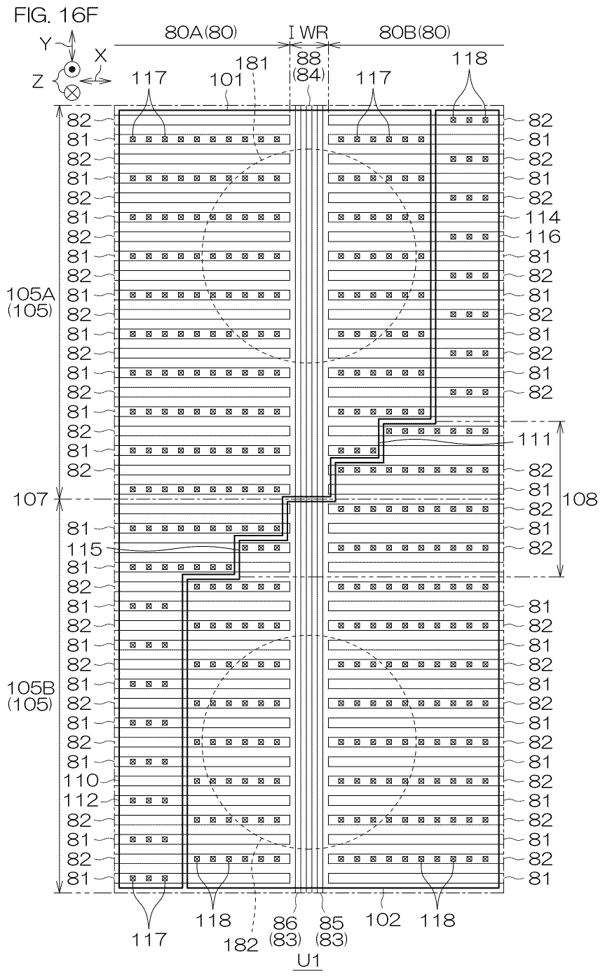

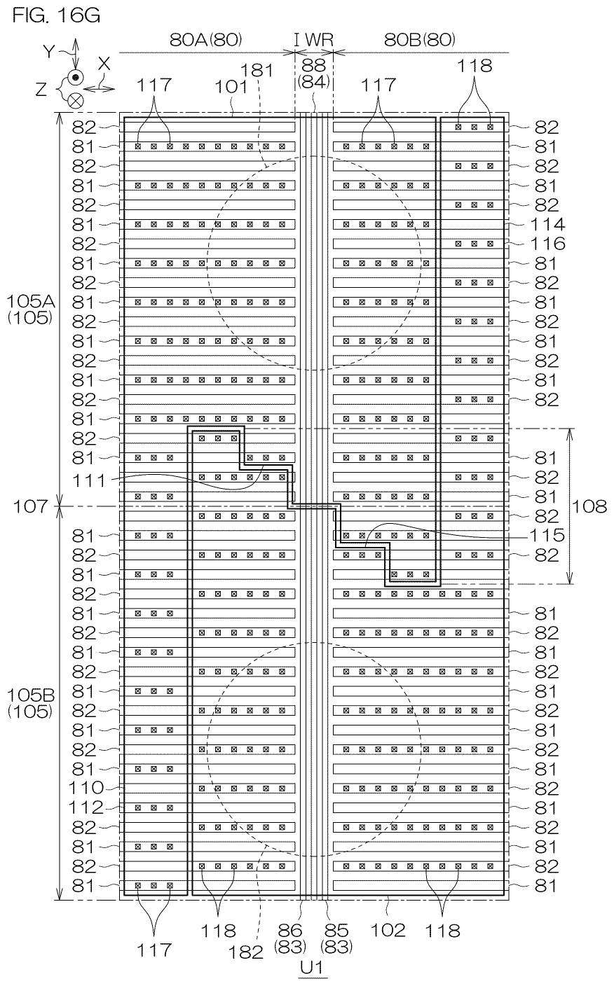

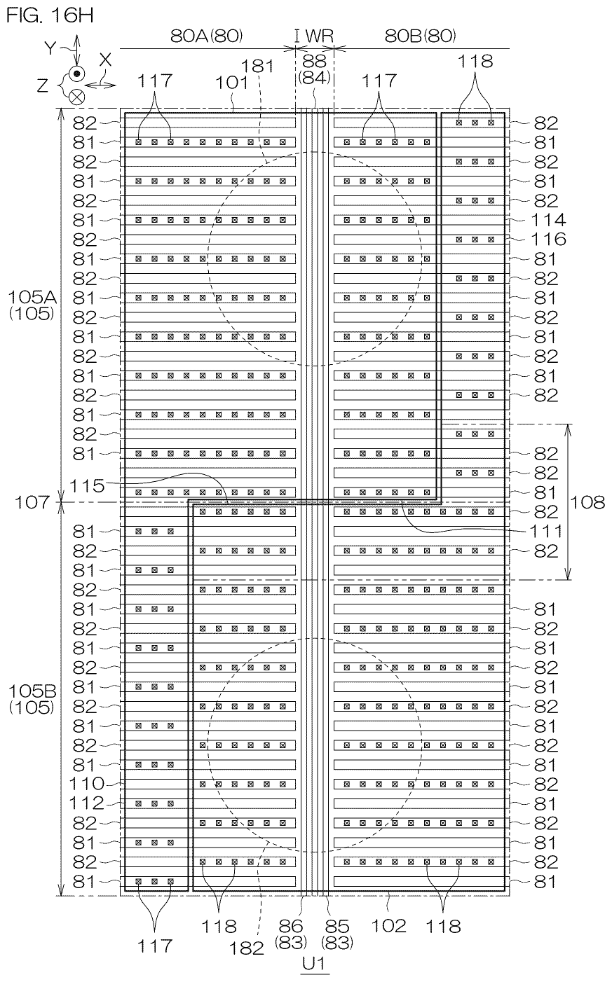

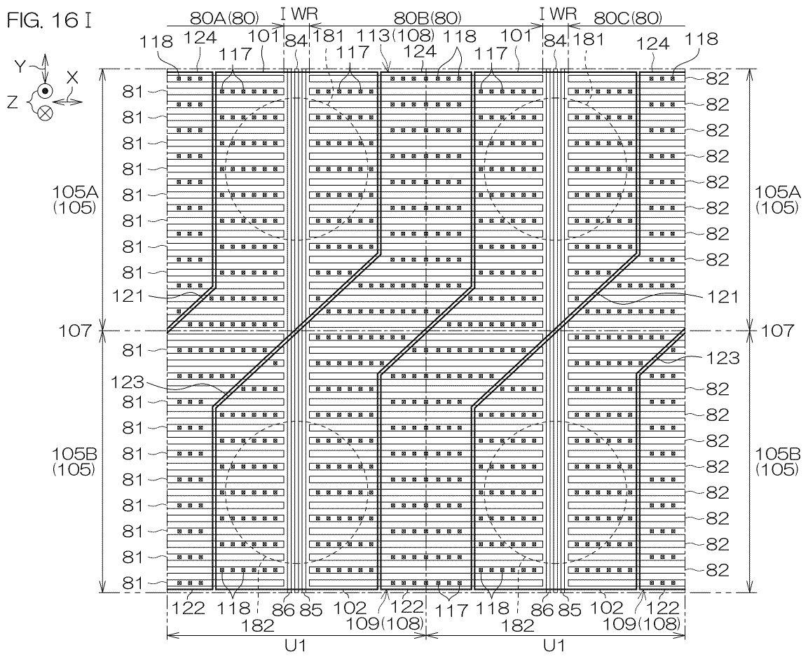

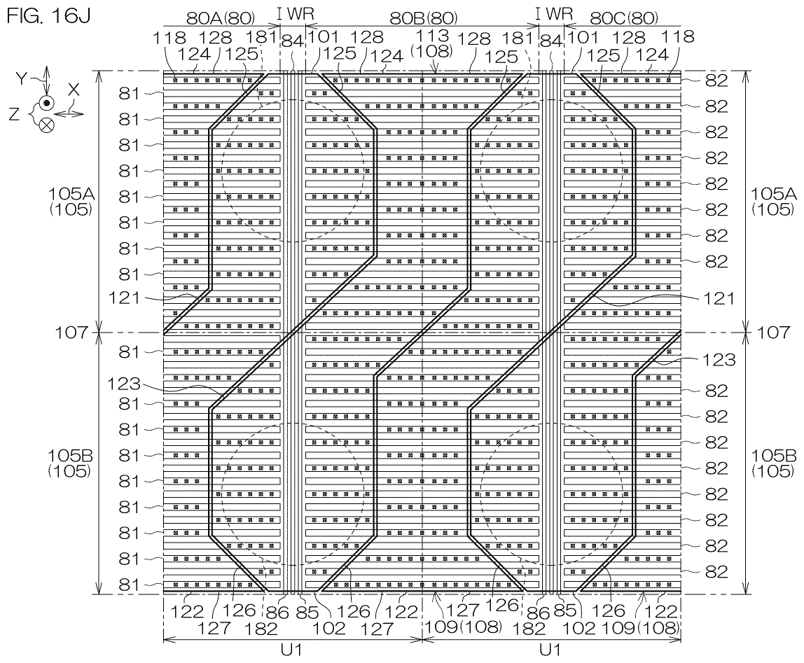

Hereinafter, a configuration of the first wiring unit U1 will be described, and then configurations of the second to fourth wiring units U2 to U4 will be described in this order. FIGS. 16A to 16J are enlarged plan views showing the first wiring units U1 according to first to tenth layout examples.

FIGS. 16A to 16J illustrate the first wiring units U1 arranged on the first side surface 5A side of the chip 2. Hereinafter, the first wiring unit U1 shown in FIG. 16A will be described as a basic form example, and the first wiring units U1 shown in FIGS. 16B to 16J will be described as modification examples of the basic form example.

Also, hereinafter, unless otherwise specified, the configuration in one of the first wiring units U1 will be described. Also, hereinafter, the first wiring group 80A and the second wiring group 80B are applied as the two wiring groups 80 on the one side and the other side in the first direction X, and a layout of the first wiring unit U1 with respect to these wiring groups 80 is exemplified.

As a matter of course, the following description is also applied to layouts of the other first wiring units U1 with respect to the two wiring groups 80 adjacent on the one side and the other side in the first direction X among the second to sixth wiring groups 80B to 80F. A specific configuration in this case is obtained by replacing the first wiring group 80A and the second wiring group 80B with two wiring groups 80 adjacent on the one side and the other side in the first direction X among the second to fifth wiring groups 80B to 80F in the following description.

With reference to FIG. 16A (the first layout example), the first wiring unit U1 includes the arrangement region 105 for the first pad wiring 101 and the arrangement region 105 for the second pad wiring 102. Hereinafter, the arrangement region 105 for the first pad wiring 101 is referred to as a “first arrangement region 105A,” and the arrangement region 105 for the second pad wiring 102 is referred to as a “second arrangement region 105B.”

The first arrangement region 105A is set on the one side in the second direction Y in plan view. The first arrangement region 105A is set in a quadrangular shape (preferably, a square shape) in plan view. The first arrangement region 105A includes the first wiring group 80A and the second wiring group 80B adjacent in the first direction X across the inter-wiring region IWR.

In other words, the first arrangement region 105A overlaps the first active region 6A and the second active region 6B adjacent in the first direction X across the boundary region 7a. The first arrangement region 105A includes at least one of the first lower wirings 81 belonging to the first wiring group 80A and at least one of the first lower wirings 81 belonging to the second wiring group 80B.

Specifically, the first arrangement region 105A includes at least one (in this embodiment, a plurality) of the first lower wirings 81 and at least one (in this embodiment, a plurality) of the second lower wirings 82 belonging to the first wiring group 80A, and at least one (in this embodiment, a plurality) of the first lower wirings 81 and at least one (in this embodiment, a plurality) of the second lower wirings 82 belonging to the second wiring group 80B.

In the first arrangement region 105A, the number of the first lower wirings 81 of the first wiring group 80A, the number of the second lower wirings 82 of the first wiring group 80A, the number of the first lower wirings 81 of the second wiring group 80B, and the number of the second lower wirings 82 of the second wiring group 80B are all arbitrary.

For example, in the first wiring group 80A (the second wiring group 80B) of the first arrangement region 105A, the number of the first lower wirings 81 (the second lower wirings 82) may be not less than 1 and not more than 1000. For example, in the first wiring group 80A (the second wiring group 80B) of the first arrangement region 105A, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first wiring group 80A of the first arrangement region 105A, it is preferable that the number of the second lower wirings 82 is substantially equal to the number of the first lower wirings 81. In the second wiring group 80B of the first arrangement region 105A, it is preferable that the number of the second lower wirings 82 is substantially equal to the number of the first lower wirings 81. In the first arrangement region 105A, it is preferable that the number of the first lower wirings 81 of the second wiring group 80B is substantially equal to the number of the first lower wirings 81 of the first wiring group 80A. Also, it is preferable that the number of the second lower wirings 82 of the second wiring group 80B is substantially equal to the number of the second lower wirings 82 of the first wiring group 80A.

In this embodiment, in both the first wiring group 80A and the second wiring group 80B, the plurality of second lower wirings 82 and the plurality of first lower wirings 81 are alternately arrayed. Also, the first lower wirings 81 and the second lower wirings 82 of the second wiring group 80B respectively oppose the first lower wirings 81 and the second lower wirings 82 of the first wiring group 80A in the first direction X.

Therefore, in the first wiring group 80A in the first arrangement region 105A, a difference value between the number of the first lower wirings 81 and the number of the second lower wirings 82 is 0 to 1. Also, in the second wiring group 80B in the first arrangement region 105A, a difference value between the number of the first lower wirings 81 and the number of the second lower wirings 82 is 0 to 1.

Also, in the first arrangement region 105A, a difference value between the number of the first lower wirings 81 of the first wiring group 80A and the number of the first lower wirings 81 of the second wiring group 80B is 0 to 1. Therefore, a difference value between the number of the second lower wirings 82 of the first wiring group 80A and the number of the second lower wirings 82 of the second wiring group 80B is 0 to 1.

The second arrangement region 105B is set on the other side in the second direction Y with respect to the first arrangement region 105A in plan view and is adjacent to the first arrangement region 105A. The second arrangement region 105B defines, together with the first arrangement region 105A, a boundary portion 107. The second arrangement region 105B is set in a quadrangular shape (preferably, a square shape) in plan view and defines the boundary portion 107 extending in the first direction X. A plane area of the second arrangement region 105B is substantially equal to a plane area of the first arrangement region 105A.

The second arrangement region 105B includes the first wiring group 80A and the second wiring group 80B adjacent in the first direction X across the inter-wiring region IWR. In other words, the second arrangement region 105B overlaps the first active region 6A and the second active region 6B adjacent in the first direction X across the boundary region 7a. The second arrangement region 105B includes at least one of the second lower wirings 82 belonging to the first wiring group 80A and at least one of the second lower wirings 82 belonging to the second wiring group 80B.

Specifically, the second arrangement region 105B includes at least one (in this embodiment, a plurality) of the first lower wirings 81 and at least one (in this embodiment, a plurality) of the second lower wirings 82 belonging to the first wiring group 80A, and at least one (in this embodiment, a plurality) of the first lower wirings 81 and at least one (in this embodiment, a plurality) of the second lower wirings 82 belonging to the second wiring group 80B.

In the second arrangement region 105B, the number of the first lower wirings 81 of the first wiring group 80A, the number of the second lower wirings 82 of the first wiring group 80A, the number of the first lower wirings 81 of the second wiring group 80B, and the number of the second lower wirings 82 of the second wiring group 80B are all arbitrary.

For example, in the first wiring group 80A (the second wiring group 80B) of the second arrangement region 105B, the number of the first lower wirings 81 (the second lower wirings 82) may be not less than 1 and not more than 1000. For example, in the first wiring group 80A (the second wiring group 80B) of the second arrangement region 105B, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first wiring group 80A of the second arrangement region 105B, it is preferable that the number of the second lower wirings 82 is substantially equal to the number of the first lower wirings 81. In the second wiring group 80B of the second arrangement region 105B, it is preferable that the number of the second lower wirings 82 is substantially equal to the number of the first lower wirings 81. In the second arrangement region 105B, it is preferable that the number of the first lower wirings 81 of the second wiring group 80B is substantially equal to the number of the first lower wirings 81 of the first wiring group 80A. Also, it is preferable that the number of the second lower wirings 82 of the second wiring group 80B is substantially equal to the number of the second lower wirings 82 of the first wiring group 80A.

In this embodiment, in both the first wiring group 80A and the second wiring group 80B, the plurality of second lower wirings 82 and the plurality of first lower wirings 81 are alternately arrayed. Also, the first lower wirings 81 and the second lower wirings 82 of the second wiring group 80B respectively oppose the first lower wirings 81 and the second lower wirings 82 of the first wiring group 80A in the first direction X.

Therefore, in the first wiring group 80A in the second arrangement region 105B, a difference value between the number of the first lower wirings 81 and the number of the second lower wirings 82 is 0 to 1. Also, in the second wiring group 80B in the second arrangement region 105B, a difference value between the number of the first lower wirings 81 and the number of the second lower wirings 82 is 0 to 1.

Also, in the second arrangement region 105B, a difference value between the number of the first lower wirings 81 of the first wiring group 80A and the number of the first lower wirings 81 of the second wiring group 80B is 0 to 1. Therefore, a difference value between the number of the second lower wirings 82 of the first wiring group 80A and the number of the second lower wirings 82 of the second wiring group 80B is 0 to 1.

With regard to the first wiring group 80A in the first arrangement region 105A and the first wiring group 80A in the second arrangement region 105B, it is preferable that the number of the first lower wirings 81 is equal to each other, and the number of the second lower wirings 82 is equal to each other. That is, it is preferable that wiring resistance related to the first wiring group 80A in the second arrangement region 105B is substantially equal to wiring resistance related to the first wiring group 80A in the first arrangement region 105A.

Also, with regard to the second wiring group 80B in the first arrangement region 105A and the second wiring group 80B in the second arrangement region 105B, it is preferable that the number of the first lower wirings 81 is equal to each other, and the number of the second lower wirings 82 is equal to each other. That is, it is preferable that wiring resistance related to the second wiring group 80B in the second arrangement region 105B is substantially equal to wiring resistance related to the second wiring group 80B in the first arrangement region 105A.

The first wiring unit U1 includes the first pad wiring 101 arranged in the first arrangement region 105A. The first pad wiring 101 has a plane area less than the plane area of the first arrangement region 105A. The first pad wiring 101 is arranged at intervals inward from a peripheral edge of the first arrangement region 105A in plan view and is formed in a polygonal shape having four sides parallel to the peripheral edges of the chip 2 (the peripheral edges of the first arrangement region 105A). The first pad wiring 101 is provided at a biased position on the one side in the first direction X with respect to a central portion of the boundary portion 107 and is provided at a biased position on the one side in the second direction Y with respect to the boundary portion 107.

The first pad wiring 101 is arranged on the first wiring group 80A and the second wiring group 80B adjacent in the first direction X across the inter-wiring region IWR. That is, the first pad wiring 101 is arranged on the inter-wiring region IWR and is led out onto the first wiring group 80A and the second wiring group 80B adjacent in the first direction X. In other words, the first pad wiring 101 is arranged on the first active region 6A and the second active region 6B adjacent in the first direction X across the boundary region 7a.

The first pad wiring 101 opposes the first wiring group 80A, the second wiring group 80B, and the inter-wiring region IWR across the second interlayer film 72. The first pad wiring 101 is electrically connected to at least one of the first lower wirings 81 of the first wiring group 80A and at least one of the first lower wirings 81 of the second wiring group 80B.

Specifically, the first pad wiring 101 has a first end portion on the one side in the first direction X and a second end portion on the other side in the first direction X. The first end portion of the first pad wiring 101 is arranged on the first wiring group 80A. The first end portion of the first pad wiring 101 is arranged on at least one (in this embodiment, a plurality) of the first lower wirings 81 of the first wiring group 80A and is electrically connected to at least one (in this embodiment, a plurality) of the first lower wirings 81 of the first wiring group 80A.

In this embodiment, the first end portion of the first pad wiring 101 overlaps at least one (in this embodiment, a plurality) of the first lower wirings 81 and at least one (in this embodiment, a plurality) of the second lower wirings 82 of the first wiring group 80A. The first end portion of the first pad wiring 101 is electrically disconnected from all of the second lower wirings 82 of the first wiring group 80A.

The second end portion of the first pad wiring 101 is arranged on the second wiring group 80B. The second end portion of the first pad wiring 101 is arranged on at least one (in this embodiment, a plurality) of the first lower wirings 81 of the second wiring group 80B and is electrically connected to at least one (in this embodiment, a plurality) of the first lower wirings 81 of the second wiring group 80B.

In this embodiment, the second end portion of the first pad wiring 101 overlaps at least one (in this embodiment, a plurality) of the first lower wirings 81 and at least one (in this embodiment, a plurality) of the second lower wirings 82 of the second wiring group 80B. The second end portion of the first pad wiring 101 is electrically disconnected from all of the second lower wirings 82 of the second wiring group 80B.

The first pad wiring 101 is electrically connected to both the first lower wirings 81 of the first wiring group 80A and the first lower wirings 81 of the second wiring group 80B by straddling the inter-wiring region IWR. Therefore, a current path connecting the first lower wiring 81 of the first wiring group 80A to the first pad wiring 101 is shortened, and a current path connecting the first lower wiring 81 of the second wiring group 80B to the first pad wiring 101 is shortened. Consequently, wiring resistance between the first pad wiring 101 and the first lower wirings 81 of the first wiring group 80A is reduced, and wiring resistance between the first pad wiring 101 and the first lower wirings 81 of the second wiring group 80B is reduced.

Directly below the first pad wiring 101, the number of the first lower wirings 81 of the first wiring group 80A, the number of the second lower wirings 82 of the first wiring group 80A, the number of the first lower wirings 81 of the second wiring group 80B, and the number of the second lower wirings 82 of the second wiring group 80B are all arbitrary.

For example, in the first wiring group 80A (the second wiring group 80B) directly below the first pad wiring 101, the number of the first lower wirings 81 (the second lower wirings 82) may be not less than 1 and not more than 1000. For example, in the first wiring group 80A (the second wiring group 80B) directly below the first pad wiring 101, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first wiring group 80A directly below the first pad wiring 101, it is preferable that the number of the second lower wirings 82 is substantially equal to the number of the first lower wirings 81. In the second wiring group 80B directly below the first pad wiring 101, it is preferable that the number of the second lower wirings 82 is substantially equal to the number of the first lower wirings 81. Directly below the first pad wiring 101, it is preferable that the number of the first lower wirings 81 of the second wiring group 80B is substantially equal to the number of the first lower wirings 81 of the first wiring group 80A. Also, it is preferable that the number of the second lower wirings 82 of the second wiring group 80B is substantially equal to the number of the second lower wirings 82 of the first wiring group 80A.

In this embodiment, in both the first wiring group 80A and the second wiring group 80B, the plurality of second lower wirings 82 and the plurality of first lower wirings 81 are alternately arrayed. Also, the first lower wirings 81 and the second lower wirings 82 of the second wiring group 80B respectively oppose the first lower wirings 81 and the second lower wirings 82 of the first wiring group 80A in the first direction X.

Therefore, in the first wiring group 80A directly below the first pad wiring 101, a difference value between the number of the first lower wirings 81 and the number of the second lower wirings 82 is 0 to 1. Also, in the second wiring group 80B directly below the first pad wiring 101, a difference value between the number of the first lower wirings 81 and the number of the second lower wirings 82 is 0 to 1.

Also, in the first pad wiring 101, a difference value between the number of the first lower wirings 81 of the first wiring group 80A and the number of the first lower wirings 81 of the second wiring group 80B is 0 to 1. Therefore, a difference value between the number of the second lower wirings 82 of the first wiring group 80A and the number of the second lower wirings 82 of the second wiring group 80B is 0 to 1.

That is, in the first wiring group 80A (the second wiring group 80B) directly below the first pad wiring 101, variation in the wiring resistance between the first lower wirings 81 and the second lower wirings 82 is prevented. Also, directly below the first pad wiring 101, variation in wiring resistance between the first wiring group 80A and the second wiring group 80B is prevented. With regard to the first wiring group 80A directly below the first end portion of the first pad wiring 101 and the second wiring group 80B directly below the second end portion of the first pad wiring 101, the number of the first lower wirings 81 is preferably equal to each other, and the number of the second lower wirings 82 is preferably equal to each other.

The first pad wiring 101 overlaps the third lower wiring 83 in a portion covering the inter-wiring region IWR. In this embodiment, the first pad wiring 101 overlaps both the first gate wiring 85 and the second gate wiring 86. The first pad wiring 101 opposes the third lower wiring 83 (the first gate wiring 85 and the second gate wiring 86) across the second interlayer film 72 and is electrically disconnected from the third lower wiring 83.

The first pad wiring 101 overlaps the fourth lower wiring 84 in the portion covering the inter-wiring region IWR. In this embodiment, the first pad wiring 101 overlaps the first base wiring 88. The first pad wiring 101 opposes the fourth lower wiring 84 (the first base wiring 88) across the second interlayer film 72 and is electrically disconnected from the fourth lower wiring 84.

The first wiring unit U1 includes the second pad wiring 102 arranged in the second arrangement region 105B at intervals on the other side in the second direction Y from the first pad wiring 101 (the first arrangement region 105A). The second pad wiring 102 has a plane area less than the plane area of the second arrangement region 105B. The second pad wiring 102 is arranged at intervals inward from a peripheral edge of the second arrangement region 105B in plan view and is formed in a polygonal shape having four sides parallel to the peripheral edges of the chip 2 (the peripheral edges of the second arrangement region 105B).

The second pad wiring 102 is provided at a biased position on the other side in the first direction X with respect to a central portion of the first pad wiring 101 (the central portion of the boundary portion 107) and is provided at a biased position on the other side in the second direction Y with respect to the boundary portion 107. It is preferable that a distance between the second pad wiring 102 and the boundary portion 107 is substantially equal to a distance between the first pad wiring 101 and the boundary portion 107. That is, it is preferable that the boundary portion 107 is positioned at a substantially intermediate portion between the first pad wiring 101 and the second pad wiring 102.

The second pad wiring 102 preferably has a planar layout substantially congruent with a planar layout of the first pad wiring 101. That is, it is preferable that a planar shape of the second pad wiring 102 is substantially identical to a planar shape of the first pad wiring 101, and the plane area of the second pad wiring 102 is substantially equal to the plane area of the first pad wiring 101. The second pad wiring 102 is preferably arranged point-symmetrically with respect to the first pad wiring 101 about the central portion of the boundary portion 107.

The second pad wiring 102 is arranged on the first wiring group 80A and the second wiring group 80B adjacent in the first direction X across the inter-wiring region IWR. That is, the second pad wiring 102 is arranged on the inter-wiring region IWR and is led out onto the first wiring group 80A and the second wiring group 80B adjacent in the first direction X. In other words, the second pad wiring 102 is arranged on the first active region 6A and the second active region 6B adjacent in the first direction X across the boundary region 7a.

The second pad wiring 102 opposes the first wiring group 80A, the second wiring group 80B, and the inter-wiring region IWR across the second interlayer film 72. The second pad wiring 102 is electrically connected to at least one of the second lower wirings 82 of the first wiring group 80A and at least one of the second lower wirings 82 of the second wiring group 80B.

Specifically, the second pad wiring 102 has a first end portion on the one side in the first direction X and a second end portion on the other side in the first direction X. The first end portion of the second pad wiring 102 is arranged on the first wiring group 80A. The first end portion of the second pad wiring 102 is arranged on at least one (in this embodiment, a plurality) of the second lower wirings 82 of the first wiring group 80A and is electrically connected to at least one (in this embodiment, a plurality) of the second lower wirings 82 of the first wiring group 80A.

In this embodiment, the first end portion of the second pad wiring 102 overlaps at least one (in this embodiment, a plurality) of the first lower wirings 81 and at least one (in this embodiment, a plurality) of the second lower wirings 82 of the first wiring group 80A. The first end portion of the second pad wiring 102 is electrically disconnected from all of the first lower wirings 81 of the first wiring group 80A.

The second end portion of the second pad wiring 102 is arranged on the second wiring group 80B. The second end portion of the second pad wiring 102 is arranged on at least one (in this embodiment, a plurality) of the second lower wirings 82 of the second wiring group 80B and is electrically connected to at least one (in this embodiment, a plurality) of the second lower wiring 82 of the second wiring group 80B.

In this embodiment, the second end portion of the second pad wiring 102 overlaps at least one (in this embodiment, a plurality) of the first lower wirings 81 and at least one (in this embodiment, a plurality) of the second lower wirings 82 of the second wiring group 80B. The second end portion of the second pad wiring 102 is electrically disconnected from all of the first lower wirings 81 of the second wiring group 80B.

The second pad wiring 102 is electrically connected to both the second lower wirings 82 of the first wiring group 80A and the second lower wirings 82 of the second wiring group 80B by straddling the inter-wiring region IWR. Therefore, a current path connecting the second lower wiring 82 of the first wiring group 80A to the second pad wiring 102 is shortened, and a current path connecting the second lower wiring 82 of the second wiring group 80B to the second pad wiring 102 is shortened. Consequently, wiring resistance between the second pad wiring 102 and the second lower wirings 82 of the first wiring group 80A is reduced, and wiring resistance between the second pad wiring 102 and the second lower wirings 82 of the second wiring group 80B is reduced.

Directly below the second pad wiring 102, the number of the first lower wirings 81 of the first wiring group 80A, the number of the second lower wirings 82 of the first wiring group 80A, the number of the first lower wirings 81 of the second wiring group 80B, and the number of the second lower wirings 82 of the second wiring group 80B are all arbitrary.

For example, in the first wiring group 80A (the second wiring group 80B) directly below the second pad wiring 102, the number of the first lower wirings 81 (the second lower wirings 82) may be not less than 1 and not more than 1000. For example, in the first wiring group 80A (the second wiring group 80B) directly below the second pad wiring 102, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first wiring group 80A directly below the second pad wiring 102, it is preferable that the number of the second lower wirings 82 is substantially equal to the number of the first lower wirings 81. In the second wiring group 80B directly below the second pad wiring 102, it is preferable that the number of the second lower wirings 82 is substantially equal to the number of the first lower wirings 81. Directly below the second pad wiring 102, it is preferable that the number of the first lower wirings 81 of the second wiring group 80B is substantially equal to the number of the first lower wirings 81 of the first wiring group 80A. Also, it is preferable that the number of the second lower wirings 82 of the second wiring group 80B is substantially equal to the number of the second lower wirings 82 of the first wiring group 80A.

In this embodiment, in both the first wiring group 80A and the second wiring group 80B, the plurality of second lower wirings 82 and the plurality of first lower wirings 81 are alternately arrayed. Also, the first lower wirings 81 and the second lower wirings 82 of the second wiring group 80B respectively oppose the first lower wirings 81 and the second lower wirings 82 of the first wiring group 80A in the first direction X.

Therefore, in the first wiring group 80A directly below the second pad wiring 102, a difference value between the number of the first lower wirings 81 and the number of the second lower wirings 82 is 0 to 1. Also, in the second wiring group 80B directly below the second pad wiring 102, a difference value between the number of the first lower wirings 81 and the number of the second lower wirings 82 is 0 to 1.

Also, directly below the second pad wiring 102, a difference value between the number of the first lower wirings 81 of the first wiring group 80A and the number of the first lower wirings 81 of the second wiring group 80B is 0 to 1. Therefore, a difference value between the number of the second lower wirings 82 of the first wiring group 80A and the number of the second lower wirings 82 of the second wiring group 80B is 0 to 1.

That is, in the first wiring group 80A (the second wiring group 80B) directly below the second pad wiring 102, variation in the wiring resistance between the first lower wirings 81 and the second lower wirings 82 is prevented. Also, directly below the second pad wiring 102, variation in the wiring resistance between the first wiring group 80A and the second wiring group 80B is prevented. With regard to the first wiring group 80A directly below the first end portion of the second pad wiring 102 and the second wiring group 80B directly below the second end portion of the second pad wiring 102, the number of the first lower wirings 81 is preferably equal to each other, and the number of the second lower wirings 82 is preferably equal to each other.

With regard to the first wiring group 80A directly below the first pad wiring 101 and the first wiring group 80A directly below the second pad wiring 102, the number of the first lower wirings 81 is preferably equal to each other, and the number of the second lower wirings 82 is preferably equal to each other. That is, it is preferable that wiring resistance related to the first wiring group 80A directly below the second pad wiring 102 is substantially equal to wiring resistance related to the first wiring group 80A directly below the first pad wiring 101.

With regard to the second wiring group 80B directly below the first pad wiring 101 and the second wiring group 80B directly below the second pad wiring 102, the number of the first lower wirings 81 is preferably equal to each other, and the number of the second lower wirings 82 is preferably equal to each other. That is, it is preferable that wiring resistance related to the second wiring group 80B directly below the second pad wiring 102 is substantially equal to wiring resistance related to the second wiring group 80B directly below the first pad wiring 101.

The second pad wiring 102 overlaps the third lower wiring 83 in a portion covering the inter-wiring region IWR. In this embodiment, the second pad wiring 102 overlaps both the first gate wiring 85 and the second gate wiring 86. The second pad wiring 102 opposes the third lower wiring 83 (the first gate wiring 85 and the second gate wiring 86) across the second interlayer film 72 and is electrically disconnected from the third lower wiring 83.

The second pad wiring 102 overlaps the fourth lower wiring 84 in the portion covering the inter-wiring region IWR. In this embodiment, the second pad wiring 102 overlaps the first base wiring 88. The second pad wiring 102 opposes the fourth lower wiring 84 (the first base wiring 88) across the second interlayer film 72 and is electrically disconnected from the fourth lower wiring 84.

The first wiring unit U1 includes a first interconnect structure 108 formed in a region between the first pad wiring 101 and the second pad wiring 102. The first interconnect structure 108 forms a current path of the drain source current Ids between the first pad wiring 101 and the second pad wiring 102.

The first interconnect structure 108 includes at least one (in this embodiment, a plurality) of first lead-out wirings 109 led out in the second direction Y from the first pad wiring 101 toward the second pad wiring 102. The plurality of first lead-out wirings 109 are electrically connected to one or both of at least one of the first lower wirings 81 of the first wiring group 80A and at least one of the first lower wirings 81 of the second wiring group 80B in the region between the first pad wiring 101 and the second pad wiring 102.

The plurality of first lead-out wirings 109 include at least one (in this embodiment, one) first long wiring 110 that is relatively long and at least one (in this embodiment, a plurality) of first short wirings 111 that are shorter than the first long wiring 110. The first long wiring 110 may be referred to as a “first long lead-out wiring,” a “first main lead-out wiring,” etc. The first short wiring 111 may be referred to as a “first short lead-out wiring,” a “first sub-lead-out wiring,” etc.

The number of the first short wirings 111 is arbitrary and is appropriately adjusted depending on a size of the first pad wiring 101, etc. The number of the first short wirings 111 may be not less than 1 and not more than 50. The number of the first short wirings 111 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50. In this embodiment, the two first short wirings 111 are provided.

The first long wiring 110 has a width less than a width of the first pad wiring 101 (the second pad wiring 102) in the first direction X and is led out as a band in the second direction Y from the first end portion of the first pad wiring 101 onto the first wiring group 80A (the first active region 6A). The width of the first long wiring 110 is larger than the width of the first lower wiring 81 (the second lower wiring 82). In this embodiment, the first long wiring 110 intersects (is orthogonal to) at least one (in this embodiment, a plurality) of the first lower wirings 81 and at least one (in this embodiment, a plurality) of the second lower wirings 82 of the first wiring group 80A in the first arrangement region 105A.

The first long wiring 110 crosses the boundary portion 107 in the second direction Y and is led out from the first arrangement region 105A to the second arrangement region 105B. In this embodiment, the first long wiring 110 intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The first long wiring 110 is electrically connected to at least one (in this embodiment, a plurality) of the first lower wirings 81 of the first wiring group 80A in the first arrangement region 105A. Also, the first long wiring 110 is electrically connected to at least one (in this embodiment, a plurality) of the first lower wirings 81 of the first wiring group 80A in the second arrangement region 105B.

The first long wiring 110 has a first opposing portion 112 led out in the second direction Y to a region opposing the second pad wiring 102 in the first direction X. The first opposing portion 112 opposes the entire first end portion of the second pad wiring 102 in the first direction X. With regard to the first wiring group 80A, the first opposing portion 112 (the first long wiring 110) intersects (is orthogonal to) one or a plurality of (preferably, all of) the first lower wirings 81 and one or a plurality of (preferably, all of) the second lower wirings 82 passing directly below the second pad wiring 102 in the first direction X.

The first opposing portion 112 is electrically connected to, of one or a plurality of (preferably, all of) the first lower wirings 81 covered with the second pad wiring 102, portions of the first lower wirings 81 exposed from the second pad wiring 102. On the other hand, the first opposing portion 112 is electrically disconnected from one or a plurality of (preferably, all of) the second lower wirings 82 passing directly below the second pad wiring 102.

The first long wiring 110 forms a current path of the drain source current Ids together with the second pad wiring 102 opposing (closely opposing) the first long wiring 110 in the first direction X. Specifically, the current path of the drain source current Ids is formed between the second pad wiring 102 and the first long wiring 110 via the first lower wirings 81 and the second lower wirings 82 passing directly below both the second pad wiring 102 and the first long wiring 110 in the first direction X. Such a layout is effective in reducing the wiring resistance between the first pad wiring 101 and the second pad wiring 102.

Each of the plurality of first short wirings 111 has a width less than the width of the first pad wiring 101 (the second pad wiring 102) in the first direction X and is provided in a region on the second end portion side with respect to the first long wiring 110. The width of the first short wiring 111 may be substantially equal to the width of the first long wiring 110. The width of the first short wiring 111 may be larger than the width of the first long wiring 110. The width of the first short wiring 111 may be less than the width of the first long wiring 110. The width of the first short wiring 111 is larger than the width of the first lower wiring 81 (the second lower wiring 82).

The plurality of first short wirings 111 are arrayed at intervals in the first direction X and are led out as bands (in this embodiment, in a rectangular shape) in the second direction Y from the first pad wiring 101 toward the second pad wiring 102. The plurality of first short wirings 111 may be led out in a trapezoidal shape (preferably, an isosceles trapezoidal shape) or a triangular shape (preferably, an isosceles triangular shape).

The plurality of first short wirings 111 are arrayed in a comb teeth shape extending in the second direction Y and oppose each other in the first direction X. The plurality of first short wirings 111 oppose the first long wiring 110 in the first direction X. The plurality of first short wirings 111 are formed at intervals from the second pad wiring 102 toward the first pad wiring 101 and oppose the second pad wiring 102 in the second direction Y.

The plurality of first short wirings 111 are electrically connected to at least one (in this embodiment, a plurality) of the first lower wirings 81 in the region between the first pad wiring 101 and the second pad wiring 102. Specifically, the plurality of first short wirings 111 include one or a plurality (in this embodiment, one) of the first short wiring 111 on the one side and one or a plurality (in this embodiment, one) of the first short wiring 111 on the other side. The number of the first short wirings 111 on the other side is preferably equal to the number of the first short wirings 111 on the one side.

The first short wiring 111 on the one side is led out from the first pad wiring 101 onto the first wiring group 80A (the first active region 6A) and opposes the second pad wiring 102 in the second direction Y in a region on the first wiring group 80A. The first short wiring 111 on the one side is electrically connected to at least one (in this embodiment, a plurality) of the first lower wirings 81 of the first wiring group 80A. In this embodiment, the first short wiring 111 on the one side intersects (is orthogonal to) at least one (in this embodiment, a plurality) of the first lower wirings 81 and at least one (in this embodiment, a plurality) of the second lower wirings 82 of the first wiring group 80A in the first arrangement region 105A.

The first short wiring 111 on the one side crosses the boundary portion 107 in the second direction Y and is led out from the first arrangement region 105A to the second arrangement region 105B. In this embodiment, the first short wiring 111 on the one side intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The first short wiring 111 on the one side is electrically connected to at least one (in this embodiment, a plurality) of the first lower wirings 81 of the first wiring group 80A in the first arrangement region 105A. Also, the first short wiring 111 on the one side is electrically connected to at least one (in this embodiment, a plurality) of the first lower wirings 81 of the first wiring group 80A in the second arrangement region 105B.

The first short wiring 111 on the one side intersects (is orthogonal to) at least one (in this embodiment, a plurality) of the first lower wirings 81 and at least one (in this embodiment, a plurality) of the second lower wirings 82 passing directly below the first long wiring 110 in the first direction X. That is, the first short wiring 111 on the one side is electrically connected to, of at least one (in this embodiment, a plurality) of the first lower wirings 81 covered with the first long wiring 110, portions of the first lower wirings 81 exposed from the first long wiring 110. In a case where the plurality of first short wirings 111 include a plurality of the first short wirings 111 on the one side, the plurality of first short wirings 111 on the one side are arrayed at intervals in the first direction X in a region on the first wiring group 80A. That is, the plurality of first short wirings 111 on the one side are arrayed in a comb teeth shape extending in the second direction Y in the region on the first wiring group 80A.

The first short wiring 111 on the other side is led out from the first pad wiring 101 onto the second wiring group 80B (the second active region 6B) and opposes the second pad wiring 102 in the second direction Y in a region on the second wiring group 80B. The first short wiring 111 on the other side is electrically connected to at least one (in this embodiment, a plurality) of the first lower wirings 81 of the second wiring group 80B. In this embodiment, the first short wiring 111 on the other side intersects (is orthogonal to) at least one (in this embodiment, a plurality) of the first lower wirings 81 and at least one (in this embodiment, a plurality) of the second lower wirings 82 of the second wiring group 80B in the first arrangement region 105A.

The first short wiring 111 on the other side crosses the boundary portion 107 in the second direction Y and is led out from the first arrangement region 105A to the second arrangement region 105B. In this embodiment, the first short wiring 111 on the other side intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The first short wiring 111 on the other side is electrically connected to at least one (in this embodiment, a plurality) of the first lower wirings 81 of the second wiring group 80B in the first arrangement region 105A. Also, the first short wiring 111 on the other side is electrically connected to at least one (in this embodiment, a plurality) of the first lower wirings 81 of the second wiring group 80B in the second arrangement region 105B.

In a case where the plurality of first short wirings 111 include a plurality of the first short wirings 111 on the other side, the plurality of first short wirings 111 on the other side are arrayed at intervals in the first direction X in a region on the second wiring group 80B. That is, the plurality of first short wirings 111 on the other side are arrayed in a comb teeth shape extending in the second direction Y in the region on the second wiring group 80B.

One or both of the first short wirings 111 on the one side and the other side may overlap the inter-wiring region IWR. In this case, one or both of the first short wirings 111 on the one side and the other side overlap one or both of the third lower wiring 83 and the fourth lower wiring 84 and are electrically disconnected from both of the third lower wiring 83 and the fourth lower wiring 84 by the second interlayer film 72.

As a matter of course, the plurality of first lead-out wirings 109 may include the intermediate first short wiring 111 overlapping the inter-wiring region IWR. In this case, the intermediate first short wiring 111 may be led out from a region on the inter-wiring region IWR onto both the first wiring group 80A and the second wiring group 80B adjacent in the first direction X.

The intermediate first short wiring 111 may be electrically connected to at least one (for example, a plurality) of the first lower wirings 81 of the first wiring group 80A and at least one (for example, a plurality) of the first lower wirings 81 of the second wiring group 80B.

The intermediate first short wiring 111 may intersect (be orthogonal to) at least one (for example, a plurality) of the first lower wirings 81 and at least one (for example, a plurality) of the second lower wirings 82 of the first wiring group 80A in the first arrangement region 105A. Also, the intermediate first short wiring 111 may intersect (be orthogonal to) at least one (for example, a plurality) of the first lower wirings 81 and at least one (for example, a plurality) of the second lower wirings 82 of the second wiring group 80B in the first arrangement region 105A.

The intermediate first short wiring 111 may cross the boundary portion 107 in the second direction Y and may be led out from the first arrangement region 105A to the second arrangement region 105B. The intermediate first short wiring 111 may intersect (be orthogonal to) at least one (for example, a plurality) of the first lower wirings 81 and at least one (for example, a plurality) of the second lower wirings 82 of the first wiring group 80A in both the first arrangement region 105A and the second arrangement region 105B.

Also, the intermediate first short wiring 111 may intersect (be orthogonal to) at least one (for example, a plurality) of the first lower wirings 81 and at least one (for example, a plurality) of the second lower wirings 82 of the second wiring group 80B in both the first arrangement region 105A and the second arrangement region 105B.

The intermediate first short wiring 111 may be electrically connected to at least one (for example, a plurality) of the first lower wirings 81 of the first wiring group 80A and at least one (for example, a plurality) of the first lower wirings 81 of the second wiring group 80B in the first arrangement region 105A. Also, the intermediate first short wiring 111 may be electrically connected to at least one (for example, a plurality) of the first lower wirings 81 of the first wiring group 80A and at least one (for example, a plurality) of the first lower wirings 81 of the second wiring group 80B in the second arrangement region 105B.

The intermediate first short wiring 111 may overlap the third lower wiring 83 (the first gate wiring 85 and/or the second gate wiring 86) in a portion covering the inter-wiring region IWR. In this case, the intermediate first short wiring 111 opposes the third lower wiring 83 (the first gate wiring 85 and/or the second gate wiring 86) across the second interlayer film 72 and is electrically disconnected from the third lower wiring 83.

The intermediate first short wiring 111 may overlap the fourth lower wiring 84 (the first base wiring 88) in the portion covering the inter-wiring region IWR. In this case, the intermediate first short wiring 111 opposes the fourth lower wiring 84 (the first base wiring 88) across the second interlayer film 72 and is electrically disconnected from the fourth lower wiring 84.

The first interconnect structure 108 includes at least one (in this embodiment, a plurality) of second lead-out wirings 113 led out in the second direction Y from the second pad wiring 102 toward the first pad wiring 101. The plurality of second lead-out wirings 113 are electrically connected to one or both of at least one of the second lower wirings 82 of the first wiring group 80A and at least one of the second lower wirings 82 of the second wiring group 80B in the region between the first pad wiring 101 and the second pad wiring 102.

The plurality of second lead-out wirings 113 include at least one (in this embodiment, one) second long wiring 114 that is relatively long and at least one (in this embodiment, a plurality) of second short wirings 115 that are shorter than the second long wiring 114. The second long wiring 114 may be referred to as a “second long lead-out wiring,” a “second main lead-out wiring,” etc. The second short wiring 115 may be referred to as a “second short lead-out wiring,” a “second sub-lead-out wiring,” etc.

The number of the second short wirings 115 is arbitrary and is appropriately adjusted depending on a size of the second pad wiring 102, etc. The number of the second short wirings 115 may be not less than 1 and not more than 50. The number of the second short wirings 115 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The number of the second short wirings 115 is preferably equal to the number of the first short wirings 111. According to this configuration, variation in wiring resistance between the first short wirings 111 and the second short wirings 115 is prevented. In this embodiment, the two second short wirings 115 are provided.

The second long wiring 114 has a width less than the width of the second pad wiring 102 (the first pad wiring 101) in the first direction X and is led out as a band in the second direction Y from the second end portion of the second pad wiring 102 onto the second wiring group 80B (the second active region 6B). The width of the second long wiring 114 is larger than the width of the second lower wiring 82 (the first lower wiring 81). The second long wiring 114 preferably has a width substantially equal to the width of the first long wiring 110 in the first direction X. According to this configuration, variation in the wiring resistance between the first long wiring 110 and the second long wiring 114 is prevented.

The second long wiring 114 is provided at intervals in the first direction X from the plurality of first lead-out wirings 109 (the first long wiring 110 and the plurality of first short wirings 111) and opposes the plurality of first lead-out wirings 109 in the first direction X. In this embodiment, the second long wiring 114 intersects (is orthogonal to) at least one (in this embodiment, a plurality) of the first lower wirings 81 and at least one (in this embodiment, a plurality) of the second lower wirings 82 of the second wiring group 80B in the second arrangement region 105B.

The second long wiring 114 crosses the boundary portion 107 in the second direction Y and is led out from the second arrangement region 105B to the first arrangement region 105A. In this embodiment, the second long wiring 114 intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The second long wiring 114 is electrically connected to at least one (in this embodiment, a plurality) of the second lower wirings 82 of the second wiring group 80B in the second arrangement region 105B. Also, the second long wiring 114 is electrically connected to at least one (in this embodiment, a plurality) of the second lower wirings 82 of the second wiring group 80B in the first arrangement region 105A.

In the region between the first pad wiring 101 and the second pad wiring 102, the second long wiring 114 intersects (is orthogonal to) one or a plurality of (preferably, all of) the first lower wirings 81 and one or a plurality of (preferably, all of) the second lower wirings 82 passing directly below at least one (in this embodiment, one) of the first lead-out wiring 109 (the first short wiring 111 on the other side) in the first direction X.

The second long wiring 114 is electrically connected to, of one or a plurality of (preferably, all of) the second lower wirings 82 covered with the first short wiring 111 on the other side, portions of the second lower wirings 82 exposed from the first short wiring 111 on the other side. On the other hand, the second long wiring 114 is electrically disconnected from one or a plurality of (preferably, all of) the first lower wirings 81 passing directly below the first short wiring 111 on the other side.

The second long wiring 114 forms a current path of the drain source current Ids together with the first short wiring 111 on the other side opposing (closely opposing) the second long wiring 114 in the first direction X. Specifically, the current path of the drain source current Ids is formed between the first short wiring 111 on the other side and the second long wiring 114 via the first lower wirings 81 and the second lower wirings 82 passing directly below both the first short wiring 111 on the other side and the second long wiring 114 in the first direction X. Such a layout is effective in reducing the wiring resistance between the first pad wiring 101 and the second pad wiring 102.

The second long wiring 114 has a second opposing portion 116 led out in the second direction Y to a region opposing the first pad wiring 101 in the first direction X. The second opposing portion 116 opposes the entire second end portion of the first pad wiring 101 in the first direction X. With regard to the second wiring group 80B, the second opposing portion 116 (the second long wiring 114) intersects (is orthogonal to) one or a plurality of (preferably, all of) the first lower wirings 81 and one or a plurality of (preferably, all of) the second lower wirings 82 passing directly below the first pad wiring 101 in the first direction X.

The second opposing portion 116 is electrically connected to, of one or a plurality of (preferably, all of) the second lower wirings 82 covered with the first pad wiring 101, portions of the second lower wirings 82 exposed from the first pad wiring 101. On the other hand, the second opposing portion 116 is electrically disconnected from one or a plurality of (preferably, all of) the first lower wirings 81 passing directly below the first pad wiring 101.

The second opposing portion 116 (the second long wiring 114) forms a current path of the drain source current Ids together with the first pad wiring 101 opposing (closely opposing) the second opposing portion 116 (the second long wiring 114) in the first direction X. Specifically, the current path of the drain source current Ids is formed between the first pad wiring 101 and the second long wiring 114 via the first lower wirings 81 and the second lower wirings 82 passing directly below both the first pad wiring 101 and the second long wiring 114 in the first direction X. Such a layout is effective in reducing the wiring resistance between the first pad wiring 101 and the second pad wiring 102.

Each of the plurality of second short wirings 115 has a width smaller than the width of the second pad wiring 102 (the first pad wiring 101) in the first direction X and is provided in a region on the first end portion side with respect to the second long wiring 114. The width of the second short wiring 115 may be substantially equal to the width of the second long wiring 114. The width of the second short wiring 115 may be larger than the width of the second long wiring 114. The width of the second short wiring 115 may be less than the width of the second long wiring 114.

The width of the second short wiring 115 is larger than the width of the second lower wiring 82 (the first lower wiring 81). It is preferable that the width of the second short wiring 115 is substantially equal to the width of the first short wiring 111. According to this configuration, variation in wiring resistance between the first short wirings 111 and the second short wirings 115 is prevented.

The plurality of second short wirings 115 are arrayed at intervals in the first direction X and are led out as bands (in this embodiment, in a rectangular shape) in the second direction Y from the second pad wiring 102 toward the first pad wiring 101. The plurality of second short wirings 115 may be led out in a trapezoidal shape (preferably, an isosceles trapezoidal shape) or a triangular shape (preferably, an isosceles triangular shape).

The plurality of second short wirings 115 are arrayed in a comb teeth shape extending in the second direction Y and oppose each other in the first direction X. The plurality of second short wirings 115 oppose the plurality of first lead-out wirings 109 in the first direction X. Specifically, the plurality of second short wirings 115 respectively enter regions between the plurality of first lead-out wirings 109 and extend in the second direction Y in the regions between the plurality of first lead-out wirings 109.

That is, the plurality of second lead-out wirings 113 include one of the second short wirings 115 arranged in a region between the first long wiring 110 and the first short wiring 111 and the second short wirings 115 arranged in the regions between the plurality of first short wirings 111. Consequently, the plurality of second short wirings 115 and the plurality of first short wirings 111 are alternately arrayed in the first direction X. That is, the plurality of second short wirings 115 are arrayed in a comb teeth shape that meshes with the plurality of first short wirings 111.

The second short wiring 115 preferably has a length substantially equal to a length of the first short wiring 111 in the second direction Y. According to this configuration, variation in wiring resistance between the first short wirings 111 and the second short wirings 115 is prevented. The plurality of second short wirings 115 are formed at intervals from the first pad wiring 101 toward the second pad wiring 102 and oppose the first pad wiring 101 in the second direction Y.

The plurality of second short wirings 115 are electrically connected to at least one (in this embodiment, a plurality) of the second lower wirings 82 in the region between the first pad wiring 101 and the second pad wiring 102. Specifically, in this embodiment, the plurality of second short wirings 115 include one or a plurality (in this embodiment, one) of the second short wiring 115 on the one side and one or a plurality (in this embodiment, one) of the second short wiring 115 on the other side. The number of the second short wirings 115 on the other side is preferably equal to the number of the second short wiring 115 on the one side.

The second short wiring 115 on the one side is led out from the second pad wiring 102 onto the first wiring group 80A (the first active region 6A) and opposes the first pad wiring 101 in the second direction Y in a region on the first wiring group 80A. The second short wiring 115 on the one side is electrically connected to at least one (in this embodiment, a plurality) of the second lower wirings 82 of the first wiring group 80A. In this embodiment, the second short wiring 115 on the one side intersects (is orthogonal to) at least one (in this embodiment, a plurality) of the first lower wirings 81 and at least one (in this embodiment, a plurality) of the second lower wirings 82 of the first wiring group 80A in the second arrangement region 105B.

The second short wiring 115 on the one side crosses the boundary portion 107 in the second direction Y and is led out from the second arrangement region 105B to the first arrangement region 105A. In this embodiment, the second short wiring 115 on the one side intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The second short wiring 115 on the one side is electrically connected to at least one (in this embodiment, a plurality) of the second lower wirings 82 of the first wiring group 80A in the second arrangement region 105B. Also, the second short wiring 115 on the one side is electrically connected to at least one (in this embodiment, a plurality) of the second lower wirings 82 of the first wiring group 80A in the first arrangement region 105A.

With regard to the first wiring group 80A, the second short wiring 115 on the one side intersects (is orthogonal to) one or a plurality of the first lower wirings 81 and one or a plurality of the second lower wirings 82 passing directly below at least one (in this embodiment, a plurality) of the first lead-out wirings 109 (the first long wiring 110 and the first short wirings 111) in the first direction X.

The second short wiring 115 on the one side is electrically connected to, of one or a plurality (in this embodiment, a plurality) of the second lower wirings 82 covered with the plurality of first lead-out wirings 109, portions of the second lower wirings 82 exposed from the plurality of first lead-out wirings 109. On the other hand, the second short wiring 115 on the one side is electrically disconnected from one or a plurality (in this embodiment, a plurality) of the first lower wirings 81 passing directly below the plurality of first lead-out wirings 109.

The second short wiring 115 on the one side forms a current path of the drain source current Ids together with the plurality of first lead-out wirings 109 opposing (closely opposing) the second short wiring 115 in the first direction X. Specifically, the current path of the drain source current Ids is formed between the plurality of first lead-out wirings 109 and the second short wiring 115 on the one side via the first lower wirings 81 and the second lower wirings 82 passing directly below both the plurality of first lead-out wirings 109 and the second short wiring 115 on the one side in the first direction X. Such a layout is effective in reducing the wiring resistance between the first pad wiring 101 and the second pad wiring 102.

In a case where the plurality of second short wirings 115 include a plurality of the second short wirings 115 on the one side, the plurality of second short wirings 115 on the one side are arrayed at intervals in the first direction X in a region on the first wiring group 80A. That is, the plurality of second short wirings 115 on the one side are arrayed in a comb teeth shape extending in the second direction Y in the region on the first wiring group 80A. For example, the plurality of second short wirings 115 on the one side are arrayed in a comb teeth shape that meshes with the plurality of first short wirings 111 on the one side in the region on the first wiring group 80A.

The second short wiring 115 on the other side is led out from the second pad wiring 102 onto the second wiring group 80B (the second active region 6B) and opposes the first pad wiring 101 in the second direction Y in a region on the second wiring group 80B. The second short wiring 115 on the other side is electrically connected to at least one (in this embodiment, a plurality) of the second lower wirings 82 of the second wiring group 80B. In this embodiment, the second short wiring 115 on the other side intersects (is orthogonal to) at least one (in this embodiment, a plurality) of the first lower wirings 81 and at least one (in this embodiment, a plurality) of the second lower wirings 82 of the second wiring group 80B in the second arrangement region 105B.

The second short wiring 115 on the other side crosses the boundary portion 107 in the second direction Y and is led out from the second arrangement region 105B to the first arrangement region 105A. In this embodiment, the second short wiring 115 on the other side intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The second short wiring 115 on the other side is electrically connected to at least one (in this embodiment, a plurality) of the second lower wirings 82 of the second wiring group 80B in the second arrangement region 105B. Also, the second short wiring 115 on the other side is electrically connected to at least one (in this embodiment, a plurality) of the second lower wirings 82 of the second wiring group 80B in the first arrangement region 105A.

The second short wiring 115 on the other side intersects (is orthogonal to) at least one (in this embodiment, a plurality) of the first lower wirings 81 and at least one (in this embodiment, a plurality) of the second lower wirings 82 passing directly below the second long wiring 114 in the first direction X. That is, the second short wiring 115 on the other side is electrically connected to, of at least one (in this embodiment, a plurality) of the second lower wirings 82 covered with the second long wiring 114, portions of the second lower wirings 82 exposed from the second long wiring 114.

With regard to the second wiring group 80B, the second short wiring 115 on the other side intersects (is orthogonal to) one or a plurality of the first lower wirings 81 and one or a plurality of the second lower wirings 82 passing directly below at least one (in this embodiment, one) of the first lead-out wirings 109 (the first short wiring 111 on the other side) in the first direction X.

The second short wiring 115 on the other side is electrically connected to, of one or a plurality (in this embodiment, a plurality) of the second lower wirings 82 covered with the first lead-out wirings 109, portions of the second lower wirings 82 exposed from the first short wiring 111 on the other side. On the other hand, the second short wiring 115 on the other side is electrically disconnected from one or a plurality (in this embodiment, a plurality) of the first lower wirings 81 passing directly below the first lead-out wirings 109.

The second short wiring 115 on the other side forms a current path of the drain source current Ids together with the first lead-out wirings 109 opposing (closely opposing) the second short wiring 115 in the first direction X. Specifically, the current path of the drain source current Ids is formed between the first lead-out wirings 109 and the second short wiring 115 on the other side via the first lower wirings 81 and the second lower wirings 82 passing directly below both the first lead-out wirings 109 and the second short wiring 115 on the other side in the first direction X. Such a layout is effective in reducing the wiring resistance between the first pad wiring 101 and the second pad wiring 102.

In a case where the plurality of second short wirings 115 include a plurality of the second short wirings 115 on the other side, the plurality of second short wirings 115 on the other side are arrayed at intervals in the first direction X in a region on the second wiring group 80B. That is, the plurality of second short wirings 115 on the other side are arrayed in a comb teeth shape extending in the second direction Y in the region on the second wiring group 80B. For example, the plurality of second short wirings 115 on the other side are arrayed in a comb teeth shape that meshes with the plurality of first short wirings 111 on the other side in the region on the second wiring group 80B.

One or both of the second short wirings 115 on the one side and the other side may overlap the inter-wiring region IWR. In this case, one or both of the second short wirings 115 on the one side and the other side overlap one or both of the third lower wiring 83 and the fourth lower wiring 84 and are electrically disconnected from both of the third lower wiring 83 and the fourth lower wiring 84 by the second interlayer film 72.

As a matter of course, the plurality of second lead-out wirings 113 may include the intermediate second short wiring 115 overlapping the inter-wiring region IWR, depending on a layout of the first lead-out wiring 109. In this case, the intermediate second short wiring 115 may be led out from a region on the inter-wiring region IWR onto both the first wiring group 80A and the second wiring group 80B adjacent in the first direction X.

The intermediate second short wiring 115 may be electrically connected to at least one (for example, a plurality) of the second lower wirings 82 of the first wiring group 80A and at least one (for example, a plurality) of the second lower wirings 82 of the second wiring group 80B.

The intermediate second short wiring 115 may intersect (be orthogonal to) at least one (for example, a plurality) of the first lower wirings 81 and at least one (for example, a plurality) of the second lower wirings 82 of the first wiring group 80A in the second arrangement region 105B. Also, the intermediate second short wiring 115 may intersect (be orthogonal to) at least one (for example, a plurality) of the first lower wirings 81 and at least one (for example, a plurality) of the second lower wirings 82 of the second wiring group 80B in the second arrangement region 105B.

The intermediate second short wiring 115 may cross the boundary portion 107 in the second direction Y and may be led out from the second arrangement region 105B to the first arrangement region 105A. The intermediate second short wiring 115 may intersect (be orthogonal to) at least one (for example, a plurality) of the first lower wirings 81 and at least one (for example, a plurality) of the second lower wirings 82 of the first wiring group 80A in both the first arrangement region 105A and the second arrangement region 105B.

Also, the intermediate second short wiring 115 may intersect (be orthogonal to) at least one (for example, a plurality) of the first lower wirings 81 and at least one (for example, a plurality) of the second lower wirings 82 of the second wiring group 80B in both the first arrangement region 105A and the second arrangement region 105B.

The intermediate second short wiring 115 may be electrically connected to at least one (for example, a plurality) of the second lower wirings 82 of the first wiring group 80A and at least one (for example, a plurality) of the second lower wirings 82 of the second wiring group 80B in the first arrangement region 105A. Also, the intermediate second short wiring 115 may be electrically connected to at least one (for example, a plurality) of the second lower wirings 82 of the first wiring group 80A and at least one (for example, a plurality) of the second lower wirings 82 of the second wiring group 80B in the second arrangement region 105B.

The intermediate second short wiring 115 may oppose, on both sides in the first direction X, the first short wiring 111 on the one side and the first short wiring 111 on the other side. In this case, the intermediate second short wiring 115 forms a current path of the drain source current Ids together with the first short wiring 111 on the one side and the first short wiring 111 on the other side opposing (closely opposing) the intermediate second short wiring 115 on both sides in the first direction X.

The intermediate second short wiring 115 may overlap the third lower wiring 83 (the first gate wiring 85 and/or the second gate wiring 86) in a portion covering the inter-wiring region IWR. In this case, the intermediate second short wiring 115 opposes the third lower wiring 83 (the first gate wiring 85 and/or the second gate wiring 86) across the second interlayer film 72 and is electrically disconnected from the third lower wiring 83.

The intermediate second short wiring 115 may overlap the fourth lower wiring 84 (the first base wiring 88) in the portion covering the inter-wiring region IWR. In this case, the intermediate second short wiring 115 opposes the fourth lower wiring 84 (the first base wiring 88) across the second interlayer film 72 and is electrically disconnected from the fourth lower wiring 84.

As described above, the first wiring unit U1 includes a first upper wiring and a second upper wiring. The first upper wiring includes the first pad wiring 101 and the plurality of first lead-out wirings 109, and the second upper wiring includes the second pad wiring 102 and the plurality of second lead-out wirings 113. In this configuration, the second upper wiring preferably has a planar layout substantially congruent with a planar layout of the first upper wiring.

That is, it is preferable that a planar shape of the second upper wiring is substantially equal to a planar shape of the first upper wiring, and a plane area of the second upper wiring is substantially equal to a plane area of the first upper wiring. The second upper wiring is preferably arranged point-symmetrically with respect to the first upper wiring about the central portion of the boundary portion 107.

The first wiring unit U1 includes a wiring slit that electrically disconnect the first upper wiring from the second upper wiring. The wiring slit is defined in a region between the first upper wiring and the second upper wiring and is a portion that exposes a portion (the second interlayer film 72) of the interlayer film 70.

A width of the wiring slit may be not less than 0.1 μm and not more than 50 μm. The width of the wiring slit may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 5 μm, not less than 5 μm and not more than 7.5 μm, not less than 7.5 μm and not more than 10 μm, not less than 10 μm and not more than 12.5 μm, not less than 12.5 μm and not more than 15 μm, not less than 15 μm and not more than 20 μm, not less than 20 μm and not more than 25 μm, and not less than 25 μm and not more than 30 μm.

The first wiring unit U1 includes a plurality of first upper via electrodes 117 and a plurality of second upper via electrodes 118 which are respectively embedded in the second interlayer film 72. The first upper via electrode 117 is a plug electrode that transmits the first drain source potential to the first lower wiring 81. The second upper via electrode 118 is a plug electrode that transmits the second drain source potential to the second lower wiring 82. The first upper via electrode 117 may be referred to as a “first drain source upper via electrode.” The second upper via electrode 118 may be referred to as a “second drain source upper via electrode.”

The plurality of first upper via electrodes 117 are arrayed in a matrix at intervals in the first direction X and the second direction Y with respect to the plurality of first lower wirings 81. As a matter of course, the plurality of first upper via electrodes 117 may be arrayed in a staggered arrangement at intervals in the first direction X and the second direction Y with respect to the plurality of first lower wirings 81. In this case, the plurality of first upper via electrodes 117 connected to one of the first lower wirings 81 oppose, in the second direction Y, regions between the plurality of first upper via electrodes 117 connected to another one of the first lower wirings 81.

The plurality of second upper via electrodes 118 are arrayed in a matrix at intervals in the first direction X and the second direction Y with respect to the plurality of second lower wirings 82. As a matter of course, the plurality of second upper via electrodes 118 may be arrayed in a staggered arrangement at intervals in the first direction X and the second direction Y with respect to the plurality of second lower wirings 82. In this case, the plurality of second upper via electrodes 118 connected to one of the second lower wiring 82 oppose, in the second direction Y, regions between the plurality of second upper via electrodes 118 connected to another one of the second lower wirings 82.

In this embodiment, each of the first and second upper via electrodes 117 and 118 includes a first electrode 119 and a second electrode 120. The first electrode 119 covers, in a film shape, wall surfaces of a via hole formed in the second interlayer film 72. The first electrode 119 may include one or both of a Ti film and a Ti alloy film. The Ti alloy film may be a TiN film.

The second electrode 120 is embedded in the via hole via the first electrode 119. The second electrode 120 may contain at least one type among W, Al, an Al alloy, Cu, and a Cu alloy. The Al alloy may include at least one type among an AlSi alloy, an AlCu alloy, and an AlSiCu alloy.

The first and second upper via electrodes 117 and 118 may be formed in a triangular shape, a quadrangular shape, a rectangular shape, a polygonal shape, a circular shape, or an elliptical shape in plan view. As a matter of course, the first and second upper via electrodes 117 and 118 may be formed as bands (for example, in a rectangular shape) extending in the first direction X.

The plurality of first upper via electrodes 117 are interposed in a region between the plurality of first lower wirings 81 and the first pad wiring 101 in the second interlayer film 72 and electrically connect the first pad wiring 101 to the plurality of first lower wirings 81. The first wiring unit U1 may have at least one of the first upper via electrodes 117 between one of the first lower wirings 81 and the first pad wiring 101. In this embodiment, the plurality of first upper via electrodes 117 are interposed between one of the first lower wirings 81 and the first pad wiring 101.

Also, the plurality of first upper via electrodes 117 are interposed in a region between the plurality of first lower wirings 81 and the plurality of first lead-out wirings 109 in the second interlayer film 72 and electrically connect the plurality of first lead-out wirings 109 to the plurality of first lower wirings 81. The first wiring unit U1 may have at least one of the first upper via electrodes 117 between one of the first lower wirings 81 and one of the first lead-out wirings 109. In this embodiment, the plurality of first upper via electrodes 117 are interposed between one of the first lower wirings 81 and one of the first lead-out wirings 109.

The number of the first upper via electrodes 117 interposed between one of the first lower wirings 81 and one of the first lead-out wirings 109 is arbitrary. For example, the number of the first upper via electrodes 117 may be not less than 1 and not more than 50. The number of the first upper via electrodes 117 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The first upper via electrode 117 may be formed using the first pad wiring 101 (the first lead-out wiring 109). In this case, the first electrode 119 of the first upper via electrode 117 is integrally formed with the first electrode 78 of the first pad wiring 101 (the first lead-out wiring 109) and forms one electrode film together with the first electrode 78. Similarly, the second electrode 120 of the first upper via electrode 117 is integrally formed with the second electrode 79 of the first pad wiring 101 (the first lead-out wiring 109) and forms one electrode together with the second electrode 79.

The plurality of second upper via electrodes 118 are interposed in a region between the plurality of second lower wirings 82 and the second pad wiring 102 in the second interlayer film 72 and electrically connect the second pad wiring 102 to the plurality of second lower wirings 82. The first wiring unit U1 may have at least one of the second upper via electrodes 118 between one of the second lower wirings 82 and the second pad wiring 102. In this embodiment, the plurality of second upper via electrodes 118 are interposed between one of the second lower wirings 82 and the second pad wiring 102.

Also, the plurality of second upper via electrodes 118 are interposed in a region between the plurality of second lower wirings 82 and the plurality of second lead-out wirings 113 in the second interlayer film 72 and electrically connect the plurality of second lead-out wirings 113 to the plurality of second lower wirings 82. The first wiring unit U1 may have at least one of the second upper via electrodes 118 between one of the second lower wirings 82 and one of the second lead-out wirings 113. In this embodiment, the plurality of second upper via electrodes 118 are interposed between one of the second lower wirings 82 and one of the second lead-out wirings 113.

The number of the second upper via electrodes 118 interposed between one of the second lower wirings 82 and one of the second lead-out wirings 113 is arbitrary. For example, the number of the second upper via electrodes 118 may be not less than 1 and not more than 50. The number of the second upper via electrodes 118 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

It is preferable that the number of the second upper via electrodes 118 connected to one of the second lead-out wirings 113 is substantially equal to the number of the first upper via electrodes 117 connected to one of the first lead-out wirings 109. It is preferable that the number of the second upper via electrodes 118 connected to the second pad wiring 102 is substantially equal to the number of the first upper via electrodes 117 connected to the first pad wiring 101.

It is preferable that the number of the second upper via electrodes 118 connected to the second pad wiring 102 and the plurality of second lead-out wirings 113 is substantially equal to the number of the first upper via electrodes 117 connected to the first pad wiring 101 and the plurality of first lead-out wirings 109. According to these configurations, variation in the wiring resistance is prevented.

The second upper via electrode 118 may be formed using the second pad wiring 102 (the second lead-out wiring 113). In this case, the first electrode 119 of the second upper via electrode 118 is integrally formed with the first electrode 78 of the second pad wiring 102 (the second lead-out wiring 113) and forms one electrode film together with the first electrode 78. Similarly, the second electrode 120 of the second upper via electrode 118 is integrally formed with the second electrode 79 of the second pad wiring 102 (the second lead-out wiring 113) and forms one electrode together with the second electrode 79.

The first interconnect structure 108 may have various layouts. Hereinafter, second to tenth layout examples will be described with reference to FIGS. 16B to 16J. With reference to FIG. 16B (the second layout example), the first interconnect structure 108 includes the plurality of first lead-out wirings 109. Each of the plurality of first lead-out wirings 109 includes the first long wiring 110 and a single one of the first short wirings 111. The first long wiring 110 has a layout similar to that of the case of the first layout example.

In this embodiment, the first short wiring 111 is led out in a triangular shape from a region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

The first short wiring 111 covers at least one (in this embodiment, a plurality) of the first lower wirings 81 and at least one (in this embodiment, a plurality) of the second lower wirings 82 of the first wiring group 80A in the first arrangement region 105A. Also, the first short wiring 111 covers at least one (in this embodiment, a plurality) of the first lower wirings 81 and at least one (in this embodiment, a plurality) of the second lower wirings 82 of the second wiring group 80B in the first arrangement region 105A.

The first short wiring 111 crosses the boundary portion 107 in the second direction Y and is led out from the first arrangement region 105A to the second arrangement region 105B. In this embodiment, the first short wiring 111 covers at least one (in this embodiment, a plurality) of the first lower wirings 81 and at least one (in this embodiment, a plurality) of the second lower wirings 82 of the first wiring group 80A in the second arrangement region 105B.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Also, the first short wiring 111 is electrically connected to at least one (in this embodiment, a plurality) of the first lower wirings 81 of the first wiring group 80A in the second arrangement region 105B. Similarly to the case of the first layout example, the first short wiring 111 is electrically connected to the corresponding first lower wirings 81 via the plurality of first upper via electrodes 117.

The first short wiring 111 may cover at least one (in this embodiment, a plurality) of the first lower wirings 81 and at least one (in this embodiment, a plurality) of the second lower wirings 82 of the second wiring group 80B in the second arrangement region 105B. In this case, the first short wiring 111 may be electrically connected to at least one (in this embodiment, a plurality) of the first lower wirings 81 of the second wiring group 80B in the second arrangement region 105B.

The first short wiring 111 has a first inclined portion inclined obliquely from the second end portion of the first pad wiring 101 toward the first end portion of the second pad wiring 102. An extension direction (an inclination direction) of the first inclined portion is a direction intersecting both the first direction X and the second direction Y. The first inclined portion crosses the inter-wiring region IWR in the inclination direction. In this embodiment, an intersection portion (an intersecting point) of the first inclined portion and the inter-wiring region IWR is positioned on the boundary portion 107.

Further, the first inclined portion further has a distal end portion that crosses the boundary portion 107 along the inclination direction and is connected to the first long wiring 110 in the second arrangement region 105B. The first inclined portion is formed at intervals from the second pad wiring 102 toward the first pad wiring 101 in the second arrangement region 105B and opposes the second pad wiring 102 in the second direction Y.

The first short wiring 111 overlaps the third lower wiring 83 in the portion covering the inter-wiring region IWR. In this embodiment, the first short wiring 111 overlaps both the first gate wiring 85 and the second gate wiring 86. The first short wiring 111 opposes the third lower wiring 83 (the first gate wiring 85 and the second gate wiring 86) across the second interlayer film 72 and is electrically disconnected from the third lower wiring 83.

The first short wiring 111 overlaps the fourth lower wiring 84 in the portion covering the inter-wiring region IWR. In this embodiment, the first short wiring 111 overlaps the first base wiring 88. The first short wiring 111 opposes the fourth lower wiring 84 (the first base wiring 88) across the second interlayer film 72 and is electrically disconnected from the fourth lower wiring 84.

The first interconnect structure 108 includes the plurality of second lead-out wirings 113. Each of the plurality of second lead-out wirings 113 includes the second long wiring 114 and the single second short wiring 115. The second long wiring 114 has a layout similar to that of the case of the first layout example.

In this embodiment, the second short wiring 115 is led out in a triangular shape from a region of the second pad wiring 102 on the first end portion side with respect to the second end portion (the second long wiring 114) of the second pad wiring 102. The second short wiring 115 covers the first wiring group 80A, the second wiring group 80B, and the inter-wiring region IWR in the region between the first pad wiring 101 and the second pad wiring 102.

The second short wiring 115 covers at least one (in this embodiment, a plurality) of the first lower wirings 81 and at least one (in this embodiment, a plurality) of the second lower wirings 82 of the first wiring group 80A in the second arrangement region 105B. Also, the second short wiring 115 covers at least one (in this embodiment, a plurality) of the first lower wirings 81 and at least one (in this embodiment, a plurality) of the second lower wirings 82 of the second wiring group 80B in the second arrangement region 105B.

The second short wiring 115 crosses the boundary portion 107 in the second direction Y and is led out from the second arrangement region 105B to the first arrangement region 105A. In this embodiment, the second short wiring 115 covers at least one (in this embodiment, a plurality) of the first lower wirings 81 and at least one (in this embodiment, a plurality) of the second lower wirings 82 of the second wiring group 80B in the first arrangement region 105A.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Also, the second short wiring 115 is electrically connected to at least one (in this embodiment, a plurality) of the second lower wirings 82 of the second wiring group 80B in the first arrangement region 105A. Similarly to the case of the first layout example, the second short wiring 115 is electrically connected to the corresponding second lower wirings 82 via the plurality of second upper via electrodes 118.

The second short wiring 115 may cover at least one (in this embodiment, a plurality) of the first lower wirings 81 and at least one (in this embodiment, a plurality) of the second lower wirings 82 of the first wiring group 80A in the first arrangement region 105A. In this case, the second short wiring 115 may be electrically connected to at least one (in this embodiment, a plurality) of the second lower wirings 82 of the first wiring group 80A in the first arrangement region 105A.

The second short wiring 115 has a second inclined portion inclined obliquely from the first end portion of the second pad wiring 102 toward the second end portion of the first pad wiring 101. An extension direction (an inclination direction) of the second inclined portion is a direction intersecting both the first direction X and the second direction Y. The second inclined portion crosses the inter-wiring region IWR in the inclination direction. In this embodiment, an intersection portion (an intersecting point) of the second inclined portion and the inter-wiring region IWR is positioned on the boundary portion 107.

Further, the second inclined portion has a distal end portion that crosses the boundary portion 107 along the inclination direction and is connected to the second long wiring 114 in the first arrangement region 105A. The second inclined portion is formed at intervals from the first pad wiring 101 toward the second pad wiring 102 in the first arrangement region 105A and opposes the first pad wiring 101 in the second direction Y.

The second inclined portion extends along the first inclined portion at intervals from the first inclined portion. It is preferable that the second inclined portion extends substantially parallel to the first inclined portion at intervals from the first inclined portion in a vertical direction of the first inclined portion. That is, it is preferable that the inclination angle of the second inclined portion is substantially equal to an inclination angle of the first inclined portion. The second short wiring 115 preferably has a planar layout substantially congruent with a planar layout of the first short wiring 111.

With regard to the first wiring group 80A, the second short wiring 115 covers one or a plurality of (preferably, all of) the first lower wirings 81 and one or a plurality of (preferably, all of) the second lower wirings 82 passing directly below the first short wiring 111 in the first direction X.

The second short wiring 115 is electrically connected to, of one or a plurality of (preferably, all of) the second lower wirings 82 covered with the first short wiring 111, portions of the second lower wirings 82 exposed from the first short wiring 111 on the first wiring group 80A side. On the other hand, the second short wiring 115 is electrically disconnected from one or a plurality of (preferably, all of) the first lower wirings 81 passing directly below the first short wiring 111.

Similarly, with regard to the second wiring group 80B, the second short wiring 115 covers one or a plurality of (preferably, all of) the first lower wirings 81 and one or a plurality of (preferably, all of) the second lower wirings 82 passing directly below the first short wiring 111 in the first direction X.

The second short wiring 115 is electrically connected to, of one or a plurality of (preferably, all of) the second lower wirings 82 covered with the first short wiring 111, portions of the second lower wirings 82 exposed from the first short wiring 111 on the second wiring group 80B side. On the other hand, the second short wiring 115 is electrically disconnected from one or a plurality of (preferably, all of) the first lower wirings 81 passing directly below the first short wiring 111.

As described above, in both the first wiring group 80A and the second wiring group 80B, the second short wiring 115 forms a current path of the drain source current Ids together with the first short wiring 111 opposing (closely opposing) the second short wiring 115 in the first direction X.

The second short wiring 115 overlaps the third lower wiring 83 in the portion covering the inter-wiring region IWR. In this embodiment, the second short wiring 115 overlaps both the first gate wiring 85 and the second gate wiring 86. The second short wiring 115 opposes the third lower wiring 83 (the first gate wiring 85 and the second gate wiring 86) across the second interlayer film 72 and is electrically disconnected from the third lower wiring 83.

The second short wiring 115 overlaps the fourth lower wiring 84 in the portion covering the inter-wiring region IWR. In this embodiment, the second short wiring 115 overlaps the first base wiring 88. The second short wiring 115 opposes the fourth lower wiring 84 (the first base wiring 88) across the second interlayer film 72 and is electrically disconnected from the fourth lower wiring 84.

With reference to FIG. 16C (the third layout example), the first interconnect structure 108 includes the plurality of first lead-out wirings 109. Each of the plurality of first lead-out wirings 109 includes the first long wiring 110 and a single one of the first short wirings 111. The first long wiring 110 has a layout similar to that of the case of the first layout example.

The first short wiring 111 is led out in a triangular shape from a region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

The first short wiring 111 covers at least one (in this embodiment, a plurality) of the first lower wirings 81 and at least one (in this embodiment, a plurality) of the second lower wirings 82 of the first wiring group 80A in the first arrangement region 105A. Also, the first short wiring 111 covers at least one (in this embodiment, a plurality) of the first lower wirings 81 and at least one (in this embodiment, a plurality) of the second lower wirings 82 of the second wiring group 80B in the first arrangement region 105A.

The first short wiring 111 crosses the boundary portion 107 in the second direction Y and is led out from the first arrangement region 105A to the second arrangement region 105B. In this embodiment, the first short wiring 111 covers at least one (in this embodiment, a plurality) of the first lower wirings 81 and at least one (in this embodiment, a plurality) of the second lower wirings 82 of the second wiring group 80B in the second arrangement region 105B.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Also, the first short wiring 111 is electrically connected to at least one (in this embodiment, a plurality) of the first lower wirings 81 of the second wiring group 80B in the second arrangement region 105B.

Similarly to the case of the first layout example, the first short wiring 111 is electrically connected to the corresponding first lower wirings 81 via the plurality of first upper via electrodes 117. The first short wiring 111 may cover at least one (in this embodiment, a plurality) of the first lower wirings 81 and at least one (in this embodiment, a plurality) of the second lower wirings 82 of the first wiring group 80A in the second arrangement region 105B. In this case, the first short wiring 111 may be electrically connected to at least one (in this embodiment, a plurality) of the first lower wirings 81 of the first wiring group 80A in the second arrangement region 105B.

In this embodiment, the first short wiring 111 has a first side portion led out in the second direction Y from the second end portion of the first pad wiring 101 toward the second wiring group 80B. The first side portion forms one side extending in the second direction Y with the second end portion of the first pad wiring 101. The first side portion crosses the boundary portion 107 in the second direction Y and is positioned in the second arrangement region 105B. The first side portion is formed at intervals from the second pad wiring 102 toward the first pad wiring 101 in the second arrangement region 105B and opposes the second pad wiring 102 in the second direction Y.

In this embodiment, the first inclined portion of the first short wiring 111 is inclined obliquely from the first end portion of the first pad wiring 101 toward the second end portion of the second pad wiring 102 and opposes the first long wiring 110 in the first direction X. The first inclined portion crosses the inter-wiring region IWR in an inclination direction. In this embodiment, the intersection portion (the intersecting point) of the first inclined portion and the inter-wiring region IWR is positioned on the boundary portion 107.

Further, the first inclined portion crosses the boundary portion 107 along the inclination direction and is connected to the first side portion in the second arrangement region 105B. That is, a distal end portion of the first inclined portion and the second end portion of the first pad wiring 101 are positioned on the same straight line.

The first interconnect structure 108 includes the plurality of second lead-out wirings 113. Each of the plurality of second lead-out wirings 113 includes the second long wiring 114 and the single second short wiring 115. The second long wiring 114 has a layout similar to that of the case of the first layout example.

The second short wiring 115 is led out in a triangular shape from the region of the second pad wiring 102 on the first end portion side and is arranged in a region between the first long wiring 110 and the first short wiring 111. The second short wiring 115 covers the first wiring group 80A, the second wiring group 80B, and the inter-wiring region IWR in the region between the first pad wiring 101 and the second pad wiring 102.

The second short wiring 115 covers at least one (in this embodiment, a plurality) of the first lower wirings 81 and at least one (in this embodiment, a plurality) of the second lower wirings 82 of the first wiring group 80A in the second arrangement region 105B. Also, the second short wiring 115 covers at least one (in this embodiment, a plurality) of the first lower wirings 81 and at least one (in this embodiment, a plurality) of the second lower wirings 82 of the second wiring group 80B in the second arrangement region 105B.

The second short wiring 115 crosses the boundary portion 107 in the second direction Y and is led out from the second arrangement region 105B to the first arrangement region 105A. In this embodiment, the second short wiring 115 covers at least one (in this embodiment, a plurality) of the first lower wirings 81 and at least one (in this embodiment, a plurality) of the second lower wirings 82 of the first wiring group 80A in the first arrangement region 105A.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Also, the second short wiring 115 is electrically connected to at least one (in this embodiment, a plurality) of the second lower wirings 82 of the first wiring group 80A in the first arrangement region 105A.

Similarly to the case of the first layout example, the second short wiring 115 is electrically connected to the corresponding second lower wirings 82 via the plurality of second upper via electrodes 118. The second short wiring 115 may cover at least one (in this embodiment, a plurality) of the first lower wirings 81 and at least one (in this embodiment, a plurality) of the second lower wirings 82 of the second wiring group 80B in the first arrangement region 105A. In this case, the second short wiring 115 may be electrically connected to at least one (in this embodiment, a plurality) of the second lower wirings 82 of the second wiring group 80B in the first arrangement region 105A.

In this embodiment, the second short wiring 115 has a second side portion led out in the second direction Y from the first end portion of the second pad wiring 102. The second side portion forms one side extending in the second direction Y with the first end portion of the second pad wiring 102. The second side portion crosses the boundary portion 107 in the second direction Y and is positioned in the first arrangement region 105A. The second side portion is formed on the second pad wiring 102 side at intervals from the first pad wiring 101 toward the first wiring group 80A in the first arrangement region 105A and opposes the first pad wiring 101 in the second direction Y.

In this embodiment, the second inclined portion of the second short wiring 115 is inclined obliquely from the second end portion of the second pad wiring 102 toward the first end portion of the first pad wiring 101 and opposes the second long wiring 114 in the first direction X. The second inclined portion crosses the inter-wiring region IWR in the inclination direction. In this embodiment, the intersection portion (the intersecting point) of the second inclined portion and the inter-wiring region IWR is positioned on the boundary portion 107.

Further, the second inclined portion crosses the boundary portion 107 along the inclination direction and is connected to the second side portion in the first arrangement region 105A. That is, a distal end portion of the second inclined portion and the first end portion of the second pad wiring 102 are positioned on the same straight line.

The second inclined portion extends along the first inclined portion at intervals from the first inclined portion. It is preferable that the second inclined portion extends substantially parallel to the first inclined portion at intervals from the first inclined portion in a vertical direction of the first inclined portion. That is, it is preferable that the inclination angle of the second inclined portion is substantially equal to an inclination angle of the first inclined portion. The second short wiring 115 preferably has a planar layout substantially congruent with the planar layout of the first short wiring 111.

Similarly to the case of the second layout example, in both the first wiring group 80A and the second wiring group 80B, the second short wiring 115 forms a current path of the drain source current Ids together with the first short wiring 111 opposing (closely opposing) the second short wiring 115 in the first direction X.

With reference to FIG. 16D (the fourth layout example), the first interconnect structure 108 includes the plurality of first lead-out wirings 109. Each of the plurality of first lead-out wirings 109 includes the first long wiring 110 and the single first short wirings 111. The first long wiring 110 has a layout similar to that of the case of the first layout example.

The first short wiring 111 is led out in a trapezoidal shape (a quadrangular shape) from a region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Also, the first short wiring 111 is electrically connected to at least one (in this embodiment, a plurality) of the first lower wirings 81 of the first wiring group 80A in the second arrangement region 105B.

The first short wiring 111 may cover at least one (in this embodiment, a plurality) of the first lower wirings 81 and at least one (in this embodiment, a plurality) of the second lower wirings 82 of the second wiring group 80B in the second arrangement region 105B. In this case, the first short wiring 111 may be electrically connected to at least one (in this embodiment, a plurality) of the first lower wirings 81 of the second wiring group 80B in the second arrangement region 105B.

The first short wiring 111 has a first distal end portion and a first inclined portion. The first distal end portion has a width less than the width of the first pad wiring 101 in the first direction X and is positioned on the second pad wiring 102 side with respect to the first pad wiring 101. The first distal end portion extends in the first direction X at least on the first wiring group 80A side and is connected to the first long wiring 110.

In this embodiment, the first distal end portion is positioned in the second arrangement region 105B. The first distal end portion is formed at intervals from the second pad wiring 102 toward the first pad wiring 101 in the second arrangement region 105B and opposes the first end portion of the second pad wiring 102 in the second direction Y. The first distal end portion extends substantially parallel to the first end portion of the second pad wiring 102.

The first inclined portion is formed at intervals from the second end portion of the first pad wiring 101 toward the first end portion of the first pad wiring 101 and exposes the second end portion of the first pad wiring 101. The first inclined portion is inclined obliquely from an inner portion of the first pad wiring 101 toward the first end portion of the second pad wiring 102. An extension direction (the inclination direction) of the first inclined portion is a direction intersecting both the first direction X and the second direction Y.

The first inclined portion crosses the inter-wiring region IWR in an inclination direction. In this embodiment, the intersection portion (the intersecting point) of the first inclined portion and the inter-wiring region IWR is positioned on the boundary portion 107. Further, the first inclined portion crosses the boundary portion 107 along the inclination direction and is connected to the first distal end portion in the second arrangement region 105B. As a matter of course, the extension direction (the inclination direction) of the first inclined portion may be the second direction Y. In this case, the first inclined portion preferably extends in the second direction Y on the first wiring group 80A or on the inter-wiring region IWR.

The first interconnect structure 108 includes the plurality of second lead-out wirings 113. Each of the plurality of second lead-out wirings 113 includes the second long wiring 114 and the single second short wiring 115. The second long wiring 114 has a layout similar to that of the case of the first layout example.

The second short wiring 115 is led out in a trapezoidal shape (a quadrangular shape) from a region of the second pad wiring 102 on the first end portion side with respect to the second end portion (the second long wiring 114) of the second pad wiring 102. The second short wiring 115 covers the first wiring group 80A, the second wiring group 80B, and the inter-wiring region IWR in the region between the first pad wiring 101 and the second pad wiring 102.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Also, the second short wiring 115 is electrically connected to at least one (in this embodiment, a plurality) of the second lower wirings 82 of the second wiring group 80B in the first arrangement region 105A.

The second short wiring 115 may cover at least one (in this embodiment, a plurality) of the first lower wirings 81 and at least one (in this embodiment, a plurality) of the second lower wirings 82 of the first wiring group 80A in the first arrangement region 105A. In this case, the second short wiring 115 may be electrically connected to at least one (in this embodiment, a plurality) of the second lower wirings 82 of the first wiring group 80A in the first arrangement region 105A.

The second short wiring 115 has a second distal end portion and the second inclined portion. The second distal end portion has a width less than the width of the second pad wiring 102 in the first direction X and is positioned on the first pad wiring 101 side with respect to the second pad wiring 102. The second distal end portion extends in the first direction X at least on the second wiring group 80B side and is connected to the second long wiring 114. It is preferable that the width of the second distal end portion is substantially equal to the width of the first distal end portion.

In this embodiment, the second distal end portion is positioned in the first arrangement region 105A. The second distal end portion is formed at intervals from the first pad wiring 101 toward the second pad wiring 102 in the first arrangement region 105A and opposes the second end portion of the first pad wiring 101 in the second direction Y. The second distal end portion extends substantially parallel to the second end portion of the first pad wiring 101.

The second inclined portion is formed at intervals from the first end portion of the second pad wiring 102 toward the second end portion of the second pad wiring 102 and exposes the first end portion of the second pad wiring 102. The second inclined portion is inclined obliquely from an inner portion of the second pad wiring 102 toward the second end portion of the first pad wiring 101. An extension direction (the inclination direction) of the second inclined portion is a direction intersecting both the first direction X and the second direction Y.

The second inclined portion crosses the inter-wiring region IWR in the inclination direction. In this embodiment, the intersection portion (the intersecting point) of the second inclined portion and the inter-wiring region IWR is positioned on the boundary portion 107. Further, the second inclined portion crosses the boundary portion 107 along the inclination direction and is connected to the second distal end portion in the first arrangement region 105A. As a matter of course, the extension direction (the inclination direction) of the second inclined portion may be the second direction Y. In this case, the second inclined portion preferably extends in the second direction Y on the second wiring group 80B or on the inter-wiring region IWR.

The second inclined portion extends along the first inclined portion at intervals from the first inclined portion. It is preferable that the second inclined portion extends substantially parallel to the first inclined portion at intervals from the first inclined portion in a vertical direction of the first inclined portion. That is, it is preferable that the inclination angle of the second inclined portion is substantially equal to an inclination angle of the first inclined portion. The second short wiring 115 preferably has a planar layout substantially congruent with the planar layout of the first short wiring 111.

Similarly to the case of the second layout example, in both the first wiring group 80A and the second wiring group 80B, the second short wiring 115 forms a current path of the drain source current Ids together with the first short wiring 111 opposing (closely opposing) the second short wiring 115 in the first direction X.

With reference to FIG. 16E (the fifth layout example), the first interconnect structure 108 includes the plurality of first lead-out wirings 109. Each of the plurality of first lead-out wirings 109 includes the first long wiring 110 and the single first short wirings 111. The first long wiring 110 has a layout similar to that of the case of the first layout example.

The first short wiring 111 is led out in a trapezoidal shape (a quadrangular shape) from the region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Also, the first short wiring 111 is electrically connected to at least one (in this embodiment, a plurality) of the first lower wirings 81 of the second wiring group 80B in the second arrangement region 105B.

The first short wiring 111 may cover at least one (in this embodiment, a plurality) of the first lower wirings 81 and at least one (in this embodiment, a plurality) of the second lower wirings 82 of the first wiring group 80A in the second arrangement region 105B. In this case, the first short wiring 111 may be electrically connected to at least one (in this embodiment, a plurality) of the first lower wirings 81 of the first wiring group 80A in the second arrangement region 105B.

The first short wiring 111 has a first side portion led out in the second direction Y from the second end portion of the first pad wiring 101 toward the second wiring group 80B. The first side portion forms one side extending in the second direction Y with the second end portion of the first pad wiring 101. The first side portion crosses the boundary portion 107 in the second direction Y and is positioned in the second arrangement region 105B. The first side portion is formed at intervals from the second pad wiring 102 toward the first pad wiring 101 in the second arrangement region 105B and opposes the second pad wiring 102 in the second direction Y.

The first distal end portion of the first short wiring 111 has a width less than the width of the first pad wiring 101 in the first direction X and is positioned on the second pad wiring 102 side with respect to the first pad wiring 101. The first distal end portion extends in the first direction X at least on the second wiring group 80B side and is connected to the first side portion. In this embodiment, the first distal end portion is formed at intervals from the second pad wiring 102 toward the first pad wiring 101 in the second arrangement region 105B and opposes the second end portion of the second pad wiring 102 in the second direction Y. The first distal end portion extends substantially parallel to the second end portion of the second pad wiring 102.

In this embodiment, the first inclined portion of the first short wiring 111 is formed at intervals from the first end portion (the first long wiring 110) of the first pad wiring 101 toward the second end portion of the first pad wiring 101 and exposes the first end portion of the first pad wiring 101. The first inclined portion is inclined obliquely from an inner portion of the first pad wiring 101 toward the second end portion of the second pad wiring 102. An extension direction (the inclination direction) of the first inclined portion is a direction intersecting both the first direction X and the second direction Y.

The first inclined portion crosses the inter-wiring region IWR in an inclination direction. In this embodiment, the intersection portion (the intersecting point) of the first inclined portion and the inter-wiring region IWR is positioned on the boundary portion 107. Further, the first inclined portion crosses the boundary portion 107 along the inclination direction and is connected to the first distal end portion in the second arrangement region 105B. As a matter of course, the extension direction (the inclination direction) of the first inclined portion may be the second direction Y. In this case, the first inclined portion preferably extends in the second direction Y on the second wiring group 80B or on the inter-wiring region IWR.

The first interconnect structure 108 includes the plurality of second lead-out wirings 113. Each of the plurality of second lead-out wirings 113 includes the second long wiring 114 and the single second short wiring 115. The second long wiring 114 has a layout similar to that of the case of the first layout example.

The second short wiring 115 is led out in a trapezoidal shape (a quadrangular shape) from a region of the second pad wiring 102 on the first end portion side with respect to the second end portion (the second long wiring 114) of the second pad wiring 102 and is arranged in the region between the first long wiring 110 and the first short wiring 111. The second short wiring 115 covers the first wiring group 80A, the second wiring group 80B, and the inter-wiring region IWR in the region between the first pad wiring 101 and the second pad wiring 102.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Also, the second short wiring 115 is electrically connected to at least one (in this embodiment, a plurality) of the second lower wirings 82 of the first wiring group 80A in the first arrangement region 105A.

The second short wiring 115 may cover at least one (in this embodiment, a plurality) of the first lower wirings 81 and at least one (in this embodiment, a plurality) of the second lower wirings 82 of the second wiring group 80B in the first arrangement region 105A. In this case, the second short wiring 115 may be electrically connected to at least one (in this embodiment, a plurality) of the second lower wirings 82 of the second wiring group 80B in the first arrangement region 105A.

In this embodiment, the second short wiring 115 has the second side portion led out in the second direction Y from the first end portion of the second pad wiring 102 toward the first wiring group 80A. The second side portion forms one side extending in the second direction Y with the first end portion of the first pad wiring 101. The second side portion crosses the boundary portion 107 in the second direction Y and is positioned in the first arrangement region 105A. The second side portion is formed at intervals from the first pad wiring 101 toward the second pad wiring 102 in the first arrangement region 105A and opposes the first pad wiring 101 in the second direction Y.

The second distal end portion has a width less than the width of the second pad wiring 102 in the first direction X and is positioned on the first pad wiring 101 side with respect to the second pad wiring 102. The second distal end portion extends in the first direction X at least on the first wiring group 80A side and is connected to the second side portion. In this embodiment, the second distal end portion is formed at intervals from the first pad wiring 101 toward the second pad wiring 102 in the first arrangement region 105A and opposes the first end portion of the first pad wiring 101 in the second direction Y. The second distal end portion extends substantially parallel to the first end portion of the first pad wiring 101.

In this embodiment, the second inclined portion is formed at intervals from the second end portion (the second long wiring 114) of the second pad wiring 102 toward the first end portion of the second pad wiring 102 and exposes the second end portion of the second pad wiring 102. The second inclined portion is inclined obliquely from an inner portion of the second pad wiring 102 toward the first end portion of the first pad wiring 101. An extension direction (the inclination direction) of the second inclined portion is a direction intersecting both the first direction X and the second direction Y.

The second inclined portion crosses the inter-wiring region IWR in the inclination direction. In this embodiment, the intersection portion (the intersecting point) of the second inclined portion and the inter-wiring region IWR is positioned on the boundary portion 107. The second inclined portion crosses the boundary portion 107 along the inclination direction and is connected to the second distal end portion in the first arrangement region 105A. As a matter of course, the extension direction (the inclination direction) of the second inclined portion may be the second direction Y. In this case, the second inclined portion preferably extends in the second direction Y on the first wiring group 80A or on the inter-wiring region IWR.

Similarly to the case of the third layout example, in both the first wiring group 80A and the second wiring group 80B, the second short wiring 115 forms a current path of the drain source current Ids together with the first short wiring 111 opposing (closely opposing) the second short wiring 115 in the first direction X.

With reference to FIG. 16F (the sixth layout example), the first interconnect structure 108 includes the plurality of first lead-out wirings 109. Each of the plurality of first lead-out wirings 109 includes the first long wiring 110 and the single first short wirings 111. The first long wiring 110 has a layout similar to that of the case of the first layout example.

The first short wiring 111 is led out in a single- or multi-stepped shape (in this embodiment, the multi-stepped shape) from a region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Also, the first short wiring 111 is electrically connected to at least one (in this embodiment, a plurality) of the first lower wirings 81 of the first wiring group 80A in the second arrangement region 105B.

The first short wiring 111 may cover at least one (in this embodiment, a plurality) of the first lower wirings 81 and at least one (in this embodiment, a plurality) of the second lower wirings 82 of the second wiring group 80B in the second arrangement region 105B. In this case, the first short wiring 111 may be electrically connected to at least one (in this embodiment, a plurality) of the first lower wirings 81 of the second wiring group 80B in the second arrangement region 105B.

The first short wiring 111 has a first step portion extending in a stepped shape. In this embodiment, the first step portion is led out in the stepped shape from the second end portion side of the first pad wiring 101 toward the first end portion side of the second pad wiring 102 and is connected to the first long wiring 110. The first step portion crosses the inter-wiring region IWR and the boundary portion 107 in the stepped shape and is connected to the first long wiring 110 in the second arrangement region 105B. The first step portion is formed at intervals from the second pad wiring 102 toward the first pad wiring 101 in the second arrangement region 105B and opposes the second pad wiring 102 in the second direction Y.

The first interconnect structure 108 includes the plurality of second lead-out wirings 113. Each of the plurality of second lead-out wirings 113 includes the second long wiring 114 and the single second short wiring 115. The second long wiring 114 has a layout similar to that of the case of the first layout example.

The second short wiring 115 is led out in a single- or multi-stepped shape (in this embodiment, the multi-stepped shape) from a region of the second pad wiring 102 on the first end portion side with respect to the second end portion (the second long wiring 114) of the second pad wiring 102. The second short wiring 115 covers the first wiring group 80A, the second wiring group 80B, and the inter-wiring region IWR in the region between the first pad wiring 101 and the second pad wiring 102.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Also, the second short wiring 115 is electrically connected to at least one (in this embodiment, a plurality) of the second lower wirings 82 of the second wiring group 80B in the first arrangement region 105A.

The second short wiring 115 may cover at least one (in this embodiment, a plurality) of the first lower wirings 81 and at least one (in this embodiment, a plurality) of the second lower wirings 82 of the first wiring group 80A in the first arrangement region 105A. In this case, the second short wiring 115 may be electrically connected to at least one (in this embodiment, a plurality) of the second lower wirings 82 of the first wiring group 80A in the first arrangement region 105A.

The second short wiring 115 has a second step portion extending in a stepped shape. In this embodiment, the second step portion is led out in the stepped shape from the first end portion side of the second pad wiring 102 toward the second end portion side of the first pad wiring 101 and is connected to the second long wiring 114. The second step portion crosses the inter-wiring region IWR and the boundary portion 107 in the stepped shape and is connected to the second long wiring 114 in the first arrangement region 105A. The second step portion is formed at intervals from the first pad wiring 101 toward the second pad wiring 102 in the first arrangement region 105A and opposes the first pad wiring 101 in the second direction Y.

The second step portion extends along the first step portion at intervals from the first step portion. The second step portion preferably extends substantially parallel to the first step portion in both the first direction X and the second direction Y. The second short wiring 115 preferably has a planar layout substantially congruent with the planar layout of the first short wiring 111.

Similarly to the case of the third layout example, in both the first wiring group 80A and the second wiring group 80B, the second short wiring 115 forms a current path of the drain source current Ids together with the first short wiring 111 opposing (closely opposing) the second short wiring 115 in the first direction X.

With reference to FIG. 16G (the seventh layout example), the first short wiring 111 is led out in a single- or multi-stepped shape (in this embodiment, the multi-stepped shape) from a region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Also, the first short wiring 111 is electrically connected to at least one (in this embodiment, a plurality) of the first lower wirings 81 of the second wiring group 80B in the second arrangement region 105B.

The first short wiring 111 may cover at least one (in this embodiment, a plurality) of the first lower wirings 81 and at least one (in this embodiment, a plurality) of the second lower wirings 82 of the first wiring group 80A in the second arrangement region 105B. In this case, the first short wiring 111 may be electrically connected to at least one (in this embodiment, a plurality) of the first lower wirings 81 of the first wiring group 80A in the second arrangement region 105B.

In this embodiment, the first short wiring 111 has a first side portion led out in the second direction Y from the second end portion of the first pad wiring 101. The first side portion forms one side extending in the second direction Y with the second end portion of the first pad wiring 101. The first side portion crosses the boundary portion 107 in the second direction Y and is positioned in the second arrangement region 105B. The first side portion is formed at intervals from the second pad wiring 102 toward the first pad wiring 101 in the second arrangement region 105B and opposes the second pad wiring 102 in the second direction Y.

The first short wiring 111 has a first step portion extending in a stepped shape. In this embodiment, the first step portion is led out in the stepped shape from the first end portion side of the first pad wiring 101 toward the second end portion side of the second pad wiring 102 and is connected to the first side portion. Specifically, the first step portion crosses the inter-wiring region IWR and the boundary portion 107 in the stepped shape and is connected to the first side portion in the second arrangement region 105B. The first step portion is formed at intervals from the second pad wiring 102 toward the first pad wiring 101 in the second arrangement region 105B and opposes the second pad wiring 102 in the second direction Y.

The second short wiring 115 is led out in a single- or multi-stepped shape (in this embodiment, the multi-stepped shape) from a region of the second pad wiring 102 on the second end portion side and is arranged in a region between the first long wiring 110 and the first short wiring 111. The second short wiring 115 covers the first wiring group 80A, the second wiring group 80B, and the inter-wiring region IWR in the region between the first pad wiring 101 and the second pad wiring 102.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Also, the second short wiring 115 is electrically connected to at least one (in this embodiment, a plurality) of the second lower wirings 82 of the first wiring group 80A in the first arrangement region 105A.

The second short wiring 115 may cover at least one (in this embodiment, a plurality) of the first lower wirings 81 and at least one (in this embodiment, a plurality) of the second lower wirings 82 of the second wiring group 80B in the first arrangement region 105A. In this case, the second short wiring 115 may be electrically connected to at least one (in this embodiment, a plurality) of the second lower wirings 82 of the second wiring group 80B in the first arrangement region 105A.

In this embodiment, the second short wiring 115 has a second side portion led out in the second direction Y from the first end portion of the second pad wiring 102. The second side portion forms one side extending in the second direction Y with the first end portion of the second pad wiring 102. The second side portion crosses the boundary portion 107 in the second direction Y and is positioned in the first arrangement region 105A. The second side portion is formed at intervals from the first pad wiring 101 toward the second pad wiring 102 in the first arrangement region 105A and opposes the first pad wiring 101 in the second direction Y.

The second short wiring 115 has a second step portion extending in a stepped shape. In this embodiment, the second step portion is led out in the stepped shape from the second end portion side of the second pad wiring 102 toward the first end portion side of the first pad wiring 101 and is connected to the second side portion. Specifically, the second step portion crosses the inter-wiring region IWR and the boundary portion 107 in the stepped shape and is connected to the second side portion in the first arrangement region 105A. The second step portion is formed at intervals from the first pad wiring 101 toward the second pad wiring 102 in the first arrangement region 105A and opposes the first pad wiring 101 in the second direction Y.

Similarly to the case of the third layout example, in both the first wiring group 80A and the second wiring group 80B, the second short wiring 115 forms a current path of the drain source current Ids together with the first short wiring 111 opposing (closely opposing) the second short wiring 115 in the first direction X.

With reference to FIG. 16H (the eighth layout example), the first interconnect structure 108 includes the plurality of first lead-out wirings 109. Each of the plurality of first lead-out wirings 109 includes the first long wiring 110 and the single first short wirings 111. The first long wiring 110 has a layout similar to that of the case of the first layout example.

The first short wiring 111 is led out in a polygonal shape (a quadrangular shape) toward the second pad wiring 102 from a region of the first pad wiring 101 on the second end portion side with respect to the first end portion (the first long wiring 110) of the first pad wiring 101. The first short wiring 111 covers the first wiring group 80A, the second wiring group 80B, and the inter-wiring region IWR in the region between the first pad wiring 101 and the second pad wiring 102.

In this embodiment, the first short wiring 111 is formed at intervals from the boundary portion 107 (an intermediate portion) toward the first pad wiring 101 and is not positioned in the second arrangement region 105B. The first short wiring 111 covers at least one (in this embodiment, a plurality) of the first lower wirings 81 and at least one (in this embodiment, a plurality) of the second lower wirings 82 of the first wiring group 80A in the first arrangement region 105A. Also, the first short wiring 111 covers at least one (in this embodiment, a plurality) of the first lower wirings 81 and at least one (in this embodiment, a plurality) of the second lower wirings 82 of the second wiring group 80B in the first arrangement region 105A.

The first short wiring 111 is electrically connected to at least one (in this embodiment, a plurality) of the first lower wirings 81 of the first wiring group 80A and at least one (in this embodiment, a plurality) of the first lower wirings 81 of the second wiring group 80B in the first arrangement region 105A. Similarly to the case of the first layout example, the first short wiring 111 is electrically connected to the corresponding first lower wirings 81 via the plurality of first upper via electrodes 117.

The first interconnect structure 108 includes the plurality of second lead-out wirings 113. Each of the plurality of second lead-out wirings 113 includes the second long wiring 114 and the single second short wiring 115. The second long wiring 114 has a layout similar to that of the case of the first layout example.

In this embodiment, the second long wiring 114 is electrically connected to one or a plurality of (preferably, all of) the second lower wirings 82 passing directly below the single first short wiring 111 in the first arrangement region 105A. On the other hand, the second long wiring 114 is electrically disconnected from one or a plurality of (preferably, all of) the first lower wirings 81 passing directly below the single first short wiring 111. Consequently, the second long wiring 114 forms a current path of the drain source current Ids together with the single first short wiring 111 opposing (closely opposing) the second long wiring 114 in the first direction X in the first arrangement region 105A.

In this embodiment, the second short wiring 115 is led out in a polygonal shape (a quadrangular shape) toward the first pad wiring 101 from a region of the second pad wiring 102 on the first end portion side with respect to the second end portion (the second long wiring 114) of the second pad wiring 102. The second short wiring 115 covers the first wiring group 80A, the second wiring group 80B, and the inter-wiring region IWR in the region between the first pad wiring 101 and the second pad wiring 102.

The second short wiring 115 is formed at intervals from the boundary portion 107 (the intermediate portion) toward the second pad wiring 102 and is not positioned in the first arrangement region 105A. The second short wiring 115 opposes the first short wiring 111 in the second direction Y across the boundary portion 107.

The second short wiring 115 covers at least one (in this embodiment, a plurality) of the first lower wirings 81 and at least one (in this embodiment, a plurality) of the second lower wirings 82 of the first wiring group 80A in the second arrangement region 105B. Also, the second short wiring 115 covers at least one (in this embodiment, a plurality) of the first lower wirings 81 and at least one (in this embodiment, a plurality) of the second lower wirings 82 of the second wiring group 80B in the second arrangement region 105B.

The second short wiring 115 is electrically connected to at least one (in this embodiment, a plurality) of the second lower wirings 82 of the first wiring group 80A and at least one (in this embodiment, a plurality) of the second lower wirings 82 of the second wiring group 80B in the second arrangement region 105B. Similarly to the case of the second layout example, the second short wiring 115 is electrically connected to the corresponding second lower wirings 82 via the plurality of second upper via electrodes 118.

The second short wiring 115 is electrically connected to, of one or a plurality of the second lower wirings 82 covered with the first long wiring 110, portions of the second lower wirings 82 exposed from the first long wiring 110 on the first wiring group 80A side. The second short wiring 115 is electrically connected to, of one or a plurality of (preferably, all of) the second lower wirings 82 covered with the second long wiring 114, portions of the second lower wirings 82 exposed from the second long wiring 114 on the second wiring group 80B side.

In this embodiment, the second short wiring 115 is electrically connected to one or a plurality of the second lower wirings 82 passing directly below the first long wiring 110 in the second arrangement region 105B. On the other hand, the second short wiring 115 is electrically disconnected from one or a plurality of (preferably, all of) the first lower wirings 81 passing directly below the first long wiring 110.

The second short wiring 115 forms a current path of the drain source current Ids together with the first long wiring 110 opposing (closely opposing) the second short wiring 115 in the first direction X in the second arrangement region 105B. Also, the second short wiring 115 forms a current path of the drain source current Ids together with the single first short wiring 111 opposing (closely opposing) the second short wiring 115 in the second direction Y.

With reference to FIG. 16I (the ninth layout example), the first wiring unit U1 according to the ninth layout example has a form in which the first pad wiring 101, the second pad wiring 102, and the first interconnect structure 108 according to the first layout example are modified. FIG. 16I shows one first wiring unit U1 straddling the first wiring group 80A and the second wiring group 80B, and the other first wiring unit U1 straddling the second wiring group 80B and the third wiring group 80C.

Hereinafter, the first arrangement region 105A of the one first wiring unit U1 is referred to as the “one first arrangement region 105A,” and the second arrangement region 105B of the one first wiring unit U1 is referred to as the “one second arrangement region 105B.” Also, the first arrangement region 105A of the other first wiring unit U1 is referred to as the “other first arrangement region 105A,” and the second arrangement region 105B of the other first wiring unit U1 is referred to as the “other second arrangement region 105B.”

The one first wiring unit U1 is arranged on the first wiring group 80A and the second wiring group 80B. That is, similarly to the case of the first layout example, the first pad wiring 101 and the second pad wiring 102 of the one first wiring unit U1 are respectively arranged on the first wiring group 80A and the second wiring group 80B. In the one first wiring unit U1, the one wiring group 80 is the first wiring group 80A, and the other wiring group 80 is the second wiring group 80B.

The other first wiring unit U1 is arranged on the second wiring group 80B and the third wiring group 80C. That is, similarly to the case of the first layout example, the first pad wiring 101 and the second pad wiring 102 of the other first wiring unit U1 are respectively arranged on the second wiring group 80B and the third wiring group 80C. In the other first wiring unit U1, the one wiring group 80 is the second wiring group 80B, and the other wiring group 80 is the third wiring group 80C.

In this embodiment, each of the first interconnect structures 108 has the single first lead-out wiring 109 instead of the plurality of first lead-out wirings 109. The first lead-out wiring 109 is led out from the first pad wiring 101 to a region opposing the second pad wiring 102 in the first direction X. The first lead-out wiring 109 includes a first inclined portion 121 and a first rectilinear portion 122.

The first inclined portion 121 is led out as a band in an oblique direction from the first pad wiring 101 toward the first end portion of the second pad wiring 102. An inclination direction of the first inclined portion 121 is a direction intersecting both the first direction X and the second direction Y. The first inclined portion 121 crosses the inter-wiring region IWR along the inclination direction and covers the two wiring groups 80 adjacent in the first direction X.

The first inclined portion 121 covers at least one (in this embodiment, a plurality) of the first lower wirings 81 and at least one (in this embodiment, a plurality) of the second lower wirings 82 of the one wiring group 80 in the first arrangement region 105A. Also, the first inclined portion 121 covers at least one (in this embodiment, a plurality) of the first lower wirings 81 and at least one (in this embodiment, a plurality) of the second lower wirings 82 of the other wiring group 80 in the first arrangement region 105A.

Further, the first inclined portion 121 crosses the boundary portion 107 along the inclination direction and is led out from the first arrangement region 105A to the second arrangement region 105B. In this embodiment, the first inclined portion 121 covers at least one (in this embodiment, a plurality) of the first lower wirings 81 and at least one (in this embodiment, a plurality) of the second lower wirings 82 of the one wiring group 80 in the second arrangement region 105B.

The first inclined portion 121 is electrically connected to at least one (in this embodiment, a plurality) of the first lower wirings 81 between the first pad wiring 101 and the second pad wiring 102. Specifically, the first inclined portion 121 is electrically connected to at least one (in this embodiment, a plurality) of the first lower wirings 81 of the one wiring group 80 and at least one (in this embodiment, a plurality) of the first lower wirings 81 of the other wiring group 80 in the first arrangement region 105A. Also, the first inclined portion 121 is electrically connected to at least one (in this embodiment, a plurality) of the first lower wirings 81 of the one wiring group 80 in the second arrangement region 105B.

The first inclined portion 121 may cover at least one (in this embodiment, a plurality) of the first lower wirings 81 and at least one (in this embodiment, a plurality) of the second lower wirings 82 of the other wiring group 80 in the second arrangement region 105B. In this case, the first inclined portion 121 may be electrically connected to at least one (in this embodiment, a plurality) of the first lower wirings 81 of the other wiring group 80 in the second arrangement region 105B.

Further, the first inclined portion 121 has a portion that crosses a boundary portion of the corresponding first wiring unit U1 along the inclination direction and is positioned in a region outside the corresponding first wiring unit U1. Consequently, a wiring area of each of the first lead-out wirings 109 is increased.

For example, the first inclined portion 121 of the other first wiring unit U1 is led out from the other second arrangement region 105B to the one second arrangement region 105B. The other first inclined portion 121 covers at least one (in this embodiment, a plurality) of the first lower wirings 81 and at least one (in this embodiment, a plurality) of the second lower wirings 82 of the one wiring group 80 (here, the second wiring group 80B) in the one second arrangement region 105B.

The other first inclined portion 121 is electrically connected to at least one (in this embodiment, a plurality) of the second lower wirings 82 of the other wiring group 80 in the one second arrangement region 105B. The other first inclined portion 121 may have a portion positioned in the one first arrangement region 105A. In this case, the other first inclined portion 121 may be electrically connected to at least one (in this embodiment, a plurality) of the second lower wirings 82 of the other wiring group 80 in the one first arrangement region 105A.

The first rectilinear portion 122 is led out as a band in the second direction Y from the first inclined portion 121 onto the one wiring group 80 in the second arrangement region 105B and intersects (is orthogonal to) at least one (in this embodiment, a plurality) of the first lower wirings 81 and at least one (in this embodiment, a plurality) of the second lower wiring 82 of the one wiring group 80.

The first rectilinear portion 122 is led out to a region opposing the second pad wiring 102 in the first direction X. The first rectilinear portion 122 opposes the entire first end portion of the second pad wiring 102 in the first direction X. With regard to the one wiring group 80, the first rectilinear portion 122 intersects (is orthogonal to) one or a plurality of (preferably, all of) the first lower wirings 81 and one or a plurality of (preferably, all of) the second lower wirings 82 passing directly below the second pad wiring 102 in the first direction X.

The first rectilinear portion 122 is electrically connected to, of one or a plurality of (preferably, all of) the first lower wirings 81 covered with the second pad wiring 102, portions of the first lower wirings 81 exposed from the second pad wiring 102. On the other hand, the first rectilinear portion 122 is electrically disconnected from one or a plurality of (preferably, all of) the second lower wirings 82 passing directly below the second pad wiring 102. Consequently, the first rectilinear portion 122 forms a current path of the drain source current Ids together with the second pad wiring 102 opposing (closely opposing) the first rectilinear portion 122 in the first direction X.

Further, the first rectilinear portion 122 has a portion that crosses a boundary portion of the corresponding first wiring unit U1 in the first direction X and is positioned in a region outside the corresponding first wiring unit U1. Consequently, the wiring area of each of the first lead-out wirings 109 is increased.

For example, the first rectilinear portion 122 of the other first wiring unit U1 is led out from the other second arrangement region 105B to the one second arrangement region 105B and opposes the one and the other second pad wirings 102 on both sides in the first direction X. The other first rectilinear portion 122 opposes the entire second end portion of the one second pad wiring 102 in the first direction X in the one second arrangement region 105B.

The other first rectilinear portion 122 has a width less than the width of the first pad wiring 101 (the second pad wiring 102) in the first direction X. As a matter of course, the width of the first rectilinear portion 122 may be larger than the width of the first pad wiring 101 (the second pad wiring 102).

With regard to the one wiring group 80 (here, the second wiring group 80B), the other first rectilinear portion 122 intersects (is orthogonal to) one or a plurality of (preferably, all of) the first lower wirings 81 and one or a plurality of (preferably, all of) the second lower wirings 82 passing directly below the one and the other second pad wirings 102 in the first direction X.

The other first rectilinear portion 122 is electrically connected to one or a plurality of (preferably, all of) the first lower wirings 81 passing directly below the one and the other second pad wirings 102. On the other hand, the other first rectilinear portion 122 is electrically disconnected from one or a plurality of (preferably, all of) the second lower wirings 82 passing directly below the one and the other second pad wirings 102. Consequently, the other first rectilinear portion 122 forms a current path of the drain source current Ids together with the one and the other second pad wirings 102.

Similarly to the case of the first layout example, the first lead-out wiring 109 (the first inclined portion 121 and the first rectilinear portion 122) is electrically connected to the corresponding first lower wirings 81 via the plurality of first upper via electrodes 117.

In this embodiment, each of the first interconnect structures 108 has the single second lead-out wiring 113 instead of the plurality of second lead-out wirings 113. The second lead-out wiring 113 is led out from the second pad wiring 102 to a region opposing the first pad wiring 101 in the first direction X. The second lead-out wiring 113 includes a second inclined portion 123 and a second rectilinear portion 124.

The second inclined portion 123 is led out as a band in an oblique direction from the second pad wiring 102 toward the second end portion of the first pad wiring 101. It is preferable that a width of the second inclined portion 123 is substantially equal to a width of the first inclined portion 121. An inclination direction of the second inclined portion 123 is a direction intersecting both the first direction X and the second direction Y. The second inclined portion 123 extends along the first inclined portion 121 at intervals from the first inclined portion 121.

It is preferable that the second inclined portion 123 extends substantially parallel to the first inclined portion 121 at intervals from the first inclined portion 121 in a vertical direction of the first inclined portion 121. That is, it is preferable that an inclination angle of the second inclined portion 123 is substantially equal to an inclination angle of the first inclined portion 121. The second inclined portion 123 crosses the inter-wiring region IWR along the inclination direction and covers the two wiring groups 80 adjacent in the first direction X.

The second inclined portion 123 covers at least one (in this embodiment, a plurality) of the first lower wirings 81 and at least one (in this embodiment, a plurality) of the second lower wirings 82 of the one wiring group 80 in the second arrangement region 105B. Also, the second inclined portion 123 covers at least one (in this embodiment, a plurality) of the first lower wirings 81 and at least one (in this embodiment, a plurality) of the second lower wirings 82 of the other wiring group 80 in the second arrangement region 105B.

Further, the second inclined portion 123 crosses the boundary portion 107 along the inclination direction and is led out from the second arrangement region 105B to the first arrangement region 105A. In this embodiment, the second inclined portion 123 covers at least one (in this embodiment, a plurality) of the first lower wirings 81 and at least one (in this embodiment, a plurality) of the second lower wirings 82 of the other wiring group 80 in the first arrangement region 105A.

The second inclined portion 123 is electrically connected to at least one (in this embodiment, a plurality) of the second lower wirings 82 of the one wiring group 80 and at least one (in this embodiment, a plurality) of the second lower wirings 82 of the other wiring group 80 in the second arrangement region 105B. Also, the second inclined portion 123 is electrically connected to at least one (in this embodiment, a plurality) of the second lower wirings 82 of the other wiring group 80 in the first arrangement region 105A.

The second inclined portion 123 may cover at least one (in this embodiment, a plurality) of the first lower wirings 81 and at least one (in this embodiment, a plurality) of the second lower wirings 82 of the one wiring group 80 in the first arrangement region 105A. In this case, the second inclined portion 123 may be electrically connected to at least one (in this embodiment, a plurality) of the second lower wirings 82 of the one wiring group 80 in the first arrangement region 105A.

With regard to the one wiring group 80, the second inclined portion 123 covers one or a plurality of (preferably, all of) the first lower wirings 81 and one or a plurality of (preferably, all of) the second lower wirings 82 passing directly below the first inclined portion 121 in the first direction X. Similarly, with regard to the other wiring group 80, the second inclined portion 123 covers one or a plurality of (preferably, all of) the first lower wirings 81 and one or a plurality of (preferably, all of) the second lower wirings 82 passing directly below the first inclined portion 121 in the first direction X.

The second inclined portion 123 is electrically connected to at least one (in this embodiment, a plurality) of the second lower wirings 82 between the first pad wiring 101 and the second pad wiring 102. Specifically, the second inclined portion 123 is electrically connected to, of one or a plurality of (preferably, all of) the second lower wirings 82 covered with the first inclined portion 121, portions of the second lower wirings 82 exposed from the first inclined portion 121 on the one wiring group 80 side. On the other hand, the second inclined portion 123 is electrically disconnected from one or a plurality of (preferably, all of) the first lower wirings 81 passing directly below the first inclined portion 121.

The second inclined portion 123 is electrically connected to, of one or a plurality of (preferably, all of) the second lower wirings 82 covered with the first inclined portion 121, portions of the second lower wirings 82 exposed from the first inclined portion 121 on the other wiring group 80 side. On the other hand, the second inclined portion 123 is electrically disconnected from one or a plurality of (preferably, all of) the first lower wirings 81 passing directly below the first inclined portion 121. As described above, in both the one and the other wiring groups 80, the second short wiring 115 forms a current path of the drain source current Ids together with the first inclined portion 121.

Further, the second inclined portion 123 has a portion that crosses the boundary portion of the corresponding first wiring unit U1 along the inclination direction and is positioned in a region outside the corresponding first wiring unit U1. Consequently, a wiring area of each of the second lead-out wirings 113 is increased.

For example, the second inclined portion 123 of the one first wiring unit U1 is led out from the one first arrangement region 105A to the other first arrangement region 105A. The one second inclined portion 123 covers at least one (in this embodiment, a plurality) of the first lower wirings 81 and at least one (in this embodiment, a plurality) of the second lower wirings 82 of the other wiring group 80 (here, the second wiring group 80B) in the other first arrangement region 105A. The one second inclined portion 123 is electrically connected to at least one (in this embodiment, a plurality) of the second lower wirings 82 of the other wiring group 80.

The one second inclined portion 123 is electrically connected to, of one or a plurality of (preferably, all of) the second lower wirings 82 covered with the other first inclined portion 121, portions of the second lower wirings 82 exposed from the other first inclined portion 121 in the other first arrangement region 105A. On the other hand, the one second inclined portion 123 is electrically disconnected from one or a plurality of (preferably, all of) the first lower wirings 81 passing directly below the other first inclined portion 121. As described above, in the one and the other wiring groups 80, the second inclined portion 123 forms a current path of the drain source current Ids together with the first inclined portion 121.

The second rectilinear portion 124 is led out as a band in the second direction Y from the second inclined portion 123 onto the other wiring group 80 in the first arrangement region 105A and intersects (is orthogonal to) at least one (in this embodiment, a plurality) of the first lower wirings 81 and at least one (in this embodiment, a plurality) of the second lower wiring 82 of the one wiring group 80. The second rectilinear portion 124 is led out to a region opposing the second end portion of the first pad wiring 101 in the first direction X. The second rectilinear portion 124 opposes the entire second end portion of the first pad wiring 101 in the first direction X.

With regard to the other wiring group 80, the second rectilinear portion 124 intersects (is orthogonal to) one or a plurality of (preferably, all of) the first lower wirings 81 and one or a plurality of (preferably, all of) the second lower wirings 82 passing directly below the first pad wiring 101 in the first direction X.

The second rectilinear portion 124 is electrically connected to, of one or a plurality of (preferably, all of) the second lower wirings 82 covered with the first pad wiring 101, portions of the second lower wirings 82 exposed from the first pad wiring 101. On the other hand, the second rectilinear portion 124 is electrically disconnected from one or a plurality of (preferably, all of) the first lower wirings 81 passing directly below the first pad wiring 101. Consequently, the second rectilinear portion 124 forms a current path of the drain source current Ids together with the first pad wiring 101 opposing (closely opposing) the second rectilinear portion 124 in the first direction X.

Further, the second rectilinear portion 124 has a portion that crosses the boundary portion of the corresponding first wiring unit U1 in the first direction X and is positioned in a region outside the corresponding first wiring unit U1. Consequently, the wiring area of each of the second lead-out wirings 113 is increased.

For example, the second rectilinear portion 124 of the one first wiring unit U1 is led out from the one first arrangement region 105A to the other first arrangement region 105A, opposes the one and the other first pad wirings 101 on both sides in the first direction X, and opposes the other first rectilinear portion 122 in the second direction Y. The one second rectilinear portion 124 opposes the entire first end portion of the other first pad wiring 101 in the first direction X in the other first arrangement region 105A.

The second rectilinear portion 124 has a width less than the width of the first pad wiring 101 (the second pad wiring 102) in the first direction X. As a matter of course, the width of the second rectilinear portion 124 may be larger than the width of the first pad wiring 101 (the second pad wiring 102). It is preferable that the width of the second rectilinear portion 124 is substantially equal to the width of the first rectilinear portion 122.

With regard to the other wiring group 80 (here, the second wiring group 80B), the one second rectilinear portion 124 intersects (is orthogonal to) one or a plurality of (preferably, all of) the first lower wirings 81 and one or a plurality of (preferably, all of) the second lower wirings 82 passing directly below the one and the other first pad wirings 101 in the first direction X.

The one second rectilinear portion 124 is electrically connected to one or a plurality of (preferably, all of) the second lower wirings 82 passing directly below the one and the other first pad wirings 101. On the other hand, the one second rectilinear portion 124 is electrically disconnected from one or a plurality of (preferably, all of) the first lower wirings 81 passing directly below the one and the other first pad wirings 101. Consequently, the one second rectilinear portion 124 forms a current path of the drain source current Ids together with the one and the other first pad wirings 101.

Similarly to the case of the first layout example, the second lead-out wiring 113 (the second inclined portion 123 and the second rectilinear portion 124) is electrically connected to the corresponding second lower wirings 82 via the plurality of second upper via electrodes 118.

As described above, the first wiring unit U1 includes the first upper wiring and the second upper wiring. The first upper wiring includes the first pad wiring 101 and the single first lead-out wiring 109, and the second upper wiring includes the second pad wiring 102 and the single second lead-out wiring 113. In this configuration, the second upper wiring preferably has a planar layout substantially congruent with a planar layout of the first upper wiring.

That is, it is preferable that the planar shape of the second upper wiring is substantially equal to the planar shape of the first upper wiring, and the plane area of the second upper wiring is substantially equal to the plane area of the first upper wiring. The second upper wiring is preferably arranged point-symmetrically with respect to the first upper wiring about the central portion of the boundary portion 107.

With reference to FIG. 16J (the tenth layout example), the tenth layout example has a configuration obtained by modifying the ninth layout example. The first pad wiring 101 has a plurality of first edge portions connecting a side extending in the first direction X to a side extending in the second direction Y. The first pad wiring 101 has at least one (in this embodiment, a plurality) of first chamfered portions 125 formed at at least one (in this embodiment, a plurality) of the first edge portions.

The plurality of first chamfered portions 125 are recessed toward an inside of the first arrangement region 105A in plan view. In this embodiment, the plurality of first chamfered portions 125 are constituted of inclined portions inclined in a direction intersecting both the first direction X and the second direction Y. The plurality of first chamfered portions 125 may be defined in a polygonal shape (for example, a quadrangular shape, a hexagonal shape, etc.) toward the inside of the first arrangement region 105A. The plurality of first chamfered portions 125 may be curved in an arc shape (a circular arc shape) toward the inside or the outside of the first arrangement region 105A.

The second pad wiring 102 has a plurality of second edge portions connecting a side extending in the first direction X to a side extending in the second direction Y. The second pad wiring 102 has at least one (in this embodiment, a plurality) of second chamfered portions 126 formed at at least one (in this embodiment, a plurality) of the second edge portions.

The plurality of second chamfered portions 126 are recessed toward an inside of the second arrangement region 105B in plan view. In this embodiment, the plurality of second chamfered portions 126 are constituted of inclined portions inclined in a direction intersecting both the first direction X and the second direction Y. The plurality of second chamfered portions 126 may be defined in a polygonal shape (for example, a quadrangular shape, a hexagonal shape, etc.) toward the inside of the second arrangement region 105B. The plurality of second chamfered portions 126 may be curved in an arc shape (a circular arc shape) toward the inside or the outside of the second arrangement region 105B.

The first lead-out wiring 109 has at least one (in this embodiment, a plurality) of first flared portions 127 flared from the first rectilinear portions 122 toward the second chamfered portions 126 of the corresponding second pad wiring 102. The first flared portion 127 increases the wiring area of the first lead-out wiring 109.

With regard to the two adjacent first wiring units U1, the first lead-out wiring 109 includes the first flared portion 127 flared in the first direction X toward the second chamfered portion 126 of the one second pad wiring 102, and the first flared portion 127 that flares in the first direction X toward the second chamfered portion 126 of the other second pad wiring 102.

In this embodiment, the first flared portion 127 flares in a triangular shape. A planar shape of the first flared portion 127 is adjusted depending on a planar shape of the second chamfered portion 126. The first flared portion 127 may flare in a polygonal shape or a circular arc shape depending on the planar shape of the second chamfered portion 126.

Each of the first flared portions 127 has a portion extending along the corresponding second chamfered portion 126 and opposes the corresponding second pad wiring 102 in both the first direction X and the second direction Y. Each of the first flared portions 127 covers at least one (in this embodiment, a plurality) of the first lower wirings 81 in a region along the corresponding second chamfered portion 126. In this embodiment, each of the first flared portions 127 covers at least one (in this embodiment, a plurality) of the first lower wirings 81 and at least one (in this embodiment, a plurality) of the second lower wirings 82.

Each of the first flared portions 127 is electrically connected to, of one or a plurality of the first lower wirings 81 covered with the corresponding second pad wiring 102, portions of the first lower wirings 81 exposed from the corresponding second pad wiring 102. On the other hand, each of the first flared portions 127 is electrically disconnected from one or a plurality of (preferably, all of) the second lower wirings 82 passing directly below the corresponding second pad wiring 102. Consequently, each of the first flared portions 127 forms a current path of the drain source current Ids together with the corresponding second pad wiring 102.

The second lead-out wiring 113 has at least one (in this embodiment, a plurality) of second flared portions 128 flared from the second rectilinear portions 124 toward the first chamfered portions 125 of the corresponding first pad wiring 101. The second flared portions 128 increases the wiring area of the second lead-out wiring 113.

With regard to the two adjacent first wiring units U1, the second lead-out wiring 113 includes the second flared portion 128 flared in the first direction X toward the first chamfered portions 125 of the one first pad wiring 101, and the second flared portion 128 flared in the first direction X toward the first chamfered portions 125 of the other first pad wiring 101.

In this embodiment, the second flared portion 128 flares in a triangular shape. A planar shape of the second flared portion 128 is adjusted depending on a planar shape of the first chamfered portion 125. The second flared portion 128 may flare in a polygonal shape or a circular arc shape depending on the planar shape of the first chamfered portion 125.

Each of the second flared portions 128 has a portion extending along the corresponding first chamfered portion 125 and opposes the corresponding first pad wiring 101 in both the first direction X and the second direction Y. Each of the second flared portions 128 covers at least one (in this embodiment, a plurality) of the second lower wirings 82 in a region along the corresponding first chamfered portion 125. In this embodiment, each of the second flared portions 128 covers at least one (in this embodiment, a plurality) of the first lower wirings 81 and at least one (in this embodiment, a plurality) of the second lower wirings 82.

Each of the second flared portions 128 is electrically connected to, of one or a plurality of the second lower wirings 82 covered with the corresponding first pad wiring 101, portions of the second lower wirings 82 exposed from the corresponding first pad wiring 101. On the other hand, each of the second flared portions 128 is electrically disconnected from one or a plurality of (preferably, all of) the first lower wirings 81 passing directly below the corresponding first pad wiring 101. Consequently, each of the second flared portions 128 forms a current path of the drain source current Ids together with the corresponding first pad wiring 101.

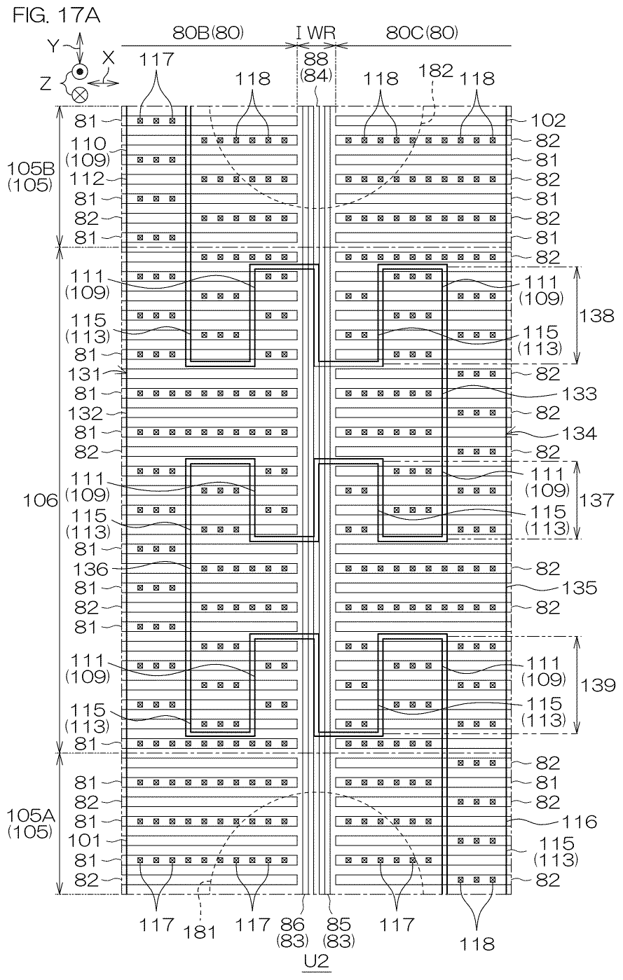

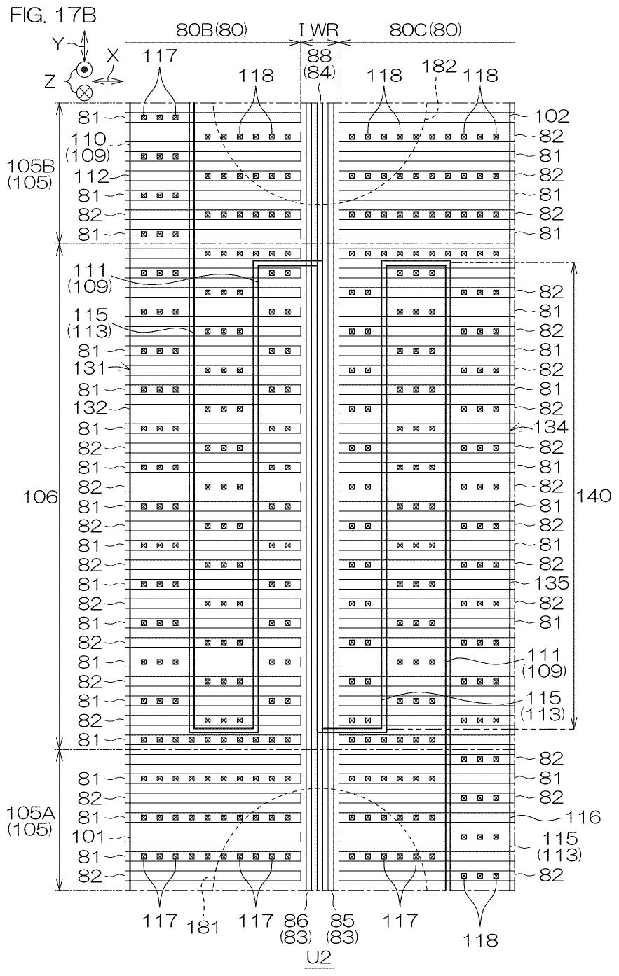

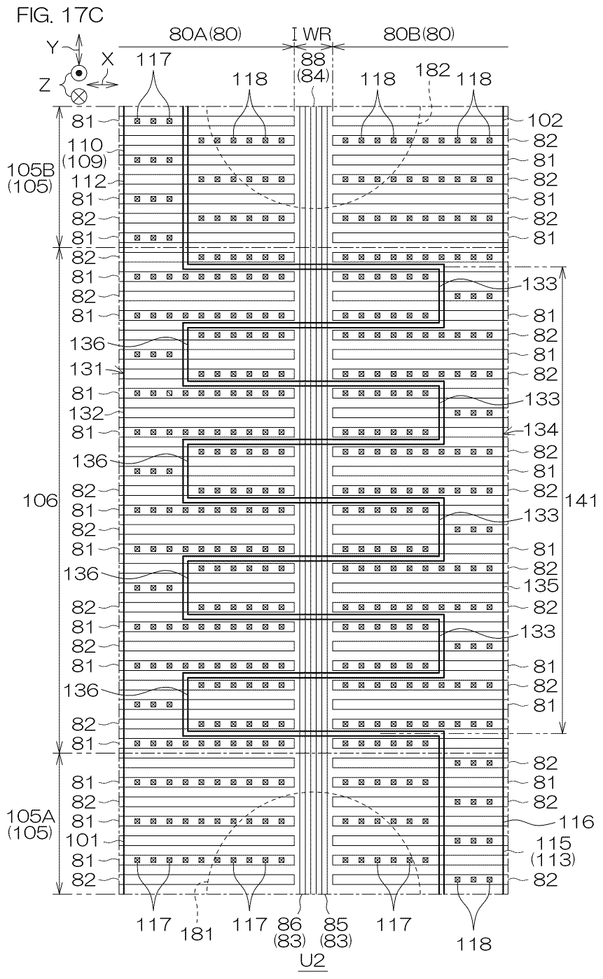

FIG. 17A is an enlarged plan view showing a first layout example of the second wiring unit U2. With reference to FIG. 17A, the second wiring unit U2 includes the first arrangement region 105A (the first pad wiring 101), the second arrangement region 105B (the second pad wiring 102), and the space region 106.

The first arrangement region 105A includes the one and the other wiring groups 80 adjacent in the first direction X across the inter-wiring region IWR. Here, the one wiring group 80 is the second wiring group 80B, and the other wiring group 80 is the third wiring group 80C. A configuration on the first arrangement region 105A side is obtained by replacing the first wiring group 80A with the second wiring group 80B and replacing the second wiring group 80B with the third wiring group 80C in the above description.

The second arrangement region 105B includes the one and the other wiring groups 80 adjacent in the first direction X across the inter-wiring region IWR. Here, the one wiring group 80 is the second wiring group 80B, and the other wiring group 80 is the third wiring group 80C.

A configuration on the second arrangement region 105B side is obtained by replacing the first wiring group 80A with the second wiring group 80B and replacing the second wiring group 80B with the third wiring group 80C in the above description.

The space region 106 is interposed between the two first wiring units U1 adjacent in the second direction Y. That is, the space region 106 is interposed between the first arrangement region 105A (the first pad wiring 101) and the second arrangement region 105B (the second pad wiring 102). The space region 106 is adjacent to the second arrangement region 105B on the one side in the second direction Y and is adjacent to the first arrangement region 105A on the other side in the second direction Y.

The space region 106 is set in a quadrangular shape (preferably, a square shape) in plan view. The space region 106 includes the one and the other wiring groups 80 adjacent in the first direction X across the inter-wiring region IWR. The one wiring group 80 is the second wiring group 80B, and the other wiring group 80 is the third wiring group 80C. In other words, the space region 106 overlaps the second active region 6B and the third active region 6C adjacent in the first direction X across the boundary region 7a.

Specifically, the space region 106 includes at least one (in this embodiment, a plurality) of the first lower wirings 81 and at least one (in this embodiment, a plurality) of the second lower wirings 82 belonging to the second wiring group 80B, and at least one (in this embodiment, a plurality) of the first lower wirings 81 and at least one (in this embodiment, a plurality) of the second lower wirings 82 belonging to the third wiring group 80C.

In the space region 106, the number of the first lower wirings 81 of the second wiring group 80B, the number of the second lower wirings 82 of the second wiring group 80B, the number of the first lower wirings 81 of the third wiring group 80C, and the number of the second lower wirings 82 of the third wiring group 80C are all arbitrary.

For example, in the second wiring group 80B (the third wiring group 80C) of the space region 106, the number of the first lower wirings 81 (the second lower wirings 82) may be not less than 1 and not more than 1000. For example, in the second wiring group 80B (the third wiring group 80C) of the space region 106, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the second wiring group 80B of the space region 106, it is preferable that the number of the second lower wirings 82 is substantially equal to the number of the first lower wirings 81. In the third wiring group 80C of the space region 106, it is preferable that the number of the second lower wirings 82 is substantially equal to the number of the first lower wirings 81. In the space region 106, it is preferable that the number of the first lower wirings 81 of the third wiring group 80C is substantially equal to the number of the first lower wirings 81 of the second wiring group 80B. Also, it is preferable that the number of the second lower wirings 82 of the third wiring group 80C is substantially equal to the number of the second lower wirings 82 of the second wiring group 80B.

In this embodiment, in both the second wiring group 80B and the third wiring group 80C, the plurality of second lower wirings 82 and the plurality of first lower wirings 81 are alternately arrayed. Also, the first lower wirings 81 and the second lower wirings 82 of the third wiring group 80C respectively oppose the first lower wirings 81 and the second lower wirings 82 of the second wiring group 80B in the first direction X.

Therefore, in the second wiring group 80B of the space region 106, a difference value between the number of the first lower wirings 81 and the number of the second lower wirings 82 is 0 to 1. Also, in the third wiring group 80C of the space region 106, a difference value between the number of the first lower wirings 81 and the number of the second lower wirings 82 is 0 to 1.

Also, in the space region 106, a difference value between the number of the first lower wirings 81 of the second wiring group 80B and the number of the first lower wirings 81 of the third wiring group 80C is 0 to 1. Also, a difference value between the number of the second lower wirings 82 of the second wiring group 80B and the number of the second lower wirings 82 of the third wiring group 80C is 0 to 1.

With regard to the second wiring group 80B (the third wiring group 80C) of the space region 106 and the second wiring group 80B (the third wiring group 80C) of the first arrangement region 105A (the second arrangement region 105B), the number of the first lower wirings 81 (the second lower wirings 82) may be equal to or different from each other.

The second wiring unit U2 includes a first routing wiring 131 routed from the first pad wiring 101 to the space region 106. The first routing wiring 131 transmits, to the space region 106, the first drain source potential applied to the first pad wiring 101. The first routing wiring 131 includes at least one (in this embodiment, one) first stem wiring 132 and at least one (in this embodiment, one) first branch wiring 133.

The number of the first branch wirings 133 is arbitrary and is appropriately adjusted depending on a size of the space region 106, etc. The number of the first branch wirings 133 may be not less than 1 and not more than 50. The number of the first branch wirings 133 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50. In this embodiment, one first branch wiring 133 is provided.

The first stem wiring 132 has a width less than the width of the first pad wiring 101 (the second pad wiring 102) in the first direction X and is led out as a band on the one side in the second direction Y from the first end portion of the first pad wiring 101 toward the space region 106. The width of the first stem wiring 132 is larger than the width of the first lower wiring 81 (the second lower wiring 82).

The first stem wiring 132 covers the second wiring group 80B. In this embodiment, the first stem wiring 132 intersects (is orthogonal to) at least one (in this embodiment, a plurality) of the first lower wirings 81 and at least one (in this embodiment, a plurality) of the second lower wirings 82 of the second wiring group 80B in the space region 106.

In this embodiment, the first stem wiring 132 crosses a boundary portion between the space region 106 and the second arrangement region 105B and is connected to the first long wiring 110 (the first opposing portion 112) of the first wiring unit U1 (the first interconnect structure 108) in the second arrangement region 105B. The first stem wiring 132 may have a width substantially equal to the width of the first long wiring 110. The width of the first stem wiring 132 may be larger than the width of the first long wiring 110. The width of the first stem wiring 132 may be less than the width of the first long wiring 110.

The first stem wiring 132 is electrically connected to at least one (in this embodiment, a plurality) of the first lower wirings 81 of the second wiring group 80B in the space region 106. Similarly to the first lead-out wiring 109, etc., the first stem wiring 132 is electrically connected to the corresponding first lower wirings 81 via the plurality of first upper via electrodes 117.

The first branch wiring 133 is led out as a band in the first direction X from the first stem wiring 132 onto the second wiring group 80B in the space region 106. The first branch wiring 133 is formed at intervals from the first pad wiring 101 and the second pad wiring 102 and opposes the first pad wiring 101 and the second pad wiring 102 in the second direction Y.

The first branch wiring 133 may have a width substantially equal to the width of the first stem wiring 132. The width of the first branch wiring 133 may be larger than the width of the first stem wiring 132. The width of the first branch wiring 133 may be less than the width of the first stem wiring 132. The width of the first branch wiring 133 is larger than the width of the first lower wiring 81 (the second lower wiring 82).

The first branch wiring 133 covers at least one (in this embodiment, a plurality) of the first lower wirings 81 and at least one (in this embodiment, a plurality) of the second lower wirings 82 of the second wiring group 80B. The first branch wiring 133 crosses the inter-wiring region IWR in the first direction X from above the second wiring group 80B and is led out onto the third wiring group 80C. The first branch wiring 133 covers at least one (in this embodiment, a plurality) of the first lower wirings 81 and at least one (in this embodiment, a plurality) of the second lower wirings 82 of the third wiring group 80C.

The first branch wiring 133 is electrically connected to at least one (in this embodiment, a plurality) of the first lower wirings 81 of the second wiring group 80B. Also, the first branch wiring 133 is electrically connected to at least one (in this embodiment, a plurality) of the first lower wirings 81 of the third wiring group 80C. Similarly to the first pad wiring 101, etc., the first branch wiring 133 is electrically connected to the corresponding first lower wirings 81 via the plurality of first upper via electrodes 117.

In a case where a plurality of the first branch wirings 133 are formed, the plurality of first branch wirings 133 are respectively led out as bands extending in the first direction X at intervals in the second direction Y. That is, the plurality of first branch wirings 133 are formed in a comb teeth shape extending in the first direction X.

The first branch wiring 133 overlaps the third lower wiring 83 in a portion covering the inter-wiring region IWR. In this embodiment, the first branch wiring 133 overlaps both the first gate wiring 85 and the second gate wiring 86. The first branch wiring 133 opposes the third lower wiring 83 (the first gate wiring 85 and the second gate wiring 86) across the second interlayer film 72 and is electrically disconnected from the third lower wiring 83.

The first branch wiring 133 overlaps the fourth lower wiring 84 in the portion covering the inter-wiring region IWR. In this embodiment, the first branch wiring 133 overlaps the first base wiring 88. The first branch wiring 133 opposes the fourth lower wiring 84 (the first base wiring 88) across the second interlayer film 72 and is electrically disconnected from the fourth lower wiring 84.

The second wiring unit U2 includes a second routing wiring 134 routed from the second pad wiring 102 to the space region 106. The second routing wiring 134 transmits, to the space region 106, the second drain source potential applied to the second pad wiring 102. The second routing wiring 134 includes at least one (in this embodiment, one) second stem wiring 135 and at least one (in this embodiment, one) second branch wiring 136.

The number of the second branch wiring 136 is arbitrary and is appropriately adjusted depending on the size of the space region 106, etc. The number of the second branch wiring 136 may be not less than 1 and not more than 50. The number of the second branch wiring 136 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The number of the second branch wirings 136 is preferably equal to the number of the first branch wirings 133. According to this configuration, variation in wiring resistance between the first branch wiring 133 and the second branch wiring 136 is prevented. In this embodiment, one second branch wiring 136 is provided.

The second stem wiring 135 has a width less than the width of the second pad wiring 102 (the first pad wiring 101) in the first direction X and is led out as a band on the other side in the second direction Y from the second end portion of the second pad wiring 102 toward the space region 106. The width of the second stem wiring 135 is larger than the width of the second lower wiring 82 (the first lower wiring 81).

The second stem wiring 135 covers the third wiring group 80C. That is, the second stem wiring 135 covers, as a connection target, the third wiring group 80C different from the second wiring group 80B which is a connection target of the first stem wiring 132. The second stem wiring 135 opposes the first stem wiring 132 in the first direction X and extends substantially parallel to the first stem wiring 132.

The second stem wiring 135 is formed at intervals in the first direction X from the first branch wiring 133 and opposes the first branch wiring 133 in the first direction X. The second stem wiring 135 intersects (is orthogonal to) at least one (in this embodiment, a plurality) of the first lower wirings 81 and at least one (in this embodiment, a plurality) of the second lower wirings 82 of the third wiring group 80C in the space region 106.

In this embodiment, the second stem wiring 135 crosses a boundary portion between the space region 106 and the first arrangement region 105A and is connected to the second long wiring 114 (the second opposing portion 116) of the first wiring unit U1 (the first interconnect structure 108) in the first arrangement region 105A.

The second stem wiring 135 may have a width substantially equal to the width of the second long wiring 114. The width of the second stem wiring 135 may be larger than the width of the second long wiring 114. The width of the second stem wiring 135 may be less than the width of the second long wiring 114. It is preferable that the width of the second stem wiring 135 is substantially equal to the width of the first stem wiring 132. According to this configuration, variation in the wiring resistance between the first stem wiring 132 and the second stem wiring 135 is prevented.

The second stem wiring 135 is electrically connected to at least one (in this embodiment, a plurality) of the second lower wirings 82 of the third wiring group 80C in the space region 106. Similarly to the second long wiring 114, etc., the second stem wiring 135 is electrically connected to the corresponding second lower wirings 82 via the plurality of second upper via electrodes 118.

The second stem wiring 135 is electrically connected to, of one or a plurality of (preferably, all of) the second lower wirings 82 covered with the first branch wiring 133, portions of the second lower wirings 82 exposed from the first branch wiring 133. On the other hand, the second stem wiring 135 is electrically disconnected from one or a plurality of (preferably, all of) the first lower wirings 81 passing directly below the first branch wiring 133. The second stem wiring 135 forms a current path of the drain source current Ids together with the first branch wiring 133 opposing (closely opposing) the second stem wiring 135 in the first direction X.

The second branch wiring 136 is led out as a band in the first direction X from the second stem wiring 135 onto the third wiring group 80C in the space region 106. The second branch wiring 136 is formed at intervals from the first pad wiring 101 and the second pad wiring 102 and opposes the first pad wiring 101 and the second pad wiring 102 in the second direction Y.

The second branch wiring 136 is formed at intervals in the second direction Y from the first branch wiring 133 and opposes the first branch wiring 133 in the second direction Y. Specifically, the second branch wiring 136 is arranged in a region between the first pad wiring 101 and the first branch wiring 133 and opposes both the first pad wiring 101 and the first branch wiring 133 in the second direction Y.

The second branch wiring 136 may have a width substantially equal to the width of the second stem wiring 135. The width of the second branch wiring 136 may be larger than the width of the second stem wiring 135. The width of the second branch wiring 136 may be less than the width of the second stem wiring 135. The width of the second branch wiring 136 is larger than the width of the second lower wiring 82 (the first lower wiring 81). It is preferable that the width of the second branch wiring 136 is substantially equal to the width of the first branch wiring 133. According to this configuration, variation in the wiring resistance between the first branch wiring 133 and the second branch wiring 136 is prevented.

The second branch wiring 136 covers at least one (in this embodiment, a plurality) of the first lower wirings 81 and at least one (in this embodiment, a plurality) of the second lower wirings 82 of the third wiring group 80C. The second branch wiring 136 crosses the inter-wiring region IWR in the first direction X from above the third wiring group 80C and is led out onto the second wiring group 80B. The second branch wiring 136 covers at least one (in this embodiment, a plurality) of the first lower wirings 81 and at least one (in this embodiment, a plurality) of the second lower wirings 82 of the second wiring group 80B.

The second branch wiring 136 opposes the first branch wiring 133 in the second direction Y on the second wiring group 80B and opposes the first branch wiring 133 in the second direction Y on the third wiring group 80C. The second branch wiring 136 is formed at intervals in the first direction X from the first stem wiring 132 on the second wiring group 80B and opposes the first stem wiring 132 in the first direction X. It is preferable that, in the first direction X, a length of the second branch wiring 136 is substantially equal to a length of the first branch wiring 133.

The second branch wiring 136 is electrically connected to at least one (in this embodiment, a plurality) of the second lower wirings 82 of the third wiring group 80C. Also, the second branch wiring 136 is electrically connected to at least one (in this embodiment, a plurality) of the second lower wirings 82 of the second wiring group 80B. Similarly to the second pad wiring 102, etc., the second branch wiring 136 is electrically connected to the corresponding second lower wirings 82 via the plurality of second upper via electrodes 118.

The second branch wiring 136 is electrically connected to, of one or a plurality of the second lower wirings 82 covered with the first stem wiring 132, portions of the second lower wirings 82 exposed from the first stem wiring 132. On the other hand, the second branch wiring 136 is electrically disconnected from one or a plurality of (preferably, all of) the first lower wirings 81 passing directly below the first stem wiring 132.

The second branch wiring 136 forms a current path of the drain source current Ids together with the first stem wiring 132 opposing (closely opposing) the second branch wiring 136 in the first direction X. Also, the second branch wiring 136 forms a current path of the drain source current Ids together with the first branch wiring 133 in both the second wiring group 80B and the third wiring group 80C.

In a case where a plurality of the second branch wirings 136 are formed, the plurality of second branch wirings 136 and one or a plurality (preferably, a plurality) of the first branch wirings 133 are alternately arrayed in the second direction Y. That is, the plurality of second branch wirings 136 are arrayed in a comb teeth shape that meshes with the one or a plurality (preferably, a plurality) of the first branch wirings 133.

As a matter of course, the plurality of first branch wirings 133 may be arrayed in a comb teeth shape that meshes with one or a plurality (preferably, a plurality) of the second branch wirings 136. In these cases, the number of the second branch wirings 136 is preferably equal to the number of the first branch wirings 133.

The second branch wiring 136 overlaps the third lower wiring 83 in a portion covering the inter-wiring region IWR. In this embodiment, the second branch wiring 136 overlaps both the first gate wiring 85 and the second gate wiring 86. The second branch wiring 136 opposes the third lower wiring 83 (the first gate wiring 85 and the second gate wiring 86) across the second interlayer film 72 and is electrically disconnected from the third lower wiring 83.

The second branch wiring 136 overlaps the fourth lower wiring 84 in the portion covering the inter-wiring region IWR. In this embodiment, the second branch wiring 136 overlaps the first base wiring 88. The second branch wiring 136 opposes the fourth lower wiring 84 (the first base wiring 88) across the second interlayer film 72 and is electrically disconnected from the fourth lower wiring 84.

The second wiring unit U2 includes a second interconnect structure 137 formed in a region between the first branch wiring 133 and the second branch wiring 136. In a case where the plurality of first branch wirings 133 and/or the plurality of second branch wirings 136 are formed, a plurality of the second interconnect structures 137 are each formed in a region between regions between a plurality of pairs of the first branch wirings 133 and the second branch wirings 136 adjacent in the second direction Y.

The second interconnect structure 137 has the same configuration and function as those of the first interconnect structure 108 except that an arrangement location differs. Similarly to the first interconnect structure 108, the second interconnect structure 137 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132.

The plurality of first lead-out wirings 109 are led out in the second direction Y from the first branch wiring 133 toward the second branch wiring 136. The plurality of first lead-out wirings 109 are electrically connected to at least one of the first lower wirings 81 of the second wiring group 80B and/or at least one of the first lower wirings 81 of the third wiring group 80C in a region between the first branch wiring 133 and the second branch wiring 136.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135.

The plurality of second lead-out wirings 113 are led out in the second direction Y from the second branch wiring 136 toward the first branch wiring 133. The plurality of second lead-out wirings 113 are electrically connected to at least one of the second lower wirings 82 of the second wiring group 80B and/or at least one of the second lower wirings 82 of the third wiring group 80C in the region between the first branch wiring 133 and the second branch wiring 136.

As described above, in the second interconnect structure 137, a current path of the drain source current Ids via the plurality of first lead-out wirings 109 and the plurality of second lead-out wirings 113 is formed in the region between the first branch wiring 133 and the second branch wiring 136.

The second interconnect structure 137 may have a configuration similar to any one of the first interconnect structures 108 according to the first to eighth layout examples. In this case, a specific configuration of the second interconnect structure 137 is obtained by replacing the “first pad wiring 101” with the “first branch wiring 133” and replacing the “second pad wiring 102” with the “second branch wiring 136” in the description of the first interconnect structure 108 described above.

The second wiring unit U2 includes a third interconnect structure 138 formed in a region between the second pad wiring 102 and the first branch wiring 133. The third interconnect structure 138 has the same configuration and function as those of the first interconnect structure 108 except that an arrangement location differs. Similarly to the first interconnect structure 108, the third interconnect structure 138 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132.

The plurality of first lead-out wirings 109 are led out in the second direction Y from the first branch wiring 133 toward the second pad wiring 102. The plurality of first lead-out wirings 109 are electrically connected to at least one of the first lower wirings 81 of the second wiring group 80B and/or at least one of the first lower wirings 81 of the third wiring group 80C in the region between the second pad wiring 102 and the first branch wiring 133.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135.

The plurality of second lead-out wirings 113 are led out in the second direction Y from the second pad wiring 102 toward the first branch wiring 133. The plurality of second lead-out wirings 113 are electrically connected to at least one of the second lower wirings 82 of the second wiring group 80B and/or at least one of the second lower wirings 82 of the third wiring group 80C in the region between the second pad wiring 102 and the second branch wiring 136.

As described above, in the third interconnect structure 138, a current path of the drain source current Ids via the plurality of first lead-out wirings 109 and the plurality of second lead-out wirings 113 is formed in the region between the second pad wiring 102 and the first branch wiring 133.

The third interconnect structure 138 may have a configuration similar to any one of the first interconnect structures 108 according to the first to eighth layout examples. In this case, a specific configuration of the third interconnect structure 138 is obtained by replacing the “first pad wiring 101” with the “first branch wiring 133” in the description of the first interconnect structure 108 described above.

The second wiring unit U2 includes a fourth interconnect structure 139 formed in a region between the first pad wiring 101 and the second branch wiring 136. The fourth interconnect structure 139 has the same configuration and function as those of the first interconnect structure 108 except that an arrangement location differs. Similarly to the first interconnect structure 108, the fourth interconnect structure 139 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132.

The plurality of first lead-out wirings 109 are led out in the second direction Y from the first pad wiring 101 toward the second branch wiring 136. The plurality of first lead-out wirings 109 are electrically connected to at least one of the first lower wirings 81 of the second wiring group 80B and/or at least one of the first lower wirings 81 of the third wiring group 80C in a region between the first pad wiring 101 and the second branch wiring 136.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135.

The plurality of second lead-out wirings 113 are led out in the second direction Y from the second branch wiring 136 toward the first pad wiring 101. The plurality of second lead-out wirings 113 are electrically connected to at least one of the second lower wirings 82 of the second wiring group 80B and/or at least one of the second lower wirings 82 of the third wiring group 80C in the region between the first pad wiring 101 and the second branch wiring 136.

As described above, in the fourth interconnect structure 139, a current path of the drain source current Ids via the plurality of first lead-out wirings 109 and the plurality of second lead-out wirings 113 is formed in the region between the first pad wiring 101 and the second branch wiring 136.

The fourth interconnect structure 139 may have a configuration similar to any one of the first interconnect structures 108 according to the first to eighth layout examples. In this case, a specific configuration of the fourth interconnect structure 139 is obtained by replacing the “second pad wiring 102” with the “second branch wiring 136” in the description of the first interconnect structure 108 described above.

The second wiring unit U2 can have a layout shown in FIG. 17B. FIG. 17B is an enlarged plan view showing the second wiring unit U2 according to a second layout example. With reference to FIG. 17B (the second layout example), in this embodiment, the second wiring unit U2 does not have the first branch wiring 133, the second branch wiring 136, and the second to fourth interconnect structures 137 to 139 but includes one first space interconnect structure 140.

The first space interconnect structure 140 has the same configuration and function as those of the first interconnect structure 108 except that an arrangement location differs. Similarly to the first interconnect structure 108, the first space interconnect structure 140 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132.

The plurality of first short wirings 111 are led out in the second direction Y from the first pad wiring 101 toward the second pad wiring 102. The plurality of first short wirings 111 are electrically connected to at least one of the first lower wirings 81 of the second wiring group 80B and/or at least one of the first lower wirings 81 of the third wiring group 80C in the region (the space region 106) between the first pad wiring 101 and the second pad wiring 102.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135.

The plurality of second short wirings 115 are led out in the second direction Y from the second pad wiring 102 toward the first pad wiring 101. The plurality of second short wirings 115 are electrically connected to at least one of the second lower wirings 82 of the second wiring group 80B and/or at least one of the second lower wirings 82 of the third wiring group 80C in the region (the space region 106) between the first pad wiring 101 and the second pad wiring 102.

As described above, in the first space interconnect structure 140, a current path of the drain source current Ids via the plurality of first lead-out wirings 109 and the plurality of second lead-out wirings 113 is formed in the space region 106.

The first space interconnect structure 140 may have a configuration similar to any one of the first interconnect structures 108 according to the first to eighth layout examples. In this case, a specific configuration of the first space interconnect structure 140 can be obtained by replacing the “region between the first pad wiring 101 and the second pad wiring 102” with the “space region 106” in the description of the first interconnect structure 108 described above.

The second wiring unit U2 can have a layout shown in FIG. 17C. FIG. 17C is an enlarged plan view showing the second wiring unit U2 according to the third layout example. With reference to FIG. 17C (the third layout example), in this embodiment, the second wiring unit U2 includes one second space interconnect structure 141 instead of the second to fourth interconnect structures 137 to 139.

The second space interconnect structure 141 is constituted of at least one (in this embodiment, a plurality) of the first branch wirings 133 and at least one (in this embodiment, a plurality) of the second branch wirings 136. The number of the second branch wirings 136 is preferably equal to the number of the first branch wirings 133.

The plurality of first branch wirings 133 respectively extend as bands in the first direction X and are arrayed at intervals in the second direction Y. That is, the plurality of first branch wirings 133 are arrayed in a comb teeth shape extending in the first direction X. On the other hand, the plurality of second branch wirings 136 respectively extend as bands in the first direction X and are arrayed at intervals in the second direction Y. That is, the plurality of second branch wirings 136 are arrayed in a comb teeth shape extending in the first direction X.

Specifically, the plurality of second branch wirings 136 and the plurality of first branch wirings 133 are alternately arrayed in the second direction Y, and the plurality of second branch wirings 136 are arrayed in the comb teeth shape that meshes with the plurality of first branch wirings 133. The plurality of second branch wirings 136 include one of the second branch wirings 136 that is interposed between the first pad wiring 101 and the first branch wiring 133. The plurality of second branch wirings 136 include one of the second branch wirings 136 opposing the second pad wiring 102 across one of the first branch wirings 133.

As a matter of course, the second space interconnect structure 141 may be constituted of the single first branch wiring 133 and the single second branch wiring 136. In this case, the first branch wiring 133 is arranged in a region opposing the second pad wiring 102 in the second direction Y, and the second branch wiring 136 is arranged in a region between the first pad wiring 101 and the first branch wiring 133.

As described above, in the second space interconnect structure 141, a current path of the drain source current Ids via the plurality of first branch wirings 133 and the plurality of second branch wirings 136 is formed in the space region 106.

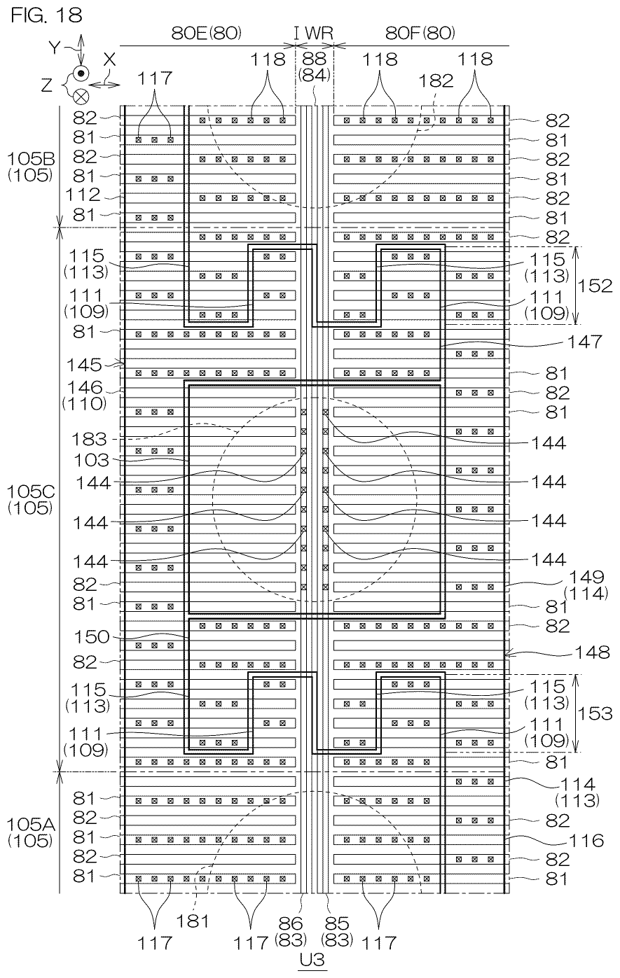

FIG. 18 is an enlarged plan view showing an example of the third wiring unit U3. The third wiring unit U3 includes the first arrangement region 105A (the first pad wiring 101), the second arrangement region 105B (the second pad wiring 102), and the arrangement region 105 for the third pad wiring 103. Hereinafter, the arrangement region 105 for the third pad wiring 103 is referred to as a “third arrangement region 105C.”

The first arrangement region 105A includes the one and the other wiring groups 80 adjacent in the first direction X across the inter-wiring region IWR. Here, the one wiring group 80 is the fifth wiring group 80E, and the other wiring group 80 is the sixth wiring group 80F. A configuration on the first arrangement region 105A side is obtained by replacing the first wiring group 80A with the fifth wiring group 80E and replacing the second wiring group 80B with the sixth wiring group 80F in the above description.

The second arrangement region 105B includes the one and the other wiring groups 80 adjacent in the first direction X across the inter-wiring region IWR. Here, the one wiring group 80 is the fifth wiring group 80E, and the other wiring group 80 is the sixth wiring group 80F. A configuration on the second arrangement region 105B side is obtained by replacing the first wiring group 80A with the fifth wiring group 80E and replacing the second wiring group 80B with the sixth wiring group 80F in the above description.

The third arrangement region 105C is interposed between the two first wiring units U1 adjacent in the second direction Y and opposes the second wiring unit U2 (the space region 106) in the first direction X. That is, the third arrangement region 105C is interposed between the first arrangement region 105A (the first pad wiring 101) and the second arrangement region 105B (the second pad wiring 102). The third arrangement region 105C is adjacent to the second arrangement region 105B on the one side in the second direction Y and is adjacent to the first arrangement region 105A on the other side in the second direction Y.

The third arrangement region 105C is set in a quadrangular shape (preferably, a square shape) in plan view. The third arrangement region 105C includes the one and the other wiring groups 80 adjacent in the first direction X across the inter-wiring region IWR. The one wiring group 80 is the fifth wiring group 80E, and the other wiring group 80 is the sixth wiring group 80F. In other words, the third arrangement region 105C overlaps the fifth active region 6E and the sixth active region 6F adjacent in the first direction X across the boundary region 7a.

The third arrangement region 105C includes at least one (in this embodiment, a plurality) of the first lower wirings 81 and at least one (in this embodiment, a plurality) of the second lower wirings 82 belonging to the fifth wiring group 80E, and at least one (in this embodiment, a plurality) of the first lower wirings 81 and at least one (in this embodiment, a plurality) of the second lower wirings 82 belonging to the sixth wiring group 80F.

In the third arrangement region 105C, the number of the first lower wirings 81 of the fifth wiring group 80E, the number of the second lower wirings 82 of the fifth wiring group 80E, the number of the first lower wirings 81 of the sixth wiring group 80F, and the number of the second lower wirings 82 of the sixth wiring group 80F are all arbitrary.

For example, in the fifth wiring group 80E (the sixth wiring group 80F) of the third arrangement region 105C, the number of the first lower wirings 81 (the second lower wirings 82) may be not less than 1 and not more than 1000. For example, in the fifth wiring group 80E (the sixth wiring group 80F) of the third arrangement region 105C, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the fifth wiring group 80E of the third arrangement region 105C, it is preferable that the number of the second lower wirings 82 is substantially equal to the number of the first lower wirings 81. In the sixth wiring group 80F of the third arrangement region 105C, it is preferable that the number of the second lower wirings 82 is substantially equal to the number of the first lower wirings 81. In the third arrangement region 105C, it is preferable that the number of the first lower wirings 81 of the sixth wiring group 80F is substantially equal to the number of the first lower wirings 81 of the fifth wiring group 80E. Also, it is preferable that the number of the second lower wirings 82 of the sixth wiring group 80F is substantially equal to the number of the second lower wirings 82 of the fifth wiring group 80E.

In this embodiment, in both the fifth wiring group 80E and the sixth wiring group 80F, the plurality of second lower wirings 82 and the plurality of first lower wirings 81 are alternately arrayed. Also, the first lower wirings 81 and the second lower wirings 82 of the sixth wiring group 80F respectively oppose the first lower wirings 81 and the second lower wirings 82 of the fifth wiring group 80E in the first direction X.

Therefore, in the fifth wiring group 80E of the third arrangement region 105C, a difference value between the number of the first lower wirings 81 and the number of the second lower wirings 82 is 0 to 1. Also, in the sixth wiring group 80F of the third arrangement region 105C, a difference value between the number of the first lower wirings 81 and the number of the second lower wirings 82 is 0 to 1.

Also, in the third arrangement region 105C, a difference value between the number of the first lower wirings 81 of the fifth wiring group 80E and the number of the first lower wirings 81 of the sixth wiring group 80F is 0 to 1. Also, a difference value between the number of the second lower wirings 82 of the fifth wiring group 80E and the number of the second lower wirings 82 of the sixth wiring group 80F is 0 to 1.

With regard to the fifth wiring group 80E (the sixth wiring group 80F) of the third arrangement region 105C and the fifth wiring group 80E (the sixth wiring group 80F) of the first arrangement region 105A (the second arrangement region 105B), the number of the first lower wirings 81 (the second lower wirings 82) may be equal to or different from each other.

The third wiring unit U3 includes the third pad wiring 103 arranged in the third arrangement region 105C. The third pad wiring 103 has a plane area less than a plane area of the third arrangement region 105C. The third pad wiring 103 is arranged at intervals inward from a peripheral edge of the third arrangement region 105C in plan view and is formed in a polygonal shape (in this embodiment, a quadrangular shape) having four sides parallel to the peripheral edges of the chip 2 (the peripheral edges of the third arrangement region 105C). The third pad wiring 103 may be formed in a hexagonal shape, an octagonal shape, a circular shape, etc.

The third pad wiring 103 is arranged on the fifth wiring group 80E and the sixth wiring group 80F adjacent in the first direction X across the inter-wiring region IWR. That is, the third pad wiring 103 is arranged on the inter-wiring region IWR and is led out onto the fifth wiring group 80E and the sixth wiring group 80F adjacent in the first direction X.

In other words, the third pad wiring 103 is arranged on the fifth active region 6E and the sixth active region 6F adjacent in the first direction X across the boundary region 7a. The third pad wiring 103 opposes the fifth wiring group 80E, the sixth wiring group 80F, and the inter-wiring region IWR across the second interlayer film 72 and is electrically disconnected from both the fifth wiring group 80E and the sixth wiring group 80F by the second interlayer film 72.

Specifically, the third pad wiring 103 has a first end portion on the one side in the first direction X and a second end portion on the other side in the first direction X. The first end portion of the third pad wiring 103 is arranged on the fifth wiring group 80E and overlaps at least one (in this embodiment, a plurality) of the first lower wirings 81 and at least one (in this embodiment, a plurality) of the second lower wirings 82 of the fifth wiring group 80E. The first end portion of the third pad wiring 103 is electrically disconnected from all of the first lower wirings 81 and all of the second lower wirings 82 of the fifth wiring group 80E by the second interlayer film 72.

The second end portion of the third pad wiring 103 is arranged on the sixth wiring group 80F and overlaps at least one (in this embodiment, a plurality) of the first lower wirings 81 and at least one (in this embodiment, a plurality) of the second lower wirings 82 of the sixth wiring group 80F. The second end portion of the third pad wiring 103 is electrically disconnected from all of the first lower wirings 81 and all of the second lower wirings 82 of the sixth wiring group 80F by the second interlayer film 72.

Directly below the third pad wiring 103, the number of the first lower wirings 81 of the fifth wiring group 80E, the number of the second lower wirings 82 of the fifth wiring group 80E, the number of the first lower wirings 81 of the sixth wiring group 80F, and the number of the second lower wirings 82 of the sixth wiring group 80F are all arbitrary.

For example, in the fifth wiring group 80E (the sixth wiring group 80F) directly below the third pad wiring 103, the number of the first lower wirings 81 (the second lower wirings 82) may be not less than 1 and not more than 1000. For example, in the fifth wiring group 80E (the sixth wiring group 80F) directly below the third pad wiring 103, the number of the first lower wirings 81 (the second lower wirings 82) may be a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the fifth wiring group 80E directly below the third pad wiring 103, it is preferable that the number of the second lower wirings 82 is substantially equal to the number of the first lower wirings 81. In the sixth wiring group 80F directly below the third pad wiring 103, it is preferable that the number of the second lower wirings 82 is substantially equal to the number of the first lower wirings 81.

Directly below the third pad wiring 103, it is preferable that the number of the first lower wirings 81 of the sixth wiring group 80F is substantially equal to the number of the first lower wirings 81 of the fifth wiring group 80E. Also, it is preferable that the number of the second lower wirings 82 of the sixth wiring group 80F is substantially equal to the number of the second lower wirings 82 of the fifth wiring group 80E.

In this embodiment, in both the fifth wiring group 80E and the sixth wiring group 80F, the plurality of second lower wirings 82 and the plurality of first lower wirings 81 are alternately arrayed. Also, the first lower wirings 81 and the second lower wirings 82 of the sixth wiring group 80F respectively oppose the first lower wirings 81 and the second lower wirings 82 of the fifth wiring group 80E in the first direction X.

Therefore, in the fifth wiring group 80E directly below the third pad wiring 103, a difference value between the number of the first lower wirings 81 and the number of the second lower wirings 82 is 0 to 1. Also, in the sixth wiring group 80F directly below the third pad wiring 103, a difference value between the number of the first lower wirings 81 and the number of the second lower wirings 82 is 0 to 1.

Also, directly below the third pad wiring 103, a difference value between the number of the first lower wirings 81 of the fifth wiring group 80E and the number of the first lower wirings 81 of the sixth wiring group 80F is 0 to 1. Also, a difference value between the number of the second lower wirings 82 of the fifth wiring group 80E and the number of the second lower wirings 82 of the sixth wiring group 80F is 0 to 1.

That is, in this embodiment, in the fifth wiring group 80E (the sixth wiring group 80F) directly below the third pad wiring 103, variation in the wiring resistance between the first lower wirings 81 and the second lower wirings 82 is prevented. Also, directly below the third pad wiring 103, variation in the wiring resistance between the fifth wiring group 80E and the sixth wiring group 80F is prevented.

In this embodiment, the third pad wiring 103 has a plane area smaller than the plane area of the first pad wiring 101. The plane area of the third pad wiring 103 is smaller than the plane area of the second pad wiring 102. Consequently, the number of the first lower wirings 81 and the number of the second lower wirings 82 hidden by the third pad wiring 103 are reduced as compared with the first pad wiring 101 (the second pad wiring 102).

The third pad wiring 103 overlaps the third lower wiring 83 in a portion covering the inter-wiring region IWR and is electrically connected to the third lower wiring 83. In this embodiment, the third pad wiring 103 overlaps both the first gate wiring 85 and the second gate wiring 86 and is electrically connected to both the first gate wiring 85 and the second gate wiring 86.

That is, the third pad wiring 103 is electrically connected to both the first gate wiring 85 and the second gate wiring 86 positioned directly below. Consequently, a current path connecting the first gate wiring 85 and the third pad wiring 103 is shortened, and a current path connecting the second gate wiring 86 and the third pad wiring 103 is shortened. As a result, the wiring resistance between the third lower wiring 83 and the third pad wiring 103 is reduced.

The third pad wiring 103 overlaps the fourth lower wiring 84 in the portion covering the inter-wiring region IWR. In this embodiment, the third pad wiring 103 overlaps the first base wiring 88. The third pad wiring 103 opposes the fourth lower wiring 84 (the first base wiring 88) across the second interlayer film 72 and is electrically disconnected from the fourth lower wiring 84.

The third wiring unit U3 includes at least one (in this embodiment, a plurality) of third upper via electrodes 144. Similarly to the first upper via electrode 117, etc., each of the plurality of third upper via electrodes 144 includes the first electrode 119 and the second electrode 120. the description of the first electrode 119 and the second electrode 120 related to the first upper via electrode 117 is applied to the description of the first electrode 119 and the second electrode 120 related to the third upper via electrodes 144.

The plurality of third upper via electrodes 144 are interposed between the third lower wiring 83 and the third pad wiring 103 in the second interlayer film 72 and electrically connect the third pad wiring 103 to the third lower wiring 83. Specifically, the plurality of third upper via electrodes 144 are interposed between the first gate wiring 85 and the third pad wiring 103 and are interposed between the second gate wiring 86 and the third pad wiring 103. Consequently, the third pad wiring 103 is electrically connected to the plurality of gate structures 12 via the third lower wiring 83.

The plurality of third upper via electrodes 144 are arrayed at intervals along the third lower wiring 83. The third upper via electrodes 144 may be formed in a triangular shape, a quadrangular shape, a rectangular shape, a polygonal shape, a circular shape, or an elliptical shape in plan view. As a matter of course, the third upper via electrodes 144 may be formed as bands extending along the third lower wiring 83.

The third upper via electrodes 144 may be formed using the third pad wiring 103. In this case, the first electrode 119 of the third upper via electrode 144 is integrally formed with the first electrode 78 of the third pad wiring 103 and forms one electrode film together with the first electrode 78. Similarly, the second electrode 120 of the third upper via electrode 144 is integrally formed with the second electrode 79 of the third pad wiring 103 and forms one electrode with the second electrode 79.

The third wiring unit U3 includes a third routing wiring 145 routed from the first pad wiring 101 to the third arrangement region 105C. The third routing wiring 145 transmits, to the third arrangement region 105C, the first drain source potential applied to the first pad wiring 101. The third routing wiring 145 includes at least one (in this embodiment, one) third stem wiring 146 and at least one (in this embodiment, one) third branch wiring 147.

The third stem wiring 146 has a width less than the width of the first pad wiring 101 (the second pad wiring 102) in the first direction X and is led out as a band on the one side in the second direction Y from the first end portion of the first pad wiring 101 toward the third arrangement region 105C. The width of the third stem wiring 146 is larger than the width of the first lower wiring 81 (the second lower wiring 82).

The third stem wiring 146 covers the fifth wiring group 80E. In this embodiment, the third stem wiring 146 intersects (is orthogonal to) at least one (in this embodiment, a plurality) of the first lower wirings 81 and at least one (in this embodiment, a plurality) of the second lower wirings 82 of the fifth wiring group 80E in the third arrangement region 105C.

The third stem wiring 146 is led out to a region opposing the third pad wiring 103 in the first direction X. The third stem wiring 146 opposes the entire region of the third pad wiring 103 in the first direction X. The third stem wiring 146 intersects (is orthogonal to) one or a plurality of (preferably, all of) the first lower wirings 81 and one or a plurality of (preferably, all of) the second lower wirings 82 passing directly below the third pad wiring 103 in the first direction X.

In this embodiment, the third stem wiring 146 crosses a boundary portion between the second arrangement region 105B and the third arrangement region 105C and is connected to the first long wiring 110 (the first opposing portion 112) of the first wiring unit U1 (the first interconnect structure 108) in the second arrangement region 105B. The third stem wiring 146 may have a width substantially equal to the width of the first long wiring 110. The width of the third stem wiring 146 may be larger than the width of the first long wiring 110. The width of the third stem wiring 146 may be less than the width of the first long wiring 110.

The third stem wiring 146 is electrically connected to at least one (in this embodiment, a plurality) of the first lower wirings 81 of the fifth wiring group 80E in the third arrangement region 105C. Similarly to the first long wiring 110, etc., the third stem wiring 146 is electrically connected to the corresponding first lower wirings 81 via the plurality of first upper via electrodes 117.

The third stem wiring 146 is electrically connected to, of one or a plurality of (preferably, all of) the first lower wirings 81 covered with the third pad wiring 103, portions of the first lower wirings 81 exposed from the third pad wiring 103. On the other hand, the third stem wiring 146 is electrically disconnected from one or a plurality of (preferably, all of) the second lower wirings 82 passing directly below the third pad wiring 103.

Although not specifically shown, the third stem wiring 146 is electrically connected to, of one or a plurality of (preferably, all of) the first lower wirings 81 covered with the second stem wiring 135 (the second wiring unit U2) opposing (closely opposing) the third stem wiring 146 in the first direction X, portions of the first lower wirings 81 exposed from the second stem wiring 135.

On the other hand, the third stem wiring 146 is electrically disconnected from one or a plurality of (preferably, all of) the second lower wirings 82 passing directly below the second stem wiring 135. Consequently, the third stem wiring 146 forms a current path of the drain source current Ids together with the second stem wiring 135.

The third branch wiring 147 is led out as a band in the first direction X from the third stem wiring 146 to a region between the second pad wiring 102 and the third pad wiring 103 in the third arrangement region 105C and covers the fifth wiring group 80E. The third branch wiring 147 is formed at intervals in the second direction Y from the second pad wiring 102 and the third pad wiring 103 and opposes the second pad wiring 102 and the third pad wiring 103 in the second direction Y.

The third branch wiring 147 may have a width substantially equal to the width of the third stem wiring 146. The width of the third branch wiring 147 may be larger than the width of the third stem wiring 146. The width of the third branch wiring 147 may be less than the width of the third stem wiring 146. The width of the third branch wiring 147 is larger than the width of the first lower wiring 81 (the second lower wiring 82).

The third branch wiring 147 covers at least one (in this embodiment, a plurality) of the first lower wirings 81 and at least one (in this embodiment, a plurality) of the second lower wirings 82 of the fifth wiring group 80E. The third branch wiring 147 crosses the inter-wiring region IWR in the first direction X from above the fifth wiring group 80E and is led out onto the sixth wiring group 80F. The third branch wiring 147 covers at least one (in this embodiment, a plurality) of the first lower wirings 81 and at least one (in this embodiment, a plurality) of the second lower wirings 82 of the sixth wiring group 80F.

The third branch wiring 147 is electrically connected to at least one (in this embodiment, a plurality) of the first lower wirings 81 of the fifth wiring group 80E. Also, the third branch wiring 147 is electrically connected to at least one (in this embodiment, a plurality) of the first lower wirings 81 of the sixth wiring group 80F. Similarly to the first pad wiring 101, etc., the third branch wiring 147 is electrically connected to the corresponding first lower wirings 81 via the plurality of first upper via electrodes 117.

The third branch wiring 147 overlaps the third lower wiring 83 in a portion covering the inter-wiring region IWR. In this embodiment, the third branch wiring 147 overlaps both the first gate wiring 85 and the second gate wiring 86. The third branch wiring 147 opposes the third lower wiring 83 (the first gate wiring 85 and the second gate wiring 86) across the second interlayer film 72 and is electrically disconnected from the third lower wiring 83.

The third branch wiring 147 overlaps the fourth lower wiring 84 in the portion covering the inter-wiring region IWR. In this embodiment, the third branch wiring 147 overlaps the first base wiring 88. The third branch wiring 147 opposes the fourth lower wiring 84 (the first base wiring 88) across the second interlayer film 72 and is electrically disconnected from the fourth lower wiring 84.

The third wiring unit U3 includes a fourth routing wiring 148 routed from the second pad wiring 102 to the third arrangement region 105C. The fourth routing wiring 148 transmits, to the third arrangement region 105C, the second drain source potential applied to the second pad wiring 102. The fourth routing wiring 148 includes at least one (in this embodiment, one) fourth stem wiring 149 and at least one (in this embodiment, one) fourth branch wiring 150.

The fourth stem wiring 149 has a width less than the width of the second pad wiring 102 (the first pad wiring 101) in the first direction X and is led out as a band on the other side in the second direction Y from the second end portion of the second pad wiring 102 toward the third arrangement region 105C. The width of the fourth stem wiring 149 is larger than the width of the second lower wiring 82 (the first lower wiring 81).

The fourth stem wiring 149 covers the sixth wiring group 80F. That is, the fourth stem wiring 149 covers, as a connection target, the sixth wiring group 80F different from the fifth wiring group 80E which is a connection target of the third stem wiring 146. In this embodiment, the fourth stem wiring 149 intersects (is orthogonal to) at least one (in this embodiment, a plurality) of the first lower wirings 81 and at least one (in this embodiment, a plurality) of the second lower wirings 82 of the sixth wiring group 80F in the third arrangement region 105C.

The fourth stem wiring 149 is formed at intervals in the first direction X from the third branch wiring 147 and opposes the third branch wiring 147 in the first direction X. The fourth stem wiring 149 is led out to a region opposing the third pad wiring 103 in the first direction X. The fourth stem wiring 149 opposes the entire region of the third pad wiring 103 in the first direction X.

The fourth stem wiring 149 opposes the third stem wiring 146 in the first direction X across the third pad wiring 103 and extends substantially parallel to the third stem wiring 146. The fourth stem wiring 149 intersects (is orthogonal to) one or a plurality of (preferably, all of) the first lower wirings 81 and one or a plurality of (preferably, all of) the second lower wirings 82 passing directly below the third pad wiring 103 in the first direction X.

In this embodiment, the fourth stem wiring 149 crosses a boundary portion between the first arrangement region 105A and the third arrangement region 105C and is connected to the second long wiring 114 (the second opposing portion 116) of the first wiring unit U1 (the first interconnect structure 108) in the first arrangement region 105A. The fourth stem wiring 149 may have a width substantially equal to the width of the second long wiring 114. The width of the fourth stem wiring 149 may be larger than the width of the second long wiring 114. The width of the fourth stem wiring 149 may be less than the width of the second long wiring 114. It is preferable that the width of the fourth stem wiring 149 is substantially equal to the width of the third stem wiring 146.

The fourth stem wiring 149 is electrically connected to at least one (in this embodiment, a plurality) of the second lower wirings 82 of the third wiring group 80C in the third arrangement region 105C. Similarly to the second long wiring 114, etc., the fourth stem wiring 149 is electrically connected to the corresponding second lower wirings 82 via the plurality of second upper via electrodes 118.

The fourth stem wiring 149 is electrically connected to, of one or a plurality of (preferably, all of) the second lower wirings 82 covered with the third branch wiring 147, portions of the second lower wirings 82 exposed from the third branch wiring 147. On the other hand, the fourth stem wiring 149 is electrically disconnected from one or a plurality of (preferably, all of) the first lower wirings 81 passing directly below the third branch wiring 147. The fourth stem wiring 149 forms a current path of the drain source current Ids together with the third branch wiring 147 opposing (closely opposing) the fourth stem wiring 149 in the first direction X.

The fourth stem wiring 149 is electrically connected to, of one or a plurality of (preferably, all of) the second lower wirings 82 covered with the third pad wiring 103, portions of the second lower wirings 82 exposed from the third pad wiring 103. On the other hand, the fourth stem wiring 149 is electrically disconnected from one or a plurality of (preferably, all of) the first lower wirings 81 passing directly below the third pad wiring 103.

The fourth branch wiring 150 is led out as a band in the first direction X from the fourth stem wiring 149 to a region between the first pad wiring 101 and the third pad wiring 103 in the third arrangement region 105C and covers the sixth wiring group 80F. The fourth branch wiring 150 is formed at intervals in the second direction Y from the first pad wiring 101 and the third pad wiring 103 and opposes the first pad wiring 101 and the third pad wiring 103 in the second direction Y.

The fourth branch wiring 150 may have a width substantially equal to the width of the fourth stem wiring 149. The width of the fourth branch wiring 150 may be larger than the width of the fourth stem wiring 149. The width of the fourth branch wiring 150 may be less than the width of the fourth stem wiring 149. It is preferable that the width of the fourth branch wiring 150 is substantially equal to the width of the third stem wiring 146. The width of the fourth branch wiring 150 is larger than the width of the second lower wiring 82 (the first lower wiring 81).

The fourth branch wiring 150 covers at least one (in this embodiment, a plurality) of the first lower wirings 81 and at least one (in this embodiment, a plurality) of the second lower wirings 82 of the sixth wiring group 80F. The fourth branch wiring 150 crosses the inter-wiring region IWR in the first direction X from above the sixth wiring group 80F and is led out onto the fifth wiring group 80E. The fourth branch wiring 150 covers at least one (in this embodiment, a plurality) of the first lower wirings 81 and at least one (in this embodiment, a plurality) of the second lower wirings 82 of the fifth wiring group 80E.

The fourth branch wiring 150 is formed at intervals in the first direction X from the third stem wiring 146 on the fifth wiring group 80E and opposes the third stem wiring 146 in the first direction X. It is preferable that, in the first direction X, a length of the fourth branch wiring 150 is substantially equal to a length of the third branch wiring 147.

The fourth branch wiring 150 is electrically connected to at least one (in this embodiment, a plurality) of the second lower wirings 82 of the sixth wiring group 80F. Also, the fourth branch wiring 150 is electrically connected to at least one (in this embodiment, a plurality) of the second lower wirings 82 of the fifth wiring group 80E. Similarly to the second pad wiring 102, etc., the fourth branch wiring 150 is electrically connected to the corresponding second lower wirings 82 via the plurality of second upper via electrodes 118.

The fourth branch wiring 150 is electrically connected to, of one or a plurality of the second lower wirings 82 covered with the third stem wiring 146, portions of the second lower wirings 82 exposed from the third stem wiring 146. On the other hand, the fourth branch wiring 150 is electrically disconnected from one or a plurality of (preferably, all of) the first lower wirings 81 passing directly below the third stem wiring 146. The fourth branch wiring 150 forms a current path of the drain source current Ids together with the third stem wiring 146 opposing (closely opposing) the fourth branch wiring 150 in the first direction X.

The fourth branch wiring 150 overlaps the third lower wiring 83 in a portion covering the inter-wiring region IWR. In this embodiment, the fourth branch wiring 150 overlaps both the first gate wiring 85 and the second gate wiring 86. The fourth branch wiring 150 opposes the third lower wiring 83 (the first gate wiring 85 and the second gate wiring 86) across the second interlayer film 72 and is electrically disconnected from the third lower wiring 83.

The fourth branch wiring 150 overlaps the fourth lower wiring 84 in the portion covering the inter-wiring region IWR. In this embodiment, the fourth branch wiring 150 overlaps the first base wiring 88. The fourth branch wiring 150 opposes the fourth lower wiring 84 (the first base wiring 88) across the second interlayer film 72 and is electrically disconnected from the fourth lower wiring 84.

The third wiring unit U3 includes a fifth interconnect structure 152 formed in a region between the second pad wiring 102 and the third branch wiring 147. The fifth interconnect structure 152 has the same configuration and function as those of the first interconnect structure 108 except that an arrangement location differs. Similarly to the first interconnect structure 108, the fifth interconnect structure 152 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the third stem wiring 146 as at least one (in this embodiment, one) of the first long wirings 110 that are relatively long and at least one (in this embodiment, a plurality) of the first short wirings 111 that are shorter than the third stem wiring 146.

The plurality of first lead-out wirings 109 are led out in the second direction Y from the third branch wiring 147 toward the second pad wiring 102. The plurality of first lead-out wirings 109 are electrically connected to at least one of the first lower wirings 81 of the fifth wiring group 80E and/or at least one of the first lower wirings 81 of the sixth wiring group 80F in the region between the second pad wiring 102 and the third branch wiring 147.

Similarly to the first interconnect structure 108, the plurality of second lead-out wirings 113 include the fourth stem wiring 149 as at least one (in this embodiment, one) of the second long wirings 114 that are relatively long and at least one (in this embodiment, a plurality) of the second short wirings 115 that are shorter than the fourth stem wiring 149.

The plurality of second lead-out wirings 113 are led out in the second direction Y from the second pad wiring 102 toward the third branch wiring 147. The plurality of second lead-out wirings 113 are electrically connected to at least one of the second lower wirings 82 of the fifth wiring group 80E and/or at least one of the second lower wirings 82 of the sixth wiring group 80F in the region between the second pad wiring 102 and the third branch wiring 147.

As described above, in the fifth interconnect structure 152, a current path of the drain source current Ids via the plurality of first lead-out wirings 109 and the plurality of second lead-out wirings 113 is formed in the region between the second pad wiring 102 and the third branch wiring 147.

The fifth interconnect structure 152 may have a configuration similar to any one of the first interconnect structures 108 according to the first to eighth layout examples. In this case, a specific configuration of the fifth interconnect structure 152 is obtained by replacing the “first pad wiring 101” with the “third branch wiring 147” in the description of the first interconnect structure 108 described above.

The third wiring unit U3 includes a sixth interconnect structure 153 formed in a region between the first pad wiring 101 and the fourth branch wiring 150. The sixth interconnect structure 153 has the same configuration and function as those of the first interconnect structure 108 except that an arrangement location differs. Similarly to the first interconnect structure 108, the sixth interconnect structure 153 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the third stem wiring 146 as at least one (in this embodiment, one) of the first long wirings 110 that are relatively long and at least one (in this embodiment, a plurality) of the first short wirings 111 that are shorter than the third stem wiring 146.

The plurality of first lead-out wirings 109 are led out in the second direction Y from the first pad wiring 101 toward the fourth branch wiring 150. The plurality of first lead-out wirings 109 are electrically connected to at least one of the first lower wirings 81 of the fifth wiring group 80E and/or at least one of the first lower wirings 81 of the sixth wiring group 80F in the region between the first pad wiring 101 and the fourth branch wiring 150.

Similarly to the first interconnect structure 108, the plurality of second lead-out wirings 113 include the fourth stem wiring 149 as at least one (in this embodiment, one) of the second long wirings 114 that are relatively long and at least one (in this embodiment, a plurality) of the second short wirings 115 that are shorter than the fourth stem wiring 149.

The plurality of second lead-out wirings 113 are led out in the second direction Y from the fourth branch wiring 150 toward the first pad wiring 101. The plurality of second lead-out wirings 113 are electrically connected to at least one of the second lower wirings 82 of the fifth wiring group 80E and/or at least one of the second lower wirings 82 of the sixth wiring group 80F in the region between the first pad wiring 101 and the fourth branch wiring 150.

As described above, in the sixth interconnect structure 153, a current path of the drain source current Ids via the plurality of first lead-out wirings 109 and the plurality of second lead-out wirings 113 is formed in the region between the first pad wiring 101 and the fourth branch wiring 150.

The sixth interconnect structure 153 may have a configuration similar to any one of the first interconnect structures 108 according to the first to eighth layout examples. In this case, a specific configuration of the sixth interconnect structure 153 is obtained by replacing the “second pad wiring 102” with the “fourth branch wiring 150” in the description of the first interconnect structure 108 described above.

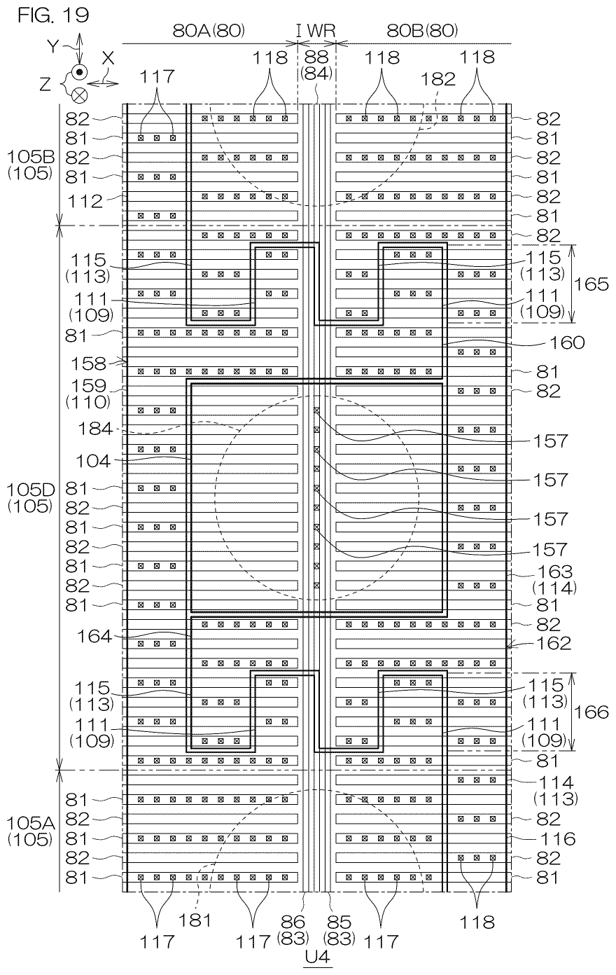

FIG. 19 is an enlarged plan view showing an example of the fourth wiring unit U4. The fourth wiring unit U4 includes the first arrangement region 105A (the first pad wiring 101), the second arrangement region 105B (the second pad wiring 102), and the arrangement region 105 for the fourth pad wiring 104. Hereinafter, the arrangement region 105 for the fourth pad wiring 104 is referred to as a “fourth arrangement region 105D.”

The first arrangement region 105A includes the one and the other wiring groups 80 adjacent in the first direction X across the inter-wiring region IWR. Here, the one wiring group 80 is the first wiring group 80A, and the other wiring group 80 is the second wiring group 80B. The second arrangement region 105B includes the one and the other wiring groups 80 adjacent in the first direction X across the inter-wiring region IWR. Here, the one wiring group 80 is the first wiring group 80A, and the other wiring group 80 is the second wiring group 80B.

The fourth arrangement region 105D is interposed between the two first wiring units U1 adjacent in the second direction Y and opposes the second wiring unit U2 (the space region 106) in the first direction X. That is, the fourth arrangement region 105D is interposed between the first arrangement region 105A (the first pad wiring 101) and the second arrangement region 105B (the second pad wiring 102). The fourth arrangement region 105D is adjacent to the second arrangement region 105B on the one side in the second direction Y and is adjacent to the first arrangement region 105A on the other side in the second direction Y.

The fourth arrangement region 105D is set in a quadrangular shape (preferably, a square shape) in plan view. The fourth arrangement region 105D includes the one and the other wiring groups 80 adjacent in the first direction X across the inter-wiring region IWR. The one wiring group 80 is the first wiring group 80A, and the other wiring group 80 is the second wiring group 80B. In other words, the fourth arrangement region 105D overlaps the first active region 6A and the second active region 6B adjacent in the first direction X across the boundary region 7a.

The fourth arrangement region 105D includes at least one (in this embodiment, a plurality) of the first lower wirings 81 and at least one (in this embodiment, a plurality) of the second lower wirings 82 belonging to the first wiring group 80A, and at least one (in this embodiment, a plurality) of the first lower wirings 81 and at least one (in this embodiment, a plurality) of the second lower wirings 82 belonging to the second wiring group 80B.

In the fourth arrangement region 105D, the number of the first lower wirings 81 of the first wiring group 80A, the number of the second lower wirings 82 of the first wiring group 80A, the number of the first lower wirings 81 of the second wiring group 80B, and the number of the second lower wirings 82 of the second wiring group 80B are all arbitrary.

For example, in the first wiring group 80A (the second wiring group 80B) of the fourth arrangement region 105D, the number of the first lower wirings 81 (the second lower wirings 82) may be not less than 1 and not more than 1000. For example, in the first wiring group 80A (the second wiring group 80B) of the fourth arrangement region 105D, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first wiring group 80A of the fourth arrangement region 105D, it is preferable that the number of the second lower wirings 82 is substantially equal to the number of the first lower wirings 81. In the second wiring group 80B of the fourth arrangement region 105D, it is preferable that the number of the second lower wirings 82 is substantially equal to the number of the first lower wirings 81. In the fourth arrangement region 105D, it is preferable that the number of the first lower wirings 81 of the second wiring group 80B is substantially equal to the number of the first lower wirings 81 of the first wiring group 80A. Also, it is preferable that the number of the second lower wirings 82 of the second wiring group 80B is substantially equal to the number of the second lower wirings 82 of the first wiring group 80A.

In this embodiment, in both the first wiring group 80A and the second wiring group 80B, the plurality of second lower wirings 82 and the plurality of first lower wirings 81 are alternately arrayed. Also, the first lower wirings 81 and the second lower wirings 82 of the second wiring group 80B respectively oppose the first lower wirings 81 and the second lower wirings 82 of the first wiring group 80A in the first direction X.

Therefore, in the first wiring group 80A of the fourth arrangement region 105D, a difference value between the number of the first lower wirings 81 and the number of the second lower wirings 82 is 0 to 1. Also, in the second wiring group 80B in the fourth arrangement region 105D, a difference value between the number of the first lower wirings 81 and the number of the second lower wirings 82 is 0 to 1.

Also, in the fourth arrangement region 105D, a difference value between the number of the first lower wirings 81 of the first wiring group 80A and the number of the first lower wirings 81 of the second wiring group 80B is 0 to 1. Also, a difference value between the number of the second lower wirings 82 of the first wiring group 80A and the number of the second lower wirings 82 of the second wiring group 80B is 0 to 1.

With regard to the first wiring group 80A (the second wiring group 80B) of the fourth arrangement region 105D and the first wiring group 80A (the second wiring group 80B) of the first arrangement region 105A (the second arrangement region 105B), the number of the first lower wirings 81 (the second lower wirings 82) may be equal to or different from each other. With regard to the first wiring group 80A (the second wiring group 80B) of the fourth arrangement region 105D and the first wiring group 80A (the second wiring group 80B) of the third arrangement region 105C, the number of the first lower wirings 81 (the second lower wirings 82) may be equal to or different from each other.

The fourth wiring unit U4 includes the fourth pad wiring 104 arranged in the fourth arrangement region 105D. The fourth pad wiring 104 has a plane area less than a plane area of the fourth arrangement region 105D. The fourth pad wiring 104 is arranged at intervals inward from peripheral edges of the fourth arrangement region 105D in plan view and is formed in a polygonal shape (in this embodiment, a quadrangular shape) having four sides parallel to the peripheral edges of the chip 2 (the peripheral edges of the fourth arrangement region 105D). The fourth pad wiring 104 may be formed in a hexagonal shape, an octagonal shape, a circular shape, etc.

The fourth pad wiring 104 is arranged on the first wiring group 80A and the second wiring group 80B adjacent in the first direction X across the inter-wiring region IWR. That is, the fourth pad wiring 104 is arranged on the inter-wiring region IWR and is led out onto the first wiring group 80A and the second wiring group 80B adjacent in the first direction X.

In other words, the fourth pad wiring 104 is arranged on the first active region 6A and the second active region 6B adjacent in the first direction X across the boundary region 7a. The fourth pad wiring 104 opposes the first wiring group 80A, the second wiring group 80B, and the inter-wiring region IWR across the second interlayer film 72 and is electrically disconnected from both the first wiring group 80A and the second wiring group 80B by the second interlayer film 72.

Specifically, the fourth pad wiring 104 has a first end portion on the one side in the first direction X and a second end portion on the other side in the first direction X. The first end portion of the fourth pad wiring 104 is arranged on the first wiring group 80A and overlaps at least one (in this embodiment, a plurality) of the first lower wirings 81 and at least one (in this embodiment, a plurality) of the second lower wirings 82 of the first wiring group 80A. The first end portion of the fourth pad wiring 104 is electrically disconnected from all of the first lower wirings 81 and all of the second lower wirings 82 of the first wiring group 80A by the second interlayer film 72.

The second end portion of the fourth pad wiring 104 is arranged on the second wiring group 80B and overlaps at least one (in this embodiment, a plurality) of the first lower wirings 81 and at least one (in this embodiment, a plurality) of the second lower wirings 82 of the second wiring group 80B. The second end portion of the fourth pad wiring 104 is electrically disconnected from all of the first lower wirings 81 and all of the second lower wirings 82 of the second wiring group 80B by the second interlayer film 72.

Directly below the fourth pad wiring 104, the number of the first lower wirings 81 of the first wiring group 80A, the number of the second lower wirings 82 of the first wiring group 80A, the number of the first lower wirings 81 of the second wiring group 80B, and the number of the second lower wirings 82 of the second wiring group 80B are all arbitrary.

For example, in the first wiring group 80A (the second wiring group 80B) directly below the fourth pad wiring 104, the number of the first lower wirings 81 (the second lower wirings 82) may be not less than 1 and not more than 1000. For example, in the first wiring group 80A (the second wiring group 80B) directly below the fourth pad wiring 104, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first wiring group 80A directly below the fourth pad wiring 104, it is preferable that the number of the second lower wirings 82 is substantially equal to the number of the first lower wirings 81. In the second wiring group 80B directly below the fourth pad wiring 104, it is preferable that the number of the second lower wirings 82 is substantially equal to the number of the first lower wirings 81.

Directly below the fourth pad wiring 104, it is preferable that the number of the first lower wirings 81 of the second wiring group 80B is substantially equal to the number of the first lower wirings 81 of the first wiring group 80A. Also, it is preferable that the number of the second lower wirings 82 of the second wiring group 80B is substantially equal to the number of the second lower wirings 82 of the first wiring group 80A.

In this embodiment, in both the first wiring group 80A and the second wiring group 80B, the plurality of second lower wirings 82 and the plurality of first lower wirings 81 are alternately arrayed. Also, the first lower wirings 81 and the second lower wirings 82 on the second wiring group 80B side respectively oppose the first lower wirings 81 and the second lower wirings 82 on the first wiring group 80A side in the first direction X.

Therefore, in the first wiring group 80A directly below the fourth pad wiring 104, a difference value between the number of the first lower wirings 81 and the number of the second lower wirings 82 is 0 to 1. Also, in the second wiring group 80B directly below the fourth pad wiring 104, a difference value between the number of the first lower wirings 81 and the number of the second lower wirings 82 is 0 to 1.

Also, directly below the fourth pad wiring 104, a difference value between the number of the first lower wirings 81 of the first wiring group 80A and the number of the first lower wirings 81 of the second wiring group 80B is 0 to 1. Also, a difference value between the number of the second lower wirings 82 of the first wiring group 80A and the number of the second lower wirings 82 of the second wiring group 80B is 0 to 1.

That is, in this embodiment, in the first wiring group 80A (the second wiring group 80B) directly below the fourth pad wiring 104, variation in the wiring resistance between the first lower wirings 81 and the second lower wirings 82 is prevented. Also, directly below the fourth pad wiring 104, variation in the wiring resistance between the first wiring group 80A and the second wiring group 80B is prevented.

In this embodiment, the fourth pad wiring 104 has a plane area smaller than the plane area of the first pad wiring 101. The plane area of the fourth pad wiring 104 is smaller than the plane area of the second pad wiring 102. Consequently, the number of the first lower wirings 81 and the number of the second lower wirings 82 hidden by the fourth pad wiring 104 are reduced as compared with the first pad wiring 101 (the second pad wiring 102). The plane area of the fourth pad wiring 104 may be substantially equal to or different from the plane area of the third pad wiring 103.

The fourth pad wiring 104 overlaps the third lower wiring 83 in a portion covering the inter-wiring region IWR. In this embodiment, the fourth pad wiring 104 overlaps both the first gate wiring 85 and the second gate wiring 86. The fourth pad wiring 104 opposes the third lower wiring 83 (the first gate wiring 85 and the second gate wiring 86) across the second interlayer film 72 and is electrically disconnected from the third lower wiring 83.

The fourth pad wiring 104 overlaps the fourth lower wiring 84 in the portion covering the inter-wiring region IWR and is electrically connected to the fourth lower wiring 84. In this embodiment, the fourth pad wiring 104 overlaps the first base wiring 88 and is electrically connected to the first base wiring 88. That is, the fourth pad wiring 104 is electrically connected to the first base wiring 88 positioned directly below. Consequently, a current path connecting the fourth lower wiring 84 and the fourth pad wiring 104 is shortened, and the wiring resistance between the fourth lower wiring 84 and the fourth pad wiring 104 is reduced.

The fourth wiring unit U4 includes at least one (in this embodiment, a plurality) of fourth upper via electrodes 157. Similarly to the first upper via electrode 117, each of the plurality of fourth upper via electrodes 157 includes the first electrode 119 and the second electrode 120. The description of the first electrode 119 and the second electrode 120 related to the first upper via electrode 117 is applied to the description of the first electrode 119 and the second electrode 120 related to the fourth upper via electrodes 157.

The plurality of fourth upper via electrodes 157 are interposed between the fourth lower wiring 84 and the fourth pad wiring 104 in the second interlayer film 72 and electrically connect the fourth pad wiring 104 to the fourth lower wiring 84. Consequently, the fourth pad wiring 104 is electrically connected to the base structure 55 via the fourth lower wiring 84.

The plurality of fourth upper via electrodes 157 are arrayed at intervals along the fourth lower wiring 84. The fourth upper via electrode 157 may be formed in a triangular shape, a quadrangular shape, a rectangular shape, a polygonal shape, a circular shape, or an elliptical shape in plan view. As a matter of course, the fourth upper via electrodes 157 may be formed as bands extending along the fourth lower wiring 84.

The fourth upper via electrodes 157 may be formed using the fourth pad wiring 104. In this case, the first electrode 119 of the fourth upper via electrode 157 is integrally formed with the first electrode 78 of the fourth pad wiring 104 and forms one electrode film together with the first electrode 78. Similarly, the second electrode 120 of the fourth upper via electrode 157 is integrally formed with the second electrode 79 of the fourth pad wiring 104 and forms one electrode with the second electrode 79.

The fourth wiring unit U4 includes a fifth routing wiring 158 routed from the first pad wiring 101 to the fourth arrangement region 105D. The fifth routing wiring 158 transmits, to the fourth arrangement region 105D, the first drain source potential applied to the first pad wiring 101. The fifth routing wiring 158 includes at least one (in this embodiment, one) fifth stem wiring 159 and at least one (in this embodiment, one) fifth branch wiring 160.

The fifth stem wiring 159 has a width less than the width of the first pad wiring 101 (the second pad wiring 102) in the first direction X and is led out as a band on the one side in the second direction Y from the first end portion of the first pad wiring 101 toward the fourth arrangement region 105D. The width of the fifth stem wiring 159 is larger than the width of the first lower wiring 81 (the second lower wiring 82).

The fifth stem wiring 159 covers the first wiring group 80A. In this embodiment, the fifth stem wiring 159 intersects (is orthogonal to) at least one (in this embodiment, a plurality) of the first lower wirings 81 and at least one (in this embodiment, a plurality) of the second lower wirings 82 of the first wiring group 80A in the fourth arrangement region 105D.

The fifth stem wiring 159 is led out to a region opposing the fourth pad wiring 104 in the first direction X. The fifth stem wiring 159 opposes the entire region of the fourth pad wiring 104 in the first direction X. The fifth stem wiring 159 intersects (is orthogonal to) one or a plurality of (preferably, all of) the first lower wirings 81 and one or a plurality of (preferably, all of) the second lower wirings 82 passing directly below the fourth pad wiring 104 in the first direction X.

In this embodiment, the fifth stem wiring 159 crosses a boundary portion between the first arrangement region 105A and the fourth arrangement region 105D and is connected to the first long wiring 110 (the first opposing portion 112) of the first wiring unit U1 (the first interconnect structure 108) in the first arrangement region 105A. The fifth stem wiring 159 may have a width substantially equal to the width of the first long wiring 110. The width of the fifth stem wiring 159 may be larger than the width of the first long wiring 110. The width of the fifth stem wiring 159 may be less than the width of the first long wiring 110.

The fifth stem wiring 159 is electrically connected to at least one (in this embodiment, a plurality) of the first lower wirings 81 of the first wiring group 80A in the fourth arrangement region 105D. Similarly to the first long wiring 110, etc., the fifth stem wiring 159 is electrically connected to the corresponding first lower wirings 81 via the plurality of first upper via electrodes 117.

The fifth stem wiring 159 is electrically connected to, of one or a plurality of (preferably, all of) the first lower wirings 81 covered with the fourth pad wiring 104, portions of the first lower wirings 81 exposed from the fourth pad wiring 104. On the other hand, the fifth stem wiring 159 is electrically disconnected from one or a plurality of (preferably, all of) the second lower wirings 82 passing directly below the fourth pad wiring 104.

The fifth branch wiring 160 is led out as a band in the first direction X from the fifth stem wiring 159 to a region between the second pad wiring 102 and the fourth pad wiring 104 in the fourth arrangement region 105D and covers the first wiring group 80A. The fifth branch wiring 160 is formed at intervals in the second direction Y from the second pad wiring 102 and the fourth pad wiring 104 and opposes the second pad wiring 102 and the fourth pad wiring 104 in the second direction Y.

The fifth branch wiring 160 may have a width substantially equal to the width of the fifth stem wiring 159. The width of the fifth branch wiring 160 may be larger than the width of the fifth stem wiring 159. The width of the fifth branch wiring 160 may be less than the width of the fifth stem wiring 159. The width of the fifth branch wiring 160 is larger than the width of the first lower wiring 81 (the second lower wiring 82).

The fifth branch wiring 160 covers at least one (in this embodiment, a plurality) of the first lower wirings 81 and at least one (in this embodiment, a plurality) of the second lower wirings 82 of the first wiring group 80A. The fifth branch wiring 160 crosses the inter-wiring region IWR in the first direction X from above the first wiring group 80A and is led out onto the second wiring group 80B. The fifth branch wiring 160 covers at least one (in this embodiment, a plurality) of the first lower wirings 81 and at least one (in this embodiment, a plurality) of the second lower wirings 82 of the second wiring group 80B.

The fifth branch wiring 160 is electrically connected to at least one (in this embodiment, a plurality) of the first lower wirings 81 of the first wiring group 80A. Also, the fifth branch wiring 160 is electrically connected to at least one (in this embodiment, a plurality) of the first lower wirings 81 of the second wiring group 80B. Similarly to the first pad wiring 101, etc., the fifth branch wiring 160 is electrically connected to the corresponding first lower wirings 81 via the plurality of first upper via electrodes 117.

The fifth branch wiring 160 overlaps the third lower wiring 83 in a portion covering the inter-wiring region IWR. In this embodiment, the fifth branch wiring 160 overlaps both the first gate wiring 85 and the second gate wiring 86. The fifth branch wiring 160 opposes the third lower wiring 83 (the first gate wiring 85 and the second gate wiring 86) across the second interlayer film 72 and is electrically disconnected from the third lower wiring 83.

The fifth branch wiring 160 overlaps the fourth lower wiring 84 in the portion covering the inter-wiring region IWR. In this embodiment, the fifth branch wiring 160 overlaps the first base wiring 88. The fifth branch wiring 160 opposes the fourth lower wiring 84 (the first base wiring 88) across the second interlayer film 72 and is electrically disconnected from the fourth lower wiring 84.

The fourth wiring unit U4 includes a sixth routing wiring 162 routed from the second pad wiring 102 to the fourth arrangement region 105D. The sixth routing wiring 162 transmits, to the fourth arrangement region 105D, the second drain source potential applied to the second pad wiring 102. The sixth routing wiring 162 includes at least one (in this embodiment, one) sixth stem wiring 163 and at least one (in this embodiment, one) sixth branch wiring 164.

The sixth stem wiring 163 has a width less than the width of the second pad wiring 102 (the first pad wiring 101) in the first direction X and is led out as a band on the other side in the second direction Y from the second end portion of the second pad wiring 102 toward the fourth arrangement region 105D. The width of the sixth stem wiring 163 is larger than the width of the second lower wiring 82 (the first lower wiring 81).

The sixth stem wiring 163 covers the second wiring group 80B. That is, the sixth stem wiring 163 covers, as a connection target, the second wiring group 80B different from the first wiring group 80A which is a connection target of the fifth stem wiring 159. In this embodiment, the sixth stem wiring 163 intersects (is orthogonal to) at least one (in this embodiment, a plurality) of the first lower wirings 81 and at least one (in this embodiment, a plurality) of the second lower wirings 82 of the second wiring group 80B in the fourth arrangement region 105D.

The sixth stem wiring 163 is formed at intervals in the first direction X from the fifth branch wiring 160 and opposes the fifth branch wiring 160 in the first direction X. The sixth stem wiring 163 is led out to a region opposing the fourth pad wiring 104 in the first direction X. The sixth stem wiring 163 opposes the entire region of the fourth pad wiring 104 in the first direction X.

The sixth stem wiring 163 opposes the fifth stem wiring 159 in the first direction X across the fourth pad wiring 104 and extends substantially parallel to the fifth stem wiring 159. The sixth stem wiring 163 intersects (is orthogonal to) one or a plurality of (preferably, all of) the first lower wirings 81 and one or a plurality of (preferably, all of) the second lower wirings 82 passing directly below the fourth pad wiring 104 in the first direction X.

In this embodiment, the sixth stem wiring 163 crosses the boundary portion between the first arrangement region 105A and the fourth arrangement region 105D and is connected to the second long wiring 114 (the second opposing portion 116) of the first wiring unit U1 (the first interconnect structure 108) in the first arrangement region 105A. The sixth stem wiring 163 may have a width substantially equal to the width of the second long wiring 114. The width of the sixth stem wiring 163 may be larger than the width of the second long wiring 114. The width of the sixth stem wiring 163 may be less than the width of the second long wiring 114. It is preferable that the width of the sixth stem wiring 163 is substantially equal to the width of the fifth stem wiring 159.

The sixth stem wiring 163 is electrically connected to at least one (in this embodiment, a plurality) of the second lower wirings 82 of the second wiring group 80B in the fourth arrangement region 105D. Similarly to the second long wiring 114, etc., the sixth stem wiring 163 is electrically connected to the corresponding second lower wirings 82 via the plurality of second upper via electrodes 118.

The sixth stem wiring 163 is electrically connected to, of one or a plurality of (preferably, all of) the second lower wirings 82 covered with the fifth branch wiring 160, portions of the second lower wirings 82 exposed from the fifth branch wiring 160. On the other hand, the sixth stem wiring 163 is electrically disconnected from one or a plurality of (preferably, all of) the first lower wirings 81 passing directly below the fifth branch wiring 160. The sixth stem wiring 163 forms a current path of the drain source current Ids together with the fifth branch wiring 160 opposing (closely opposing) the sixth stem wiring 163 in the first direction X.

The sixth stem wiring 163 is electrically connected to, of one or a plurality of (preferably, all of) the second lower wirings 82 covered with the fourth pad wiring 104, portions of the second lower wirings 82 exposed from the fourth pad wiring 104. On the other hand, the sixth stem wiring 163 is electrically disconnected from one or a plurality of (preferably, all of) the first lower wirings 81 passing directly below the fourth pad wiring 104.

Although not specifically shown, the sixth stem wiring 163 is electrically connected to, of one or a plurality of (preferably, all of) the second lower wirings 82 covered with the first stem wiring 132 (the second wiring unit U2) opposing (closely opposing) the sixth stem wiring in the first direction X, portions of the second lower wirings 82 exposed from the first stem wiring 132.

On the other hand, the sixth stem wiring 163 is electrically disconnected from one or a plurality of (preferably, all of) the first lower wirings 81 passing directly below the first stem wiring 132. Consequently, the sixth stem wiring 163 forms a current path of the drain source current Ids together with the first stem wiring 132.

The sixth branch wiring 164 is led out as a band in the first direction X from the sixth stem wiring 163 to a region between the first pad wiring 101 and the fourth pad wiring 104 in the fourth arrangement region 105D and covers the second wiring group 80B. The sixth branch wiring 164 is formed at intervals in the second direction Y from the first pad wiring 101 and the fourth pad wiring 104 and opposes the first pad wiring 101 and the fourth pad wiring 104 in the second direction Y.

The sixth branch wiring 164 may have a width substantially equal to the width of the sixth stem wiring 163. The width of the sixth branch wiring 164 may be larger than the width of the sixth stem wiring 163. The width of the sixth branch wiring 164 may be less than the width of the sixth stem wiring 163. It is preferable that the width of the sixth branch wiring 164 is substantially equal to the width of the fifth branch wiring 160. The width of the sixth branch wiring 164 is larger than the width of the second lower wiring 82 (the first lower wiring 81).

The sixth branch wiring 164 covers at least one (in this embodiment, a plurality) of the first lower wirings 81 and at least one (in this embodiment, a plurality) of the second lower wirings 82 of the second wiring group 80B. The sixth branch wiring 164 crosses the inter-wiring region IWR from above the second wiring group 80B and is led out onto the first wiring group 80A. The sixth branch wiring 164 covers at least one (in this embodiment, a plurality) of the first lower wirings 81 and at least one (in this embodiment, a plurality) of the second lower wirings 82 of the first wiring group 80A.

The sixth branch wiring 164 is formed at intervals in the first direction X from the fifth stem wiring 159 on the first wiring group 80A and opposes the fifth stem wiring 159 in the first direction X. It is preferable that, in the first direction X, a length of the sixth branch wiring 164 is substantially equal to a length of the fifth branch wiring 160.

The sixth branch wiring 164 is electrically connected to at least one (in this embodiment, a plurality) of the second lower wirings 82 of the first wiring group 80A. Also, the sixth branch wiring 164 is electrically connected to at least one (in this embodiment, a plurality) of the second lower wirings 82 of the second wiring group 80B. Similarly to the second pad wiring 102, etc., the sixth branch wiring 164 is electrically connected to the corresponding second lower wirings 82 via the plurality of second upper via electrodes 118.

The sixth branch wiring 164 is electrically connected to, of one or a plurality of the second lower wirings 82 covered with the fifth stem wiring 159, portions of the second lower wirings 82 exposed from the fifth stem wiring 159. On the other hand, the sixth branch wiring 164 is electrically disconnected from one or a plurality of (preferably, all of) the first lower wirings 81 passing directly below the fifth stem wiring 159. The sixth branch wiring 164 forms a current path of the drain source current Ids together with the fifth stem wiring 159 opposing (closely opposing) the sixth branch wiring 164 in the first direction X.

The sixth branch wiring 164 overlaps the third lower wiring 83 in a portion covering the inter-wiring region IWR. In this embodiment, the sixth branch wiring 164 overlaps both the first gate wiring 85 and the second gate wiring 86. The sixth branch wiring 164 opposes the third lower wiring 83 (the first gate wiring 85 and the second gate wiring 86) across the second interlayer film 72 and is electrically disconnected from the third lower wiring 83.

The sixth branch wiring 164 overlaps the fourth lower wiring 84 in the portion covering the inter-wiring region IWR. In this embodiment, the sixth branch wiring 164 overlaps the first base wiring 88. The sixth branch wiring 164 opposes the fourth lower wiring 84 (the first base wiring 88) across the second interlayer film 72 and is electrically disconnected from the fourth lower wiring 84.

The fourth wiring unit U4 includes a seventh interconnect structure 165 formed in a region between the second pad wiring 102 and the fifth branch wiring 160. The seventh interconnect structure 165 has the same configuration and function as those of the first interconnect structure 108 except that an arrangement location differs. Similarly to the first interconnect structure 108, the seventh interconnect structure 165 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the fifth stem wiring 159 as at least one (in this embodiment, one) of the first long wirings 110 that are relatively long and at least one (in this embodiment, a plurality) of the first short wirings 111 that are shorter than the fifth stem wiring 159.

The plurality of first lead-out wirings 109 are led out in the second direction Y from the fifth branch wiring 160 toward the second pad wiring 102. The plurality of first lead-out wirings 109 are electrically connected to at least one of the first lower wirings 81 of the first wiring group 80A and/or at least one of the first lower wirings 81 of the second wiring group 80B in the region between the second pad wiring 102 and the fifth branch wiring 160.

Similarly to the first interconnect structure 108, the plurality of second lead-out wirings 113 include the sixth stem wiring 163 as at least one (in this embodiment, one) of the second long wirings 114 that are relatively long and at least one (in this embodiment, a plurality) of the second short wirings 115 that are shorter than the sixth stem wiring 163.

The plurality of second lead-out wirings 113 are led out in the second direction Y from the second pad wiring 102 toward the fifth branch wiring 160. The plurality of second lead-out wirings 113 are electrically connected to at least one of the second lower wirings 82 of the first wiring group 80A and/or at least one of the second lower wirings 82 of the second wiring group 80B in the region between the second pad wiring 102 and the fifth branch wiring 160.

As described above, in the seventh interconnect structure 165, a current path of the drain source current Ids via the plurality of first lead-out wirings 109 and the plurality of second lead-out wirings 113 is formed in the region between the second pad wiring 102 and the fifth branch wiring 160.

The seventh interconnect structure 165 may have a configuration similar to any one of the first interconnect structures 108 according to the first to eighth layout examples. In this case, a specific configuration of the seventh interconnect structure 165 is obtained by replacing the “first pad wiring 101” with the “fifth branch wiring 160” in the description of the first interconnect structure 108 described above.

The fourth wiring unit U4 includes an eighth interconnect structure 166 formed in a region between the first pad wiring 101 and the sixth branch wiring 164. The eighth interconnect structure 166 has the same configuration and function as those of the first interconnect structure 108 except that an arrangement location differs. Similarly to the first interconnect structure 108, the eighth interconnect structure 166 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the fifth stem wiring 159 as at least one (in this embodiment, one) of the first long wirings 110 that are relatively long and at least one (in this embodiment, a plurality) of the first short wirings 111 that are shorter than the fifth stem wiring 159.

The plurality of first lead-out wirings 109 are led out in the second direction Y from the first pad wiring 101 toward the sixth branch wiring 164. The plurality of first lead-out wirings 109 are electrically connected to at least one of the first lower wirings 81 of the first wiring group 80A and/or at least one of the first lower wirings 81 of the second wiring group 80B in the region between the first pad wiring 101 and the sixth branch wiring 164.

Similarly to the first interconnect structure 108, the plurality of second lead-out wirings 113 include the sixth stem wiring 163 as at least one (in this embodiment, one) of the second long wirings 114 that are relatively long and at least one (in this embodiment, a plurality) of the second short wirings 115 that are shorter than the sixth stem wiring 163.

The plurality of second lead-out wirings 113 are led out in the second direction Y from the sixth branch wiring 164 toward the first pad wiring 101. The plurality of second lead-out wirings 113 are electrically connected to at least one of the second lower wirings 82 of the first wiring group 80A and/or at least one of the second lower wirings 82 of the second wiring group 80B in the region between the first pad wiring 101 and the sixth branch wiring 164.

As described above, in the eighth interconnect structure 166, a current path of the drain source current Ids via the plurality of first lead-out wirings 109 and the plurality of second lead-out wirings 113 is formed in the region between the first pad wiring 101 and the sixth branch wiring 164.

The eighth interconnect structure 166 may have a configuration similar to any one of the first interconnect structures 108 according to the first to eighth layout examples. In this case, a specific configuration of the eighth interconnect structure 166 is obtained by replacing the “second pad wiring 102” with the “sixth branch wiring 164” in the description of the first interconnect structure 108 described above.

With reference again to FIG. 15, the second layer wiring 75 includes a first side wiring 167 and a second side wiring 168. The first side wiring 167 applies the first drain source potential to the first lower wirings 81. The second side wiring 168 applies the second drain source potential to the second lower wirings 82.

The first side wiring 167 covers an end portion of the outermost wiring group 80 (that is, the first wiring group 80A) positioned on the one side in the first direction X. The first side wiring 167 has a width less than the width of the first pad wiring 101 (the second pad wiring 102) in the first direction X. As a matter of course, the width of the first side wiring 167 may be larger than the width of the first pad wiring 101 (the second pad wiring 102). The width of the first side wiring 167 is larger than the width of the first lower wiring 81 (the second lower wiring 82).

In this embodiment, the first side wiring 167 extends as a band in the second direction Y along the first wiring group 80A and opposes at least one (in this embodiment, a plurality) of the first pad wirings 101, at least one (in this embodiment, a plurality) of the second pad wirings 102, and the fourth pad wiring 104 in the first direction X. In this embodiment, the first side wiring 167 opposes the entire region of the plurality of second pad wirings 102 in the first direction X.

In this embodiment, the first side wiring 167 is connected to the first lead-out wiring 109 (the first long wiring 110) of the first wiring unit U1, the fifth routing wiring 158 (the fifth stem wiring 159) of the fourth wiring unit U4, etc., in the first direction X and is electrically connected to the first pad wiring 101 via these wirings.

The first side wiring 167 intersects (is orthogonal to) at least one (in this embodiment, a plurality) of the first lower wirings 81 and at least one (in this embodiment, a plurality) of the second lower wirings 82 of the first wiring group 80A. The first side wiring 167 is electrically connected to at least one (in this embodiment, a plurality) of the first lower wirings 81 of the first wiring group 80A.

The first side wiring 167 is electrically connected to, of the plurality of first lower wirings 81 covered with the plurality of first pad wirings 101, the plurality of second pad wirings 102, and the fourth pad wiring 104, portions of the first lower wirings 81 exposed from the plurality of first pad wirings 101, the plurality of second pad wirings 102, and the fourth pad wiring 104.

On the other hand, the first side wiring 167 is electrically disconnected from one or a plurality of (preferably, all of) the second lower wirings 82 passing directly below the plurality of first pad wirings 101, the plurality of second pad wirings 102, and fourth pad wiring 104 among the plurality of second lower wirings 82. Consequently, the first side wiring 167 forms a current path of the drain source current Ids together with the plurality of second pad wirings 102 opposing (closely opposing) the first side wiring 167 in the first direction X.

The first side wiring 167 increases the current path (a connection area) with respect to at least one (in this embodiment, a plurality) of the first lower wirings 81 at an end portion of the first wiring group 80A. Similarly to the first pad wiring 101, etc., the first side wiring 167 is electrically connected to the corresponding first lower wirings 81 via the plurality of first upper via electrodes 117.

The second side wiring 168 covers an end portion of the outermost wiring group 80 (that is, the sixth wiring group 80F) positioned on the other side in the first direction X. The second side wiring 168 has a width less than the width of the first pad wiring 101 (the second pad wiring 102) in the first direction X. As a matter of course, the width of the second side wiring 168 may be larger than the width of the first pad wiring 101 (the second pad wiring 102). The width of the second side wiring 168 is larger than the width of the first lower wiring 81 (the second lower wiring 82).

In this embodiment, the second side wiring 168 extends as a band in the second direction Y along the sixth wiring group 80F and opposes at least one (in this embodiment, a plurality) of the first pad wirings 101, at least one (in this embodiment, a plurality) of the second pad wirings 102, and the third pad wiring 103 in the first direction X. In this embodiment, the second side wiring 168 opposes the entire region of the plurality of first pad wirings 101 in the first direction X.

In this embodiment, the second side wiring 168 is connected to the second lead-out wiring 113 (the second long wiring 114) of the first wiring unit U1, the fourth routing wiring 148 (the fourth stem wiring 149) of the third wiring unit U3, etc., in the first direction X and is electrically connected to the second pad wiring 102 via these wirings.

The second side wiring 168 intersects (is orthogonal to) at least one (in this embodiment, a plurality) of the first lower wirings 81 and at least one (in this embodiment, a plurality) of the second lower wirings 82 of the sixth wiring group 80F. The second side wiring 168 is electrically connected to at least one (in this embodiment, a plurality) of the second lower wirings 82 of the sixth wiring group 80F.

The second side wiring 168 is electrically connected to, of the plurality of second lower wirings 82 covered with the plurality of first pad wirings 101, the plurality of second pad wirings 102, and the third pad wiring 103, portions of the second lower wirings 82 exposed from the plurality of first pad wirings 101, the plurality of second pad wirings 102, and the third pad wiring 103.

On the other hand, the second side wiring 168 is electrically disconnected from one or a plurality of (preferably, all of) the first lower wirings 81 passing directly below the plurality of first pad wirings 101, the plurality of second pad wirings 102, and third pad wiring 103. Consequently, the second side wiring 168 forms a current path of the drain source current Ids together with the plurality of first pad wirings 101 opposing (closely opposing) the second side wiring 168 in the first direction X.

The second side wiring 168 increases the current path (a connection area) with respect to at least one (in this embodiment, a plurality) of the second lower wirings 82 at an end portion of the sixth wiring group 80F. Similarly to the second pad wiring 102, etc., the second side wiring 168 is electrically connected to the corresponding second lower wirings 82 via the plurality of second upper via electrodes 118.

With reference again to FIG. 2, the semiconductor device 1A includes an upper insulation film 170 that covers the second layer wiring 75 (the first to fourth wiring units U1 to U4) on the interlayer film 70 (the second interlayer film 72). The upper insulation film 170 has a plurality of pad openings 171. The plurality of pad openings 171 selectively expose the plurality of pad wirings 101 to 104, respectively.

The upper insulation film 170 may have a single layer structure constituted of an inorganic insulation film or an organic insulation film. The upper insulation film 170 may have a laminated structure including an inorganic insulation film and an organic insulation film laminated in that order from the interlayer film 70 (the second interlayer film 72) side. The inorganic insulation film may include at least one of a silicon oxide film, a silicon nitride film, and a silicon oxynitride film. The inorganic insulation film preferably contains an insulating material different from the interlayer film 70 (the second interlayer film 72). The inorganic insulation film preferably includes the silicon nitride film.

The organic insulation film may include a negative type or positive type of photosensitive resin film. The organic insulation film may include at least one of a polyimide film, a polyamide film, or a polybenzoxazole film. The organic insulation film preferably has a thickness larger than a thickness of the inorganic insulation film.

With reference to FIGS. 1 and 2, the semiconductor device 1A includes a plurality of pad electrodes 181 to 184 respectively arranged on a plurality of pad wirings 101 to 104. The plurality of pad electrodes 181 to 184 are terminal electrodes that are physically and electrically connected to a wiring of a mounting substrate, etc., which is a connection target. The plurality of pad electrodes 181 to 184 may be referred to as “pad terminals,” “terminal electrodes,” “external terminals,” etc. The plurality of pad electrodes 181 to 184 include the first pad electrode 181, the second pad electrode 182, the third pad electrode 183, and the fourth pad electrode 184.

The first pad electrode 181 is a terminal that applies, to the first pad wiring 101, the first drain source potential applied from the outside. The second pad electrode 182 is a terminal that applies, to the second pad wiring 102, the second drain source potential applied from the outside. The third pad electrode 183 is a terminal that applies, to third pad wiring 103, the gate potential applied from the outside. The fourth pad electrode 184 is a terminal that applies, to fourth pad wiring 104, the base potential applied from the outside.

The first pad electrode 181 may be referred to as a “first drain source pad electrode (terminal).” The second pad electrode 182 may be referred to as a “second drain source pad electrode (terminal).” The third pad electrode 183 may be referred to as a “gate pad electrode (terminal).” The fourth pad electrode 184 may be referred to as a “base pad electrode (terminal).”

The number of the first to fourth pad electrodes 181 to 184 is adjusted depending on the number of the first to fourth pad wirings 101 to 104. In this embodiment, the semiconductor device 1A includes the ten first pad electrodes 181, the ten second pad electrodes 182, the one third pad electrode 183, and the one fourth pad electrode 184.

The plurality of first pad electrodes 181 are respectively arranged on the plurality of first pad wirings 101, the plurality of second pad electrodes 182 are respectively arranged on the plurality of second pad wirings 102, the third pad electrode 183 is arranged on the third pad wiring 103, and the fourth pad electrode 184 is arranged on the fourth pad wiring 104.

Each of the plurality of pad electrodes 181 to 184 includes a base electrode film 185 and a low-melting-point metal 186 formed in that order from the plurality of pad wirings 101 to 104 side. The plurality of base electrode films 185 respectively cover, in a film shape, the plurality of pad wirings 101 to 104 in the corresponding pad openings 171, and are respectively electrically connected to the plurality of pad wirings 101 to 104.

Each of the plurality of base electrode films 185 has an overlapping portion led out from the corresponding pad opening 171 onto the upper insulation film 170. The plurality of base electrode films 185 may include at least one of a Ti film, a TiN film, a Cu film, an Au film, an Ni film, and an Al film.

The plurality of low-melting-point metals 186 are respectively arranged on the corresponding base electrode films 185. The plurality of low-melting-point metals 186 are respectively electrically connected to the plurality of pad wirings 101 to 104 via the corresponding base electrode films 185 in the pad openings 171. The plurality of low-melting-point metals 186 cover the overlapping portions of the corresponding base electrode films 185 outside the pad openings 171. The plurality of low-melting-point metals 186 project in a hemispherical shape. The plurality of low-melting-point metals 186 may include solder.

In the semiconductor device 1A, the first drain source potential (a high potential) is to be applied to the plurality of first pad wirings 101 (the first pad electrodes 181), the second drain source potential (a low potential) is to be applied to the plurality of second pad wirings 102 (the second pad electrodes 182), the gate potential is to be applied to the third pad wiring 103 (the third pad electrode 183), and the base potential is to be applied to the fourth pad wiring 104 (the fourth pad electrode 184).

The first drain source potential is to be applied from the plurality of first pad wirings 101 to the plurality of first drain source regions 28 via the plurality of first lower wirings 81, the second drain source potential is to be applied from the plurality of second pad wirings 102 to the plurality of second drain source regions 29 via the plurality of second lower wirings 82, the gate potential is to be applied from the third pad wiring 103 to the plurality of gate structures 12 via the third lower wiring 83, and the base potential is to be applied from the fourth pad wiring 104 to the base structure 55 via the fourth lower wiring 84.

Consequently, the plurality of gate structures 12 are controlled to an ON state, and the drain source current Ids is generated. The drain source current Ids flows from the plurality of first pad wirings 101 via the plurality of first lower wirings 81 to the plurality of first drain source regions 28. The drain source current Ids flows from the plurality of first drain source regions 28 via the drift layer 9 and the plurality of first impurity regions 51 to the plurality of second drain source regions 29. The drain source current Ids flows from the plurality of second drain source regions 29 via the plurality of second lower wirings 82 to the plurality of second pad wirings 102.

In this embodiment, an example is described, in which the first drain source potential is a high potential, and the second drain source potential is a low potential. However, the semiconductor device 1A has an electrically symmetrical configuration with respect to the first drain source potential and the second drain source potential. Therefore, the first drain source potential may be a low potential and the second drain source potential may be a high potential.

In this case, the drain source current Ids flows from the second pad wirings 102 toward the first pad wirings 101. That is, the semiconductor device 1A is a bidirectional device capable of causing the drain source current Ids to flow in both directions between the first pad wirings 101 and the second pad wirings 102.

As described above, the semiconductor device 1A includes the wiring groups 80, the first pad wirings 101, the second pad wirings 102, at least one of the first lead-out wirings 109, and at least one of the second lead-out wirings 113. The wiring group 80 includes the plurality of first lower wirings 81 and the plurality of second lower wirings 82 arrayed as stripes extending in the first direction X. The first pad wiring 101 is arranged at least one of the first lower wirings 81. The second pad wiring 102 is arranged on at least one of the second lower wiring 82 at intervals from the first pad wiring 101 in the second direction Y.

The first lead-out wiring 109 is led out in the second direction Y from the first pad wiring 101 and is electrically connected to at least one of the first lower wirings 81 in the region between the first pad wiring 101 and the second pad wiring 102. The second lead-out wiring 113 is led out in the second direction Y from the second pad wiring 102 and is electrically connected to at least one of the second lower wirings 82 in the region between the first pad wiring 101 and the second pad wiring 102.

According to this configuration, the semiconductor device 1A having a novel wiring structure is provided. In the semiconductor device 1A, the first lower wiring 81 positioned on the second pad wiring 102 side with respect to the first pad wiring 101 is electrically connected to the first pad wiring 101 by the first lead-out wiring 109. Consequently, a wiring distance connecting the first lower wirings 81 on the second pad wiring 102 side to the first pad wiring 101 is shortened. As a result, the wiring resistance caused by the first lower wiring 81 on the second pad wiring 102 side is reduced.

Similarly, the second lower wiring 82 positioned on the first pad wiring 101 side with respect to the second pad wiring 102 is electrically connected to the second pad wiring 102 by the second lead-out wiring 113. Consequently, a wiring distance connecting the second lower wirings 82 on the first pad wiring 101 side to the second pad wiring 102 is shortened. As a result, the wiring resistance caused by the second lower wiring 82 on the first pad wiring 101 side is reduced.

Such a configuration is effective in reducing ON-resistance between the first pad wiring 101 and the second pad wiring 102 in a case where a voltage is applied between the first pad wiring 101 and the second pad wiring 102 and a current is generated between the first pad wiring 101 and the second pad wiring 102.

The wiring group 80 preferably includes the plurality of first lower wirings 81 and the plurality of second lower wirings 82 alternately arrayed in the second direction Y. According to this configuration, in the wiring group 80, electrical symmetry of the plurality of first lower wirings 81 and the plurality of second lower wirings 82 is improved. Consequently, in the wiring group 80, variation in the wiring resistance between the first lower wiring 81 and the second lower wiring 82 is prevented.

It is preferable that the first pad wiring 101 is electrically connected to at least one of the first lower wirings 81. According to this configuration, the wiring distance connecting the first lower wirings 81 positioned directly below the first pad wiring 101 to the first pad wiring 101 is shortened. Therefore, the wiring resistance caused by the first lower wiring 81 directly below the first pad wiring 101 is reduced.

It is preferable that the second pad wiring 102 is electrically connected to at least one of the second lower wirings 82. According to this configuration, the wiring distance connecting the second lower wirings 82 positioned directly below the second pad wiring 102 to the second pad wiring 102 is shortened. Therefore, the wiring resistance caused by the second lower wiring 82 directly below the second pad wiring 102 is reduced.

The first pad wiring 101 may overlap at least one of the first lower wirings 81 and at least one of the second lower wirings 82. The second pad wiring 102 may overlap at least one of the first lower wirings 81 and at least one of the second lower wirings 82. The first pad wiring 101 may overlap a plurality of the first lower wirings 81 and a plurality of the second lower wirings 82. The second pad wiring 102 may overlap a plurality of the first lower wirings 81 and a plurality of the second lower wirings 82.

It is preferable that at least one of the first lead-out wirings 109 crosses the intermediate portion (the boundary portion 107) between the first pad wiring 101 and the second pad wiring 102. According to this configuration, the wiring distance connecting the first lower wirings 81, positioned closer to the second pad wiring 102 side than to the intermediate portion (the boundary portion 107), to the first pad wiring 101 is shortened.

It is preferable that at least one of the second lead-out wirings 113 crosses the intermediate portion (the boundary portion 107) between the first pad wiring 101 and the second pad wiring 102. According to this configuration, the wiring distance connecting the second lower wirings 82, positioned closer to first pad wiring 101 side than to the intermediate portion (the boundary portion 107), to the second pad wiring 102 is shortened.

It is preferable that at least one of the second lead-out wirings 113 opposes at least one of the first lead-out wirings 109 in the first direction X. According to this configuration, the first lead-out wirings 109 can be electrically connected to, of the first lower wirings 81 covered with the second lead-out wiring 113, portions of the first lower wirings 81 exposed from the second lead-out wiring 113. Therefore, the wiring distance connecting the first lower wirings 81 partially hidden by the second lead-out wiring 113 to the first pad wiring 101 is shortened.

Similarly, the second lead-out wiring 113 can be electrically connected to, of the second lower wirings 82 covered with the first lead-out wiring 109, portions of the second lower wirings 82 exposed from the first lead-out wiring 109. Therefore, the wiring distance connecting the second lower wirings 82 partially hidden by the first lead-out wiring 109 to the second pad wiring 102 is shortened.

Also, according to this configuration, in a case where a current is generated between the first pad wiring 101 and the second pad wiring 102, a relatively short current path via the first lower wiring 81 and the second lower wiring 82 can be formed between the first lead-out wiring 109 and the second lead-out wiring 113. Such a configuration is effective in reducing the ON-resistance.

It is preferable that at least one of the first lead-out wirings 109 opposes the second pad wiring 102 in the first direction X. According to this configuration, the first lead-out wiring 109 can be electrically connected to, of the first lower wirings 81 covered with the second pad wiring 102, portions of the first lower wirings 81 exposed from the second pad wiring 102. Therefore, the wiring distance connecting the first lower wirings 81 partially hidden by the second pad wiring 102 to the first pad wiring 101 is shortened.

Also, according to this configuration, in the case where a current is generated between the first pad wiring 101 and the second pad wiring 102, a relatively short current path via the first lower wiring 81 and the second lower wiring 82 can be formed between the second pad wiring 102 and the first lead-out wiring 109. Such a configuration is effective in reducing the ON-resistance.

It is preferable that at least one of the first lead-out wirings 109 opposes the second pad wiring 102 in the second direction Y. In this configuration, the first lead-out wiring 109 may overlap at least one of the first lower wirings 81 and at least one of the second lower wirings 82 in the region between the first pad wiring 101 and the second pad wiring 102.

It is preferable that at least one of the second lead-out wirings 113 opposes the first pad wiring 101 in the first direction X. According to this configuration, the second lead-out wiring 113 can be electrically connected to, of the second lower wirings 82 covered with the first pad wiring 101, portions of the second lower wirings 82 exposed from the first pad wiring 101. Therefore, the wiring distance connecting the second lower wirings 82 partially hidden by the first pad wiring 101 to the second pad wiring 102 is shortened.

Also, according to this configuration, in the case where a current is generated between the first pad wiring 101 and the second pad wiring 102, a relatively short current path via the first lower wiring 81 and the second lower wiring 82 can be formed between the first pad wiring 101 and the second lead-out wiring 113. Such a configuration is effective in reducing the ON-resistance.

It is preferable that at least one of the second lead-out wirings 113 opposes the first pad wiring 101 in the second direction Y. In this configuration, the second lead-out wiring 113 may overlap at least one of the first lower wirings 81 and at least one of the second lower wirings 82 in the region between the first pad wiring 101 and the second pad wiring 102.

It is preferable that the plurality of first lead-out wirings 109 are led out from the first pad wiring 101. According to this configuration, the wiring distance connecting the first lower wirings 81 on the second pad wiring 102 side to the first pad wiring 101 is shortened by the plurality of first lead-out wirings 109.

It is preferable that the plurality of second lead-out wirings 113 are led out from the second pad wiring 102. According to this configuration, the wiring distance connecting the second lower wirings 82 on the first pad wiring 101 side to the second pad wiring 102 is shortened by the plurality of second lead-out wirings 113.

In this case, it is preferable that the plurality of second lead-out wirings 113 and the plurality of first lead-out wirings 109 are alternately arrayed in the first direction X. According to this configuration, both the wiring distance connecting the first lower wirings 81 on the second pad wiring 102 side to the first pad wiring 101, and the wiring distance connecting the second lower wirings 82 on the first pad wiring 101 side to the second pad wiring 102 are efficiently shortened. Also, according to this configuration, a relatively short current path via the first lower wirings 81 and the second lower wirings 82 can be formed between the plurality of first lead-out wirings 109 and the plurality of second lead-out wirings 113. Such a configuration is effective in reducing the ON-resistance.

The semiconductor device 1A preferably includes the first interlayer film 71 and the second interlayer film 72 laminated on the first interlayer film 71. In this case, it is preferable that the plurality of first lower wirings 81 and the plurality of second lower wirings 82 are arranged on the first interlayer film 71, and the first pad wiring 101, the second pad wiring 102, the first lead-out wirings 109, and the second lead-out wirings 113 are arranged on the second interlayer film 72.

According to this configuration, the first lower wirings 81, the second lower wirings 82, the first pad wiring 101, the second pad wiring 102, the first lead-out wirings 109, and the second lead-out wirings 113 can be appropriately arrayed in a three-dimensionally intersection arrangement by using the first interlayer film 71 and the second interlayer film 72.

The semiconductor device 1A preferably includes the first pad electrodes 181 arranged on the first pad wirings 101 and the second pad electrodes 182 arranged on the second pad wirings 102. According to this configuration, the wiring distance connecting the first lower wirings 81 on the second pad wirings 102 side to the first pad electrode 181 is shortened, and the wiring distance connecting the second lower wirings 82 on the first pad wirings 101 side to the second pad electrode 182 is shortened.

The semiconductor device 1A preferably includes the chip 2 and the device structure formed in the chip 2. In this case, the device structure includes a first application end to which the first potential is to be applied and a second application end to which the second potential different from the first potential is to be applied. The plurality of first lower wirings 81 are electrically connected to the first application end on the chip 2, and the plurality of second lower wirings 82 are electrically connected to the second application end in the chip 2. According to this configuration, the ON-resistance via the device structure between the first pad wiring 101 and the second pad wiring 102 is reduced.

In this embodiment, the semiconductor device 1A includes the drain source common transistor structure Tr as an example of the device structure. The transistor structure Tr has the first drain source region 28 as the first application end and the second drain source region 29 as the second application end. The plurality of first lower wirings 81 are electrically connected to the first drain source region 28, and the plurality of second lower wirings 82 are electrically connected to the second drain source region 29. According to this configuration, the ON-resistance via the transistor structure Tr is reduced between the first pad wiring 101 and the second pad wiring 102.

From another viewpoint, the semiconductor device 1A includes the one and the other wiring groups 80, the first pad wiring 101, and the second pad wiring 102. The one and the other wiring groups 80 are arranged at intervals in the first direction X. Each of the one and the other wiring groups 80 includes the plurality of first lower wirings 81 and the plurality of second lower wirings 82 arrayed as stripes extending in the first direction X.

The first pad wiring 101 is arranged on the one and the other wiring groups 80 and is electrically connected to at least one of the first lower wirings 81 of the one wiring group 80 and at least one of the first lower wirings 81 of the other wiring group 80. The second pad wiring 102 is arranged on at the one and the other wiring groups 80 at intervals from the first pad wiring 101 in the second direction Y. The second pad wiring 102 is electrically connected to at least one of the second lower wirings 82 of the one wiring group 80 and at least one of the second lower wirings 82 of the other wiring group 80.

According to this configuration, the semiconductor device 1A having a novel wiring structure is provided. In this semiconductor device 1A, the current path connecting the first lower wirings 81 of the first wiring group 80A to the first pad wiring 101 is shortened, and the wiring resistance caused by the first lower wirings 81 of the first wiring group 80A is reduced. Also, the current path connecting the first lower wirings 81 of the second wiring group 80B to the first pad wiring 101 is shortened, and the wiring resistance caused by the first lower wirings 81 of the second wiring group 80B is reduced.

Similarly, the current path connecting the second lower wirings 82 of the first wiring group 80A to the second pad wiring 102 is shortened, and the wiring resistance caused by the second lower wirings 82 of the first wiring group 80A is reduced. Also, the current path connecting the second lower wirings 82 of the second wiring group 80B to the second pad wiring 102 is shortened, and the wiring resistance caused by the second lower wirings 82 of said second wiring group 80B is reduced.

Such a configuration is effective in reducing the ON-resistance between the first pad wiring 101 and the second pad wiring 102 in the case where a voltage is applied between the first pad wiring 101 and the second pad wiring 102 and a current is generated between the first pad wiring 101 and the second pad wiring 102.

It is preferable that each of the one and the other wiring groups 80 includes the plurality of second lower wirings 82 with which the plurality of first lower wirings 81 are alternately arrayed in the second direction Y. According to this configuration, in the one and the other wiring groups 80, electrical symmetry of the plurality of first lower wirings 81 and the plurality of second lower wirings 82 is improved. Consequently, in the one and the other wiring groups 80, variation in the wiring resistance between the first lower wirings 81 and the second lower wirings 82 is prevented.

The first pad wiring 101 may overlap both the first lower wirings 81 and the second lower wirings 82 of each of the wiring groups 80. The second pad wiring 102 may overlap both the first lower wirings 81 and the second lower wirings 82 of each of the wiring groups 80.

The semiconductor device 1A preferably includes at least one of the first lead-out wirings 109. The first lead-out wiring 109 is led out in the second direction Y from the first pad wiring 101 toward the second pad wiring 102 and is electrically connected to the first lower wirings 81 in the region between the first pad wiring 101 and the second pad wiring 102.

In this configuration, the first lower wiring 81 positioned on the second pad wiring 102 side with respect to the first pad wiring 101 is electrically connected to the first pad wiring 101 by the first lead-out wiring 109. Consequently, the wiring distance connecting the first lower wirings 81 on the second pad wirings 102 side to the first pad wiring 101 is shortened, and the wiring resistance caused by the first lower wirings 81 on the second pad wirings 102 side is reduced.

The semiconductor device 1A preferably includes at least one of the second lead-out wirings 113. The second lead-out wiring 113 is led out in the second direction Y from the second pad wiring 102 toward the first pad wiring 101 and is electrically connected to the second lower wirings 82 in the region between the first pad wiring 101 and the second pad wiring 102.

In this configuration, the second lower wiring 82 positioned on the first pad wiring 101 side with respect to the second pad wiring 102 is electrically connected to the second pad wiring 102 by the second lead-out wiring 113. Consequently, the wiring distance connecting the second lower wirings 82 on the first pad wirings 101 side to the second pad wiring 102 is shortened, and the wiring resistance caused by the second lower wirings 82 on the first pad wirings 101 side is reduced.

It is preferable that at least one of the second lead-out wirings 113 opposes at least one of the first lead-out wirings 109 in the first direction X. According to this configuration, the first lead-out wirings 109 can be electrically connected to, of the first lower wirings 81 covered with the second lead-out wiring 113, portions of the first lower wirings 81 exposed from the second lead-out wiring 113. Therefore, the wiring distance connecting the first lower wirings 81 partially hidden by the second lead-out wiring 113 to the first pad wiring 101 is shortened.

Similarly, the second lead-out wiring 113 can be electrically connected to, of the second lower wirings 82 covered with the first lead-out wiring 109, portions of the second lower wirings 82 exposed from the first lead-out wiring 109. Therefore, the wiring distance connecting the second lower wirings 82 partially hidden by the first lead-out wiring 109 to the second pad wiring 102 is shortened.

Also, according to this configuration, in the case where a current is generated between the first pad wiring 101 and the second pad wiring 102, a relatively short current path via the first lower wiring 81 and the second lower wiring 82 can be formed between the first lead-out wiring 109 and the second lead-out wiring 113. Such a configuration is effective in reducing the ON-resistance.

It is preferable that the at least one of the first lead-out wirings 109 is electrically connected to the first lower wirings 81 of the one wiring group 80. According to this configuration, the wiring distance connecting the first lower wirings 81 of the one wiring group 80 to the first pad wiring 101 is shortened, and the wiring resistance caused by the first lower wirings 81 of the one wiring group 80 is reduced.

It is preferable that the at least one of the first lead-out wirings 109 is electrically connected to the first lower wirings 81 of the other wiring group 80. According to this configuration, the wiring distance connecting the first lower wirings 81 of the other wiring group 80 to the first pad wiring 101 is shortened, and the wiring resistance caused by the first lower wirings 81 of the other wiring group 80 is reduced.

It is preferable that at least one of the first lead-out wirings 109 opposes the second pad wiring 102 in the first direction X. According to this configuration, the first lead-out wiring 109 can be electrically connected to, of the first lower wirings 81 covered with the second pad wiring 102, portions of the first lower wiring 81 exposed from the second pad wiring 102.

Therefore, the wiring distance connecting the first lower wirings 81 partially hidden by the second pad wiring 102 to the first pad wiring 101 is shortened. Also, a relatively short current path via the first lower wirings 81 and the second lower wirings 82 can be formed between the second pad wiring 102 and the first lead-out wiring 109. Such a configuration is effective in reducing the ON-resistance.

It is preferable that at least one of the first lead-out wirings 109 opposes the second pad wiring 102 in the second direction Y. In this configuration, the first lead-out wiring 109 may overlap at least one of the first lower wirings 81 and at least one of the second lower wirings 82 in the region between the first pad wiring 101 and the second pad wiring 102.

It is preferable that the at least one of the second lead-out wirings 113 is electrically connected to the second lower wirings 82 of the one wiring group 80. According to this configuration, the wiring distance connecting the second lower wirings 82 of the one wiring group 80 to the second pad wiring 102 is shortened, and the wiring resistance caused by the second lower wirings 82 of the one wiring group 80 is reduced.

It is preferable that the at least one of the second lead-out wirings 113 is electrically connected to the second lower wirings 82 of the other wiring group 80. According to this configuration, the wiring distance connecting the second lower wirings 82 of the other wiring group 80 to the second pad wiring 102 is shortened, and the wiring resistance caused by the second lower wirings 82 of the other wiring group 80 is reduced.

It is preferable that at least one of the second lead-out wirings 113 opposes the first pad wiring 101 in the first direction X. According to this configuration, the second lead-out wiring 113 can be electrically connected to, of the second lower wirings 82 covered with the first pad wiring 101, portions of the second lower wiring 82 exposed from the first pad wiring 101.

Therefore, the wiring distance connecting the second lower wirings 82 partially hidden by the first pad wiring 101 to the second pad wiring 102 is shortened. Also, a relatively short current path via the first lower wirings 81 and the second lower wirings 82 can be formed between the first pad wiring 101 and the second lead-out wiring 113. Such a configuration is effective in reducing the ON-resistance.

It is preferable that at least one of the second lead-out wirings 113 opposes the first pad wiring 101 in the second direction Y. In this configuration, the second lead-out wiring 113 may overlap at least one of the first lower wirings 81 and at least one of the second lower wirings 82 in the region between the first pad wiring 101 and the second pad wiring 102.

It is preferable that the plurality of first lead-out wirings 109 are led out from the first pad wiring 101. According to this configuration, the wiring distance connecting the first lower wirings 81 on the second pad wiring 102 side to the first pad wiring 101 is shortened by the plurality of first lead-out wirings 109. It is preferable that the plurality of second lead-out wirings 113 are led out from the second pad wiring 102. According to this configuration, the wiring distance connecting the second lower wirings 82 on the first pad wiring 101 side to the second pad wiring 102 is shortened by the plurality of second lead-out wirings 113.

In this case, it is preferable that the plurality of second lead-out wirings 113 and the plurality of first lead-out wirings 109 are alternately arrayed in the first direction X. According to this configuration, both the wiring distance connecting the first lower wirings 81 on the second pad wiring 102 side to the first pad wiring 101, and the wiring distance connecting the second lower wirings 82 on the first pad wiring 101 side to the second pad wiring 102 are efficiently shortened. Also, according to this configuration, a relatively short current path via the first lower wirings 81 and the second lower wirings 82 can be formed between the plurality of first lead-out wirings 109 and the plurality of second lead-out wirings 113. Such a configuration is effective in reducing the ON-resistance.

The semiconductor device 1A may include the inter-wiring region IWR defined in a region between the one and the other wiring groups 80. According to this configuration, a wiring other than the first wiring group 80A and the second wiring group 80B can be arranged in the inter-wiring region IWR.

For example, semiconductor device 1A may include any one or both of the third lower wiring 83 and the fourth lower wiring 84 arranged in the inter-wiring region IWR. In this case, the first pad wiring 101 may overlap any one or both of the third lower wiring 83 and the fourth lower wiring 84. Also, the second pad wiring 102 may overlap any one or both of the third lower wiring 83 and the fourth lower wiring 84.

The semiconductor device 1A preferably includes the first interlayer film 71 and the second interlayer film 72 laminated on the first interlayer film 71. In this case, it is preferable that the plurality of first lower wirings 81 and the plurality of second lower wirings 82 are arranged on the first interlayer film 71, and the first pad wiring 101, the second pad wiring 102, the first lead-out wirings 109, and the second lead-out wirings 113 are arranged on the second interlayer film 72.

According to this configuration, the first lower wirings 81, the second lower wirings 82, the first pad wiring 101, the second pad wiring 102, the first lead-out wirings 109, and the second lead-out wirings 113 can be appropriately arrayed in a three-dimensionally intersection arrangement by using the first interlayer film 71 and the second interlayer film 72.

The semiconductor device 1A preferably includes the first pad electrodes 181 arranged on the first pad wirings 101 and the second pad electrodes 182 arranged on the second pad wirings 102. According to this configuration, the wiring distance connecting the first lower wirings 81 on the second pad wirings 102 side to the first pad electrode 181 is shortened, and the wiring distance connecting the second lower wirings 82 on the first pad wirings 101 side to the second pad electrode 182 is shortened.

The semiconductor device 1A preferably includes the chip 2 and the device structure formed in the chip 2. In this case, the device structure includes the first application end to which the first potential is to be applied and the second application end to which the second potential different from the first potential is to be applied. The plurality of first lower wirings 81 are electrically connected to the first application end on the chip 2, and the plurality of second lower wirings 82 are electrically connected to the second application end in the chip 2. According to this configuration, the ON-resistance via the device structure between the first pad wiring 101 and the second pad wiring 102 is reduced.

In this embodiment, the semiconductor device 1A includes the drain source common transistor structure Tr as an example of the device structure. The transistor structure Tr has the first drain source region 28 as the first application end and the second drain source region 29 as the second application end. The plurality of first lower wirings 81 are electrically connected to the first drain source region 28, and the plurality of second lower wirings 82 are electrically connected to the second drain source region 29. According to this configuration, the ON-resistance via the transistor structure Tr is reduced between the first pad wiring 101 and the second pad wiring 102.

From another viewpoint, the semiconductor device 1A includes the plurality of wiring groups 80, the inter-wiring region IWR, intermediate wirings (83 and 84), and intermediate pad wirings (103 and 104). The plurality of wiring groups 80 are arranged at intervals in the first direction X. Each of the plurality of wiring groups 80 includes the plurality of first lower wirings 81 and the plurality of second lower wirings 82.

The inter-wiring region IWR is defined as a band extending in the second direction Y between the plurality of wiring groups 80. The intermediate wirings (83 and 84) are arranged in the inter-wiring region IWR and are electrically disconnected from the plurality of wiring groups 80. The intermediate pad wirings (103 and 104) are arranged on the intermediate wirings (83 and 84), are electrically disconnected from the plurality of wiring groups 80, and are electrically connected to the intermediate wirings (83 and 84).

According to this configuration, the semiconductor device 1A having a novel wiring structure is provided. In the semiconductor device 1A, the intermediate wirings (83 and 84) are arranged in the inter-wiring region IWR, and the intermediate pad wirings (103 and 104) are electrically connected to the intermediate wirings (83 and 84) directly below. Therefore, the plurality of wiring groups 80 do not interfere with the current path between the intermediate wirings (83 and 84) and the intermediate pad wirings (103 and 104).

That is, when electrically connecting the intermediate wirings (83 and 84) to the intermediate pad wirings (103 and 104), there is no need to form the intermediate wirings (83 and 84) that cross the wiring groups 80 or the intermediate wirings (83 and 84) that bypass the wiring groups 80. Consequently, the current path connecting the intermediate wiring (83 or 84) to the intermediate pad wiring (103 or 104) is shortened, and the wiring resistance between the intermediate pad wiring (103 or 104) and the intermediate wiring (83 or 84) is reduced.

Each of the plurality of wiring groups 80 preferably includes the plurality of first lower wirings 81 and the plurality of second lower wirings 82 arrayed as stripes extending in the first direction X. It is preferable that each of the plurality of wiring groups 80 includes the plurality of second lower wirings 82 with which the plurality of first lower wirings 81 are alternately arrayed in the second direction Y. According to this configuration, in the plurality of wiring groups 80, the electrical symmetry of the plurality of first lower wirings 81 and the plurality of second lower wirings 82 is improved. Consequently, in the one and the other wiring groups 80, variation in the wiring resistance between the first lower wirings 81 and the second lower wirings 82 is prevented.

The intermediate pad wirings (103 and 104) may overlap the plurality of wiring groups 80. According to this configuration, a pad area of the intermediate pad wiring (103 or 104) is increased. The intermediate wirings (83 and 84) may oppose the plurality of wiring groups 80 on both sides in the first direction X. The intermediate wirings (83 and 84) may extend as bands in the second direction Y. It is preferable that the intermediate wiring (83 or 84) does not have a portion extending in the first direction X in the inter-wiring region IWR.

The intermediate wirings (83 and 84) may respectively have lead-out portions (87 and 89) led out from the inter-wiring region IWR to the outside of the inter-wiring region IWR. According to this configuration, the potential applied from the intermediate pad wirings (103 and 104) to the intermediate wirings (83 and 84) can be transmitted to a region outside the inter-wiring region IWR. The lead-out portions (87 and 89) may extend in the first direction X outside the inter-wiring region IWR and may oppose at least one of the wiring groups 80 in the second direction Y.

The semiconductor device 1A may include the first pad wiring 101. The first pad wiring 101 may be arranged on at least one of the wiring groups 80 and may be electrically connected to the first lower wirings 81 of at least one of the wiring groups 80. According to this configuration, in the configuration including the plurality of wiring groups 80, the intermediate wirings (83 and 84), and the intermediate pad wirings (103 and 104), a current path connecting the first lower wirings 81 and the first pad wiring 101 can be formed.

The semiconductor device 1A may include the second pad wiring 102. The second pad wiring 102 may be arranged at intervals from the first pad wiring 101 on at least one of the wiring groups 80 and may be electrically connected to the second lower wirings 82 of at least one of the wiring groups 80. According to this configuration, in the configuration including the plurality of wiring groups 80, the intermediate wirings (83 and 84), and the intermediate pad wirings (103 and 104), a current path connecting the second lower wirings 82 and the second pad wiring 102 can be formed.

The second pad wiring 102 may be arranged at intervals in the second direction Y from the first pad wiring 101. In this case, the intermediate pad wirings (103 and 104) may be arranged in the region between the first pad wiring 101 and the second pad wiring 102.

From another viewpoint, the semiconductor device 1A includes the chip 2, the plurality of active regions 6, the boundary regions 7a, the intermediate wirings (83 and 84), and the intermediate pad wirings (103 and 104). The plurality of active regions 6 are formed at intervals in the first direction X in the chip 2. The boundary regions 7a are formed as bands extending in the second direction Y between the plurality of active regions 6 in the chip 2. The intermediate wirings (83 and 84) are arranged on the boundary region 7a. The intermediate pad wirings (103 and 104) are respectively arranged on the intermediate wirings (83 and 84), and are electrically connected to the intermediate wirings (83 and 84).

According to this configuration, the semiconductor device 1A having a novel wiring structure is provided. In the semiconductor device 1A, the intermediate wirings (83 and 84) are arranged in the boundary region 7a, and the intermediate pad wirings (103 and 104) are electrically connected to the intermediate wirings (83 and 84) directly below. Therefore, the plurality of active regions 6 do not interfere with the current path between the intermediate wirings (83 and 84) and the intermediate pad wirings (103 and 104).

That is, when electrically connecting the intermediate wirings (83 and 84) to the intermediate pad wirings (103 and 104), there is no need to form the intermediate wirings (83 and 84) that cross the active regions 6 or the intermediate wirings (83 and 84) that bypass the active regions 6. Consequently, the current path connecting the intermediate wiring (83 or 84) to the intermediate pad wiring (103 or 104) is shortened, and the wiring resistance between the intermediate pad wiring (103 or 104) and the intermediate wiring (83 or 84) is reduced.

The intermediate pad wirings (103 and 104) may overlap the plurality of active regions 6. According to this configuration, the pad area of the intermediate pad wiring (103 or 104) is increased. It is preferable that the intermediate wiring (83 or 84) does not have a portion extending in the first direction X in the boundary region 7a.

The semiconductor device 1A may include the outer peripheral region 7b formed around the plurality of active regions 6 in the chip 2. In this case, the intermediate wirings (83 and 84) may have the respective lead-out portions (87 and 89) led out from the boundary region 7a toward the outer peripheral region 7b. According to this configuration, the potential applied from the intermediate pad wirings (103 and 104) to the intermediate wirings (83 and 84) can be transmitted to a region outside the boundary region 7a. The lead-out portions (87 and 89) may extend in the first direction X in the outer peripheral region 7b and may oppose at least one of the active regions 6 in the second direction Y.

The semiconductor device 1A may include a plurality of the transistor structures Tr respectively formed in the plurality of active regions 6. The intermediate wirings (83 and 84) may include the third lower wiring 83 (the gate wiring) electrically connected to the gates (the gate structures 12) of the plurality of transistor structures Tr. The intermediate wirings (83 and 84) may include the fourth lower wiring 84 (a chip wiring) electrically connected to the chip 2, at intervals from the plurality of transistor structures Tr.

The semiconductor device 1A may include the plurality of wiring groups 80. The plurality of wiring groups 80 may be respectively arranged on the plurality of active regions 6 at intervals in the first direction X. Each of the plurality of wiring groups 80 may include the plurality of first lower wirings 81 and the plurality of second lower wirings 82. In this case, the intermediate wirings (83 and 84) are arranged on the boundary region 7a at intervals from the plurality of wiring groups 80 and are electrically disconnected from the plurality of wiring groups 80. The intermediate pad wirings (103 and 104) are electrically disconnected from the plurality of wiring groups 80.

The semiconductor device 1A may include the first pad wiring 101. The first pad wiring 101 may be arranged on at least one of the wiring groups 80 and may be electrically connected to the first lower wirings 81 of at least one of the wiring groups 80. According to this configuration, in the configuration including the plurality of wiring groups 80, the intermediate wirings (83 and 84), and the intermediate pad wirings (103 and 104), the current path connecting the first lower wirings 81 and the first pad wiring 101 can be formed.

The semiconductor device 1A may include the second pad wiring 102. The second pad wiring 102 may be arranged at intervals from the first pad wiring 101 on at least one of the wiring groups 80 and may be electrically connected to the second lower wirings 82 of at least one of the wiring groups 80. According to this configuration, in the configuration including the plurality of wiring groups 80, the intermediate wirings (83 and 84), and the intermediate pad wirings (103 and 104), the current path connecting the second lower wirings 82 and the second pad wiring 102 can be formed.

The second pad wiring 102 may be arranged at intervals in the second direction Y from the first pad wiring 101. In this case, the intermediate pad wirings (103 and 104) may be arranged in the region between the first pad wiring 101 and the second pad wiring 102.

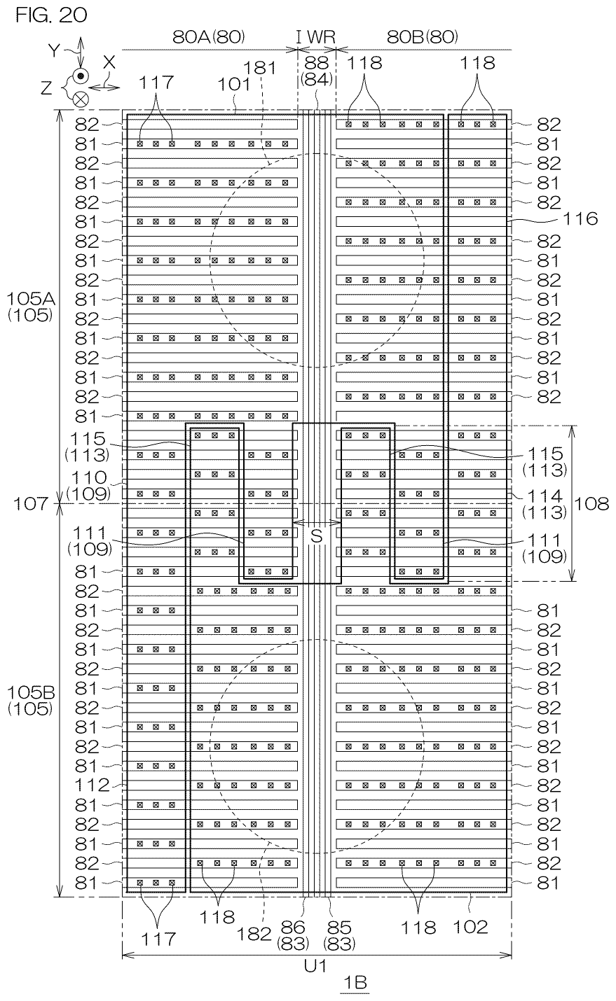

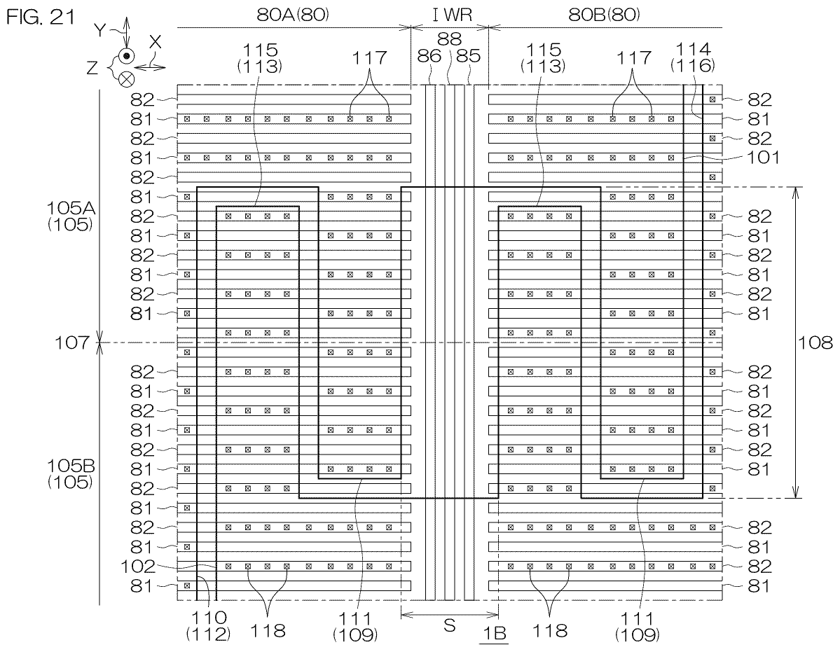

FIG. 20 is an enlarged plan view showing the first wiring unit U1 of a semiconductor device 1B according to a second embodiment. FIG. 21 is an enlarged plan view showing a main portion of the first wiring unit U1 in FIG. 20. The first wiring unit U1 of the semiconductor device 1B has a layout obtained by modifying the first interconnect structure 108 (see FIG. 16A) according to the first layout example.

Similarly to the case of the first layout example, the first interconnect structure 108 includes the plurality of first lead-out wirings 109 and the plurality of second lead-out wirings 113. Each of the plurality of first lead-out wirings 109 includes the single first long wiring 110 and at least one (in this embodiment, a plurality) of the first short wirings 111. The first long wiring 110 has a layout similar to that of the case of the first layout example.

Similarly to the case of the first layout example, the plurality of first short wirings 111 include one or a plurality (in this embodiment, one) of the first short wiring 111 on the one side and one or a plurality (in this embodiment, one) of the first short wiring 111 on the other side. The first short wiring 111 on the one side is positioned on the first wiring group 80A side, and the first short wiring 111 on the other side is positioned on the second wiring group 80B side.

In this embodiment, the first short wiring 111 on the one side is led out to a region outside the inter-wiring region IWR at intervals in the first direction X from the inter-wiring region IWR toward the first wiring group 80A. The first short wiring 111 on the one side is arranged at intervals from one or both (in this embodiment, both) of the third lower wiring 83 and the fourth lower wiring 84 and exposes one or both (in this embodiment, both) of the third lower wiring 83 and the fourth lower wiring 84.

The first short wiring 111 on the one side extends as a band in the second direction Y along the inter-wiring region IWR. The first short wiring 111 on the one side extends substantially parallel to the inter-wiring region IWR. The first short wiring 111 on the one side intersects (is orthogonal to) at least one (in this embodiment, a plurality) of the first lower wirings 81 and at least one (in this embodiment, a plurality) of the second lower wirings 82 of the first wiring group 80A.

It is preferable that the first short wiring 111 on the one side is arranged at intervals in the first direction X from end portions of the plurality of first lower wirings 81 and end portions of the plurality of second lower wirings 82 and exposes the end portions of the plurality of first lower wirings 81 and the end portions of the plurality of second lower wirings 82. Similarly to the case of the first layout example, the first short wiring 111 on the one side is electrically connected to the corresponding first lower wirings 81 of the first wiring group 80A via the plurality of first upper via electrodes 117.

In this embodiment, the first short wiring 111 on the other side is led out to a region outside the inter-wiring region IWR at intervals in the first direction X from the inter-wiring region IWR toward the second wiring group 80B. The first short wiring 111 on the other side is arranged at intervals from one or both (in this embodiment, both) of the third lower wiring 83 and the fourth lower wiring 84 and exposes one or both (in this embodiment, both) of the third lower wiring 83 and the fourth lower wiring 84.

The first short wiring 111 on the other side extends as a band in the second direction Y along the inter-wiring region IWR and opposes the first short wiring 111 on the one side in the first direction X across the inter-wiring region IWR. The first short wiring 111 on the other side extends substantially parallel to the inter-wiring region IWR. The first short wiring 111 on the other side intersects (is orthogonal to) at least one (in this embodiment, a plurality) of the first lower wirings 81 and at least one (in this embodiment, a plurality) of the second lower wirings 82 of the second wiring group 80B.

It is preferable that the first short wiring 111 on the other side is arranged at intervals in the first direction X from end portions of the plurality of first lower wirings 81 and end portions of the plurality of second lower wirings 82 and exposes the end portions of the plurality of first lower wirings 81 and the end portions of the plurality of second lower wirings 82. Similarly to the case of the first layout example, the first short wiring 111 on the other side is electrically connected to the corresponding first lower wirings 81 of the second wiring group 80B via the plurality of first upper via electrodes 117.

Each of the plurality of second lead-out wirings 113 includes the single second long wiring 114 and at least one (in this embodiment, a plurality) of the second short wirings 115. The second long wiring 114 has the layout similar to that of the case of the first layout example.

Similarly to the case of the first layout example, the plurality of second short wirings 115 include one or a plurality (in this embodiment, one) of the second short wiring 115 on the one side and one or a plurality (in this embodiment, one) of the second short wiring 115 on the other side. The second short wiring 115 on the one side is positioned on the first wiring group 80A side, and the second short wiring 115 on the other side is positioned on the second wiring group 80B side.

In this embodiment, the second short wiring 115 on the one side is led out to a region outside the inter-wiring region IWR at intervals in the first direction X from the inter-wiring region IWR toward the first wiring group 80A. The second short wiring 115 on the one side is arranged at intervals from one or both (in this embodiment, both) of the third lower wiring 83 and the fourth lower wiring 84 and exposes one or both (in this embodiment, both) of the third lower wiring 83 and the fourth lower wiring 84.

The second short wiring 115 on the one side extends as a band in the second direction Y along the inter-wiring region IWR. The second short wiring 115 on the one side extends substantially parallel to the inter-wiring region IWR. The second short wiring 115 on the one side intersects (is orthogonal to) at least one (in this embodiment, a plurality) of the first lower wirings 81 and at least one (in this embodiment, a plurality) of the second lower wirings 82 of the first wiring group 80A.

The second short wiring 115 on the one side is arranged on the first wiring group 80A side at intervals in the first direction X from the first short wiring 111 on the one side and opposes the first short wiring 111 on the one side in the first direction X. The second short wiring 115 on the one side extends substantially parallel to the first short wiring 111 on the one side. The second short wiring 115 on the one side opposes the first short wiring 111 on the other side across the inter-wiring region IWR and extends substantially parallel to the first short wiring 111 on the other side.

In this embodiment, the second short wiring 115 on the one side is arranged in a region opposing the inter-wiring region IWR in the first direction X across the first short wiring 111 on the one side. Specifically, the second short wiring 115 on the one side is arranged in a region between the plurality of first lead-out wirings 109 (in this embodiment, the first long wiring 110 and the first short wiring 111) and opposes the plurality of first lead-out wirings 109 on both sides in the first direction X.

The second short wiring 115 on the one side opposes the first short wiring 111 on the other side in the first direction X across the first short wiring 111 on the one side and the inter-wiring region IWR. As a matter of course, the second short wiring 115 on the one side may be arranged in a region between the first short wiring 111 on the one side and the inter-wiring region IWR and may oppose the first short wiring 111 on the other side in the first direction X across the inter-wiring region IWR.

Similarly to the case of the first layout example, the second short wiring 115 on the one side forms a current path of the drain source current Ids together with at least one of the first lead-out wirings 109 opposing (closely opposing) the second short wiring 115 in the first direction X on the first wiring group 80A side. Similarly to the case of the first layout example, the second short wiring 115 on the one side is electrically connected to the corresponding second lower wirings 82 of the first wiring group 80A via the plurality of second upper via electrodes 118.

The second short wiring 115 on the other side is led out to a region outside the inter-wiring region IWR at intervals in the first direction X from the inter-wiring region IWR toward the second wiring group 80B. The second short wiring 115 on the other side is arranged at intervals from one or both (in this embodiment, both) of the third lower wiring 83 and the fourth lower wiring 84 and exposes one or both (in this embodiment, both) of the third lower wiring 83 and the fourth lower wiring 84.

The second short wiring 115 on the other side extends as a band in the second direction Y along the inter-wiring region IWR. The second short wiring 115 on the other side extends substantially parallel to the inter-wiring region IWR. The second short wiring 115 on the other side intersects (is orthogonal to) at least one (in this embodiment, a plurality) of the first lower wirings 81 and at least one (in this embodiment, a plurality) of the second lower wirings 82 of the second wiring group 80B.

The second short wiring 115 on the other side is arranged on the second wiring group 80B side at intervals in the first direction X from the first short wiring 111 on the other side and opposes the first short wiring 111 on the other side in the first direction X. The second short wiring 115 on the other side extends substantially parallel to the first short wiring 111 on the other side.

The second short wiring 115 on the other side opposes the second short wiring 115 on the one side across the inter-wiring region IWR and extends substantially parallel to the second short wiring 115 on the one side. Also, the second short wiring 115 on the other side opposes the first short wiring 111 on the one side across the inter-wiring region IWR and extends substantially parallel to the first short wiring 111 on the one side.

In this embodiment, the second short wiring 115 on the other side may be arranged in a region between the first short wiring 111 on the other side and the inter-wiring region IWR and may oppose the first short wiring 111 on the one side in the first direction X across the inter-wiring region IWR. As a matter of course, the second short wiring 115 on the other side may be arranged in a region opposing the inter-wiring region IWR in the first direction X across the first short wiring 111 on the other side. In this case, the second short wiring 115 on the other side is arranged in a region between the plurality of first lead-out wirings 109 (the first short wiring 111 on the other side) and opposes the plurality of first lead-out wirings 109 on both sides in the first direction X.

Similarly to the case of the first layout example, the second short wiring 115 on the other side forms a current path of the drain source current Ids together with at least one of the first lead-out wirings 109 opposing (closely opposing) the second short wiring 115 in the first direction X on the second wiring group 80B side. Similarly to the case of the first layout example, the second short wiring 115 on the other side is electrically connected to the corresponding second lower wirings 82 of the second wiring group 80B via the plurality of second upper via electrodes 118.

The semiconductor device 1B includes an intermediate slit S defined on the inter-wiring region IWR in a region between the first lead-out wiring 109 and the second lead-out wiring 113. In this embodiment, the intermediate slit S is defined in a region between the first short wiring 111 on the one side and the second short wiring 115 on the other side. The intermediate slit S is adjusted to various layouts depending on the layout of the first lead-out wiring 109 and the second lead-out wiring 113.

For example, the intermediate slit S may be defined in a region between the first short wiring 111 on the other side and the second short wiring 115 on the one side opposing (closely opposing) each other in the first direction X. For example, the intermediate slit S may be defined in a region between the first short wirings 111 on the one and the other sides opposing (closely opposing) each other in the first direction X. For example, the intermediate slit S may be defined in a region between the second short wirings 115 on the one and the other sides opposing (closely opposing) each other in the first direction X.

The intermediate slit S extends in the second direction Y along the inter-wiring region IWR and exposes at least a part of the inter-wiring region IWR. In this embodiment, the intermediate slit S exposes the entire region of the inter-wiring region IWR. That is, the intermediate slit S exposes both the third lower wiring 83 and the fourth lower wiring 84. Specifically, the intermediate slit S exposes the first gate wiring 85, the second gate wiring 86, and the first base wiring 88.

In this embodiment, the intermediate slit S exposes the end portions of the plurality of first lower wirings 81 belonging to the first wiring group 80A and the end portions of the plurality of second lower wirings 82 belonging to the first wiring group 80A. Also, the intermediate slit S exposes the end portions of the plurality of first lower wirings 81 belonging to the second wiring group 80B and the end portions of the plurality of second lower wirings 82 belonging to the second wiring group 80B.

As described above, the semiconductor device 1B includes the wiring groups 80 on the one and the other sides, the inter-wiring region IWR, the first pad wiring 101, the second pad wiring 102, at least one of the first lead-out wirings 109, and at least one of the second lead-out wirings 113.

The one and the other wiring groups 80 are arranged at intervals in the first direction X. Each of the one and the other wiring groups 80 includes the plurality of first lower wirings 81 and the plurality of second lower wirings 82. The inter-wiring region IWR is defined between the one and the other wiring groups 80. The first pad wiring 101 is arranged on the inter-wiring region IWR. The second pad wiring 102 is arranged on the inter-wiring region IWR at intervals from the first pad wiring 101.

The first lead-out wiring 109 is led out from the first pad wiring 101 to a region outside the inter-wiring region IWR and is electrically connected to the first lower wirings 81 of the one wiring group 80. The second lead-out wiring 113 is led out from the second pad wiring 102 to a region outside the inter-wiring region IWR such as to oppose the first lead-out wiring 109 in the first direction X across the inter-wiring region IWR and is electrically connected to the second lower wirings 82 of the other wiring group 80.

According to this configuration, the semiconductor device 1B having a novel wiring structure is provided. In the semiconductor device 1B, the intermediate slit S exposing the inter-wiring region IWR is defined in the region between the first lead-out wiring 109 and the second lead-out wiring 113. For example, in a case where the intermediate slit S is positioned on the wiring group 80, the intermediate slit S interferes with a connection location of the first lead-out wiring 109 (the second lead-out wiring 113) with respect to the wiring group 80, and the wiring resistance may increase due to the intermediate slit S.

On the other hand, in the semiconductor device 1B, a layout location of the intermediate slit S is matched with the inter-wiring region IWR in which the first lower wirings 81 and the second lower wirings 82 are not provided. According to this configuration, the intermediate slit S does not interfere with the connection location of the first lead-out wiring 109 with respect to the first lower wirings 81 (the wiring group 80). Also, the intermediate slit S does not interfere with a connection location of the second lead-out wiring 113 with respect to the second lower wirings 82 (the wiring group 80).

Consequently, a connection area (an opposing area) of the first lead-out wiring 109 with respect to the first lower wirings 81 is appropriately secured, and a connection area (an opposing area) of the second lead-out wiring 113 with respect to the second lower wirings 82 is appropriately secured. Accordingly, an increase in the wiring resistance due to the intermediate slit S is prevented.

As a matter of course, the layout of the first interconnect structure 108 (the layout of the intermediate slit S) according to the second embodiment may be applied to any one of the second interconnect structure 137, the third interconnect structure 138, the fourth interconnect structure 139, the fifth interconnect structure 152, the sixth interconnect structure 153, the seventh interconnect structure 165, and the eighth interconnect structure 166.

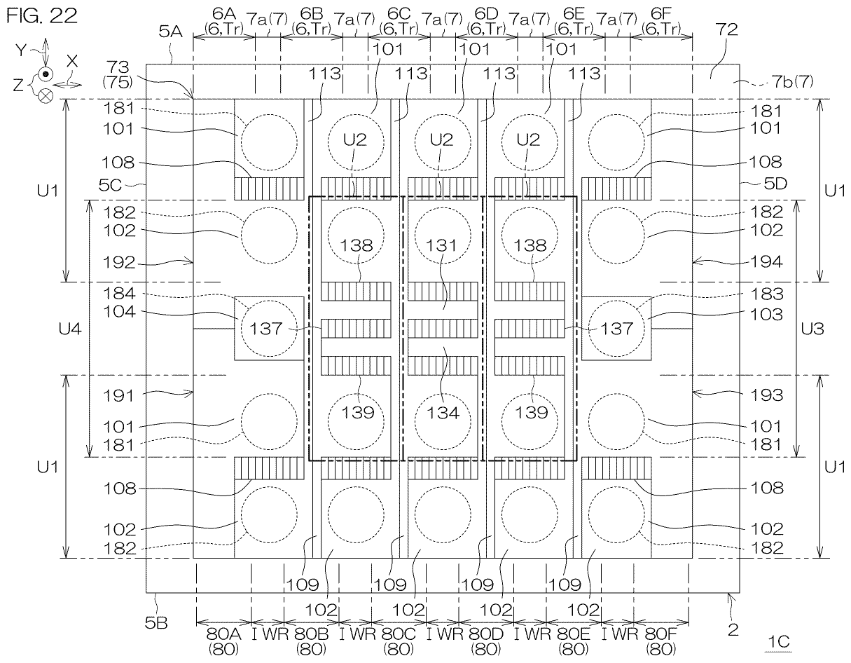

FIG. 22 is a plan view showing a first layout example of the second layer wiring 75 of a semiconductor device 1C according to a third embodiment. The second layer wiring 75 according to the semiconductor device 1C includes first to fourth side wirings 191 to 194 instead of the first and second side wirings 167 and 168 (see FIG. 15). The first side wiring 191 applies the first drain source potential to the first lower wirings 81. The second side wiring 192 applies the second drain source potential to the second lower wirings 82. The third side wiring 193 applies the first drain source potential to the first lower wirings 81. The fourth side wiring 194 applies the second drain source potential to the second lower wirings 82.

The first side wiring 191 covers, in a region on the other side in the second direction Y, the end portion of the outermost wiring group 80 (that is, the first wiring group 80A) positioned on the one side in the first direction X. The first side wiring 191 may have a width less than the width of the first pad wiring 101 (the second pad wiring 102) in the first direction X. As a matter of course, the width of the first side wiring 191 may be larger than the width of the first pad wiring 101 (the second pad wiring 102). The width of the first side wiring 191 is larger than the width of the first lower wiring 81 (the second lower wiring 82).

The first side wiring 191 is arranged in a region on the other side in the second direction Y with respect to an intermediate portion of the first wiring group 80A in the second direction Y.

The first side wiring 191 is constituted of a lead-out portion led out from the outermost first pad wiring 101 to the end portion of the first wiring group 80A and is physically and electrically connected to the first pad wiring 101. The first side wiring 191 is electrically disconnected from the second pad wiring 102.

The first side wiring 191 extends as a band in the second direction Y along the first wiring group 80A. The first side wiring 191 intersects (is orthogonal to) at least one (in this embodiment, a plurality) of the first lower wirings 81 and at least one (in this embodiment, a plurality) of the second lower wirings 82 of the first wiring group 80A.

In this embodiment, the first side wiring 191 is led out to the region opposing the second pad wiring 102 in the first direction X in the region on the other side in the second direction Y. The first side wiring 191 opposes the entire region of the second pad wiring 102 in the first direction X. The first side wiring 191 intersects (is orthogonal to) one or a plurality of (preferably, all of) the first lower wirings 81 and one or a plurality of (preferably, all of) the second lower wirings 82 passing directly below the second pad wiring 102 in the first direction X.

The first side wiring 191 is electrically connected to, of one or a plurality of (preferably, all of) the first lower wirings 81 covered with the second pad wiring 102, portions of the first lower wirings 81 exposed from the second pad wiring 102. On the other hand, the first side wiring 191 is electrically disconnected from one or a plurality of (preferably, all of) the second lower wirings 82 passing directly below the second pad wiring 102.

Consequently, the first side wiring 191 forms a current path of the drain source current Ids together with the second pad wiring 102 opposing (closely opposing) the first side wiring 191 in the first direction X. The first side wiring 191 increases the current path (the connection area) with respect to at least one (in this embodiment, a plurality) of the first lower wirings 81 at an end portion of the first wiring group 80A.

In this embodiment, the first side wiring 191 has a portion opposing the fourth arrangement region 105D in the first direction X in the region on the one side in the second direction Y. The fourth arrangement region 105D is an inter-pad region between the first pad wiring 101 and the second pad wiring 102.

In this embodiment, the first side wiring 191 partially opposes the fourth pad wiring 104 in the first direction X and is electrically disconnected from the fourth pad wiring 104. The first side wiring 191 intersects (is orthogonal to) one or a plurality of the first lower wirings 81 and one or a plurality of the second lower wirings 82 passing directly below the fourth pad wiring 104 (the fourth arrangement region 105D) in the first direction X.

The first side wiring 191 is electrically connected to, of one or a plurality of the first lower wirings 81 covered with the fourth pad wiring 104, portions of the first lower wirings 81 exposed from the fourth pad wiring 104. On the other hand, the first side wiring 191 is electrically disconnected from one or a plurality of the second lower wirings 82 passing directly below the fourth pad wiring 104.

The first side wiring 191 increases the connection area with respect to at least one (in this embodiment, a plurality) of the first lower wirings 81 at the end portion of the first wiring group 80A. Similarly to the first pad wiring 101, etc., the first side wiring 191 is electrically connected to the corresponding first lower wirings 81 via the plurality of first upper via electrodes 117.

The second side wiring 192 covers, in a region on the one side in the second direction Y, the end portion of the outermost wiring group 80 (that is, the first wiring group 80A) positioned on the one side in the first direction X. The second side wiring 192 may have a width less than the width of the first pad wiring 101 (the second pad wiring 102) in the first direction X. As a matter of course, the width of the second side wiring 192 may be larger than the width of the first pad wiring 101 (the second pad wiring 102). The width of the second side wiring 192 is larger than the width of the first lower wiring 81 (the second lower wiring 82).

The second side wiring 192 is arranged in a region on the one side in the second direction Y with respect to the intermediate portion of the first wiring group 80A in the second direction Y. The second side wiring 192 is constituted of a lead-out portion led out from the outermost second pad wiring 102 to the end portion of the first wiring group 80A and is physically and electrically connected to the second pad wiring 102. The second side wiring 192 is electrically disconnected from the first pad wiring 101.

The second side wiring 192 extends as a band in the second direction Y along the first wiring group 80A. The second side wiring 192 is arranged at intervals in the second direction Y from the first side wiring 191 and opposes the first side wiring 191 in the second direction Y. The second side wiring 192 intersects (is orthogonal to) at least one (in this embodiment, a plurality) of the first lower wirings 81 and at least one (in this embodiment, a plurality) of the second lower wirings 82 of the first wiring group 80A.

In this embodiment, the second side wiring 192 is led out to the region opposing the first pad wiring 101 in the first direction X in the region on the one side in the second direction Y. The second side wiring 192 opposes the entire region of the first pad wiring 101 in the first direction X. The second side wiring 192 intersects (is orthogonal to) one or a plurality of (preferably, all of) the first lower wirings 81 and one or a plurality of (preferably, all of) the second lower wirings 82 passing directly below the first pad wiring 101 in the first direction X.

The second side wiring 192 is electrically connected to, of one or a plurality of (preferably, all of) the second lower wirings 82 covered with the first pad wiring 101, portions of the second lower wirings 82 exposed from the first pad wiring 101. On the other hand, the second side wiring 192 is electrically disconnected from one or a plurality of (preferably, all) first lower wirings 81 passing directly below the first pad wiring 101.

Consequently, the second side wiring 192 forms a current path of the drain source current Ids together with the first pad wiring 101 opposing (closely opposing) the second side wiring 192 in the first direction X. The second side wiring 192 increases the current path (the connection area) with respect to at least one (in this embodiment, a plurality) of the second lower wirings 82 at the end portion of the first wiring group 80A.

In this embodiment, the second side wiring 192 has a portion opposing the fourth arrangement region 105D in the first direction X in the region on the other side in the second direction Y. The second side wiring 192 partially opposes the fourth pad wiring 104 in the first direction X and is electrically disconnected from the fourth pad wiring 104. The second side wiring 192 intersects (is orthogonal to) one or a plurality of the first lower wirings 81 and one or a plurality of the second lower wirings 82 passing directly below the fourth pad wiring 104 (the fourth arrangement region 105D) in the first direction X.

The second side wiring 192 is electrically connected to, of one or a plurality of the second lower wirings 82 covered with the fourth pad wiring 104, portions of the second lower wirings 82 exposed from the fourth pad wiring 104. On the other hand, the second side wiring 192 is electrically disconnected from one or a plurality of the first lower wirings 81 passing directly below the fourth pad wiring 104.

The second side wiring 192 increases the connection area with respect to at least one (in this embodiment, a plurality) of the second lower wirings 82 at the end portion of the first wiring group 80A. Similarly to the second pad wiring 102, etc., the second side wiring 192 is electrically connected to the corresponding second lower wirings 82 via the plurality of second upper via electrodes 118.

The third side wiring 193 covers, in the region on the other side in the second direction Y, the end portion of the outermost wiring group 80 (that is, the sixth wiring group 80F) positioned on the other side in the first direction X. The third side wiring 193 has the same layout as that of the first side wiring 191. A configuration of the third side wiring 193 is obtained by replacing the first wiring group 80A with the sixth wiring group 80F and replacing the fourth arrangement region 105D (the fourth pad wiring 104) with the third arrangement region 105C (the third pad wiring 103) in the description of the first side wiring 191.

The fourth side wiring 194 covers, in a region on the one side in the second direction Y, the end portion of the outermost wiring group 80 (that is, the sixth wiring group 80F) positioned on the one side in the first direction X. The fourth side wiring 194 has the same layout as that of the second side wiring 192. A configuration of the fourth side wiring 194 is obtained by replacing the first wiring group 80A with the sixth wiring group 80F and replacing the fourth arrangement region 105D (the fourth pad wiring 104) with the third arrangement region 105C (the third pad wiring 103) in the description of the second side wiring 192.

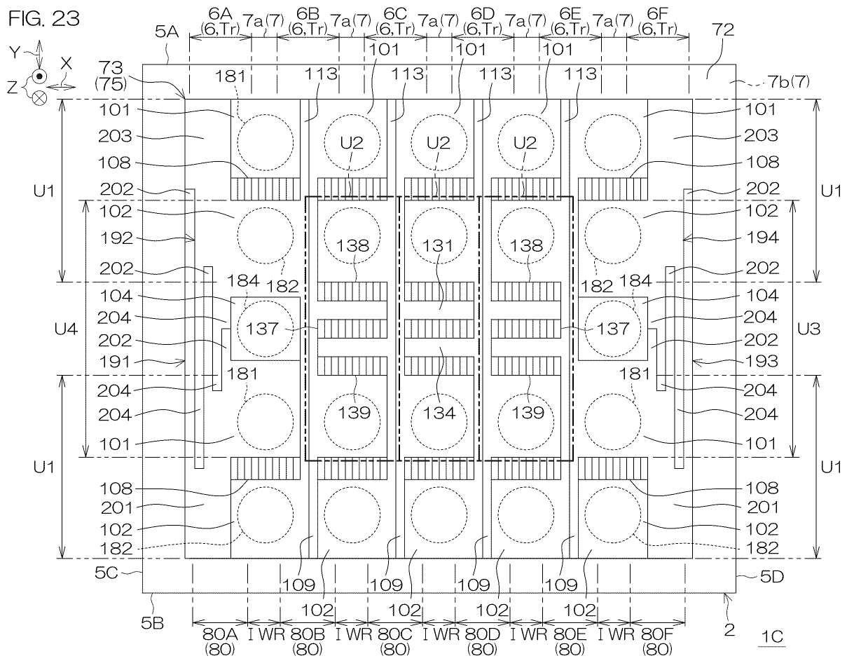

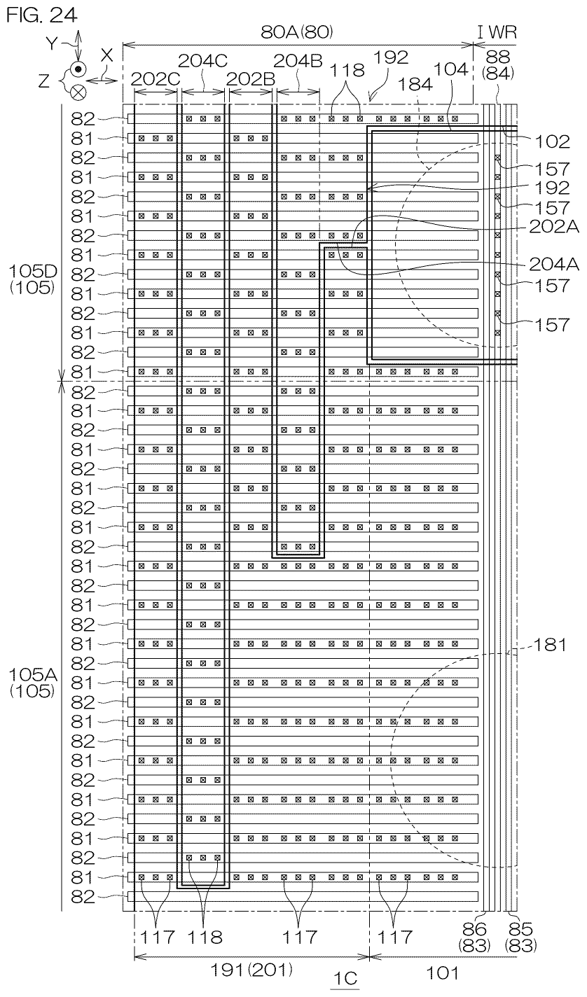

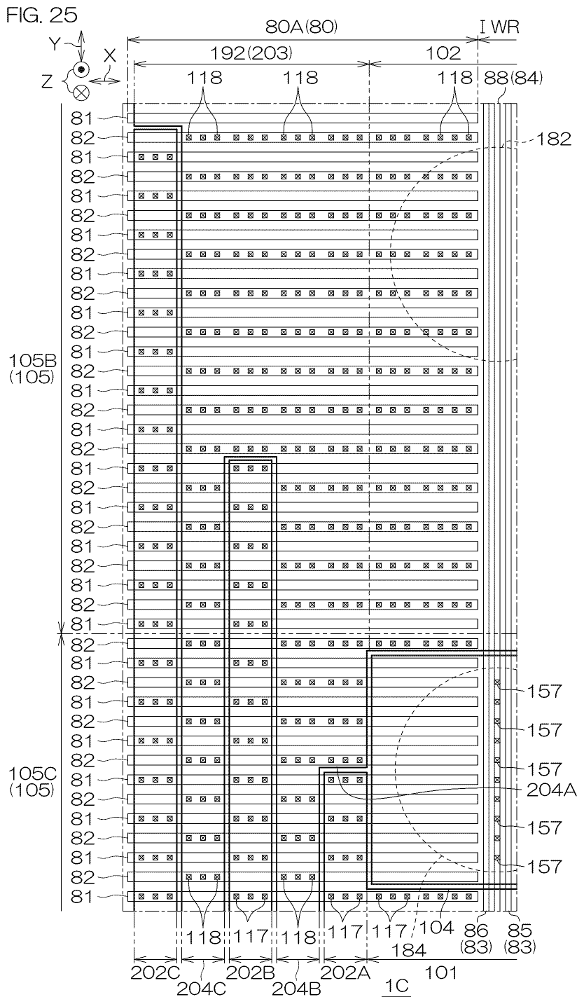

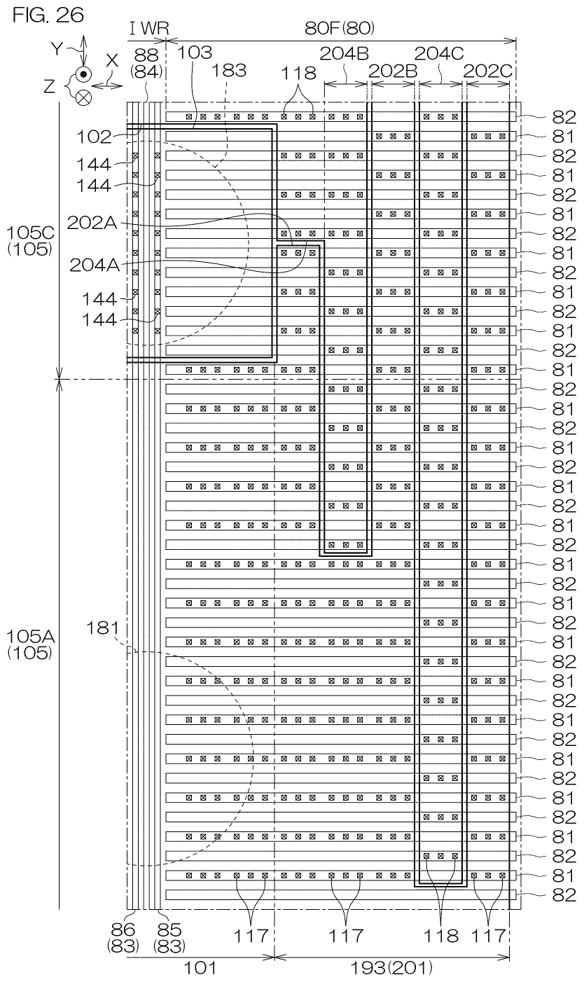

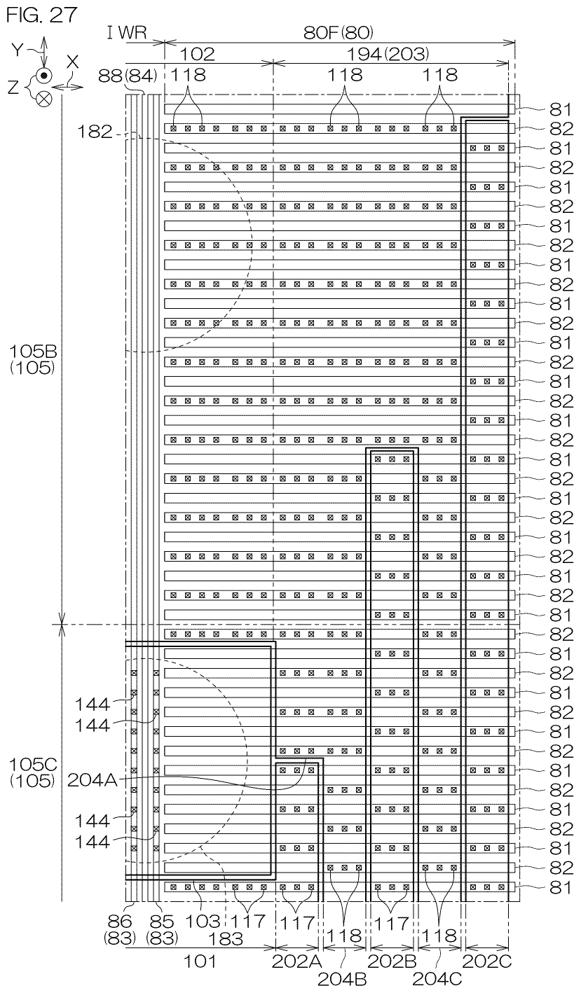

The first to fourth side wirings 191 to 194 may have layout examples shown in FIGS. 23 to 27. FIG. 23 is a plan view showing a second layout example of the second layer wiring 75 in FIG. 22. FIGS. 24 to 27 are enlarged plan views showing a main portion of the first to fourth side wirings 191 to 194 of the second layer wiring 75 in FIG. 23.

Similarly to the case of the first layout example, with reference to FIGS. 23 to 27, the first side wiring 191 covers, in the region on the other side in the second direction Y, the end portion of the outermost wiring group 80 (that is, the first wiring group 80A) positioned on the one side in the first direction X.

In this embodiment, the first side wiring 191 includes a first body portion 201. The first body portion 201 is led out from the first pad wiring 101 to the one side in the first direction X and covers the end portion of the first wiring group 80A in the region on the other side in the second direction Y. That is, the first body portion 201 is constituted of a lead-out portion led out from the outermost first pad wiring 101 to the end portion of the first wiring group 80A and is physically and electrically connected to the first pad wiring 101.

The first body portion 201 may have a width less than the width of the first pad wiring 101 (the second pad wiring 102) in the first direction X. As a matter of course, the width of the first body portion 201 may be larger than the width of the first pad wiring 101 (the second pad wiring 102). The width of the first body portion 201 is larger than the width of the first lower wiring 81 (the second lower wiring 82).

The first body portion 201 extends as a band in the second direction Y along the first wiring group 80A. The first body portion 201 intersects (is orthogonal to) at least one (in this embodiment, a plurality) of the first lower wirings 81 and at least one (in this embodiment, a plurality) of the second lower wirings 82 of the first wiring group 80A.

In this embodiment, the first body portion 201 is led out to the region opposing the second pad wiring 102 in the first direction X in the region on the other side in the second direction Y. The first body portion 201 opposes the entire region of the second pad wiring 102 in the first direction X. The first body portion 201 intersects (is orthogonal to) one or a plurality of (preferably, all of) the first lower wirings 81 and one or a plurality of (preferably, all of) the second lower wirings 82 passing directly below the second pad wiring 102 in the first direction X.

The first body portion 201 is electrically connected to, of one or a plurality of (preferably, all of) the first lower wirings 81 covered with the second pad wiring 102, portions of the first lower wirings 81 exposed from the second pad wiring 102. On the other hand, the first body portion 201 is electrically disconnected from one or a plurality of (preferably, all of) the second lower wirings 82 passing directly below the second pad wiring 102. Consequently, the first body portion 201 forms a current path of the drain source current Ids together with the second pad wiring 102 opposing (closely opposing) the first body portion 201 in the first direction X.

The first body portion 201 increases the current path (the connection area) with respect to at least one (in this embodiment, a plurality) of the first lower wirings 81 at the end portion of the first wiring group 80A. Similarly to the first pad wiring 101, etc., the first body portion 201 is electrically connected to the corresponding first lower wirings 81 via the plurality of first upper via electrodes 117.

The first side wiring 191 includes at least one (in this embodiment, a plurality) of first finger portions 202 led out from the first body portion 201 toward the one side in the second direction Y. The first finger portions 202 are electrically connected to the first pad wiring 101 via the first body portion 201 and are electrically disconnected from the second pad wiring 102 and the fourth pad wiring 104.

The number of the first finger portions 202 is arbitrary and is appropriately adjusted depending on a size of the first body portion 201, a size of the first wiring group 80A, etc. The number of the first finger portions 202 may be not less than 1 and not more than 50. The number of the first finger portions 202 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50. In this embodiment, the three first finger portions 202 are provided.

Each of the plurality of first finger portions 202 has a width less than the width of the first body portion 201 in the first direction X and is arrayed at intervals in the first direction X. The plurality of first finger portions 202 are led out as bands (in this embodiment, in a rectangular shape) to the one side in the second direction Y. That is, the plurality of first finger portions 202 are arrayed in a comb teeth shape extending in the second direction Y and oppose each other in the first direction X. The plurality of first finger portions 202 may be led out in a trapezoidal shape (preferably, an isosceles trapezoidal shape) or a triangular shape (preferably, an isosceles triangular shape).

A width of each of the first finger portions 202 is less than the width of the first pad wiring 101 (the second pad wiring 102). The width of each of the first finger portions 202 is less than the width of the fourth pad wiring 104 (the third pad wiring 103). The width of each of the first finger portions 202 is preferably larger than the width of each of the first lead-out wirings 109 (the second lead-out wiring 113). The width of each of the first finger portions 202 is larger than the width of the first lower wiring 81 (the second lower wiring 82).

In this embodiment, the plurality of first finger portions 202 have wiring lengths different from each other in the second direction Y. Specifically, the plurality of first finger portions 202 respectively have wiring lengths that sequentially increase toward the peripheral edge of the chip 2. As a matter of course, the plurality of first finger portions 202 may have the same wiring length as each other in the second direction Y. In this case, distal end portions of the plurality of first finger portions 202 are positioned on the same imaginary straight line extending along the first direction X.

As a matter of course, the plurality of first finger portions 202 may respectively have wiring lengths that sequentially increase toward the inner side of the chip 2. The plurality of first finger portions 202 may have a layout in which the first finger portions 202 having a relatively long wiring length and the first finger portions 202 having a relatively short wiring length are alternately arrayed in the first direction X.

The plurality of first finger portions 202 increases the current path (the connection area) with respect to at least one (in this embodiment, a plurality) of the first lower wirings 81 at the end portion of the first wiring group 80A. Similarly to the first lead-out wiring 109, etc., the plurality of first finger portions 202 are electrically connected to the corresponding first lower wirings 81 via the plurality of first upper via electrodes 117.

Hereinafter, the first finger portion 202 having a first wiring length is referred to as a first finger portion 202A, the first finger portion 202 having a second wiring length larger than the first wiring length is referred to as a first finger portion 202B, and the first finger portion 202 having a third wiring length larger than the second wiring length is referred to as a first finger portion 202C. The first finger portion 202A is arranged in the innermost region, the first finger portion 202B is arranged in an intermediate region, and the first finger portion 202C is arranged in the outermost region.

The plurality of first finger portions 202 may be constituted of at least one of the first finger portions 202A to 202C. The wiring lengths and layouts of the plurality of first finger portions 202 can be selectively adjusted by the layouts (presence or absence, the number, an arrangement location, etc.) of the first finger portions 202A to 202C.

The first finger portion 202A is led out to a region opposing the fourth arrangement region 105D in the first direction X. The fourth arrangement region 105D is the inter-pad region between the first pad wiring 101 and the second pad wiring 102. In this embodiment, the first finger portion 202A is positioned in a region on the other side in the second direction Y with respect to the second pad wiring 102 on the one side in the second direction Y and partially opposes the fourth pad wiring 104 in the first direction X.

The first finger portion 202A may cross an intermediate portion of the fourth pad wiring 104 or may be positioned on the first pad wiring 101 side with respect to the intermediate portion of the fourth pad wiring 104. The first finger portion 202A intersects (is orthogonal to) one or a plurality of the first lower wirings 81 and one or a plurality of the second lower wirings 82 passing directly below the fourth pad wiring 104 in the first direction X.

The first finger portion 202A is electrically connected to, of one or a plurality of the first lower wirings 81 covered with the fourth pad wiring 104, portions of the first lower wirings 81 exposed from the fourth pad wiring 104. On the other hand, the first finger portion 202A is electrically disconnected from one or a plurality of the second lower wirings 82 passing directly below the fourth pad wiring 104.

The first finger portion 202B is led out to a region opposing the entire region of the fourth arrangement region 105D in the first direction X. In this embodiment, the first finger portion 202B opposes the entire region of the fourth pad wiring 104 in the first direction X. In this embodiment, the first finger portion 202B is led out to a region partially opposing the second pad wiring 102 in the first direction X.

The first finger portion 202B may cross an intermediate portion of the second pad wiring 102 or may be positioned on the fourth pad wiring 104 side with respect to the intermediate portion of the second pad wiring 102. The first finger portion 202B intersects (is orthogonal to) one or a plurality of (preferably, all of) the first lower wirings 81 and one or a plurality of (preferably, all of) the second lower wirings 82 passing directly below the fourth pad wiring 104 in the first direction X.

The first finger portion 202B is electrically connected to, of one or a plurality of (preferably, all of) the first lower wirings 81 covered with the fourth pad wiring 104, portions of the first lower wirings 81 exposed from the fourth pad wiring 104. On the other hand, the first finger portion 202B is electrically disconnected from one or a plurality of (preferably, all of) the second lower wirings 82 passing directly below the fourth pad wiring 104.

Also, the first finger portion 202B is electrically connected to, of one or a plurality of the first lower wirings 81 covered with the second pad wiring 102, portions of the first lower wirings 81 exposed from the second pad wiring 102. On the other hand, the first finger portion 202B is electrically disconnected from one or a plurality of the second lower wirings 82 passing directly below the second pad wiring 102. The first finger portion 202B forms a current path of the drain source current Ids together with the second pad wiring 102 opposing (closely opposing) the first finger portion 202B in the first direction X.

The first finger portion 202C is led out to a region opposing the entire region of the second pad wiring 102 in the first direction X. In this embodiment, the first finger portion 202C is led out to a region partially opposing the region between the first pad wiring 101 and the second pad wiring 102 in the first direction X.

A distal end portion of the first finger portion 202C may be positioned on the second pad wiring 102 side with respect to first pad wiring 101. The distal end portion of the first finger portion 202C may partially oppose the first pad wiring 101 in the first direction X. As a matter of course, the first finger portion 202C may be led out to a region opposing the entire region of the first pad wiring 101 in the first direction X. In these cases, the first finger portion 202C may oppose the first interconnect structure 108 in the first direction X.

The first finger portion 202C intersects (is orthogonal to) one or a plurality of (preferably, all of) the first lower wirings 81 and one or a plurality of (preferably, all of) the second lower wirings 82 passing directly below the fourth pad wiring 104 in the first direction X.

The first finger portion 202C is electrically connected to, of one or a plurality of (preferably, all of) the first lower wirings 81 covered with the fourth pad wiring 104, portions of the first lower wirings 81 exposed from the fourth pad wiring 104. On the other hand, the first finger portion 202C is electrically disconnected from one or a plurality of (preferably, all of) the second lower wirings 82 passing directly below the fourth pad wiring 104.

Also, the first finger portion 202C is electrically connected to, of one or a plurality of (preferably, all of) the first lower wirings 81 covered with the second pad wiring 102, portions of the first lower wirings 81 exposed from the second pad wiring 102. On the other hand, the first finger portion 202C is electrically disconnected from one or a plurality of (preferably, all of) the second lower wirings 82 passing directly below the second pad wiring 102. The first finger portion 202C forms a current path of the drain source current Ids together with the second pad wiring 102 opposing (closely opposing) the f first finger portion 202C in the first direction X.

Similarly to the case of the first layout example, the second side wiring 192 covers, in the region on the one side in the second direction Y, the end portion of the outermost wiring group 80 (that is, the first wiring group 80A) positioned on the one side in the first direction X.

In this embodiment, the second side wiring 192 includes a second body portion 203. The second body portion 203 is led out from the second pad wiring 102 to the one side in the first direction X and covers the end portion of the first wiring group 80A in the region on the one side in the second direction Y. That is, the second body portion 203 is constituted of a lead-out portion led out from the outermost second pad wiring 102 to the end portion of the first wiring group 80A and is physically and electrically connected to the second pad wiring 102.

The second body portion 203 may have a width less than the width of the first pad wiring 101 (the second pad wiring 102) in the first direction X. As a matter of course, the width of the second body portion 203 may be larger than the width of the first pad wiring 101 (the second pad wiring 102). The width of the second body portion 203 is larger than the width of the first lower wiring 81 (the second lower wiring 82).

The second body portion 203 extends as a band in the second direction Y along the first wiring group 80A. The second body portion 203 intersects (is orthogonal to) at least one (in this embodiment, a plurality) of the first lower wirings 81 and at least one (in this embodiment, a plurality) of the second lower wirings 82 of the first wiring group 80A.

In this embodiment, the second body portion 203 is led out to the region opposing the first pad wiring 101 in the first direction X in the region on the one side in the second direction Y. The second body portion 203 opposes the entire region of the first pad wiring 101 in the first direction X. The second body portion 203 intersects (is orthogonal to) one or a plurality of (preferably, all of) the first lower wirings 81 and one or a plurality of (preferably, all of) the second lower wirings 82 passing directly below the first pad wiring 101 in the first direction X.

The second body portion 203 is electrically connected to, of one or a plurality of (preferably, all of) the second lower wirings 82 covered with the first pad wiring 101, portions of the second lower wirings 82 exposed from the first pad wiring 101. On the other hand, the second body portion 203 is electrically disconnected from one or a plurality of (preferably, all of) the first lower wirings 81 passing directly below the first pad wiring 101. Consequently, the second body portion 203 forms a current path of the drain source current Ids together with the first pad wiring 101 opposing (closely opposing) the second body portion 203 in the first direction X.

Also, the second body portion 203 is arranged in the region on the one side in the second direction Y at intervals in the first direction X and the second direction Y from the plurality of first finger portions 202. The second body portion 203 has a portion opposing at least one (in this embodiment, a plurality) of the first finger portions 202 of the first side wiring 191 in the first direction X.

The second body portion 203 intersects (is orthogonal to) one or a plurality of the first lower wirings 81 and one or a plurality of the second lower wirings 82 passing directly below at least one (in this embodiment, a plurality) of the first finger portions 202 in the first direction X.

The second body portion 203 is electrically connected to one or a plurality of the second lower wirings 82 passing directly below the plurality of first finger portions 202. On the other hand, the second body portion 203 is electrically disconnected from one or a plurality of (preferably, all of) the first lower wirings 81 passing directly below the plurality of first finger portions 202. Consequently, the second body portion 203 forms a current path of the drain source current Ids together with the plurality of first finger portions 202 opposing (closely opposing) the second body portion 203 in the first direction X.

The second body portion 203 increases the current path (the connection area) with respect to at least one (in this embodiment, a plurality) of the second lower wirings 82 at the end portion of the first wiring group 80A. Similarly to the second pad wiring 102, etc., the second body portion 203 is electrically connected to the corresponding second lower wirings 82 via the plurality of second upper via electrodes 118.

The second side wiring 192 includes at least one (in this embodiment, a plurality) of second finger portions 204 led out as bands (in this embodiment, in a rectangular shape) from the second body portion 203 toward the other side in the second direction Y. The second finger portions 204 are electrically connected to the second pad wiring 102 via the second body portion 203 and are electrically disconnected from the first pad wiring 101 and the fourth pad wiring 104.

The number of the second finger portions 204 is arbitrary and is appropriately adjusted depending on a size of the second body portion 203, the size of the first wiring group 80A, etc. The number of the second finger portions 204 may be not less than 1 and not more than 50. The number of the second finger portions 204 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The number of the second finger portions 204 is preferably equal to the number of the first finger portions 202. According to this configuration, variation in the wiring resistance between the first finger portions 202 and the second finger portions 204 is prevented. In this embodiment, the three second finger portions 204 are provided.

Each of the plurality of second finger portions 204 has a width less than the width of the second body portion 203 in the first direction X and is arrayed at intervals in the first direction X. The plurality of second finger portions 204 are led out as bands (in this embodiment, in a rectangular shape) to the other side in the second direction Y. That is, the plurality of second finger portions 204 are arrayed in a comb teeth shape extending in the second direction Y and oppose each other in the first direction X.

Specifically, the plurality of second finger portions 204 respectively enter regions between the plurality of first finger portions 202 and extend in the second direction Y in the regions between the plurality of first finger portions 202. The plurality of second finger portions 204 and the plurality of first finger portions 202 are alternately arrayed in the first direction X, and the plurality of second finger portions 204 oppose the plurality of first finger portions 202 in the first direction X. Consequently, the plurality of second finger portions 204 are arrayed in a comb teeth shape that meshes with the plurality of first finger portions 202. The plurality of second finger portions 204 are arranged at intervals from the first body portion 201 toward the second body portion 203.

As a matter of course, at least one of the second finger portions 204 may be arranged at intervals in the second direction Y from at least one of the first finger portions 202 and may oppose at least one of the first finger portions 202 in the second direction Y. The plurality of second finger portions 204 may be led out in a trapezoidal shape (preferably, an isosceles trapezoidal shape) or a triangular shape (preferably, an isosceles triangular shape).

The width of each of the second finger portions 204 is less than the width of the second pad wiring 102 (the first pad wiring 101). The width of each of the second finger portions 204 is less than the width of the fourth pad wiring 104 (the third pad wiring 103). The width of each of the second finger portions 204 is preferably larger than the width of each of the first lead-out wirings 109 (the second lead-out wiring 113).

The width of each of the second finger portions 204 is larger than the width of the first lower wiring 81 (the second lower wiring 82). It is preferable that the width of each of the second finger portions 204 is substantially equal to the width of each of the first finger portions 202. According to this configuration, variation in the wiring resistance between the first finger portions 202 and the second finger portions 204 is prevented.

In this embodiment, the plurality of second finger portions 204 have wiring lengths different from each other in the second direction Y. Specifically, the plurality of second finger portions 204 respectively have wiring lengths that sequentially increase toward the peripheral edge of the chip 2. As a matter of course, the plurality of second finger portions 204 may have the same wiring length as each other in the second direction Y. In this case, distal end portions of the plurality of second finger portions 204 are positioned on the same imaginary straight line extending along the first direction X.

As a matter of course, the plurality of second finger portions 204 may respectively have wiring lengths that sequentially increase toward the inner side of the chip 2. The plurality of second finger portions 204 may have a layout in which the second finger portions 204 having a relatively long wiring length and the second finger portions 204 having a relatively short wiring length are alternately arrayed in the first direction X.

The plurality of second finger portions 204 preferably have wiring lengths substantially equal to the wiring lengths of the plurality of first finger portions 202. In a case where the plurality of first finger portions 202 have the wiring lengths different from each other, it is preferable that at least one of the second finger portions 204 has a wiring length substantially equal to the wiring length of at least one of the first finger portions 202 which is adjacent to the one of the second finger portions 204 in the first direction X or the second direction Y. It is preferable that the total wiring length of the plurality of second finger portions 204 is substantially equal to the total wiring length of the plurality of first finger portions 202.

The plurality of second finger portions 204 increase the current path (the connection area) with respect to at least one (in this embodiment, a plurality) of the second lower wirings 82 at the end portion of the first wiring group 80A. Similarly to the second lead-out wiring 113, etc., the plurality of second finger portions 204 are electrically connected to the corresponding second lower wirings 82 via the plurality of second upper via electrodes 118.

Hereinafter, the second finger portion 204 having a first wiring length is referred to as a second finger portion 204A, the second finger portion 204 having a second wiring length larger than the first wiring length is referred to as a second finger portion 204B, and the second finger portion 204 having a third wiring length larger than the second wiring length is referred to as a second finger portion 204C. The second finger portion 204A is arranged in the innermost region, the second finger portion 204B is arranged in an intermediate region, and the second finger portion 204C is arranged in the outermost region.

The plurality of second finger portions 204 may be constituted of at least one of the second finger portions 204A to 204C. The wiring lengths and layouts of the plurality of second finger portions 204 can be selectively adjusted by layouts (presence or absence, the number, an arrangement location, etc.) of the second finger portions 204A to 204C.

The second finger portion 204A is led out to a region opposing the fourth arrangement region 105D in the first direction X. In this embodiment, the second finger portion 204A is positioned in a region on the one side in the second direction Y with respect to the first pad wiring 101 on the other side in the second direction Y and partially opposes the fourth pad wiring 104 in the first direction X.

The second finger portion 204A may cross the intermediate portion of the fourth pad wiring 104 or may be positioned on the second pad wiring 102 side with respect to the intermediate portion of the fourth pad wiring 104. The second finger portion 204A intersects (is orthogonal to) one or a plurality of the first lower wirings 81 and one or a plurality of the second lower wirings 82 passing directly below the fourth pad wiring 104 in the first direction X.

The second finger portion 204A is electrically connected to, of one or a plurality of the second lower wirings 82 covered with the fourth pad wiring 104, portions of the second lower wirings 82 exposed from the fourth pad wiring 104. On the other hand, the second finger portion 204A is electrically disconnected from one or a plurality of the first lower wirings 81 passing directly below the fourth pad wiring 104.

The second finger portion 204A is led out to a region opposing at least one of the first finger portions 202 in the first direction X. In this embodiment, the second finger portion 204A opposes the first finger portion 202B in the first direction X and opposes the first finger portion 202A in the second direction Y.

The second finger portion 204A intersects (is orthogonal to) one or a plurality of the first lower wirings 81 and one or a plurality of the second lower wirings 82 passing directly below the first finger portions 202 in the first direction X. The second finger portion 204A is electrically connected to, of one or a plurality of (preferably, all of) the second lower wirings 82 covered with the first finger portions 202, portions of the second lower wirings 82 exposed from the first finger portions 202.

On the other hand, the second finger portion 204A is electrically disconnected from one or a plurality of the first lower wirings 81 passing directly below the first finger portions 202. Consequently, the second finger portion 204A forms, on a side of the fourth arrangement region 105D (the fourth pad wiring 104), a current path of the drain source current Ids together with the first finger portions 202 opposing the second finger portion 204A in the first direction X.

The second finger portion 204B is led out to a region opposing the entire region of the fourth arrangement region 105D in the first direction X. In this embodiment, the second finger portion 204B opposes the entire region of the fourth pad wiring 104 in the first direction X. In this embodiment, the second finger portion 204B is led out to a region partially opposing the first pad wiring 101 in the first direction X.

The second finger portion 204B may cross an intermediate portion of the first pad wiring 101 or may be positioned on the fourth pad wiring 104 side with respect to the intermediate portion of the first pad wiring 101. The second finger portion 204B intersects (is orthogonal to) one or a plurality of (preferably, all of) the first lower wirings 81 and one or a plurality of (preferably, all of) the second lower wirings 82 passing directly below the fourth pad wiring 104 in the first direction X.

The second finger portion 204B is electrically connected to, of one or a plurality of (preferably, all of) the second lower wirings 82 covered with the fourth pad wiring 104, portions of the second lower wirings 82 exposed from the fourth pad wiring 104. On the other hand, the second finger portion 204B is electrically disconnected from one or a plurality of (preferably, all of) the first lower wirings 81 passing directly below the fourth pad wiring 104.

Also, the second finger portion 204B is electrically connected to, of one or a plurality of the second lower wirings 82 covered with the first pad wiring 101, portions of the second lower wirings 82 exposed from the first pad wiring 101. On the other hand, the second finger portion 204B is electrically disconnected from one or a plurality of the first lower wirings 81 passing directly below the first pad wiring 101. Consequently, the second finger portion 204B forms a current path of the drain source current Ids together with the first pad wiring 101 opposing (closely opposing) the second finger portion 204B in the first direction X.

Also, the second finger portion 204B is led out to a region opposing at least one of the first finger portions 202 in the first direction X. In this embodiment, the second finger portion 204B opposes the first finger portion 202A and the first finger portion 202B in the first direction X.

The second finger portion 204B intersects (is orthogonal to) one or a plurality of the first lower wirings 81 and one or a plurality of the second lower wirings 82 passing directly below the plurality of first finger portions 202 in the first direction X. The second finger portion 204B is electrically connected to, of one or a plurality of the second lower wirings 82 covered with the plurality of first finger portions 202, portions of the second lower wirings 82 exposed from the plurality of first finger portions 202.

On the other hand, the second finger portion 204B is electrically disconnected from one or a plurality of the first lower wirings 81 passing directly below the plurality of first finger portions 202. Consequently, the second finger portion 204B forms a current path of the drain source current Ids together with the plurality of first finger portions 202 opposing (closely opposing) the second finger portion 204B in the first direction X.

Also, the second finger portion 204B is formed at intervals in the first direction X from the first body portion 201 and has a portion partially opposing the first body portion 201 in the first direction X. The second finger portion 204B intersects (is orthogonal to) one or a plurality of the first lower wirings 81 and one or a plurality of the second lower wirings 82 passing directly below the first body portion 201 in the first direction X.

The second finger portion 204B is electrically connected to one or a plurality of the second lower wirings 82 passing directly below the first body portion 201. On the other hand, the second finger portion 204B is electrically disconnected from one or a plurality of the first lower wirings 81 passing directly below the first body portion 201. Consequently, the second finger portion 204B forms a current path of the drain source current Ids together with the first body portion 201.

The second finger portion 204C is led out to a region opposing the entire region of the first pad wiring 101 in the first direction X. In this embodiment, the second finger portion 204C is led out to a region partially opposing the region between the first pad wiring 101 and the second pad wiring 102 in the first direction X.

A distal end portion of the second finger portion 204C may be positioned on the first pad wiring 101 side with respect to second pad wiring 102. The distal end portion of the second finger portion 204C may partially oppose the second pad wiring 102 in the first direction X. As a matter of course, the second finger portion 204C may be led out to a region opposing the entire region of the second pad wiring 102 in the first direction X. In these cases, the second finger portion 204C may oppose the first interconnect structure 108 in the first direction X.

The second finger portion 204C intersects (is orthogonal to) one or a plurality of (preferably, all of) the first lower wirings 81 and one or a plurality of (preferably, all of) the second lower wirings 82 passing directly below the fourth pad wiring 104 in the first direction X.

The second finger portion 204C is electrically connected to, of one or a plurality of (preferably, all of) the second lower wirings 82 covered with the fourth pad wiring 104, portions of the second lower wirings 82 exposed from the fourth pad wiring 104. On the other hand, the second finger portion 204C is electrically disconnected from one or a plurality of (preferably, all of) the first lower wirings 81 passing directly below the fourth pad wiring 104. That is, the second finger portion 204C forms, on a side of the fourth pad wiring 104, a current path of the drain source current Ids together with the first finger portions 202 opposing (closely opposing) the second finger portion 204C in the first direction X.

Also, the second finger portion 204C is electrically connected to, of one or a plurality of (preferably, all of) the second lower wirings 82 covered with the first pad wiring 101, portions of the second lower wirings 82 exposed from the first pad wiring 101. On the other hand, the second finger portion 204C is electrically disconnected from one or a plurality of (preferably, all of) the first lower wirings 81 passing directly below the first pad wiring 101. The second finger portion 204C forms a current path of the drain source current Ids together with the first pad wiring 101 opposing (closely opposing) the second finger portion 204C in the first direction X.

The second finger portion 204C is led out to a region opposing at least one of the first finger portions 202 in the first direction X. In this embodiment, the second finger portion 204C opposes the first finger portions 202A to 202C in the first direction X.

The second finger portion 204C intersects (is orthogonal to) one or a plurality of (preferably, all of) the first lower wirings 81 and one or a plurality of (preferably, all of) the second lower wirings 82 passing directly below the plurality of first finger portions 202 in the first direction X. The second finger portion 204C is electrically connected to, of one or a plurality of (preferably, all of) the second lower wirings 82 covered with the plurality of first finger portions 202, portions of the second lower wirings 82 exposed from the first finger portions 202.

On the other hand, the second finger portion 204C is electrically disconnected from one or a plurality of (preferably, all of) the first lower wirings 81 passing directly below the plurality of first finger portions 202. Consequently, the second finger portion 204C forms a current path of the drain source current Ids together with the plurality of first finger portions 202 opposing (closely opposing) the second finger portion 204C in the first direction X.

Also, the second finger portion 204C is formed at intervals in the first direction X from the first body portion 201 and has a portion partially opposing the first body portion 201 in the first direction X. The second finger portion 204C intersects (is orthogonal to) one or a plurality of the first lower wirings 81 and one or a plurality of the second lower wirings 82 passing directly below the first body portion 201 in the first direction X.

The second finger portion 204C is electrically connected to one or a plurality of the second lower wirings 82 passing directly below the first body portion 201. On the other hand, the second finger portion 204C is electrically disconnected from one or a plurality of the first lower wirings 81 passing directly below the first body portion 201. Consequently, the second finger portion 204C forms a current path of the drain source current Ids together with the first body portion 201.

Similarly to the case of the first layout example, the third side wiring 193 covers, in the region on the other side in the second direction Y, the end portion of the outermost wiring group 80 (that is, the sixth wiring group 80F) positioned on the other side in the first direction X. Similarly to the first side wiring 191, the third side wiring 193 includes the first body portion 201 and the first finger portion 202. The configuration of the third side wiring 193 is obtained by replacing the first wiring group 80A with the sixth wiring group 80F and replacing the fourth arrangement region 105D (the fourth pad wiring 104) with the third arrangement region 105C (the third pad wiring 103) in the description of the first side wiring 191.

Similarly to the case of the first layout example, the fourth side wiring 194 covers, in the region on the one side in the second direction Y, the end portion of the outermost wiring group 80 (that is, the sixth wiring group 80F) positioned on the one side in the first direction X. Similarly to the second side wiring 192, the fourth side wiring 194 includes the second body portion 203 and the second finger portion 204. The configuration of the fourth side wiring 194 is obtained by replacing the first wiring group 80A with the sixth wiring group 80F and replacing the fourth arrangement region 105D (the fourth pad wiring 104) with the third arrangement region 105C (the third pad wiring 103) in the description of the second side wiring 192.

As described above, the semiconductor device 1C includes the wiring groups 80, the first pad wiring 101, the second pad wiring 102, the inter-pad regions (105C and 105D), the first side wiring 191, and the second side wiring 192. Each of the wiring group 80 includes the plurality of first lower wirings 81 and the plurality of second lower wirings 82 arrayed as stripes extending in the first direction X.

The first pad wiring 101 is arranged at least one of the first lower wirings 81. The second pad wiring 102 is arranged on at least one of the second lower wiring 82 at intervals from the first pad wiring 101 in the second direction Y intersecting the first direction X. The inter-pad region (105C or 105D) is defined between the first pad wiring 101 and the second pad wiring 102.

The first side wiring 191 is led out from the first pad wiring 101 to a region opposing the inter-pad region (105C or 105D) on the one side in the first direction X. The first side wiring 191 is electrically connected to at least one of the first lower wirings 81 passing through the inter-pad region (105C or 105D). The second side wiring 192 is led out from the second pad wiring 102 to a region opposing the inter-pad region (105C or 105D) on the one side in the first direction X. The second side wiring 192 is electrically connected to one of the second lower wirings 82 passing through the inter-pad region (105C or 105D).

According to this configuration, the semiconductor device 1C having a novel wiring structure is provided. In the semiconductor device 1C, the current path connecting the first lower wiring 81 passing through the inter-pad region (105C or 105D) to the first pad wiring 101 is shortened by the first side wiring 191, and the wiring resistance caused by said first lower wiring 81 is reduced. Also, the current path connecting the second lower wiring 82 passing through the inter-pad region (105C or 105D) to the second pad wiring 102 is shortened by the second side wiring 192, and the wiring resistance caused by the second lower wiring 82 is reduced.

Such a configuration is effective in reducing the ON-resistance between the first pad wiring 101 and the second pad wiring 102 in the case where a voltage is applied between the first pad wiring 101 and the second pad wiring 102 and a current is generated between the first pad wiring 101 and the second pad wiring 102.

The wiring group 80 preferably includes the plurality of first lower wirings 81 and the plurality of second lower wirings 82 alternately arrayed in the second direction Y. According to this configuration, the electrical symmetry of the plurality of first lower wirings 81 and the plurality of second lower wirings 82 is improved. Consequently, variation in the wiring resistance between the first lower wiring 81 and the second lower wiring 82 is prevented.

It is preferable that the first pad wiring 101 is electrically connected to at least one of the first lower wirings 81. According to this configuration, the wiring distance connecting the first lower wiring 81 positioned directly below the first pad wiring 101 to the first pad wiring 101 is shortened, and the wiring resistance caused by the first lower wiring 81 is reduced.

It is preferable that the second pad wiring 102 is electrically connected to at least one of the second lower wirings 82. According to this configuration, the wiring distance connecting the second lower wiring 82 positioned directly below the second pad wiring 102 to the second pad wiring 102 is shortened, and the wiring resistance caused by the second lower wiring 82 is reduced.

The first pad wiring 101 may overlap at least one of the first lower wirings 81 and at least one of the second lower wirings 82. The first pad wiring 101 may overlap a plurality of the first lower wirings 81 and a plurality of the second lower wirings 82. The second pad wiring 102 may overlap at least one of the first lower wirings 81 and at least one of the second lower wirings 82. The second pad wiring 102 may overlap a plurality of the first lower wirings 81 and a plurality of the second lower wirings 82.

The second side wiring 192 preferably opposes the first side wiring 191 in the first direction (X). According to this configuration, the first side wiring 191 can be electrically connected to, of the first lower wirings 81 covered with the second side wiring 192, portions of the first lower wirings 81 exposed from the second side wiring 192. Therefore, the wiring distance connecting the first lower wirings 81 partially hidden by the second side wiring 192 to the first pad wiring 101 is shortened.

Similarly, the second side wiring 192 can be electrically connected to, of the second lower wirings 82 covered with the first side wiring 191, portions of the second lower wirings 82 exposed from the first side wiring 191. Therefore, the wiring distance connecting the second lower wirings 82 partially hidden by the first side wiring 191 to the second pad wiring 102 is shortened.

Also, according to this configuration, in the case where a current is generated between the first pad wiring 101 and the second pad wiring 102, a relatively short current path via the first lower wiring 81 and the second lower wiring 82 can be formed between the first side wiring 191 and the second side wiring 192. Such a configuration is effective in reducing the ON-resistance.

The first side wiring 191 preferably includes at least one of the first finger portions 202. It is preferable that at least one of the first finger portions 202 is led out from the first pad wiring 101 to the region opposing the inter-pad region (105C or 105D) on the one side in the first direction X and is electrically connected to at least one of the first lower wirings 81 passing through the inter-pad region (105C or 105D). According to this configuration, the current path connecting the first lower wirings 81 passing through the inter-pad region (105C or 105D) to the first pad wiring 101 is shortened by the first finger portion 202.

The second side wiring 192 preferably includes at least one of the second finger portions 204. It is preferable that at least one of the second finger portions 204 is led out from the second pad wiring 102 to the region opposing the inter-pad region (105C or 105D) on the one side in the first direction X and is electrically connected to at least one of the second lower wirings 82 passing through the inter-pad region (105C or 105D). According to this configuration, the current path connecting the second lower wirings 82 passing through the inter-pad region (105C or 105D) are connected to the second pad wiring 102 is shortened by the second finger portion 204.

It is preferable that at least one of the second finger portions 204 opposes at least one of the first finger portions 202 in the first direction X. According to this configuration, the first finger portion 202 can be electrically connected to, of the first lower wirings 81 covered with the second finger portion 204, portions of the first lower wirings 81 exposed from the second finger portion 204. Therefore, the wiring distance connecting the first lower wirings 81 partially hidden by the second finger portion 204 to the first pad wiring 101 is shortened.

Similarly, the second finger portion 204 can be electrically connected to, of the second lower wirings 82 covered with the first finger portion 202, portions of the second lower wirings 82 exposed from the first finger portion 202. Therefore, the wiring distance connecting the second lower wirings 82 partially hidden by the first finger portion 202 to the second pad wiring 102 is shortened.

Also, according to this configuration, in the case where a current is generated between the first pad wiring 101 and the second pad wiring 102, a relatively short current path via the first lower wiring 81 and the second lower wiring 82 can be formed between the first finger portion 202 and the second finger portion 204. Such a configuration is effective in reducing the ON-resistance.

At least one of the first finger portions 202 may overlap the plurality of first lower wirings 81 and the plurality of second lower wirings 82 in a region opposing the inter-pad region (105C or 105D). At least one of the second finger portions 204 may overlap the plurality of first lower wirings 81 and the plurality of second lower wirings 82 in a region opposing the inter-pad region (105C or 105D).

It is preferable that at least one of the first finger portions 202 crosses an intermediate portion of the inter-pad region (105C or 105D). According to this configuration, the first finger portion 202 can be connected to the first lower wirings 81 positioned closer to the second pad wiring 102 than the intermediate portion of the inter-pad region (105C or 105D).

It is preferable that at least one of the first finger portions 202 is led out to a region opposing the second pad wiring 102 on the one side in the first direction X. According to this configuration, the first finger portion 202 can be electrically connected to, of the first lower wirings 81 covered with the second pad wiring 102, portions of the first lower wirings 81 exposed from the second pad wiring 102.

It is preferable that at least one of the second finger portions 204 crosses an intermediate portion of the inter-pad region (105C or 105D). According to this configuration, the second finger portion 204 can be connected to the second lower wirings 82 positioned closer to the first pad wiring 101 than the intermediate portion of the inter-pad region (105C or 105D).

It is preferable that at least one of the second finger portions 204 is led out to a region opposing the first pad wiring 101 on the one side in the first direction X. According to this configuration, the second finger portion 204 can be electrically connected to, of the second lower wirings 82 covered with the first pad wiring 101, portions of the second lower wirings 82 exposed from the first pad wiring 101.

The first side wiring 191 preferably includes the plurality of first finger portions 202. According to this configuration, the current path connecting the first lower wirings 81 to the first pad wiring 101 is shortened by the plurality of first finger portions 202. The second side wiring 192 preferably includes the plurality of second finger portions 204. The current path connecting the second lower wirings 82 to the second pad wiring 102 is shortened by the plurality of second finger portions 204.

The plurality of first finger portions 202 are preferably arrayed in a comb teeth shape. The plurality of second finger portions 204 are preferably arrayed in a comb teeth shape. The plurality of second finger portions 204 are preferably arrayed in a comb teeth shape that meshes with the plurality of first finger portions 202.

According to this configuration, both the wiring distance connecting the first lower wirings 81 on the second pad wiring 102 side to the first pad wiring 101, and the wiring distance connecting the second lower wirings 82 on the first pad wiring 101 side to the second pad wiring 102 are efficiently shortened. Also, a relatively short current path via the first lower wirings 81 and the second lower wirings 82 can be formed between the plurality of first finger portions 202 and the plurality of second finger portions 204. Such a configuration is effective in reducing the ON-resistance.

The plurality of first finger portions 202 may have a wiring length different from each other in the second direction Y. According to this configuration, the plurality of first finger portions 202 can be respectively electrically connected to the different first lower wirings 81. Also, the wiring distance between the first lower wirings 81 and the first pad wiring 101 can be adjusted by the plurality of first finger portions 202.

The plurality of second finger portions 204 may have a wiring length different from each other in the second direction Y. According to this configuration, the plurality of second finger portions 204 can be respectively electrically connected to the different second lower wirings 82. Also, the wiring distance between the second lower wirings 82 and the second pad wiring 102 can be adjusted by the plurality of second finger portions 204.

The plurality of wiring groups 80 are arrayed at intervals in the first direction X. In this case, the first pad wiring 101, the second pad wiring 102, the inter-pad regions (105C and 105D), the first side wiring 191, and the second side wiring 192 may be formed on the outermost wiring group 80 in the first direction X among the plurality of wiring groups 80.

The semiconductor device 1C may include intermediate pad wirings (103 and 104) arranged in an inter-pad region (105C or 105D). It is preferable that the intermediate pad wirings (103 and 104) are electrically disconnected from the plurality of first lower wirings 81 and the plurality of second lower wirings 82.

According to this configuration, the first side wiring 191 can be electrically connected to, of the first lower wirings 81 hidden by the intermediate pad wiring (103, 104), portions of the first lower wirings 81 exposed from the intermediate pad wiring (103, 104). Similarly, the second side wiring 192 can be electrically connected to, of the second lower wirings 82 hidden by the intermediate pad wiring (103, 104), portions of the second lower wirings 82 exposed from the intermediate pad wiring (103, 104).

According to this configuration, in the case where a current is generated between the first pad wiring 101 and the second pad wiring 102, a relatively short current path via the first lower wirings 81 and the second lower wirings 82 can be formed between the first side wiring 191 and the second side wiring 192 on a side of the intermediate pad wiring (103 or 104).

The semiconductor device 1C preferably includes the first pad electrodes 181 arranged on the first pad wirings 101 and the second pad electrodes 182 arranged on the second pad wirings 102. According to this configuration, the wiring distance connecting the first lower wirings 81 to the first pad electrode 181 is shortened, and the wiring distance connecting the second lower wirings 82 to the second pad electrode 182 is shortened.

The semiconductor device 1C preferably includes the chip 2 and the device structure formed in the chip 2. In this case, the device structure includes the first application end to which the first potential is to be applied and the second application end to which the second potential different from the first potential is to be applied. The plurality of first lower wirings 81 are electrically connected to the first application end on the chip 2, and the plurality of second lower wirings 82 are electrically connected to the second application end in the chip 2. According to this configuration, the ON-resistance via the device structure between the first pad wiring 101 and the second pad wiring 102 is reduced.

In this embodiment, the semiconductor device 1C includes the drain source common transistor structure Tr as an example of the device structure. The transistor structure Tr has the first drain source region 28 as the first application end and the second drain source region 29 as the second application end. The plurality of first lower wirings 81 are electrically connected to the first drain source region 28, and the plurality of second lower wirings 82 are electrically connected to the second drain source region 29. According to this configuration, the ON-resistance via the transistor structure Tr is reduced between the first pad wiring 101 and the second pad wiring 102.

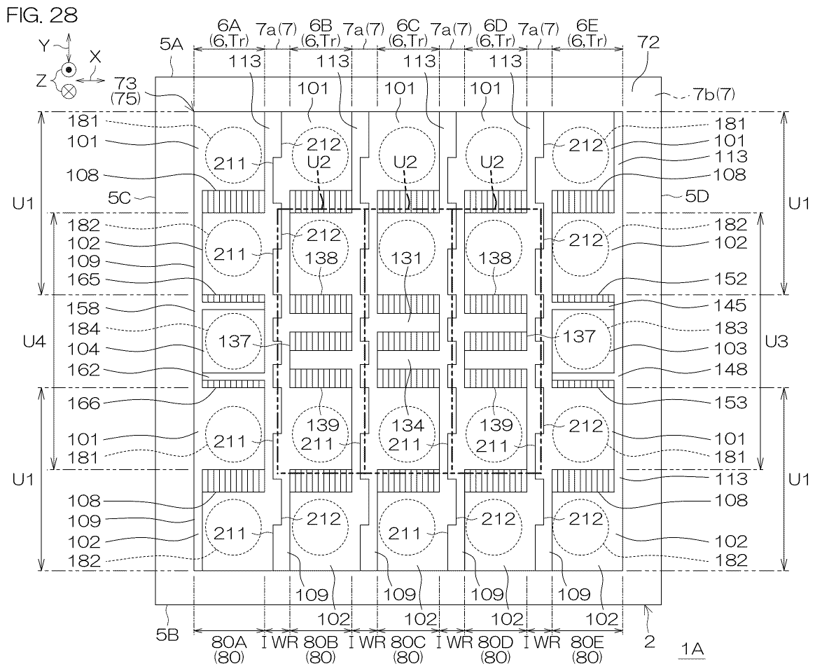

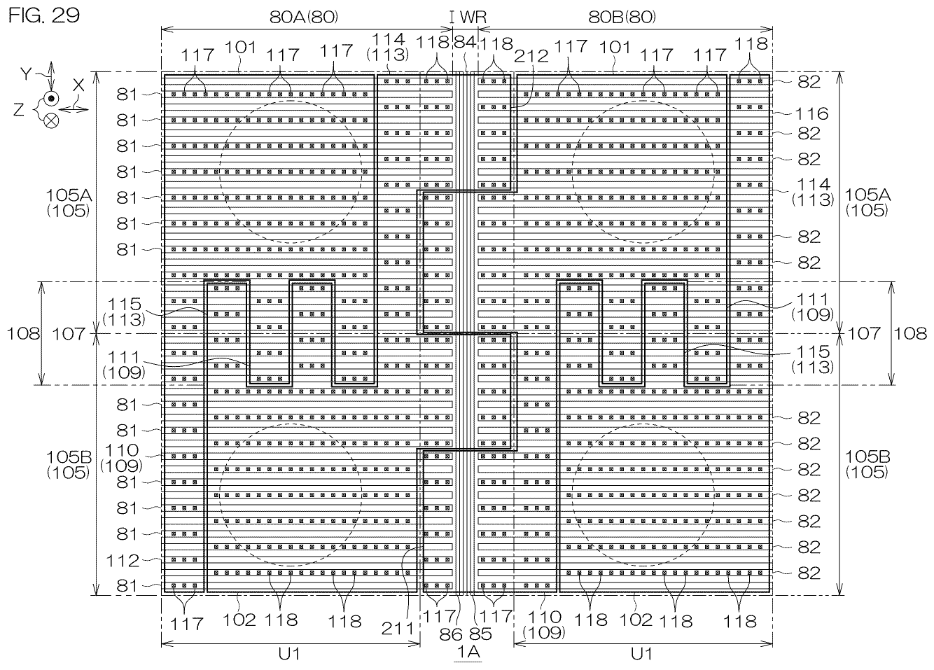

Hereinafter, modification examples of the semiconductor devices 1A to 1C according to the first to third embodiments will be described. For example, each of the semiconductor devices 1A to 1C according to the first to third embodiments has the first to fourth wiring units U1 to U4 arranged on the boundary region 7a such as to straddle the two active regions 6 adjacent in the first direction X. However, the semiconductor devices 1A to 1C according to the first to third embodiments may have a layout shown in FIGS. 28 and 29.

FIG. 28 is a plan view showing a first modification example (a modification example of the second layer wiring 75) of the semiconductor devices 1A to 1C according to the first to third embodiments. FIG. 29 is an enlarged plan view showing a main portion of the second layer wiring 75.

With reference to FIG. 28, the first wiring unit U1 may be arranged on the corresponding one active region 6. In this case, in the first wiring unit U1, the first pad wiring 101, the second pad wiring 102, and the first interconnect structure 108 are arranged on the corresponding one wiring group 80 in the same layout as that in the case of the above-described embodiment.

The first pad wiring 101, the second pad wiring 102, and the first interconnect structure 108 are arranged on the one wiring group 80 at intervals inward from both end portions (the inter-wiring region IWR) of the corresponding wiring group 80. That is, the first pad wiring 101, the second pad wiring 102, and the first interconnect structure 108 are selectively electrically connected to the plurality of first lower wirings 81 and the plurality of second lower wirings 82 of the corresponding one wiring group 80.

With reference to FIG. 29, with regard to the one and the other first wiring units U1 adjacent in the first direction X, the one first wiring unit U1 may include at least one (in this embodiment, a plurality) of first boundary branch wirings 211, and the other first wiring unit U1 may include at least one (in this embodiment, a plurality) of second boundary branch wirings 212.

The number of the first boundary branch wirings 211 is arbitrary. The number of the first boundary branch wirings 211 may be not less than 1 and not more than 50. The number of the first boundary branch wirings 211 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50. In this embodiment, the two first boundary branch wirings 211 are provided.

The number of the second boundary branch wirings 212 is arbitrary. The number of the second boundary branch wirings 212 may be not less than 1 and not more than 50. The number of the second boundary branch wirings 212 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The number of the second boundary branch wirings 212 is preferably equal to the number of the first boundary branch wirings 211. According to this configuration, variation in the wiring resistance between the first boundary branch wirings 211 and the second boundary branch wirings 212 is prevented. In this embodiment, the two second boundary branch wirings 212 are provided.

The plurality of first boundary branch wirings 211 are each led out as a band (in this embodiment, in a quadrangular shape) in the first direction X from one or both (in this embodiment, both) of the first pad wiring 101 and the first lead-out wiring 109 (the first long wiring 110) and are arrayed at intervals in the second direction Y. That is, the plurality of first boundary branch wirings 211 are formed in a comb teeth shape extending in the first direction X. The plurality of first boundary branch wirings 211 may be led out in a trapezoidal shape (preferably, an isosceles trapezoidal shape) or a triangular shape (preferably, an isosceles triangular shape).

The first boundary branch wiring 211 may have a width less than the width of the first pad wiring 101 (the second pad wiring 102) in the first direction X. As a matter of course, the width of the first boundary branch wiring 211 may be larger than the width of the first pad wiring 101 (the second pad wiring 102). The width of the first boundary branch wiring 211 is larger than the width of the first lower wiring 81 (the second lower wiring 82).

The plurality of first boundary branch wirings 211 are led out from above the one wiring group 80 (the one active region 6) onto the other wiring group 80 (the other active region 6) by crossing the inter-wiring region IWR (the boundary region 7a). The plurality of first boundary branch wirings 211 cover at least one (in this embodiment, a plurality) of the first lower wirings 81 and at least one (in this embodiment, a plurality) of the second lower wirings 82 of the other wiring group 80.

Also, the plurality of first boundary branch wirings 211 are electrically connected to at least one (in this embodiment, a plurality) of the first lower wirings 81 of the other wiring group 80. Similarly to the first lead-out wiring 109, etc., the plurality of first boundary branch wirings 211 are electrically connected to the corresponding first lower wirings 81 via the plurality of first upper via electrodes 117.

At least one of the first boundary branch wirings 211 is led out in the first direction X toward the second pad wiring 102. At least one of the first boundary branch wirings 211 is formed on the other wiring group 80 at intervals from the second pad wiring 102 in the first direction X and opposes the second pad wiring 102 in the first direction X.

At least one of the first boundary branch wirings 211 is electrically connected to, of one or a plurality of the first lower wirings 81 covered with the second pad wiring 102, portions of the first lower wirings 81 exposed from the second pad wiring 102. On the other hand, at least one of the first boundary branch wirings 211 is electrically disconnected from one or a plurality of (preferably, all of) the second lower wirings 82 passing directly below the second pad wiring 102.

At least one of the first boundary branch wirings 211 is led out in the first direction X toward the second lead-out wiring 113 (the second long wiring 114). At least one of the first boundary branch wirings 211 is formed on the other wiring group 80 at intervals from the second lead-out wiring 113 in the first direction X and opposes the second lead-out wiring 113 in the first direction X.

At least one of the first boundary branch wirings 211 is electrically connected to, of one or a plurality of the first lower wirings 81 covered with the second lead-out wiring 113, portions of the first lower wirings 81 exposed from the second lead-out wiring 113. On the other hand, at least one of the first boundary branch wirings 211 is electrically disconnected from one or a plurality of (preferably, all of) the second lower wirings 82 passing directly below the second lead-out wiring 113.

As described above, at least one of the first boundary branch wirings 211 forms a current path of the drain source current Ids together with the second pad wiring 102 opposing (closely opposing) the first boundary branch wiring 211 in the first direction X. Also, at least one of the first boundary branch wirings 211 forms a current path of the drain source current Ids together with the second lead-out wirings 113 opposing (closely opposing) the first boundary branch wiring 211 in the first direction X.

The plurality of first boundary branch wirings 211 overlap the third lower wiring 83 in a portion covering the inter-wiring region IWR. In this embodiment, the plurality of first boundary branch wirings 211 overlap both the first gate wiring 85 and the second gate wiring 86. The plurality of first boundary branch wirings 211 oppose the third lower wiring 83 (the first gate wiring 85 and the second gate wiring 86) across the second interlayer film 72 and are electrically disconnected from the third lower wiring 83.

The plurality of first boundary branch wirings 211 overlap the fourth lower wiring 84 in the portion covering the inter-wiring region IWR. In this embodiment, the plurality of first boundary branch wirings 211 overlap the first base wiring 88. The plurality of first boundary branch wirings 211 oppose the fourth lower wiring 84 (the first base wiring 88) across the second interlayer film 72 and are electrically disconnected from the fourth lower wiring 84.

The plurality of second boundary branch wirings 212 are each led out as a band (in this embodiment, in a quadrangular shape) in the first direction X from one or both (in this embodiment, both) of the second pad wiring 102 and the second lead-out wiring 113 (the second long wiring 114) and are arrayed at intervals in the second direction Y. That is, the plurality of second boundary branch wirings 212 are formed in a comb teeth shape extending in the first direction X.

The plurality of second boundary branch wirings 212 and the plurality of first boundary branch wirings 211 are alternately arrayed in the second direction Y, and the plurality of second boundary branch wirings 212 oppose the plurality of first boundary branch wirings 211 in the second direction Y. That is, the plurality of second boundary branch wirings 212 are arrayed in a comb teeth shape that meshes with the plurality of first boundary branch wirings 211. The plurality of second boundary branch wirings 212 may be led out in a trapezoidal shape (preferably, an isosceles trapezoidal shape) or a triangular shape (preferably, an isosceles triangular shape).

The second boundary branch wiring 212 may have a width smaller than the width of the first pad wiring 101 (the second pad wiring 102) in the first direction X. As a matter of course, the width of the second boundary branch wiring 212 may be larger than the width of the first pad wiring 101 (the second pad wiring 102). The width of the second boundary branch wiring 212 is larger than the width of the first lower wiring 81 (the second lower wiring 82).

The plurality of second boundary branch wirings 212 are led out from above the other wiring group 80 (the other active region 6) onto the one wiring group 80 (the one active region 6) by crossing the inter-wiring region IWR (the boundary region 7a). That is, the plurality of second boundary branch wirings 212 respectively have portions opposing the plurality of first boundary branch wirings 211 in the second direction Y on the inter-wiring region IWR (the boundary region 7a). The plurality of second boundary branch wirings 212 cover at least one (in this embodiment, a plurality) of the first lower wirings 81 and at least one (in this embodiment, a plurality) of the second lower wirings 82 of the one wiring group 80.

The plurality of second boundary branch wirings 212 are electrically connected to at least one (in this embodiment, a plurality) of the second lower wirings 82 of the one wiring group 80. Similarly to the second lead-out wiring 113, etc., the plurality of second boundary branch wirings 212 are electrically connected to the corresponding second lower wirings 82 via the plurality of second upper via electrodes 118.

At least one of the second boundary branch wirings 212 is led out in the first direction X toward the first pad wiring 101. At least one of the second boundary branch wirings 212 is formed on the one wiring group 80 at intervals from the first pad wiring 101 in the first direction X and opposes the first pad wiring 101 in the first direction X.

At least one of the second boundary branch wirings 212 is electrically connected to, of one or a plurality of the second lower wirings 82 covered with the first pad wiring 101, portions of the second lower wirings 82 exposed from the first pad wiring 101. On the other hand, at least one of the second boundary branch wirings 212 is electrically disconnected from one or a plurality of (preferably, all of) the first lower wirings 81 passing directly below the first pad wiring 101.

At least one of the second boundary branch wirings 212 is led out in the first direction X toward the first lead-out wiring 109 (the first long wiring 110). At least one of the second boundary branch wirings 212 is formed on the one wiring group 80 at intervals from the first lead-out wiring 109 in the first direction X and opposes the first lead-out wiring 109 in the first direction X.

At least one of the second boundary branch wirings 212 is electrically connected to, of one or a plurality of the second lower wirings 82 covered with the first lead-out wiring 109, portions of the second lower wirings 82 exposed from the first lead-out wiring 109. On the other hand, at least one of the second boundary branch wirings 212 is electrically disconnected from one or a plurality of (preferably, all of) the first lower wirings 81 passing directly below the first lead-out wiring 109.

As described above, at least one of the second boundary branch wirings 212 forms a current path of the drain source current Ids together with the first pad wiring 101 opposing (closely opposing) the second boundary branch wiring 212 in the first direction X. Also, at least one of the second boundary branch wirings 212 forms a current path of the drain source current Ids together with the first lead-out wiring 109 opposing (closely opposing) the second boundary branch wiring 212 in the first direction X. Also, the plurality of second boundary branch wirings 212 form a current path of the drain source current Ids together with the plurality of first boundary branch wirings 211 opposing (closely opposing) the second boundary branch wirings 212 in the second direction Y.

The plurality of second boundary branch wirings 212 overlap the third lower wiring 83 in a portion covering the inter-wiring region IWR. In this embodiment, the plurality of second boundary branch wirings 212 overlap both the first gate wiring 85 and the second gate wiring 86. The plurality of second boundary branch wirings 212 oppose the third lower wiring 83 (the first gate wiring 85 and the second gate wiring 86) across the second interlayer film 72 and are electrically disconnected from the third lower wiring 83.

The plurality of second boundary branch wirings 212 overlap the fourth lower wiring 84 in the portion covering the inter-wiring region IWR. In this embodiment, the plurality of second boundary branch wirings 212 overlap the first base wiring 88. The plurality of second boundary branch wirings 212 oppose the fourth lower wiring 84 (the first base wiring 88) across the second interlayer film 72 and are electrically disconnected from the fourth lower wiring 84.

Similarly to the case of the first wiring unit U1, the second wiring unit U2 may have at least one of the first boundary branch wirings 211 and at least one of the second boundary branch wirings 212. In this case, the first boundary branch wiring 211 is led out from above the one wiring group 80 onto the other wiring group 80 by crossing the inter-wiring region IWR, with the first routing wiring 131 (the first stem wiring 132) as a starting point. Also, the second boundary branch wiring 212 is led out from above the other wiring group 80 onto the one wiring group 80 by crossing the inter-wiring region IWR, with the second routing wiring 134 (the second stem wiring 135) as a starting point.

Similarly to the case of the first wiring unit U1, the third wiring unit U3 may have at least one of the first boundary branch wirings 211. The first boundary branch wiring 211 is led out from above the wiring group 80 on the third wiring unit U3 side onto the wiring group 80 on the second wiring unit U2 side by crossing the inter-wiring region IWR, with the third routing wiring 145 (the third stem wiring 146) as a starting point.

In this case, the second wiring unit U2 may have at least one of the second boundary branch wirings 212 directed toward the third wiring unit U3. The second boundary branch wiring 212 on the second wiring unit U2 side is led out from above the wiring group 80 on the second wiring unit U2 side onto the wiring group 80 on the third wiring unit U3 side by crossing the inter-wiring region IWR, with the second routing wiring 134 (the second stem wiring 135) as a starting point.

Similarly to the case of the first wiring unit U1, the fourth wiring unit U4 may have at least one of the second boundary branch wirings 212. The second boundary branch wiring 212 is led out from above the wiring group 80 on the fourth wiring unit U4 side onto the wiring group 80 on the second wiring unit U2 side by crossing the inter-wiring region IWR, with the sixth routing wiring 162 (the sixth stem wiring 163) as a starting point.

In this case, the second wiring unit U2 may have at least one of the first boundary branch wirings 211 directed toward the fourth wiring unit U4. The first boundary branch wiring 211 on the second wiring unit U2 side is led out from above the wiring group 80 on the second wiring unit U2 side onto the wiring group 80 on the fourth wiring unit U4 side by crossing the inter-wiring region IWR, with the first routing wiring 131 (the first stem wiring 132) as a starting point.

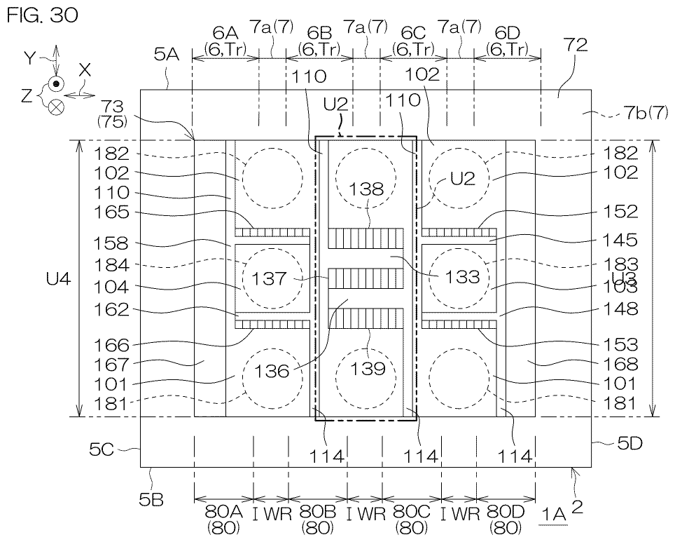

FIG. 30 is a plan view showing a second modification example of the semiconductor devices 1A to 1C according to the first to third embodiments. In FIG. 30, the plurality of arrangement regions 105 are set in a 3×3 matrix. The three first arrangement regions 105A are set on the first row, the three second arrangement regions 105B are set on the third row, the single third arrangement region 105C is set on the third column of the second row, the single fourth arrangement region 105D is set on the first column of the second row, and the single space region 106 is set on the second column of the second row.

Each of the semiconductor devices 1A to 1C (the second layer wiring 75) according to the modification example includes the single second wiring unit U2, the single third wiring unit U3, and the single fourth wiring unit U4, and does not include the first wiring unit U1. That is, the semiconductor devices 1A to 1C only need to include at least one of the first to fourth wiring units U1 to U4 and do not necessarily include all of the first to fourth wiring units U1 to U4 at the same time.

For example, the semiconductor devices 1A to 1C may include only at least one of the first to fourth wiring units U1 to U4. For example, the semiconductor devices 1A to 1C may include only at least two of the first to fourth wiring units U1 to U4. For example, the semiconductor devices 1A to 1C may include only at least three of the first to fourth wiring units U1 to U4.

The layouts of the first to fourth wiring units U1 to U4 can be selected depending to a market demand such as a size of the chip 2 or a wiring layout of a connection target. For example, the layout of the first wiring unit U1 and the layout of the second wiring unit U2 may be applied to a two-terminal device. For example, the layout of the third wiring unit U3 and the layout of the fourth wiring unit U4 can be applied to a three-terminal device.

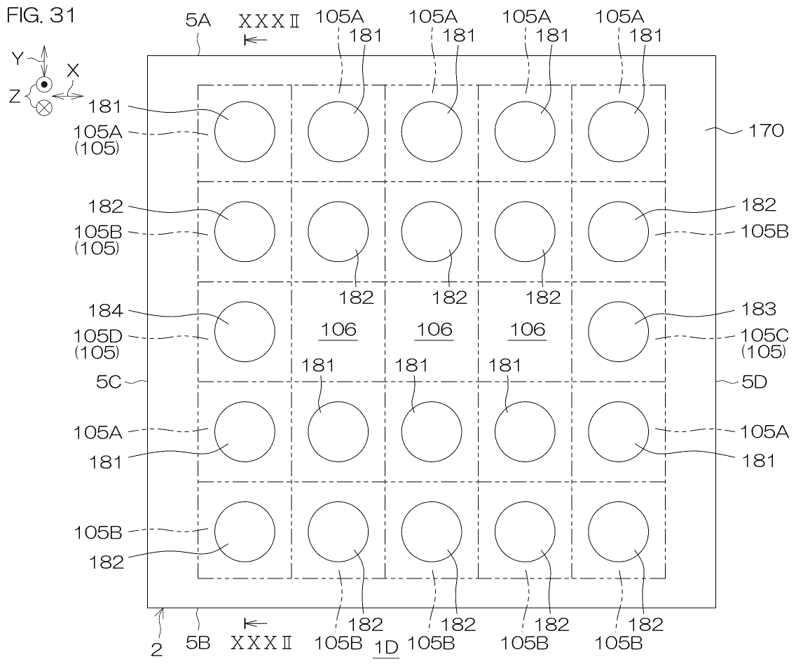

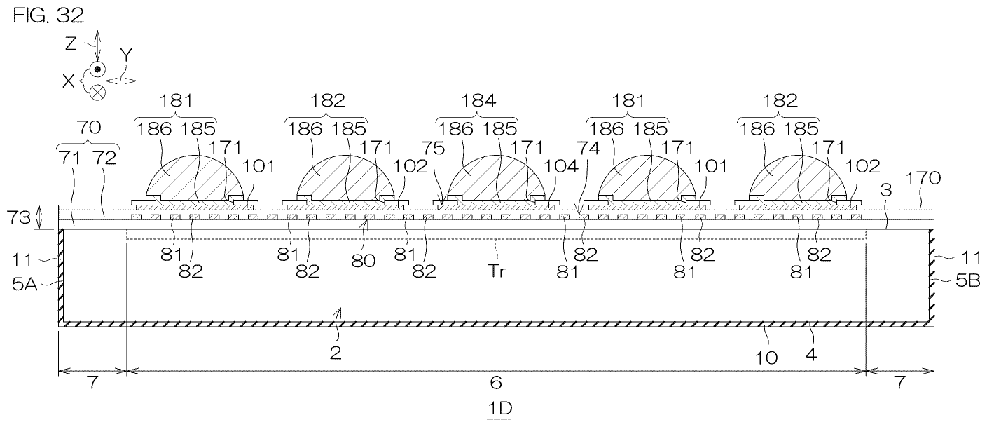

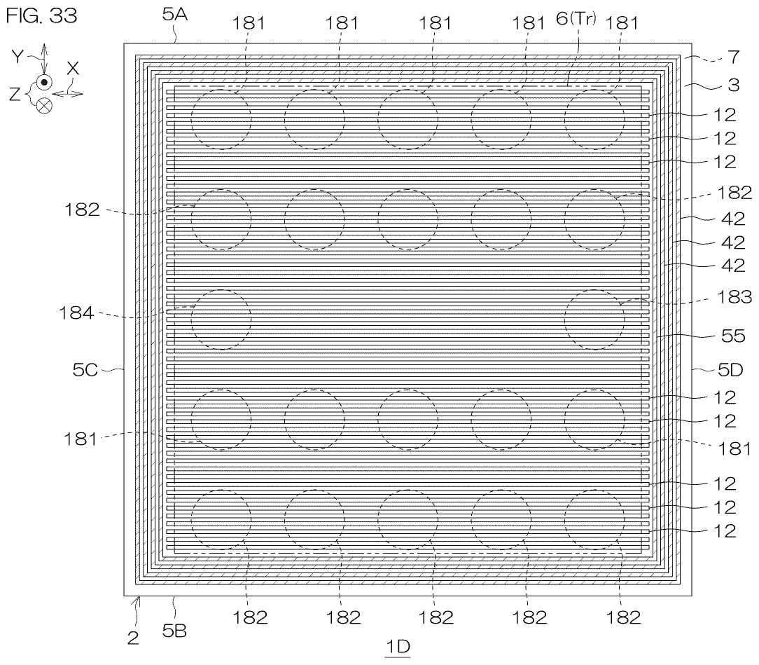

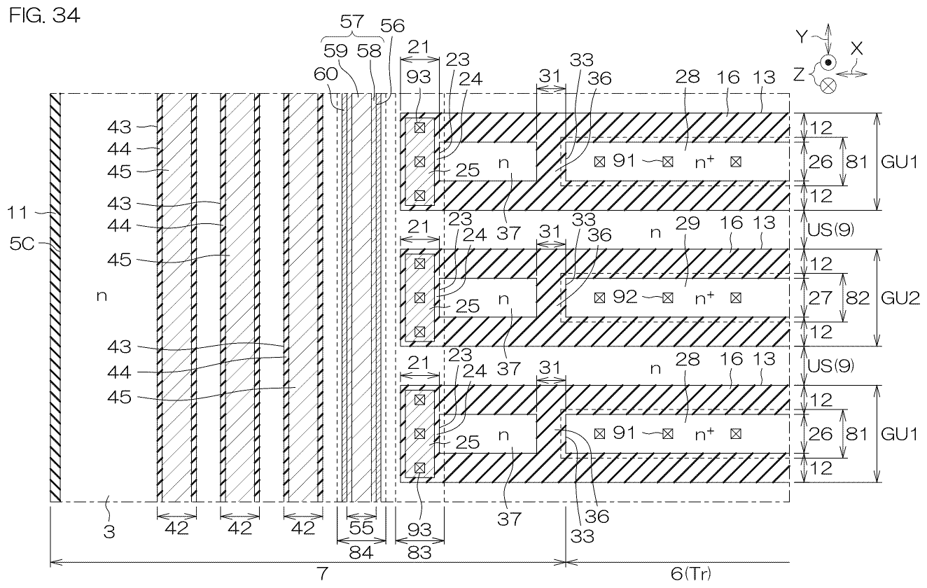

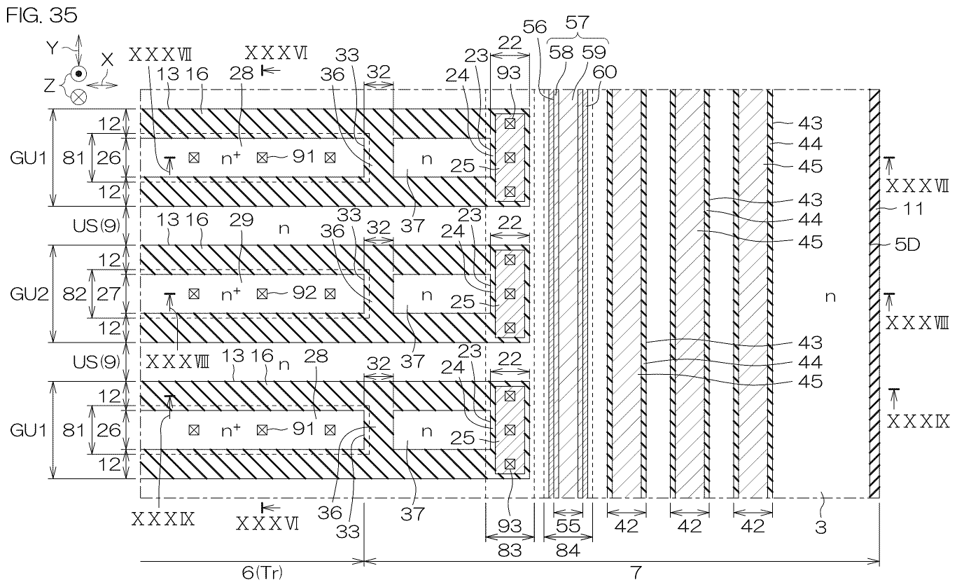

FIG. 31 is a plan view showing a semiconductor device 1D according to a fourth embodiment. FIG. 32 is a cross-sectional view taken along line XXXII-XXXII in FIG. 31. FIG. 33 is a plan view showing a layout example of the first main surface 3. FIG. 34 is an enlarged plan view showing a main portion of the first main surface 3. FIG. 35 is an enlarged plan view showing another main portion (main portion different from that in FIG. 34) of the first main surface 3.

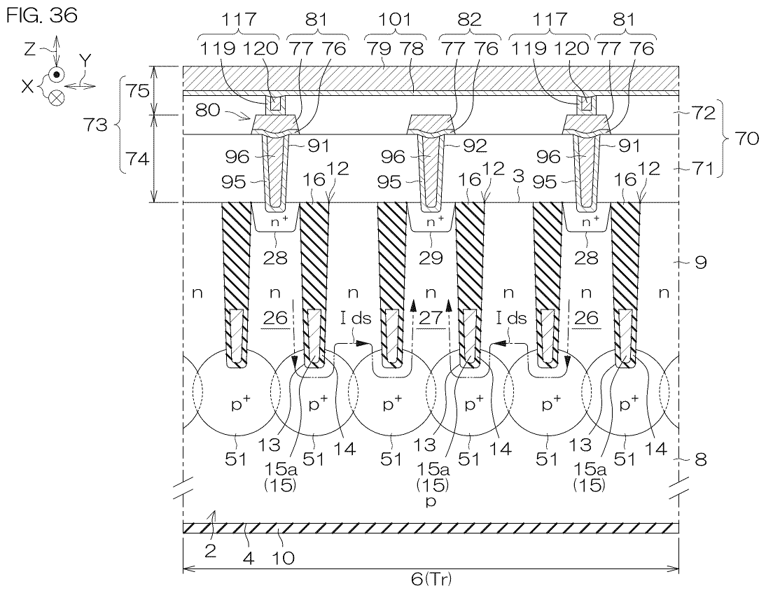

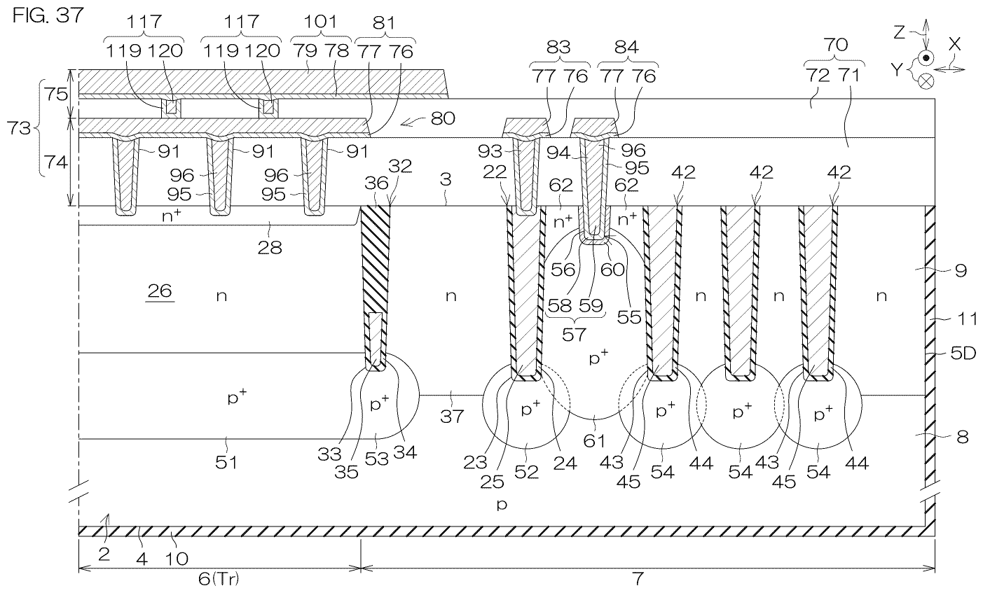

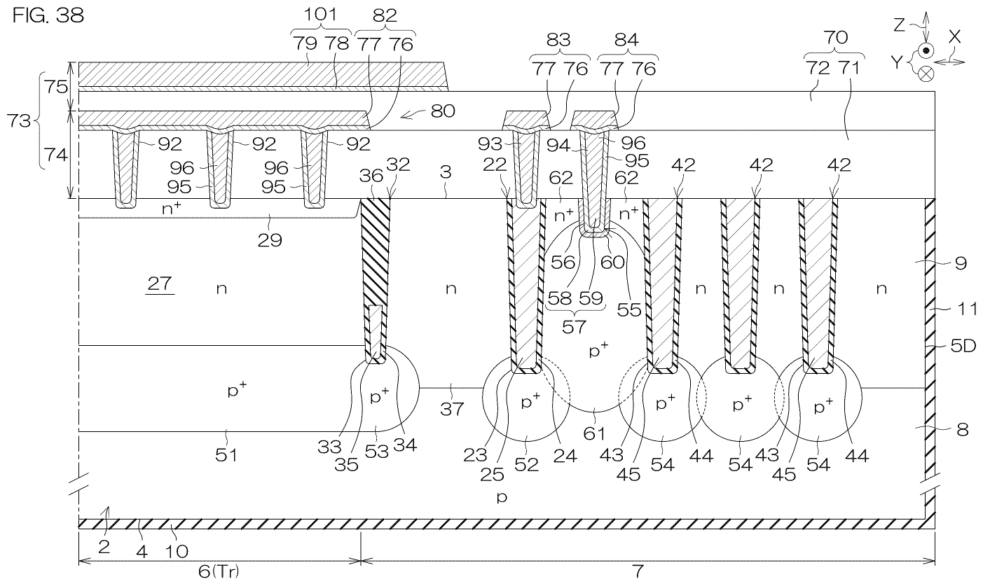

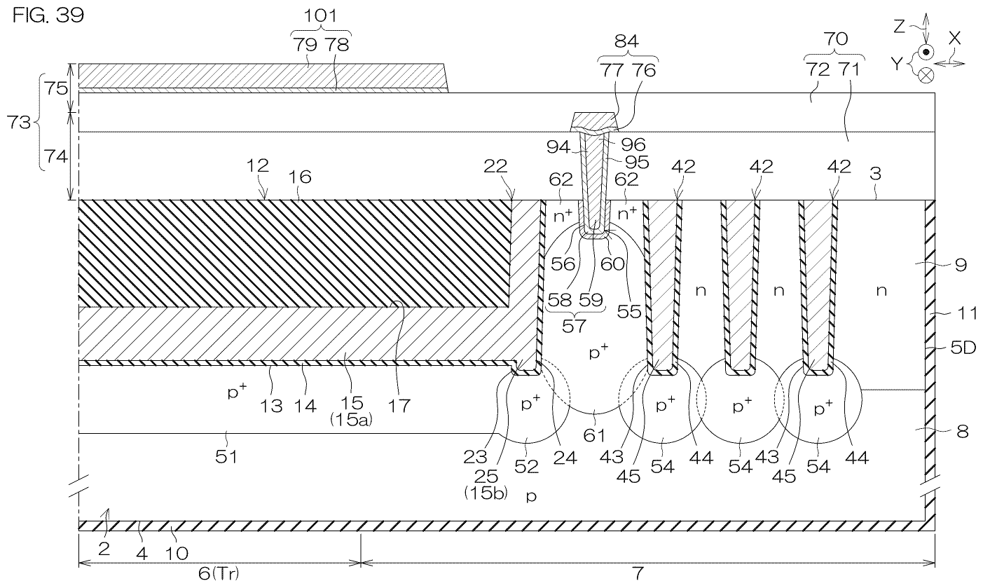

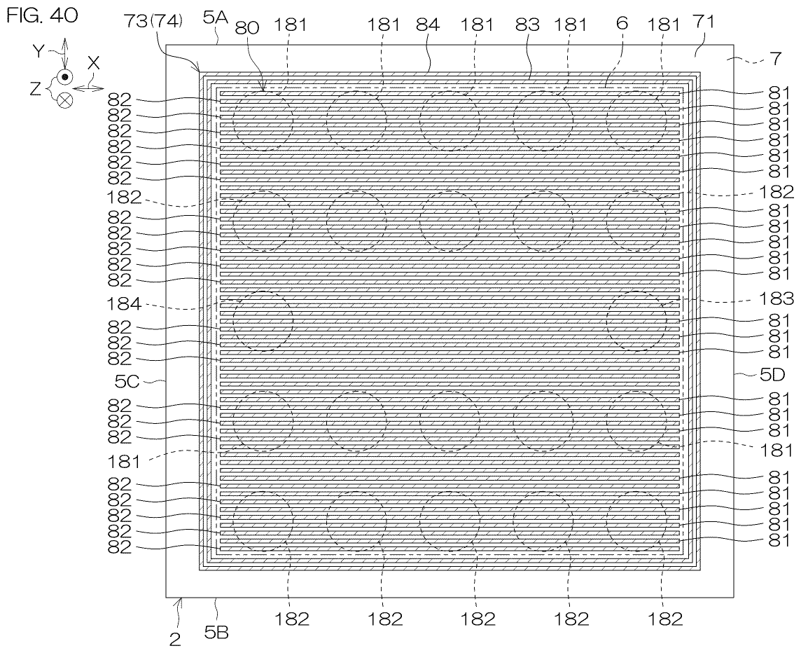

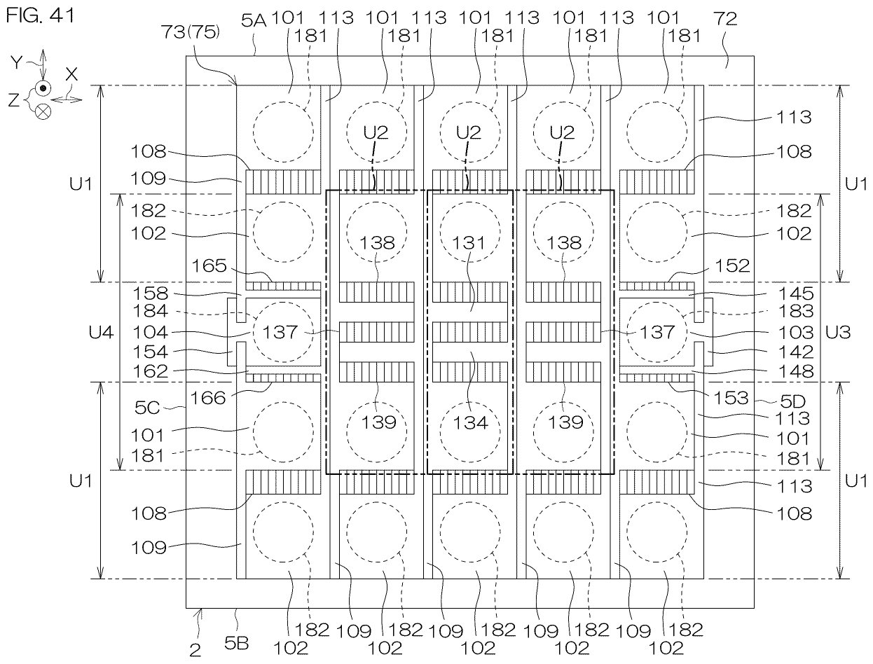

FIG. 36 is a cross-sectional view taken along line XXXVI-XXXVI in FIG. 35. FIG. 37 is a cross-sectional view taken along line XXXVII-XXXVII in FIG. 35. FIG. 38 is a cross-sectional view taken along line XXXVIII-XXXVIII in FIG. 35. FIG. 39 is a cross-sectional view taken along line XXXIX-XXXIX in FIG. 35. FIG. 40 is a plan view showing a layout example of the first layer wiring 74. FIG. 41 is a plan view showing a layout example of the second layer wiring 75.

The semiconductor device 1D is a semiconductor switching device including the lateral drain source common transistor structure Tr (the field effect transistor) as an example of the device structure. With reference to FIGS. 31 to 41, the semiconductor device 1D includes the chip 2 having a hexahedral shape (specifically, a rectangular parallelepiped shape). The chip 2 may be referred to as a “semiconductor chip.” In this embodiment, the chip 2 has a single layer structure constituted of a silicon monocrystal substrate (a semiconductor substrate).

The chip 2 has the first main surface 3 on one side, the second main surface 4 on the other side, and the first to fourth side surfaces 5A to 5D connecting the first main surface 3 and the second main surface 4. The first main surface 3 and the second main surface 4 are formed in a quadrangular shape in plan view in the normal direction Z of both the main surfaces (hereinafter, simply referred to as “plan view”). The normal direction Z is also a thickness direction of the chip 2.

The first side surface 5A and the second side surface 5B extend in the first direction X along the first main surface 3 and oppose each other in the second direction Y intersecting the first direction X along the first main surface 3. Specifically, the second direction Y is orthogonal to the first direction X. The third side surface 5C and the fourth side surface 5D extend in the second direction Y and oppose each other in the first direction X. In the following description, one side in the first direction X means the third side surface 5C side, and the other side in the first direction X means the fourth side surface 5D side. Also, one side in the second direction Y means the first side surface 5A side, and the other side in the second direction Y means the second side surface 5B side.

The semiconductor device 1D includes the active region 6 provided on the first main surface 3. The active region 6 is a region in which the transistor structure Tr (the device structure) is formed and is provided in an inner portion of the first main surface 3 at intervals from peripheral edges of the first main surface 3. Specifically, the active region 6 is defined in a polygonal shape (in this embodiment, a quadrangular shape) having four sides parallel to peripheral edges (the first to fourth side surfaces 5A to 5D) of the chip 2 in plan view. A planar shape of the active region 6 is arbitrary.

The semiconductor device 1D includes the outer region 7 provided in a region outside the active region 6 on the first main surface 3. The outer region 7 is provided in a region between the peripheral edges of the first main surface 3 and the active region 6 and extends as a band along the peripheral edges of the first main surface 3 and the active region 6. In this embodiment, the outer region 7 surrounds the active region 6 in plan view and is defined as a polygonal annular shape (in this embodiment, a quadrangular annular shape) having four sides parallel to the peripheral edges of the chip 2.

The semiconductor device 1D includes the base layer 8 (the base region) of the p-type formed in the chip 2. The base layer 8 may have a p-type impurity concentration of not less than 1×10¹³ cm⁻³ and not more than 1×10¹⁶ cm⁻³. A base potential is to be applied to the base layer 8. The base potential may be the reference potential. The reference potential is a potential serving as a reference of circuit operation. The reference potential may be a ground potential.

The base layer 8 is formed in the entire region between the first main surface 3 and the second main surface 4 in the thickness range of the chip 2. The base layer 8 extends in a layer shape along the first main surface 3 and the second main surface 4 and forms the first main surface 3, the second main surface 4, and the first to fourth side surfaces 5A to 5D. In this embodiment, the chip 2 is constituted of a semiconductor substrate of the p-type (a semiconductor chip of the p-type), and the base layer 8 is formed using the chip 2 of the p-type.

The base layer 8 may have a thickness of not less than 1 μm and not more than 800 μm. The thickness of the base layer 8 may have a value falling within at least one of ranges of not less than 1 μm and not more than 50 μm, not less than 50 μm and not more than 100 μm, not less than 100 μm and not more than 200 μm, not less than 200 μm and not more than 300 μm, not less than 300 μm and not more than 400 μm, not less than 400 μm and not more than 500 μm, not less than 500 μm and not more than 600 μm, not less than 600 μm and not more than 700 μm, and not less than 700 μm and not more than 800 μm.

The semiconductor device 1D includes the drift layer 9 (the drift region) of the n-type that is formed in a surface layer portion of the first main surface 3. In this embodiment, the drift layer 9 is an impurity region in which a conductivity type of the base layer 8 is replaced from the p-type to the n-type by an ion implantation method. As a matter of course, the drift layer 9 may be an epitaxial layer of the n-type laminated on the semiconductor substrate (the base layer 8) of the p-type. The drift layer 9 may have an n-type impurity concentration of not less than 1×10¹⁴ cm⁻³ and not more than 1×10¹⁸ cm⁻³.

The drift layer 9 is formed at intervals from the second main surface 4 (a bottom portion of the base layer 8) toward the first main surface 3 in the active region 6 and extends in a layer shape along the first main surface 3. The drift layer 9 has a portion that is led out from the active region 6 to the outer region 7 and is positioned in the outer region 7. In this embodiment, the drift layer 9 is formed in the surface layer portion of the first main surface 3 in the entire region of the first main surface 3 and is exposed from the first to fourth side surfaces 5A to 5D. As a matter of course, the drift layer 9 may be formed in the active region 6 at intervals inward from the first to fourth side surfaces 5A to 5D.

A depth of the drift layer 9 may be not less than 0.1 μm and not more than 10 μm. The depth of the drift layer 9 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm. The depth of the drift layer 9 is preferably not more than 2 μm.

The semiconductor device 1D includes outer insulation films 10 and 11 covering outer surfaces of the chip 2. The outer insulation films 10 and 11 include the first outer insulation film 10 and the second outer insulation film 11. The outer insulation films 10 and 11 do not necessarily include both the first outer insulation film 10 and the second outer insulation film 11 at the same time and may be constituted only one of the first outer insulation film 10 and the second outer insulation film 11. As a matter of course, the presence or absence of the outer insulation films 10 and 11 is arbitrary, and a configuration without the outer insulation films 10 and 11 may be employed.

The first outer insulation film 10 covers, in a film shape, the second main surface 4. That is, the first outer insulation film 10 covers the base layer 8 exposed from the second main surface 4. In this embodiment, the first outer insulation film 10 covers the entire region of the second main surface 4 and insulates and reinforces the chip 2 from the second main surface 4 side.

The second outer insulation film 11 covers, in a film shape, at least one of the first to fourth side surfaces 5A to 5D. That is, the second outer insulation film 11 covers the base layer 8 and the drift layer 9 exposed from at least one of the first to fourth side surfaces 5A to 5D. In this embodiment, the second outer insulation film 11 covers all of the first to fourth side surfaces 5A to 5D and insulates and reinforces the chip 2 from the first to fourth side surfaces 5A to 5D sides. The second outer insulation film 11 is continuous to the first outer insulation film 10 at peripheral edges of the second main surface 4.

The outer insulation films 10 and 11 may have a single layer structure or a laminated structure including any one or both of an inorganic insulation film and an organic insulation film. In a case where the outer insulation films 10 and 11 having the laminated structure are employed, the outer insulation films 10 and 11 may include the inorganic insulation film and the organic insulation film laminated in that order from the chip 2 side.

For example, the inorganic insulation film may include at least one of a silicon oxide film, a silicon nitride film, and a silicon oxynitride film. For example, the organic insulation film may include at least one type among polyimide, polyamide, polybenzoxazole, and epoxy resin.

The semiconductor device 1D includes the transistor structure Tr formed in the active region 6 on the first main surface 3. Hereinafter, a configuration of transistor structure Tr will be specifically described. The semiconductor device 1D includes the plurality of trench-electrode gate structures 12 (control ends) formed in the first main surface 3 in the active region 6. The gate structure 12 may be referred to as a “trench gate structure.” A gate potential (a gate signal) as a control potential is to be applied to the plurality of gate structures 12.

The plurality of gate structures 12 are each formed as a band extending in the first direction X and are arrayed at intervals in the second direction Y. That is, the plurality of gate structures 12 are arrayed as stripes extending in the first direction X. Each of the plurality of gate structures 12 has a first end portion on the one side in the first direction X and a second end portion on the other side in the first direction X. The first end portion is led out from the active region 6 to one side of the outer region 7. The second end portion is led out from the active region 6 to the other side of the outer region 7.

In this embodiment, the plurality of gate structures 12 are positioned in the drift layer 9 in cross-sectional view. Specifically, the plurality of gate structures 12 are formed at intervals from a depth position of a bottom portion of the drift layer 9 toward the first main surface 3 and have side walls and bottom walls positioned in the drift layer 9. The plurality of gate structures 12 may be formed in a tapered shape having an opening width narrowing toward the bottom wall in cross-sectional view.

The plurality of gate structures 12 may penetrate the bottom portion of the drift layer 9 such as to reach the base layer 8. That is, each of the plurality of gate structures 12 may have a portion (the side wall) positioned in the drift layer 9 and a portion (the bottom wall) positioned in the base layer 8. The bottom walls of the plurality of gate structures 12 preferably have flat portions extending substantially parallel to the first main surface 3, respectively. The bottom walls of the plurality of gate structures 12 may be curved in a circular arc shape toward the second main surface 4.

The intervals between the plurality of gate structures 12 may be not less than 0.1 μm and not more than 5 μm. The interval between the gate structures 12 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The interval between the gate structures 12 is preferably not more than 3 μm.

A width of the gate structure 12 may be not less than 0.1 μm and not more than 5 μm. The width of the gate structure 12 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The width of the gate structure 12 is preferably not more than 3 μm.

A depth of the gate structure 12 may be not less than 0.1 μm and not more than 10 μm. The depth of the gate structure 12 may have a value falling within at least one of ranges of 0.1 μm and not more than 0.25 μm, 0.25 μm and not more than 0.5 μm, 0.5 μm and not more than 1 μm, 1 μm and not more than 1.5 μm, 1.5 μm and not more than 2 μm, 2 μm and not more than 2.5 μm, 2.5 μm and not more than 3 μm, 3 μm and not more than 4 μm, 4 μm and not more than 6 μm, 6 μm and not more than 8 μm, and 8 μm and not more than 10 μm. The depth of the gate structure 12 is preferably not more than 3 μm.

Hereinafter, a configuration of one of the gate structures 12 will be described. The gate structure 12 includes the trench 13, the insulation film 14, the embedded electrode 15, and the embedded insulator 16. The trench 13 may be referred to as a “gate trench,” the insulation film 14 may be referred to as a “gate insulation film,” and the embedded electrode 15 may be referred to as a “gate electrode.” The trench 13 is dug down from the first main surface 3 toward the second main surface 4 and defines the side walls and the bottom wall of the gate structure 12.

The insulation film 14 covers, in a film shape, the wall surfaces of the trench 13. The insulation film 14 may include at least one of a silicon oxide film, a silicon nitride film, and a silicon oxynitride film. The insulation film 14 preferably has a single layer structure. The insulation film 14 preferably includes a silicon oxide film constituted of an oxide of the chip 2.

The embedded electrode 15 is embedded in the trench 13 via the insulation film 14. The embedded electrode 15 may contain conductive polysilicon. The embedded electrode 15 includes the embedded portion 15a and at least one (in this embodiment, a plurality) of the lead-out portions 15b.

The embedded portion 15a is embedded on the bottom wall side of the trench 13 at intervals from the first main surface 3 toward the bottom wall of the trench 13 in the active region 6. It is preferable that the embedded portion 15a is embedded at intervals from an intermediate portion of the trench 13 toward the bottom wall of the trench 13 and has an electrode surface positioned closer to the bottom wall than to the intermediate portion of the trench 13.

The plurality of lead-out portions 15b include the lead-out portion 15b positioned at the first end portion of the trench 13 in the outer region 7 and the lead-out portion 15b positioned at the second end portion of the trench 13 in the outer region 7. The plurality of lead-out portions 15b are each led out from the bottom wall side (the embedded portion 15a side) of the trench 13 to an opening side of the trench 13. The plurality of lead-out portions 15b define, together with the embedded portions 15a, electrode recesses 17 on the opening side of the trenches 13. The electrode recesses 17 extend as bands in the first direction X along the trenches 13.

Each of the plurality of lead-out portions 15b has the electrode surface positioned in the vicinity of the first main surface 3. The electrode surface of the lead-out portion 15b may be formed flush with the first main surface 3. The electrode surface of the lead-out portion 15b may be positioned on the bottom wall side of the trench 13 with respect to the first main surface 3. The electrode surface of the lead-out portion 15b may project upward from the first main surface 3.

The embedded insulator 16 is embedded on the opening side of the trench 13. Specifically, the embedded insulator 16 is embedded in the electrode recess 17 and covers the embedded portion 15a in the trench 13. The embedded insulator 16 may be embedded in the trench 13 across the insulation film 14. The embedded insulator 16 may be embedded in the trench 13 without interposition of the insulation film 14 such as to directly cover the side walls of the trench 13. The embedded insulator 16 extends as a band in the first direction X in plan view. The embedded insulator 16 is provided as a field insulator that relaxes an electric field with respect to the trench 13. A cross-sectional area of the embedded insulator 16 is preferably larger than a cross-sectional area of the embedded portion 15a.

The embedded insulator 16 has an insulation surface positioned in the vicinity of the first main surface 3. The insulation surface may be formed flush with the first main surface 3. The insulation surface may be positioned on the bottom wall side of the trench 13 with respect to the first main surface 3. The insulation surface may project upward from the first main surface 3.

The embedded insulator 16 may include at least one type among silicon oxide, silicon nitride, and silicon oxynitride. The embedded insulator 16 may have a single layer structure. The embedded insulator 16 may be formed of the same insulating material as the insulation film 14. In this case, it is preferable that the embedded insulator 16 is constituted of a deposited substance accumulated by a chemical vapor deposition (CVD) method, etc., and has a denseness different from a denseness of the insulation film 14.

The semiconductor device 1D includes the plurality of gate units GU1 and GU2. The plurality of gate units GU1 and GU2 include the plurality of first gate units GU1 and the plurality of second gate units GU2. Each of the plurality of first gate units GU1 is constituted of at least two (in this embodiment, two) of the gate structures 12 adjacent in the second direction Y. The plurality of first gate units GU1 are alternately arrayed with at least two (in this embodiment, two) gate structures 12 in the second direction Y.

Each of the plurality of second gate units GU2 is constituted of at least two (in this embodiment, two) of the gate structures 12 other than the plurality of gate structures 12 constituting the plurality of first gate units GU1 among the plurality of gate structures 12. Each of the plurality of second gate units GU2 is constituted of at least two of the gate structures 12 adjacent in the second direction Y. The plurality of second gate units GU2 and the plurality of first gate units GU1 are alternately arrayed in the second direction Y.

The semiconductor device 1D includes the plurality of unit spaces US defined by the regions between the plurality of first gate units GU1 and the plurality of second gate units GU2 adjacent in the second direction Y in the active region 6. Each of the unit spaces US is defined by a region between the single gate structure 12 of the first gate unit GU1 and the single gate structure 12 of the second gate unit GU2 and includes the drift layer 9.

The semiconductor device 1D includes the plurality of trench-electrode connection structures 21 and 22 formed in the outer region 7 in the first main surface 3. The plurality of connection structures 21 and 22 connect at least two of the gate structures 12 adjacent in the second direction Y. The gate potential is to be applied to the plurality of connection structures 21 and 22. The connection structures 21 and 22 may be referred to as “gate connection structures.”

The plurality of connection structures 21 and 22 are respectively connected to the first end portions and the second end portions of the plurality of gate structures 12 in the corresponding gate units GU1 and GU2. Consequently, the plurality of connection structures 21 and 22 respectively constitute, together with the plurality of corresponding gate structures 12, the plurality of gate units GU1 and GU2 each of which has an annular shape or a ladder shape (in this embodiment, a quadrangular annular shape). The plurality of connection structures 21 and 22 include the plurality of first connection structures 21 arranged on the first end portion side of the plurality of gate structures 12 and the plurality of second connection structures 22 arranged on the second end portion side of the plurality of gate structures 12.

The plurality of first connection structures 21 are each formed as a band extending in the second direction Y and are arrayed at intervals in the second direction Y. The plurality of first connection structures 21 are aligned in the second direction Y. The plurality of first connection structures 21 are respectively connected to the first end portions of the plurality of gate structures 12 which are to be unitized (grouped). In this embodiment, the plurality of first connection structures 21 respectively connect the first end portions of pairs of gate structures 12 adjacent in the second direction Y.

The plurality of second connection structures 22 are each formed as a band extending in the second direction Y and are arrayed at intervals in the second direction Y. The plurality of second connection structures 22 are aligned in the second direction Y. The plurality of second connection structures 22 are respectively connected to the second end portions of the plurality of gate structures 12 unitized (grouped) by the first connection structures 21. In this embodiment, the plurality of second connection structures 22 are respectively connected to the second end portions of pairs of gate structures 12 adjacent in the second direction Y.

In this embodiment, the plurality of connection structures 21 and 22 are positioned in the drift layer 9 in cross-sectional view. Specifically, the plurality of connection structures 21 and 22 are formed at intervals from the depth position of the bottom portion of the drift layer 9 toward the first main surface 3 and have the side walls and the bottom walls positioned in the drift layer 9. The plurality of connection structures 21 and 22 may be formed in a tapered shape having an opening width narrowing toward the bottom wall in cross-sectional view.

The plurality of connection structures 21 and 22 may respectively have bottom walls which penetrate the bottom portion of the drift layer 9 such as to reach the base layer 8 and are positioned in the base layer 8. That is, each of the plurality of connection structures 21 and 22 may have a portion (the side wall) positioned in the drift layer 9 and a portion (the bottom wall) positioned in the base layer 8. The bottom walls of the plurality of connection structures 21 and 22 preferably have flat portions extending substantially parallel to the first main surface 3, respectively. As a matter of course, the bottom walls of the plurality of connection structures 21 and 22 may be curved in a circular arc shape toward the second main surface 4.

In this embodiment, a width of each of the connection structures 21 and 22 is larger than the width of the gate structure 12. The width of each of the connection structures 21 and 22 may be substantially equal to the width of the gate structure 12. The width of each of the connection structures 21 and 22 may be less than the width of the gate structure 12.

The width of each of the connection structures 21 and 22 may be not less than 0.1 μm and not more than 5 μm. The width of each of the connection structures 21 and 22 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, a depth of each of the connection structures 21 and 22 is larger than the depth of the gate structure 12. The depth of each of the connection structures 21 and 22 may be substantially equal to the depth of the gate structure 12. The depth of each of the connection structures 21 and 22 may be less than the depth of the gate structure 12.

The depth of each of the connection structures 21 and 22 may be not less than 0.1 μm and not more than 10 μm. The depth of each of the connection structures 21 and 22 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

Hereinafter, a configuration of one of the connection structures 21 and 22 will be described. Each of the connection structures 21 and 22 includes the connection trench 23, the connection insulation film 24, and the connection electrode 25. The connection trench 23 is dug from the first main surface 3 toward the second main surface 4 and defines the side wall and the bottom wall of each of the connection structures 21 and 22. The connection trench 23 is connected to the plurality of trenches 13 adjacent in the second direction Y.

The connection insulation film 24 covers, in a film shape, wall surfaces of the connection trench 23. The connection insulation film 24 is connected to the insulation film 14 and the embedded insulator 16 at communication portions between the trenches 13 and the connection trench 23. The connection insulation film 24 may include at least one of a silicon oxide film, a silicon nitride film, and a silicon oxynitride film. The connection insulation film 24 preferably has a single layer structure. The connection insulation film 24 preferably includes the silicon oxide film constituted of the oxide of the chip 2. The connection insulation film 24 is preferably formed of the same insulating material as the insulation film 14.

The connection electrode 25 is embedded in the connection trench 23 via the connection insulation film 24. The connection electrode 25 may contain conductive polysilicon. The connection electrode 25 is formed as a band extending in the second direction Y in plan view and is connected to the embedded electrode 15 at a communication portion between the trench 13 and the connection trench 23.

The connection electrode 25 can be regarded as a portion of the embedded electrode 15 (the lead-out portion 15b) led out into the connection trench 23. A connection portion between the embedded electrode 15 and the connection electrode 25 may be regarded as one component of the gate structure 12 or may be regarded as one component of each of the connection structures 21 and 22.

The connection electrode 25 has the electrode surface positioned in the vicinity of the first main surface 3. The electrode surface of the connection electrode 25 may be formed flush with the first main surface 3. The electrode surface of the connection electrode 25 may be positioned on the bottom wall side of the connection trench 23 with respect to the first main surface 3. The electrode surface of the connection electrode 25 may project upward from the first main surface 3. A plane area of the electrode surface of the connection electrode 25 is preferably larger than a plane area of the electrode surface of the embedded portion 15a.

The semiconductor device 1D includes the plurality of mesa portions 26 and 27 defined in the active region 6 on the first main surface 3. The plurality of mesa portions 26 and 27 are respectively defined by the plurality of gate units GU1 and GU2. That is, the mesa portions 26 and 27 are constituted of respective portions surrounded by the plurality of gate structures 12 and the plurality of connection structures 21 and 22. The plurality of mesa portions 26 and 27 respectively extend as bands in the first direction X and are defined at intervals in the second direction Y. That is, the plurality of mesa portions 26 and 27 are defined as stripes extending in the first direction X.

The plurality of mesa portions 26 and 27 include the plurality of first mesa portions 26 and the plurality of second mesa portions 27. The plurality of first mesa portions 26 are regions (first application ends) which are respectively defined in the plurality of first gate units GU1, and to which a first drain source potential as a first potential (a high potential) is to be applied.

The plurality of second mesa portions 27 are regions (second application ends) which are respectively defined by the plurality of second gate units GU2, and to which a second drain source potential as a second potential (a low potential) different from the first potential is to be applied. That is, the plurality of second mesa portions 27 and the plurality of first mesa portions 26 are alternately defined in the second direction Y via the plurality of unit spaces US. The second drain source potential may be the same potential as the base potential or may be a potential different from the base potential.

The semiconductor device 1D includes the plurality of drain source regions 28 and 29 of the n-type formed in the surface layer portion of the first main surface 3 (the drift layer 9). The plurality of drain source regions 28 and 29 are formed in the plurality of mesa portions 26 and 27. That is, the plurality of drain source regions 28 and 29 are respectively formed in regions between the plurality of gate structures 12 in the corresponding gate units GU1 and GU2. The plurality of drain source regions 28 and 29 have an n-type impurity concentration higher than the n-type impurity concentration of the drift layer 9. The n-type impurity concentration of the plurality of drain source regions 28 and 29 may be not less than 1×10¹⁶ cm⁻³ and not more than 1×10²¹ cm⁻³.

The plurality of drain source regions 28 and 29 include the plurality of first drain source regions 28 and the plurality of second drain source regions 29. The plurality of first drain source regions 28 are regions (the first application ends) to which the first drain source potential is to be applied and are formed as bands extending in the first direction X in the plurality of first mesa portions 26.

The plurality of second drain source regions 29 are regions (the second application ends) to which the second drain source potential is to be applied and are formed as bands extending in the first direction X in the plurality of second mesa portions 27. That is, the plurality of second drain source regions 29 and the plurality of first drain source regions 28 are alternately formed in the second direction Y. Also, the plurality of drain source regions 28 and 29 are arrayed as stripes extending in the first direction X.

Hereinafter, a configuration of one of the drain source region 28 and 29 will be described. The drain source regions 28 and 29 are formed at intervals from the bottom walls of the plurality of gate structures 12 toward the first main surface 3 and oppose the base layer 8 across a part of the drift layer 9. Specifically, the drain source regions 28 and 29 are formed at intervals from depth positions of the electrode surfaces of the plurality of embedded electrodes 15 toward the first main surface 3 and oppose the plurality of embedded insulators 16 in a horizontal direction along the first main surface 3.

Such a configuration is effective in preventing breakdown voltage from decreasing due to a voltage drop between the gate structures 12 and the drain source regions 28 and 29. The drain source regions 28 and 29 may be in contact with the plurality of gate structures 12. That is, the drain source regions 28 and 29 may be in contact with portions of the plurality of gate structures 12 in which the embedded insulators 16 are arranged.

The drain source regions 28 and 29 are formed at intervals in the first direction X from the first end portions and the second end portions of the plurality of gate structures 12 and are not in contact with portions of the plurality of gate structures 12 in which the lead-out portions 15b are arranged. That is, the drain source regions 28 and 29 are formed at intervals in the first direction X from the plurality of connection structures 21 and 22 positioned on both sides. Such a configuration is effective in preventing the breakdown voltage from decreasing due to a voltage drop between the end portions of the gate structures 12 (the connection structures 21 and 22) and the drain source regions 28 and 29.

The drain source regions 28 and 29 are preferably formed at region intervals of not less than 0.1 μm and not more than 2 μm from the end portions of the gate structures 12 (the connection structures 21 and 22). The region interval may have a value falling within at least one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The semiconductor device 1D includes the plurality of trench-electrode separating structures 31 and 32 formed in the active region 6 in the first main surface 3. A gate potential is to be applied to the plurality of separating structures 31 and 32. The separating structures 31 and 32 may be referred to as “gate separating structures.” The plurality of separating structures 31 and 32 respectively connect the plurality of gate structures 12 adjacent in the second direction Y in the corresponding gate units GU1 and GU2.

The plurality of separating structures 31 and 32 are respectively arranged in regions between the end portions of the plurality of gate structures 12 and the plurality of drain source regions 28 and 29 and physically and electrically isolate the plurality of drain source regions 28 and 29 from the end portions of the plurality of gate structures 12. That is, the plurality of separating structures 31 and 32 physically and electrically isolate the plurality of drain source regions 28 and 29 from the plurality of connection structures 21 and 22.

Each of the plurality of separating structures 31 and 32 defines a boundary portion between the active region 6 and the outer region 7 on the first main surface 3 and at the same time, increases a creepage distance between the end portion of each of the gate structures 12 (each of the connection structures 21 and 22) and each of the drain source regions 28 and 29. In this embodiment, the plurality of separating structures 31 and 32 include the plurality of first separating structures 31 arranged on the first end portion side and the plurality of second separating structures 32 arranged on the second end portion side.

The plurality of first separating structures 31 are arranged at intervals from the plurality of first end portions (the plurality of first connection structures 21) toward the drain source regions 28 and 29. The plurality of first separating structures 31 respectively extend as bands in the second direction Y and are respectively connected to the plurality of gate structures 12 adjacent in the second direction Y. The plurality of first separating structures 31 are aligned in the second direction Y. The plurality of first separating structures 31 may be connected to the drain source regions 28 and 29.

The plurality of second separating structures 32 are arranged at intervals from the plurality of second end portions (the plurality of second connection structures 22) toward the drain source regions 28 and 29. The plurality of second separating structures 32 respectively extend as bands in the second direction Y and are respectively connected to the plurality of gate structures 12 adjacent in the second direction Y. The plurality of second separating structures 32 are aligned in the second direction Y. The plurality of second separating structures 32 may be connected to the drain source regions 28 and 29.

In this embodiment, the plurality of separating structures 31 and 32 are positioned in the drift layer 9 in cross-sectional view. Specifically, the plurality of separating structures 31 and 32 are formed at intervals from the depth position of the bottom portion of the drift layer 9 toward the first main surface 3 and have the side walls and the bottom walls positioned in the drift layer 9. The plurality of separating structures 31 and 32 may be formed in a tapered shape having an opening width narrowing toward the bottom wall in cross-sectional view.

The plurality of separating structures 31 and 32 may penetrate the bottom portion of the drift layer 9 such as to reach the base layer 8. That is, each of the plurality of separating structures 31 and 32 may have a portion (the side wall) positioned in the drift layer 9 and a portion (the bottom wall) positioned in the base layer 8. The bottom walls of the plurality of separating structures 31 and 32 preferably have flat portions extending substantially parallel to the first main surface 3, respectively. As a matter of course, the bottom walls of the plurality of separating structures 31 and 32 may be curved in a circular arc shape toward the second main surface 4.

In this embodiment, a width of each of the separating structures 31 and 32 is less than the width of each of the connection structures 21 and 22. The width of each of the separating structures 31 and 32 may be substantially equal to the width of each of the connection structures 21 and 22. The width of each of the separating structures 31 and 32 may be larger than the width of each of the connection structures 21 and 22. The width of each of the separating structures 31 and 32 may be substantially equal to the width of the gate structure 12. The width of each of the separating structures 31 and 32 may be larger than the width of the gate structure 12. The width of each of the separating structures 31 and 32 may be less than the width of the gate structure 12.

The width of each of the separating structures 31 and 32 may be not less than 0.1 μm and not more than 5 μm. The width of each of the separating structures 31 and 32 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, a depth of each of the separating structures 31 and 32 is less than the depth of each of the connection structures 21 and 22. The depth of each of the separating structures 31 and 32 may be substantially equal to the depth of each of the connection structures 21 and 22. The depth of each of the separating structures 31 and 32 may be larger than the depth of each of the connection structures 21 and 22. The depth of each of the separating structures 31 and 32 may be substantially equal to the depth of the gate structure 12. The depth of each of the separating structures 31 and 32 may be larger than the depth of the gate structure 12. The depth of each of the separating structures 31 and 32 may be less than the depth of the gate structure 12. For example, the separating structures 31 and 32 may be formed at intervals from a depth position of an intermediate portion of the gate structures 12 toward the first main surface 3.

The depth of each of the separating structures 31 and 32 may be not less than 0.1 μm and not more than 10 μm. The depth of each of the separating structures 31 and 32 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

Hereinafter, a configuration of one of the separating structures 31 and 32 will be described. Each of the separating structures 31 and 32 includes the separation trench 33, the separation insulation film 34, the separation electrode 35, and the separation embedded insulator 36. The separation trench 33 is dug from the first main surface 3 toward the second main surface 4 and defines the side walls and the bottom wall of each of the separating structures 31 and 32. The separation trench 33 is connected to the plurality of trenches 13 adjacent in the second direction Y.

The separation insulation film 34 covers, in a film shape, wall surfaces of the separation trench 33. The separation insulation film 34 is connected to the insulation film 14 and the embedded insulator 16 at communication portions between the trenches 13 and the separation trench 33. The separation insulation film 34 can be regarded as a portion of the insulation film 14 led out into the separation trench 33. A connection portion between the insulation film 14 and the separation insulation film 34 may be regarded as one component of the gate structure 12 or may be regarded as one component of each of the separating structures 31 and 32.

The separation insulation film 34 may include at least one of a silicon oxide film, a silicon nitride film, and a silicon oxynitride film. The separation insulation film 34 preferably has a single layer structure. The separation insulation film 34 preferably includes the silicon oxide film constituted of an oxide of the chip 2. The separation insulation film 34 is preferably formed of the same insulating material as the insulation film 14.

The separation electrode 35 is embedded in the separation trench 33 via the separation insulation film 34. The separation electrode 35 may contain conductive polysilicon. The separation electrode 35 is embedded on the bottom wall side of the trench 13 at intervals from the first main surface 3 toward a bottom wall of the separation trench 33. It is preferable that the separation electrode 35 is embedded at intervals from an intermediate portion of the separation trench 33 toward the bottom wall of the separation trench 33 and has an electrode surface positioned closer to the bottom wall than to the intermediate portion of the separation trench 33.

The separation electrode 35 is connected to the embedded portion 15a at a communication portion between the trench 13 and the separation trench 33. The separation electrode 35 can be regarded as a portion of the embedded electrode 15 (the embedded portion 15a) led out into the separation trench 33. A connection portion between the embedded electrode 15 and the separation electrode 35 may be regarded as one component of the gate structure 12 or may be regarded as one component of each of the separating structures 31 and 32.

The electrode surface of the separation electrode 35 may be positioned on the bottom wall side of the separation trench 33 with respect to the electrode surface of the lead-out portion 15b of the embedded electrode 15. The electrode surface of the separation electrode 35 is preferably positioned at a depth position substantially equal to the electrode surface of the embedded portion 15a.

The separation embedded insulator 36 is embedded on an opening side of the separation trench 33. The separation embedded insulator 36 may be embedded in the separation trench 33 across the separation insulation film 34. The separation embedded insulator 36 may be embedded in the separation trench 33 without interposition of the separation insulation film 34 such as to directly cover the side walls of the separation trench 33.

The separation embedded insulator 36 extends as a band in the second direction Y in plan view. The separation embedded insulator 36 is connected to the embedded insulator 16 at a communication portion between the trench 13 and the separation trench 33. The separation embedded insulator 36 is provided as a field insulator that relaxes an electric field with respect to the separation trench 33. A cross-sectional area of the separation embedded insulator 36 is preferably larger than a cross-sectional area of the separation electrode 35.

The separation embedded insulator 36 has an insulation surface positioned in the vicinity of the first main surface 3. The insulation surface may be formed flush with the first main surface 3. The insulation surface may be positioned on the bottom wall side of the separation trench 33 with respect to the first main surface 3. The insulation surface may project upward from the first main surface 3.

The separation embedded insulator 36 may include at least one type among silicon oxide, silicon nitride, and silicon oxynitride. The separation embedded insulator 36 may have a single layer structure. The separation embedded insulator 36 may be formed of the same insulating material as the separation insulation film 34. It is preferable that the separation embedded insulator 36 is constituted of a deposited substance accumulated by the CVD method, etc., and has a denseness different from a denseness of the separation insulation film 34. The separation embedded insulator 36 is preferably formed of the same insulating material as the embedded insulator 16.

The separating structures 31 and 32 may be of a trench insulation type instead of the trench electrode type. In this case, instead of the separation electrode 35, an insulator (silicon oxide, silicon nitride, silicon oxynitride, etc.) is embedded in the separation trench 33 via the separation insulation film 34. In this case, the separation insulation film 34 may be removed.

The semiconductor device 1D includes the plurality of floating regions 37 of the n-type formed in regions between the end portions of the plurality of gate structures 12 (the connection structures 21 and 22) and the plurality of separating structures 31 and 32 in the outer region 7. The plurality of floating regions 37 respectively include portions of the drift layer 9 positioned in regions between the end portions of the plurality of gate structures 12 (the connection structures 21 and 22) and the plurality of separating structures 31 and 32 and are formed in an electrically floating state.

Although not specifically shown, the plurality of floating regions 37 may include a high concentration region having an n-type impurity concentration higher than the n-type impurity concentration of the drift layer 9 in the surface layer portion of the drift layer 9. In this case, the n-type impurity concentration of the high concentration region may be substantially equal to the n-type impurity concentration of the drain source regions 28 and 29. Also, the high concentration region may have a depth substantially equal to the depth of the drain source regions 28 and 29.

The semiconductor device 1D includes one or a plurality of the trench-electrode field structures 42 formed in the outer region 7 in the first main surface 3. The field structure 42 may be referred to as a “trench field structure.” The number of the field structures 42 is arbitrary and is adjusted depending on an electric field, etc., which are to be relaxed.

The number of the field structures 42 may be one, two, three, four, five, six, seven, eight, nine, or ten. The number of the field structures 42 is preferably not more than five. In this embodiment, the semiconductor device 1D includes the three field structures 42. The base potential or the second drain source potential (the low potential) may be applied to the plurality of field structures 42. The plurality of field structures 42 may be formed in an electrically floating state.

The plurality of field structures 42 are formed in the first main surface 3 of the outer peripheral region 7b at intervals from the plurality of gate structures 12 (the plurality of connection structures 21 and 22) toward the peripheral edge of the first main surface 3. An interval between the plurality of gate structures 12 (the plurality of connection structures 21 and 22) and the innermost field structure 42 (on the active region 6 side) is preferably larger than the intervals between the plurality of gate structures 12. As a matter of course, the interval between the gate structures 12 and the field structure 42 may be less than or equal to (less than) the intervals between the plurality of gate structures 12.

Each of the plurality of field structures 42 is arranged at intervals from each other and extends as a band along the peripheral edge of the first main surface 3. In this embodiment, the plurality of field structures 42 collectively surround the active region 6 (the plurality of gate structures 12) in plan view and are formed in a polygonal annular shape (in this embodiment, a quadrangular annular shape) having four sides parallel to the peripheral edges of the chip 2. That is, the plurality of field structures 42 define the active region 6 in the outer region 7.

In this embodiment, the plurality of field structures 42 are positioned in the drift layer 9 in cross-sectional view. Specifically, the plurality of field structures 42 are formed at intervals from the depth position of the bottom portion of the drift layer 9 toward the first main surface 3 and have the side walls and the bottom walls positioned in the drift layer 9. The plurality of field structures 42 may be formed in a tapered shape having an opening width narrowing toward the bottom wall in cross-sectional view.

The plurality of field structures 42 may penetrate the bottom portion of the drift layer 9 such as to reach the base layer 8. That is, each of the plurality of field structures 42 may have the portion (the side wall) positioned in the drift layer 9 and the portion (the bottom wall) positioned in the base layer 8. The bottom walls of the plurality of field structures 42 preferably have flat portions extending substantially parallel to the first main surface 3, respectively. As a matter of course, the bottom walls of the plurality of field structures 42 may be curved in a circular arc shape toward the second main surface 4.

The intervals between the plurality of field structures 42 may be substantially equal to the intervals between the plurality of gate structures 12. The intervals between the plurality of field structures 42 may be less than the intervals between the plurality of gate structures 12. The intervals between the plurality of field structures 42 may be larger than the intervals between the plurality of gate structures 12.

The intervals between the plurality of field structures 42 may be not less than 0.1 μm and not more than 5 μm. The interval between the field structures 42 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, the width of the field structure 42 is larger than the width of the gate structure 12. The width of the field structure 42 may be less than the width of the gate structure 12. The width of the field structure 42 may be substantially equal to the width of the gate structure 12. The width of the field structure 42 may be substantially equal to the width of each of the connection structures 21 and 22. The width of the field structure 42 may be larger than the width of each of the connection structures 21 and 22. The width of the field structure 42 may be less than the width of each of the connection structures 21 and 22.

The width of the field structure 42 may be not less than 0.1 μm and not more than 5 μm. The width of the field structure 42 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

In this embodiment, the depth of the field structure 42 is larger than the depth of the gate structure 12. The depth of the field structure 42 may be less than the depth of the gate structure 12. The depth of the field structure 42 may be substantially equal to the depth of the gate structure 12. The depth of the field structure 42 may be substantially equal to the depth of each of the connection structures 21 and 22. The depth of the field structure 42 may be larger than the depth of each of the connection structures 21 and 22. The depth of the field structure 42 may be less than the depth of each of the connection structures 21 and 22.

The depth of the field structure 42 may be not less than 0.1 μm and not more than 10 μm. The depth of the field structure 42 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

Hereinafter, the configuration of one of the field structures 42 will be described. The field structure 42 includes the field trench 43, the field insulation film 44, and the field electrode 45. The field trench 43 is dug from the first main surface 3 toward the second main surface 4 and defines the side walls and the bottom wall of the field structure 42.

The field insulation film 44 covers, in a film shape, wall surfaces of the field trench 43. The field insulation film 44 may include at least one of a silicon oxide film, a silicon nitride film, and a silicon oxynitride film. The field insulation film 44 preferably has a single layer structure. The field insulation film 44 preferably includes the silicon oxide film constituted of an oxide of the chip 2. The field insulation film 44 is preferably formed of the same insulating material as the insulation film 14.

The field electrode 45 is embedded in the field trench 43 via the field insulation film 44. The field electrode 45 may contain conductive polysilicon. The field electrode 45 has the electrode surface positioned on the first main surface 3 side with respect to the electrode surface of the embedded portion 15a. The electrode surface of the field electrode 45 is positioned in the vicinity of the first main surface 3.

The electrode surface of the field electrode 45 may be formed flush with the first main surface 3. The electrode surface of the field electrode 45 may be positioned on the bottom wall side of the field trench 43 with respect to the first main surface 3. The electrode surface of the field electrode 45 may project upward from the first main surface 3.

The field structure 42 may be of the trench insulation type instead of the trench electrode type. In this case, instead of the field electrode 45, an insulator (silicon oxide, silicon nitride, silicon oxynitride, etc.) is embedded in the field trench 43 via the field insulation film 44. In this case, the field insulation film 44 may be removed.

The semiconductor device 1D includes the plurality of first impurity regions 51 of the p-type respectively formed in the regions along the lower end portions of the plurality of gate structures 12 in the chip 2. The first impurity regions 51 have the p-type impurity concentration higher than the p-type impurity concentration of the base layer 8. The p-type impurity concentration of the first impurity regions 51 may be not less than 1×10¹⁶ cm⁻³ and not more than 1×10¹⁹ cm⁻³.

The plurality of first impurity regions 51 are respectively formed at intervals from the gate structure 12 adjacent in the second direction Y in a one-to-one correspondence relationship with the lower end portions of the corresponding gate structures 12. The plurality of first impurity regions 51 have the respective portions covering the bottom walls and the respective portions covering the side walls at the lower end portions of the corresponding gate structures 12. The plurality of first impurity regions 51 extend as bands in the first direction X along the corresponding gate structures 12 in plan view.

The plurality of first impurity regions 51 oppose the embedded electrodes 15 across the insulation films 14 at the lower end portions of the corresponding gate structures 12. The plurality of first impurity regions 51 are electrically connected to the drift layer 9 on the first main surface 3 side and are electrically connected to the base layer 8 on the second main surface 4 side. In this embodiment, each of the plurality of first impurity regions 51 has the portion in which the conductivity type of the drift layer 9 on the first main surface 3 side is replaced from the n-type to the p-type.

In the case where the bottom walls of the plurality of gate structures 12 are positioned in the base layer 8, the plurality of first impurity regions 51 may be formed at intervals from the bottom portion of the drift layer 9 toward the second main surface 4. In this case, the plurality of first impurity regions 51 may oppose the drift layer 9 across a part of the base layer 8.

The plurality of first impurity regions 51 are respectively formed to be wider than the corresponding gate structures 12. Specifically, the plurality of first impurity regions 51 respectively include the bulging portions flared in an arc shape (a circular arc shape) in the horizontal direction (on both sides) from the regions below the gate structures 12 in cross-sectional view. In the case where the gate structures 12 are each formed in a tapered shape, the bulging portions oppose the side walls of the gate structures 12 in the thickness direction of the chip 2.

With regard to the plurality of first impurity regions 51 adjacent in the second direction Y, the bulging portion of one of the first impurity regions 51 is connected to the bulging portion of the other of the first impurity regions 51. That is, the plurality of first impurity regions 51 are connected to each other in the second direction Y. Consequently, the plurality of first impurity regions 51 separates the base layer 8 and the drift layer 9 from each other in the up-down direction in the active region 6. Connection portions of the plurality of bulging portions may oppose the plurality of drain source regions 28 and 29 across the drift layer 9.

Portions of the plurality of first impurity regions 51 along the lower end portions of the plurality of gate structures 12 respectively form channels (current paths) of the transistor structure Tr. Inversion and non-inversion of the channels are controlled by the plurality of gate structures 12.

When the gate potential is applied to the plurality of gate structures 12, the first drain source potential is applied to the first drain source region 28, and the second drain source potential is applied to the second drain source region 29, the plurality of channels are turned on, and the drain source current Ids is generated (see FIG. 36).

The drain source current Ids flows from the first drain source region 28 to the second drain source region 29 via the drift layer 9 and the plurality of first impurity regions 51. That is, the drain source current Ids passes through the region below the plurality of (in this embodiment, two) gate structures 12 interposed between the first drain source region 28 and the second drain source region 29 in the second direction Y.

The first impurity region 51 is formed by introducing the p-type impurity into the chip 2 via the bottom wall portion of the trench 13. In the case of the trench 13 having the flat bottom wall, the p-type impurity can be appropriately introduced into the chip 2. Therefore, the first impurity region 51 (the channel) is appropriately formed in the region along the lower end portion of the gate structure 12.

The semiconductor device 1D includes the plurality of second impurity regions 52 of the p-type respectively formed in regions along lower end portions of the plurality of connection structures 21 and 22 inside the chip 2. The second impurity regions 52 have a p-type impurity concentration higher than the p-type impurity concentration of the base layer 8. It is preferable that the p-type impurity concentration of the second impurity regions 52 is substantially equal to the p-type impurity concentration of the first impurity regions 51. The p-type impurity concentration of the second impurity regions 52 may be not less than 1×10¹⁶ cm⁻³ and not more than 1×10¹⁹ cm⁻³.

The plurality of second impurity regions 52 are respectively formed in a one-to-one correspondence relationship with the lower end portions of the corresponding connection structures 21 and 22. The plurality of second impurity regions 52 respectively have portions covering bottom walls and portions covering side walls at the lower end portions of the corresponding connection structures 21 and 22. The plurality of second impurity regions 52 extend as bands in the second direction Y along the corresponding connection structures 21 and 22 in plan view and are connected to the first impurity regions 51 at both end portions of the corresponding connection structures 21 and 22.

The plurality of second impurity regions 52 oppose the connection electrodes 25 across the connection insulation films 24 at the lower end portions of the corresponding connection structures 21 and 22. The plurality of second impurity regions 52 are electrically connected to the drift layer 9 on the first main surface 3 side and are electrically connected to the base layer 8 on the second main surface 4 side. In this embodiment, each of the plurality of second impurity regions 52 has a portion in which the conductivity type of the drift layer 9 on the first main surface 3 side is replaced from the n-type to the p-type.

In a case where the bottom walls of the plurality of connection structures 21 and 22 are positioned in the base layer 8, the plurality of second impurity regions 52 may be formed at intervals from the bottom portion of the drift layer 9 toward the second main surface 4. In this case, the plurality of second impurity regions 52 may oppose the drift layer 9 across a part of the base layer 8.

In this embodiment, the plurality of connection structures 21 and 22 are formed deeper than the plurality of gate structures 12, and the plurality of second impurity regions 52 are formed deeper than the plurality of first impurity regions 51. That is, bottom portions of the plurality of second impurity regions 52 are positioned on the second main surface 4 side with respect to bottom portions of the plurality of first impurity regions 51. As a matter of course, the plurality of connection structures 21 and 22 may be formed at substantially the same depth as the plurality of gate structures 12, and the plurality of second impurity regions 52 may be formed at substantially the same depth as the plurality of first impurity regions 51.

The plurality of second impurity regions 52 are respectively formed to be wider than the corresponding connection structures 21 and 22. Specifically, similarly to the plurality of first impurity regions 51, the plurality of second impurity regions 52 respectively include bulging portions flared in an arc shape (a circular arc shape) in the horizontal direction (on both sides) from regions below the connection structures 21 and 22 in cross-sectional view. In a case where the connection structures 21 and 22 are each formed in a tapered shape, the bulging portions oppose the side walls of the connection structures 21 and 22 in the thickness direction of the chip 2.

The second impurity region 52 is formed by introducing the p-type impurity into the chip 2 via a bottom wall portion of the connection trench 23. In the case of the connection trench 23 having a flat bottom wall, the p-type impurity can be appropriately introduced into the chip 2. Therefore, the second impurity regions 52 are appropriately formed in the regions along the lower end portions of the connection structures 21 and 22.

The semiconductor device 1D includes the plurality of third impurity regions 53 of the p-type respectively formed in regions along lower end portions of the plurality of separating structures 31 and 32 inside the chip 2. The third impurity regions 53 have a p-type impurity concentration higher than the p-type impurity concentration of the base layer 8. It is preferable that the p-type impurity concentration of the third impurity regions 53 is substantially equal to the p-type impurity concentration of the first impurity regions 51. The p-type impurity concentration of the third impurity regions 53 may be not less than 1×10¹⁶ cm⁻³ and not more than 1×10¹⁹ cm⁻³.

The plurality of third impurity regions 53 are respectively formed in a one-to-one correspondence relationship with the lower end portions of the corresponding separating structures 31 and 32. The plurality of third impurity regions 53 respectively have portions covering bottom walls and portions covering side walls at the lower end portions of the corresponding separating structures 31 and 32. The plurality of third impurity regions 53 extend as bands in the second direction Y along the corresponding separating structures 31 and 32 in plan view and are connected to the first impurity regions 51 at both end portions of the corresponding separating structures 31 and 32.

The plurality of third impurity regions 53 oppose the separation electrodes 35 across the separation insulation films 34 at the lower end portions of the corresponding separating structures 31 and 32. The plurality of third impurity regions 53 are electrically connected to the drift layer 9 on the first main surface 3 side and are electrically connected to the base layer 8 on the second main surface 4 side. In this embodiment, each of the plurality of third impurity regions 53 has a portion in which the conductivity type of the drift layer 9 on the first main surface 3 side is replaced from the n-type to the p-type.

In a case where the bottom walls of the plurality of separating structures 31 and 32 are positioned in the base layer 8, the plurality of third impurity regions 53 may be formed at intervals from the bottom portion of the drift layer 9 toward the second main surface 4. In this case, the plurality of third impurity regions 53 may oppose the drift layer 9 across a part of the base layer 8.

In this embodiment, the plurality of separating structures 31 and 32 are formed at substantially the same depth as the plurality of gate structures 12, and the plurality of third impurity regions 53 are formed at substantially the same depth as the plurality of first impurity regions 51. As a matter of course, the plurality of separating structures 31 and 32 may be formed deeper than the plurality of gate structures 12, and the plurality of third impurity regions 53 may be formed deeper than the plurality of first impurity regions 51.

The plurality of third impurity regions 53 are respectively formed to be wider than the corresponding separating structures 31 and 32. Specifically, similarly to the plurality of first impurity regions 51, the plurality of third impurity regions 53 respectively include bulging portions flared in an arc shape (a circular arc shape) in the horizontal direction (on both sides) from regions below the separating structures 31 and 32 in cross-sectional view. In a case where the separating structures 31 and 32 are each formed in a tapered shape, the bulging portions oppose the side walls of the separating structures 31 and 32 in the thickness direction of the chip 2.

The third impurity region 53 is formed by introducing the p-type impurity into the chip 2 via a bottom wall portion of the separation trench 33. In the case of the separation trench 33 having a flat bottom wall, the p-type impurity can be appropriately introduced into the chip 2. Therefore, the third impurity regions 53 are appropriately formed in the regions along the lower end portions of the separating structures 31 and 32.

The semiconductor device 1D includes the plurality of fourth impurity regions 54 of the p-type respectively formed in regions along lower end portions of the plurality of field structures 42 in the chip 2. The fourth impurity regions 54 have a p-type impurity concentration higher than the p-type impurity concentration of the base layer 8. It is preferable that the p-type impurity concentration of the fourth impurity regions 54 is substantially equal to the p-type impurity concentration of the first impurity regions 51. The p-type impurity concentration of the fourth impurity regions 54 may be not less than 1×10¹⁶ cm⁻³ and not more than 1×10¹⁹ cm⁻³.

The plurality of fourth impurity regions 54 are respectively formed at intervals from the first impurity regions 51, the second impurity regions 52, and the third impurity regions 53 in a one-to-one correspondence relationship with the lower end portions of the corresponding field structures 42. The plurality of fourth impurity regions 54 respectively have portions covering bottom walls and portions covering side walls at the lower end portions of the corresponding field structures 42. The plurality of fourth impurity regions 54 extend as bands along the corresponding field structures 42 in plan view. Specifically, the plurality of fourth impurity regions 54 extend in an annular shape along the corresponding field structures 42 in plan view.

The plurality of fourth impurity regions 54 oppose the field electrodes 45 across the field insulation films 44 at the lower end portions of the corresponding field structures 42. The plurality of fourth impurity regions 54 are electrically connected to the drift layer 9 on the first main surface 3 side and are electrically connected to the base layer 8 on the second main surface 4 side. In this embodiment, each of the plurality of fourth impurity regions 54 has a portion in which the conductivity type of the drift layer 9 on the first main surface 3 side is replaced from the n-type to the p-type.

In a case where the bottom walls of the plurality of field structures 42 are positioned in the base layer 8, the plurality of fourth impurity regions 54 may be formed at intervals from the bottom portion of the drift layer 9 toward the second main surface 4. In this case, the plurality of fourth impurity regions 54 may oppose the drift layer 9 across a part of the base layer 8.

In this embodiment, the plurality of field structures 42 are formed deeper than the plurality of gate structures 12, and the plurality of fourth impurity regions 54 are formed deeper than the plurality of first impurity regions 51. That is, bottom portions of the plurality of fourth impurity regions 54 are positioned on the second main surface 4 side with respect to bottom portions of the plurality of first impurity regions 51. As a matter of course, the plurality of field structures 42 may be formed at substantially the same depth as the plurality of gate structures 12, and the plurality of fourth impurity regions 54 may be formed at substantially the same depth as the plurality of first impurity regions 51.

The plurality of fourth impurity regions 54 are respectively formed to be wider than the corresponding field structures 42. Specifically, similarly to the plurality of first impurity regions 51, the plurality of fourth impurity regions 54 respectively include bulging portions flared in an arc shape (a circular arc shape) in the horizontal direction (on both sides) from regions below the field structures 42 in cross-sectional view. In a case where the field structures 42 are each formed in a tapered shape, the bulging portions oppose the side walls of the field structures 42 in the thickness direction of the chip 2.

With regard to the plurality of adjacent fourth impurity regions 54, a bulging portion of one of the fourth impurity regions 54 is connected to a bulging portion of the other of the fourth impurity regions 54. Consequently, the plurality of fourth impurity regions 54 separate the base layer 8 and the drift layer 9 from each other in the up-down direction in the outer region 7.

The fourth impurity region 54 is formed by introducing the p-type impurity into the chip 2 via a bottom wall portion of the field trench 43. In the case of the field trench 43 having a flat bottom wall, the p-type impurity can be appropriately introduced into the chip 2. Therefore, the fourth impurity regions 54 are appropriately formed in the regions along the lower end portions of the field structures 42.

The semiconductor device 1D includes one or a plurality (in this embodiment, one) of the trench-electrode base structure 55 formed in the outer region 7 on the first main surface 3. The base structure 55 may be referred to as a “trench base structure.” The base potential is to be applied to the base structure 55. The base structure 55 is arranged in a region between the plurality of gate structures 12 (the plurality of connection structures 21 and 22) and the innermost field structure 42.

The base structure 55 extends as a band along the active region 6 in plan view. In this embodiment, the base structure 55 has a portion extending as a band in the first direction X and a portion extending as a band in the second direction Y in plan view. In this embodiment, the base structure 55 surrounds the plurality of gate structures 12 (the active region 6) in plan view and is formed in a polygonal annular shape (in this embodiment, a quadrangular annular shape) having four sides parallel to the peripheral edges of the chip 2.

That is, the base structure 55 defines the active region 6 in the outer region 7. The base structure 55 opposes the plurality of active regions 6 (the plurality of gate structures 12) in the first direction X and the second direction Y. As a matter of course, the plurality of base structures 55 may be arrayed at intervals in the first direction X and the second direction Y along the active region 6 such as to surround the plurality of gate structures 12 (the active region 6).

The base structure 55 is positioned in the drift layer 9 in cross-sectional view. Specifically, the base structure 55 is formed at intervals from the depth position of the bottom portion of the drift layer 9 toward the first main surface 3 and has side walls and a bottom wall positioned in the drift layer 9. The base structure 55 may be formed in a tapered shape having an opening width narrowing toward the bottom wall in cross-sectional view. The bottom wall of the base structure 55 may have a flat portion extending substantially parallel to the first main surface 3. As a matter of course, the bottom wall of the base structure 55 may be curved in a circular arc shape toward the second main surface 4.

A width of the base structure 55 is preferably less than the width of the field structure 42. The width of the base structure 55 may be larger than the width of the field structure 42. The width of the base structure 55 may be substantially equal to the width of the field structure 42. In this embodiment, the width of the base structure 55 is less than the width of the gate structure 12. The width of the base structure 55 may be larger than the width of the gate structure 12. The width of the base structure 55 may be substantially equal to the width of the gate structure 12.

The width of the base structure 55 may be not less than 0.1 μm and not more than 5 μm. The width of the base structure 55 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

A depth of the base structure 55 is less than the depth of the field structure 42. In this embodiment, the depth of the base structure 55 is less than the depth of the gate structure 12. The base structure 55 is preferably formed at intervals from the depth position of the electrode surface of the embedded portion 15a of the gate structure 12 toward the first main surface 3. The base structure 55 is preferably formed at intervals from the depth position of the intermediate portion of the gate structure 12 toward the first main surface 3. That is, the bottom wall of the base structure 55 is preferably formed at a depth position opposing the embedded insulator 16 in the horizontal direction.

The depth of the base structure 55 may be not less than 0.1 μm and not more than 10 μm. The depth of the base structure 55 may have a value falling within at least one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 4 μm, not less than 4 μm and not more than 6 μm, not less than 6 μm and not more than 8 μm, and not less than 8 μm and not more than 10 μm.

The base structure 55 includes the base trench 56 and the base electrode 57. The base trench 56 is dug from the first main surface 3 toward the second main surface 4, and defines the side walls and the bottom wall of the base structure 55. The base electrode 57 is embedded in the base trench 56 and is electrically connected to the chip 2 in the base trench 56.

In this embodiment, the base electrode 57 includes the first electrode 58 and the second electrode 59. The first electrode 58 covers, in a film shape, wall surfaces of the base trench 56. The first electrode 58 may have a single layer structure constituted of a Ti film or a Ti alloy film. The first electrode 58 may have a laminated structure including the Ti film and the Ti alloy film laminated in that order from the chip 2 side. The Ti alloy film may be a TiN film.

The second electrode 59 is embedded in the base trench 56 via the first electrode 58 and is electrically connected to the chip 2 via the first electrode 58. The second electrode 59 may contain at least one type among W, Al, an Al alloy, Cu, and a Cu alloy. The Al alloy may include at least one type among an AlSi alloy, an AlCu alloy, and an AlSiCu alloy.

The semiconductor device 1D includes the silicide layer 60 formed in a region along the base structure 55 in the chip 2. The silicide layer 60 is formed in a film shape along the wall surfaces (the side walls and the bottom wall) of the base structure 55 and is mechanically and electrically connected to the base electrode 57. The silicide layer 60 is formed at intervals from the plurality of gate structures 12 and the innermost field structure 42.

The silicide layer 60 may include at least one of a Ti silicide layer, an Ni silicide layer, a Co silicide layer, a Mo silicide layer, and a W silicide layer. In this embodiment, the silicide layer 60 includes the Ti silicide layer.

A thickness of the silicide layer 60 may be not less than 1 nm and not more than 500 nm. The thickness of the silicide layer 60 may have a value falling within at least one of ranges of not less than 1 nm and not more than 50 nm, not less than 50 nm and not more than 100 nm, not less than 100 nm and not more than 200 nm, not less than 200 nm and not more than 300 nm, not less than 300 nm and not more than 400 nm, and not less than 400 nm and not more than 500 nm.

The semiconductor device 1D includes the contact region 61 of the p-type formed in a region below the base structure 55 in the chip 2. In this embodiment, the contact region 61 is formed by introducing the p-type impurity into the drift layer 9. The contact region 61 has a p-type impurity concentration higher than an n-type impurity concentration of the drift layer 9 and replaces the conductivity type of the drift layer 9 from the n-type to the p-type.

The p-type impurity concentration of the contact region 61 is higher than the p-type impurity concentration of the base layer 8. As a matter of course, the contact region 61 may be formed by introducing the p-type impurity into the base layer 8. The p-type impurity concentration of the contact region 61 may be not less than 1×10¹⁶ cm⁻³ and not more than 1×10²¹ cm⁻³.

The contact region 61 extends as a band along the base structure 55. In this embodiment, the contact region 61 has a portion extending as a band in the first direction X and a portion extending as a band in the second direction Y in plan view. In this embodiment, the contact region 61 is formed in a polygonal annular shape (in this embodiment, a quadrangular annular shape) extending along the base structure 55 in plan view.

The contact region 61 flares in the horizontal direction from a region directly below the base structure 55 and is connected to the plurality of gate structures 12, the plurality of connection structures 21 and 22, and the innermost field structure 42. The contact region 61 extends in the thickness direction of the chip 2 in a thickness range between the base layer 8 and the base structure 55 and penetrates the bottom portion of the drift layer 9 to reach the base layer 8.

The contact region 61 has a lower end portion connected to the base layer 8 and an upper end portion connected to the base structure 55 and electrically connects the base structure 55 to the base layer 8. In this embodiment, the lower end portion of the contact region 61 is formed at intervals from the depth positions of the bottom portions of the first impurity region 51 and the fourth impurity region 54 toward the first main surface 3.

As a matter of course, the lower end portion of the contact region 61 may be positioned below the depth positions of the bottom portions of the first impurity region 51 and the fourth impurity region 54 (on the second main surface 4 side). The lower end portion of the contact region 61 may be curved in an arc shape (a circular arc shape) toward the second main surface 4.

The lower end portion of the contact region 61 may be connected to the first impurity regions 51 at portions along the gate structures 12. The lower end portion of the contact region 61 may be connected to the second impurity regions 52 at portions along the connection structures 21 and 22. The lower end portion of the contact region 61 may be connected to the innermost fourth impurity region 54 at a portion along the innermost field structure 42.

The upper end portion of the contact region 61 is formed at intervals from the first main surface 3 toward the bottom wall of the base structure 55 and has a portion along the side walls and the bottom wall of the base structure 55. The upper end portion of the contact region 61 is electrically connected to the side walls and the bottom wall of the base structure 55 via the silicide layer 60. The upper end portion of the contact region 61 may be curved in an arc shape (a circular arc shape) toward the first main surface 3. That is, the upper end portion of the contact region 61 may be formed to be gradually separated from the first main surface 3 as being away from the base structure 55.

The semiconductor device 1D includes the surface layer region 62 of the n-type formed around the base structure 55 in the surface layer portion of the first main surface 3. The surface layer region 62 has an n-type impurity concentration higher than the n-type impurity concentration of the drift layer 9. The n-type impurity concentration of the surface layer region 62 may be higher than the n-type impurity concentration of the drain source regions 28 and 29. The n-type impurity concentration of the surface layer region 62 may be lower than the n-type impurity concentration of the drain source regions 28 and 29. The n-type impurity concentration of the surface layer region 62 may be not less than 1×10¹⁵ cm⁻³ and not more than 1×10²⁰ cm⁻³.

The surface layer region 62 extends as a band along the base structure 55 in plan view. In this embodiment, the surface layer region 62 has a portion extending as a band in the first direction X and a portion extending as a band in the second direction Y in plan view. In this embodiment, the surface layer region 62 is formed in a polygonal annular shape (in this embodiment, a quadrangular annular shape) extending along the base structure 55 in plan view.

The surface layer region 62 is formed in a thickness range between the first main surface 3 and the contact region 61. The surface layer region 62 has an upper end portion that is electrically connected to the base structure 55 via the silicide layer 60 and a lower end portion that is electrically connected to the contact region 61. In this embodiment, the surface layer region 62 has a bottom portion curved in an arc shape toward the first main surface 3.

That is, the surface layer region 62 is formed to gradually become deeper as being away from the base structure 55 and has a shallow portion formed in the vicinity of the base structure 55 and a deep portion formed far from the base structure 55. The shallow portion of the surface layer region 62 is formed at intervals from the bottom wall of the base structure 55 toward the first main surface 3 and is electrically connected to the side walls of the base structure 55 via the silicide layer 60.

The deep portion of the surface layer region 62 is positioned in a region on the second main surface 4 side with respect to the depth position of the bottom wall of the base structure 55. The deep portion of the surface layer region 62 is positioned in a region on the first main surface 3 side with respect to depth positions of the bottom walls of the plurality of gate structures 12 and the bottom walls of the plurality of field structures 42. The deep portion of the surface layer region 62 is preferably positioned in a region on the first main surface 3 side with respect to the depth position of the electrode surface of the embedded electrode 15.

The deep portion of the surface layer region 62 is particularly preferably positioned in a region on the first main surface 3 side with respect to the depth position of the intermediate portion of the gate structure 12. The deep portion of the surface layer region 62 is connected to the plurality of gate structures 12, the plurality of connection structures 21 and 22, and the innermost field structure 42. As a matter of course, the surface layer region 62 may have a substantially constant depth.

The surface layer region 62 may have a concentration gradient in which the n-type impurity concentration gradually decreases in the thickness direction. That is, the n-type impurity concentration of the surface layer region 62 may gradually decrease from the shallow portion toward the deep portion. In this case, the n-type impurity concentration in the deep portion is less than the n-type impurity concentration in the shallow portion. The n-type impurity concentration of the shallow portion may be substantially equal to the n-type impurity concentration of the plurality of drain source regions 28 and 29.

With reference to FIGS. 36 to 39, the semiconductor device 1D includes the insulating interlayer film 70 covering the first main surface 3. The interlayer film 70 may be referred to as an “interlayer insulation film,” an “intermediate film,” an “intermediate insulation film,” etc. The interlayer film 70 has a laminated structure including the first interlayer film 71 and the second interlayer film 72 laminated in that order from the chip 2 (the first main surface 3) side.

The first interlayer film 71 is an insulation film, in which a wiring is arranged, and has a single layer structure constituted of a single insulation film or a laminated structure including a plurality of insulation films. The first interlayer film 71 may include at least one of a silicon oxide film, a silicon nitride film, and a silicon oxynitride film. The first interlayer film 71 collectively covers, in a film shape (a layer shape), the active region 6 and the outer region 7 on the first main surface 3.

That is, the first interlayer film 71 collectively covers the plurality of gate structures 12, the plurality of connection structures 21 and 22, the plurality of separating structures 31 and 32, the plurality of drain source regions 28 and 29, the plurality of field structures 42, etc. The first interlayer film 71 may cover the outer insulation films 10 and 11 on the peripheral edge side of the first main surface 3. The first interlayer film 71 may cover the first main surface 3 at intervals inward from the outer insulation films 10 and 11 and expose the outer insulation films 10 and 11.

The second interlayer film 72 is an insulation film, in which a wiring is arranged at a position higher than that of the first interlayer film 71, and has a single layer structure constituted of a single insulation film or a laminated structure including a plurality of insulation films. The second interlayer film 72 may include at least one of a silicon oxide film, a silicon nitride film, and a silicon oxynitride film. The second interlayer film 72 covers, in a film shape (a layer shape), the first interlayer film 71.

With reference to FIGS. 40 and 41, the semiconductor device 1D includes the multilayer wiring structure 73 arranged on the chip 2 (the first main surface 3). The multilayer wiring structure 73 is formed using the interlayer film 70. Specifically, the multilayer wiring structure 73 includes the first layer wiring 74 arranged on a lower layer side of the interlayer film 70 and the second layer wiring 75 arranged on an upper layer side of the interlayer film 70. The first layer wiring 74 is arranged on the first interlayer film 71 and is covered with the second interlayer film 72. The second layer wiring 75 is arranged on the second interlayer film 72 and three-dimensionally intersects the first layer wiring 74.

In this embodiment, the multilayer wiring structure 73 is constituted of a two-layer structure including the first layer wiring 74 and the second layer wiring 75. That is, the first layer wiring 74 is formed as the lowermost wiring of the multilayer wiring structure 73, and the second layer wiring 75 is formed as the uppermost wiring of the multilayer wiring structure 73. The second layer wiring 75 is exposed from the interlayer film 70.

The multilayer wiring structure 73 may include the first layer wiring 74 and the second layer wiring 75 opposing each other in the up-down direction across a part (the second interlayer film 72) of the interlayer film 70, and the number of laminated layers of the multilayer wiring structure 73 is not limited to two. That is, the multilayer wiring structure 73 may have a laminated structure of three or more layers. For example, in a case where the interlayer film 70 has one or a plurality of lower interlayer films below the first interlayer film 71, the multilayer wiring structure 73 may include one or a plurality of lower layer wirings arranged below the first layer wirings 74.

The first layer wiring 74 has a laminated structure including the first electrode 76 and the second electrode 77 laminated in that order from the first interlayer film 71 side. The first electrode 76 covers, in a film shape, the first interlayer film 71. The first electrode 76 may include one or both of a Ti film and a Ti alloy film. The Ti alloy film may be a TiN film.

The second electrode 77 covers, in a film shape, the first electrode 76. The second electrode 77 may include at least one of a W film, an Al film, an Al alloy film, a Cu film, and a Cu alloy film. The Al alloy film may include at least one of an AlSi alloy film, an AlCu alloy film, and an AlSiCu alloy film.

The second layer wiring 75 has a laminated structure including the first electrode 78 and the second electrode 79 laminated in that order from the second interlayer film 72 side. The first electrode 78 covers, in a film shape, the second interlayer film 72. The first electrode 78 may include one or both of a Ti film and a Ti alloy film. The Ti alloy film may be a TiN film.

The second electrode 79 covers, in a film shape, the first electrode 78. The second electrode 79 may include at least one of a W film, an Al film, an Al alloy film, a Cu film, and a Cu alloy film. The Al alloy film may include at least one of an AlSi alloy film, an AlCu alloy film, and an AlSiCu alloy film.

With reference to FIG. 40, etc., the first layer wiring 74 includes the wiring group 80. The wiring group 80 includes the plurality of first lower wirings 81 and the plurality of second lower wirings 82. The first lower wiring 81 transmits the first drain source potential to the first drain source region 28. The second lower wiring 82 transmits the second drain source potential to the second drain source region 29. The first lower wiring 81 may be referred to as a “first drain source wiring.” The second lower wiring 82 may be referred to as a “second drain source wiring.”

The plurality of first lower wirings 81 respectively extend as bands in the first direction X on the active region 6 and are arrayed at intervals in the second direction Y. That is, the plurality of first lower wirings 81 are arrayed as stripes extending in the first direction X. The plurality of first lower wirings 81 are respectively arranged on the plurality of first drain source regions 28 (the plurality of first mesa portions 26) and respectively oppose the plurality of first drain source regions 28 (the plurality of first mesa portions 26) in a one-to-one correspondence relationship in a lamination direction. The plurality of first lower wirings 81 are respectively electrically connected to the corresponding first drain source regions 28.

Hereinafter, a layout of one of the first lower wirings 81 will be described. The first lower wiring 81 preferably has both end portions positioned inward (on an inner side of the active region 6) from both end portions (the first end portion and the second end portion) of the corresponding gate structure 12 in the first direction X. Both the end portions of the first lower wiring 81 are preferably positioned inward from the plurality of connection structures 21 and 22.

Both the end portions of the first lower wiring 81 may be positioned in regions between the corresponding connection structures 21 and 22 and the separating structures 31 and 32 and may oppose the floating region 37 in the lamination direction. Both the end portions of the first lower wiring 81 may be positioned on the corresponding separating structures 31 and 32. Both the end portions of the first lower wiring 81 may be positioned inward from the corresponding separating structures 31 and 32 such as to be positioned on the corresponding first drain source region 28 (the first mesa portion 26).

Each of the first lower wirings 81 may have a width larger than the width of the corresponding first mesa portion 26 in the second direction Y. That is, the first lower wiring 81 may overlap the plurality of (in this embodiment, two) gate structures 12 positioned directly below. In this case, the first lower wiring 81 preferably has a width less than the width of the corresponding first gate unit GU1. As a matter of course, the first lower wiring 81 may have a width less than the width of the first mesa portion 26. As a matter of course, the first lower wiring 81 may have a width larger than the width of the first gate unit GU1.

The width of the first lower wiring 81 may be not less than 0.1 μm and not more than 15 μm. The width of the first lower wiring 81 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, not less than 9 μm and not more than 10 μm, not less than 10 μm and not more than 11 μm, not less than 11 μm and not more than 12 μm, not less than 12 μm and not more than 13 μm, not less than 13 μm and not more than 14 μm, and not less than 14 μm and not more than 15 μm.

The plurality of second lower wirings 82 are arranged on the active region 6 at intervals in the second direction Y from the plurality of first lower wirings 81. The plurality of second lower wirings 82 respectively extend as bands in the first direction X and are arrayed at intervals in the second direction Y. That is, the plurality of second lower wirings 82 are arrayed as stripes extending in the first direction X. The plurality of second lower wirings 82 are respectively interposed in regions between the plurality of first lower wirings 81. Specifically, the plurality of second lower wirings 82 and the plurality of first lower wirings 81 are alternately arrayed in the second direction Y.

The plurality of second lower wirings 82 are respectively arranged on the plurality of second drain source regions 29 (the plurality of second mesa portions 27) and respectively oppose the plurality of second drain source regions 29 (the plurality of second mesa portions 27) in a one-to-one correspondence relationship in the lamination direction. The plurality of second lower wirings 82 are respectively electrically connected to the corresponding second drain source regions 29. The plurality of second lower wirings 82 may be respectively arranged at wiring intervals of not less than 0.1 μm and not more than 15 μm from the plurality of first lower wirings 81 in the second direction Y.

The wiring interval may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, not less than 9 μm and not more than 10 μm, not less than 10 μm and not more than 11 μm, not less than 11 μm and not more than 12 μm, not less than 12 μm and not more than 13 μm, not less than 13 μm and not more than 14 μm, and not less than 14 μm and not more than 15 μm.

Hereinafter, a layout of one of the second lower wirings 82 will be described. The second lower wiring 82 preferably has both end portions positioned inward (on an inner side of the active region 6) from both end portions (the first end portion and the second end portion) of the corresponding gate structure 12 in the first direction X. Both the end portions of the second lower wiring 82 are preferably positioned inward from the corresponding connection structures 21 and 22.

Both the end portions of the second lower wiring 82 may be positioned in regions between the corresponding connection structures 21 and 22 and the corresponding separating structures 31 and 32 and may oppose the floating region 37 in the lamination direction. Both the end portions of the second lower wiring 82 may be positioned on the corresponding separating structures 31 and 32. Both the end portions of the second lower wiring 82 may be positioned inward from the corresponding separating structures 31 and 32 such as to be positioned on the corresponding second drain source region 29 (the second mesa portion 27).

Each of the second lower wirings 82 may have a width larger than the width of the corresponding second mesa portion 27 in the second direction Y. That is, the second lower wiring 82 may overlap the plurality of (in this embodiment, two) gate structures 12 positioned directly below. In this case, the second lower wiring 82 preferably has a width less than the width of the corresponding second gate unit GU2. As a matter of course, the second lower wiring 82 may have a width less than the width of the second mesa portion 27. As a matter of course, the second lower wiring 82 may have a width larger than the width of the second gate unit GU2.

The width of the second lower wiring 82 may be not less than 0.1 μm and not more than 15 μm. The width of the second lower wiring 82 may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, not less than 4.5 μm and not more than 5 μm, not less than 5 μm and not more than 6 μm, not less than 6 μm and not more than 7 μm, not less than 7 μm and not more than 8 μm, not less than 8 μm and not more than 9 μm, not less than 9 μm and not more than 10 μm, not less than 10 μm and not more than 11 μm, not less than 11 μm and not more than 12 μm, not less than 12 μm and not more than 13 μm, not less than 13 μm and not more than 14 μm, and not less than 14 μm and not more than 15 μm.

The second lower wiring 82 preferably has the length substantially equal to the length of the first lower wiring 81 in the first direction X. According to this configuration, variation in the wiring resistance between the first lower wiring 81 and the second lower wiring 82 is prevented. The second lower wiring 82 preferably has the width substantially equal to the width of the first lower wiring 81 in the second direction Y. According to this configuration, variation in the wiring resistance between the first lower wiring 81 and the second lower wiring 82 is prevented.

As described above, in the wiring group 80, the first drain source potential is to be applied to the plurality of first drain source regions 28 via the plurality of first lower wirings 81, and the second drain source potential is to be applied to the second drain source region 29 via the plurality of second lower wirings 82. That is, the first drain source potential and the second drain source potential are alternately applied in the second direction Y corresponding to the layout of the plurality of first lower wirings 81 and the plurality of second lower wirings 82. Therefore, according to this, the drain source current Ids is alternately input and output in the second direction Y.

The first layer wiring 74 includes one or a plurality (in this embodiment, one) of the third lower wiring 83 and one or a plurality (in this embodiment, one) of the fourth lower wiring 84. The third lower wiring 83 transmits the gate potential to the gate structures 12. The fourth lower wiring 84 transmits the base potential to the base structure 55. The third lower wiring 83 may be referred to as a “gate wiring.” The fourth lower wiring 84 may be referred to as a “base wiring.”

The third lower wiring 83 is arranged on the outer region 7 at intervals from the wiring group 80. The third lower wiring 83 is arranged at intervals from the active region 6 (the plurality of gate structures 12) toward the peripheral edge side of the chip 2 in plan view. The third lower wiring 83 is arranged in a region between the active region 6 (the plurality of gate structures 12) and the innermost field structure 42. The third lower wiring 83 is arranged at intervals from the base structure 55 toward the active region 6. The third lower wiring 83 is formed as a band extending along the active region 6 in plan view and intersects the end portions of the plurality of gate structures 12.

Specifically, the third lower wiring 83 has a portion extending in the first direction X and a portion extending in the second direction Y in plan view. In this embodiment, the third lower wiring 83 is formed in a polygonal shape (in this embodiment, a quadrangular shape) having four sides parallel to the peripheral edges of the chip 2 in plan view and intersects (specifically, is orthogonal to) both end portions of each of the plurality of gate structures 12 in a portion extending in the second direction Y. The third lower wiring 83 opposes the wiring group 80 in the first direction X and the second direction Y. The third lower wiring 83 collectively covers the plurality of connection structures 21 and 22 at a portion extending in the second direction Y and is electrically connected to the plurality of gate structures 12 via the plurality of connection structures 21 and 22.

The fourth lower wiring 84 is arranged on the outer region 7 at intervals from the wiring group 80. The fourth lower wiring 84 is arranged at intervals from the active region 6 (the plurality of gate structures 12) toward the peripheral edge side of the chip 2 in plan view. The fourth lower wiring 84 is arranged in a region between the active region 6 (the plurality of gate structures 12) and the innermost field structure 42.

The fourth lower wiring 84 is arranged at intervals from the third lower wiring 83 toward the innermost field structure 42. The fourth lower wiring 84 is arranged at a position overlapping the base structure 55 in plan view and extends as a band along the base structure 55. The fourth lower wiring 84 has a portion extending in the first direction X and a portion extending in the second direction Y in plan view.

In this embodiment, the fourth lower wiring 84 is formed in a polygonal shape (in this embodiment, a quadrangular shape) having four sides parallel to the peripheral edge of the chip 2 in plan view. The fourth lower wiring 84 opposes the wiring group 80 in the first direction X and the second direction Y. The fourth lower wiring 84 is electrically connected to the base structure 55. For example, in a case where the base potential is applied to the plurality of field structures 42, the fourth lower wiring 84 collectively covers the plurality of field structures 42 and is electrically connected to the plurality of field structures 42.

In the case where the plurality of field structures 42 are formed in an electrically floating state, the electrical connection portion of the fourth lower wiring 84 to the plurality of field structures 42 is not formed. In this case, the fourth lower wiring 84 may be arranged in a region directly on the plurality of field structures 42 and may oppose the plurality of field structures 42 across the first interlayer film 71. As a matter of course, the fourth lower wiring 84 may be arranged at intervals inward from the plurality of field structures 42.

The multilayer wiring structure 73 (the semiconductor device 1D) includes the plurality of via electrodes 91 to 94 embedded in the first interlayer film 71. The plurality of via electrodes 91 to 94 include the plurality of first via electrodes 91, the plurality of second via electrodes 92, the plurality of third via electrodes 93, and the at least one (in this embodiment, the single) fourth via electrode 94.

The first via electrode 91 is a plug electrode that transmits the first drain source potential to the first drain source region 28. The second via electrode 92 is a plug electrode that transmits the second drain source potential to the second drain source region 29. The third via electrode 93 is a plug electrode that transmits the gate potential to the gate structures 12 (the connection structures 21 and 22). The fourth via electrode 94 is a plug electrode that transmits the base potential to the base structure 55.

The first via electrode 91 may be referred to as a “first drain source via electrode.” The second via electrode 92 may be referred to as a “second drain source via electrode.” The third via electrode 93 may be referred to as a “gate via electrode.” The fourth via electrode 94 may be referred to as a “base via electrode.”

In this embodiment, each of the plurality of via electrodes 91 to 94 includes the first electrode 95 and the second electrode 96. The first electrode 95 covers, in a film shape, the wall surfaces of the via hole formed in the first interlayer film 71. The first electrode 95 may include one or both of a Ti film and a Ti alloy film. The Ti alloy film may be a TiN film.

The second electrode 96 is embedded in the via hole via the first electrode 95. The second electrode 96 may contain at least one type among W, Al, an Al alloy, Cu, and a Cu alloy. The Al alloy may include at least one type among an AlSi alloy, an AlCu alloy, and an AlSiCu alloy.

The plurality of first via electrodes 91 are interposed in a region between the plurality of first drain source regions 28 and the plurality of first lower wirings 81 in the first interlayer film 71 and respectively electrically connect the plurality of first lower wirings 81 to the corresponding first drain source regions 28. The multilayer wiring structure 73 may have at least one of the first via electrodes 91 in a region between one of the first lower wirings 81 and one of the first drain source regions 28.

In this embodiment, the plurality of first via electrodes 91 are interposed in the region between the corresponding first lower wiring 81 and the corresponding first drain source region 28 and are arrayed at intervals in the first direction X. The first via electrode 91 may be formed in a triangular shape, a quadrangular shape, a rectangular shape, a polygonal shape, a circular shape, or an elliptical shape in plan view. As a matter of course, the first via electrode 91 may be formed as a band (for example, in a rectangular shape) extending in the first direction X.

The first via electrode 91 may be formed using the first lower wiring 81. In this case, the first electrode 95 of the first via electrode 91 is integrally formed with the first electrode 76 of the first lower wiring 81 and forms one electrode film together with the first electrode 76. Similarly, the second electrode 96 of the first via electrode 91 is integrally formed with the second electrode 77 of the first lower wiring 81 and forms one electrode with the second electrode 77.

The plurality of second via electrodes 92 are interposed in a region between the plurality of second drain source regions 29 and the plurality of second lower wirings 82 in the first interlayer film 71 and respectively electrically connect the plurality of second lower wirings 82 to the corresponding second drain source regions 29. The multilayer wiring structure 73 may have at least one of the second via electrodes 92 in a region between one of the second lower wirings 82 and one of the second drain source regions 29.

In this embodiment, the plurality of second via electrodes 92 are interposed in the region between the corresponding second lower wiring 82 and the corresponding second drain source region 29 and are arrayed at intervals in the first direction X. The second via electrode 92 may be formed in a triangular shape, a quadrangular shape, a rectangular shape, a polygonal shape, a circular shape, or an elliptical shape in plan view. As a matter of course, the second via electrode 92 may be formed as a band (for example, a rectangular shape) extending in the first direction X.

The second via electrode 92 may be formed using the second lower wiring 82. In this case, the first electrode 95 of the second via electrode 92 is integrally formed with the first electrode 76 of the second lower wiring 82 and forms one electrode film together with the first electrode 76. Similarly, the second electrode 96 of the second via electrode 92 is integrally formed with the second electrode 77 of the second lower wiring 82 and forms one electrode with the second electrode 77.

The plurality of third via electrodes 93 are interposed in regions between the plurality of gate structures 12 (the plurality of connection structures 21 and 22) and the third lower wirings 83 in the first interlayer film 71 and electrically connect the third lower wirings 83 to the plurality of gate structures 12 (the plurality of connection structures 21 and 22). The multilayer wiring structure 73 may have at least one of the third via electrodes 93 for one of the gate structures 12 (the connection structures 21 and 22).

In this embodiment, the plurality of third via electrodes 93 are interposed in a region between one of the connection structures 21 and 22 and the third lower wiring 83 and are arrayed at intervals in the second direction Y. The third via electrode 93 may be formed in a triangular shape, a quadrangular shape, a rectangular shape, a polygonal shape, a circular shape, or an elliptical shape in plan view. As a matter of course, the third via electrode 93 may be formed as a band (for example, in a rectangular shape) extending in the second direction Y.

In this embodiment, the connection structures 21 and 22 wider than the gate structures 12 are formed. Therefore, since alignment margins of the third via electrodes 93 with respect to the connection structures 21 and 22 are secured, the third via electrodes 93 are appropriately connected to the connection structures 21 and 22.

The third via electrode 93 may be formed using the third lower wiring 83. In this case, the first electrode 95 of the third via electrode 93 is integrally formed with the first electrode 76 of the third lower wiring 83 and forms one electrode film together with the first electrode 76. Similarly, the second electrode 96 of the third via electrode 93 is integrally formed with the second electrode 77 of the third lower wiring 83 and forms one electrode with the second electrode 77.

The fourth via electrode 94 is interposed in the region between the base structure 55 and the fourth lower wiring 84 in the first interlayer film 71 and electrically connects the fourth lower wiring 84 to the base structure 55. The fourth via electrode 94 is formed as a band extending along the base structure 55 in plan view. The fourth via electrode 94 has a portion extending in the first direction X and a portion extending in the second direction Y in plan view. In this embodiment, the fourth via electrode 94 is formed in a polygonal shape (in this embodiment, a quadrangular shape in this embodiment) having four sides parallel to the peripheral edge of the chip 2 in plan view.

As a matter of course, the multilayer wiring structure 73 may include the plurality of fourth via electrodes 94. In this case, the plurality of fourth via electrodes 94 are arrayed at intervals along the base structure 55 (the fourth lower wiring 84). In this case, the fourth via electrode 94 may be formed in a triangular shape, a quadrangular shape, a rectangular shape, a polygonal shape, a circular shape, or an elliptical shape in plan view. As a matter of course, the fourth via electrode 94 may be formed in an ended band shape extending along the base structure 55 (the base wiring).

The fourth via electrode 94 is mechanically and electrically connected to the base electrode 57. In this embodiment, the fourth via electrode 94 is integrally formed with the base electrode 57. Specifically, the first electrode 95 of the fourth via electrode 94 is integrally formed with the first electrode 58 of the base electrode 57 and forms one electrode film with the first electrode 58. Similarly, the second electrode 96 of the fourth via electrode 94 is integrally formed with the second electrode 59 of the base electrode 57 and forms one electrode with the second electrode 59.

The fourth via electrode 94 may be formed using the fourth lower wiring 84. In this case, the first electrode 95 of the fourth via electrode 94 is integrally formed with the first electrode 76 of the fourth lower wiring 84 and forms one electrode film together with the first electrode 76. Similarly, the second electrode 96 of the fourth via electrode 94 is integrally formed with the second electrode 77 of the fourth lower wiring 84 and forms one electrode with the second electrode 77.

In a case where the base potential is applied to the plurality of field structures 42, the plurality of fourth via electrodes 94 are interposed between the fourth lower wiring 84 and the plurality of field structures 42 and electrically connect the fourth lower wiring 84 to the plurality of field structures 42.

With reference to FIG. 41, etc., the second layer wiring 75 includes the plurality of pad wirings 101 to 104. The plurality of pad wirings 101 to 104 include one or a plurality (in this embodiment, a plurality) of the first pad wirings 101, one or a plurality (in this embodiment, a plurality) of the second pad wirings 102, one or a plurality (in this embodiment, one) of the third pad wirings 103, and one or a plurality (in this embodiment, one) of the fourth pad wirings 104.

The first pad wiring 101 applies the first drain source potential to the first lower wiring 81. The second pad wiring 102 applies the second drain source potential to the second lower wiring 82. The third pad wiring 103 applies the gate potential to the third lower wiring 83. The fourth pad wiring 104 applies the base potential to the fourth lower wiring 84.

The first pad wiring 101 may be referred to as a “first drain source pad wiring.” The second pad wiring 102 may be referred to as a “second drain source pad wiring.” The third pad wiring 103 may be referred to as a “gate pad wiring.” The fourth pad wiring 104 may be referred to as a “base pad wiring.”

The number of the first pad wirings 101, the number of the second pad wirings 102, the number of the third pad wirings 103, and the number of the fourth pad wirings 104 are all arbitrary.

In this embodiment, the multilayer wiring structure 73 (the semiconductor device 1D) includes the ten first pad wirings 101, the ten second pad wirings 102, the one third pad wiring 103, and the one fourth pad wiring 104. That is, the total number of the first to fourth pad wirings 101 to 104 is 22.

The plurality of pad wirings 101 to 104 are respectively arranged in the plurality of arrangement regions 105 set in the interlayer film 70 (see also FIG. 31). The arrangement region 105 may be referred to as a “pad arrangement region.” The plurality of arrangement regions 105 are the quadrangular imaginary regions set as a matrix (in this embodiment, five rows and five columns) along the first direction X and the second direction Y in plan view. A plane area of the plurality of arrangement regions 105 is appropriately adjusted depending on a plane area of the chip 2, a wiring layout of a mounting substrate, etc.

The ten first pad wirings 101 are arranged in the five arrangement regions 105 of the first row and the five arrangement regions 105 of the fourth row at intervals in the first direction X. The ten second pad wirings 102 are arranged in the five arrangement regions 105 of the second row and the five arrangement regions 105 of the fifth row at intervals in the first direction X.

The plurality of second pad wirings 102 arranged in the second row respectively oppose the plurality of first pad wirings 101 arranged in the first row in a one-to-one correspondence relationship in the second direction Y. Similarly, the plurality of second pad wirings 102 arranged in the fifth row respectively oppose the plurality of first pad wirings 101 arranged in the fourth row in a one-to-one correspondence relationship in the second direction Y.

The third pad wiring 103 is arranged in the arrangement region 105 of the fifth column in the third row. The third pad wiring 103 opposes the second pad wiring 102 on the one side in the second direction Y and opposes the first pad wiring 101 on the other side in the second direction Y. The fourth pad wiring 104 is arranged in the arrangement region 105 of the first column in the third row. The fourth pad wiring 104 opposes the second pad wiring 102 on the one side in the second direction Y and opposes the first pad wiring 101 on the other side in the second direction Y.

The extra arrangement regions 105 without having the pad wirings 101 to 104 are set as space regions 106. In this embodiment, three arrangement regions 105 of the second to fourth columns of the third row are set as the space regions 106. That is, the three second pad wirings 102 arranged in the second row respectively oppose the three first pad wirings 101 arrayed in the fourth row across the three space regions 106 in a one-to-one correspondence relationship in the second direction Y. The fourth pad wiring 104 opposes the third pad wiring 103 in the first direction X across the three space regions 106.

The second layer wiring 75 includes the plurality of first wiring units U1, the plurality of second wiring units U2, the one third wiring unit U3, and the one fourth wiring unit U4. The first to fourth wiring units U1 to U4 are grouped (classified) according to a layout of the first to fourth pad wirings 101 to 104.

Each of the plurality of first wiring units U1 includes the first pad wiring 101 and the second pad wiring 102 opposing (closely opposing) each other in the second direction Y. That is, the second layer wiring 75 includes the ten first wiring units U1. In each of the first wiring units U1, the first pad wiring 101 and the second pad wiring 102 are selectively electrically connected to the first lower wirings 81 and the second lower wirings 82 positioned directly below.

The plurality of first wiring units U1 have identical layouts to each other except for a difference in connection locations (shifted in the first direction X) to the first lower wirings 81 and the second lower wirings 82. That is, the plurality of first wiring units U1 adjacent in the first direction X are electrically connected to the same first lower wiring 81 and the same second lower wiring 82 at different locations in the first direction X.

Each of the plurality of second wiring units U2 includes the first pad wiring 101 and the second pad wiring 102 opposing each other in the second direction Y across the space region 106. That is, the second layer wiring 75 includes the three second wiring units U2. In each of the second wiring units U2, the first pad wiring 101 and the second pad wiring 102 are selectively electrically connected to the first lower wirings 81 and the second lower wirings 82 positioned directly below.

The plurality of second wiring units U2 adjacent in the first direction X have identical layouts to each other except for a difference in connection locations (shifted in the first direction X) to the first lower wirings 81 and the second lower wirings 82. That is, the plurality of second wiring units U2 are electrically connected to the same first lower wiring 81 and the same second lower wiring 82 at different locations in the first direction X.

The third wiring unit U3 includes the first pad wiring 101, the second pad wiring 102, and the third pad wiring 103 opposing (closely opposing) each other in the second direction Y. In the third wiring unit U3, the first pad wiring 101 and the second pad wiring 102 are selectively electrically connected to the first lower wirings 81 and the second lower wirings 82 positioned directly below. Also, the third pad wiring 103 is electrically connected to the third lower wiring 83.

The fourth wiring unit U4 includes the first pad wiring 101, the second pad wiring 102, and the fourth pad wiring 104 opposing (closely opposing) each other in the second direction Y. In the fourth wiring unit U4, the first pad wiring 101 and the second pad wiring 102 are selectively electrically connected to the first lower wirings 81 and the second lower wirings 82 positioned directly below. Also, the fourth pad wiring 104 is electrically connected to the fourth lower wiring 84.

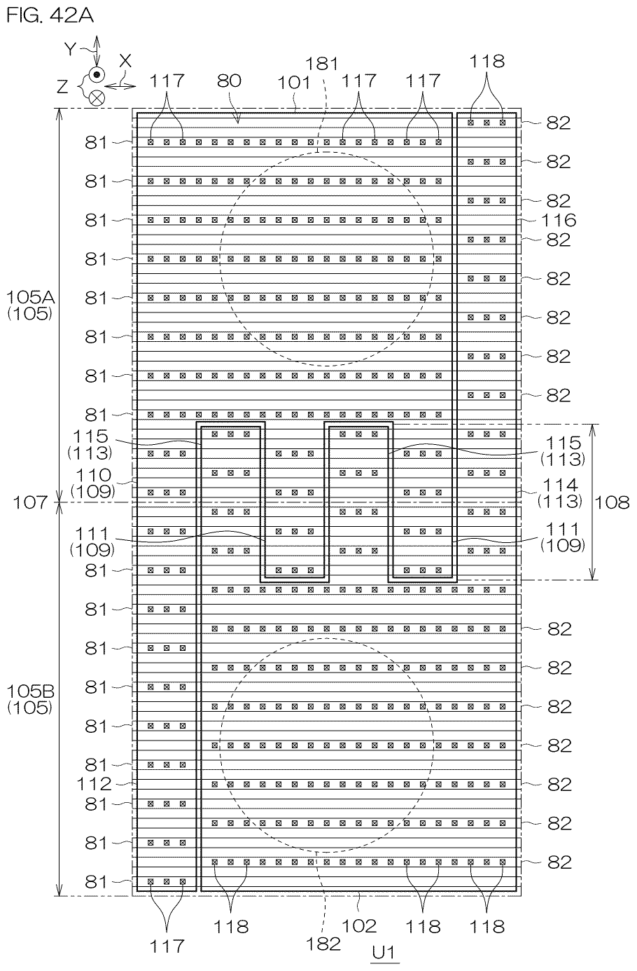

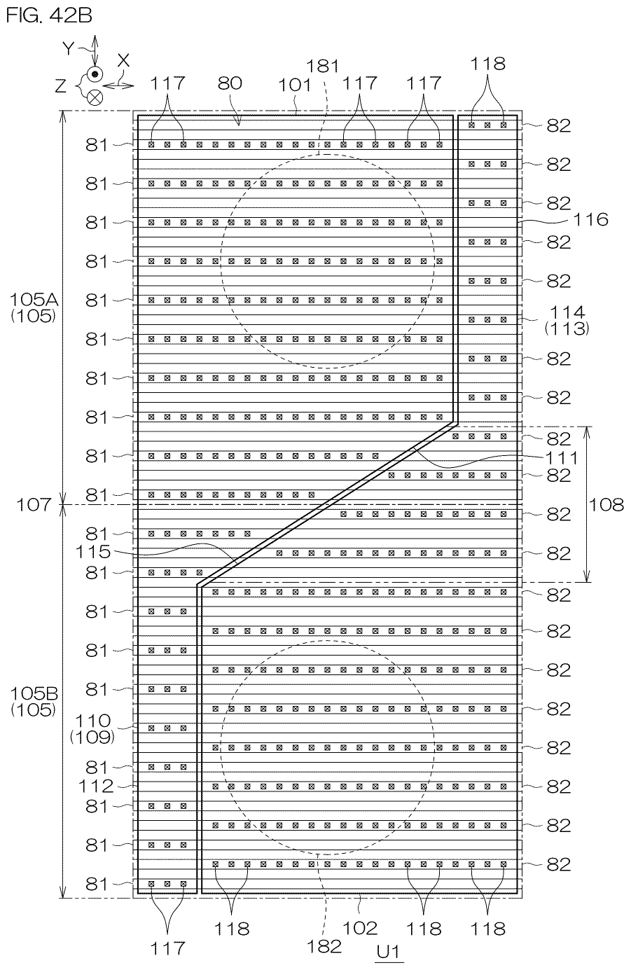

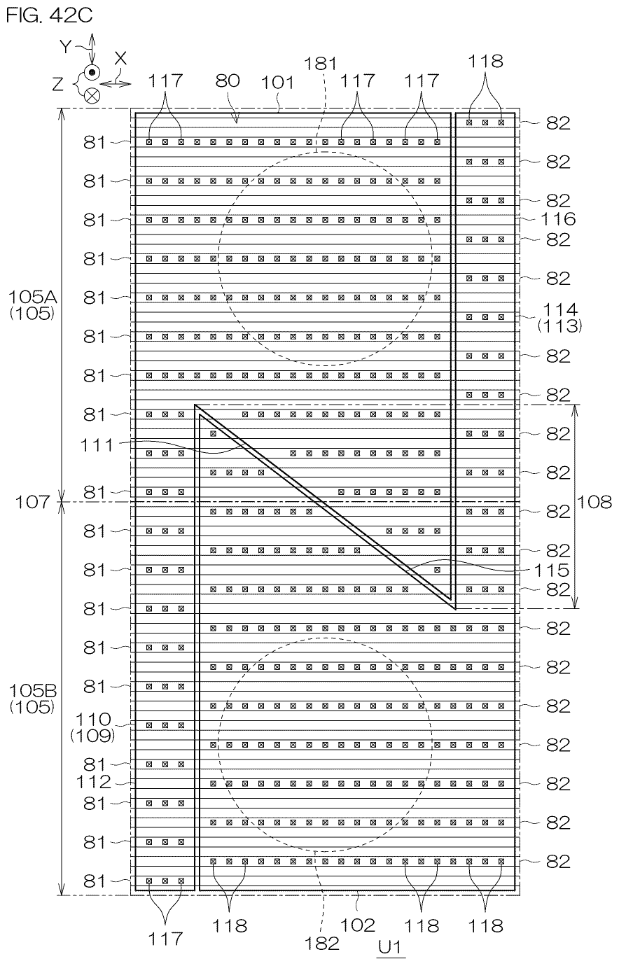

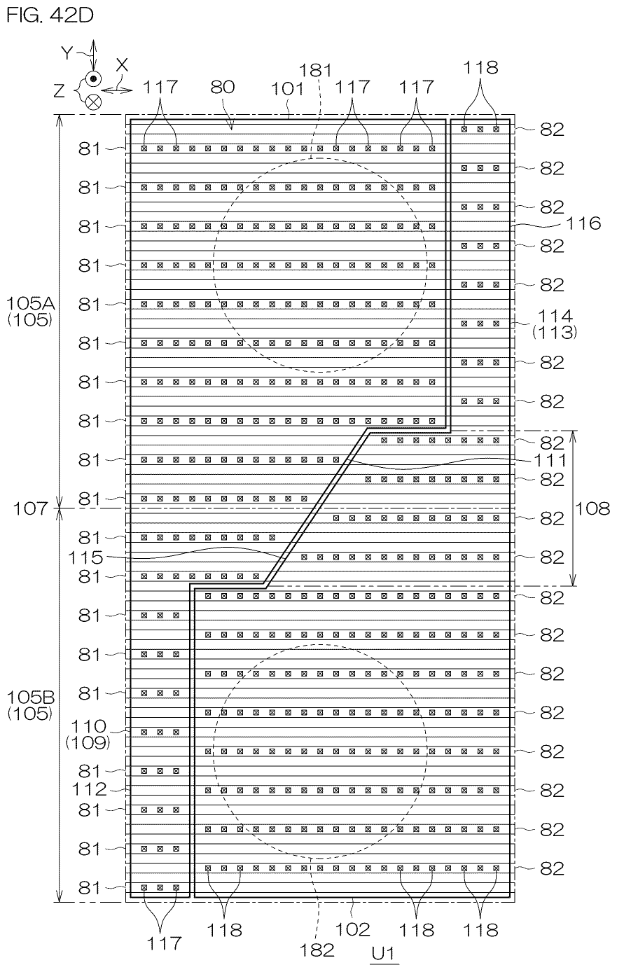

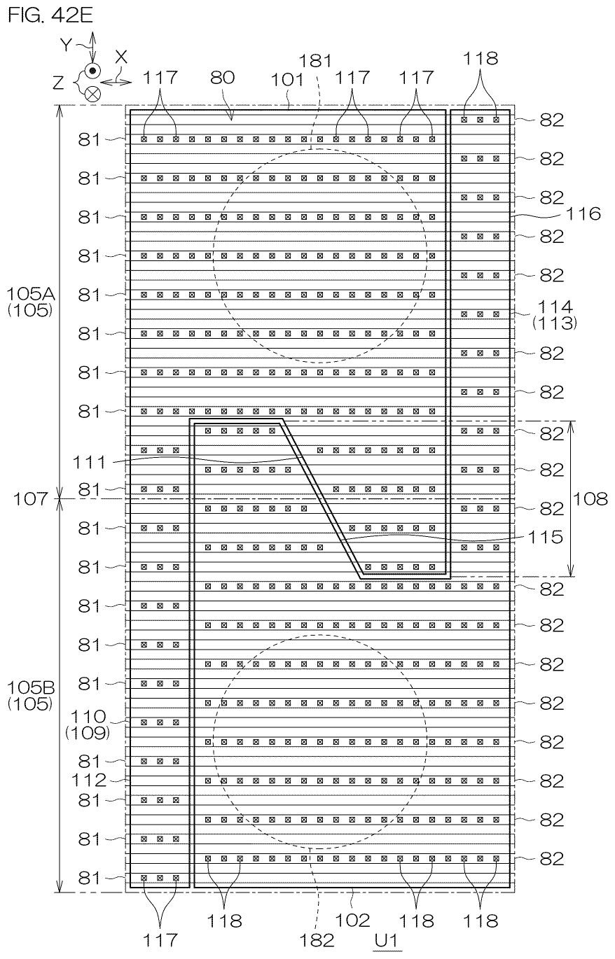

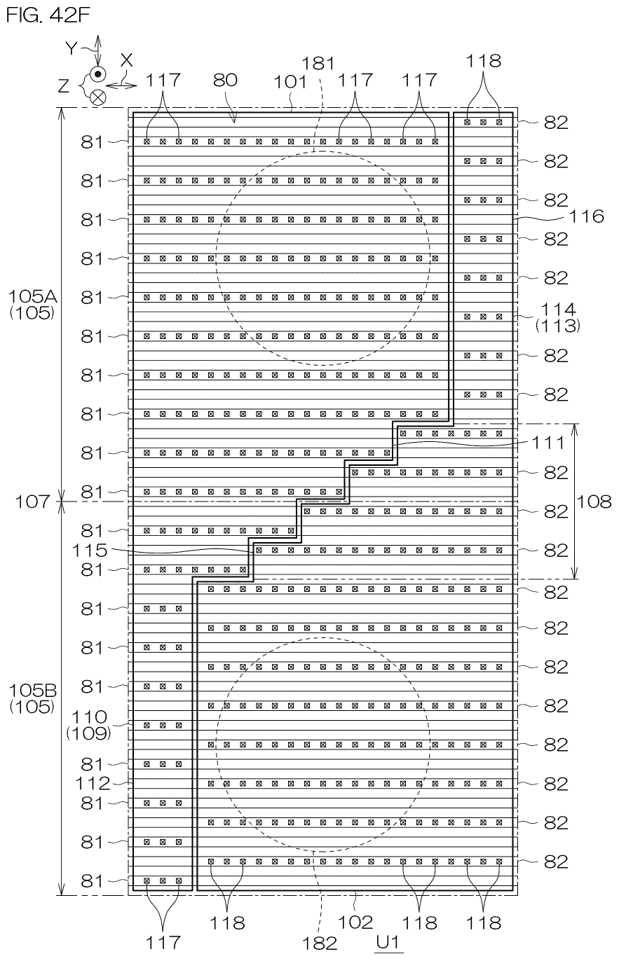

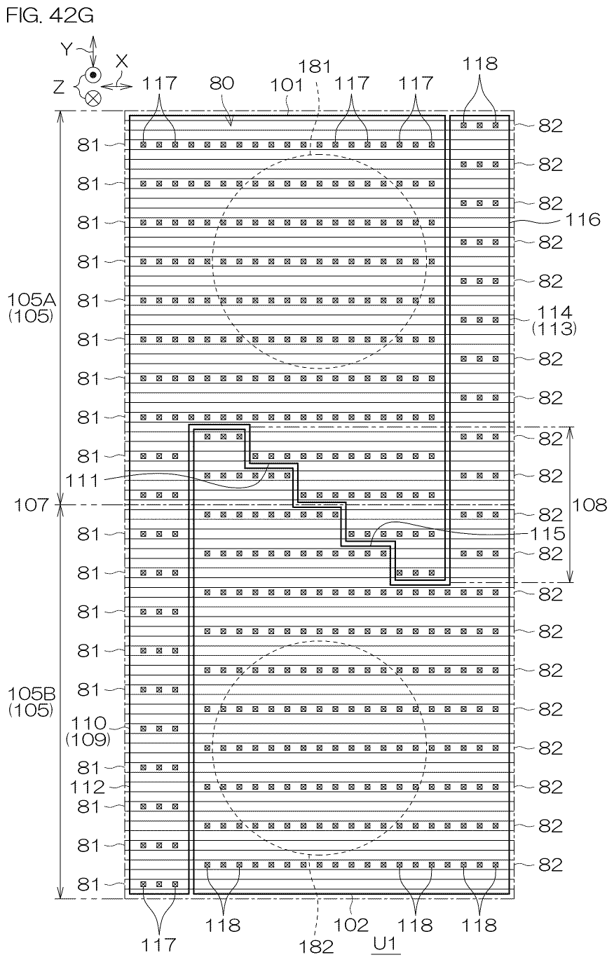

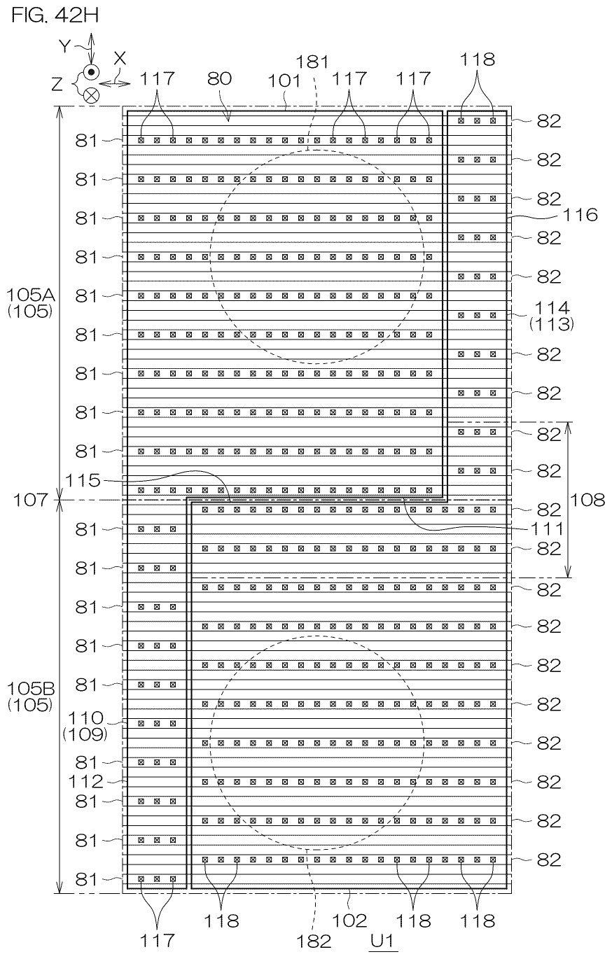

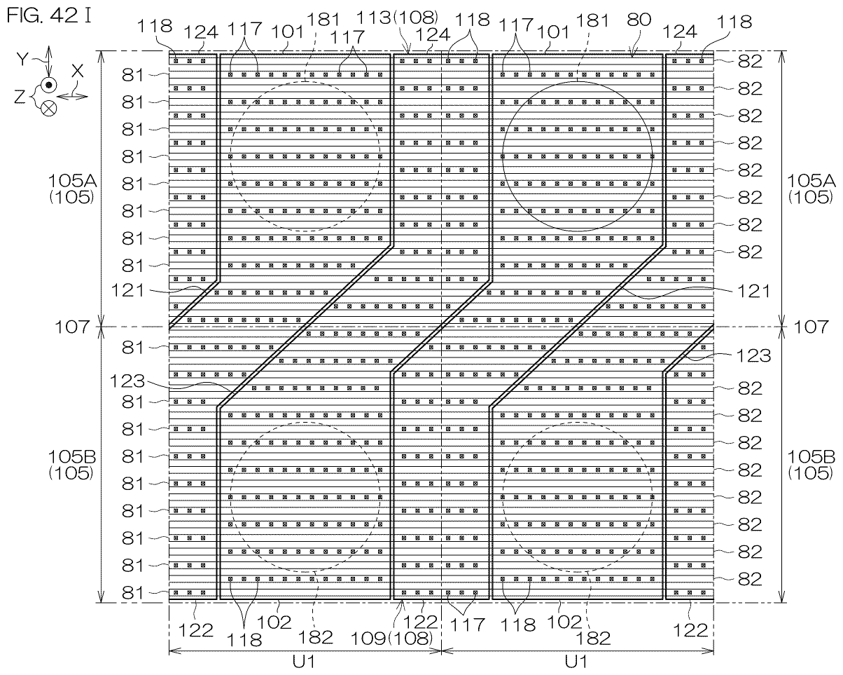

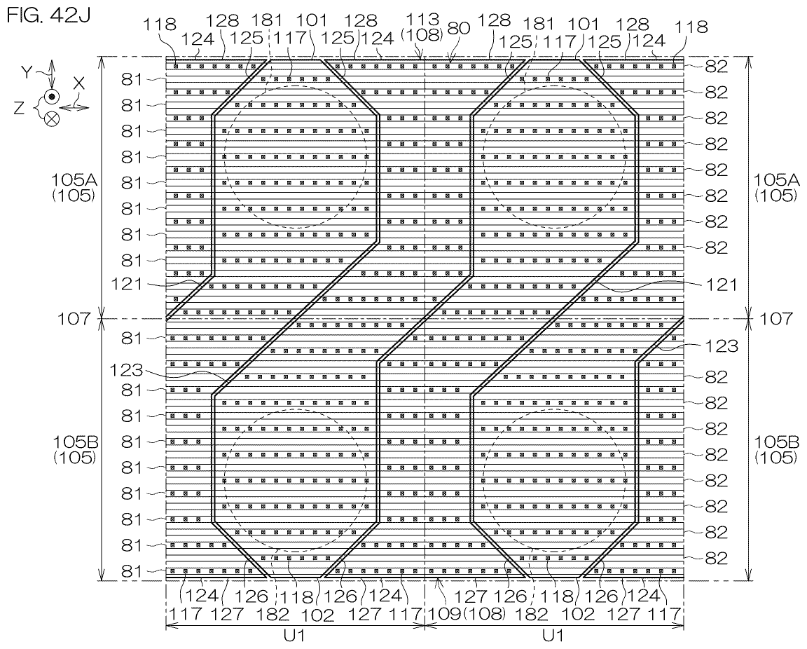

Hereinafter, a configuration of the first wiring unit U1 will be described, and then configurations of the second to fourth wiring units U2 to U4 will be described in this order. FIGS. 42A to 42J are enlarged plan views showing the first wiring units U1 according to first to tenth layout examples.

FIGS. 42A to 42J illustrate the first wiring units U1 arranged on the first side surface 5A side of the chip 2. Hereinafter, the first wiring unit U1 shown in FIG. 42A will be described as a basic form example, and the first wiring units U1 shown in FIGS. 42B to 42J will be described as modification examples of the basic form example. Also, hereinafter, unless otherwise specified, the configuration in one of the first wiring units U1 will be described.

With reference to FIG. 42A (the first layout example), the first wiring unit U1 includes the arrangement region 105 for the first pad wiring 101 and the arrangement region 105 for the second pad wiring 102. Hereinafter, the arrangement region 105 for the first pad wiring 101 is referred to as the “first arrangement region 105A,” and the arrangement region 105 for the second pad wiring 102 is referred to as the “second arrangement region 105B.”

The first arrangement region 105A is set on the one side in the second direction Y in plan view. The first arrangement region 105A is set in a quadrangular shape (preferably, a square shape) in plan view and includes at least one of the first lower wirings 81. Specifically, the first arrangement region 105A includes at least one (in this embodiment, a plurality) of the first lower wirings 81 and at least one (in this embodiment, a plurality) of the second lower wirings 82. In the first arrangement region 105A, both the number of the first lower wirings 81 and the number of the second lower wirings 82 are arbitrary.

For example, in the first arrangement region 105A, the number of the first lower wirings 81 (the second lower wirings 82) may be not less than 1 and not more than 1000. For example, in the first arrangement region 105A, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the first arrangement region 105A, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, in the first arrangement region 105A, a difference value between the number of the first lower wirings 81 and the number of the second lower wirings 82 is 0 to 1. That is, in the first arrangement region 105A, the wiring resistance of the second lower wiring 82 is substantially equal to the wiring resistance of the first lower wiring 81.

The second arrangement region 105B is set on the other side in the second direction Y with respect to the first arrangement region 105A in plan view and is adjacent to the first arrangement region 105A. The second arrangement region 105B defines, together with the first arrangement region 105A, the boundary portion 107. The second arrangement region 105B is set in a quadrangular shape (preferably, a square shape) in plan view and defines the boundary portion 107 extending in the first direction X. A plane area of the second arrangement region 105B is substantially equal to a plane area of the first arrangement region 105A.

The second arrangement region 105B includes at least one of the second lower wirings 82. Specifically, the second arrangement region 105B includes at least one (in this embodiment, a plurality) of the first lower wirings 81 and at least one (in this embodiment, a plurality) of the second lower wirings 82. In the second arrangement region 105B, the number of the first lower wirings 81 and the number of the second lower wirings 82 are arbitrary.

For example, in the second arrangement region 105B, the number of the first lower wirings 81 (the second lower wirings 82) may be not less than 1 and not more than 1000. For example, in the second arrangement region 105B, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the second arrangement region 105B, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, in the second arrangement region 105B, a difference value between the number of the first lower wirings 81 and the number of the second lower wirings 82 is 0 to 1. That is, in the second arrangement region 105B, the wiring resistance of the second lower wiring 82 is substantially equal to the wiring resistance of the first lower wiring 81.

It is preferable that, with regard to the first arrangement region 105A and the second arrangement region 105B, the number of the first lower wirings 81 is substantially equal to each other. That is, it is preferable that the wiring resistance related to the first lower wirings 81 in the second arrangement region 105B is substantially equal to the wiring resistance related to the first lower wirings 81 in the first arrangement region 105A. Also, it is preferable that, with regard to the first arrangement region 105A and the second arrangement region 105B, the number of the second lower wirings 82 is substantially equal to each other. That is, it is preferable that the wiring resistance related to the second lower wirings 82 in the second arrangement region 105B is substantially equal to the wiring resistance related to the second lower wirings 82 in the first arrangement region 105A.

The first wiring unit U1 includes the first pad wiring 101 arranged in the first arrangement region 105A. The first pad wiring 101 has the plane area less than the plane area of the first arrangement region 105A. The first pad wiring 101 is arranged at intervals inward from the peripheral edge of the first arrangement region 105A in plan view and is formed in a polygonal shape having four sides parallel to the peripheral edges of the chip 2 (the peripheral edges of the first arrangement region 105A).

The first pad wiring 101 is provided at a biased position on the one side in the first direction X with respect to a central portion of the boundary portion 107 and is provided at a biased position on the one side in the second direction Y with respect to the boundary portion 107. The first pad wiring 101 has a first end portion on the one side in the first direction X and a second end portion on the other side in the first direction X.

The first pad wiring 101 is arranged on at least one (in this embodiment, a plurality) of the first lower wirings 81 and is electrically connected to at least one (in this embodiment, a plurality) of the first lower wirings 81. The first pad wiring 101 is arranged on at least one (in this embodiment, a plurality) of the first lower wirings 81 and at least one (in this embodiment, a plurality) of the second lower wirings 82 and is electrically disconnected from all of the second lower wirings 82. Directly below the first pad wiring 101, both the number of the first lower wirings 81 and the number of the second lower wirings 82 are arbitrary.

For example, directly below the first pad wiring 101, the number of the first lower wirings 81 (the second lower wirings 82) may be not less than 1 and not more than 1000. For example, directly below the first pad wiring 101, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

Directly below the first pad wiring 101, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, directly below the first pad wiring 101, a difference value between the number of the first lower wirings 81 and the number of the second lower wirings 82 is 0 to 1. That is, directly below the first pad wiring 101, the wiring resistance of the second lower wirings 82 is substantially equal to the wiring resistance of the first lower wirings 81.

The first wiring unit U1 includes the second pad wiring 102 arranged in the second arrangement region 105B at intervals on the other side in the second direction Y from the first pad wiring 101 (the first arrangement region 105A). The second pad wiring 102 has the plane area less than the plane area of the second arrangement region 105B. The second pad wiring 102 is arranged at intervals inward from the peripheral edge of the second arrangement region 105B in plan view and is formed in a polygonal shape having four sides parallel to the peripheral edges of the chip 2 (the peripheral edges of the second arrangement region 105B).

The second pad wiring 102 is provided at the biased position on the other side in the first direction X with respect to the central portion of the first pad wiring 101 (the central portion of the boundary portion 107) and is provided at the biased position on the other side in the second direction Y with respect to the boundary portion 107. The second pad wiring 102 has a first end portion on the one side in the first direction X and a second end portion on the other side in the first direction X.

It is preferable that a distance between the second pad wiring 102 and the boundary portion 107 is substantially equal to a distance between the first pad wiring 101 and the boundary portion 107. That is, it is preferable that the boundary portion 107 is positioned at a substantially intermediate portion between the first pad wiring 101 and the second pad wiring 102.

The second pad wiring 102 preferably has a planar layout substantially congruent with a planar layout of the first pad wiring 101. That is, it is preferable that a planar shape of the second pad wiring 102 is substantially identical to a planar shape of the first pad wiring 101, and the plane area of the second pad wiring 102 is substantially equal to the plane area of the first pad wiring 101. The second pad wiring 102 is preferably arranged point-symmetrically with respect to the first pad wiring 101 about the central portion of the boundary portion 107.

The second pad wiring 102 is arranged on at least one (in this embodiment, a plurality) of the second lower wirings 82 and is electrically connected to at least one (in this embodiment, a plurality) of the second lower wirings 82. The second pad wiring 102 is arranged on at least one (in this embodiment, a plurality) of the first lower wirings 81 and at least one (in this embodiment, a plurality) of the second lower wirings 82 and is electrically disconnected from all of the first lower wirings 81. Directly below the second pad wiring 102, both the number of the first lower wirings 81 and the number of the second lower wirings 82 are arbitrary.

For example, directly below the second pad wiring 102, the number of the first lower wirings 81 (the second lower wirings 82) may be not less than 1 and not more than 1000. For example, directly below the second pad wiring 102, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

Directly below the second pad wiring 102, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, directly below the second pad wiring 102, a difference value between the number of the first lower wirings 81 and the number of the second lower wirings 82 is 0 to 1. That is, directly below the second pad wiring 102, the wiring resistance of the second lower wirings 82 is substantially equal to the wiring resistance of the first lower wirings 81.

It is preferable that the number of the first lower wirings 81 directly below the second pad wiring 102 is substantially equal to the number of the first lower wirings 81 directly below the first pad wiring 101. That is, it is preferable that the wiring resistance of the first lower wirings 81 on the second pad wiring 102 side is substantially equal to the wiring resistance of the first lower wirings 81 on the first pad wiring 101 side. It is preferable that the number of the second lower wirings 82 directly below the second pad wiring 102 is substantially equal to the number of the second lower wirings 82 directly below the first pad wiring 101. That is, it is preferable that the wiring resistance of the second lower wirings 82 on the second pad wiring 102 side is substantially equal to the wiring resistance of the second lower wirings 82 on the first pad wiring 101 side.

The first wiring unit U1 includes the first interconnect structure 108 formed in a region between the first pad wiring 101 and the second pad wiring 102. The first interconnect structure 108 forms a current path of the drain source current Ids between the first pad wiring 101 and the second pad wiring 102.

The first interconnect structure 108 includes at least one (in this embodiment, a plurality) of the first lead-out wirings 109 led out in the second direction Y from the first pad wiring 101 toward the second pad wiring 102. The plurality of first lead-out wirings 109 are electrically connected to at least one of the first lower wirings 81 in the region between the first pad wiring 101 and the second pad wiring 102.

The plurality of first lead-out wirings 109 include the at least one (in this embodiment, one) first long wiring 110 that is relatively long and at least one (in this embodiment, a plurality) of first short wirings 111 that are shorter than the first long wiring 110. The first long wiring 110 may be referred to as a “first long lead-out wiring,” a “first main lead-out wiring,” etc. The first short wiring 111 may be referred to as a “first short lead-out wiring,” a “first sub-lead-out wiring,” etc.

The number of the first short wirings 111 is arbitrary and is appropriately adjusted depending on a size of the first pad wiring 101, etc. The number of the first short wirings 111 may be not less than 1 and not more than 50. The number of the first short wirings 111 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50. In this embodiment, the two first short wirings 111 are provided.

The first long wiring 110 has a width less than a width of the first pad wiring 101 (the second pad wiring 102) in the first direction X and is led out as a band in the second direction Y from the first end portion of the first pad wiring 101. The width of the first long wiring 110 is larger than the width of the first lower wiring 81 (the second lower wiring 82). In this embodiment, the first long wiring 110 intersects (is orthogonal to) at least one (in this embodiment, a plurality) of the first lower wirings 81 and at least one (in this embodiment, a plurality) of the second lower wirings 82 in the first arrangement region 105A.

The first long wiring 110 crosses the boundary portion 107 in the second direction Y and is led out from the first arrangement region 105A to the second arrangement region 105B. In this embodiment, the first long wiring 110 intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The first long wiring 110 is electrically connected to at least one (in this embodiment, a plurality) of the first lower wirings 81 in the first arrangement region 105A. Also, the first long wiring 110 is electrically connected to at least one (in this embodiment, a plurality) of the first lower wirings 81 in the second arrangement region 105B.

The first long wiring 110 has the first opposing portion 112 led out in the second direction Y to a region opposing the second pad wiring 102 in the first direction X. The first opposing portion 112 opposes the entire first end portion of the second pad wiring 102 in the first direction X. The first opposing portion 112 (the first long wiring 110) intersects (is orthogonal to) one or a plurality of (preferably, all of) the first lower wirings 81 and one or a plurality of (preferably, all of) the second lower wirings 82 passing directly below the second pad wiring 102 in the first direction X.

The first opposing portion 112 is electrically connected to, of one or a plurality of (preferably, all of) the first lower wirings 81 covered with the second pad wiring 102, portions of the first lower wirings 81 exposed from the second pad wiring 102. On the other hand, the first opposing portion 112 is electrically disconnected from one or a plurality of (preferably, all of) the second lower wirings 82 passing directly below the second pad wiring 102.

The first long wiring 110 forms a current path of the drain source current Ids together with the second pad wiring 102 opposing (closely opposing) the first long wiring 110 in the first direction X. Specifically, the current path of the drain source current Ids is formed between the second pad wiring 102 and the first long wiring 110 via the first lower wirings 81 and the second lower wirings 82 passing directly below both the second pad wiring 102 and the first long wiring 110 in the first direction X. Such a layout is effective in reducing the wiring resistance between the first pad wiring 101 and the second pad wiring 102.

Each of the plurality of first short wirings 111 has a width less than the width of the first pad wiring 101 (the second pad wiring 102) in the first direction X and is provided in a region on the second end portion side with respect to the first long wiring 110. The width of the first short wiring 111 may be substantially equal to the width of the first long wiring 110. The width of the first short wiring 111 may be larger than the width of the first long wiring 110. The width of the first short wiring 111 may be less than the width of the first long wiring 110. The width of the first short wiring 111 is larger than the width of the first lower wiring 81 (the second lower wiring 82).

The plurality of first short wirings 111 are arrayed at intervals in the first direction X and are led out as bands (in this embodiment, in a rectangular shape) in the second direction Y from the first pad wiring 101 toward the second pad wiring 102. The plurality of first short wirings 111 may be led out in a trapezoidal shape (preferably, an isosceles trapezoidal shape) or a triangular shape (preferably, an isosceles triangular shape).

The plurality of first short wirings 111 are arrayed in a comb teeth shape extending in the second direction Y and oppose each other in the first direction X. The plurality of first short wirings 111 oppose the first long wiring 110 in the first direction X. The plurality of first short wirings 111 are formed at intervals from the second pad wiring 102 toward the first pad wiring 101 and oppose the second pad wiring 102 in the second direction Y.

The plurality of first short wirings 111 cover at least one (in this embodiment, a plurality) of the first lower wirings 81 in the region between the first pad wiring 101 and the second pad wiring 102 and is electrically connected to at least one (in this embodiment, a plurality) of the first lower wirings 81. Specifically, the plurality of first short wirings 111 intersect (are orthogonal to) at least one (in this embodiment, a plurality) of the first lower wirings 81 and at least one (in this embodiment, a plurality) of the second lower wirings 82 in the first arrangement region 105A.

Further, the plurality of first short wirings 111 cross the boundary portion 107 in the second direction Y and are led out from the first arrangement region 105A to the second arrangement region 105B. Consequently, the plurality of first short wirings 111 intersect (are orthogonal to) at least one (in this embodiment, a plurality) of the first lower wirings 81 and at least one (in this embodiment, a plurality) of the second lower wirings 82 in both the first arrangement region 105A and the second arrangement region 105B.

The plurality of first short wirings 111 are electrically connected to at least one (in this embodiment, a plurality) of the first lower wirings 81 in the first arrangement region 105A. Also, the plurality of first short wirings 111 are electrically connected to at least one (in this embodiment, a plurality) of the first lower wirings 81 in the second arrangement region 105B.

The plurality of first short wirings 111 on the one side intersect (are orthogonal to) at least one (in this embodiment, a plurality) of the first lower wirings 81 and at least one (in this embodiment, a plurality) of the second lower wirings 82 passing directly below the first long wiring 110 in the first direction X. The plurality of first short wirings 111 are electrically connected to, of at least one (in this embodiment, a plurality) of the first lower wirings 81 covered with the first long wiring 110, portions of the first lower wirings 81 exposed from the first long wiring 110.

The first interconnect structure 108 includes at least one (in this embodiment, a plurality) of the second lead-out wirings 113 led out in the second direction Y from the second pad wiring 102 toward the first pad wiring 101. The plurality of second lead-out wirings 113 are electrically connected to at least one of the second lower wirings 82 in the region between the first pad wiring 101 and the second pad wiring 102.

The plurality of second lead-out wirings 113 include the at least one (in this embodiment, one) second long wiring 114 that is relatively long and at least one (in this embodiment, a plurality) of the second short wirings 115 that are shorter than the second long wiring 114. The second long wiring 114 may be referred to as a “second long lead-out wiring,” a “second main lead-out wiring,” etc. The second short wiring 115 may be referred to as a “second short lead-out wiring,” a “second sub-lead-out wiring,” etc.

The number of the second short wirings 115 is arbitrary and is appropriately adjusted depending on the size of the second pad wiring 102, etc. The number of the second short wirings 115 may be not less than 1 and not more than 50. The number of the second short wirings 115 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The number of the second short wirings 115 is preferably equal to the number of the first short wirings 111. According to this configuration, variation in wiring resistance between the first short wirings 111 and the second short wirings 115 is prevented. In this embodiment, the two second short wirings 115 are provided.

The second long wiring 114 has a width less than a width of the second pad wiring 102 (the first pad wiring 101) in the first direction X and is led out as a band in the second direction Y from the second end portion of the second pad wiring 102. The second long wiring 114 preferably has a width substantially equal to the width of the first long wiring 110 in the first direction X. According to this configuration, variation in the wiring resistance between the first long wiring 110 and the second long wiring 114 is prevented.

The second long wiring 114 is provided at intervals in the first direction X from the plurality of first lead-out wirings 109 (the first long wiring 110 and the plurality of first short wirings 111) and opposes the plurality of first lead-out wirings 109 in the first direction X. In this embodiment, the second long wiring 114 intersects (is orthogonal to) at least one (in this embodiment, a plurality) of the first lower wirings 81 and at least one (in this embodiment, a plurality) of the second lower wirings 82 in the second arrangement region 105B.

The second long wiring 114 crosses the boundary portion 107 in the second direction Y and is led out from the second arrangement region 105B to the first arrangement region 105A. In this embodiment, the second long wiring 114 intersects (is orthogonal to) at least one (in this embodiment, a plurality) of the first lower wirings 81 and at least one (in this embodiment, a plurality) of the second lower wirings 82 in both the first arrangement region 105A and the second arrangement region 105B.

The second long wiring 114 is electrically connected to at least one (in this embodiment, a plurality) of the second lower wirings 82 in the second arrangement region 105B. Also, the second long wiring 114 is electrically connected to at least one (in this embodiment, a plurality) of the second lower wirings 82 in the first arrangement region 105A.

In the region between the first pad wiring 101 and the second pad wiring 102, the second long wiring 114 intersects (is orthogonal to) one or a plurality of (preferably, all of) the first lower wirings 81 and one or a plurality of (preferably, all of) the second lower wirings 82 passing directly below at least one (in this embodiment, a plurality) of the first lead-out wirings 109 (the first long wiring 110 and the plurality of first short wirings 111) in the first direction X.

The second long wiring 114 is electrically connected to, of one or a plurality of (preferably, all of) the second lower wirings 82 covered with the plurality of first lead-out wirings 109, portions of the second lower wirings 82 exposed from the plurality of first lead-out wirings 109. On the other hand, the second long wiring 114 is electrically disconnected from one or a plurality of (preferably, all of) the first lower wirings 81 passing directly below the plurality of first lead-out wirings 109.

The second long wiring 114 forms a current path of the drain source current Ids together with the plurality of first lead-out wirings 109 opposing (closely opposing) the second long wiring 114 in the first direction X. Specifically, the current path of the drain source current Ids is formed between the plurality of first lead-out wirings 109 and the second long wiring 114 via the first lower wirings 81 and the second lower wirings 82 passing directly below both the plurality of first lead-out wirings 109 and the second long wiring 114 in the first direction X. Such a layout is effective in reducing the wiring resistance between the first pad wiring 101 and the second pad wiring 102.

The second long wiring 114 has the second opposing portion 116 led out in the second direction Y to a region opposing the first pad wiring 101 in the first direction X. The second opposing portion 116 opposes the entire second end portion of the first pad wiring 101 in the first direction X. The second opposing portion 116 (the second long wiring 114) intersects (is orthogonal to) one or a plurality of (preferably, all of) the first lower wirings 81 and one or a plurality of (preferably, all of) the second lower wirings 82 passing directly below the first pad wiring 101 in the first direction X.

The second opposing portion 116 is electrically connected to, of one or a plurality of (preferably, all of) the second lower wirings 82 covered with the first pad wiring 101, portions of the second lower wirings 82 exposed from the first pad wiring 101. On the other hand, the second opposing portion 116 is electrically disconnected from one or a plurality of (preferably, all of) the first lower wirings 81 passing directly below the first pad wiring 101.

The second opposing portion 116 (the second long wiring 114) forms a current path of the drain source current Ids together with the first pad wiring 101 opposing (closely opposing) the second opposing portion 116 (the second long wiring 114) in the first direction X. Specifically, the current path of the drain source current Ids is formed between the first pad wiring 101 and the second long wiring 114 via the first lower wirings 81 and the second lower wirings 82 passing directly below both the first pad wiring 101 and the second long wiring 114 in the first direction X. Such a layout is effective in reducing the wiring resistance between the first pad wiring 101 and the second pad wiring 102.

Each of the plurality of second short wirings 115 has a width smaller than the width of the second pad wiring 102 (the first pad wiring 101) in the first direction X and is provided in a region on the first end portion side with respect to the second long wiring 114. The width of the second short wiring 115 may be substantially equal to the width of the second long wiring 114. The width of the second short wiring 115 may be larger than the width of the second long wiring 114. The width of the second short wiring 115 may be less than the width of the second long wiring 114.

The width of the second short wiring 115 is larger than the width of the second lower wiring 82 (the first lower wiring 81). It is preferable that the width of the second short wiring 115 is substantially equal to the width of the first short wiring 111. According to this configuration, variation in wiring resistance between the first short wirings 111 and the second short wirings 115 is prevented.

The plurality of second short wirings 115 are arrayed at intervals in the first direction X and are led out as bands (in this embodiment, in a rectangular shape) in the second direction Y from the second pad wiring 102 toward the first pad wiring 101. The plurality of second short wirings 115 may be led out in a trapezoidal shape (preferably, an isosceles trapezoidal shape) or a triangular shape (preferably, an isosceles triangular shape).

The plurality of second short wirings 115 are arrayed in a comb teeth shape extending in the second direction Y and oppose each other in the first direction X. The plurality of second short wirings 115 oppose the plurality of first lead-out wirings 109 (the first long wiring 110 and the first short wiring 111) in the first direction X. Specifically, the plurality of second short wirings 115 respectively enter regions between the plurality of first lead-out wirings 109 and extend in the second direction Y in the regions between the plurality of first lead-out wirings 109.

That is, the plurality of second lead-out wirings 113 include one of the second short wirings 115 arranged in a region between the first long wiring 110 and the first short wiring 111 and the second short wirings 115 arranged in the regions between the plurality of first short wirings 111. Consequently, the plurality of second short wirings 115 and the plurality of first lead-out wirings 109 are alternately arrayed in the first direction X. That is, the plurality of second short wirings 115 are arrayed in a comb teeth shape that meshes with the plurality of first short wirings 111.

The second short wiring 115 preferably has a length substantially equal to a length of the first short wiring 111 in the second direction Y. According to this configuration, variation in wiring resistance between the first short wirings 111 and the second short wirings 115 is prevented. The plurality of second short wirings 115 are formed at intervals from the first pad wiring 101 toward the second pad wiring 102 and oppose the first pad wiring 101 in the second direction Y.

The plurality of second short wirings 115 cover at least one (in this embodiment, a plurality) of the second lower wirings 82 in the region between the first pad wiring 101 and the second pad wiring 102 and is electrically connected to at least one (in this embodiment, a plurality) of the second lower wirings 82. Specifically, the plurality of second short wirings 115 intersect (are orthogonal to) at least one (in this embodiment, a plurality) of the first lower wirings 81 and at least one (in this embodiment, a plurality) of the second lower wirings 82 in the second arrangement region 105B.

Further, the plurality of second short wirings 115 cross the boundary portion 107 in the second direction Y and are led out from the second arrangement region 105B to the first arrangement region 105A. Consequently, the plurality of second short wirings 115 intersect (are orthogonal to) at least one (in this embodiment, a plurality) of the first lower wirings 81 and at least one (in this embodiment, a plurality) of the second lower wirings 82 in both the first arrangement region 105A and the second arrangement region 105B.

The plurality of second short wirings 115 are electrically connected to at least one (in this embodiment, a plurality) of the second lower wirings 82 in the second arrangement region 105B. Also, the plurality of second short wirings 115 are electrically connected to at least one (in this embodiment, a plurality) of the second lower wirings 82 in the first arrangement region 105A.

The plurality of second short wirings 115 intersect (are orthogonal to) one or a plurality of the first lower wirings 81 and one or a plurality of the second lower wirings 82 passing directly below at least one (in this embodiment, a plurality) of the first lead-out wirings 109 (the first long wiring 110 and the first short wirings 111) in the first direction X.

The plurality of second short wirings 115 are electrically connected to, of one or a plurality (in this embodiment, a plurality) of the second lower wirings 82 covered with the plurality of first lead-out wirings 109, portions of the second lower wirings 82 exposed from the plurality of first lead-out wirings 109. On the other hand, the plurality of second short wirings 115 are electrically disconnected from one or a plurality (in this embodiment, a plurality) of the first lower wirings 81 passing directly below the plurality of first lead-out wirings 109.

In this embodiment, the plurality of second short wirings 115 are electrically connected to all of the second lower wirings 82 passing directly below the plurality of first short wirings 111. On the other hand, the plurality of second short wirings 115 are electrically disconnected from all of the plurality of first lower wirings 81 passing directly below the plurality of first lead-out wirings 109.

The plurality of second short wirings 115 form a current path of the drain source current Ids together with the plurality of first lead-out wirings 109 opposing (closely opposing) the second short wirings 115 in the first direction X. Specifically, the current path of the drain source current Ids is formed between the plurality of first lead-out wirings 109 and the plurality of second short wirings 115 via the first lower wirings 81 and the second lower wirings 82 passing directly below both the plurality of first lead-out wirings 109 and the plurality of second short wirings 115 in the first direction X. Such a layout is effective in reducing the wiring resistance between the first pad wiring 101 and the second pad wiring 102.

As described above, the first wiring unit U1 includes the first upper wiring and the second upper wiring. The first upper wiring includes the first pad wiring 101 and the plurality of first lead-out wirings 109, and the second upper wiring includes the second pad wiring 102 and the plurality of second lead-out wirings 113. In this configuration, the second upper wiring preferably has a planar layout substantially congruent with the planar layout of the first upper wiring.

That is, it is preferable that the planar shape of the second upper wiring is substantially equal to the planar shape of the first upper wiring, and the plane area of the second upper wiring is substantially equal to the plane area of the first upper wiring. The second upper wiring is preferably arranged point-symmetrically with respect to the first upper wiring about the central portion of the boundary portion 107.

The first wiring unit U1 includes the wiring slit that electrically disconnect the first upper wiring from the second upper wiring. The wiring slit is defined in the region between the first upper wiring and the second upper wiring and is the portion that exposes the portion (the second interlayer film 72) of the interlayer film 70.

The width of the wiring slit may be not less than 0.1 μm and not more than 50 μm. The width of the wiring slit may have a value falling within at least one of ranges of not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 5 μm, not less than 5 μm and not more than 7.5 μm, not less than 7.5 μm and not more than 10 μm, not less than 10 μm and not more than 12.5 μm, not less than 12.5 μm and not more than 15 μm, not less than 15 μm and not more than 20 μm, not less than 20 μm and not more than 25 μm, and not less than 25 μm and not more than 30 μm.

The first wiring unit U1 includes the plurality of first upper via electrodes 117 and the plurality of second upper via electrodes 118 which are respectively embedded in the second interlayer film 72. The first upper via electrode 117 is a plug electrode that transmits the first drain source potential to the first lower wiring 81. The second upper via electrode 118 is a plug electrode that transmits the second drain source potential to the second lower wiring 82. The first upper via electrode 117 may be referred to as a “first drain source upper via electrode.” The second upper via electrode 118 may be referred to as a “second drain source upper via electrode.”

The plurality of first upper via electrodes 117 are arrayed in a matrix at intervals in the first direction X and the second direction Y with respect to the plurality of first lower wirings 81. As a matter of course, the plurality of first upper via electrodes 117 may be arrayed in a staggered arrangement at intervals in the first direction X and the second direction Y with respect to the plurality of first lower wirings 81. In this case, the plurality of first upper via electrodes 117 connected to one of the first lower wirings 81 oppose, in the second direction Y, the regions between the plurality of first upper via electrodes 117 connected to another one of the first lower wirings 81.

The plurality of second upper via electrodes 118 are arrayed in a matrix at intervals in the first direction X and the second direction Y with respect to the plurality of second lower wirings 82. As a matter of course, the plurality of second upper via electrodes 118 may be arrayed in a staggered arrangement at intervals in the first direction X and the second direction Y with respect to the plurality of second lower wirings 82. In this case, the plurality of second upper via electrodes 118 connected to one of the second lower wiring 82 oppose, in the second direction Y, the regions between the plurality of second upper via electrodes 118 connected to another one of the second lower wirings 82.

In this embodiment, each of the first and second upper via electrodes 117 and 118 includes the first electrode 119 and the second electrode 120. The first electrode 119 covers, in a film shape, the wall surfaces of the via hole formed in the second interlayer film 72. The first electrode 119 may include one or both of a Ti film and a Ti alloy film. The Ti alloy film may be a TiN film.

The second electrode 120 is embedded in the via hole via the first electrode 119. The second electrode 120 may contain at least one type among W, Al, an Al alloy, Cu, and a Cu alloy. The Al alloy may include at least one type among an AlSi alloy, an AlCu alloy, and an AlSiCu alloy.

The first and second upper via electrodes 117 and 118 may be formed in a triangular shape, a quadrangular shape, a rectangular shape, a polygonal shape, a circular shape, or an elliptical shape in plan view. As a matter of course, the first and second upper via electrodes 117 and 118 may be formed as bands (for example, in a rectangular shape) extending in the first direction X.

The plurality of first upper via electrodes 117 are interposed in the region between the plurality of first lower wirings 81 and the first pad wiring 101 in the second interlayer film 72 and electrically connect the first pad wiring 101 to the plurality of first lower wirings 81. The first wiring unit U1 may have at least one of the first upper via electrodes 117 between one of the first lower wirings 81 and the first pad wiring 101. In this embodiment, the plurality of first upper via electrodes 117 are interposed between one of the first lower wirings 81 and the first pad wiring 101.

Also, the plurality of first upper via electrodes 117 are interposed in a region between the plurality of first lower wirings 81 and the plurality of first lead-out wirings 109 in the second interlayer film 72 and electrically connect the plurality of first lead-out wirings 109 to the plurality of first lower wirings 81. The first wiring unit U1 may have at least one of the first upper via electrodes 117 between one of the first lower wirings 81 and one of the first lead-out wirings 109. In this embodiment, the plurality of first upper via electrodes 117 are interposed between one of the first lower wirings 81 and one of the first lead-out wirings 109.

The number of the first upper via electrodes 117 interposed between one of the first lower wirings 81 and one of the first lead-out wirings 109 is arbitrary. For example, the number of the first upper via electrodes 117 may be not less than 1 and not more than 50. The number of the first upper via electrodes 117 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The first upper via electrode 117 may be formed using the first pad wiring 101 (the first lead-out wiring 109). In this case, the first electrode 119 of the first upper via electrode 117 is integrally formed with the first electrode 78 of the first pad wiring 101 (the first lead-out wiring 109) and forms one electrode film together with the first electrode 78. Similarly, the second electrode 120 of the first upper via electrode 117 is integrally formed with the second electrode 79 of the first pad wiring 101 (the first lead-out wiring 109) and forms one electrode together with the second electrode 79.

The plurality of second upper via electrodes 118 are interposed in a region between the plurality of second lower wirings 82 and the second pad wiring 102 in the second interlayer film 72 and electrically connect the second pad wiring 102 to the plurality of second lower wirings 82. The first wiring unit U1 may have at least one of the second upper via electrodes 118 between one of the second lower wirings 82 and the second pad wiring 102. In this embodiment, the plurality of second upper via electrodes 118 are interposed between one of the second lower wirings 82 and the second pad wiring 102.

Also, the plurality of second upper via electrodes 118 are interposed in a region between the plurality of second lower wirings 82 and the plurality of second lead-out wirings 113 in the second interlayer film 72 and electrically connect the plurality of second lead-out wirings 113 to the plurality of second lower wirings 82. The first wiring unit U1 may have at least one of the second upper via electrodes 118 between one of the second lower wirings 82 and one of the second lead-out wirings 113. In this embodiment, the plurality of second upper via electrodes 118 are interposed between one of the second lower wirings 82 and one of the second lead-out wirings 113.

The number of the second upper via electrodes 118 interposed between one of the second lower wirings 82 and one of the second lead-out wirings 113 is arbitrary. For example, the number of the second upper via electrodes 118 may be not less than 1 and not more than 50. The number of the second upper via electrodes 118 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

It is preferable that the number of the second upper via electrodes 118 connected to one of the second lead-out wirings 113 is substantially equal to the number of the first upper via electrodes 117 connected to one of the first lead-out wirings 109. It is preferable that the number of the second upper via electrodes 118 connected to the second pad wiring 102 is substantially equal to the number of the first upper via electrodes 117 connected to the first pad wiring 101.

It is preferable that the number of the second upper via electrodes 118 connected to the second pad wiring 102 and the plurality of second lead-out wirings 113 is substantially equal to the number of the first upper via electrodes 117 connected to the first pad wiring 101 and the plurality of first lead-out wirings 109. According to these configurations, variation in the wiring resistance is prevented.

The second upper via electrode 118 may be formed using the second pad wiring 102 (the second lead-out wiring 113). In this case, the first electrode 119 of the second upper via electrode 118 is integrally formed with the first electrode 78 of the second pad wiring 102 (the second lead-out wiring 113) and forms one electrode film together with the first electrode 78. Similarly, the second electrode 120 of the second upper via electrode 118 is integrally formed with the second electrode 79 of the second pad wiring 102 (the second lead-out wiring 113) and forms one electrode together with the second electrode 79.

The first interconnect structure 108 shown in FIG. 42A may have various layouts. Hereinafter, the second to tenth layout examples will be described with reference to FIGS. 42B to 42J. With reference to FIG. 42B (the second layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

In this embodiment, the first short wiring 111 is led out in a triangular shape from the region of a first pad wiring 101 on the second end portion side with respect to the first end portion (the first long wiring 110) of the first pad wiring 101. The first short wiring 111 covers at least one (in this embodiment, a plurality) of the first lower wirings 81 and at least one (in this embodiment, a plurality) of the second lower wirings 82 in the first arrangement region 105A.

The first short wiring 111 crosses the boundary portion 107 in the second direction Y and is led out from the first arrangement region 105A to the second arrangement region 105B. The first short wiring 111 covers at least one (in this embodiment, a plurality) of the first lower wirings 81 and at least one (in this embodiment, a plurality) of the second lower wirings 82 in the second arrangement region 105B.

The first short wiring 111 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B. Similarly to the case of the first layout example, the first short wiring 111 is electrically connected to the corresponding first lower wirings 81 via the plurality of first upper via electrodes 117.

The first short wiring 111 has a first inclined portion inclined obliquely from the second end portion of the first pad wiring 101 toward the first end portion of the second pad wiring 102. An extension direction (the inclination direction) of the first inclined portion is a direction intersecting both the first direction X and the second direction Y. In this embodiment, the first inclined portion further has a distal end portion that crosses the boundary portion 107 along the inclination direction and is connected to the first long wiring 110 in the second arrangement region 105B. The first inclined portion is formed at intervals from the second pad wiring 102 toward the first pad wiring 101 in the second arrangement region 105B and opposes the second pad wiring 102 in the second direction Y.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

The second short wiring 115 is led out in a triangular shape from a region of the second pad wiring 102 on the first end portion side with respect to the second end portion (the second long wiring 114) of the second pad wiring 102. The second short wiring 115 covers at least one (in this embodiment, a plurality) of the first lower wirings 81 and at least one (in this embodiment, a plurality) of the second lower wirings 82 in the second arrangement region 105B.

The second short wiring 115 crosses the boundary portion 107 in the second direction Y and is led out from the second arrangement region 105B to the first arrangement region 105A. The second short wiring 115 covers at least one (in this embodiment, a plurality) of the first lower wirings 81 and at least one (in this embodiment, a plurality) of the second lower wirings 82 in the first arrangement region 105A.

The second short wiring 115 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A. Similarly to the case of the first layout example, the second short wiring 115 is electrically connected to the corresponding second lower wirings 82 via the plurality of second upper via electrodes 118.

The second short wiring 115 has the second inclined portion inclined obliquely from the first end portion of the second pad wiring 102 toward the second end portion of the first pad wiring 101. An extension direction (the inclination direction) of the second inclined portion is a direction intersecting both the first direction X and the second direction Y. In this embodiment, the second inclined portion has a distal end portion that crosses the boundary portion 107 along the inclination direction and is connected to the second long wiring 114 in the first arrangement region 105A. The second inclined portion is formed at intervals from the first pad wiring 101 toward the second pad wiring 102 in the first arrangement region 105A and opposes the first pad wiring 101 in the second direction Y.

The second inclined portion extends along the first inclined portion at intervals from the first inclined portion. It is preferable that the second inclined portion extends substantially parallel to the first inclined portion at intervals from the first inclined portion in a vertical direction of the first inclined portion. That is, it is preferable that the inclination angle of the second inclined portion is substantially equal to the inclination angle of the first inclined portion. The second short wiring 115 preferably has a planar layout substantially congruent with the planar layout of the first short wiring 111.

The second short wiring 115 covers one or a plurality of (preferably, all of) the first lower wirings 81 and one or a plurality of (preferably, all of) the second lower wirings 82 passing directly below the first short wiring 111 in the first direction X.

The second short wiring 115 is electrically connected to, of one or a plurality of (preferably, all of) the second lower wirings 82 covered with the first short wiring 111, portions of the second lower wirings 82 exposed from the first short wiring 111 On the other hand, the second short wiring 115 is electrically disconnected from one or a plurality of (preferably, all of) the first lower wirings 81 passing directly below the first short wiring 111.

As described above, in both the first arrangement region 105A and the second arrangement region 105B, the second short wiring 115 forms a current path of the drain source current Ids together with the first short wiring 111 opposing (closely opposing) the second short wiring 115 in the first direction X.

With reference to FIG. 42C (the third layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

The first short wiring 111 is led out in a triangular shape from the region of the first pad wiring 101 on the second end portion side with respect to the first end portion (the first long wiring 110) of the first pad wiring 101. Similarly to the case of the second layout example, the first short wiring 111 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B. Also, the first short wiring 111 is electrically connected to the corresponding first lower wirings 81 via the plurality of first upper via electrodes 117.

In this embodiment, the first short wiring 111 has a first side portion led out in the second direction Y from the second end portion of the first pad wiring 101. The first side portion forms one side extending in the second direction Y with the second end portion of the first pad wiring 101. The first side portion crosses the boundary portion 107 in the second direction Y and is positioned in the second arrangement region 105B. The first side portion is formed at intervals from the second pad wiring 102 toward the first pad wiring 101 in the second arrangement region 105B and opposes the second pad wiring 102 in the second direction Y.

In this embodiment, the first inclined portion of the first short wiring 111 is inclined obliquely from the first end portion of the first pad wiring 101 toward the second end portion of the second pad wiring 102 and opposes the first long wiring 110 in the first direction X. The first inclined portion crosses the boundary portion 107 along the inclination direction and is connected to the first side portion in the second arrangement region 105B. That is, the distal end portion of the first inclined portion and the second end portion of the first pad wiring 101 are positioned on the same straight line.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

The second short wiring 115 is led out in a triangular shape from the region of the second pad wiring 102 on the first end portion side with respect to the second end portion (the second long wiring 114) of the second pad wiring 102 and is arranged in a region between the first long wiring 110 and the first short wiring 111.

Similarly to the case of the second layout example, the second short wiring 115 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A. Also, the second short wiring 115 is electrically connected to the corresponding second lower wirings 82 via the plurality of second upper via electrodes 118.

In this embodiment, the second short wiring 115 has a second side portion led out in the second direction Y from the first end portion of the second pad wiring 102. The second side portion forms one side extending in the second direction Y with the first end portion of the second pad wiring 102. The second side portion crosses the boundary portion 107 in the second direction Y and is positioned in the first arrangement region 105A. The second side portion is formed at intervals from the first pad wiring 101 toward the second pad wiring 102 in the first arrangement region 105A and opposes the first pad wiring 101 in the second direction Y.

In this embodiment, the second inclined portion of the second short wiring 115 is inclined obliquely from the second end portion of the second pad wiring 102 toward the first end portion of the first pad wiring 101 and opposes the second long wiring 114 in the first direction X. The second inclined portion crosses the boundary portion 107 along the inclination direction and is connected to the second side portion in the first arrangement region 105A. That is, the distal end portion of the second inclined portion and the first end portion of the second pad wiring 102 are positioned on the same straight line.

The second inclined portion extends along the first inclined portion at intervals from the first inclined portion. It is preferable that the second inclined portion extends substantially parallel to the first inclined portion at intervals from the first inclined portion in the vertical direction of the first inclined portion. That is, it is preferable that the inclination angle of the second inclined portion is substantially equal to the inclination angle of the first inclined portion. The second short wiring 115 preferably has the planar layout substantially congruent with a planar layout of the first short wiring 111.

Similarly to the case of the second layout example, in both the first arrangement region 105A and the second arrangement region 105B, the second short wiring 115 forms a current path of the drain source current Ids together with the first short wiring 111 opposing (closely opposing) the second short wiring 115 in the first direction X.

With reference to FIG. 42D (the fourth layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

The first short wiring 111 is led out in a trapezoidal shape (a quadrangular shape) from the region of the first pad wiring 101 on the second end portion side with respect to the first end portion (the first long wiring 110) of the first pad wiring 101. Similarly to the case of the second layout example, the first short wiring 111 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B. Also, the first short wiring 111 is electrically connected to the corresponding first lower wirings 81 via the plurality of first upper via electrodes 117.

The first short wiring 111 has a first distal end portion and a first inclined portion. The first distal end portion has a width less than the width of the first pad wiring 101 in the first direction X and is positioned on the second pad wiring 102 side with respect to the first pad wiring 101. The first distal end portion extends in the first direction X and is connected to the first long wiring 110.

In this embodiment, the first distal end portion is positioned in the second arrangement region 105B. The first distal end portion is formed at intervals from the second pad wiring 102 toward the first pad wiring 101 in the second arrangement region 105B and opposes the first end portion of the second pad wiring 102 in the second direction Y. The first distal end portion extends substantially parallel to the first end portion of the second pad wiring 102.

The first inclined portion is formed at intervals from the second end portion of the first pad wiring 101 toward the first end portion of the first pad wiring 101 and exposes the second end portion of the first pad wiring 101. The first inclined portion is inclined obliquely from an inner portion of the first pad wiring 101 toward the first end portion of the second pad wiring 102.

An extension direction (the inclination direction) of the first inclined portion is a direction intersecting both the first direction X and the second direction Y. As a matter of course, the extension direction (the inclination direction) of the first inclined portion may be the second direction Y. The first inclined portion crosses the boundary portion 107 along the inclination direction and is connected to the first distal end portion in the second arrangement region 105B.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

The second short wiring 115 is led out in a trapezoidal shape (a quadrangular shape) from a region of the second pad wiring 102 on the first end portion side with respect to the second end portion (the second long wiring 114) of the second pad wiring 102. Similarly to the case of the second layout example, the second short wiring 115 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A. Also, the second short wiring 115 is electrically connected to the corresponding second lower wirings 82 via the plurality of second upper via electrodes 118.

The second short wiring 115 has a second distal end portion and the second inclined portion. The second distal end portion has a width less than the width of the second pad wiring 102 in the first direction X and is positioned on the first pad wiring 101 side with respect to the second pad wiring 102. The second distal end portion extends in the first direction X and is connected to the second long wiring 114. It is preferable that the width of the second distal end portion is substantially equal to the width of the first distal end portion.

In this embodiment, the second distal end portion is positioned in the first arrangement region 105A. The second distal end portion is formed at intervals from the first pad wiring 101 toward the second pad wiring 102 in the first arrangement region 105A and opposes the second end portion of the first pad wiring 101 in the second direction Y. The second distal end portion extends substantially parallel to the second end portion of the first pad wiring 101.

The second inclined portion is formed at intervals from the first end portion of the second pad wiring 102 toward the second end portion of the second pad wiring 102 and exposes the first end portion of the second pad wiring 102. The second inclined portion is inclined obliquely from an inner portion of the second pad wiring 102 toward the second end portion of the first pad wiring 101.

An extension direction (the inclination direction) of the second inclined portion is a direction intersecting both the first direction X and the second direction Y. As a matter of course, the extension direction (the inclination direction) of the second inclined portion may be the second direction Y. The second inclined portion crosses the boundary portion 107 along the inclination direction and is connected to the second distal end portion in the first arrangement region 105A.

The second inclined portion extends along the first inclined portion at intervals from the first inclined portion. It is preferable that the second inclined portion extends substantially parallel to the first inclined portion at intervals from the first inclined portion in the vertical direction of the first inclined portion. That is, it is preferable that the inclination angle of the second inclined portion is substantially equal to the inclination angle of the first inclined portion. The second short wiring 115 preferably has the planar layout substantially congruent with a planar layout of the first short wiring 111.

Similarly to the case of the second layout example, in both the first arrangement region 105A and the second arrangement region 105B, the second short wiring 115 forms a current path of the drain source current Ids together with the first short wiring 111 opposing (closely opposing) the second short wiring 115 in the first direction X.

With reference to FIG. 42E (the fifth layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

The first short wiring 111 is led out in a trapezoidal shape (a quadrangular shape) from the region of the first pad wiring 101 on the second end portion side with respect to the first end portion (the first long wiring 110) of the first pad wiring 101. Similarly to the case of the second layout example, the first short wiring 111 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B. Also, the first short wiring 111 is electrically connected to the corresponding first lower wirings 81 via the plurality of first upper via electrodes 117.

In this embodiment, the first short wiring 111 has the first side portion led out in the second direction Y from the second end portion of the first pad wiring 101. The first side portion forms one side extending in the second direction Y with the second end portion of the first pad wiring 101. The first side portion crosses the boundary portion 107 in the second direction Y and is positioned in the second arrangement region 105B. The first side portion is formed at intervals from the second pad wiring 102 toward the first pad wiring 101 in the second arrangement region 105B and opposes the second pad wiring 102 in the second direction Y.

The first distal end portion of the first short wiring 111 has a width less than the width of the first pad wiring 101 in the first direction X and is positioned on the second pad wiring 102 side with respect to the first pad wiring 101. The first distal end portion extends in the first direction X and is connected to the first side portion. The first distal end portion is formed at intervals from the second pad wiring 102 toward the first pad wiring 101 in the second arrangement region 105B and opposes the second end portion of the second pad wiring 102 in the second direction Y. The first distal end portion extends substantially parallel to the second end portion of the second pad wiring 102.

In this embodiment, the first inclined portion of the first short wiring 111 is formed at intervals from the first end portion (the first long wiring 110) of the first pad wiring 101 toward the second end portion of the first pad wiring 101 and exposes the first end portion of the first pad wiring 101. The first inclined portion is inclined obliquely from the inner portion of the first pad wiring 101 toward the second end portion of the second pad wiring 102.

An extension direction (the inclination direction) of the first inclined portion is a direction intersecting both the first direction X and the second direction Y. As a matter of course, the extension direction (the inclination direction) of the first inclined portion may be the second direction Y. The first inclined portion crosses the boundary portion 107 along the inclination direction and is connected to the first distal end portion in the second arrangement region 105B.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

The second short wiring 115 is led out in a trapezoidal shape (a quadrangular shape) from a region of the second pad wiring 102 on the first end portion side with respect to the second end portion (the second long wiring 114) of the second pad wiring 102 and is arranged in the region between the first long wiring 110 and the first short wiring 111.

Similarly to the case of the second layout example, the second short wiring 115 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A. Also, the second short wiring 115 is electrically connected to the corresponding second lower wirings 82 via the plurality of second upper via electrodes 118.

In this embodiment, the second short wiring 115 has a second side portion led out in the second direction Y from the first end portion of the second pad wiring 102. The second side portion forms one side extending in the second direction Y with the first end portion of the first pad wiring 101. The second side portion crosses the boundary portion 107 in the second direction Y and is positioned in the first arrangement region 105A. The second side portion is formed at intervals from the first pad wiring 101 toward the second pad wiring 102 in the first arrangement region 105A and opposes the first pad wiring 101 in the second direction Y.

The second distal end portion of the second short wiring 115 has a width less than the width of the second pad wiring 102 in the first direction X and is positioned on the first pad wiring 101 side with respect to the second pad wiring 102. The second distal end portion extends in the first direction X and is connected to the second side portion. The second distal end portion is formed at intervals from the first pad wiring 101 toward the second pad wiring 102 in the first arrangement region 105A and opposes the first end portion of the first pad wiring 101 in the second direction Y. The second distal end portion extends substantially parallel to the first end portion of the first pad wiring 101.

In this embodiment, the second inclined portion of the second short wiring 115 is formed at intervals from the second end portion (the second long wiring 114) of the second pad wiring 102 toward the first end portion of the second pad wiring 102 and exposes the second end portion of the second pad wiring 102. The second inclined portion is inclined obliquely from an inner portion of the second pad wiring 102 toward the first end portion of the first pad wiring 101.

An extension direction (the inclination direction) of the second inclined portion is a direction intersecting both the first direction X and the second direction Y. As a matter of course, the extension direction (the inclination direction) of the second inclined portion may be the second direction Y. The second inclined portion crosses the boundary portion 107 along the inclination direction and is connected to the second distal end portion in the first arrangement region 105A.

Similarly to the case of the second layout example, in both the first arrangement region 105A and the second arrangement region 105B, the second short wiring 115 forms a current path of the drain source current Ids together with the first short wiring 111 opposing (closely opposing) the second short wiring 115 in the first direction X.

With reference to FIG. 42F (the sixth layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

The first short wiring 111 is led out in a single- or multi-stepped shape (in this embodiment, the multi-stepped shape) from a region of the first pad wiring 101 on the second end portion side with respect to the first end portion (the first long wiring 110) of the first pad wiring 101.

Similarly to the case of the second layout example, the first short wiring 111 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B. Also, the first short wiring 111 is electrically connected to the corresponding first lower wirings 81 via the plurality of first upper via electrodes 117.

The first short wiring 111 has a first step portion extending in a stepped shape. In this embodiment, the first step portion is led out in the stepped shape from the second end portion side of the first pad wiring 101 toward the first end portion side of the second pad wiring 102 and is connected to the first long wiring 110. The first step portion crosses the boundary portion 107 in the stepped shape and is connected to the first long wiring 110 in the second arrangement region 105B. The first step portion is formed at intervals from the second pad wiring 102 toward the first pad wiring 101 in the second arrangement region 105B and opposes the second pad wiring 102 in the second direction Y.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

The second short wiring 115 is led out in a single- or multi-stepped shape (in this embodiment, the multi-stepped shape) from a region of the second pad wiring 102 on the first end portion side with respect to the second end portion (the second long wiring 114) of the second pad wiring 102.

Similarly to the case of the second layout example, the second short wiring 115 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A. Also, the second short wiring 115 is electrically connected to the corresponding second lower wirings 82 via the plurality of second upper via electrodes 118.

The second short wiring 115 has a second step portion extending in a stepped shape. In this embodiment, the second step portion is led out in the stepped shape from the first end portion side of the second pad wiring 102 toward the second end portion side of the first pad wiring 101 and is connected to the second long wiring 114. The second step portion crosses the boundary portion 107 in the stepped shape and is connected to the second long wiring 114 in the first arrangement region 105A. The second step portion is formed at intervals from the first pad wiring 101 toward the second pad wiring 102 in the first arrangement region 105A and opposes the first pad wiring 101 in the second direction Y.

The second step portion extends along the first step portion at intervals from the first step portion. The second step portion preferably extends substantially parallel to the first step portion in both the first direction X and the second direction Y. The second short wiring 115 preferably has the planar layout substantially congruent with a planar layout of the first short wiring 111.

Similarly to the case of the second layout example, in both the first arrangement region 105A and the second arrangement region 105B, the second short wiring 115 forms a current path of the drain source current Ids together with the first short wiring 111 opposing (closely opposing) the second short wiring 115 in the first direction X.

With reference to FIG. 42G (the seventh layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

The first short wiring 111 is led out in a single- or multi-stepped shape (in this embodiment, the multi-stepped shape) from a region of the first pad wiring 101 on the second end portion side with respect to the first end portion (the first long wiring 110) of the first pad wiring 101.

Similarly to the case of the second layout example, the first short wiring 111 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B. Also, the first short wiring 111 is electrically connected to the corresponding first lower wirings 81 via the plurality of first upper via electrodes 117.

In this embodiment, the first short wiring 111 has the first side portion led out in the second direction Y from the second end portion of the first pad wiring 101. The first side portion forms one side extending in the second direction Y with the second end portion of the first pad wiring 101. The first side portion crosses the boundary portion 107 in the second direction Y and is positioned in the second arrangement region 105B. The first side portion is formed at intervals from the second pad wiring 102 toward the first pad wiring 101 in the second arrangement region 105B and opposes the second pad wiring 102 in the second direction Y.

The first short wiring 111 has a first step portion extending in a stepped shape. In this embodiment, the first step portion is led out in the stepped shape from the first end portion side of the first pad wiring 101 toward the second end portion side of the second pad wiring 102 and is connected to the first side portion. Specifically, the first step portion crosses the boundary portion 107 in the stepped shape and is connected to the first side portion in the second arrangement region 105B. The first step portion is formed at intervals from the second pad wiring 102 toward the first pad wiring 101 in the second arrangement region 105B and opposes the second pad wiring 102 in the second direction Y.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

The second short wiring 115 is led out in a single- or multi-stepped shape (in this embodiment, the multi-stepped shape) from a region of the second pad wiring 102 on the first end portion side with respect to the second end portion (the second long wiring 114) of the second pad wiring 102 and is arranged in a region between the first long wiring 110 and the first short wiring 111.

Similarly to the case of the second layout example, the second short wiring 115 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A. Also, the second short wiring 115 is electrically connected to the corresponding second lower wirings 82 via the plurality of second upper via electrodes 118.

In this embodiment, the second short wiring 115 has a second side portion led out in the second direction Y from the first end portion of the second pad wiring 102. The second side portion forms one side extending in the second direction Y with the first end portion of the second pad wiring 102. The second side portion crosses the boundary portion 107 in the second direction Y and is positioned in the first arrangement region 105A. The second side portion is formed at intervals from the first pad wiring 101 toward the second pad wiring 102 in the first arrangement region 105A and opposes the first pad wiring 101 in the second direction Y.

The second short wiring 115 has a second step portion extending in a stepped shape. In this embodiment, the second step portion is led out in the stepped shape from the second end portion side of the second pad wiring 102 toward the first end portion side of the first pad wiring 101 and is connected to the second side portion. Specifically, the second step portion crosses the boundary portion 107 in the stepped shape and is connected to the second side portion in the first arrangement region 105A. The second step portion is formed at intervals from the first pad wiring 101 toward the second pad wiring 102 in the first arrangement region 105A and opposes the first pad wiring 101 in the second direction Y.

Similarly to the case of the second layout example, in both the first arrangement region 105A and the second arrangement region 105B, the second short wiring 115 forms a current path of the drain source current Ids together with the first short wiring 111 opposing (closely opposing) the second short wiring 115 in the first direction X.

With reference to FIG. 42H (the eighth layout example), the first interconnect structure 108 includes the plurality of first lead-out wirings 109. Each of the plurality of first lead-out wirings 109 includes the first long wiring 110 and the single first short wirings 111. The first long wiring 110 has the layout similar to that of the case of the first layout example.

The first short wiring 111 is led out in a polygonal shape (a quadrangular shape) toward the second pad wiring 102 from a region of the first pad wiring 101 on the second end portion side with respect to the first end portion (the first long wiring 110) of the first pad wiring 101. In this embodiment, the first short wiring 111 is formed at intervals from the boundary portion 107 (an intermediate portion) toward the first pad wiring 101 and is not positioned in the second arrangement region 105B.

The first short wiring 111 covers at least one (in this embodiment, a plurality) of the first lower wirings 81 and at least one (in this embodiment, a plurality) of the second lower wirings 82 in the first arrangement region 105A. The first short wirings 111 are electrically connected to at least one (in this embodiment, a plurality) of the first lower wirings 81 in the first arrangement region 105A. Similarly to the case of the second layout example, the first short wiring 111 is electrically connected to the corresponding first lower wirings 81 via the plurality of first upper via electrodes 117.

The first interconnect structure 108 includes the plurality of second lead-out wirings 113. Each of the plurality of second lead-out wirings 113 includes the second long wiring 114 and the single second short wiring 115. The second long wiring 114 has the layout similar to that of the case of the first layout example.

In this embodiment, the second long wiring 114 is electrically connected to one or a plurality of (preferably, all of) the second lower wirings 82 passing directly below the single first short wiring 111 in the first arrangement region 105A. On the other hand, the second long wiring 114 is electrically disconnected from one or a plurality of (preferably, all of) the first lower wirings 81 passing directly below the single first short wiring 111. Consequently, the second long wiring 114 forms a current path of the drain source current Ids together with the single first short wiring 111 opposing (closely opposing) the second long wiring 114 in the first direction X in the first arrangement region 105A.

In this embodiment, the second short wiring 115 is led out in a polygonal shape (a quadrangular shape) toward the first pad wiring 101 from a region of the second pad wiring 102 on the first end portion side with respect to the second end portion (the second long wiring 114) of the second pad wiring 102. In this embodiment, the second short wiring 115 is formed at intervals from the boundary portion 107 (the intermediate portion) toward the second pad wiring 102 and is not positioned in the first arrangement region 105A. The second short wiring 115 opposes the first short wiring 111 in the second direction Y across the boundary portion 107.

The second short wiring 115 covers at least one (in this embodiment, a plurality) of the first lower wirings 81 and at least one (in this embodiment, a plurality) of the second lower wirings 82 in the second arrangement region 105B. The second short wirings 115 are electrically connected to at least one (in this embodiment, a plurality) of the second lower wirings 82 in the second arrangement region 105B. Similarly to the case of the second layout example, the second short wiring 115 is electrically connected to the corresponding second lower wirings 82 via the plurality of second upper via electrodes 118.

In this embodiment, the second short wiring 115 is electrically connected to one or a plurality of the second lower wirings 82 passing directly below the first long wiring 110 in the second arrangement region 105B. On the other hand, the second short wiring 115 is electrically disconnected from one or a plurality of (preferably, all of) the first lower wirings 81 passing directly below the first long wiring 110.

The second short wiring 115 forms a current path of the drain source current Ids together with the first long wiring 110 opposing (closely opposing) the second short wiring 115 in the first direction X in the second arrangement region 105B. Also, the second short wiring 115 forms a current path of the drain source current Ids together with the single first short wiring 111 opposing (closely opposing) the second short wiring 115 in the second direction Y.

With reference to FIG. 42I (the ninth layout example), the first wiring unit U1 according to the ninth layout example has a form in which the first pad wiring 101, the second pad wiring 102, and the first interconnect structure 108 according to the first layout example are modified. Hereinafter, with regard to the two first wiring units U1 adjacent in the first direction X, the first wiring unit U1 on the one side in the first direction X is referred to as the “one first wiring unit U1,” and the first wiring unit U1 on the other side in the first direction X is referred to as the “other first wiring unit U1.”

Hereinafter, the first arrangement region 105A of the one first wiring unit U1 is referred to as the “one first arrangement region 105A,” and the second arrangement region 105B of the one first wiring unit U1 is referred to as the “one second arrangement region 105B.” Also, the first arrangement region 105A of the other first wiring unit U1 is referred to as the “other first arrangement region 105A,” and the second arrangement region 105B of the other first wiring unit U1 is referred to as the “other second arrangement region 105B.” Hereinafter, a configuration of the ninth layout example will be described with the configuration on the one first wiring unit U1 side as a reference.

In this embodiment, the first pad wirings 101 are individually formed at intervals inward from both sides of the first arrangement region 105A in the first direction X and are provided at the biased position on the one side in the second direction Y. Similarly to the case of the first layout example, each of the first pad wirings 101 has a first end portion on the one side in the first direction X and a second end portion on the other side in the first direction X.

In this embodiment, the second pad wirings 102 are individually formed at intervals inward from both sides of the second arrangement region 105B in the first direction X and are provided at the biased position on the other side in the second direction Y. Similarly to the case of the first layout example, each of the second pad wirings 102 has a first end portion on the one side in the first direction X and a second end portion on the other side in the first direction X.

In this embodiment, each of the first interconnect structures 108 has the single first lead-out wiring 109 instead of the plurality of first lead-out wirings 109. The first lead-out wiring 109 is led out from the first pad wiring 101 to a region opposing the second pad wiring 102 in the first direction X. The first lead-out wiring 109 includes the first inclined portion 121 and the first rectilinear portion 122.

The first inclined portion 121 is led out as a band in an oblique direction from the first pad wiring 101 toward the first end portion of the second pad wiring 102. An inclination direction of the first inclined portion 121 is the direction intersecting both the first direction X and the second direction Y. The first inclined portion 121 covers at least one (in this embodiment, a plurality) of the first lower wirings 81 and at least one (in this embodiment, a plurality) of the second lower wirings 82 in the first arrangement region 105A.

Further, the first inclined portion 121 crosses the boundary portion 107 along the inclination direction and is led out from the first arrangement region 105A to the second arrangement region 105B. In this embodiment, the first inclined portion 121 covers at least one (in this embodiment, a plurality) of the first lower wirings 81 and at least one (in this embodiment, a plurality) of the second lower wirings 82 in the second arrangement region 105B.

Consequently, the first inclined portion 121 is electrically connected to at least one (in this embodiment, a plurality) of the first lower wirings 81 between the first pad wiring 101 and the second pad wiring 102. Specifically, the first inclined portion 121 is electrically connected to at least one (in this embodiment, a plurality) of the first lower wirings 81 in the first arrangement region 105A and is electrically connected to at least one (in this embodiment, a plurality) of the first lower wirings 81 in the second arrangement region 105B.

Further, the first inclined portion 121 has a portion that crosses a boundary portion of the corresponding first wiring unit U1 along the inclination direction and is positioned in a region outside the corresponding first wiring unit U1. Consequently, the wiring area of each of the first lead-out wirings 109 is increased.

For example, the first inclined portion 121 of the other first wiring unit U1 is led out from the other second arrangement region 105B to the one second arrangement region 105B. The other first inclined portion 121 covers at least one (in this embodiment, a plurality) of the first lower wirings 81 and at least one (in this embodiment, a plurality) of the second lower wirings 82 in the one second arrangement region 105B.

The other first inclined portion 121 is electrically connected to at least one (in this embodiment, a plurality) of the first lower wirings 81 in the one second arrangement region 105B. The other first inclined portion 121 may have the portion positioned in the one first arrangement region 105A. In this case, the other first inclined portion 121 may be electrically connected to at least one (in this embodiment, a plurality) of the first lower wirings 81 in the one first arrangement region 105A.

The first rectilinear portion 122 is led out as a band in the second direction Y from the first inclined portion 121 in the second arrangement region 105B and intersects (is orthogonal to) at least one (in this embodiment, a plurality) of the first lower wirings 81 and at least one (in this embodiment, a plurality) of the second lower wiring 82.

The first rectilinear portion 122 is led out to the region opposing the second pad wiring 102 in the first direction X. The first rectilinear portion 122 opposes the entire first end portion of the second pad wiring 102 in the first direction X. The first rectilinear portion 122 intersects (is orthogonal to) one or a plurality of (preferably, all of) the first lower wirings 81 and one or a plurality of (preferably, all of) the second lower wirings 82 passing directly below the second pad wiring 102 in the first direction X.

The first rectilinear portion 122 is electrically connected to, of one or a plurality of (preferably, all of) the first lower wirings 81 covered with the second pad wiring 102, portions of the first lower wirings 81 exposed from the second pad wiring 102. On the other hand, the first rectilinear portion 122 is electrically disconnected from one or a plurality of (preferably, all of) the second lower wirings 82 passing directly below the second pad wiring 102. Consequently, the first rectilinear portion 122 forms a current path of the drain source current Ids together with the second pad wiring 102 opposing (closely opposing) the first rectilinear portion 122 in the first direction X.

Further, the first rectilinear portion 122 has the portion that crosses the boundary portion of the corresponding first wiring unit U1 in the first direction X and is positioned in the region outside the corresponding first wiring unit U1. Consequently, the wiring area of each of the first lead-out wirings 109 is increased.

For example, the first rectilinear portion 122 of the other first wiring unit U1 is led out from the other second arrangement region 105B to the one second arrangement region 105B and opposes the one and the other second pad wirings 102 on both sides in the first direction X. The other first rectilinear portion 122 opposes the entire second end portion of the one second pad wiring 102 in the first direction X in the one second arrangement region 105B.

The other first rectilinear portion 122 has a width less than the width of the first pad wiring 101 (the second pad wiring 102) in the first direction X. As a matter of course, the width of the first rectilinear portion 122 may be larger than the width of the first pad wiring 101 (the second pad wiring 102).

The other first rectilinear portion 122 intersects (is orthogonal to) one or a plurality of (preferably, all of) the first lower wirings 81 and one or a plurality of (preferably, all of) the second lower wirings 82 passing directly below the one and the other second pad wirings 102 in the first direction X.

The other first rectilinear portion 122 is electrically connected to one or a plurality of (preferably, all of) the first lower wirings 81 passing directly below the one and the other second pad wirings 102. On the other hand, the other first rectilinear portion 122 is electrically disconnected from one or a plurality of (preferably, all of) the second lower wirings 82 passing directly below the one and the other second pad wirings 102. Consequently, the other first rectilinear portion 122 forms a current path of the drain source current Ids together with the one and the other second pad wirings 102.

Similarly to the case of the first layout example, the first lead-out wiring 109 (the first inclined portion 121 and the first rectilinear portion 122) is electrically connected to the corresponding first lower wirings 81 via the plurality of first upper via electrodes 117.

In this embodiment, each of the first interconnect structures 108 has the single second lead-out wiring 113 instead of the plurality of second lead-out wirings 113. The second lead-out wiring 113 is led out from the second pad wiring 102 to the region opposing the first pad wiring 101 in the first direction X. The second lead-out wiring 113 includes the second inclined portion 123 and the second rectilinear portion 124.

The second inclined portion 123 is led out as a band in the oblique direction from the second pad wiring 102 toward the second end portion of the first pad wiring 101. It is preferable that the width of the second inclined portion 123 is substantially equal to the width of the first inclined portion 121. The inclination direction of the second inclined portion 123 is the direction intersecting both the first direction X and the second direction Y. The second inclined portion 123 extends along the first inclined portion 121 at intervals from the first inclined portion 121.

It is preferable that the second inclined portion 123 extends substantially parallel to the first inclined portion 121 at intervals from the first inclined portion 121 in the vertical direction of the first inclined portion 121. That is, it is preferable that the inclination angle of the second inclined portion 123 is substantially equal to the inclination angle of the first inclined portion 121. The second inclined portion 123 covers at least one (in this embodiment, a plurality) of the first lower wirings 81 and at least one (in this embodiment, a plurality) of the second lower wirings 82 in the second arrangement region 105B.

Further, the second inclined portion 123 crosses the boundary portion 107 along the inclination direction and is led out from the second arrangement region 105B to the first arrangement region 105A. In this embodiment, the second inclined portion 123 covers at least one (in this embodiment, a plurality) of the first lower wirings 81 and at least one (in this embodiment, a plurality) of the second lower wirings 82 in the first arrangement region 105A.

Consequently, the second inclined portion 123 is electrically connected to at least one (in this embodiment, a plurality) of the second lower wirings 82 between the first pad wiring 101 and the second pad wiring 102. Specifically, the second inclined portion 123 is electrically connected to at least one (in this embodiment, a plurality) of the second lower wirings 82 in the second arrangement region 105B and is electrically connected to at least one (in this embodiment, a plurality) of the second lower wirings 82 in the first arrangement region 105A.

The second inclined portion 123 covers one or a plurality of (preferably, all of) the first lower wirings 81 and one or a plurality of (preferably, all of) the second lower wirings 82 passing directly below the first inclined portion 121 in the first direction X. The second inclined portion 123 is electrically connected to, of one or a plurality of (preferably, all of) the second lower wirings 82 covered with the first inclined portion 121, portions of the second lower wirings 82 exposed from the first inclined portion 121.

On the other hand, the second inclined portion 123 is electrically disconnected from one or a plurality of (preferably, all of) the first lower wirings 81 passing directly below the first inclined portion 121. Consequently, in both the first arrangement region 105A and the second arrangement region 105B, the second inclined portion 123 forms a current path of the drain source current Ids together with the first inclined portion 121 opposing (closely opposing) the second inclined portion 123 in the first direction X.

Further, the second inclined portion 123 has a portion that crosses the boundary portion of the corresponding first wiring unit U1 along the inclination direction and is positioned in a region outside the corresponding first wiring unit U1. Consequently, the wiring area of each of the second lead-out wirings 113 is increased.

For example, the second inclined portion 123 of the one first wiring unit U1 is led out from the one first arrangement region 105A to the other first arrangement region 105A. The one second inclined portion 123 covers at least one (in this embodiment, a plurality) of the first lower wirings 81 and at least one (in this embodiment, a plurality) of the second lower wirings 82 in the other first arrangement region 105A.

The one second inclined portion 123 is electrically connected to, of one or a plurality of (preferably, all of) the second lower wirings 82 covered with the other first inclined portion 121, portions of the second lower wirings 82 exposed from the other first inclined portion 121 in the other first arrangement region 105A. On the other hand, the one second inclined portion 123 is electrically disconnected from one or a plurality of (preferably, all of) the first lower wirings 81 passing directly below the other first inclined portion 121. Consequently, the one second inclined portion 123 forms a current path of the drain source current Ids together with the other first inclined portion 121.

The one second inclined portion 123 may have a portion positioned in the other second arrangement region 105B. In this case, the one second inclined portion 123 may be electrically connected to at least one (in this embodiment, a plurality) of the second lower wirings 82 in the other second arrangement region 105B and may form a current path of the drain source current Ids together with the other first inclined portion 121.

The second rectilinear portion 124 is led out as a band in the second direction Y from the second inclined portion 123 in the first arrangement region 105A and intersects (is orthogonal to) at least one (in this embodiment, a plurality) of the first lower wirings 81 and at least one (in this embodiment, a plurality) of the second lower wiring 82. The second rectilinear portion 124 is led out to a region opposing the second end portion of the first pad wiring 101 in the first direction X. The second rectilinear portion 124 opposes the entire second end portion of the first pad wiring 101 in the first direction X. The second rectilinear portion 124 opposes the first rectilinear portion 122 in the second direction Y.

The second rectilinear portion 124 intersects (is orthogonal to) one or a plurality of (preferably, all of) the first lower wirings 81 and one or a plurality of (preferably, all of) the second lower wirings 82 passing directly below the first pad wiring 101 in the first direction X. The second rectilinear portion 124 is electrically connected to, of one or a plurality of (preferably, all of) the second lower wirings 82 covered with the first pad wiring 101, portions of the second lower wirings 82 exposed from the first pad wiring 101.

On the other hand, the second rectilinear portion 124 is electrically disconnected from one or a plurality of (preferably, all of) the first lower wirings 81 passing directly below the first pad wiring 101. Consequently, the second rectilinear portion 124 forms a current path of the drain source current Ids together with the first pad wiring 101 opposing (closely opposing) the second rectilinear portion 124 in the first direction X.

Further, the second rectilinear portion 124 has a portion that crosses the boundary portion of the corresponding first wiring unit U1 in the first direction X and is positioned in a region outside the corresponding first wiring unit U1. Consequently, the wiring area of each of the second lead-out wirings 113 is increased.

For example, the second rectilinear portion 124 of the one first wiring unit U1 is led out from the one first arrangement region 105A to the other first arrangement region 105A, opposes the one and the other first pad wirings 101 on both sides in the first direction X, and opposes the other first rectilinear portion 122 in the second direction Y. The one second rectilinear portion 124 opposes the entire first end portion of the other first pad wiring 101 in the first direction X in the other first arrangement region 105A.

The second rectilinear portion 124 has a width less than the width of the first pad wiring 101 (the second pad wiring 102) in the first direction X. As a matter of course, the width of the second rectilinear portion 124 may be larger than the width of the first pad wiring 101 (the second pad wiring 102). It is preferable that the width of the second rectilinear portion 124 is substantially equal to the width of the first rectilinear portion 122.

The one second rectilinear portion 124 intersects (is orthogonal to) one or a plurality of (preferably, all of) the first lower wirings 81 and one or a plurality of (preferably, all of) the second lower wirings 82 passing directly below the one and the other first pad wirings 101 in the first direction X. The one second rectilinear portion 124 is electrically connected to one or a plurality of (preferably, all of) the second lower wirings 82 passing directly below the one and the other first pad wirings 101.

On the other hand, the one second rectilinear portion 124 is electrically disconnected from one or a plurality of (preferably, all of) the first lower wirings 81 passing directly below the one and the other first pad wirings 101. Consequently, the one second rectilinear portion 124 forms a current path of the drain source current Ids together with the one and the other first pad wirings 101.

Similarly to the case of the first layout example, the second lead-out wiring 113 (the second inclined portion 123 and the second rectilinear portion 124) is electrically connected to the corresponding second lower wirings 82 via the plurality of second upper via electrodes 118.

As described above, the first wiring unit U1 includes the first upper wiring and the second upper wiring. The first upper wiring includes the first pad wiring 101 and the single first lead-out wiring 109, and the second upper wiring includes the second pad wiring 102 and the single second lead-out wiring 113. In this configuration, the second upper wiring preferably has a planar layout substantially congruent with the planar layout of the first upper wiring.

That is, it is preferable that the planar shape of the second upper wiring is substantially equal to the planar shape of the first upper wiring, and the plane area of the second upper wiring is substantially equal to the plane area of the first upper wiring. The second upper wiring is preferably arranged point-symmetrically with respect to the first upper wiring about the central portion of the boundary portion 107.

With reference to FIG. 42J (the tenth layout example), the tenth layout example has a configuration obtained by modifying the ninth layout example. The first pad wiring 101 has a plurality of first edge portions connecting the side extending in the first direction X to a side extending in the second direction Y. The first pad wiring 101 has at least one (in this embodiment, a plurality) of the first chamfered portions 125 formed at at least one (in this embodiment, a plurality) of the first edge portions.

The plurality of first chamfered portions 125 are recessed toward the inside of the first arrangement region 105A in plan view. In this embodiment, the plurality of first chamfered portions 125 are constituted of the inclined portions inclined in the direction intersecting both the first direction X and the second direction Y. The plurality of first chamfered portions 125 may be defined in a polygonal shape (for example, a quadrangular shape, a hexagonal shape, etc.) toward the inside of the first arrangement region 105A. The plurality of first chamfered portions 125 may be curved in an arc shape (a circular arc shape) toward the inside or the outside of the first arrangement region 105A.

The second pad wiring 102 has the plurality of second edge portions connecting the side extending in the first direction X to the side extending in the second direction Y. The second pad wiring 102 has at least one (in this embodiment, a plurality) of the second chamfered portions 126 formed at at least one (in this embodiment, a plurality) of the second edge portions.

The plurality of second chamfered portions 126 are recessed toward an inside of the second arrangement region 105B in plan view. In this embodiment, the plurality of second chamfered portions 126 are constituted of inclined portions inclined in a direction intersecting both the first direction X and the second direction Y. The plurality of second chamfered portions 126 may be defined in a polygonal shape (for example, a quadrangular shape, a hexagonal shape, etc.) toward the inside of the second arrangement region 105B. The plurality of second chamfered portions 126 may be curved in an arc shape (a circular arc shape) toward the inside or the outside of the second arrangement region 105B.

The first lead-out wiring 109 has at least one (in this embodiment, a plurality) of the first flared portions 127 flared from the first rectilinear portions 122 toward the second chamfered portions 126 of the corresponding second pad wiring 102. The first flared portion 127 increases the wiring area of the first lead-out wiring 109.

With regard to the two adjacent first wiring units U1, the first lead-out wiring 109 includes the first flared portion 127 flared in the first direction X toward the second chamfered portion 126 of the one second pad wiring 102, and the first flared portion 127 that flares in the first direction X toward the second chamfered portion 126 of the other second pad wiring 102.

In this embodiment, the first flared portion 127 flares in a triangular shape. A planar shape of the first flared portion 127 is adjusted depending on a planar shape of the second chamfered portion 126. The first flared portion 127 may flare in a polygonal shape or a circular arc shape depending on the planar shape of the second chamfered portion 126.

Each of the first flared portions 127 has a portion extending along the corresponding second chamfered portion 126 and opposes the corresponding second pad wiring 102 in both the first direction X and the second direction Y. Each of the first flared portions 127 covers at least one (in this embodiment, a plurality) of the first lower wirings 81 in a region along the corresponding second chamfered portion 126. In this embodiment, each of the first flared portions 127 covers at least one (in this embodiment, a plurality) of the first lower wirings 81 and at least one (in this embodiment, a plurality) of the second lower wirings 82.

Each of the first flared portions 127 is electrically connected to, of one or a plurality of the first lower wirings 81 covered with the corresponding second pad wiring 102, portions of the first lower wirings 81 exposed from the corresponding second pad wiring 102. On the other hand, each of the first flared portions 127 is electrically disconnected from one or a plurality of (preferably, all of) the second lower wirings 82 passing directly below the corresponding second pad wiring 102. Consequently, each of the first flared portions 127 forms a current path of the drain source current Ids together with the corresponding second pad wiring 102.

The second lead-out wiring 113 has at least one (in this embodiment, a plurality) of second flared portions 128 flared from the second rectilinear portions 124 toward the first chamfered portions 125 of the corresponding first pad wiring 101. The second flared portions 128 increases the wiring area of the second lead-out wiring 113.

With regard to the two adjacent first wiring units U1, the second lead-out wiring 113 includes the second flared portion 128 flared in the first direction X toward the first chamfered portions 125 of the one first pad wiring 101, and the second flared portion 128 flared in the first direction X toward the first chamfered portions 125 of the other first pad wiring 101.

In this embodiment, the second flared portion 128 flares in a triangular shape. A planar shape of the second flared portion 128 is adjusted depending on a planar shape of the first chamfered portion 125. The second flared portion 128 may flare in a polygonal shape or a circular arc shape depending on the planar shape of the first chamfered portion 125.

Each of the second flared portions 128 has a portion extending along the corresponding first chamfered portion 125 and opposes the corresponding first pad wiring 101 in both the first direction X and the second direction Y. Each of the second flared portions 128 covers at least one (in this embodiment, a plurality) of the second lower wirings 82 in a region along the corresponding first chamfered portion 125. In this embodiment, each of the second flared portions 128 covers at least one (in this embodiment, a plurality) of the first lower wirings 81 and at least one (in this embodiment, a plurality) of the second lower wirings 82.

Each of the second flared portions 128 is electrically connected to, of one or a plurality of the second lower wirings 82 covered with the corresponding first pad wiring 101, portions of the second lower wirings 82 exposed from the corresponding first pad wiring 101. On the other hand, each of the second flared portions 128 is electrically disconnected from one or a plurality of (preferably, all of) the first lower wirings 81 passing directly below the corresponding first pad wiring 101. Consequently, each of the second flared portions 128 forms a current path of the drain source current Ids together with the corresponding first pad wiring 101.

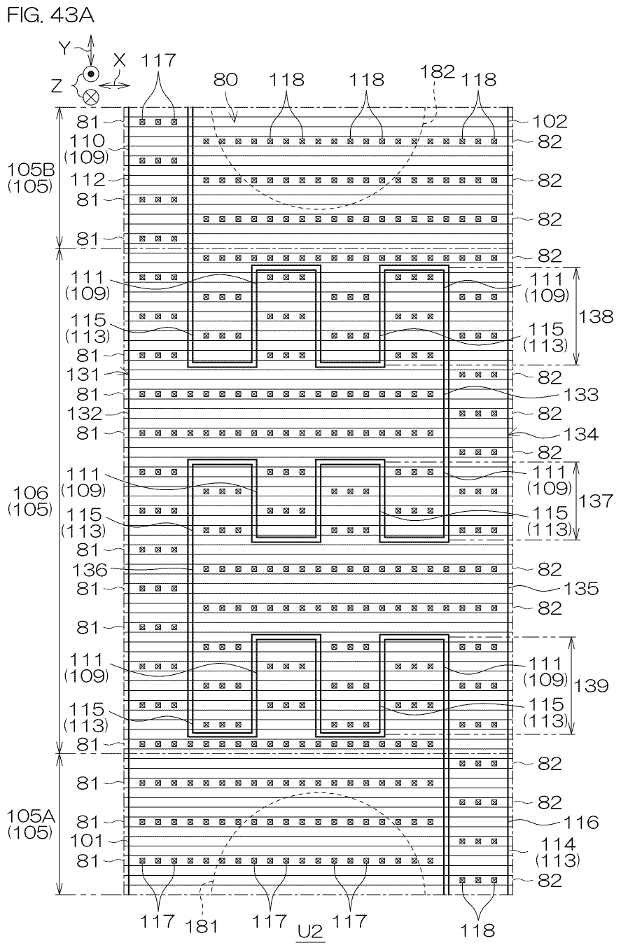

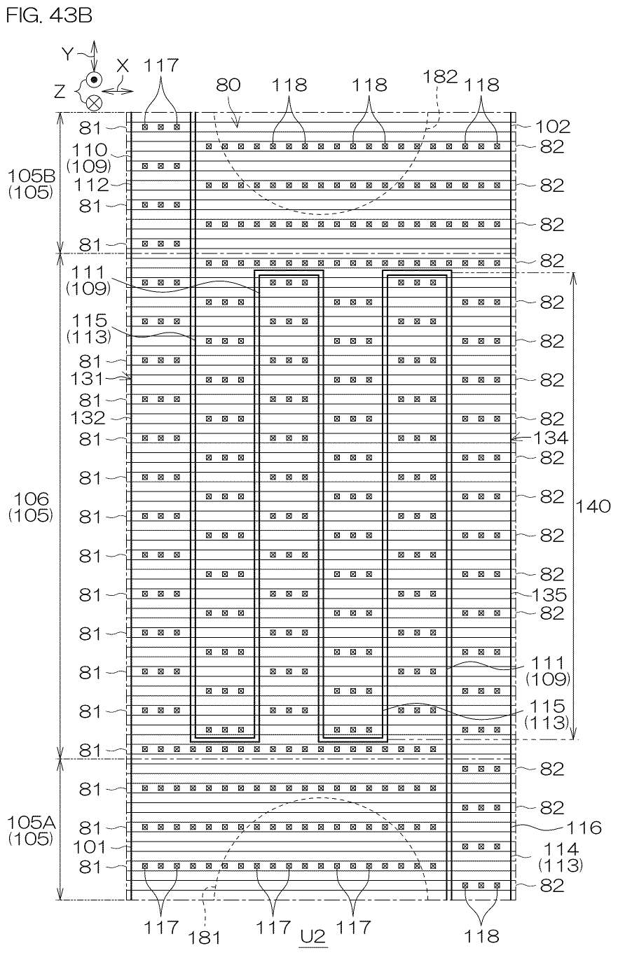

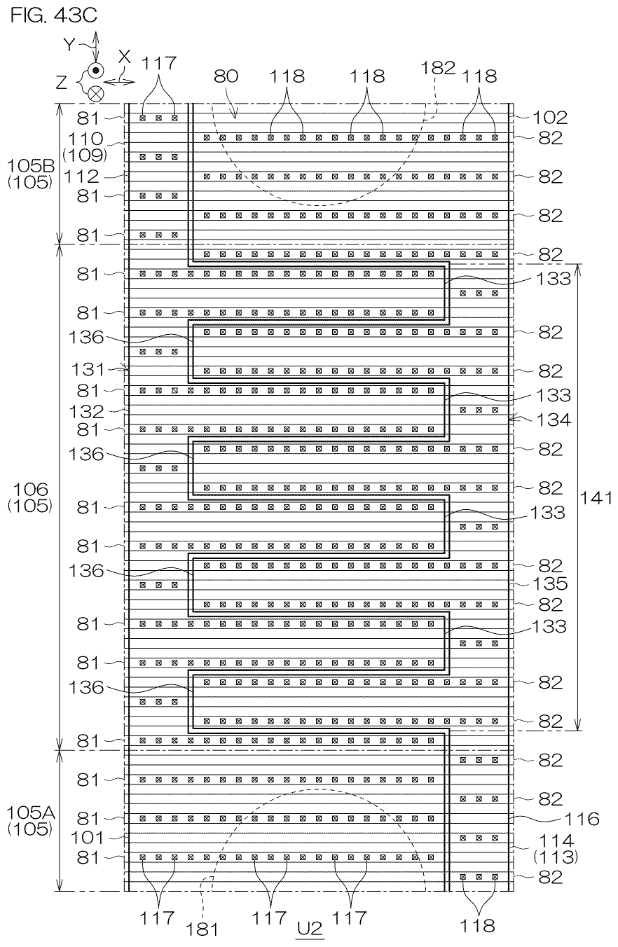

FIG. 43A is an enlarged plan view showing a layout example of the second wiring unit U2. With reference to FIG. 43A, the second wiring unit U2 includes the first arrangement region 105A (the first pad wiring 101), the second arrangement region 105B (the second pad wiring 102), and the space region 106.

The first pad wiring 101 is positioned on the other side in the second direction Y, and the second pad wiring 102 is positioned on the one side in the second direction Y. The layout of the first pad wiring 101 and the layout of the second pad wiring 102 are similar to the case of the first wiring unit U1, etc., according to the first layout example.

The space region 106 is interposed between the two first wiring units U1 adjacent in the second direction Y. That is, the space region 106 is interposed between the first arrangement region 105A (the first pad wiring 101) and the second arrangement region 105B (the second pad wiring 102). The space region 106 is adjacent to the second arrangement region 105B on the one side in the second direction Y and is adjacent to the first arrangement region 105A on the other side in the second direction Y.

The space region 106 is set in a quadrangular shape (preferably, a square shape) in plan view and includes at least one (in this embodiment, a plurality) of the first lower wirings 81 and at least one (in this embodiment, a plurality) of the second lower wirings 82. In the space region 106, both the number of the first lower wirings 81 and the number of the second lower wirings 82 are arbitrary.

For example, in the space region 106, the number of the first lower wirings 81 (the second lower wirings 82) may be not less than 1 and not more than 1000. For example, in the space region 106, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the space region 106, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, in the space region 106, a difference value between the number of the first lower wirings 81 and the number of the second lower wirings 82 is 0 to 1. The number of the first lower wirings 81 (the second lower wirings 82) in the space region 106 may be substantially equal to or different from the number of the first lower wirings 81 (the second lower wirings 82) in the first arrangement region 105A (the second arrangement region 105B).

The second wiring unit U2 includes a first routing wiring 131 routed from the first pad wiring 101 to the space region 106. The first routing wiring 131 transmits, to the space region 106, the first drain source potential applied to the first pad wiring 101. The first routing wiring 131 includes at least one (in this embodiment, one) first stem wiring 132 and at least one (in this embodiment, one) first branch wiring 133.

The number of the first branch wirings 133 is arbitrary and is appropriately adjusted depending on a size of the space region 106, etc. The number of the first branch wirings 133 may be not less than 1 and not more than 50. The number of the first branch wirings 133 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50. In this embodiment, one first branch wiring 133 is provided.

The first stem wiring 132 has a width less than the width of the first pad wiring 101 (the second pad wiring 102) in the first direction X and is led out as a band on the one side in the second direction Y from the first end portion of the first pad wiring 101 toward the space region 106. The width of the first stem wiring 132 is larger than the width of the first lower wiring 81 (the second lower wiring 82). In this embodiment, the first stem wiring 132 intersects (is orthogonal to) at least one (in this embodiment, a plurality) of the first lower wirings 81 and at least one (in this embodiment, a plurality) of the second lower wirings 82 in the space region 106.

In this embodiment, the first stem wiring 132 crosses a boundary portion between the space region 106 and the second arrangement region 105B and is connected to the first long wiring 110 (the first opposing portion 112) of the first wiring unit U1 (the first interconnect structure 108) in the second arrangement region 105B. The first stem wiring 132 may have a width substantially equal to the width of the first long wiring 110. The width of the first stem wiring 132 may be larger than the width of the first long wiring 110. The width of the first stem wiring 132 may be less than the width of the first long wiring 110.

The first stem wiring 132 is electrically connected to at least one (in this embodiment, a plurality) of the first lower wirings 81. Similarly to the first lead-out wiring 109, etc., the first stem wiring 132 is electrically connected to the corresponding first lower wirings 81 via the plurality of first upper via electrodes 117.

The first branch wiring 133 is led out as a band in the first direction X from the first stem wiring 132 in the space region 106. The first branch wiring 133 is formed at intervals from the first pad wiring 101 and the second pad wiring 102 and opposes the first pad wiring 101 and the second pad wiring 102 in the second direction Y.

The first branch wiring 133 may have a width substantially equal to the width of the first stem wiring 132. The width of the first branch wiring 133 may be larger than the width of the first stem wiring 132. The width of the first branch wiring 133 may be less than the width of the first stem wiring 132. The width of the first branch wiring 133 is larger than the width of the first lower wiring 81 (the second lower wiring 82).

The first branch wiring 133 covers at least one (in this embodiment, a plurality) of the first lower wirings 81 and at least one (in this embodiment, a plurality) of the second lower wirings 82. The first branch wiring 133 is electrically connected to at least one (in this embodiment, a plurality) of the first lower wirings 81. Similarly to the first pad wiring 101, etc., the first branch wiring 133 is electrically connected to the corresponding first lower wirings 81 via the plurality of first upper via electrodes 117.

In a case where a plurality of the first branch wirings 133 are formed, the plurality of first branch wirings 133 are respectively led out as bands extending in the first direction X at intervals in the second direction Y. That is, the plurality of first branch wirings 133 are formed in a comb teeth shape extending in the first direction X.

The second wiring unit U2 includes the second routing wiring 134 routed from the second pad wiring 102 to the space region 106. The second routing wiring 134 transmits, to the space region 106, the second drain source potential applied to the second pad wiring 102. The second routing wiring 134 includes at least one (in this embodiment, one) second stem wiring 135 and at least one (in this embodiment, one) second branch wiring 136.

The number of the second branch wiring 136 is arbitrary and is appropriately adjusted depending on the size of the space region 106, etc. The number of the second branch wiring 136 may be not less than 1 and not more than 50. The number of the second branch wiring 136 may be set to a value falling within at least one of ranges of not less than 1 and not more than 5, not less than 5 and not more than 10, not less than 10 and not more than 20, not less than 20 and not more than 30, not less than 30 and not more than 40, and not less than 40 and not more than 50.

The number of the second branch wirings 136 is preferably equal to the number of the first branch wirings 133. According to this configuration, variation in the wiring resistance between the first branch wiring 133 and the second branch wiring 136 is prevented. In this embodiment, one second branch wiring 136 is provided.

The second stem wiring 135 has a width less than the width of the second pad wiring 102 (the first pad wiring 101) in the first direction X and is led out as a band on the other side in the second direction Y from the second end portion of the second pad wiring 102 toward the space region 106. The width of the second stem wiring 135 is larger than the width of the second lower wiring 82 (the first lower wiring 81). The second stem wiring 135 is formed at intervals in the first direction X from the first stem wiring 132 and opposes the first stem wiring 132 in the first direction X. The second stem wiring 135 extends substantially parallel to the first stem wiring 132.

The second stem wiring 135 is formed at intervals in the first direction X from the first branch wiring 133 and opposes the first branch wiring 133 in the first direction X. The second stem wiring 135 intersects (is orthogonal to) at least one (in this embodiment, a plurality) of the first lower wirings 81 and at least one (in this embodiment, a plurality) of the second lower wirings 82 in the space region 106.

In this embodiment, the second stem wiring 135 crosses a boundary portion between the space region 106 and the first arrangement region 105A and is connected to the second long wiring 114 (the second opposing portion 116) of the first wiring unit U1 (the first interconnect structure 108) in the first arrangement region 105A.

The second stem wiring 135 may have a width substantially equal to the width of the second long wiring 114. The width of the second stem wiring 135 may be larger than the width of the second long wiring 114. The width of the second stem wiring 135 may be less than the width of the second long wiring 114. It is preferable that the width of the second stem wiring 135 is substantially equal to the width of the first stem wiring 132. According to this configuration, variation in the wiring resistance between the first stem wiring 132 and the second stem wiring 135 is prevented.

The second stem wiring 135 is electrically connected to at least one (in this embodiment, a plurality) of the second lower wirings 82. Similarly to the second long wiring 114, etc., the second stem wiring 135 is electrically connected to the corresponding second lower wirings 82 via the plurality of second upper via electrodes 118.

The second stem wiring 135 is electrically connected to, of one or a plurality of (preferably, all of) the second lower wirings 82 covered with the first branch wiring 133, portions of the second lower wirings 82 exposed from the first branch wiring 133. On the other hand, the second stem wiring 135 is electrically disconnected from one or a plurality of (preferably, all of) the first lower wirings 81 passing directly below the first branch wiring 133. The second stem wiring 135 forms a current path of the drain source current Ids together with the first branch wiring 133 opposing (closely opposing) the second stem wiring 135 in the first direction X.

The second branch wiring 136 is led out as a band in the first direction X from the second stem wiring 135 in the space region 106. The second branch wiring 136 is formed at intervals from the first pad wiring 101 and the second pad wiring 102 and opposes the first pad wiring 101 and the second pad wiring 102 in the second direction Y.

The second branch wiring 136 is formed at intervals in the second direction Y from the first branch wiring 133 and opposes the first branch wiring 133 in the second direction Y. Specifically, the second branch wiring 136 is arranged in a region between the first pad wiring 101 and the first branch wiring 133 and opposes both the first pad wiring 101 and the first branch wiring 133 in the second direction Y.

The second branch wiring 136 may have a width substantially equal to the width of the second stem wiring 135. The width of the second branch wiring 136 may be larger than the width of the second stem wiring 135. The width of the second branch wiring 136 may be less than the width of the second stem wiring 135. The width of the second branch wiring 136 is larger than the width of the second lower wiring 82 (the first lower wiring 81). It is preferable that the width of the second branch wiring 136 is substantially equal to the width of the first branch wiring 133. According to this configuration, variation in the wiring resistance between the first branch wiring 133 and the second branch wiring 136 is prevented.

The second branch wiring 136 covers at least one (in this embodiment, a plurality) of the first lower wirings 81 and at least one (in this embodiment, a plurality) of the second lower wirings 82. The second branch wiring 136 is formed at intervals in the first direction X from the first stem wiring 132 and opposes the first stem wiring 132 in the first direction X. It is preferable that, in the first direction X, a length of the second branch wiring 136 is substantially equal to a length of the first branch wiring 133.

The second branch wiring 136 is electrically connected to at least one (in this embodiment, a plurality) of the second lower wirings 82. Similarly to the second pad wiring 102, etc., the second branch wiring 136 is electrically connected to the corresponding second lower wirings 82 via the plurality of second upper via electrodes 118.

The second branch wiring 136 is electrically connected to, of one or a plurality of the second lower wirings 82 covered with the first stem wiring 132, portions of the second lower wirings 82 exposed from the first stem wiring 132. On the other hand, the second branch wiring 136 is electrically disconnected from one or a plurality of (preferably, all of) the first lower wirings 81 passing directly below the first stem wiring 132.

The second branch wiring 136 forms a current path of the drain source current Ids together with the first stem wiring 132 opposing (closely opposing) the second branch wiring 136 in the first direction X. Also, the second branch wiring 136 forms a current path of the drain source current Ids together with the first branch wiring 133.

In a case where a plurality of the second branch wirings 136 are formed, the plurality of second branch wirings 136 and one or a plurality (preferably, a plurality) of the first branch wirings 133 are alternately arrayed in the second direction Y. That is, the plurality of second branch wirings 136 are arrayed in a comb teeth shape that meshes with the one or a plurality (preferably, a plurality) of the first branch wirings 133.

As a matter of course, the plurality of first branch wirings 133 may be arrayed in a comb teeth shape that meshes with one or a plurality (preferably, a plurality) of the second branch wirings 136. In these cases, the number of the second branch wirings 136 is preferably equal to the number of the first branch wirings 133.

The second wiring unit U2 includes the second interconnect structure 137 formed in a region between the first branch wiring 133 and the second branch wiring 136. In a case where the plurality of first branch wirings 133 and/or the plurality of second branch wirings 136 are formed, the plurality of second interconnect structures 137 are each formed in a region between the regions between the plurality of pairs of the first branch wirings 133 and the second branch wirings 136 adjacent in the second direction Y.

The second interconnect structure 137 has the same configuration and function as those of the first interconnect structure 108 except that an arrangement location differs. Similarly to the first interconnect structure 108, the second interconnect structure 137 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132. The plurality of first lead-out wirings 109 are led out in the second direction Y from the first branch wiring 133 toward the second branch wiring 136 and are electrically connected to at least one of the first lower wirings 81 in the region between the first branch wiring 133 and the second branch wiring 136.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135. The plurality of second lead-out wirings 113 are led out in the second direction Y from the second branch wiring 136 toward the first branch wiring 133 and are electrically connected to at least one of the second lower wiring 82 in the region between the first branch wiring 133 and the second branch wiring 136.

As described above, in the second interconnect structure 137, a current path of the drain source current Ids via the plurality of first lead-out wirings 109 and the plurality of second lead-out wirings 113 is formed in the region between the first branch wiring 133 and the second branch wiring 136.

The second interconnect structure 137 may have a configuration similar to any one of the first interconnect structures 108 according to the first to eighth layout examples. In this case, a specific configuration of the second interconnect structure 137 is obtained by replacing the “first pad wiring 101” with the “first branch wiring 133” and replacing the “second pad wiring 102” with the “second branch wiring 136” in the description of the first interconnect structure 108 described above.

The second wiring unit U2 includes the third interconnect structure 138 formed in a region between the second pad wiring 102 and the first branch wiring 133. The third interconnect structure 138 has the same configuration and function as those of the first interconnect structure 108 except that an arrangement location differs. Similarly to the first interconnect structure 108, the third interconnect structure 138 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132. The plurality of first lead-out wirings 109 are led out in the second direction Y from the first branch wiring 133 toward the second pad wiring 102 and are electrically connected to at least one of the first lower wirings 81 in the region between the second pad wiring 102 and the first branch wiring 133.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135. The plurality of second lead-out wirings 113 are led out in the second direction Y from the second pad wiring 102 toward the first branch wiring 133 and are electrically connected to at least one of the second lower wiring 82 in the region between the second pad wiring 102 and the second branch wiring 136.

As described above, in the third interconnect structure 138, a current path of the drain source current Ids via the plurality of first lead-out wirings 109 and the plurality of second lead-out wirings 113 is formed in the region between the second pad wiring 102 and the first branch wiring 133.

The third interconnect structure 138 may have a configuration similar to any one of the first interconnect structures 108 according to the first to eighth layout examples. In this case, a specific configuration of the third interconnect structure 138 is obtained by replacing the “first pad wiring 101” with the “first branch wiring 133” in the description of the first interconnect structure 108 described above.

The second wiring unit U2 includes the fourth interconnect structure 139 formed in a region between the first pad wiring 101 and the second branch wiring 136. The fourth interconnect structure 139 has the same configuration and function as those of the first interconnect structure 108 except that an arrangement location differs. Similarly to the first interconnect structure 108, the fourth interconnect structure 139 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132. The plurality of first lead-out wirings 109 are led out in the second direction Y from the first pad wiring 101 toward the second branch wiring 136 and are electrically connected to at least one of the first lower wirings 81 in the region between the first pad wiring 101 and the second branch wiring 136.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135. The plurality of second lead-out wirings 113 are led out in the second direction Y from the second branch wiring 136 toward the first pad wiring 101 and are electrically connected to at least one of the second lower wiring 82 in the region between the first pad wiring 101 and the second branch wiring 136.

As described above, in the fourth interconnect structure 139, a current path of the drain source current Ids via the plurality of first lead-out wirings 109 and the plurality of second lead-out wirings 113 is formed in the region between the first pad wiring 101 and the second branch wiring 136.

The fourth interconnect structure 139 may have a configuration similar to any one of the first interconnect structures 108 according to the first to eighth layout examples. In this case, a specific configuration of the fourth interconnect structure 139 is obtained by replacing the “second pad wiring 102” with the “second branch wiring 136” in the description of the first interconnect structure 108 described above.

The second wiring unit U2 can have a layout shown in FIG. 43B. FIG. 43B is an enlarged plan view showing the second wiring unit U2 according to the second layout example. With reference to FIG. 43B (the second layout example), in this embodiment, the second wiring unit U2 does not have the first branch wiring 133, the second branch wiring 136, and the second to fourth interconnect structures 137 to 139 but includes the one first space interconnect structure 140.

The first space interconnect structure 140 has the same configuration and function as those of the first interconnect structure 108 except that an arrangement location differs. Similarly to the first interconnect structure 108, the first space interconnect structure 140 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the first stem wiring 132 as at least one (in this embodiment, one) of the first long wirings 110 that are relatively long and at least one (in this embodiment, a plurality) of the first short wirings 111 that are shorter than the first stem wiring 132.

The plurality of first short wirings 111 are led out in the second direction Y from the first pad wiring 101 toward the second pad wiring 102. The plurality of first short wirings 111 are electrically connected to at least one of the first lower wirings 81 in the region (the space region 106) between the first pad wiring 101 and the second pad wiring 102.

Similarly to the first interconnect structure 108, the plurality of second lead-out wirings 113 include the second stem wiring 135 as at least one (in this embodiment, one) of the second long wirings 114 that are relatively long and at least one (in this embodiment, a plurality) of the second short wirings 115 that are shorter than the second stem wiring 135.

The plurality of second short wirings 115 are led out in the second direction Y from the second pad wiring 102 toward the first pad wiring 101. The plurality of second short wirings 115 are connected to at least one of the second lower wirings 82 in the region (the space region 106) between the first pad wiring 101 and the second pad wiring 102.

As described above, in the first space interconnect structure 140, a current path of the drain source current Ids via the plurality of first lead-out wirings 109 and the plurality of second lead-out wirings 113 is formed in the space region 106.

The first space interconnect structure 140 may have a configuration similar to any one of the first interconnect structures 108 according to the first to eighth layout examples. In this case, a specific configuration of the first space interconnect structure 140 can be obtained by replacing the “region between the first pad wiring 101 and the second pad wiring 102” with the “space region 106” in the description of the first interconnect structure 108 described above.

The second wiring unit U2 can have a layout shown in FIG. 43C. FIG. 43C is an enlarged plan view showing the second wiring unit U2 according to the third layout example. With reference to FIG. 43C (the third layout example), in this embodiment, the second wiring unit U2 includes the one second space interconnect structure 141 instead of the second to fourth interconnect structures 137 to 139.

The second space interconnect structure 141 is constituted of at least one (in this embodiment, a plurality) of the first branch wirings 133 and at least one (in this embodiment, a plurality) of the second branch wirings 136. The number of the second branch wirings 136 is preferably equal to the number of the first branch wirings 133.

The plurality of first branch wirings 133 respectively extend as bands in the first direction X and are arrayed at intervals in the second direction Y. That is, the plurality of first branch wirings 133 are arrayed in a comb teeth shape extending in the first direction X. On the other hand, the plurality of second branch wirings 136 respectively extend as bands in the first direction X and are arrayed at intervals in the second direction Y. That is, the plurality of second branch wirings 136 are arrayed in a comb teeth shape extending in the first direction X.

Specifically, the plurality of second branch wirings 136 and the plurality of first branch wirings 133 are alternately arrayed in the second direction Y, and the plurality of second branch wirings 136 are arrayed in the comb teeth shape that meshes with the plurality of first branch wirings 133. The plurality of second branch wirings 136 include one of the second branch wirings 136 that is interposed between the first pad wiring 101 and the first branch wiring 133. The plurality of second branch wirings 136 include one of the second branch wirings 136 opposing the second pad wiring 102 across one of the first branch wirings 133.

As a matter of course, the second space interconnect structure 141 may be constituted of the single first branch wiring 133 and the single second branch wiring 136. In this case, the first branch wiring 133 is arranged in the region opposing the second pad wiring 102 in the second direction Y, and the second branch wiring 136 is arranged in the region between the first pad wiring 101 and the first branch wiring 133.

As described above, in the second space interconnect structure 141, a current path of the drain source current Ids via the plurality of first branch wirings 133 and the plurality of second branch wirings 136 is formed in the space region 106.

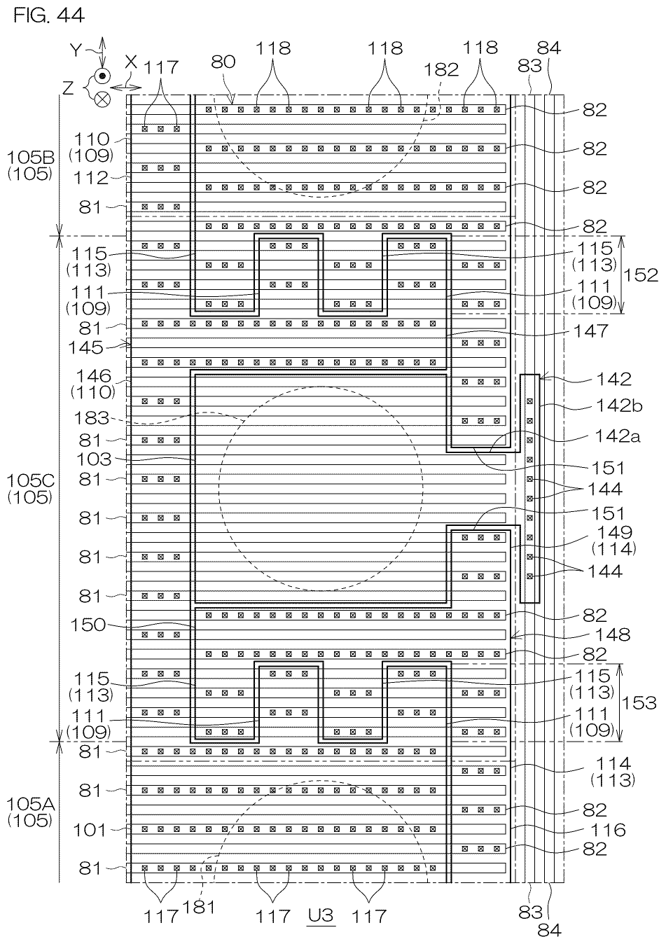

FIG. 44 is an enlarged plan view showing an example of the third wiring unit U3. The third wiring unit U3 includes the first arrangement region 105A (the first pad wiring 101), the second arrangement region 105B (the second pad wiring 102), and the arrangement region 105 for the third pad wiring 103. Hereinafter, the arrangement region 105 for the third pad wiring 103 is referred to as the “third arrangement region 105C.”

The third arrangement region 105C is interposed between the two first wiring units U1 adjacent in the second direction Y and opposes the second wiring unit U2 (the space region 106) in the first direction X. That is, the third arrangement region 105C is interposed between the first arrangement region 105A (the first pad wiring 101) and the second arrangement region 105B (the second pad wiring 102). The third arrangement region 105C is adjacent to the second arrangement region 105B on the one side in the second direction Y and is adjacent to the first arrangement region 105A on the other side in the second direction Y.

The third arrangement region 105C is set in a quadrangular shape (preferably, a square shape) in plan view and includes at least one (in this embodiment, a plurality) of the first lower wirings 81 and at least one (in this embodiment, a plurality) of the second lower wirings 82. In the third arrangement region 105C, both the number of the first lower wirings 81 and the number of the second lower wirings 82 are arbitrary.

For example, in the third arrangement region 105C, the number of the first lower wirings 81 (the second lower wirings 82) may be not less than 1 and not more than 1000. For example, in the third arrangement region 105C, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the third arrangement region 105C, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, in the third arrangement region 105C, a difference value between the number of the first lower wirings 81 and the number of the second lower wirings 82 is 0 to 1. The number of the first lower wirings 81 (the second lower wirings 82) in the third arrangement region 105C may be substantially equal to or different from the number of the first lower wirings 81 (the second lower wirings 82) in the first arrangement region 105A (the second arrangement region 105B).

The third wiring unit U3 includes the third pad wiring 103 arranged in the third arrangement region 105C. The third pad wiring 103 has a plane area less than a plane area of the third arrangement region 105C. The third pad wiring 103 is arranged at intervals inward from a peripheral edge of the third arrangement region 105C in plan view and is formed in a polygonal shape (in this embodiment, a quadrangular shape) having four sides parallel to the peripheral edges of the chip 2 (the peripheral edges of the third arrangement region 105C). The third pad wiring 103 may be formed in a hexagonal shape, an octagonal shape, a circular shape, etc.

The third pad wiring 103 is arranged on at least one (in this embodiment, a plurality) of the first lower wirings 81 and at least one (in this embodiment, a plurality) of the second lower wirings 82. The third pad wiring 103 is electrically disconnected from both the plurality of first lower wirings 81 and the plurality of second lower wirings 82 by the second interlayer film 72. Directly below the third pad wiring 103, both the number of the first lower wirings 81 and the number of the second lower wirings 82 are arbitrary.

For example, directly below the third pad wiring 103, the number of the first lower wirings 81 (the second lower wirings 82) may be not less than 1 and not more than 1000. For example, directly below the third pad wiring 103, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

Directly below the third pad wiring 103, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, directly below the third pad wiring 103, a difference value between the number of the first lower wirings 81 and the number of the second lower wirings 82 is 0 to 1. The number of the first lower wirings 81 (the second lower wirings 82) directly below the third pad wiring 103 may be substantially equal to or different from the number of the first lower wirings 81 (the second lower wirings 82) directly below the first pad wiring 101 (the second pad wiring 102).

In this embodiment, the third pad wiring 103 has a plane area smaller than the plane area of the first pad wiring 101. The plane area of the third pad wiring 103 is smaller than the plane area of the second pad wiring 102. Consequently, the number of the first lower wirings 81 and the number of the second lower wirings 82 hidden by the third pad wiring 103 are reduced as compared with the first pad wiring 101 (the second pad wiring 102).

The third wiring unit U3 includes a first finger wiring 142 led out from the third pad wiring 103 onto the outer region 7. The first finger wiring 142 is constituted of a lead-out portion of the third pad wiring 103. The first finger wiring 142 is led out from the third pad wiring 103 onto the third lower wirings 83 and is electrically connected to the third lower wiring 83.

In this embodiment, the first finger wiring 142 includes a first portion 142a and a second portion 142b. The first portion 142a is led out as a band in the first direction X from the third pad wiring 103 toward the third lower wiring 83. In the second direction Y, the first portion 142a has a width less than the width of the third pad wiring 103. As a matter of course, the first portion 142a may have a width substantially equal to the width of the third pad wiring 103.

The second portion 142b is led out from the first portion 142a onto the third lower wiring 83 and extends as a band along the third lower wiring 83. In a case where the first portion 142a has a width substantially equal to the width of the third pad wiring 103, the second portion 142b may have a width substantially equal to the width of the third pad wiring 103. In this case, the first finger wiring 142 can be regarded as being formed from an end portion of the third pad wiring 103. The second portion 142b is electrically connected to the third lower wiring 83.

The third wiring unit U3 includes at least one (in this embodiment, a plurality) of the third upper via electrodes 144. Similarly to the first upper via electrode 117, etc., each of the plurality of third upper via electrodes 144 includes the first electrode 119 and the second electrode 120. The description of the first electrode 119 and the second electrode 120 related to the first upper via electrode 117 is applied to the description of the first electrode 119 and the second electrode 120 related to the third upper via electrodes 144.

The plurality of third upper via electrodes 144 are interposed between the third lower wiring 83 and the first finger wiring 142 (the second portion 142b) in the second interlayer film 72 and electrically connect the first finger wiring 142 to the third lower wiring 83. Consequently, the third pad wiring 103 is electrically connected to the plurality of gate structures 12 via the first finger wiring 142 and the third lower wiring 83.

The plurality of third upper via electrodes 144 are arrayed at intervals along the third lower wiring 83. The third upper via electrodes 144 may be formed in a triangular shape, a quadrangular shape, a rectangular shape, a polygonal shape, a circular shape, or an elliptical shape in plan view. As a matter of course, the third upper via electrodes 144 may be formed as bands extending along the third lower wiring 83.

The third upper via electrodes 144 may be formed using the first finger wiring 142 (the second portion 142b). In this case, the first electrode 119 of the third upper via electrodes 144 is integrally formed with the first electrode 78 of the first finger wiring 142 and forms one electrode film together with the first electrode 78. Similarly, the second electrode 120 of the third upper via electrodes 144 is integrally formed with the second electrode 79 of the first finger wiring 142 and forms one electrode together with the second electrode 79.

The third wiring unit U3 includes the third routing wiring 145 routed from the first pad wiring 101 to the third arrangement region 105C. The third routing wiring 145 transmits, to the third arrangement region 105C, the first drain source potential applied to the first pad wiring 101. The third routing wiring 145 includes the at least one (in this embodiment, one) third stem wiring 146 and the at least one (in this embodiment, one) third branch wiring 147.

The third stem wiring 146 has a width less than the width of the first pad wiring 101 (the second pad wiring 102) in the first direction X and is led out as a band on the one side in the second direction Y from the first end portion of the first pad wiring 101 toward the third arrangement region 105C. The width of the third stem wiring 146 is larger than the width of the first lower wiring 81 (the second lower wiring 82). In this embodiment, the third stem wiring 146 intersects (is orthogonal to) at least one (in this embodiment, a plurality) of the first lower wirings 81 and at least one (in this embodiment, a plurality) of the second lower wirings 82 in the third arrangement region 105C.

The third stem wiring 146 is led out to a region opposing the third pad wiring 103 in the first direction X. The third stem wiring 146 opposes the entire region of the third pad wiring 103 in the first direction X. The third stem wiring 146 intersects (is orthogonal to) one or a plurality of (preferably, all of) the first lower wirings 81 and one or a plurality of (preferably, all of) the second lower wirings 82 passing directly below the third pad wiring 103 in the first direction X.

In this embodiment, the third stem wiring 146 crosses a boundary portion between the second arrangement region 105B and the third arrangement region 105C and is connected to the first long wiring 110 (the first opposing portion 112) of the first wiring unit U1 (the first interconnect structure 108) in the second arrangement region 105B. The third stem wiring 146 may have a width substantially equal to the width of the first long wiring 110. The width of the third stem wiring 146 may be larger than the width of the first long wiring 110. The width of the third stem wiring 146 may be less than the width of the first long wiring 110.

The third stem wiring 146 is electrically connected to at least one (in this embodiment, a plurality) of the first lower wirings 81. Similarly to the first long wiring 110, etc., the third stem wiring 146 is electrically connected to the corresponding first lower wirings 81 via the plurality of first upper via electrodes 117.

The third stem wiring 146 is electrically connected to, of one or a plurality of (preferably, all of) the first lower wirings 81 covered with the third pad wiring 103, portions of the first lower wirings 81 exposed from the third pad wiring 103. On the other hand, the third stem wiring 146 is electrically disconnected from one or a plurality of (preferably, all of) the second lower wirings 82 passing directly below the third pad wiring 103.

Although not specifically shown, the third stem wiring 146 is electrically connected to, of one or a plurality of (preferably, all of) the first lower wirings 81 covered with the second stem wiring 135 (the second wiring unit U2) opposing (closely opposing) the third stem wiring 146 in the first direction X, portions of the first lower wirings 81 exposed from the second stem wiring 135.

On the other hand, the third stem wiring 146 is electrically disconnected from one or a plurality of (preferably, all of) the second lower wirings 82 passing directly below the second stem wiring 135. Consequently, the third stem wiring 146 forms a current path of the drain source current Ids together with the second stem wiring 135.

The third branch wiring 147 is led out as a band in the first direction X from the third stem wiring 146 to a region between the second pad wiring 102 and the third pad wiring 103 in the third arrangement region 105C. The third branch wiring 147 is formed at intervals in the second direction Y from the second pad wiring 102 and the third pad wiring 103 and opposes the second pad wiring 102 and the third pad wiring 103 in the second direction Y.

The third branch wiring 147 may have a width substantially equal to the width of the third stem wiring 146. The width of the third branch wiring 147 may be larger than the width of the third stem wiring 146. The width of the third branch wiring 147 may be less than the width of the third stem wiring 146. The width of the third branch wiring 147 is larger than the width of the first lower wiring 81 (the second lower wiring 82).

The third branch wiring 147 covers at least one (in this embodiment, a plurality) of the first lower wirings 81 and at least one (in this embodiment, a plurality) of the second lower wirings 82. The third branch wiring 147 is electrically connected to at least one (in this embodiment, a plurality) of the first lower wirings 81. Similarly to the first pad wiring 101, etc., the third branch wiring 147 is electrically connected to the corresponding first lower wirings 81 via the plurality of first upper via electrodes 117.

The third wiring unit U3 includes the fourth routing wiring 148 routed from the second pad wiring 102 to the third arrangement region 105C. The fourth routing wiring 148 transmits, to the third arrangement region 105C, the second drain source potential applied to the second pad wiring 102. The fourth routing wiring 148 includes at least one (in this embodiment, one) fourth stem wiring 149 and at least one (in this embodiment, one) fourth branch wiring 150.

The fourth stem wiring 149 has a width less than the width of the second pad wiring 102 (the first pad wiring 101) in the first direction X and is led out as a band on the other side in the second direction Y from the second end portion of the second pad wiring 102 toward the third arrangement region 105C. The width of the fourth stem wiring 149 is larger than the width of the second lower wiring 82 (the first lower wiring 81). In this embodiment, the fourth stem wiring 149 intersects (is orthogonal to) at least one (in this embodiment, a plurality) of the first lower wirings 81 and at least one (in this embodiment, a plurality) of the second lower wirings 82 in the third arrangement region 105C.

The fourth stem wiring 149 is formed at intervals in the first direction X from the third branch wiring 147 and opposes the third branch wiring 147 in the first direction X. The fourth stem wiring 149 is led out to the region opposing the third pad wiring 103 in the first direction X. The fourth stem wiring 149 opposes the third stem wiring 146 in the first direction X across the third pad wiring 103 and extends substantially parallel to the third stem wiring 146.

The fourth stem wiring 149 intersects (is orthogonal to) one or a plurality of the first lower wirings 81 and one or a plurality of the second lower wirings 82 passing directly below the third pad wiring 103 in the first direction X. In this embodiment, the fourth stem wiring 149 crosses a boundary portion between the first arrangement region 105A and the third arrangement region 105C and is connected to the second long wiring 114 (the second opposing portion 116) of the first wiring unit U1 (the first interconnect structure 108) in the first arrangement region 105A.

To be precise, the fourth stem wiring 149 has a pair of open ends 151 through which the first finger wiring 142 passes, and is divided into two portions in the second direction Y by the first finger wiring 142 (the open ends 151) extending in the first direction X. A portion of the fourth stem wiring 149 on the one side in the second direction Y is connected to the second pad wiring 102 on the one side in the second direction Y. A portion of the fourth stem wiring 149 on the other side in the second direction Y is connected to the second long wiring 114 on the other side in the second direction Y.

The fourth stem wiring 149 may have a width substantially equal to the width of the second long wiring 114. The width of the fourth stem wiring 149 may be larger than the width of the second long wiring 114. The width of the fourth stem wiring 149 may be less than the width of the second long wiring 114. It is preferable that the width of the fourth stem wiring 149 is substantially equal to the width of the third stem wiring 146.

The fourth stem wiring 149 is electrically connected to at least one (in this embodiment, a plurality) of the second lower wirings 82. Similarly to the second long wiring 114, etc., the fourth stem wiring 149 is electrically connected to the corresponding second lower wirings 82 via the plurality of second upper via electrodes 118.

The fourth stem wiring 149 is electrically connected to, of one or a plurality of (preferably, all of) the second lower wirings 82 covered with the third branch wiring 147, portions of the second lower wirings 82 exposed from the third branch wiring 147. On the other hand, the fourth stem wiring 149 is electrically disconnected from one or a plurality of (preferably, all of) the first lower wirings 81 passing directly below the third branch wiring 147. The fourth stem wiring 149 forms a current path of the drain source current Ids together with the third branch wiring 147 opposing (closely opposing) the fourth stem wiring in the first direction X.

The fourth stem wiring 149 is electrically connected to, of one or a plurality of (preferably, all of) the second lower wirings 82 covered with the third pad wiring 103, portions of the second lower wirings 82 exposed from the third pad wiring 103. On the other hand, the fourth stem wiring 149 is electrically disconnected from one or a plurality of (preferably, all of) the first lower wirings 81 passing directly below the third pad wiring 103.

Consequently, the fourth stem wiring 149 forms a current path of the drain source current Ids together with the third stem wiring 146 opposing the fourth stem wiring in the first direction X across the third pad wiring 103. That is, in this configuration, the drain source current Ids is input and output via at least one (in this embodiment, a plurality) of the first lower wirings 81 and at least one (in this embodiment, a plurality) of the second lower wirings 82 positioned directly below the third pad wiring 103.

The fourth branch wiring 150 is led out as a band in the first direction X from the fourth stem wiring 149 to a region between the first pad wiring 101 and the third pad wiring 103 in the third arrangement region 105C. The fourth branch wiring 150 is formed at intervals in the second direction Y from the first pad wiring 101 and the third pad wiring 103 and opposes the first pad wiring 101 and the third pad wiring 103 in the second direction Y.

The fourth branch wiring 150 may have a width substantially equal to the width of the fourth stem wiring 149. The width of the fourth branch wiring 150 may be larger than the width of the fourth stem wiring 149. The width of the fourth branch wiring 150 may be less than the width of the fourth stem wiring 149. It is preferable that the width of the fourth branch wiring 150 is substantially equal to the width of the third stem wiring 146. The width of the fourth branch wiring 150 is larger than the width of the second lower wiring 82 (the first lower wiring 81).

The fourth branch wiring 150 covers at least one (in this embodiment, a plurality) of the first lower wirings 81 and at least one (in this embodiment, a plurality) of the second lower wirings 82. The fourth branch wiring 150 is formed at intervals in the first direction X from the third stem wiring 146 and opposes the third stem wiring 146 in the first direction X. It is preferable that, in the first direction X, a length of the fourth branch wiring 150 is substantially equal to the length of the third branch wiring 147.

The fourth branch wiring 150 is electrically connected to at least one (in this embodiment, a plurality) of the second lower wirings 82. Similarly to the second pad wiring 102, etc., the fourth branch wiring 150 is electrically connected to the corresponding second lower wirings 82 via the plurality of second upper via electrodes 118.

The fourth branch wiring 150 is electrically connected to, of one or a plurality of the second lower wirings 82 covered with the third stem wiring 146, portions of the second lower wirings 82 exposed from the third stem wiring 146. On the other hand, the fourth branch wiring 150 is electrically disconnected from one or a plurality of (preferably, all of) the first lower wirings 81 passing directly below the third stem wiring 146. The fourth branch wiring 150 forms a current path of the drain source current Ids together with the third stem wiring 146 opposing (closely opposing) the fourth branch wiring 150 in the first direction X.

The third wiring unit U3 includes the fifth interconnect structure 152 formed in a region between the second pad wiring 102 and the third branch wiring 147. The fifth interconnect structure 152 has the same configuration and function as those of the first interconnect structure 108 except that an arrangement location differs. Similarly to the first interconnect structure 108, the fifth interconnect structure 152 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the third stem wiring 146 as at least one (in this embodiment, one) of the first long wirings 110 that are relatively long and at least one (in this embodiment, a plurality) of the first short wirings 111 that are shorter than the third stem wiring 146. The plurality of first lead-out wirings 109 are led out in the second direction Y from the third branch wiring 147 toward the second pad wiring 102 and are electrically connected to at least one of the first lower wirings 81 in the region between the second pad wiring 102 and the third branch wiring 147.

Similarly to the first interconnect structure 108, the plurality of second lead-out wirings 113 include the fourth stem wiring 149 as at least one (in this embodiment, one) of the second long wirings 114 that are relatively long and at least one (in this embodiment, a plurality) of the second short wirings 115 that are shorter than the fourth stem wiring 149. The plurality of second lead-out wirings 113 are led out in the second direction Y from the second pad wiring 102 toward the third branch wiring 147 and are electrically connected to at least one of the second lower wiring 82 in the region between the second pad wiring 102 and the third branch wiring 147.

As described above, in the fifth interconnect structure 152, a current path of the drain source current Ids via the plurality of first lead-out wirings 109 and the plurality of second lead-out wirings 113 is formed in the region between the second pad wiring 102 and the third branch wiring 147.

The fifth interconnect structure 152 may have a configuration similar to any one of the first interconnect structures 108 according to the first to eighth layout examples. In this case, a specific configuration of the fifth interconnect structure 152 is obtained by replacing the “first pad wiring 101” with the “third branch wiring 147” in the description of the first interconnect structure 108 described above.

The third wiring unit U3 includes the sixth interconnect structure 153 formed in the region between the first pad wiring 101 and the fourth branch wiring 150. The sixth interconnect structure 153 has the same configuration and function as those of the first interconnect structure 108 except that an arrangement location differs. Similarly to the first interconnect structure 108, the sixth interconnect structure 153 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the third stem wiring 146 as at least one (in this embodiment, one) of the first long wirings 110 that are relatively long and at least one (in this embodiment, a plurality) of the first short wirings 111 that are shorter than the third stem wiring 146. The plurality of first lead-out wirings 109 are led out in the second direction Y from the first pad wiring 101 toward the fourth branch wiring 150 and are electrically connected to at least one of the first lower wirings 81 in the region between the first pad wiring 101 and the fourth branch wiring 150.

Similarly to the first interconnect structure 108, the plurality of second lead-out wirings 113 include the fourth stem wiring 149 as at least one (in this embodiment, one) of the second long wirings 114 that are relatively long and at least one (in this embodiment, a plurality) of the second short wirings 115 that are shorter than the fourth stem wiring 149. The plurality of second lead-out wirings 113 are led out in the second direction Y from the fourth branch wiring 150 toward the first pad wiring 101 and are electrically connected to at least one of the second lower wirings 82 in the region between the first pad wiring 101 and the fourth branch wiring 150.

As described above, in the sixth interconnect structure 153, a current path of the drain source current Ids via the plurality of first lead-out wirings 109 and the plurality of second lead-out wirings 113 is formed in the region between the first pad wiring 101 and the fourth branch wiring 150.

The sixth interconnect structure 153 may have a configuration similar to any one of the first interconnect structures 108 according to the first to eighth layout examples. In this case, a specific configuration of the sixth interconnect structure 153 is obtained by replacing the “second pad wiring 102” with the “fourth branch wiring 150” in the description of the first interconnect structure 108 described above.

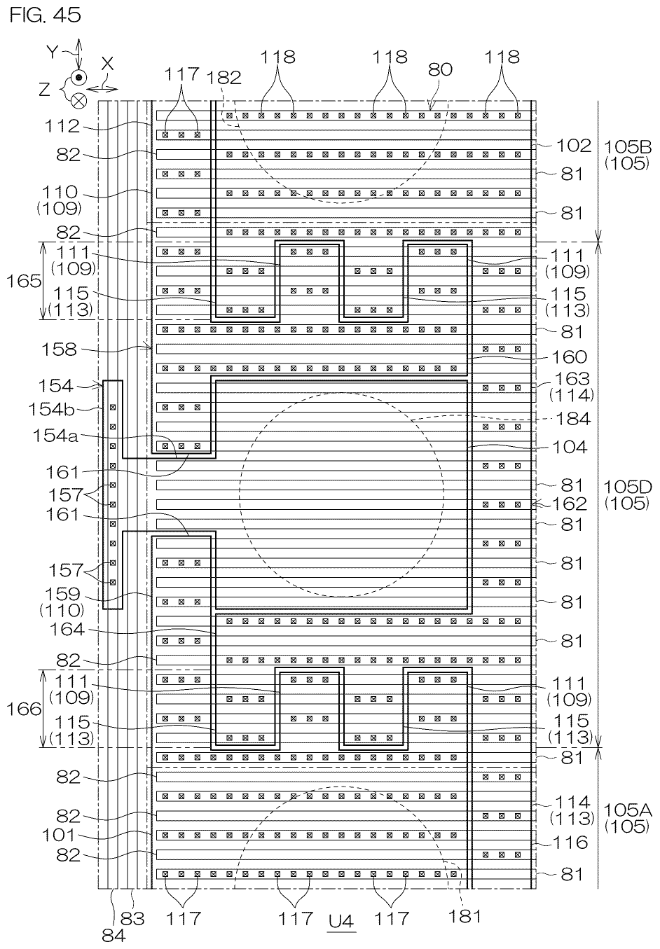

FIG. 45 is an enlarged plan view showing an example of the fourth wiring unit U4. The fourth wiring unit U4 includes the first arrangement region 105A (the first pad wiring 101), the second arrangement region 105B (the second pad wiring 102), and the arrangement region 105 for the fourth pad wiring 104. Hereinafter, the arrangement region 105 for the fourth pad wiring 104 is referred to as the “fourth arrangement region 105D.”

The fourth arrangement region 105D is interposed between the two first wiring units U1 adjacent in the second direction Y and opposes the second wiring unit U2 (the space region 106) in the first direction X. That is, the fourth arrangement region 105D is interposed between the first arrangement region 105A (the first pad wiring 101) and the second arrangement region 105B (the second pad wiring 102). The fourth arrangement region 105D is adjacent to the second arrangement region 105B on the one side in the second direction Y and is adjacent to the first arrangement region 105A on the other side in the second direction Y.

The fourth arrangement region 105D is set in a quadrangular shape (preferably, a square shape) in plan view and includes at least one (in this embodiment, a plurality) of the first lower wirings 81 and at least one (in this embodiment, a plurality) of the second lower wirings 82. In the fourth arrangement region 105D, the number of the first lower wirings 81 and the number of the second lower wirings 82 are arbitrary.

For example, in the fourth arrangement region 105D, the number of the first lower wirings 81 (the second lower wirings 82) may be not less than 1 and not more than 1000. For example, in the fourth arrangement region 105D, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

In the fourth arrangement region 105D, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, in the fourth arrangement region 105D, a difference value between the number of the first lower wirings 81 and the number of the second lower wirings 82 is 0 to 1.

The number of the first lower wirings 81 (the second lower wirings 82) in the fourth arrangement region 105D may be substantially equal to or different from the number of the first lower wirings 81 (the second lower wirings 82) in the first arrangement region 105A (the second arrangement region 105B). The number of the first lower wirings 81 (the second lower wirings 82) in the fourth arrangement region 105D may be substantially equal to or different from the number of the first lower wirings 81 (the second lower wirings 82) in the third arrangement region 105C.

The fourth wiring unit U4 includes the fourth pad wiring 104 arranged in the fourth arrangement region 105D. The fourth pad wiring 104 has a plane area less than the plane area of the fourth arrangement region 105D. The fourth pad wiring 104 is arranged at intervals inward from peripheral edges of the fourth arrangement region 105D in plan view and is formed in a polygonal shape (in this embodiment, a quadrangular shape) having four sides parallel to the peripheral edges of the chip 2 (the peripheral edges of the fourth arrangement region 105D). The fourth pad wiring 104 may be formed in a hexagonal shape, an octagonal shape, a circular shape, etc.

The fourth pad wiring 104 is arranged on at least one (in this embodiment, a plurality) of the first lower wirings 81 and at least one (in this embodiment, a plurality) of the second lower wirings 82. The fourth pad wiring 104 is electrically disconnected from both the plurality of first lower wirings 81 and the plurality of second lower wirings 82 by the second interlayer film 72. The fourth pad wiring 104 opposes the third pad wiring 103 in the first direction X. The fourth pad wiring 104 partially hides, on the one side in first direction X, at least one (in this embodiment, a plurality) of the first lower wiring 81 and at least one (in this embodiment, a plurality) of the second lower wiring 82 partially hidden by the third pad wiring 103. Directly below the fourth pad wiring 104, both the number of the first lower wirings 81 and the number of the second lower wirings 82 are arbitrary.

For example, directly below the fourth pad wiring 104, the number of the first lower wirings 81 (the second lower wirings 82) may be not less than 1 and not more than 1000. For example, directly below the fourth pad wiring 104, the number of the first lower wirings 81 (the second lower wirings 82) may be set to a value falling within at least one of ranges of not less than 1 and not more than 50, not less than 50 and not more than 100, not less than 100 and not more than 250, not less than 250 and not more than 500, not less than 500 and not more than 750, and not less than 750 and not more than 1000.

Directly below the fourth pad wiring 104, it is preferable that the number of the second lower wirings 82 is substantially equal to the number of the first lower wirings 81. In this embodiment, the plurality of second lower wirings 82 and the plurality of first lower wirings 81 are alternately arrayed. Therefore, directly below the fourth pad wiring 104, a difference value between the number of the first lower wirings 81 and the number of the second lower wirings 82 is 0 to 1.

The number of the first lower wirings 81 (the second lower wirings 82) directly below the fourth pad wiring 104 may be substantially equal to or different from the number of the first lower wirings 81 (the second lower wirings 82) directly below the first pad wiring 101 (the second pad wiring 102). The number of the first lower wirings 81 (the second lower wirings 82) directly below the fourth pad wiring 104 may be substantially equal to or different from the number of the first lower wirings 81 (the second lower wirings 82) directly below the third pad wiring 103.

In this embodiment, the fourth pad wiring 104 has a plane area smaller than the plane area of the first pad wiring 101. The plane area of the fourth pad wiring 104 is smaller than the plane area of the second pad wiring 102. Consequently, the number of the first lower wirings 81 and the number of the second lower wirings 82 hidden by the fourth pad wiring 104 are reduced as compared with the first pad wiring 101 (the second pad wiring 102). The plane area of the fourth pad wiring 104 may be substantially equal to or different from the plane area of the third pad wiring 103.

The fourth wiring unit U4 includes a second finger wiring 154 led out from the fourth pad wiring 104 onto the outer region 7. The second finger wiring 154 is constituted of a lead-out portion of the fourth pad wiring 104. The second finger wiring 154 is led out from the fourth pad wiring 104 onto the fourth lower wirings 84 and is electrically connected to the fourth lower wiring 84.

In this embodiment, the second finger wiring 154 includes a first portion 154a and a second portion 154b. The first portion 154a is led out as a band in the first direction X from the fourth pad wiring 104 toward the fourth lower wiring 84. The first portion 154a three-dimensionally intersects the third lower wiring 83 and is led out onto the fourth lower wiring 84. In the second direction Y, the first portion 154a has a width less than the width of the fourth pad wiring 104. As a matter of course, the first portion 154a may have a width substantially equal to the width of the fourth pad wiring 104.

The second portion 154b is led out from the first portion 154a onto the fourth lower wiring 84 and extends as a band along the fourth lower wiring 84. In a case where the first portion 154a has a width substantially equal to the width of the fourth pad wiring 104, the second portion 154b may have a width substantially equal to the width of the fourth pad wiring 104. In this case, the second finger wiring 154 can be regarded as being formed from an end portion of the fourth pad wiring 104. The second portion 154b is electrically connected to the fourth lower wiring 84.

The fourth wiring unit U4 includes at least one (in this embodiment, a plurality) of the fourth upper via electrodes 157. Similarly to the first upper via electrode 117, each of the plurality of fourth upper via electrodes 157 includes the first electrode 119 and the second electrode 120. The description of the first electrode 119 and the second electrode 120 related to the first upper via electrode 117 is applied to the description of the first electrode 119 and the second electrode 120 related to the fourth upper via electrodes 157.

The plurality of fourth upper via electrodes 157 are interposed between the fourth lower wiring 84 and the second finger wiring 154 (the second portion 154b) in the second interlayer film 72 and electrically connect the second finger wiring 154 to the fourth lower wiring 84. Consequently, the fourth pad wiring 104 is electrically connected to the base structure 55 via the second finger wiring 154 and the fourth lower wiring 84.

The plurality of fourth upper via electrodes 157 are arrayed at intervals along the fourth lower wiring 84. The fourth upper via electrode 157 may be formed in a triangular shape, a quadrangular shape, a rectangular shape, a polygonal shape, a circular shape, or an elliptical shape in plan view. As a matter of course, the fourth upper via electrodes 157 may be formed as bands extending along the fourth lower wiring 84.

The fourth upper via electrodes 157 may be formed using the second finger wiring 154 (the second portion 154b). In this case, the first electrode 119 of the fourth upper via electrodes 157 is integrally formed with the first electrode 78 of the second finger wiring 154 and forms one electrode film together with the first electrode 78. Similarly, the second electrode 120 of the fourth upper via electrodes 157 is integrally formed with the second electrode 79 of the second finger wiring 154 and forms one electrode together with the second electrode 79.

The fourth wiring unit U4 includes the fifth routing wiring 158 routed from the first pad wiring 101 to the fourth arrangement region 105D. The fifth routing wiring 158 transmits, to the fourth arrangement region 105D, the first drain source potential applied to the first pad wiring 101. The fifth routing wiring 158 includes at least one (in this embodiment, one) fifth stem wiring 159 and at least one (in this embodiment, one) fifth branch wiring 160.

The fifth stem wiring 159 has a width less than the width of the first pad wiring 101 (the second pad wiring 102) in the first direction X and is led out as a band on the one side in the second direction Y from the first end portion of the first pad wiring 101 toward the fourth arrangement region 105D. The width of the fifth stem wiring 159 is larger than the width of the first lower wiring 81 (the second lower wiring 82). In this embodiment, the fifth stem wiring 159 intersects (is orthogonal to) at least one (in this embodiment, a plurality) of the first lower wirings 81 and at least one (in this embodiment, a plurality) of the second lower wirings 82 in the fourth arrangement region 105D.

The fifth stem wiring 159 is led out to a region opposing the fourth pad wiring 104 in the first direction X. The fifth stem wiring 159 intersects (is orthogonal to) one or a plurality of the first lower wirings 81 and one or a plurality of the second lower wirings 82 passing directly below the fourth pad wiring 104 in the first direction X. In this embodiment, the fifth stem wiring 159 crosses a boundary portion between the first arrangement region 105A and the fourth arrangement region 105D and is connected to the first long wiring 110 (the first opposing portion 112) of the first wiring unit U1 (the first interconnect structure 108) in the first arrangement region 105A.

To be precise, the fifth stem wiring 159 has a pair of open ends 161 through which the second finger wiring 154 passes, and is divided into two portions in the second direction Y by the second finger wiring 154 (the open ends 161) extending in the first direction X. A portion of the fifth stem wiring 159 on the one side in the second direction Y is connected to the first long wiring 110 on the one side in the second direction Y. A portion of the fifth stem wiring 159 on the other side in the second direction Y is connected to the first pad wiring 101 on the other side in the second direction Y.

The fifth stem wiring 159 may have a width substantially equal to the width of the first long wiring 110. The width of the fifth stem wiring 159 may be larger than the width of the first long wiring 110. The width of the fifth stem wiring 159 may be less than the width of the first long wiring 110.

The fifth stem wiring 159 is electrically connected to at least one (in this embodiment, a plurality) of the first lower wirings 81. Similarly to the first long wiring 110, etc., the fifth stem wiring 159 is electrically connected to the corresponding first lower wirings 81 via the plurality of first upper via electrodes 117.

The fifth stem wiring 159 is electrically connected to, of one or a plurality of (preferably, all of) the first lower wirings 81 covered with the fourth pad wiring 104, portions of the first lower wirings 81 exposed from the fourth pad wiring 104. On the other hand, the fifth stem wiring 159 is electrically disconnected from one or a plurality of (preferably, all of) the second lower wirings 82 passing directly below the fourth pad wiring 104.

The fifth branch wiring 160 is led out as a band in the first direction X from the fifth stem wiring 159 to a region between the second pad wiring 102 and the fourth pad wiring 104 in the fourth arrangement region 105D. The fifth branch wiring 160 is formed at intervals in the second direction Y from the second pad wiring 102 and the fourth pad wiring 104 and opposes the second pad wiring 102 and the fourth pad wiring 104 in the second direction Y.

The fifth branch wiring 160 may have a width substantially equal to the width of the fifth stem wiring 159. The width of the fifth branch wiring 160 may be larger than the width of the fifth stem wiring 159. The width of the fifth branch wiring 160 may be less than the width of the fifth stem wiring 159. The width of the fifth branch wiring 160 is larger than the width of the first lower wiring 81 (the second lower wiring 82).

The fifth branch wiring 160 covers at least one (in this embodiment, a plurality) of the first lower wirings 81 and at least one (in this embodiment, a plurality) of the second lower wirings 82. The fifth branch wiring 160 is electrically connected to at least one (in this embodiment, a plurality) of the first lower wirings 81. Similarly to the first pad wiring 101, etc., the fifth branch wiring 160 is electrically connected to the corresponding first lower wirings 81 via the plurality of first upper via electrodes 117.

The fourth wiring unit U4 includes the sixth routing wiring 162 routed from the second pad wiring 102 to the fourth arrangement region 105D. The sixth routing wiring 162 transmits, to the fourth arrangement region 105D, the second drain source potential applied to the second pad wiring 102. The sixth routing wiring 162 includes at least one (in this embodiment, one) sixth stem wiring 163 and at least one (in this embodiment, one) sixth branch wiring 164.

The sixth stem wiring 163 has a width less than the width of the second pad wiring 102 (the first pad wiring 101) in the first direction X and is led out as a band on the other side in the second direction Y from the second end portion of the second pad wiring 102 toward the fourth arrangement region 105D. The width of the sixth stem wiring 163 is larger than the width of the second lower wiring 82 (the first lower wiring 81). In this embodiment, the sixth stem wiring 163 intersects (is orthogonal to) at least one (in this embodiment, a plurality) of the first lower wirings 81 and at least one (in this embodiment, a plurality) of the second lower wirings 82 in the fourth arrangement region 105D.

The sixth stem wiring 163 is formed at intervals in the first direction X from the fifth branch wiring 160 and opposes the fifth branch wiring 160 in the first direction X. The sixth stem wiring 163 is led out to a region opposing the fourth pad wiring 104 in the first direction X. The sixth stem wiring 163 opposes the entire region of the fourth pad wiring 104 in the first direction X.

The sixth stem wiring 163 opposes the fifth stem wiring 159 in the first direction X across the fourth pad wiring 104 and extends substantially parallel to the fifth stem wiring 159. The sixth stem wiring 163 intersects (is orthogonal to) one or a plurality of (preferably, all of) the first lower wirings 81 and one or a plurality of (preferably, all of) the second lower wirings 82 passing directly below the fourth pad wiring 104 in the first direction X.

In this embodiment, the sixth stem wiring 163 crosses the boundary portion between the first arrangement region 105A and the fourth arrangement region 105D and is connected to the second long wiring 114 (the second opposing portion 116) of the first wiring unit U1 (the first interconnect structure 108) in the first arrangement region 105A.

The sixth stem wiring 163 may have a width substantially equal to the width of the second long wiring 114. The width of the sixth stem wiring 163 may be larger than the width of the second long wiring 114. The width of the sixth stem wiring 163 may be less than the width of the second long wiring 114. It is preferable that the width of the sixth stem wiring 163 is substantially equal to the width of the fifth stem wiring 159.

The sixth stem wiring 163 is electrically connected to at least one (in this embodiment, a plurality) of the second lower wirings 82 in the fourth arrangement region 105D. Similarly to the second long wiring 114, etc., the sixth stem wiring 163 is electrically connected to the corresponding second lower wirings 82 via the plurality of second upper via electrodes 118.

The sixth stem wiring 163 is electrically connected to, of one or a plurality of (preferably, all of) the second lower wirings 82 covered with the fifth branch wiring 160, portions of the second lower wirings 82 exposed from the fifth branch wiring 160. On the other hand, the sixth stem wiring 163 is electrically disconnected from one or a plurality of (preferably, all of) the first lower wirings 81 passing directly below the fifth branch wiring 160. The sixth stem wiring 163 forms a current path of the drain source current Ids together with the fifth branch wiring 160 opposing (closely opposing) the sixth stem wiring 163 in the first direction X.

The sixth stem wiring 163 is electrically connected to, of one or a plurality of (preferably, all of) the second lower wirings 82 covered with the fourth pad wiring 104, portions of the second lower wirings 82 exposed from the fourth pad wiring 104. On the other hand, the sixth stem wiring 163 is electrically disconnected from one or a plurality of (preferably, all of) the first lower wirings 81 passing directly below the fourth pad wiring 104.

Consequently, the sixth stem wiring 163 forms a current path of the drain source current Ids together with the fifth stem wiring 159 opposing the sixth stem wiring 163 in the first direction X across the fourth pad wiring 104. That is, in this configuration, the drain source current Ids is input and output via at least one (in this embodiment, a plurality) of the first lower wirings 81 and at least one (in this embodiment, a plurality) of the second lower wirings 82 positioned directly below the fifth stem wiring 159.

Although not specifically shown, the sixth stem wiring 163 is electrically connected to, of one or a plurality of (preferably, all of) the second lower wirings 82 covered with the first stem wiring 132 (the second wiring unit U2) opposing (closely opposing) the sixth stem wiring in the first direction X, portions of the second lower wirings 82 exposed from the first stem wiring 132.

On the other hand, the sixth stem wiring 163 is electrically disconnected from one or a plurality of (preferably, all of) the first lower wirings 81 passing directly below the first stem wiring 132. Consequently, the sixth stem wiring 163 forms a current path of the drain source current Ids together with the first stem wiring 132.

The sixth branch wiring 164 is led out as a band in the first direction X from the sixth stem wiring 163 to a region between the first pad wiring 101 and the fourth pad wiring 104 in the fourth arrangement region 105D. The sixth branch wiring 164 is formed at intervals in the second direction Y from the first pad wiring 101 and the fourth pad wiring 104 and opposes the first pad wiring 101 and the fourth pad wiring 104 in the second direction Y.

The sixth branch wiring 164 may have a width substantially equal to the width of the sixth stem wiring 163. The width of the sixth branch wiring 164 may be larger than the width of the sixth stem wiring 163. The width of the sixth branch wiring 164 may be less than the width of the sixth stem wiring 163. It is preferable that the width of the sixth branch wiring 164 is substantially equal to the width of the fifth branch wiring 160. The width of the sixth branch wiring 164 is larger than the width of the second lower wiring 82 (the first lower wiring 81).

The sixth branch wiring 164 covers at least one (in this embodiment, a plurality) of the first lower wirings 81 and at least one (in this embodiment, a plurality) of the second lower wirings 82. The sixth branch wiring 164 is formed at intervals in the first direction X from the fifth stem wiring 159 and opposes the fifth stem wiring 159 in the first direction X. It is preferable that, in the first direction X, a length of the sixth branch wiring 164 is substantially equal to a length of the fifth branch wiring 160.

The sixth branch wiring 164 is electrically connected to at least one (in this embodiment, a plurality) of the second lower wirings 82. Similarly to the second pad wiring 102, etc., the sixth branch wiring 164 is electrically connected to the corresponding second lower wirings 82 via the plurality of second upper via electrodes 118.

The sixth branch wiring 164 is electrically connected to, of one or a plurality of the second lower wirings 82 covered with the fifth stem wiring 159, portions of the second lower wirings 82 exposed from the fifth stem wiring 159. On the other hand, the sixth branch wiring 164 is electrically disconnected from one or a plurality of (preferably, all of) the first lower wirings 81 passing directly below the fifth stem wiring 159. The sixth branch wiring 164 forms a current path of the drain source current Ids together with the fifth stem wiring 159 opposing (closely opposing) the sixth branch wiring 164 in the first direction X.

The fourth wiring unit U4 includes the seventh interconnect structure 165 formed in a region between the second pad wiring 102 and the fifth branch wiring 160. The seventh interconnect structure 165 has the same configuration and function as those of the first interconnect structure 108 except that an arrangement location differs. Similarly to the first interconnect structure 108, the seventh interconnect structure 165 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the fifth stem wiring 159 as at least one (in this embodiment, one) of the first long wirings 110 that are relatively long and at least one (in this embodiment, a plurality) of the first short wirings 111 that are shorter than the fifth stem wiring 159. The plurality of first lead-out wirings 109 are led out in the second direction Y from the fifth branch wiring 160 toward the second pad wiring 102 and are electrically connected to at least one of the first lower wirings 81 in the region between the second pad wiring 102 and the fifth branch wiring 160.

Similarly to the first interconnect structure 108, the plurality of second lead-out wirings 113 include the sixth stem wiring 163 as at least one (in this embodiment, one) of the second long wirings 114 that are relatively long and at least one (in this embodiment, a plurality) of the second short wirings 115 that are shorter than the sixth stem wiring 163. The plurality of second lead-out wirings 113 are led out in the second direction Y from the second pad wiring 102 toward the fifth branch wiring 160 and are electrically connected to at least one of the second lower wiring 82 in the region between the second pad wiring 102 and the fifth branch wiring 160.

As described above, in the seventh interconnect structure 165, a current path of the drain source current Ids via the plurality of first lead-out wirings 109 and the plurality of second lead-out wirings 113 is formed in the region between the second pad wiring 102 and the fifth branch wiring 160.

The seventh interconnect structure 165 may have a configuration similar to any one of the first interconnect structures 108 according to the first to eighth layout examples. In this case, a specific configuration of the seventh interconnect structure 165 is obtained by replacing the “first pad wiring 101” with the “fifth branch wiring 160” in the description of the first interconnect structure 108 described above.

The fourth wiring unit U4 includes the eighth interconnect structure 166 formed in a region between the first pad wiring 101 and the sixth branch wiring 164. The eighth interconnect structure 166 has the same configuration and function as those of the first interconnect structure 108 except that an arrangement location differs. Similarly to the first interconnect structure 108, the eighth interconnect structure 166 includes at least one (in this embodiment, a plurality) of the first lead-out wirings 109 and at least one (in this embodiment, a plurality) of the second lead-out wirings 113.

Similarly to the first interconnect structure 108, the plurality of first lead-out wirings 109 include the fifth stem wiring 159 as at least one (in this embodiment, one) of the first long wirings 110 that are relatively long and at least one (in this embodiment, a plurality) of the first short wirings 111 that are shorter than the fifth stem wiring 159. The plurality of first lead-out wirings 109 are led out in the second direction Y from the first pad wiring 101 toward the sixth branch wiring 164 and are electrically connected to at least one of the first lower wirings 81 in the region between the first pad wiring 101 and the sixth branch wiring 164.

Similarly to the first interconnect structure 108, the plurality of second lead-out wirings 113 include the sixth stem wiring 163 as at least one (in this embodiment, one) of the second long wirings 114 that are relatively long and at least one (in this embodiment, a plurality) of the second short wirings 115 that are shorter than the sixth stem wiring 163. The plurality of second lead-out wirings 113 are led out in the second direction Y from the sixth branch wiring 164 toward the first pad wiring 101 and are electrically connected to at least one of the second lower wirings 82 in the region between the first pad wiring 101 and the sixth branch wiring 164.

As described above, in the eighth interconnect structure 166, a current path of the drain source current Ids via the plurality of first lead-out wirings 109 and the plurality of second lead-out wirings 113 is formed in the region between the first pad wiring 101 and the sixth branch wiring 164.

The eighth interconnect structure 166 may have a configuration similar to any one of the first interconnect structures 108 according to the first to eighth layout examples. In this case, a specific configuration of the eighth interconnect structure 166 is obtained by replacing the “second pad wiring 102” with the “sixth branch wiring 164” in the description of the first interconnect structure 108 described above.

With reference again to FIG. 32, the semiconductor device 1D includes the upper insulation film 170 that covers the second layer wiring 75 (the first to fourth wiring units U1 to U4) on the interlayer film 70 (the second interlayer film 72). The upper insulation film 170 has the plurality of pad openings 171. The plurality of pad openings 171 selectively expose the plurality of pad wirings 101 to 104, respectively.

The upper insulation film 170 may have a single layer structure constituted of an inorganic insulation film or an organic insulation film. The upper insulation film 170 may have a laminated structure including an inorganic insulation film and an organic insulation film laminated in that order from the interlayer film 70 (the second interlayer film 72) side. The inorganic insulation film may include at least one of a silicon oxide film, a silicon nitride film, and a silicon oxynitride film. The inorganic insulation film preferably contains an insulating material different from the interlayer film 70 (the second interlayer film 72). The inorganic insulation film preferably includes the silicon nitride film.

The organic insulation film may include a negative type or positive type of photosensitive resin film. The organic insulation film may include at least one of a polyimide film, a polyamide film, or a polybenzoxazole film. The organic insulation film preferably has a thickness larger than a thickness of the inorganic insulation film.

With reference to FIGS. 31 and 32, the semiconductor device 1D includes the plurality of pad electrodes 181 to 184 respectively arranged on the plurality of pad wirings 101 to 104. The plurality of pad electrodes 181 to 184 are terminal electrodes that are physically and electrically connected to a wiring of a mounting substrate, etc., which is a connection target. The plurality of pad electrodes 181 to 184 may be referred to as a “pad terminals,” a “terminal electrodes,” an “external terminals,” etc. The plurality of pad electrodes 181 to 184 include the first pad electrode 181, the second pad electrode 182, the third pad electrode 183, and the fourth pad electrode 184.

The first pad electrode 181 is a terminal that applies, to the first pad wiring 101, the first drain source potential applied from the outside. The second pad electrode 182 is a terminal that applies, to the second pad wiring 102, the second drain source potential applied from the outside. The third pad electrode 183 is a terminal that applies, to third pad wiring 103, the gate potential applied from the outside. The fourth pad electrode 184 is a terminal that applies, to fourth pad wiring 104, the base potential applied from the outside.

The first pad electrode 181 may be referred to as a “first drain source pad electrode (terminal).” The second pad electrode 182 may be referred to as a “second drain source pad electrode (terminal).” The third pad electrode 183 may be referred to as a “gate pad electrode (terminal).” The fourth pad electrode 184 may be referred to as a “base pad electrode (terminal).”

The number of the first to fourth pad electrodes 181 to 184 is adjusted depending on the number of the first to fourth pad wirings 101 to 104. In this embodiment, the semiconductor device 1D includes the ten first pad electrodes 181, the ten second pad electrodes 182, the one third pad electrode 183, and the one fourth pad electrode 184.

The plurality of first pad electrodes 181 are respectively arranged on the plurality of first pad wirings 101, the plurality of second pad electrodes 182 are respectively arranged on the plurality of second pad wirings 102, the third pad electrode 183 is arranged on the third pad wiring 103, and the fourth pad electrode 184 is arranged on the fourth pad wiring 104.

Each of the plurality of pad electrodes 181 to 184 includes the single base electrode film 185 and the single low-melting-point metal 186 formed in that order from the plurality of pad wirings 101 to 104 side. The plurality of base electrode films 185 respectively cover, in a film shape, the plurality of pad wirings 101 to 104 in the corresponding pad openings 171, and are respectively electrically connected to the plurality of pad wirings 101 to 104.

Each of the plurality of base electrode films 185 has an overlapping portion led out from the corresponding pad opening 171 onto the upper insulation film 170. The plurality of base electrode films 185 may include at least one of a Ti film, a TiN film, a Cu film, an Au film, an Ni film, and an Al film.

The plurality of low-melting-point metals 186 are respectively arranged on the corresponding base electrode films 185. The plurality of low-melting-point metals 186 are respectively electrically connected to the plurality of pad wirings 101 to 104 via the corresponding base electrode films 185 in the pad openings 171. The plurality of low-melting-point metals 186 cover the overlapping portions of the corresponding base electrode films 185 outside the pad openings 171. The plurality of low-melting-point metals 186 project in a hemispherical shape. The plurality of low-melting-point metals 186 may include solder.

In the semiconductor device 1D, the first drain source potential (a high potential) is to be applied to the plurality of first pad wirings 101 (the first pad electrodes 181), the second drain source potential (a low potential) is to be applied to the plurality of second pad wirings 102 (the second pad electrodes 182), the gate potential is to be applied to the third pad wiring 103 (the third pad electrode 183), and the base potential is to be applied to the fourth pad wiring 104 (the fourth pad electrode 184).

The first drain source potential is to be applied from the plurality of first pad wirings 101 to the plurality of first drain source regions 28 via the plurality of first lower wirings 81, the second drain source potential is to be applied from the plurality of second pad wirings 102 to the plurality of second drain source regions 29 via the plurality of second lower wirings 82, the gate potential is to be applied from the third pad wiring 103 to the plurality of gate structures 12 via the third lower wiring 83, and the base potential is to be applied from the fourth pad wiring 104 to the base structure 55 via the fourth lower wiring 84.

Consequently, the plurality of gate structures 12 are controlled to an ON state, and the drain source current Ids is generated. The drain source current Ids flows from the plurality of first pad wirings 101 via the plurality of first lower wirings 81 to the plurality of first drain source regions 28. The drain source current Ids flows from the plurality of first drain source regions 28 via the drift layer 9 and the plurality of first impurity regions 51 to the plurality of second drain source regions 29. The drain source current Ids flows from the plurality of second drain source regions 29 via the plurality of second lower wirings 82 to the plurality of second pad wirings 102.

In this embodiment, an example is described, in which the first drain source potential is a high potential, and the second drain source potential is a low potential. However, the semiconductor device 1D has an electrically symmetrical configuration with respect to the first drain source potential and the second drain source potential. Therefore, the first drain source potential may be a low potential and the second drain source potential may be a high potential.

In this case, the drain source current Ids flows from the second pad wirings 102 toward the first pad wirings 101. That is, the semiconductor device 1D is a bidirectional device capable of causing the drain source current Ids to flow in both directions between the first pad wirings 101 and the second pad wirings 102.

As described above, the semiconductor device 1D includes the wiring groups 80, the first pad wirings 101, the second pad wirings 102, at least one of the first lead-out wirings 109, and at least one of the second lead-out wirings 113. Each of the wiring group 80 includes the plurality of first lower wirings 81 and the plurality of second lower wirings 82 arrayed as stripes extending in the first direction X. The first pad wiring 101 is arranged at least one of the first lower wirings 81. The second pad wiring 102 is arranged on at least one of the second lower wiring 82 at intervals from the first pad wiring 101 in the second direction Y.

The first lead-out wiring 109 is led out in the second direction Y from the first pad wiring 101 and is electrically connected to at least one of the first lower wirings 81 in the region between the first pad wiring 101 and the second pad wiring 102. The second lead-out wiring 113 is led out in the second direction Y from the second pad wiring 102 and is electrically connected to at least one of the second lower wirings 82 in the region between the first pad wiring 101 and the second pad wiring 102.

According to this configuration, the semiconductor device 1D having a novel wiring structure is provided. In the semiconductor device 1D, the first lower wiring 81 positioned on the second pad wiring 102 side with respect to the first pad wiring 101 is electrically connected to the first pad wiring 101 by the first lead-out wiring 109. Consequently, a wiring distance connecting the first lower wirings 81 on the second pad wiring 102 side to the first pad wiring 101 is shortened. As a result, the wiring resistance caused by the first lower wiring 81 on the second pad wiring 102 side is reduced.

Similarly, the second lower wiring 82 positioned on the first pad wiring 101 side with respect to the second pad wiring 102 is electrically connected to the second pad wiring 102 by the second lead-out wiring 113. Consequently, a wiring distance connecting the second lower wirings 82 on the first pad wiring 101 side to the second pad wiring 102 is shortened. As a result, the wiring resistance caused by the second lower wiring 82 on the first pad wiring 101 side is reduced.

Such a configuration is effective in reducing the ON-resistance between the first pad wiring 101 and the second pad wiring 102 in the case where a voltage is applied between the first pad wiring 101 and the second pad wiring 102 and a current is generated between the first pad wiring 101 and the second pad wiring 102.

The wiring group 80 preferably includes the plurality of first lower wirings 81 and the plurality of second lower wirings 82 alternately arrayed in the second direction Y. According to this configuration, in the wiring group 80, electrical symmetry of the plurality of first lower wirings 81 and the plurality of second lower wirings 82 is improved. Consequently, in the wiring group 80, variation in the wiring resistance between the first lower wiring 81 and the second lower wiring 82 is prevented.

It is preferable that the first pad wiring 101 is electrically connected to at least one of the first lower wirings 81. According to this configuration, the wiring distance connecting the first lower wirings 81 positioned directly below the first pad wiring 101 to the first pad wiring 101 is shortened. Therefore, the wiring resistance caused by the first lower wiring 81 directly below the first pad wiring 101 is reduced.

It is preferable that the second pad wiring 102 is electrically connected to at least one of the second lower wirings 82. According to this configuration, the wiring distance connecting the second lower wirings 82 positioned directly below the second pad wiring 102 to the second pad wiring 102 is shortened. Therefore, the wiring resistance caused by the second lower wiring 82 directly below the second pad wiring 102 is reduced.

The first pad wiring 101 may overlap at least one of the first lower wirings 81 and at least one of the second lower wirings 82. The second pad wiring 102 may overlap at least one of the first lower wirings 81 and at least one of the second lower wirings 82. The first pad wiring 101 may overlap a plurality of the first lower wirings 81 and a plurality of the second lower wirings 82. The second pad wiring 102 may overlap a plurality of the first lower wirings 81 and a plurality of the second lower wirings 82.

It is preferable that at least one of the first lead-out wirings 109 crosses the intermediate portion (the boundary portion 107) between the first pad wiring 101 and the second pad wiring 102. According to this configuration, the wiring distance connecting the first lower wirings 81, positioned closer to the second pad wiring 102 side than to the intermediate portion (the boundary portion 107), to the first pad wiring 101 is shortened.

It is preferable that at least one of the second lead-out wirings 113 crosses the intermediate portion (the boundary portion 107) between the first pad wiring 101 and the second pad wiring 102. According to this configuration, the wiring distance connecting the second lower wirings 82, positioned closer to first pad wiring 101 side than to the intermediate portion (the boundary portion 107), to the second pad wiring 102 is shortened.

It is preferable that at least one of the second lead-out wirings 113 opposes at least one of the first lead-out wirings 109 in the first direction X. According to this configuration, the first lead-out wirings 109 can be electrically connected to, of the first lower wirings 81 covered with the second lead-out wiring 113, portions of the first lower wirings 81 exposed from the second lead-out wiring 113. Therefore, the wiring distance connecting the first lower wirings 81 partially hidden by the second lead-out wiring 113 to the first pad wiring 101 is shortened.

Similarly, the second lead-out wiring 113 can be electrically connected to, of the second lower wirings 82 covered with the first lead-out wiring 109, portions of the second lower wirings 82 exposed from the first lead-out wiring 109. Therefore, the wiring distance connecting the second lower wirings 82 partially hidden by the first lead-out wiring 109 to the second pad wiring 102 is shortened.

Also, according to this configuration, in the case where a current is generated between the first pad wiring 101 and the second pad wiring 102, a relatively short current path via the first lower wiring 81 and the second lower wiring 82 can be formed between the first lead-out wiring 109 and the second lead-out wiring 113. Such a configuration is effective in reducing the ON-resistance.

It is preferable that at least one of the first lead-out wirings 109 opposes the second pad wiring 102 in the first direction X. According to this configuration, the first lead-out wiring 109 can be electrically connected to, of the first lower wirings 81 covered with the second pad wiring 102, portions of the first lower wirings 81 exposed from the second pad wiring 102. Therefore, the wiring distance connecting the first lower wirings 81 partially hidden by the second pad wiring 102 to the first pad wiring 101 is shortened.

Also, according to this configuration, in the case where a current is generated between the first pad wiring 101 and the second pad wiring 102, a relatively short current path via the first lower wiring 81 and the second lower wiring 82 can be formed between the second pad wiring 102 and the first lead-out wiring 109. Such a configuration is effective in reducing the ON-resistance.

It is preferable that at least one of the first lead-out wirings 109 opposes the second pad wiring 102 in the second direction Y. In this configuration, the first lead-out wiring 109 may overlap at least one of the first lower wirings 81 and at least one of the second lower wirings 82 in the region between the first pad wiring 101 and the second pad wiring 102.

It is preferable that at least one of the second lead-out wirings 113 opposes the first pad wiring 101 in the first direction X. According to this configuration, the second lead-out wiring 113 can be electrically connected to, of the second lower wirings 82 covered with the first pad wiring 101, portions of the second lower wiring 82 exposed from the first pad wiring 101. Therefore, the wiring distance connecting the second lower wirings 82 partially hidden by the first pad wiring 101 to the second pad wiring 102 is shortened.

Also, according to this configuration, in the case where a current is generated between the first pad wiring 101 and the second pad wiring 102, a relatively short current path via the first lower wiring 81 and the second lower wiring 82 can be formed between the first pad wiring 101 and the second lead-out wiring 113. Such a configuration is effective in reducing the ON-resistance.

It is preferable that at least one of the second lead-out wirings 113 opposes the first pad wiring 101 in the second direction Y. In this configuration, the second lead-out wiring 113 may overlap at least one of the first lower wirings 81 and at least one of the second lower wirings 82 in the region between the first pad wiring 101 and the second pad wiring 102.

It is preferable that the plurality of first lead-out wirings 109 are led out from the first pad wiring 101. According to this configuration, the wiring distance connecting the first lower wirings 81 on the second pad wiring 102 side to the first pad wiring 101 is shortened by the plurality of first lead-out wirings 109.

It is preferable that the plurality of second lead-out wirings 113 are led out from the second pad wiring 102. According to this configuration, the wiring distance connecting the second lower wirings 82 on the first pad wiring 101 side to the second pad wiring 102 is shortened by the plurality of second lead-out wirings 113.

In this case, it is preferable that the plurality of second lead-out wirings 113 and the plurality of first lead-out wirings 109 are alternately arrayed in the first direction X. According to this configuration, both the wiring distance connecting the first lower wirings 81 on the second pad wiring 102 side to the first pad wiring 101, and the wiring distance connecting the second lower wirings 82 on the first pad wiring 101 side to the second pad wiring 102 are efficiently shortened. Also, according to this configuration, a relatively short current path via the first lower wirings 81 and the second lower wirings 82 can be formed between the plurality of first lead-out wirings 109 and the plurality of second lead-out wirings 113. Such a configuration is effective in reducing the ON-resistance.

The semiconductor device 1D preferably includes the first interlayer film 71 and the second interlayer film 72 laminated on the first interlayer film 71. In this case, it is preferable that the plurality of first lower wirings 81 and the plurality of second lower wirings 82 are arranged on the first interlayer film 71, and the first pad wiring 101, the second pad wiring 102, the first lead-out wirings 109, and the second lead-out wirings 113 are arranged on the second interlayer film 72.

According to this configuration, the first lower wirings 81, the second lower wirings 82, the first pad wiring 101, the second pad wiring 102, the first lead-out wirings 109, and the second lead-out wirings 113 can be appropriately arrayed in a three-dimensionally intersection arrangement by using the first interlayer film 71 and the second interlayer film 72.

The semiconductor device 1D preferably includes the first pad electrodes 181 arranged on the first pad wirings 101 and the second pad electrodes 182 arranged on the second pad wirings 102. According to this configuration, the wiring distance connecting the first lower wirings 81 on the second pad wirings 102 side to the first pad electrode 181 is shortened, and the wiring distance connecting the second lower wirings 82 on the first pad wirings 101 side to the second pad electrode 182 is shortened.

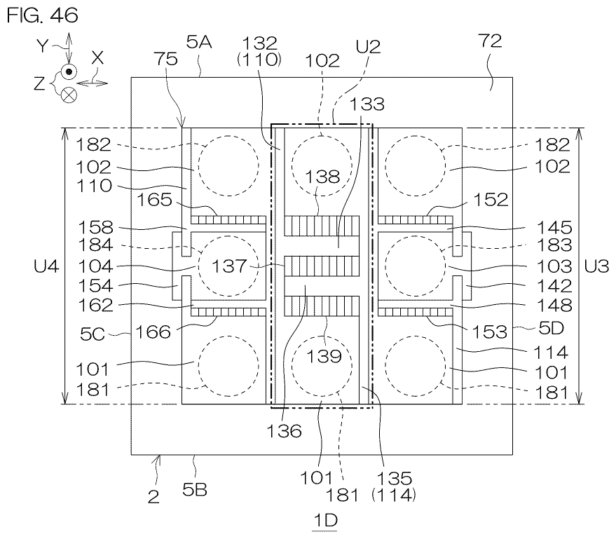

Hereinafter, modification examples of the semiconductor device 1D will be described. FIG. 46 is a plan view showing a modification example of the semiconductor device 1D according to the fourth embodiment. In FIG. 46, the plurality of arrangement regions 105 are set in a 3×3 matrix. The three first arrangement regions 105A are set on the first row, the three second arrangement regions 105B are set on the third row, the single third arrangement region 105C is set on the third column of the second row, the single fourth arrangement region 105D is set on the first column of the second row, and the single space region 106 is set on the second column of the second row.

The semiconductor device 1D (the second layer wiring 75) according to the modification example includes the single second wiring unit U2, the single third wiring unit U3, and the single fourth wiring unit U4, and does not include the first wiring unit U1. That is, the semiconductor device 1D only needs to include at least one of the first to fourth wiring units U1 to U4 and does not necessarily include all of the first to fourth wiring units U1 to U4 at the same time.

For example, the semiconductor device 1D may include only at least one of the first to fourth wiring units U1 to U4. For example, the semiconductor device 1D may include only at least two of the first to fourth wiring units U1 to U4. For example, the semiconductor device 1D may include only at least three of the first to fourth wiring units U1 to U4.

The layouts of the first to fourth wiring units U1 to U4 can be selected depending to a market demand such as a size of the chip 2 or a wiring layout of a connection target. For example, the layout of the first wiring unit U1 and the layout of the second wiring unit U2 may be applied to a two-terminal device. For example, the layout of the third wiring unit U3 and the layout of the fourth wiring unit U4 can be applied to a three-terminal device.

The embodiments (including the modification examples) described above can be implemented by still other embodiments. For example, in the embodiments described above, the plurality of first gate units GU1 and the plurality of second gate units GU2 may be alternately and continuously formed in the second direction Y without interposition of the unit space US. In this case, with regard to the active region 6 (individual active regions 6), the single first connection structure 21 extending in the second direction Y is connected to the first end portions of the plurality of gate structures 12, and the single second connection structure 22 extending in the second direction Y is connected to the second end portions of the plurality of gate structures 12.

In this case, the plurality of second mesa portions 27 and the plurality of first mesa portions 26 are alternately defined across the corresponding single gate structure 12 in the second direction Y. That is, the plurality of second drain source regions 29 and the plurality of first drain source regions 28 are alternately formed across the corresponding single gate structure 12 in the second direction Y.

In the embodiments described above, a structure may be employed, in which the conductivity type of a semiconductor region of the “n-type” is inverted to the “p-type,” and the conductivity type of the semiconductor region of the “p-type” is inverted to the “n-type.” A configuration in this case can be obtained by replacing the “n-type” with the “p-type” at the same time as replacing the “p-type” with the “n-type” in the description provided above.

For example, in the embodiments described above, the chip 2 including a monocrystal of a wide band gap semiconductor may be employed instead of the silicon monocrystal. The wide bandgap semiconductor is a semiconductor that has a bandgap exceeding the bandgap of silicon. Examples of the monocrystal of the wide bandgap semiconductor include silicon carbide, gallium nitride, diamond, and gallium oxide.

For example, the chip 2 may be an SiC chip containing an SiC monocrystal constituted of a hexagonal crystal. In this case, the SiC chip may contain at least one of a 2H (hexagonal)-SiC monocrystal, a 4H-SiC monocrystal, and a 6H-SiC monocrystal. The SiC chip preferably contains the 4H-SiC monocrystal.

The first main surface 3 and the second main surface 4 are preferably formed with a c-plane of the SiC monocrystal. The first main surface 3 is preferably a silicon surface (a (0001) plane) of the SiC monocrystal, and the second main surface 4 is preferably a carbon surface (a (000-1) plane) of the SiC monocrystal. The chip 2 (the first main surface 3 and the second main surface 4) may have an off angle inclined at a predetermined angle in a predetermined off direction with respect to the c-plane of the SiC monocrystal. The off direction is preferably an a-axis direction of the SiC monocrystal. The off angle may exceed 0° and be not more than 10°.

It is preferable that the first direction X described above is the a-axis direction ([11-20] direction) of the SiC monocrystal, and the second direction Y described above is an m-axis direction ([1-100] direction) of the SiC monocrystal. As a matter of course, the first direction X may be the m-axis direction of the SiC monocrystal, and the second direction Y may be the a-axis direction of the SiC monocrystal.

For example, the layout of the first layer wiring 74 (the layout of the wiring group 80) or the layout of the second layer wiring 75 (the layout of the first to fourth wiring units U1 to U4) according to the embodiments described above is not limited to the wiring structure of the drain source common transistor structure Tr and can also be applied to a wiring structure of a unipolar insulated gate transistor (for example, the MISFET).

In this case, the unipolar insulated gate transistor (for example, the MISFET) includes a gate structure (the control end), a drain region (the first application end), and a source region (the second application end) and is formed in the chip 2 (the active region 6). One of the first lower wiring 81 (the first pad wiring 101) and the second lower wiring 82 (the second pad wiring 102) is formed as a “drain wiring,” and the other of the first lower wiring 81 (the first pad wiring 101) and the second lower wiring 82 (the second pad wiring 102) is formed as a “source wiring.”

For example, the layout of the first layer wiring 74 (the layout of the wiring group 80) or the layout of the second layer wiring 75 (the layout of the first to fourth wiring units U1 to U4) according to the embodiments described above can also be applied to a wiring structure of a bipolar insulated gate transistor (for example, the IGBT). The bipolar insulated gate transistor may be an RC-IGBT (reverse conducting-GBT) including the IGBT and a freewheeling diode.

In this case, the bipolar insulated gate transistor (for example, the IGBT) includes a gate structure (the control end), a drain region (the first application end), and an emitter region (the second application end) and is formed in the chip 2 (the active region 6). One of the first lower wiring 81 (the first pad wiring 101) and the second lower wiring 82 (the second pad wiring 102) is formed as a “drain wiring,” and the other of the first lower wiring 81 (the first pad wiring 101) and the second lower wiring 82 (the second pad wiring 102) is formed as an “emitter wiring.”

For example, the layout of the first layer wiring 74 (the layout of the wiring group 80) or the layout of the second layer wiring 75 (the layout of the first to fourth wiring units U1 to U4) according to the embodiments described above can also be applied to a wiring structure of a diode (a semiconductor rectifier). The diode may include at least one of a pn-junction diode, a pin-junction diode, a Zener diode, a Schottky barrier diode, and a fast recovery diode.

In this case, the diode includes an anode region (the first application end) and a cathode region (the second application end) and is formed in the chip 2 (active region 6). One of the first lower wiring 81 (the first pad wiring 101) and the second lower wiring 82 (the second pad wiring 102) is formed as an “anode wiring,” and the other of the first lower wiring 81 (the first pad wiring 101) and the second lower wiring 82 (the second pad wiring 102) is formed as a “cathode wiring.”

For example, the layout of the first layer wiring 74 (the layout of the wiring group 80) or the layout of the second layer wiring 75 (the layout of the first to fourth wiring units U1 to U4) according to the embodiments described above can also be applied to a wiring structure of a passive device. The passive device may include at least one of a resistor, a capacitor, an inductor, and a fuse.

In this case, the passive device includes the first application end on a high potential side and the second application end on a low potential side and is formed in the chip 2 (active region 6). One of the first lower wiring 81 (the first pad wiring 101) and the second lower wiring 82 (the second pad wiring 102) is formed as a “high potential wiring,” and the other of the first lower wiring 81 (the first pad wiring 101) and the second lower wiring 82 (the second pad wiring 102) is formed as a “low potential wiring.”

Hereinafter, characteristic examples extracted from this Description and the attached drawings will be described. Hereinafter, the alphanumeric characters, etc., in parentheses represent the corresponding components, etc., in the embodiments described above, but are not intended to limit the scope of each clause to the embodiments described above. The “semiconductor device” in the following clauses may be replaced with a “semiconductor switching device,” a “transistor device,” a “drain source common transistor device,” a “MISFET device,” an “IGBT device,” a “semiconductor rectifier,” a “semiconductor passive device,” a “passive device,” an “electronic component,” etc., as necessary.

[A1] A semiconductor device (1A, 1B, 1C, 1E) comprising: a wiring group (80) that includes first lower wirings (81) and second lower wirings (82) that are arrayed as stripes extending in a first direction (X); a first pad wiring (101) that is arranged over at least one of the first lower wirings (81); a second pad wiring (102) that is arranged over at least one of the second lower wirings (82) at an interval from the first pad wiring (101) in a second direction (Y) intersecting the first direction (X); at least one of first lead-out wirings (109 to 111) that is led out from the first pad wiring (101) in the second direction (Y) and is electrically connected to at least one of the first lower wirings (81) in a region between the first pad wiring (101) and the second pad wiring (102); and at least one of second lead-out wirings (113 to 115) that is led out from the second pad wiring (102) in the second direction (Y) and is electrically connected to at least one of the second lower wirings (82) in the region between the first pad wiring (101) and the second pad wiring (102).

[A2] The semiconductor device (1A, 1B, 1C, 1E) according to A1, wherein the wiring group (80) includes the first lower wirings (81) and the second lower wirings (82) alternately arrayed in the second direction (Y).

[A3] The semiconductor device (1A, 1B, 1C, 1E) according to A1 or A2, wherein the first pad wiring (101) is electrically connected to at least one of the first lower wirings (81), and the second pad wiring (102) is electrically connected to at least one of the second lower wirings (82).

[A4] The semiconductor device (1A, 1B, 1C, 1E) according to any one of A1 to A3, wherein the first pad wiring (101) overlaps at least one of the first lower wirings (81) and at least one of the second lower wirings (82), and the second pad wiring (102) overlaps at least one of the first lower wirings (81) and at least one of the second lower wirings (82).

[A5] The semiconductor device (1A, 1B, 1C, 1E) according to A4, wherein the first pad wiring (101) overlaps the first lower wirings (81) and the second lower wirings (82), and the second pad wiring (102) overlaps the first lower wirings (81) and the second lower wirings (82).

[A6] The semiconductor device (1A, 1B, 1C, 1E) according to any one of A1 to A5, wherein at least one of the first lead-out wirings (109 to 111) crosses an intermediate portion (107) between the first pad wiring (101) and the second pad wiring (102), and at least one of the second lead-out wirings (113 to 115) crosses the intermediate portion (107), and opposes at least one of the first lead-out wirings (109 to 111) in the first direction (X).

[A7] The semiconductor device (1A, 1B, 1C, 1E) according to any one of A1 to A6, wherein at least one of the first lead-out wirings (109 to 111) opposes the second pad wiring (102) in the first direction (X).

[A8] The semiconductor device (1A, 1B, 1C, 1E) according to A7, wherein the second pad wiring (102) covers at least one of the first lower wirings (81), and the at least one of the first lead-out wirings (109 to 111) is electrically connected to a portion of the first lower wiring (81) exposed from the second pad wiring (102) in regard to the first lower wiring (81) covered with the second pad wiring (102).

[A9] The semiconductor device (1A, 1B, 1C, 1E) according to any one of A1 to A8, wherein at least one of the first lead-out wirings (109 to 111) opposes the second pad wiring (102) in the second direction (Y).

[A10] The semiconductor device (1A, 1B, 1C, 1E) according to A9, wherein at least one of the first lead-out wirings (109 to 111) overlaps at least one of the first lower wirings (81) and at least one of the second lower wirings (82) in the region between the first pad wiring (101) and the second pad wiring (102).

[A11] The semiconductor device (1A, 1B, 1C, 1E) according to any one of A1 to A10, wherein at least one of the second lead-out wirings (113 to 115) opposes the first pad wiring (101) in the first direction (X).

[A12] The semiconductor device (1A, 1B, 1C, 1E) according to A11, wherein the first pad wiring (101) covers at least one of the second lower wirings (82), and the at least one of the second lead-out wirings (113 to 115) is electrically connected to a portion of the second lower wiring (82) exposed from the first pad wiring (101) in regard to the second lower wiring (82) covered with the first pad wiring (101).

[A13] The semiconductor device (1A, 1B, 1C, 1E) according to any one of A1 to A12, wherein at least one of the second lead-out wirings (113 to 115) opposes the first pad wiring (101) in the second direction (Y).

[A14] The semiconductor device (1A, 1B, 1C, 1E) according to A13, wherein at least one of the second lead-out wirings (113 to 115) overlaps at least one of the first lower wirings (81) and at least one of the second lower wirings (82) in the region between the first pad wiring (101) and the second pad wiring (102).

[A15] The semiconductor device (1A, 1B, 1C, 1E) according to A13 or A14, wherein at least one of the first lead-out wirings (109 to 111) covers at least one of the second lower wirings (82) in the region between the first pad wiring (101) and the second pad wiring (102), and at least one of the second lead-out wirings (113 to 115) is electrically connected to a portion of the second lower wiring (82) exposed from the first lead-out wiring (109 to 111) in regard to the second lower wiring (82) covered with the first lead-out wirings (109 to 111).

[A16] The semiconductor device (1A, 1B, 1C, 1E) according to any one of A1 to A15, wherein the first lead-out wirings (109 to 111) are led out from the first pad wiring (101), and the second lead-out wirings (113 to 115) are led out from the second pad wiring (102).

[A17] The semiconductor device (1A, 1B, 1C, 1E) according to A16, wherein the second lead-out wirings (113 to 115) and the first lead-out wirings (109 to 111) are alternately arrayed in the first direction (X).

[A18] The semiconductor device (1A, 1B, 1C, 1E) according to any one of A1 to A17, further comprising: a first interlayer film (71); and a second interlayer film (72) that is laminated on the first interlayer film (71); and wherein the first lower wirings (81) and the second lower wirings (82) are arranged on the first interlayer film (71), and the first pad wiring (101), the second pad wiring (102), the first lead-out wirings (109 to 111), and the second lead-out wirings (113 to 115) are arranged on the second interlayer film (72).

[A19] The semiconductor device (1A, 1B, 1C, 1E) according to any one of A1 to A18, further comprising: a first pad electrode (181) that is arranged on the first pad wiring (101); and a second pad electrode (182) that is arranged on the second pad wiring (102).

[A20] The semiconductor device (1A, 1B, 1C, 1E) according to A1 to A19, further comprising: a chip (2); and a device structure (Tr) that is formed in the chip (2) and includes a first application end (28) to which a first potential is to be applied and a second application end (29) to which a second potential different from the first potential is to be applied; wherein the first lower wirings (81) are electrically connected to the first application end (28) over the chip (2), and the second lower wirings (82) are electrically connected to the second application end (29) over the chip (2).

[B1] A semiconductor device (1A, 1B, 1C, 1E) comprising: one and the other wiring groups (80) that are arranged at an interval in a first direction (X), the one and the other wiring groups (80) each including first lower wirings (81) and second lower wirings (82) arrayed as stripes extending in the first direction (X); a first pad wiring (101) that is arranged over the one and the other wiring groups (80) and is electrically connected to at least one of the first lower wirings (81) of each of the wiring groups (80); and a second pad wiring (102) that is arranged over the one and the other wiring groups (80) at an interval from the first pad wiring (101) in a second direction (Y) intersecting the first direction (X) and is electrically connected to at least one of the second lower wirings (82) of each of the wiring groups (80).

[B2] The semiconductor device (1A, 1B, 1C, 1E) according to B1, wherein each of the one and the other wiring groups (80) includes the first lower wirings (81) and the second lower wirings (82) that are alternately arrayed in the second direction (Y).

[B3] The semiconductor device (1A, 1B, 1C, 1E) according to B1 or B2, wherein the first pad wiring (101) overlaps both the first lower wirings (81) and the second lower wirings (82) of each of the wiring groups (80), and the second pad wiring (102) overlaps both the first lower wirings (81) and the second lower wirings (82) of each of the wiring groups (80).

[B4] The semiconductor device (1A, 1B, 1C, 1E) according to any one of B1 to B3, further comprising: at least one of first lead-out wirings (109 to 111) that is led out from the first pad wiring (101) in the second direction (Y) and is electrically connected to the first lower wirings (81) in a region between the first pad wiring (101) and the second pad wiring (102); and at least one of second lead-out wirings (113 to 115) that is led out from the second pad wiring (102) in the second direction (Y) and is electrically connected to the second lower wirings (82) in the region between the first pad wiring (101) and the second pad wiring (102).

[B5] The semiconductor device (1A, 1B, 1C, 1E) according to B4, wherein at least one of the second lead-out wirings (113 to 115) opposes the first lead-out wirings (109 to 111) in the first direction (X).

[B6] The semiconductor device (1A, 1B, 1C, 1E) according to B4 or B5, wherein at least one of the first lead-out wirings (109 to 111) is electrically connected to the first lower wirings (81) of the one wiring group (80).

[B7] The semiconductor device (1A, 1B, 1C, 1E) according to any one of B4 to B6, wherein at least one of the first lead-out wirings (109 to 111) is electrically connected to the first lower wirings (81) of the other wiring group (80).

[B8] The semiconductor device (1A, 1B, 1C, 1E) according to any one of B4 to B7, wherein at least one of the first lead-out wirings (109 to 111) opposes the second pad wiring (102) in the first direction (X).

[B9] The semiconductor device (1A, 1B, 1C, 1E) according to any one of B4 to B8, wherein at least one of the first lead-out wirings (109 to 111) opposes the second pad wiring (102) in the second direction (Y).

[B10] The semiconductor device (1A, 1B, 1C, 1E) according to any one of B4 to B9, wherein at least one of the second lead-out wirings (113 to 115) is electrically connected to the second lower wirings (82) of the one wiring group (80).

[B11] The semiconductor device (1A, 1B, 1C, 1E) according to any one of B4 to B10, wherein at least one of the second lead-out wirings (113 to 115) is electrically connected to the second lower wirings (82) of the other wiring group (80).

[B12] The semiconductor device (1A, 1B, 1C, 1E) according to any one of B4 to B11, wherein at least one of the second lead-out wirings (113 to 115) opposes the first pad wiring (101) in the first direction (X).

[B13] The semiconductor device (1A, 1B, 1C, 1E) according to any one of B4 to B12, wherein at least one of the second lead-out wirings (113 to 115) opposes the first pad wiring (101) in the second direction (Y).

[B14] The semiconductor device (1A, 1B, 1C, 1E) according to any one of B4 to B13, further comprising: an inter-wiring region (IWR) that is defined between the one and the other wiring groups (80); and wherein the first pad wiring (101) overlaps the inter-wiring region (IWR), the second pad wiring (102) overlaps the inter-wiring region (IWR), at least one of the first lead-out wirings (109 to 111) is led out to a region outside the inter-wiring region (IWR), and at least one of the second lead-out wirings (113 to 115) is led out to a region outside the inter-wiring region (IWR) and opposes the first lead-out wirings (109 to 111) in the first direction (X) across the inter-wiring region (IWR).

[B15] The semiconductor device (1A, 1B, 1C, 1E) according to B14, wherein at least one of the first lead-out wirings (109 to 111) extends as a band along the inter-wiring region (IWR), and at least one of the second lead-out wirings (113 to 115) extends as a band along the inter-wiring region (IWR).

[B16] The semiconductor device (1A, 1B, 1C, 1E) according to any one of B4 to B15, wherein the first lead-out wirings (109 to 111) are led out from the first pad wiring (101), and the second lead-out wirings (113 to 115) are led out from the second pad wiring (102).

[B17] The semiconductor device (1A, 1B, 1C, 1E) according to any one of B1 to B16, further comprising: a first pad electrode (181) that is arranged on the first pad wiring (101); and a second pad electrode (182) that is arranged on the second pad wiring (102).

[B18] The semiconductor device (1A, 1B, 1C, 1E) according to any one of B1 to B17, further comprising: an intermediate wiring (83, 84) that is arranged in a region between the one and the other wiring groups (80); and wherein the first pad wiring (101) overlaps the intermediate wiring (83, 84), and the second pad wiring (102) overlaps the intermediate wiring (83, 84).

[B19] The semiconductor device (1A, 1B, 1C, 1E) according to any one of B1 to B18, further comprising: a chip (2); and a device structure (Tr) that is formed in the chip (2) and includes a first application end (28) to which a first potential is to be applied and a second application end (29) to which a second potential different from the first potential is to be applied, wherein the first lower wirings (81) are electrically connected to the first application end (28) over the chip (2), and the second lower wirings (82) are electrically connected to the second application end (29) over the chip (2).

[B20] A semiconductor device (1A, 1B, 1C, 1E) comprising: one and the other wiring groups (80) that are arranged at an interval from each other, the one and the other wiring groups (80) each including first lower wirings (81) and second lower wirings (82); an inter-wiring region (IWR) that is defined between the one and the other wiring groups (80); a first pad wiring (101) that is arranged on the inter-wiring region (IWR); a second pad wiring (102) that is separated from the first pad wiring (101) and is arranged on the inter-wiring region (IWR); a first lead-out wiring (109 to 111) that is led out from the first pad wiring (101) to a region outside the inter-wiring region (IWR) and is electrically connected to the first lower wirings (81) of the one wiring group (80); and a second lead-out wiring (113 to 115) that is led out from the second pad wiring (102) to a region outside the inter-wiring region (IWR) such as to oppose the first lead-out wiring (109 to 111) across the inter-wiring region (IWR) and is electrically connected to the second lower wirings (82) of the other wiring group (80).

[C1] A semiconductor device (1A, 1B, 1C, 1E) comprising: wiring groups (80) that are arranged at an interval in a first direction (X), the wiring groups (80) each including first lower wirings (81) and second lower wirings (82); an inter-wiring region (IWR) that is defined as a band extending in a second direction (Y) intersecting the first direction (X) between the wiring groups (80); an intermediate wiring (83, 84) that is arranged in the inter-wiring region (IWR) and is electrically disconnected from the wiring groups (80); and an intermediate pad wiring (103, 104) that is arranged on the intermediate wiring (83, 84), is electrically disconnected from the wiring groups (80), and is connected to the intermediate wiring (83, 84).

[C2] The semiconductor device (1A, 1B, 1C, 1E) according to C1, wherein each of the wiring groups (80) includes the first lower wirings (81) and the second lower wirings (82) that are arrayed as stripes extending in the first direction (X).

[C3] The semiconductor device (1A, 1B, 1C, 1E) according to C2, wherein each of the wiring groups (80) includes the first lower wirings (81) and the second lower wirings (82) that are alternately arrayed in the second direction (Y).

[C4] The semiconductor device (1A, 1B, 1C, 1E) according to any one of C1 to C3, wherein the intermediate pad wiring (103, 104) overlaps the wiring groups (80).

[C5] The semiconductor device (1A, 1B, 1C, 1E) according to any one of C1 to C4, wherein the intermediate wiring (83, 84) extends as a band in the second direction (Y).

[C6] The semiconductor device (1A, 1B, 1C, 1E) according to C5, wherein the intermediate wiring (83, 84) does not have a portion extending in the first direction (X) in the inter-wiring region (IWR).

[C7] The semiconductor device (1A, 1B, 1C, 1E) according to any one of C to C6, wherein the intermediate wiring (83, 84) has a lead-out portion (87, 89) led out from the inter-wiring region (IWR) to the outside of the inter-wiring region (IWR).

[C8] The semiconductor device (1A, 1B, 1C, 1E) according to C7, the lead-out portion (87, 89) extends in the first direction (X) outside the inter-wiring region (IWR) and opposes at least one of the wiring groups (80) in the second direction (Y).

[C9] The semiconductor device (1A, 1B, 1C, 1E) according to any one of C1 to C8, further comprising: a first pad wiring (101) that is arranged on at least one of the wiring groups (80) and is electrically connected to the first lower wirings (81) of at least one of the wiring groups (80); and a second pad wiring (102) that is arranged on at least one of the wiring groups (80) at an interval from the first pad wiring (101) and is electrically connected to the second lower wirings (82) of at least one of the wiring groups (80).

[C10] The semiconductor device (1A, 1B, 1C, 1E) according to C9, wherein the first pad wiring (101) is arranged to overlap the intermediate wiring (83, 84) and is electrically disconnected from the intermediate wiring (83, 84), the second pad wiring (102) is arranged at an interval in the second direction (Y) from the first pad wiring (101) such as to overlap the intermediate wiring (83, 84), and is electrically disconnected from the intermediate wiring (83, 84), and the intermediate pad wiring (103, 104) is arranged in a region between the first pad wiring (101) and the second pad wiring (102).

[C11] A semiconductor device (1A, 1B, 1C, 1E) comprising: a chip (2); active regions (6) that is formed in the chip (2) at an interval in a first direction (X); a boundary region (7a) that is formed as a band extending in a second direction (Y) intersecting the first direction (X) between the active regions (6) in the chip (2); an intermediate wiring (83, 84) that is arranged in the boundary region (7a); and an intermediate pad wiring (103, 104) that is arranged over the intermediate wiring (83, 84), and is electrically connected to the intermediate wiring (83, 84).

[C12] The semiconductor device (1A, 1B, 1C, 1E) according to C11, wherein the intermediate pad wiring (103, 104) overlaps the active regions (6).

[C13] The semiconductor device (1A, 1B, 1C, 1E) according to C11 or C12, wherein the intermediate wiring (83, 84) extends as a band in the second direction (Y).

[C14] The semiconductor device (1A, 1B, 1C, 1E) according to any one of C11 to C13, further comprising: an outer peripheral region (7b) that is formed around the active regions (6) in the chip (2); wherein the intermediate wiring (83, 84) has a lead-out portion (87, 89) that is led out from above the boundary region (7a) onto the outer peripheral region (7b).

[C15] The semiconductor device (1A, 1B, 1C, 1E) according to C14, wherein the lead-out portions (87, 89) extends in the first direction (X) in the outer peripheral region (7b) and opposes at least one of the active regions (6) in the second direction (Y).

[C16] The semiconductor device (1A, 1B, 1C, 1E) according to any one of C11 to C15, further comprising: transistor structures (Tr) respectively formed in the active regions (6).

[C17] The semiconductor device (1A, 1B, 1C, 1E) according to C16, wherein the intermediate wiring (83, 84) includes a gate wiring (83) that is electrically connected to gates of the transistor structures (Tr).

[C18] The semiconductor device (1A, 1B, 1C, 1E) according to C16 or C17, wherein the intermediate wiring (83, 84) includes a chip wiring (84) that is electrically connected to the chip (2) at an interval from the transistor structures (Tr).

[C19] The semiconductor device (1A, 1B, 1C, 1E) according to any one of C11 to C18, further comprising: wiring groups (80) that are respectively arranged over the active regions (6) at an interval in the first direction (X), the wiring groups (80) each including first lower wirings (81) and second lower wirings (82); wherein the intermediate wiring (83, 84) is electrically disconnected from the wiring groups (80), and the intermediate pad wiring (103, 104) is electrically disconnected from the wiring groups (80).

[C20] The semiconductor device (1A, 1B, 1C, 1E) according to C19, further comprising: a first pad wiring (101) that is arranged over at least one of the wiring groups (80) and is electrically connected to the first lower wirings (81) of at least one of the wiring groups (80); and a second pad wiring (102) that is arranged over at least one of the wiring groups (80) at an interval from the first pad wiring (101) and is electrically connected to the second lower wirings (82) of at least one of the wiring groups (80).

[D1] A semiconductor device (1A, 1B, 1C, 1E, 1D) comprising: a wiring group (80) that includes first lower wirings (81) and second lower wirings (82) that are arrayed as stripes extending in a first direction (X); a first pad wiring (101) that is arranged over at least one of the first lower wirings (81); a second pad wiring (102) that is arranged over at least one of the second lower wirings (82) at an interval from the first pad wiring (101) in a second direction (Y) intersecting the first direction (X); an inter-pad region (105C, 105D) that is defined between the first pad wiring (101) and the second pad wiring (102); a first side wiring (191) that is led out from the first pad wiring (101) to a region opposing the inter-pad region (105C, 105D) on one side in the first direction (X) and is electrically connected to at least one of the first lower wirings (81) passing through the inter-pad region (105C, 105D); and a second side wiring (192) that is led out from the second pad wiring (102) to a region opposing the inter-pad region (105C, 105D) on one side in the first direction (X) and is electrically connected to at least one of the second lower wirings (82) passing through the inter-pad region (105C, 105D).

[D2] The semiconductor device (1A, 1B, 1C, 1E, 1D) according to D1, wherein the wiring group (80) includes the first lower wirings (81) and the second lower wirings (82) that are alternately arrayed in the second direction (Y).

[D3] The semiconductor device (1A, 1B, 1C, 1E, 1D) according to D1 or D2, wherein the first pad wiring (101) is electrically connected to at least one of the first lower wirings (81), and the second pad wiring (102) is electrically connected to at least one of the second lower wirings (82).

[D4] The semiconductor device (1A, 1B, 1C, 1E, 1D) according to any one of D1 to D3, wherein the second side wiring (192) opposes the first side wiring (191) in the first direction (X).

[D5] The semiconductor device (1A, 1B, 1C, 1E, 1D) according to any one of D1 to D4, wherein the first side wiring (191) has at least one first finger portion (202) that is led out from the first pad wiring (101) to a region opposing the inter-pad region (105C, 105D) on one side in the first direction (X) and is electrically connected to at least one of the first lower wirings (81) passing through the inter-pad region (105C, 105D), and the second side wiring (192) has at least one second finger portion (204) that is led out from the second pad wiring (102) to a region opposing the inter-pad region (105C, 105D) on one side in the first direction (X) and is electrically connected to at least one of the second lower wirings (82) passing through the inter-pad region (105C, 105D).

[D6] The semiconductor device (1A, 1B, 1C, 1E, 1D) according to D5, wherein at least one of the second finger portions (204) opposes at least one of the first finger portions (202) in the first direction (X).

[D7] The semiconductor device (1A, 1B, 1C, 1E, 1D) according to D5 or D6, wherein at least one of the first finger portions (202) overlaps the first lower wirings (81) and the second lower wirings (82) in a region opposing the inter-pad region (105C, 105D), and at least one of the second finger portions (204) overlaps the first lower wirings (81) and the second lower wirings (82) in a region opposing the inter-pad region (105C, 105D).

[D8] The semiconductor device (1A, 1B, 1C, 1E, 1D) according to any one of D5 to D7, wherein at least one of the first finger portions (202) crosses an intermediate portion of the inter-pad region (105C, 105D).

[D9] The semiconductor device (1A, 1B, 1C, 1E, 1D) according to any one of D5 to D8, wherein at least one of the first finger portions (202) is led out to a region opposing the second pad wiring (102) on the one side in the first direction (X).

[D10] The semiconductor device (1A, 1B, 1C, 1E, 1D) according to any one of D5 to D9, wherein at least one of the second finger portions (204) crosses an intermediate portion of the inter-pad region (105C, 105D).

[D11] The semiconductor device (1A, 1B, 1C, 1E, 1D) according to any one of D5 to D10,
wherein at least one of the second finger portions (204) is led out to a region opposing the first pad wiring (101) on the one side in the first direction (X).

[D12] The semiconductor device (1A, 1B, 1C, 1E, 1D) according to any one of D5 to D11, wherein the first side wiring (191) includes the first finger portions (202), and the second side wiring (192) includes the second finger portions (204).

[D13] The semiconductor device (1A, 1B, 1C, 1E, 1D) according to D12, wherein the first finger portions (202) are arrayed in a comb teeth shape, and the second finger portions (204) are arrayed in a comb teeth shape.

[D14] The semiconductor device (1A, 1B, 1C, 1E, 1D) according to D13, wherein the second finger portions (204) are arrayed in a comb teeth shape that meshes with the first finger portions (202).

[D15] The semiconductor device (1A, 1B, 1C, 1E, 1D) according to any one of D12 to D14, wherein the first finger portions (202) have a wiring length different from each other in the second direction (Y), and the second finger portions (204) have a wiring length different from each other in the second direction (Y).

[D16] The semiconductor device (1A, 1B, 1C, 1E, 1D) according to any one of D1 to D15, wherein the wiring groups (80) are arrayed at an interval in the first direction (X), and the first pad wiring (101), the second pad wiring (102), the inter-pad region (105C, 105D), the first side wiring (191), and the second side wiring (192) are formed over the outermost wiring group (80) in the first direction (X) among the wiring groups (80).

[D17] The semiconductor device (1A, 1B, 1C, 1E, 1D) according to any one of D1 to D16, further comprising: an intermediate pad wiring (103, 104) that is arranged in the inter-pad region (105C, 105D); and wherein the first side wiring (191) is electrically connected to a portion of the first lower wirings (81) exposed from the intermediate pad wiring (103, 104) in the first lower wirings (81) hidden by the intermediate pad wiring (103, 104), and the second side wiring (192) is electrically connected to portion of the second lower wirings (82) exposed from the intermediate pad wiring (103, 104) in the second lower wirings (82) hidden by the intermediate pad wiring (103, 104).

[D18] The semiconductor device (1A, 1B, 1C, 1E, 1D) according to D17, wherein the intermediate pad wiring (103, 104) is electrically disconnected from the first lower wirings (81) and the second lower wirings (82).

[D19] The semiconductor device (1A, 1B, 1C, 1E, 1D) according to any one of D1 to D18, further comprising: a first pad electrode (181) that is arranged on the first pad wiring (101); and a second pad electrode (182) that is arranged on the second pad wiring (102).

[D20] The semiconductor device (1A, 1B, 1C, 1E, 1D) according to any one of D1 to D19, further comprising: a chip (2); and a device structure (Tr) that is formed in the chip (2) and includes a first application end (28) to which a first potential is to be applied and a second application end (29) to which a second potential different from the first potential is to be applied, wherein the first lower wirings (81) are electrically connected to the first application end (28) over the chip (2), and the second lower wirings (82) are electrically connected to the second application end (29) over the chip (2).

[E1] A semiconductor device (1A, 1B, 1C, 1E, 1D) comprising: a chip (2) having a first main surface (3) on one side and a second main surface (4) on the other side; a base layer (8) of a first conductivity type (p-type) that is formed on the second main surface (4) side in the chip (2); a drift layer (9) of a second conductivity type (n-type) that is formed on the first main surface (3) side in the chip (2); gate structures (12) of trench-electrode-types that are formed in the first main surface (3) such as to be positioned in the drift layer (9); drain source regions (28, 29) of the second conductivity type (n-type) that are respectively formed in regions between the gate structures (12) in a surface layer portion of the drift layer (9); and impurity regions (51) of the first conductivity type (p-type) that are formed in regions along lower end portions of the gate structures (12).

[E2] The semiconductor device (1A, 1B, 1C, 1E, 1D) according to E1, further comprising: a field structure (42) of a trench-electrode-type formed in a peripheral edge portion of the first main surface (3) at an interval from the gate structures (12).

[E3] The semiconductor device (1A, 1B, 1C, 1E, 1D) according to E2, wherein the field structure (42) surrounds the gate structures (12).

[E4] The semiconductor device (1A, 1B, 1C, 1E, 1D) according to E2 or E3, wherein the field structure (42) is formed to be wider than the gate structure (12).

[E5] The semiconductor device (1A, 1B, 1C, 1E, 1D) according to any one of E2 to E4, wherein the field structure (42) is deeper than the gate structure (12).

[E6] The semiconductor device (1A, 1B, 1C, 1E, 1D) according to any one of E2 to E5, further comprising: the field structures (42).

[E7] The semiconductor device (1A, 1B, 1C, 1E, 1D) according to any one of E1 to E6, further comprising: a base structure (55) of a trench-electrode-type that is formed in the first main surface (3) at an interval from end portions of the gate structures (12) and is electrically connected to the chip (2).

[E8] The semiconductor device (1A, 1B, 1C, 1E, 1D) according to E7, wherein the base structure (55) is formed to be narrower than the gate structure (12).

[E9] The semiconductor device (1A, 1B, 1C, 1E, 1D) according to E8, wherein the base structure (55) is deeper than the gate structure (12).

[E10] The semiconductor device (1A, 1B, 1C, 1E, 1D) according to any one of E7 to E9, wherein the base structure (55) includes a base trench (56) formed in the first main surface (3) and a base electrode (57) that is embedded in the base trench (56) and is mechanically and electrically connected to the chip (2).

[E11] The semiconductor device (1A, 1B, 1C, 1E, 1D) according to any one of E7 to E10, further comprising: a contact region (61) of the first conductivity type (p-type) that is formed in the chip (2) within a depth range between the base layer (8) and the base structure (55) and electrically connects the base structure (55) to the base layer (8).

[E12] The semiconductor device (1A, 1B, 1C, 1E, 1D) according to any one of E7 to E11, further comprising: a surface layer region (62) of the second conductivity type (n-type) electrically connected to the base structure (55) in a surface layer portion of the first main surface (3).

[E13] The semiconductor device (1A, 1B, 1C, 1E, 1D) according to any one of E7 to E12, further comprising: a silicide layer (60) formed in a region along the base structure (55) in the chip (2).

[E14] The semiconductor device (1A, 1B, 1C, 1E, 1D) according to any one of E1 to E13, further comprising: a wiring group (80) including wirings (81, 82) electrically connected to the drain source regions (28, 29) on the first main surface (3).

[E15] The semiconductor device (1A, 1B, 1C, 1E, 1D) according to E14, wherein the drain source regions (28, 29) include first drain source regions (28) to which a first potential is to be applied and second drain source regions (29) to which a second potential different from the first potential is to be applied, the wiring group (80) includes first wirings (81) that apply the first potential to the first drain source regions (28) and second wirings (82) that apply the second potential to the second drain source regions (29).

[E16] The semiconductor device (1A, 1B, 1C, 1E, 1D) according to E15, wherein the first wirings (81) are respectively arranged over the first drain source regions (28), and the second wirings (82) are respectively arranged over the second drain source regions (29).

[E17] The semiconductor device (1A, 1B, 1C, 1E, 1D) according to E15 or E16, wherein the second drain source regions (29) and the first drain source regions (28) are alternately formed, and the second wirings (82) and the first wirings (81) are alternately arrayed.

[E18] The semiconductor device (1A, 1B, 1C, 1E, 1D) according to any one of E15 to E17, further comprising: a first pad wiring (101) electrically connected to at least one of the first wirings (81) over the wiring group (80); and a second pad wiring (102) electrically connected to at least one of the second wirings (82) over the wiring group (80).

[E19] The semiconductor device (1A, 1B, 1C, 1E, 1D) according to any one of E1 to E18, further comprising: a gate wiring (83) electrically connected to the gate structures (12) over the first main surface (3).

[E20] The semiconductor device (1A, 1B, 1C, 1E, 1D) according to any one of E1 to E19, further comprising: a base wiring (84) electrically connected to the chip over the first main surface (3).

The configurations according to [A1] to [A20], the configurations according to [B1] to [B20], the configurations according to [C1] to [C20], the configurations according to [D1] to [D20], and the configurations according to [E1] to [E20] can be appropriately combined with one another.

While the specific embodiments have been described in detail above, these are merely specific examples used to clarify the technical contents. The various technical ideas extracted from this Description can be combined as appropriate with one another without being limited by the order of description, the order of configuration examples, the order of modification examples, etc., in the Description.

What is claimed is:

1. A semiconductor device comprising:
one and the other wiring groups that are arranged at an interval in a first direction X, the one and the other wiring groups each including first lower wirings and second lower wirings arrayed as stripes extending in the first direction X;
a first pad wiring that is arranged over the one and the other wiring groups and is electrically connected to at least one of the first lower wirings of each of the wiring groups; and
a second pad wiring that is arranged over the one and the other wiring groups at an interval from the first pad wiring in a second direction Y intersecting the first direction X and is electrically connected to at least one of the second lower wirings of each of the wiring groups.

2. The semiconductor device according to claim 1,
wherein each of the one and the other wiring groups includes the first lower wirings and the second lower wirings that are alternately arrayed in the second direction Y.

3. The semiconductor device according to claim 1,
wherein the first pad wiring overlaps both the first lower wirings and the second lower wirings of each of the wiring groups, and
the second pad wiring overlaps both the first lower wirings and the second lower wirings of each of the wiring groups.

4. The semiconductor device according to claim 1, further comprising:
at least one of first lead-out wirings that is led out from the first pad wiring in the second direction Y and is electrically connected to the first lower wirings in a region between the first pad wiring and the second pad wiring; and
at least one of second lead-out wirings that is led out from the second pad wiring in the second direction Y and is electrically connected to the second lower wirings in a region between the first pad wiring and the second pad wiring.

5. The semiconductor device according to claim 4,
wherein at least one of the second lead-out wirings opposes the first lead-out wirings in the first direction X.

6. The semiconductor device according to claim 4,
wherein at least one of the first lead-out wirings is electrically connected to the first lower wirings of the one wiring group.

7. The semiconductor device according to claim 4,
wherein at least one of the first lead-out wirings is electrically connected to the first lower wirings of the other wiring group.

8. The semiconductor device according to claim 4,
wherein at least one of the first lead-out wirings opposes the second pad wiring in the first direction X.

9. The semiconductor device according to claim 4,
wherein at least one of the first lead-out wirings opposes the second pad wiring in the second direction Y.

10. The semiconductor device according to claim 4,
wherein at least one of the second lead-out wirings is electrically connected to the second lower wirings of the one wiring group.

11. The semiconductor device according to claim 4,
wherein at least one of the second lead-out wirings is electrically connected to the second lower wirings of the other wiring group.

12. The semiconductor device according to claim 4,
wherein at least one of the second lead-out wirings opposes the first pad wiring in the first direction X.

13. The semiconductor device according to claim 4,
wherein at least one of the second lead-out wirings opposes the first pad wiring in the second direction Y.

14. The semiconductor device according to claim 4, further comprising:
an inter-wiring region that is defined between the one and the other wiring groups;
wherein the first pad wiring overlaps the inter-wiring region,
the second pad wiring overlaps the inter-wiring region,
at least one of the first lead-out wirings is led out to a region outside the inter-wiring region, and
at least one of the second lead-out wirings is led out to a region outside the inter-wiring region and opposes the first lead-out wirings in the first direction X across the inter-wiring region.

15. The semiconductor device according to claim 14,
wherein at least one of the first lead-out wirings extends as a band along the inter-wiring region, and
at least one of the second lead-out wirings extends as a band along the inter-wiring region.

16. The semiconductor device according to claim 4,
wherein the first lead-out wirings are led out from the first pad wiring, and
the second lead-out wirings are led out from the second pad wiring.

17. The semiconductor device according to claim 1, further comprising:
a first pad electrode that is arranged on the first pad wiring; and
a second pad electrode that is arranged on the second pad wiring.

18. The semiconductor device according to claim 1, further comprising:
an intermediate wiring that is arranged in a region between the one and the other wiring groups, wherein
the first pad wiring overlaps the intermediate wiring, and
the second pad wiring overlaps the intermediate wiring.

19. The semiconductor device according to claim 1, further comprising:
a chip; and
a device structure that is formed in the chip and includes a first application end to which a first potential is to be applied and a second application end to which a second potential different from the first potential is to be applied; and
wherein the first lower wirings are electrically connected to the first application end over the chip, and
the second lower wirings are electrically connected to the second application end over the chip.

20. A semiconductor device comprising:
one and the other wiring groups that are arranged at an interval from each other, the one and the other wiring groups each including first lower wirings and second lower wirings;
an inter-wiring region that is defined between the one and the other wiring groups;
a first pad wiring that is arranged over the inter-wiring region;
a second pad wiring that is separated from the first pad wiring and is arranged over the inter-wiring region;
a first lead-out wiring that is led out from the first pad wiring to a region outside the inter-wiring region and is electrically connected to the first lower wirings of the one wiring group; and
a second lead-out wiring that is led out from the second pad wiring to a region outside the inter-wiring region such as to oppose the first lead-out wiring across the inter-wiring region and is electrically connected to the second lower wirings of the other wiring group.
